(19) United States
(12) Patent Application Publication
(10) Pub. No.: US 2025/0057039 A1
(43) Pub. Date: Feb. 13, 2025

(54) LIGHT EMITTING ELEMENT, COMPOUND FOR THE SAME, AND DISPLAY DEVICE INCLUDING THE LIGHT EMITTING ELEMENT

(71) Applicant: Samsung Display Co., Ltd., Yongin-si (KR)

(72) Inventors: DONGJUN KIM, Yongin-si (KR); BEOMJOON KIM, Yongin-si (KR); HANKYU PAK, Yongin-si (KR); HYUNBIN PARK, Yongin-si (KR); JINYOUNG YUN, Yongin-si (KR); HAN NA CHA, Yongin-si (KR); SANGHYUN HAN, Yongin-si (KR)

(21) Appl. No.: 18/629,854

(22) Filed: Apr. 8, 2024

(30) Foreign Application Priority Data
Jul. 10, 2023 (KR) 10-2023-0088889

(51) Int. Cl. H10K 85/60; C07F 9/6521; C09K 11/06; H10K 50/16; H10K 85/30

(52) U.S. Cl. CPC H10K 85/654; C07F 9/6521; C09K 11/06; H10K 50/16; H10K 85/342; H10K 85/346; C09K 2211/1018

(57) ABSTRACT

A light emitting element including a first electrode, a second electrode on the first electrode, and at least one functional layer is provided. The functional layer includes a compound having two phenylene groups connected to a cycloalkyl group, and also includes a phosphine oxide group and a triazine group. The compound may be between the first electrode and the second electrode.

### CROSS-REFERENCE TO RELATED APPLICATION

This application claims priority to and the benefit of Korean Patent Application No. 10-2023-0088889, filed on Jul. 10, 2023, in the Korean Intellectual Property Office, the entire content of which is incorporated herein by reference.

### BACKGROUND

### 1. Field

The present disclosure herein relates to a compound for a light emitting element, a light emitting element including the same, a display device including the light emitting element, and to a light emitting element and a display device, including a novel compound in an electron transport layer.

### 2. Description of the Related Art

Recently, the development of an organic electroluminescence display device as an image display device is being actively conducted. The organic electroluminescence display device is a display device including a so-called “self-luminescent” type or kind of light emitting element in which holes and electrons injected, respectively, from a first electrode and a second electrode are combined in an emission layer of the display device. Subsequently, a light emitting material in the emission layer (e.g., light-emitting layer) emits light to achieve (e.g., implement) display (e.g., of an image).

Implementation of a light emitting element to a display device requires, (or there is a desire for), the decrease of a driving voltage and the increase of emission efficiency and lifetime. Therefore, the need or desire exists for continued research and development on materials for a light emitting element capable of stably achieving such characteristics or desires.

### SUMMARY

One or more aspects of embodiments of the present disclosure is directed toward a light emitting element having improved emission efficiency and element lifetime.

One or more aspects of embodiments of the present disclosure is directed toward a compound which may improve the emission efficiency of a light emitting element and element lifetime.

One or more aspects of embodiments of the present disclosure is directed toward a display device having excellent or suitable display quality by including a light emitting element having improved emission efficiency and element lifetime.

A light emitting element of one or more embodiments includes: a first electrode; a second electrode provided on the first electrode; and at least one functional layer including a compound represented by Formula 1, and provided between the first electrode and the second electrode.

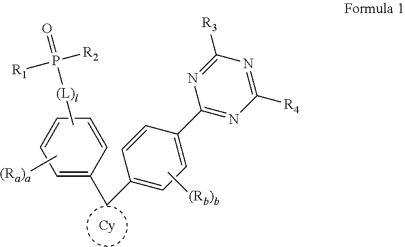

In Formula 1, Cy may be a substituted or unsubstituted cycloalkyl group of 3 to 30 ring-forming carbon atoms, L may be a substituted or unsubstituted arylene group of 6 to 30 ring-forming carbon atoms, or a substituted or unsubstituted heteroarylene group of 2 to 30 ring-forming carbon atoms, R₁ to R₄ may each independently be a substituted or unsubstituted alkyl group of 1 to 10 carbon atoms, or a substituted or unsubstituted aryl group of 6 to 30 ring-forming carbon atoms, Rₐ and R_{b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, “a” and “b” may each independently be an integer of 0 to 4, and “l” may be 1 or 2.

In one or more embodiments, Formula 1 may be represented by at least one selected from among Formula 1-1a to Formula 1-1c.

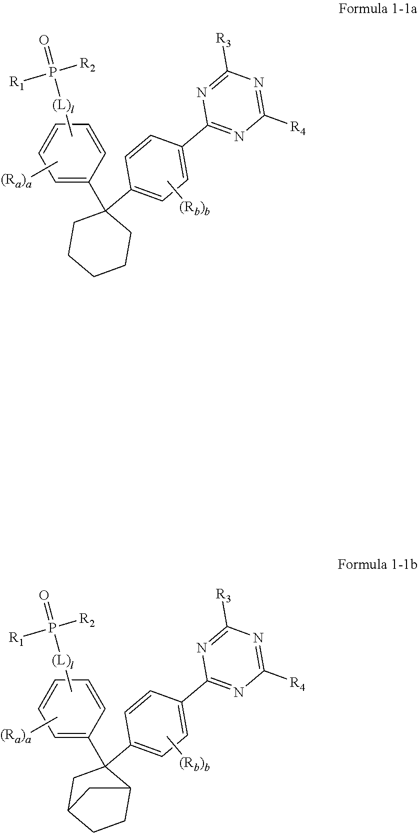

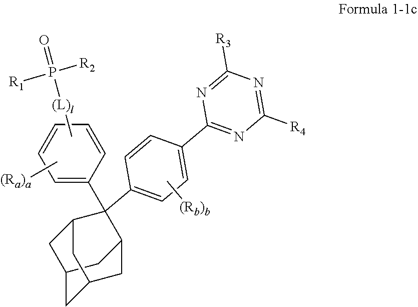

In Formula 1-1a to Formula 1-1c, L, R₁ to R₄, Rₐ, R_{b}, “a”, “b”, and “l” may each independently be as defined in Formula 1.

In one or more embodiments, R₁ and R₂ may each independently be an unsubstituted methyl group or an unsubstituted phenyl group.

In one or more embodiments, R₃ and R₄ may each independently be an unsubstituted phenyl group, an unsubstituted biphenyl group, an unsubstituted terphenyl group, an unsubstituted naphthyl group, an unsubstituted anthracenyl group, or an anthracenyl group substituted with a phenyl group.

In one or more embodiments, L may be an unsubstituted phenylene group, an unsubstituted naphthalene group, or an unsubstituted anthracene group.

In one or more embodiments, Formula 1 may be represented by Formula 1-2a or Formula 1-2b.

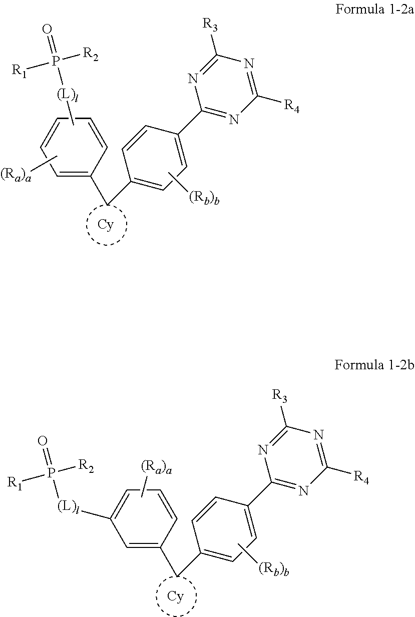

In Formula 1-2a and Formula 1-2b, Cy, L, R₁ to R₄, Rₐ, R_{b}, “a”, “b”, and “l” may each independently be as defined in Formula 1.

In one or more embodiments, Rₐ and R_{b} may each be a hydrogen atom.

In one or more embodiments, the at least one functional layer may include an emission layer, a hole transport region provided between the first electrode and the emission layer, and an electron transport region provided between the emission layer and the second electrode, and the electron transport region may include the compound represented by Formula 1.

A compound of one or more embodiments is represented by Formula 1.

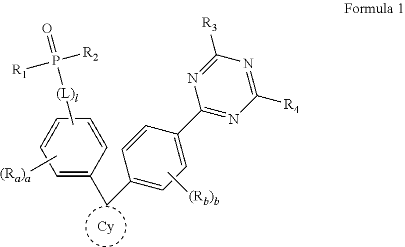

In Formula 1, Cy may be a substituted or unsubstituted cycloalkyl group of 3 to 30 ring-forming carbon atoms, L is a substituted or unsubstituted arylene group of 6 to 30 ring-forming carbon atoms, or a substituted or unsubstituted heteroarylene group of 2 to 30 ring-forming carbon atoms, R₁ to R₄ may each independently be a substituted or unsubstituted alkyl group of 1 to 10 carbon atoms, or a substituted or unsubstituted aryl group of 6 to 30 ring-forming carbon atoms, Rₐ and R_{b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, “a” and “b” may each independently be an integer of 0 to 4, and “l” may be 1 or 2.

In one or more embodiments, Formula 1 may be represented by at least one selected from among Formula 1-1a to Formula 1-1c.

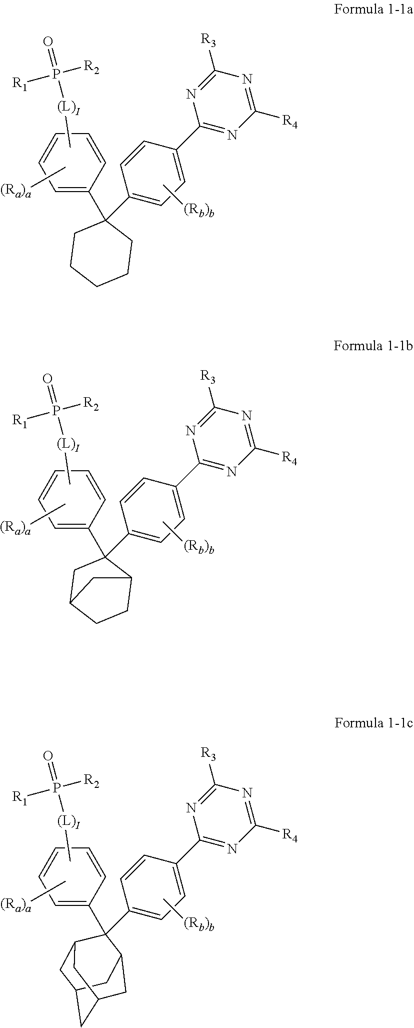

In Formula 1-1a to Formula 1-1c, L, R₁ to R₄, Rₐ, R_{b}, “a”, “b”, and “l” may each independently be as defined in Formula 1.

In one or more embodiments, R₁ and R₂ may each independently be an unsubstituted methyl group or an unsubstituted phenyl group.

In one or more embodiments, R₃ and R₄ may each independently be an unsubstituted phenyl group, an unsubstituted biphenyl group, an unsubstituted terphenyl group, an unsubstituted naphthyl group, an unsubstituted anthracenyl group, or an anthracenyl group substituted with a phenyl group.

In one or more embodiments, L may be an unsubstituted phenylene group, an unsubstituted naphthalene group, or an unsubstituted anthracene group.

In one or more embodiments, Formula 1 may be represented by Formula 1-2a or Formula 1-2b.

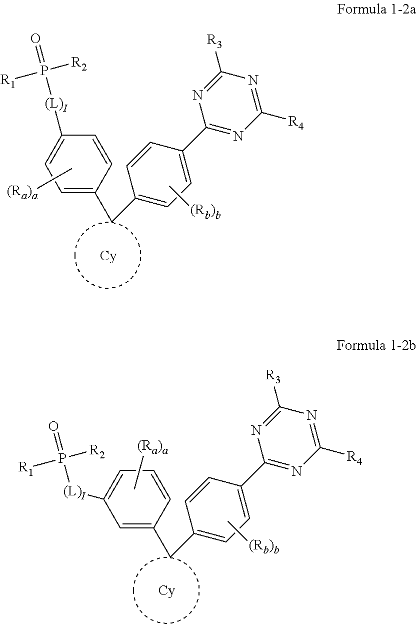

In Formula 1-2a and Formula 1-2b, Cy, L, R₁ to R₄, Rₐ, R_{b}, “a”, “b”, and “l” may each independently be as the defined in Formula 1.

In one or more embodiments, Rₐ and R_{b} may each be a hydrogen atom.

A display device of one or more embodiments includes: a base layer; a circuit layer provided on the base layer; and a display element layer including a light emitting element, and provided on the circuit layer, wherein the light emitting element includes a first electrode, a second electrode opposite (e.g., oppositely provided) to (e.g., facing) the first electrode, and at least one functional layer provided between the first electrode and the second electrode, and the at least one functional layer includes a compound represented by Formula 1.

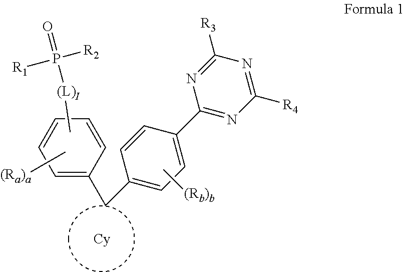

In Formula 1, Cy may be a substituted or unsubstituted cycloalkyl group of 3 to 30 ring-forming carbon atoms, L is a substituted or unsubstituted arylene group of 6 to 30 ring-forming carbon atoms, or a substituted or unsubstituted heteroarylene group of 2 to 30 ring-forming carbon atoms, R₁ to R₄ may each independently be a substituted or unsubstituted alkyl group of 1 to 10 carbon atoms, or a substituted or unsubstituted aryl group of 6 to 30 ring-forming carbon atoms, Rₐ and R_{b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, “a” and “b” may each independently be an integer of 0 to 4, and “l” may be 1 or 2.

In one or more embodiments, the at least one functional layer may include an emission layer, a hole transport region provided between the first electrode and the emission layer, and an electron transport region provided between the emission layer and the second electrode, and the electron transport region may include the compound represented by Formula 1.

In one or more embodiments, the display device may include a quantum dot and may further include a light control layer provided on the display element layer.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display device according to one or more embodiments of the present disclosure;

FIG. 2 is a cross-sectional view showing a display device according to one or more embodiments of the present disclosure;

FIG. 3 is a cross-sectional view schematically showing a light emitting element of one or more embodiments of the present disclosure;

FIG. 4 is a cross-sectional view schematically showing a light emitting element of one or more embodiments of the present disclosure;

FIG. 5 is a cross-sectional view schematically showing a light emitting element of one or more embodiments of the present disclosure;

FIG. 6 is a cross-sectional view schematically showing a light emitting element of one or more embodiments of the present disclosure;

FIG. 7 is a cross-sectional view showing a display device according to one or more embodiments of the present disclosure;

FIG. 8 is a cross-sectional view showing a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure; and

FIG. 11 is a perspective view schematically showing an electronic apparatus including a display device according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure are exaggeratingly illustrated for clarity of the present disclosure. It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure.

As utilized herein, the singular forms, “a,” “an,” and “the” are intended to include the plural forms as well, unless the context clearly indicates otherwise.

As utilized herein, the term “and/or” includes any and all combinations that the associated configurations can define.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

In the present application, it will be understood that the terms “include,” “includes,” “including,” “comprise,” “comprises”, “comprising,” “has,” “having,” “have,” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. The preceding comparative terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition/structure, but the “component” of less than a suitable amount may still be included due to other impurities and/or external factor.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

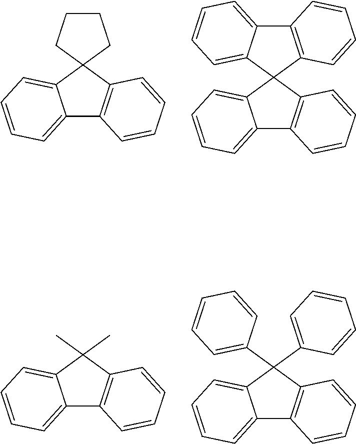

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

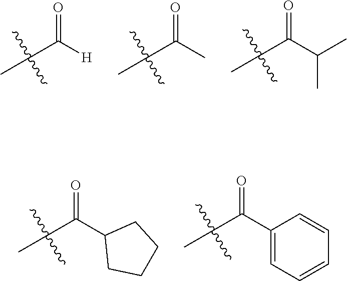

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In some embodiments, in the specification,

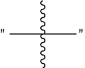

and “—*” refer to a position to be connected.

Hereinafter, embodiments of the present disclosure will be described with reference to the accompanying drawings.

### Display Device

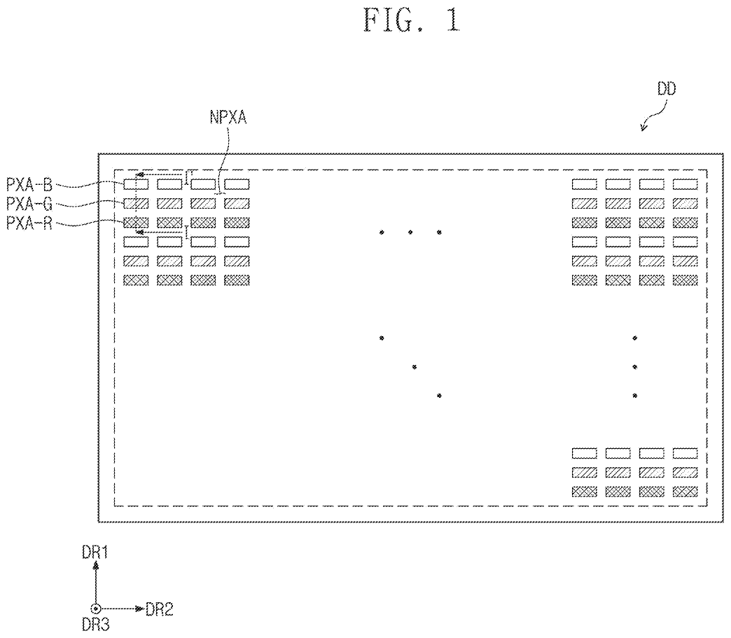

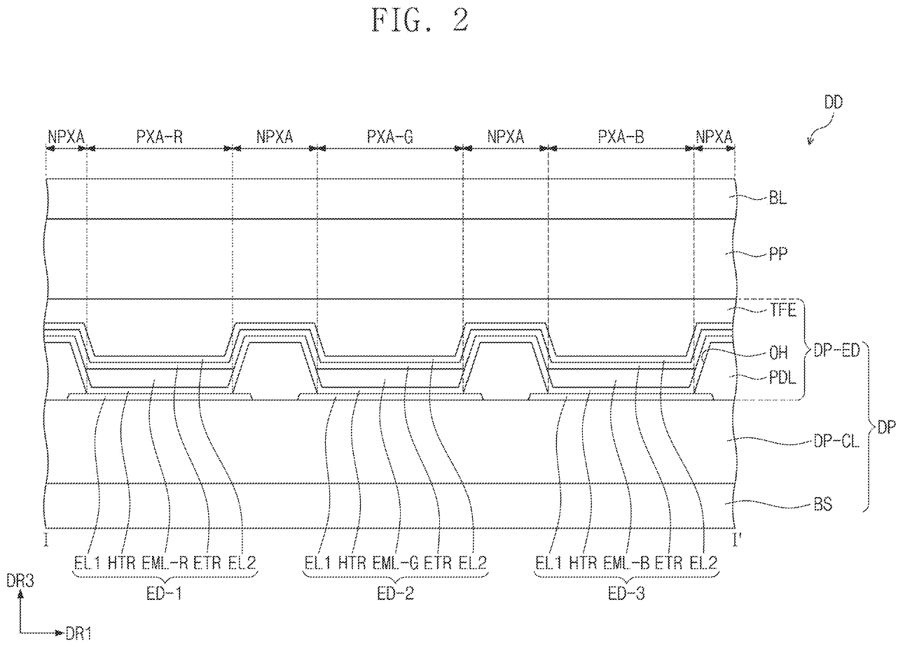

FIG. 1 is a plan view illustrating one or more embodiments of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP provided on the display panel DP. The display panel DP includes light emitting devices ED-1, ED-2, and ED-3. The display apparatus DD may include a plurality of light emitting devices ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided (e.g., excluded) from the display apparatus DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided (e.g., excluded).

The display apparatus DD according to one or more embodiments may further include a filling layer. The filling layer may be provided between a display element layer DP-ED and the base substrate BL. The filling layer may be an organic material layer. The filling layer may include at least one of an acrylic-based resin, a silicone-based resin, or an epoxy-based resin (e.g., at least one selected from among an acrylic-based resin, a silicone-based resin, and an epoxy-based resin).

The display panel DP may include a base layer BS, a circuit layer DP-CL provided on the base layer BS, and the display element layer DP-ED. The display element layer DP-ED may include a pixel defining film PDL, the light emitting devices ED-1, ED-2, and ED-3 provided between portions of the pixel defining film PDL, and an encapsulation layer TFE provided on the light emitting devices ED-1, ED-2, and ED-3.

The base layer BS may be a member which provides a base surface on which the display element layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display element layer DP-ED.

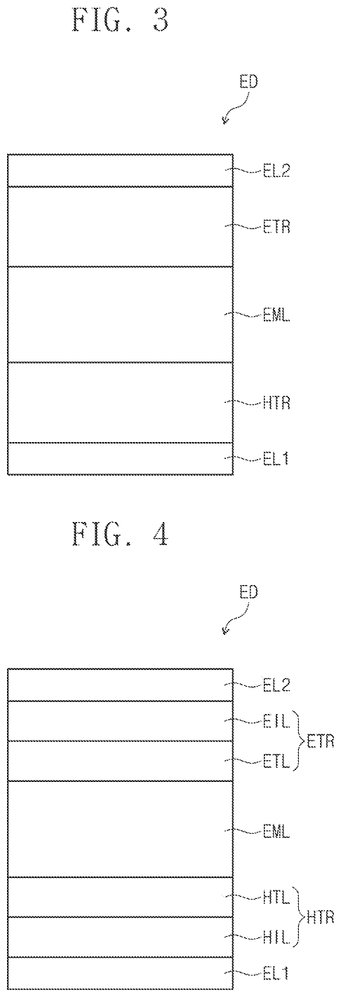

Each of the light emitting devices ED-1, ED-2, and ED-3 may have a structure of each light emitting device ED of embodiments according to FIGS. 3 to 6, as described in more detail herein. Each of the light emitting devices ED-1, ED-2, and ED-3 may include a first electrode EL1, a hole transport region HTR, a layer selected from emission layers EML-R, EML-G, and EML-B, an electron transport region ETR, and a second electrode EL2.

FIG. 2 illustrates one or more embodiments in which the emission layers EML-R, EML-G, and EML-B of the light emitting devices ED-1, ED-2, and ED-3 are provided in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in one or more embodiments may be provided by being patterned in an inkjet printing method.

The encapsulation layer TFE may cover the light emitting devices ED-1, ED-2 and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include one or more non-light emitting region(s) NPXA and also include light emitting regions PXA-R, PXA-G, and PXA-B. The light emitting regions PXA-R, PXA-G, and PXA-B may be regions in which lights generated by the respective light emitting devices ED-1, ED-2, and ED-3 are emitted. The light emitting regions PXA-R, PXA-G, and PXA-B may be spaced and/or apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display apparatus DD according to one or more embodiments, the plurality of light emitting devices ED-1, ED-2 and ED-3 may be to emit (e.g., configured to emit) light beams having wavelengths different from each other. For example, in one or more embodiments, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit (e.g., configured to emit) light beams in substantially the same wavelength range or at least one light emitting device may be to emit (e.g., configured to emit) a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE™) arrangement form or a diamond (Diamond Pixel™) arrangement form, (PENTILE® and Diamond Pixel® are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically showing light emitting devices according to one or more embodiments. The light emitting device ED of one or more embodiments may include a first electrode EL1, a hole transport region HTR, an emission layer EML, an electron transport region ETR, and a second electrode EL2 stacked in order.

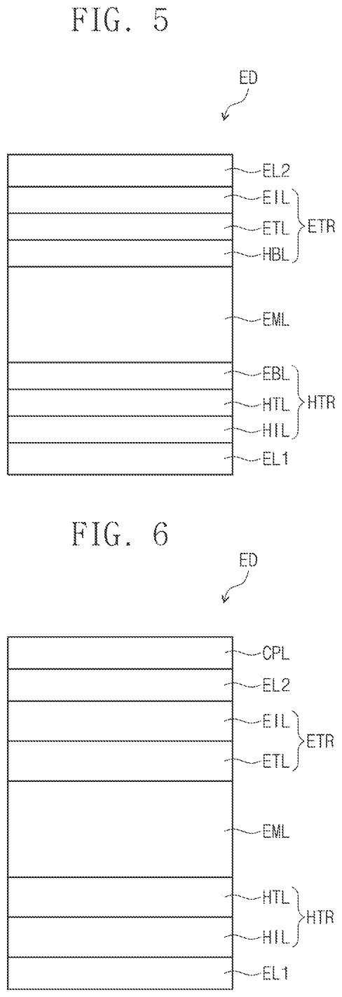

Compared with FIG. 3, FIG. 4 illustrates a cross-sectional view of a light emitting device ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting device ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of one or more embodiments including a capping layer CPL provided on a second electrode EL2.

The first electrode EL1 has conductivity (e.g., is a conductor). The first electrode EL1 may include (e.g., be formed of) a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film including (e.g., formed of) the herein-described materials, and a transparent conductive film including (e.g., formed of) ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer including (e.g., formed of) a single material, a single layer including (e.g., formed of) a plurality of different materials, or a multilayer structure including a plurality of layers including (e.g., formed of) a plurality of different materials.

For example, the hole transport region HTR may have a single layer structure of the hole injection layer HIL or the hole transport layer HTL, or may have a single layer structure including (e.g., formed of) a hole injection material and a hole transport material. In some embodiments, the hole transport region HTR may have a single layer structure including (e.g., formed of) a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

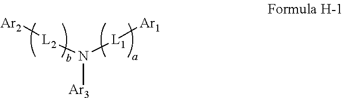

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-2 may be a diamine compound in which at least one among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

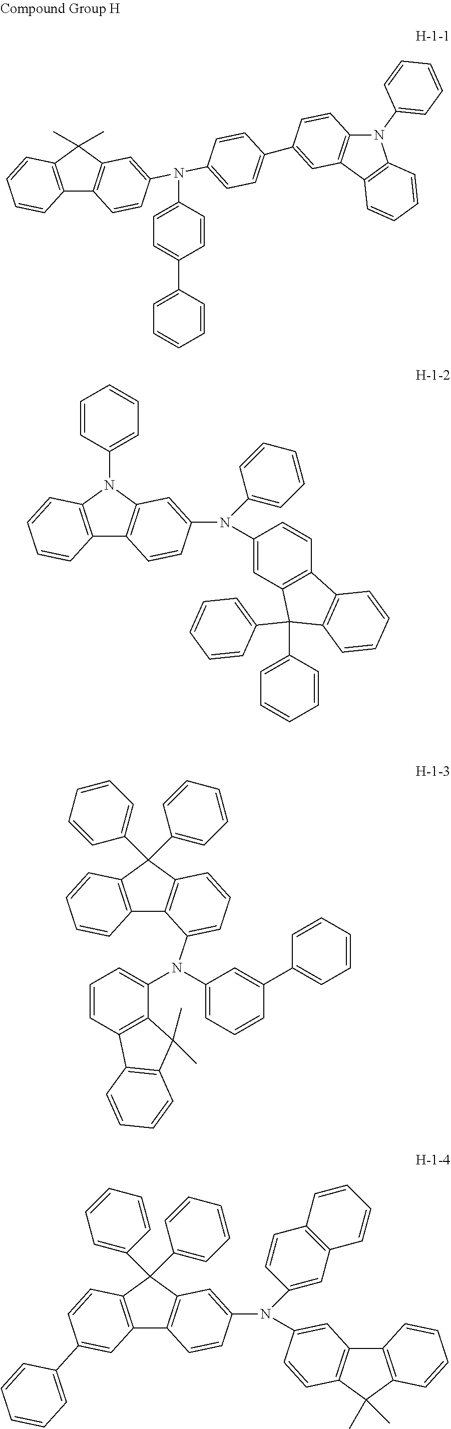 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

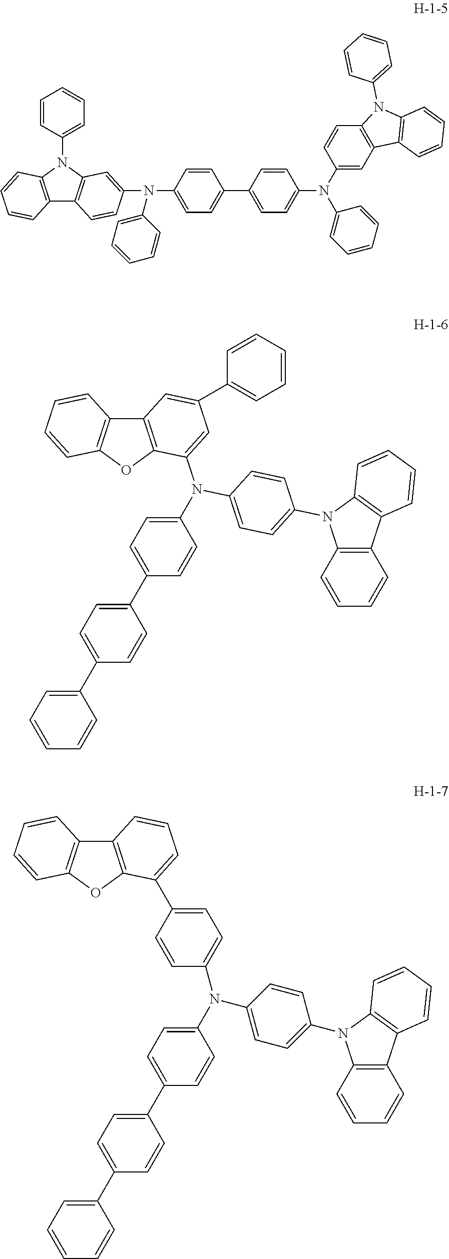 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

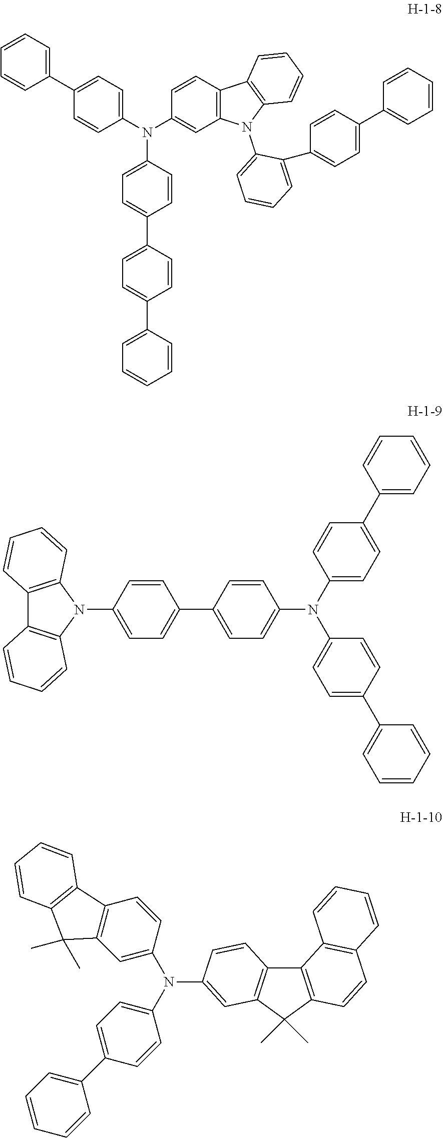 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

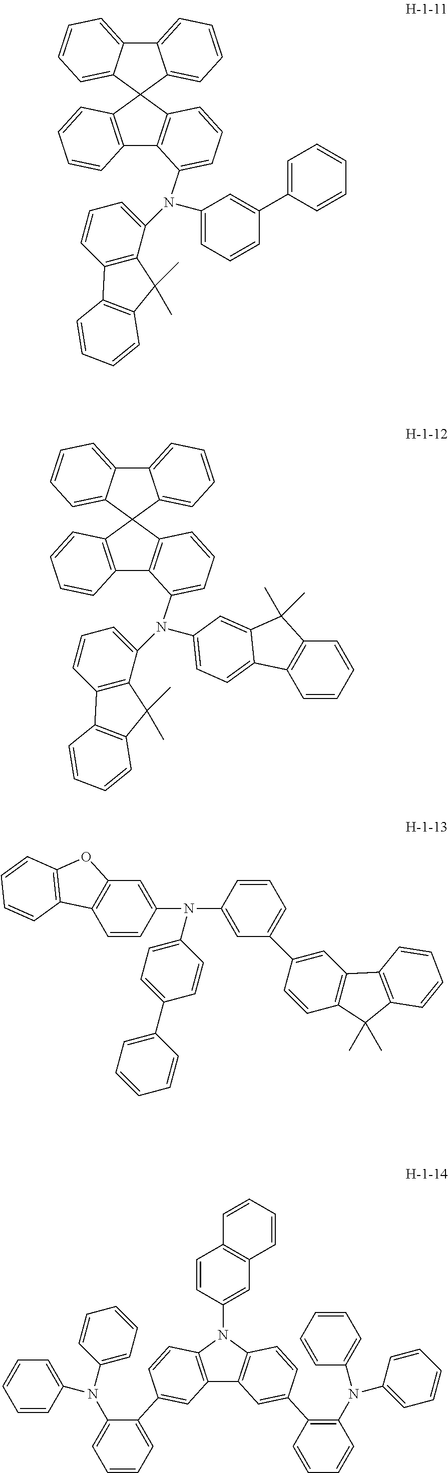 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

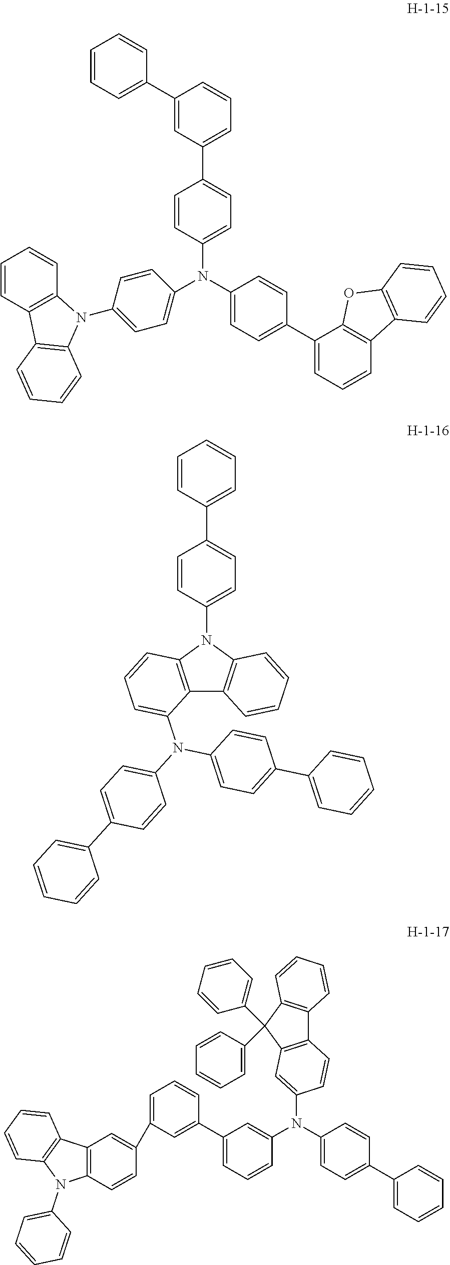 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

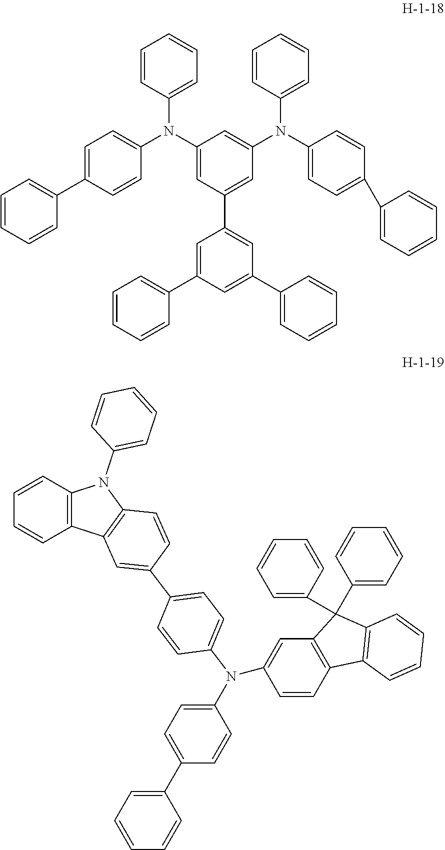 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include at least one selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

An emission layer EML is provided on the hole transport region HTR. The emission layer EML may have a thickness of, for example, about 100 Å to about 1,000 Å or about 100 Å to about 300 Å. The emission layer EML may have a single layer including (e.g., formed utilizing) a single material, a single layer including (e.g., formed utilizing) multiple different materials, or a multilayer structure having multiple layers including (e.g., formed utilizing) multiple different materials.

In the light emitting element ED of one or more embodiments, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting elements ED of embodiments, shown in FIG. 3 to FIG. 6, the emission layer EML may include a host and a dopant.

The emission layer EML may include a first compound represented by any one among Formula F-a to Formula F-c. The compounds represented by Formula F-a to Formula F-c may be utilized as fluorescence dopant materials.

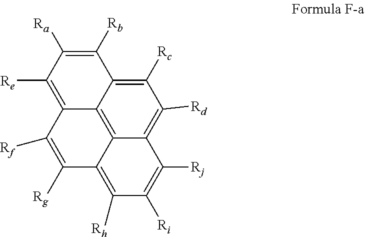

In Formula F-a, two selected from Rₐ to Rⱼ may each independently be substituted with *—NAr₁Ar₂. The remainder not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

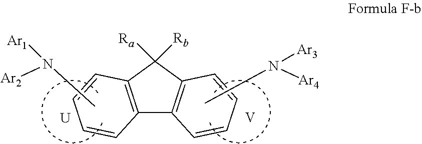

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or Vis 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

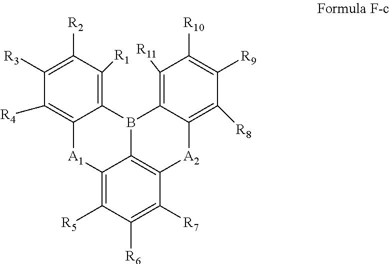

In Formula F-c, A1 and A2 may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A1 and A2 may each independently be combined with the substituents of an adjacent ring to form a fused ring. For example, when A1 and A2 may each independently be NRₘ, A1 may be combined with R₄ or R₅ to form a ring. In some embodiments, A2 may be combined with R₇ or R₈ to form a ring.

The emission layer EML may include a compound represented by Formula E-1. The compound represented by Formula E-1 may be utilized as a fluorescence host material.

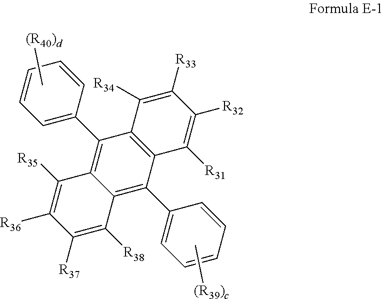

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, each of R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

Formula E-1 may be represented by any one selected from among Compound E1 to Compound E19.

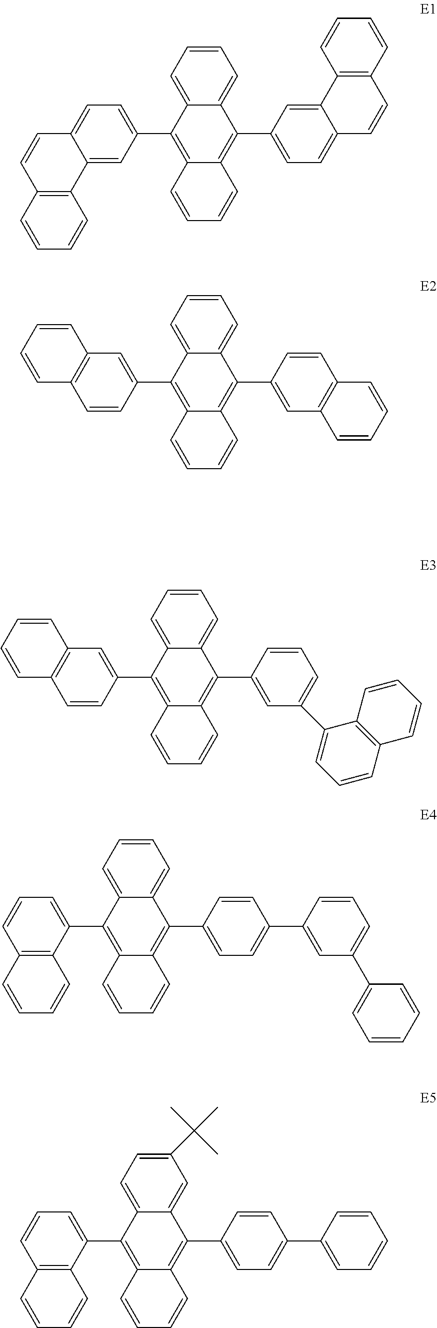

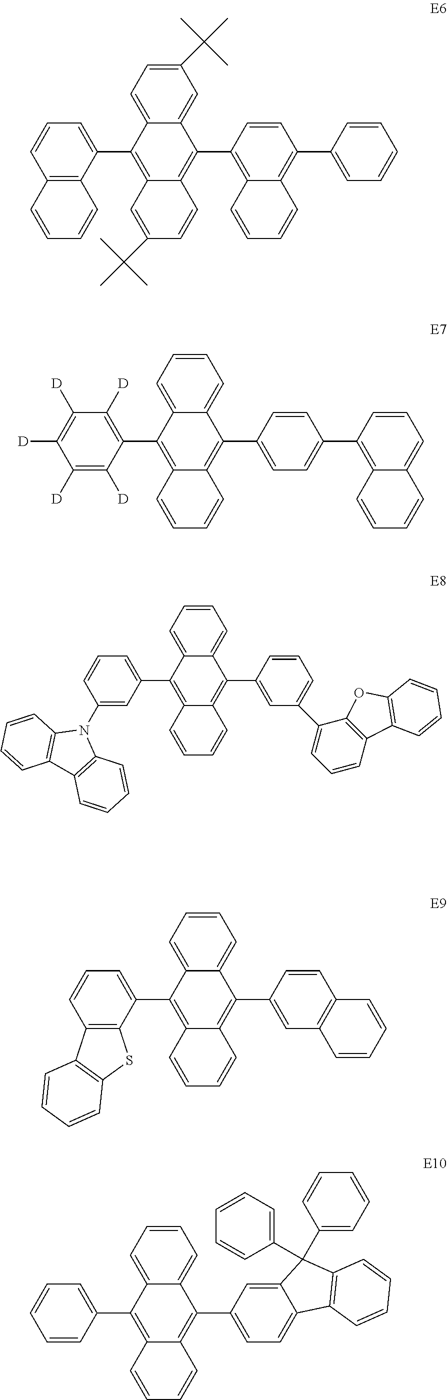

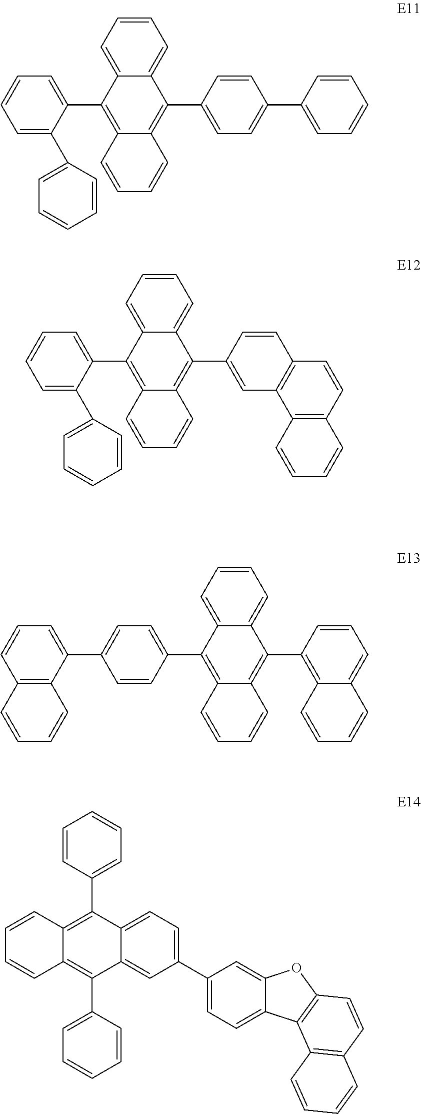

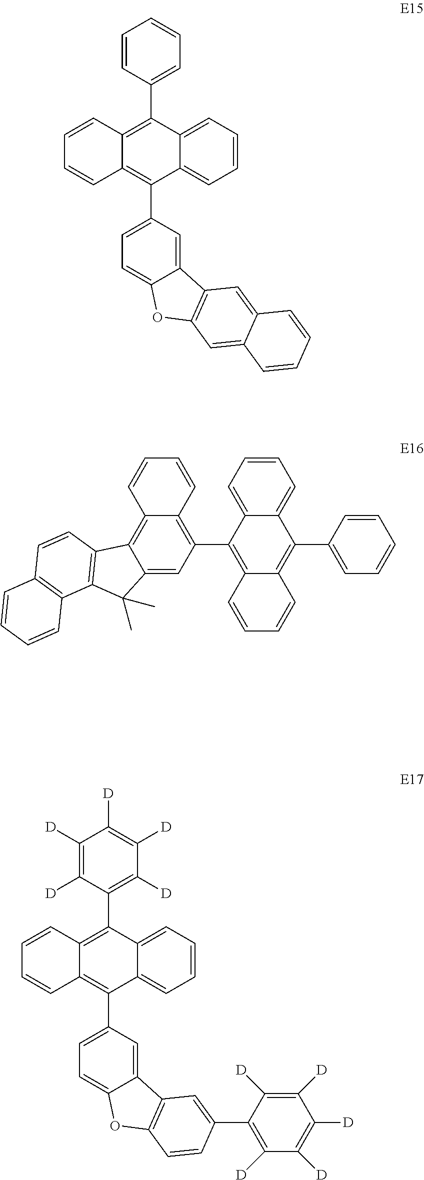

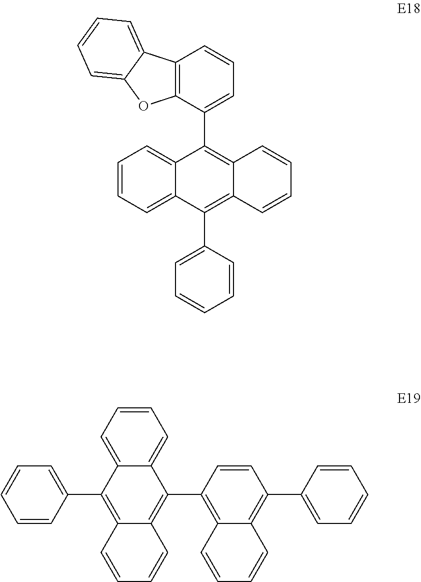

In one or more embodiments, the emission layer EML may include at least one among a first compound represented by any one among Formula F-a to Formula F-c, a second compound represented by Formula HT-1, a third compound represented by Formula ET-1, and a fourth compound represented by Formula D-1.

In one or more embodiments, the second compound may be utilized as a hole transport host material of the emission layer EML.

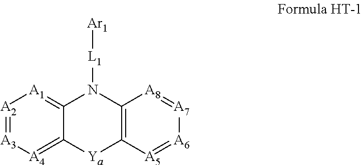

In Formula HT-1, A₁ to A₈ may each independently be N or CR₅₁. For example, A₁ to A₈ may be all CR₅₁. In some embodiments, any one among A₁ to A₈ may be N, and the remainder may be CR₅₁

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but one or more embodiments of the present disclosure is not limited thereto.

In Formula HT-1, Yₐ may be a direct linkage, CR₅₂R₅₃, or SiR₅₄R₅₅. For example, two benzene rings connected with the nitrogen atom of Formula HT-1 may be connected via a direct linkage,

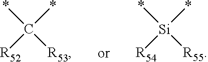

In Formula HT-1, when Yₐ is a direct linkage, the second compound represented by Formula HT-1 may include a carbazole moiety.

In Formula HT-1, Ar₁ may be a substituted or unsubstituted aryl group of 6 to 30 ring-forming carbon atoms, or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, or a substituted or unsubstituted biphenyl group, but one or more embodiments of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 ring-forming carbon atoms, a substituted or unsubstituted aryl group of 6 to 60 ring-forming carbon atoms, or a substituted or unsubstituted heteroaryl group of 2 to 60 ring-forming carbon atoms. In some embodiments, each of R₅₁ to R₅₅ may be combined with an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by at least one selected from among the compounds represented in Compound Group 2. The emission layer EML may include at least one selected from among the compounds represented in Compound Group 2 as a hole transport host material.

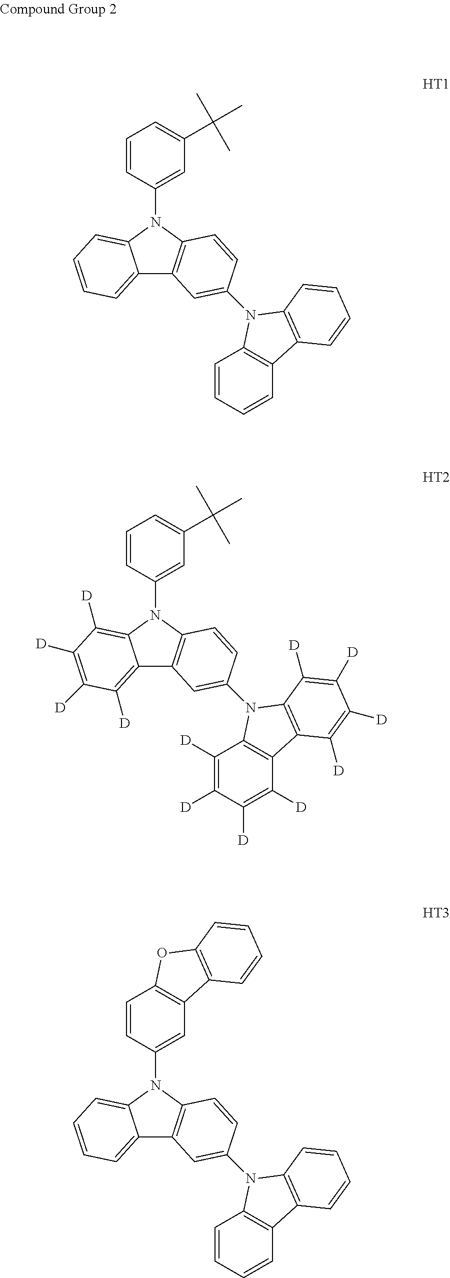 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

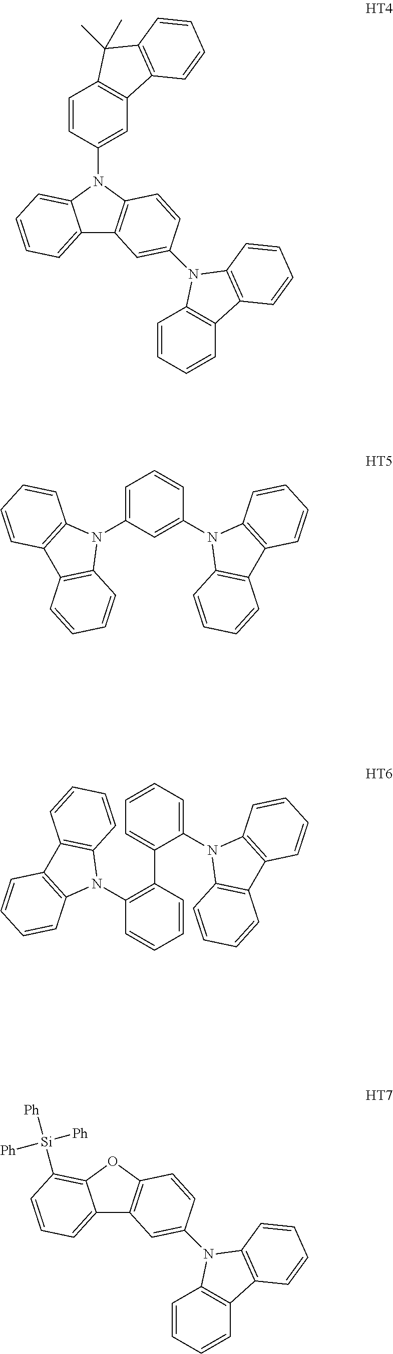 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

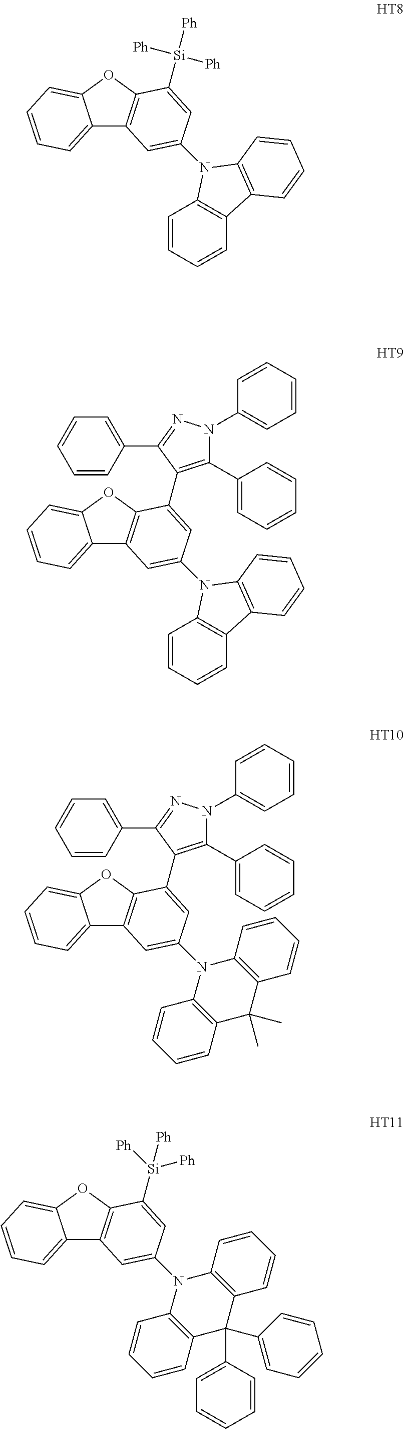 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

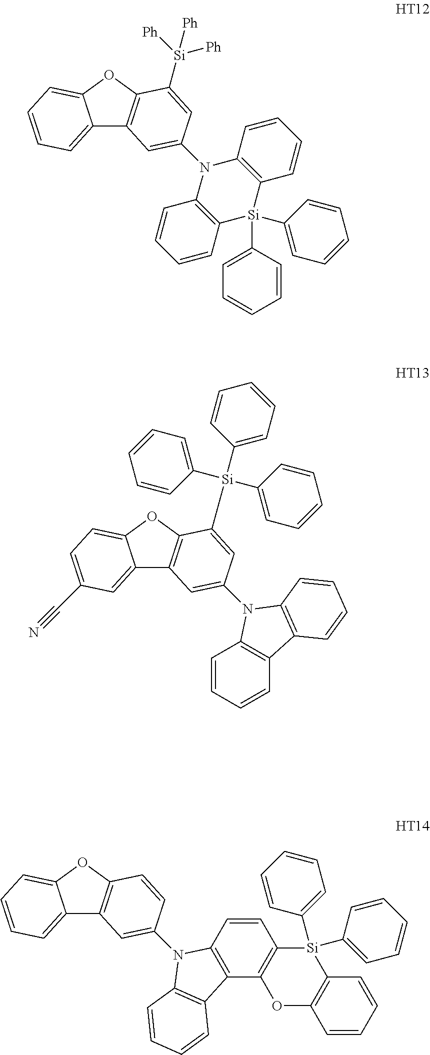 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

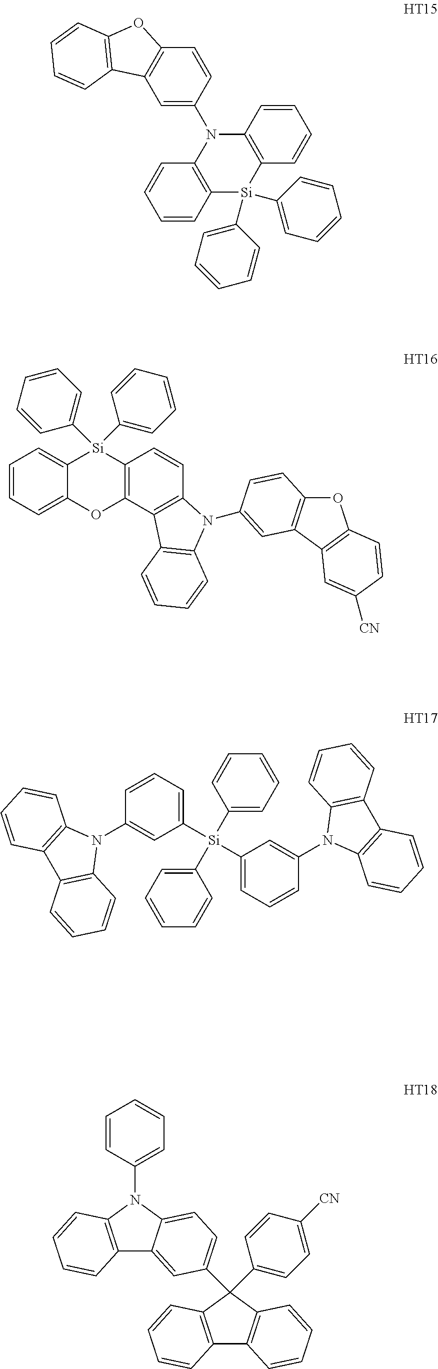 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

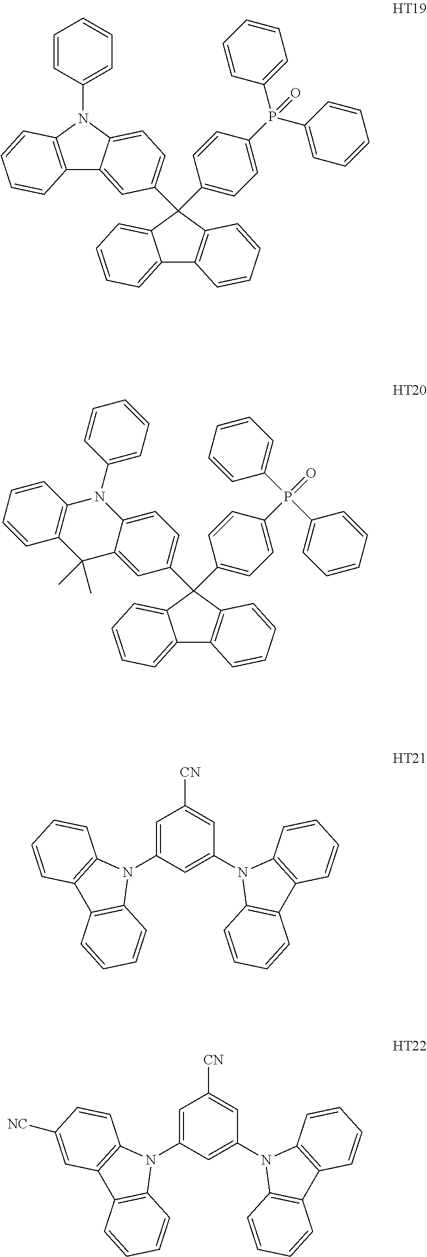 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

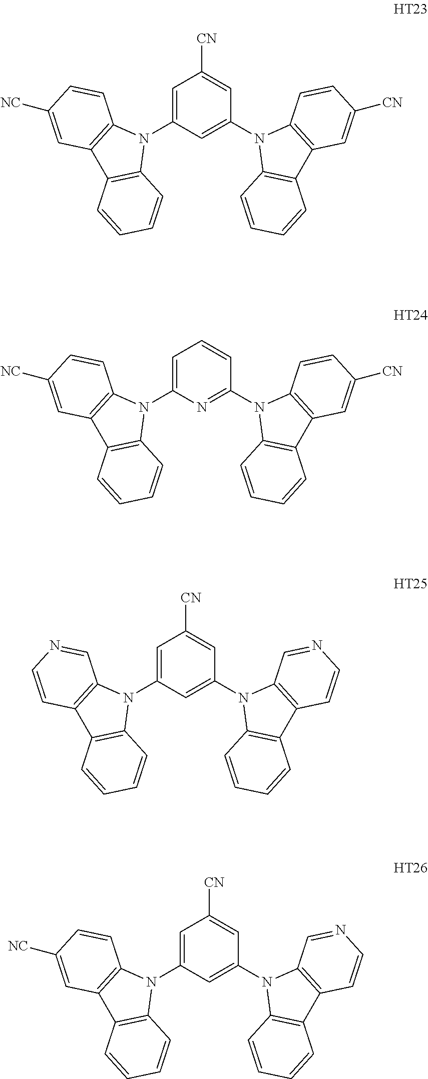 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

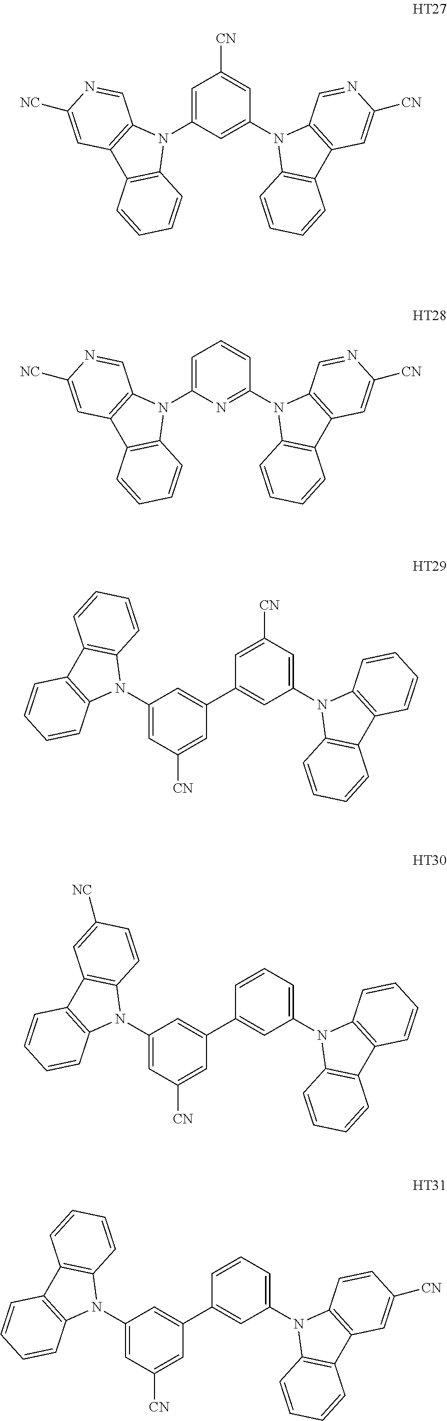 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

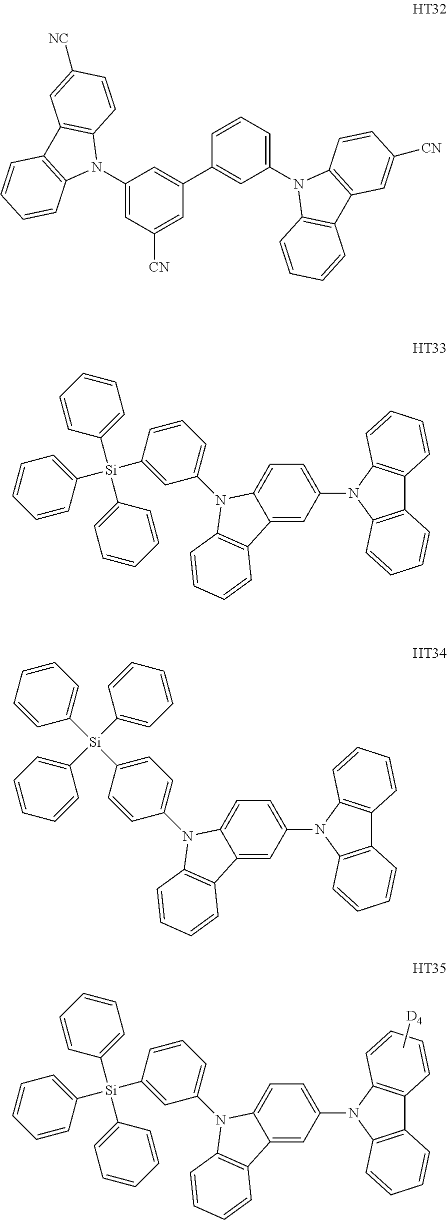

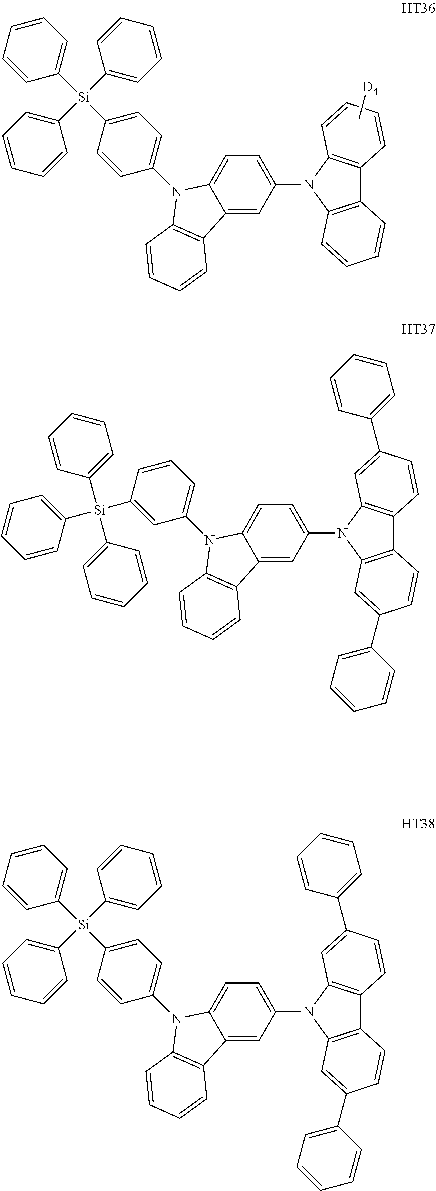

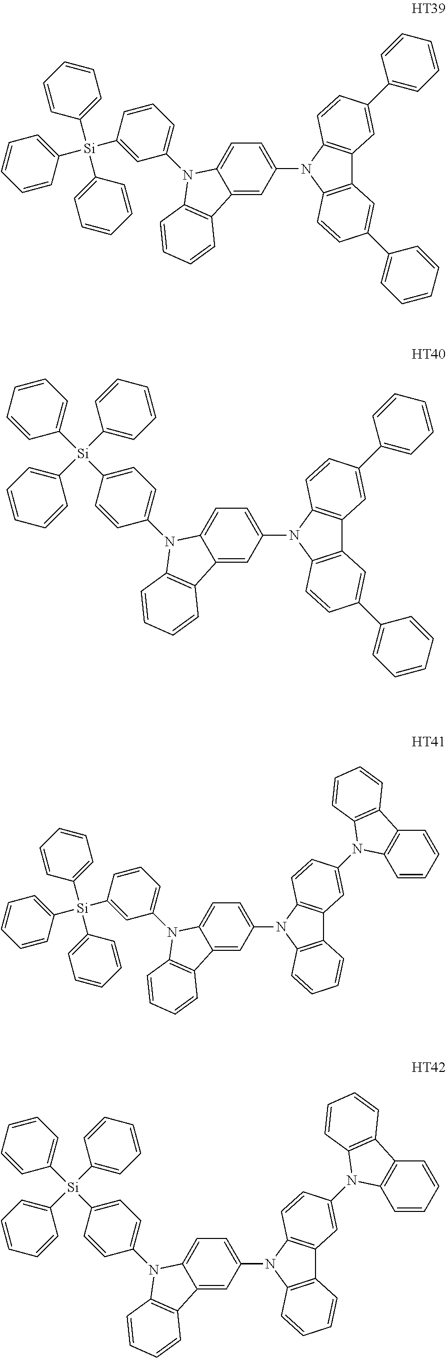 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

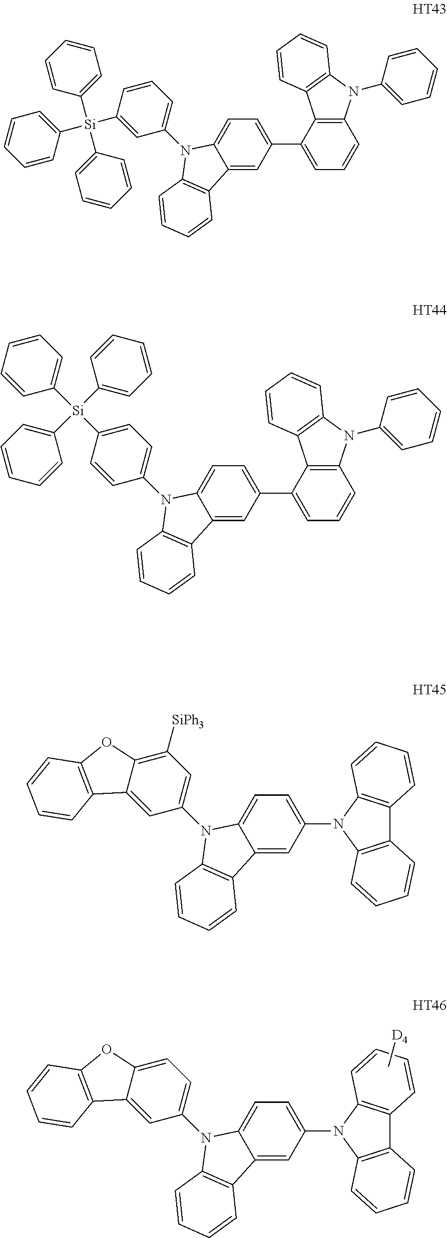

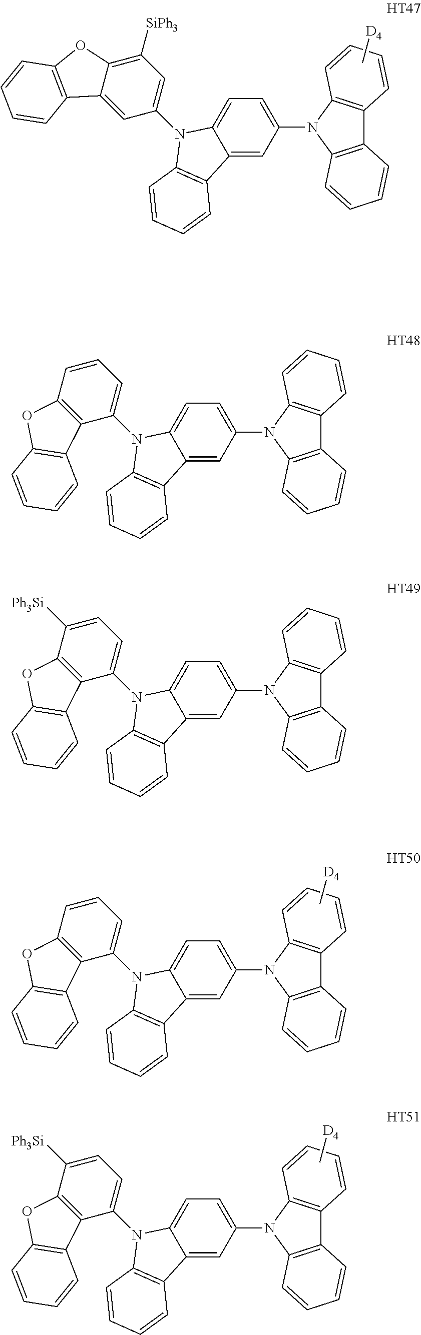

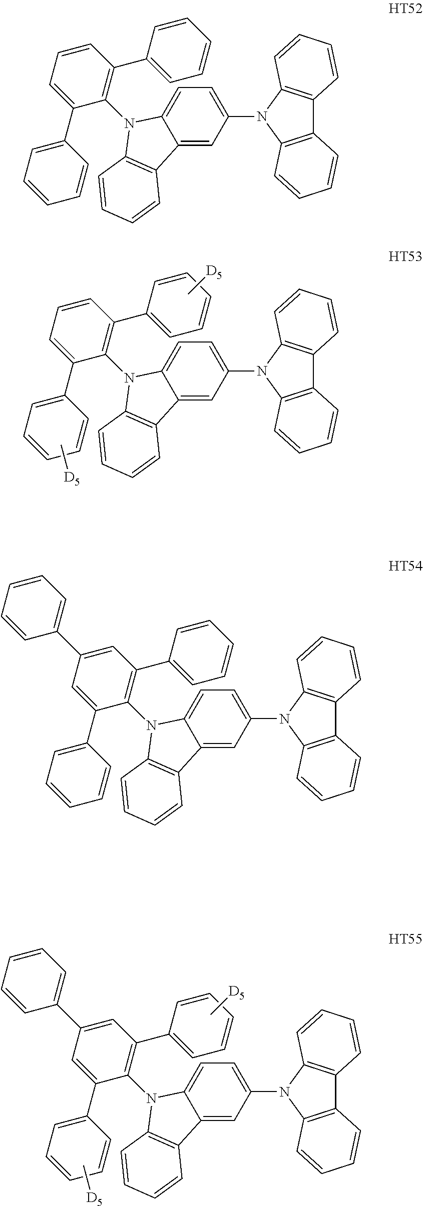

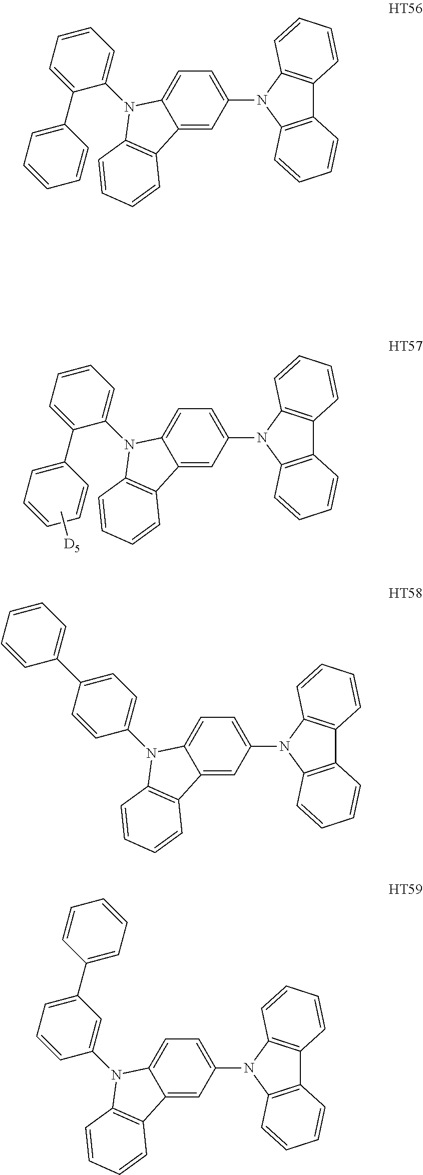

In the particular compounds suggested in Compound Group 2, “D” refers to a deuterium atom, and “Ph” refers to a substituted or unsubstituted phenyl group. For example, in the compounds suggested in Compound Group 2, “Ph” may be an unsubstituted phenyl group.

In one or more embodiments, the emission layer EML may include a third compound represented by Formula ET-1. For example, the third compound may be utilized as the electron transport host material of the emission layer EML.

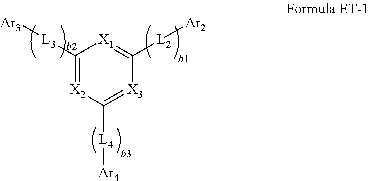

In Formula ET-1, at least one among X₁ to X₃ may be N, and the remainder of X₁ to X₃ may be CR₅₆. For example, any one among X₁ to X₃ may be N, and the remaining two of X₁ to X₃ may each independently be CR₅₆. In this case, the third compound represented by Formula ET-1 may include a pyridine moiety. In some embodiments, two among X₁ to X₃ may be N, and the remaining one of X₁ to X₃ may be CR₅₆. In this case, the third compound represented by Formula ET-1 may include a pyrimidine moiety. In some embodiments, X₁ to X₃ may each be (e.g., all) N. In this case, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when b1 to b3 are integers of 2 or more, L₂ to L₄ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be represented by at least one selected from among the compounds in Compound Group 3. The light emitting element ED of one or more embodiments may include at least one selected from among the compounds in Compound Group 3.

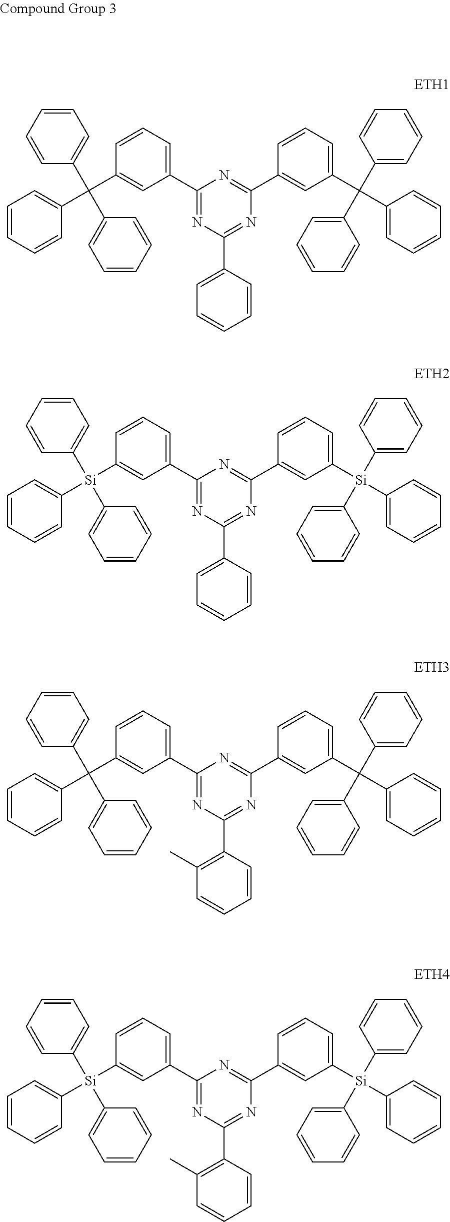 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

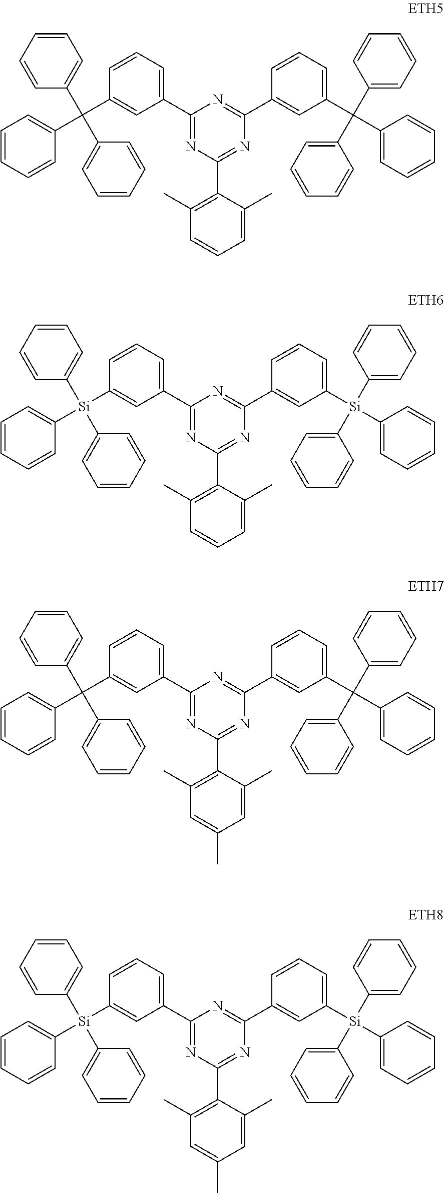 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

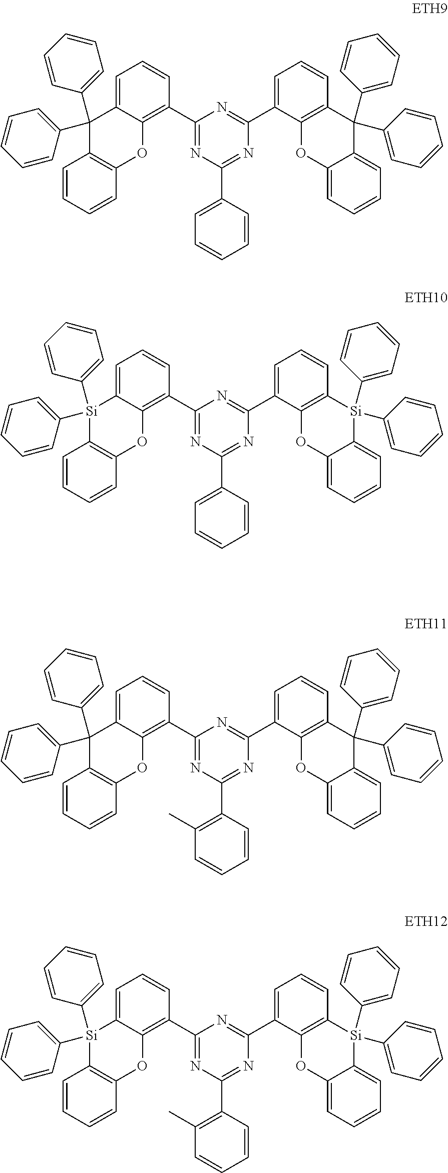 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

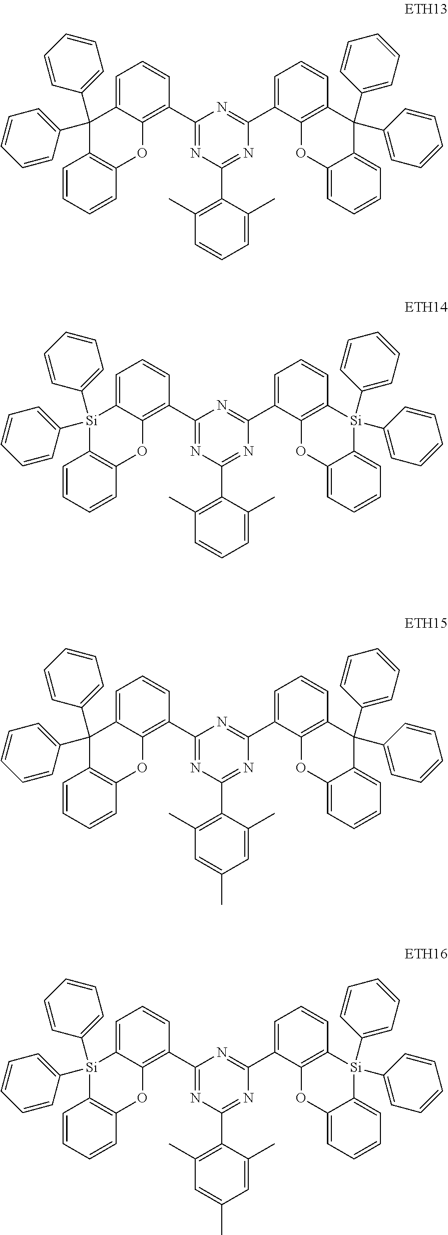 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

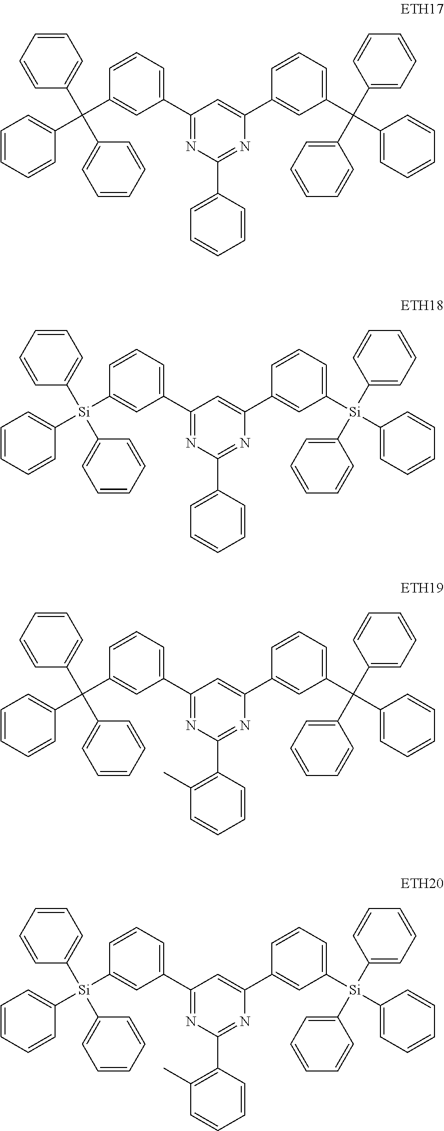 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

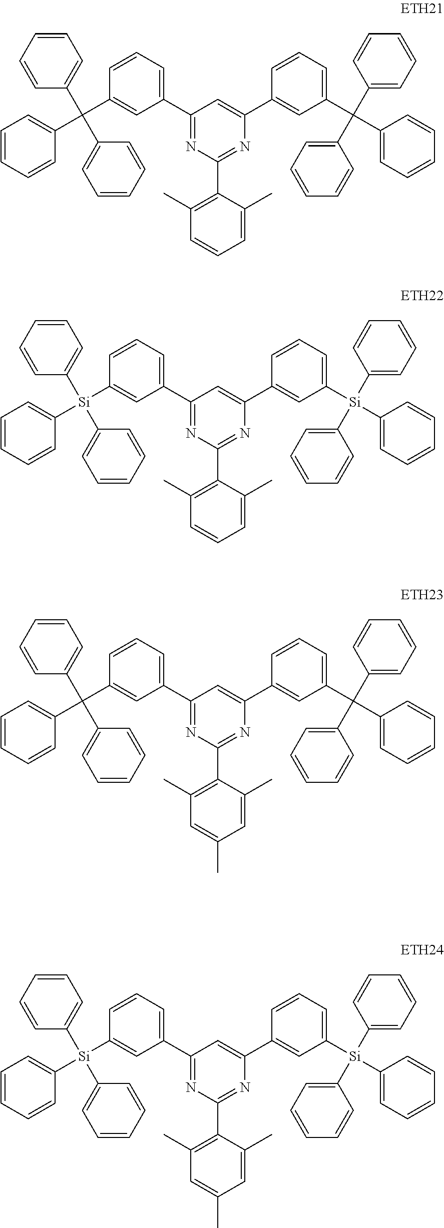 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

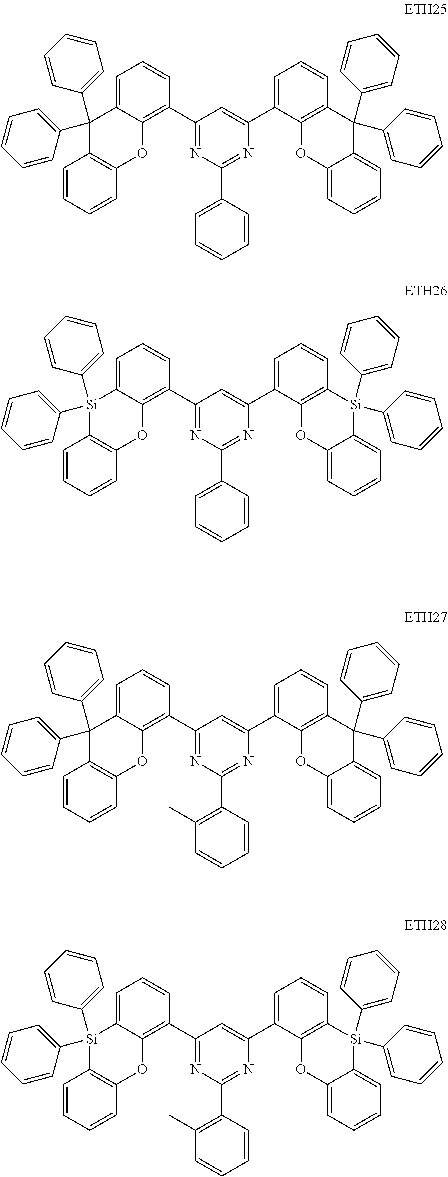 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

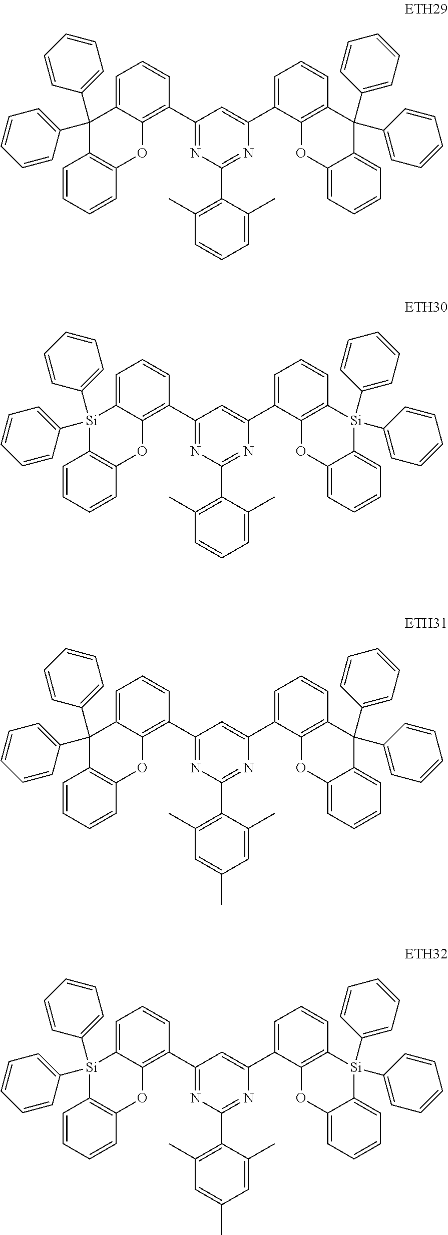 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

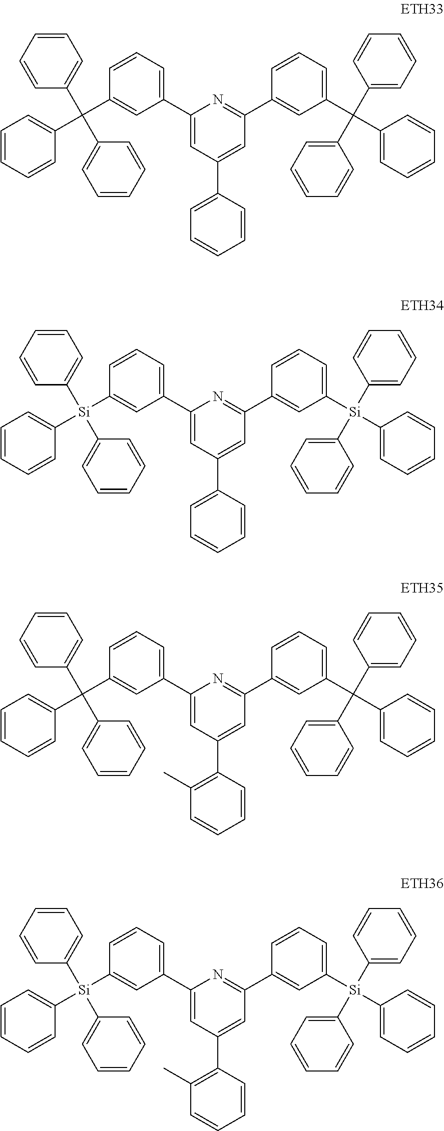 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

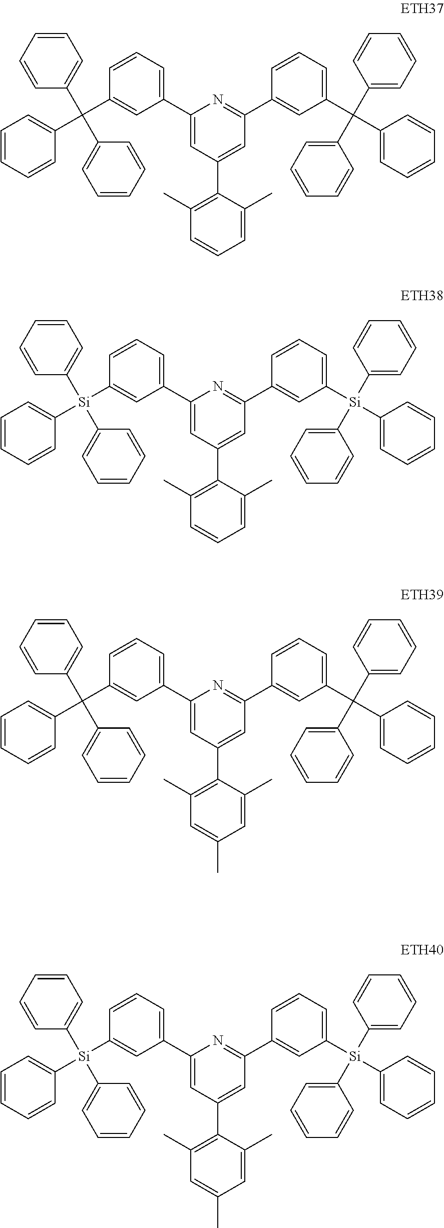 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

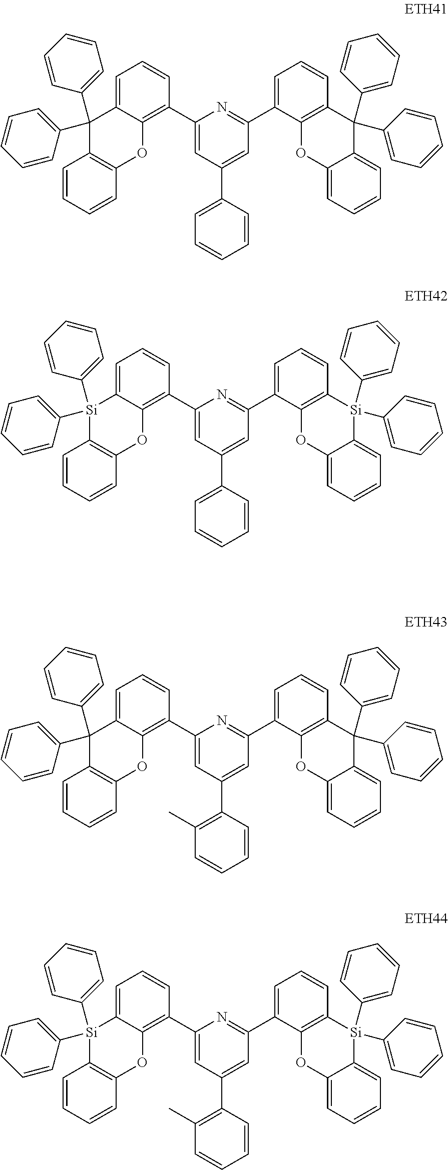 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

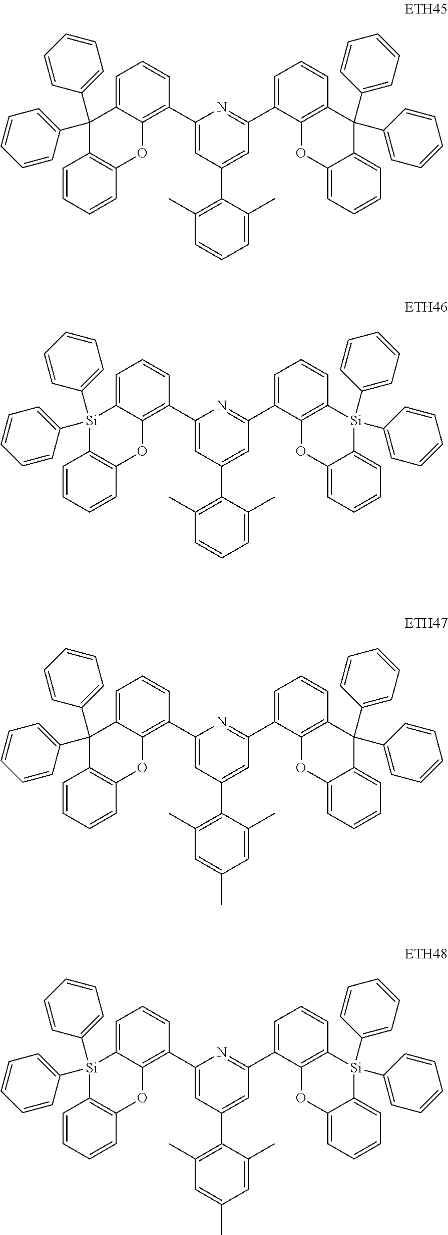 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

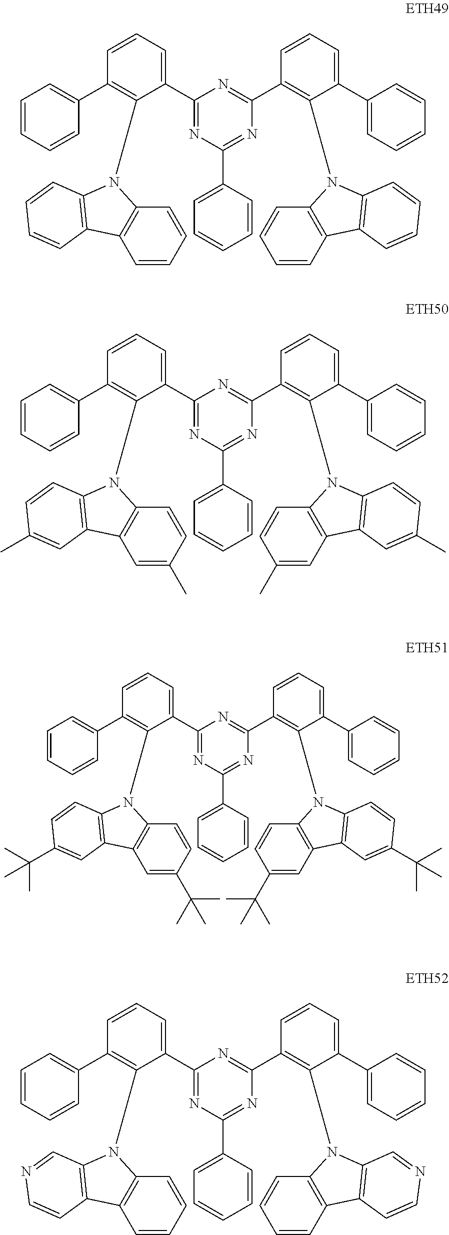

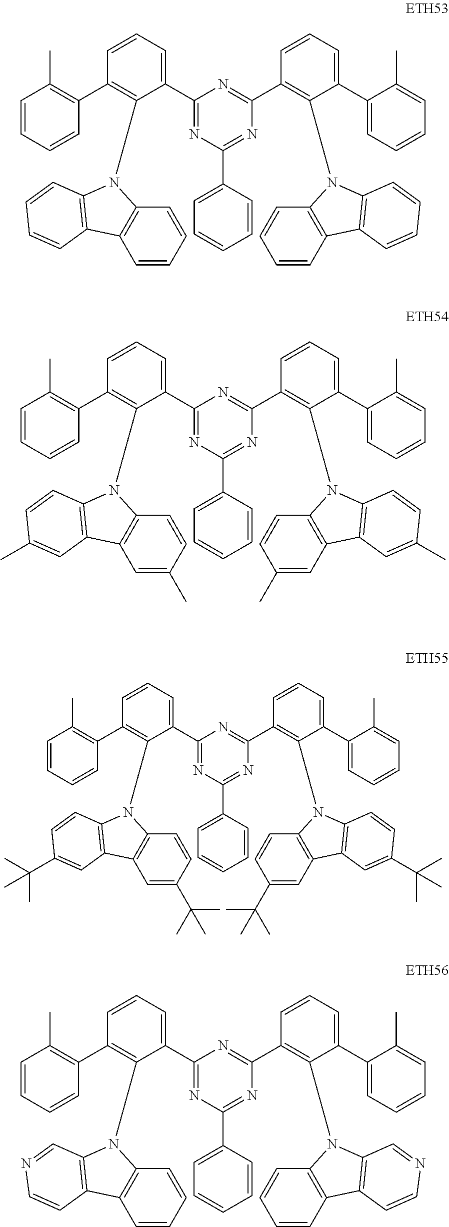

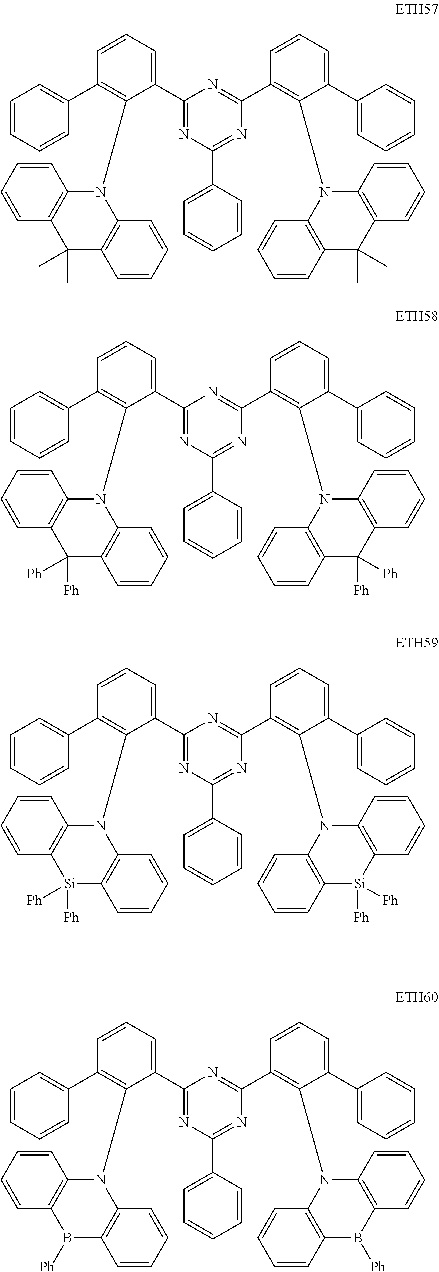

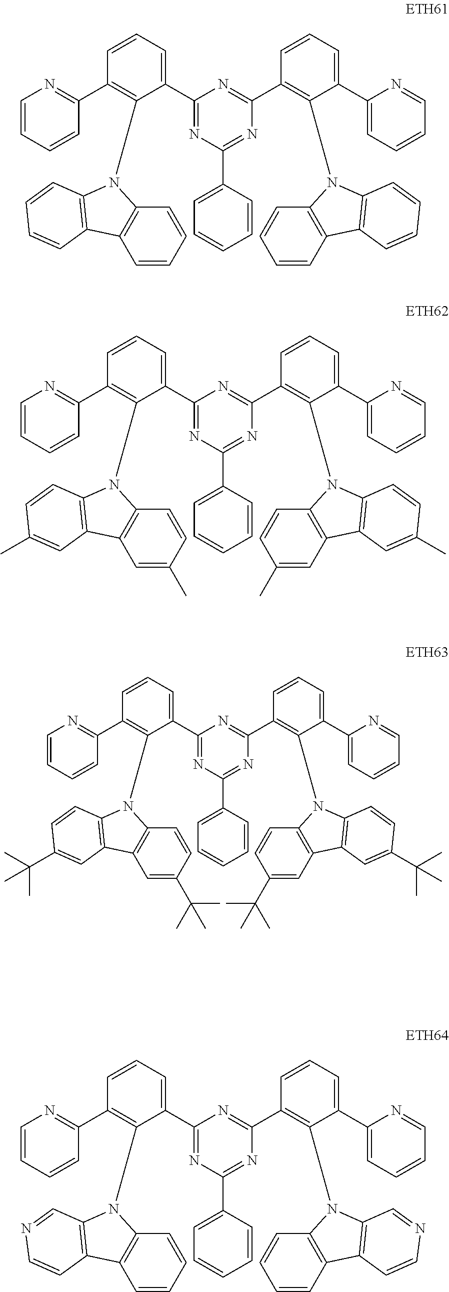

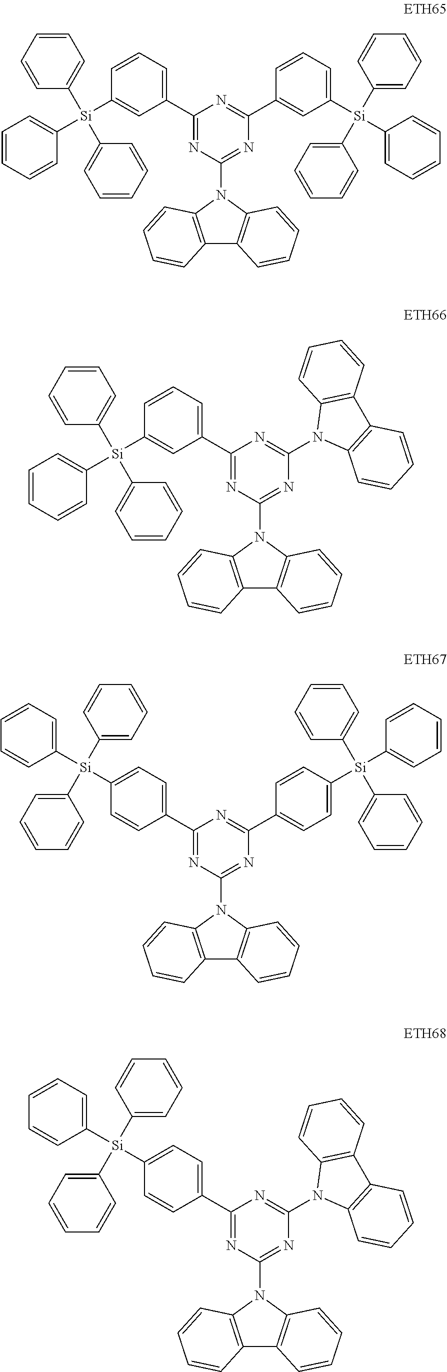 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

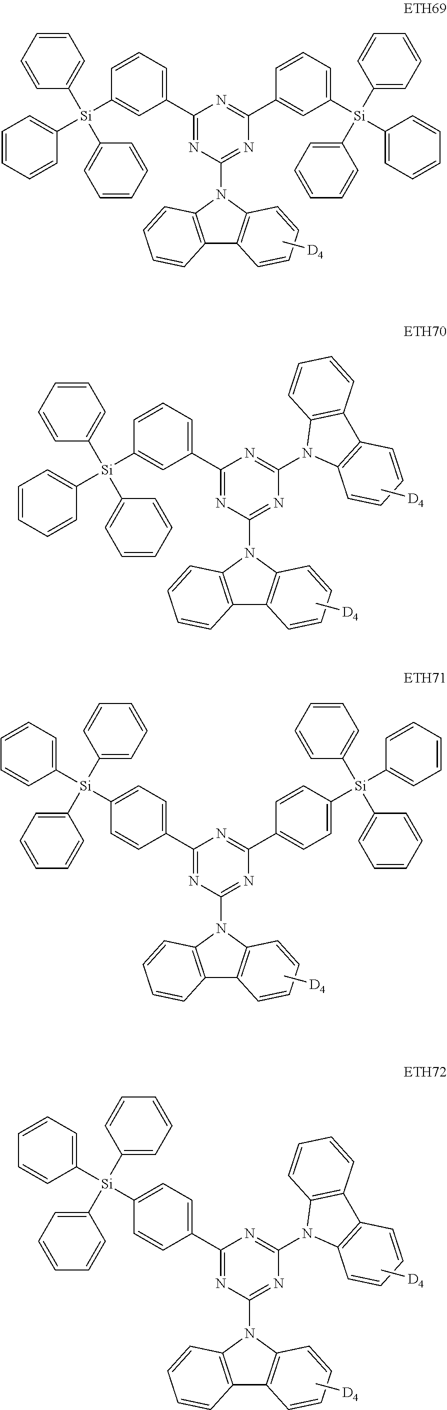

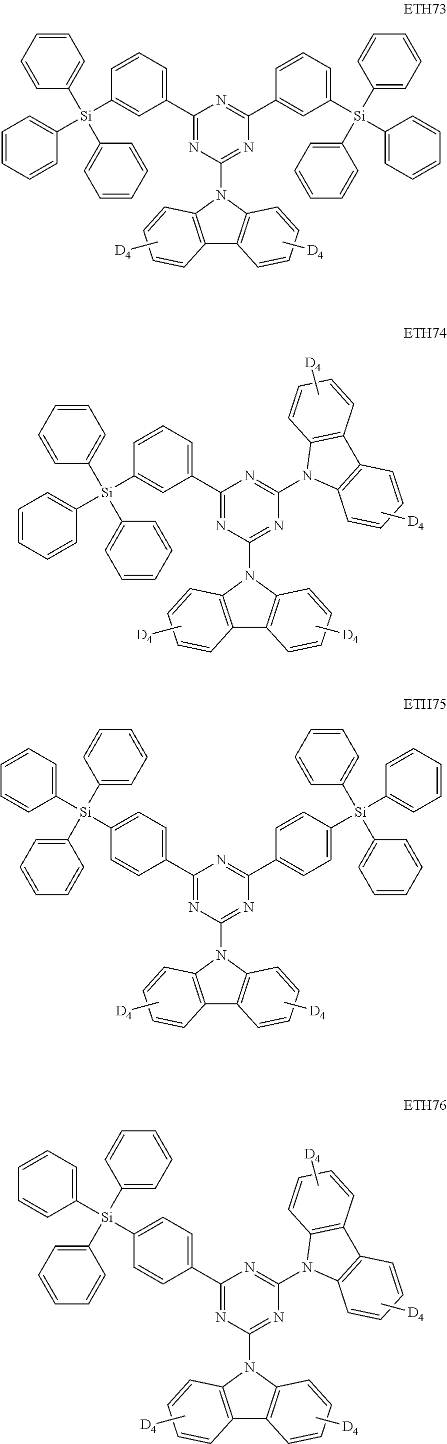

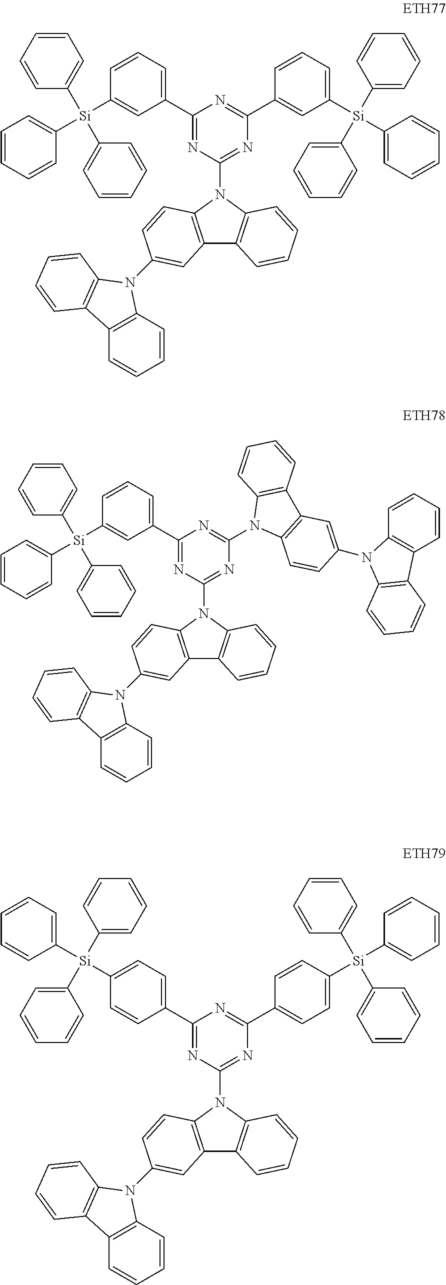 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

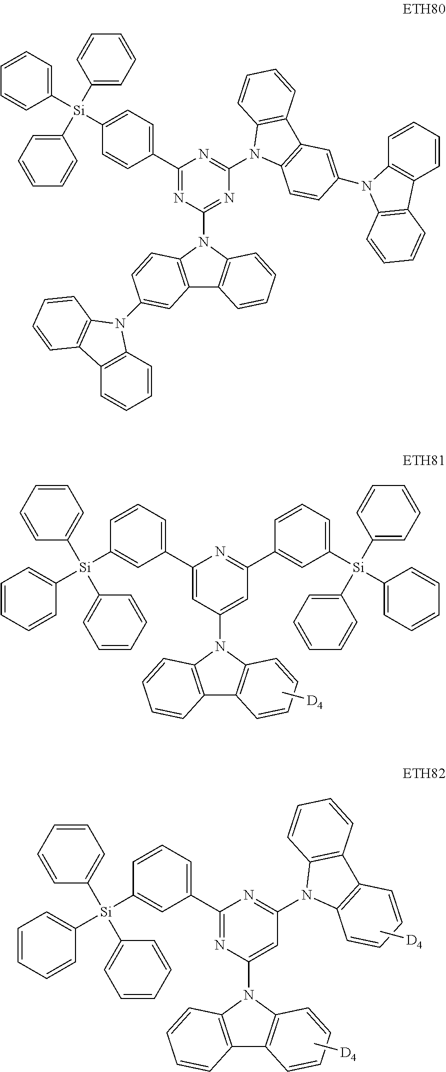

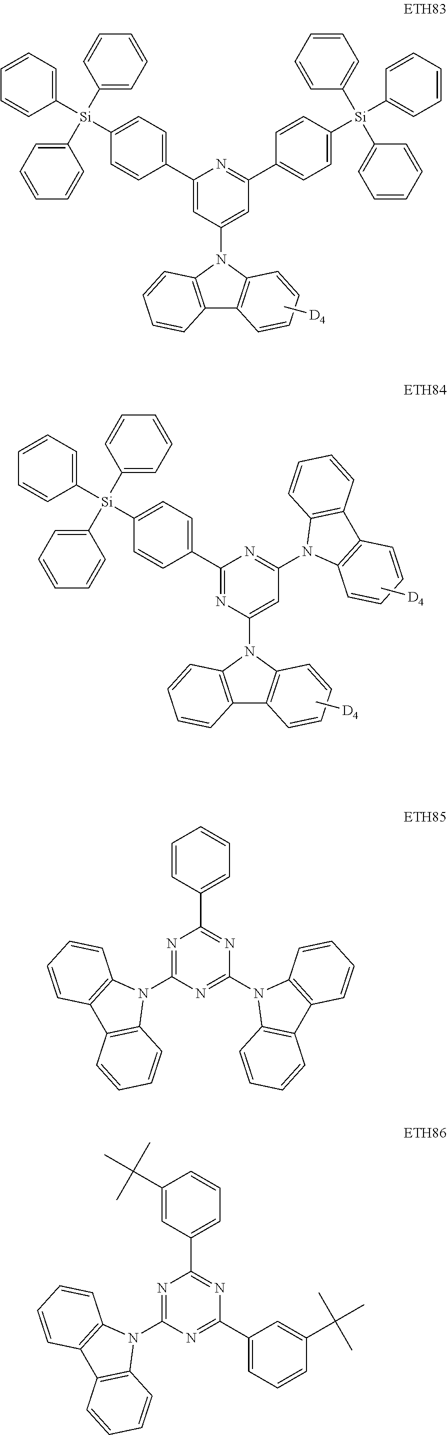

In the compounds suggested in Compound Group 3, “D” refers to a deuterium atom, and “Ph” refers to an unsubstituted phenyl group.

The emission layer EML includes the second compound and the third compound, and the second compound and the third compound may form an exciplex. In the emission layer EML, the exciplex may be formed by a hole transport host and an electron transport host. In this case, the triplet energy of the exciplex formed by the hole transport host and the electron transport host may correspond to an energy level difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 electron volt (eV) to about 3.0 eV. In some embodiments, the triplet energy of the exciplex may be smaller than the energy gap of each host material. The exciplex may have a triplet energy of about 3.0 eV or less, which may be the energy gap between the hole transport host and the electron transport host.

In one or more embodiments, the emission layer EML may include the fourth compound in addition to the first compound to the third compound. The fourth compound may be utilized as a phosphorescence sensitizer of the emission layer EML. Energy transfer from the fourth compound to the first compound may occur to emit light.

For example, the emission layer EML may include an organometallic complex including platinum (Pt) as a central metal atom and ligands bonded to the central metal atom, as the fourth compound. In the light emitting element ED of one or more embodiments, the emission layer EML may include a compound represented by Formula D-1 as the fourth compound.

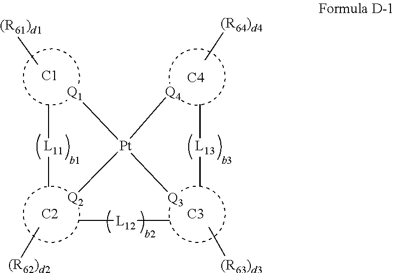

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1. L₁₁ to L₁₃ may each independently be a direct linkage, *—O—*, *—S—*,

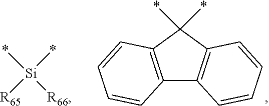

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “—*” refers to a part connected with C1 to C4.

In Formula D-1, b1 to b3 may each independently be 0 or 1. When b1 is 0, C1 and C2 may not be connected to each other. When b2 is 0, C2 and C3 may not be connected to each other. When b3 is 0, C3 and C4 may not be connected to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 ring-forming carbon atoms, a substituted or unsubstituted aryl group of 6 to 60 ring-forming carbon atoms, or a substituted or unsubstituted heteroaryl group of 2 to 60 ring-forming carbon atoms. In some embodiments, each of R₆₁ to R₆₆ may be connected with an adjacent group to form a ring. R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, when d1 to d4 are 0, the fourth compound may be unsubstituted with R₆₁ to R₆₄, respectively. Cases where d1 to d4 are 4, and R₆₁ to R₆₄ are hydrogen atoms, may be the same as cases where d1 to d4 are 0, respectively. When d1 to d4 are integers of 2 or more, each of multiple R₆₁ to R₆₄ may the same, or at least one among each of multiple R₆₁ to R₆₄ may be different.

In Formula D-1, C1 to C4 may each independently be a substituted or unsubstituted hydrocarbon ring, or a substituted or unsubstituted heterocycle, represented by any one among C-1 to C-4.

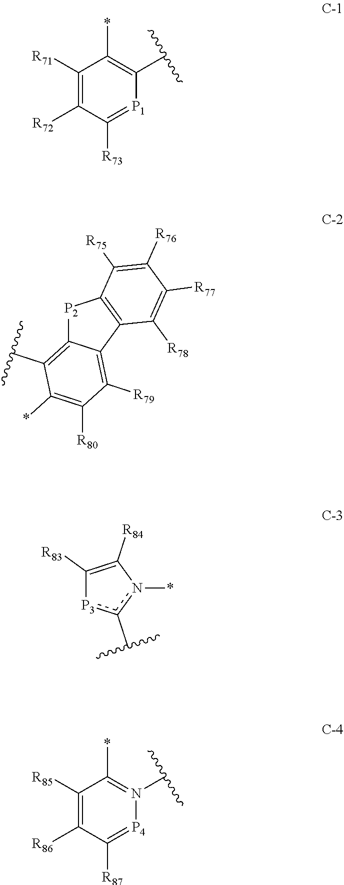

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In C-1 to C-4,

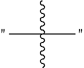

is a part connected with a Pt central metal atom, and “—*” corresponds to a part connected with an adjacent ring group (C1 to C4) or a linker (L₁₁ to L₁₃).

The emission layer EML of one or more embodiments may include the first compound which is a fused polycyclic compound, and at least one among the second compound to the fourth compound. For example, the emission layer EML may include the first compound, the second compound and the third compound. In the emission layer EML, the second compound and the third compound may form an exciplex, and energy transfer from the exciplex to the first compound may occur to emit light.

In some embodiments, the emission layer EML may include the first compound, the second compound, the third compound and the fourth compound. In the emission layer EML, the second compound and the third compound may form an exciplex, and energy transfer from the exciplex to the fourth compound and the first compound may occur to emit light. In one or more embodiments, the fourth compound may be a sensitizer. In the light emitting element ED of one or more embodiments, the fourth compound included in the emission layer EML may function as a sensitizer and may play the role of transferring energy from the host to the first compound which is a light emitting dopant. For example, the fourth compound which plays the role of an auxiliary dopant may accelerate energy transfer to the first compound which is the light emitting dopant and may increase the emission ratio of the first compound. Accordingly, the emission layer EML of one or more embodiments may improve emission efficiency. In some embodiments, when the energy transfer to the first compound increases, excitons formed in the emission layer EML may not be accumulated in the emission layer EML but may rapidly emit light, and the deterioration of an element may be reduced. Accordingly, the lifetime of the light emitting element ED of one or more embodiments may increase.

The light emitting element ED of one or more embodiments may include (e.g., all of) the first compound, the second compound, the third compound and the fourth compound, and the emission layer EML may include the combination of two host materials and two dopant materials. In the light emitting element ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by at least one selected from among the compounds represented in Compound Group 4. The emission layer EML may include at least one selected from among the compounds represented in Compound Group 4 as a sensitizer material.

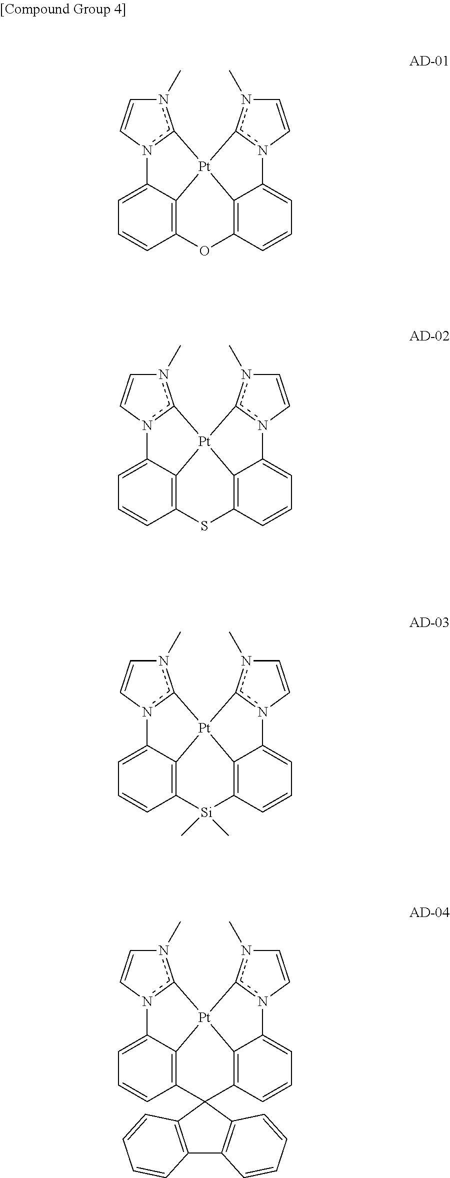

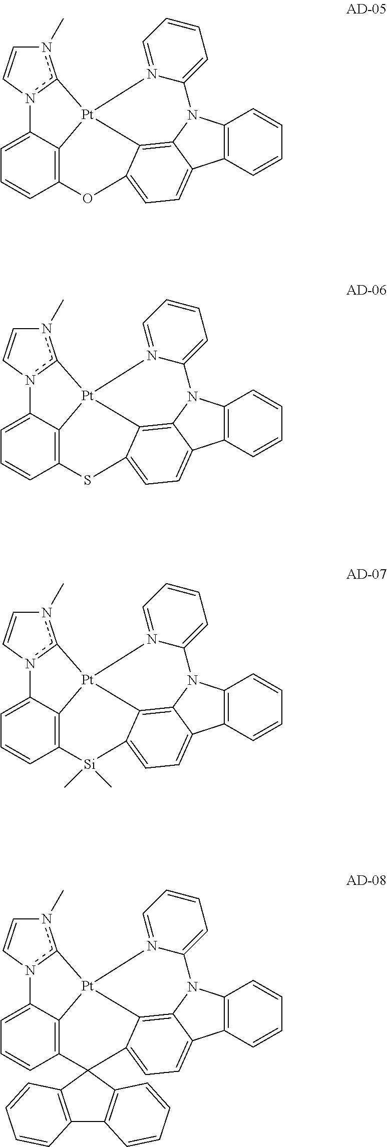

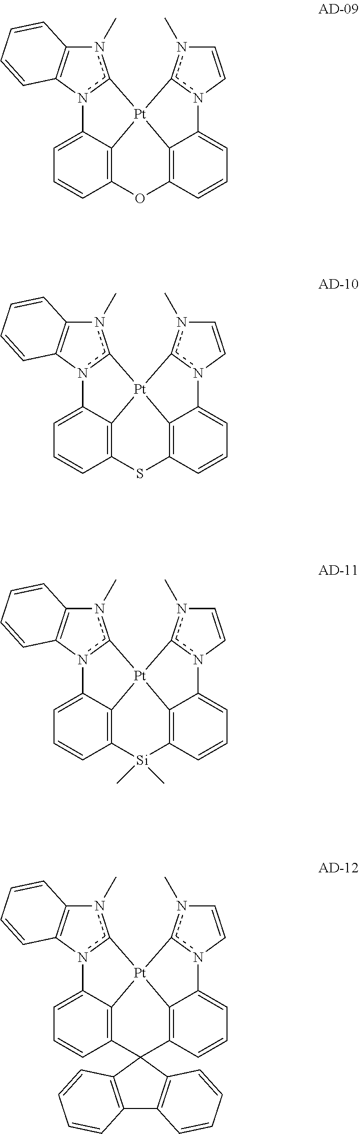

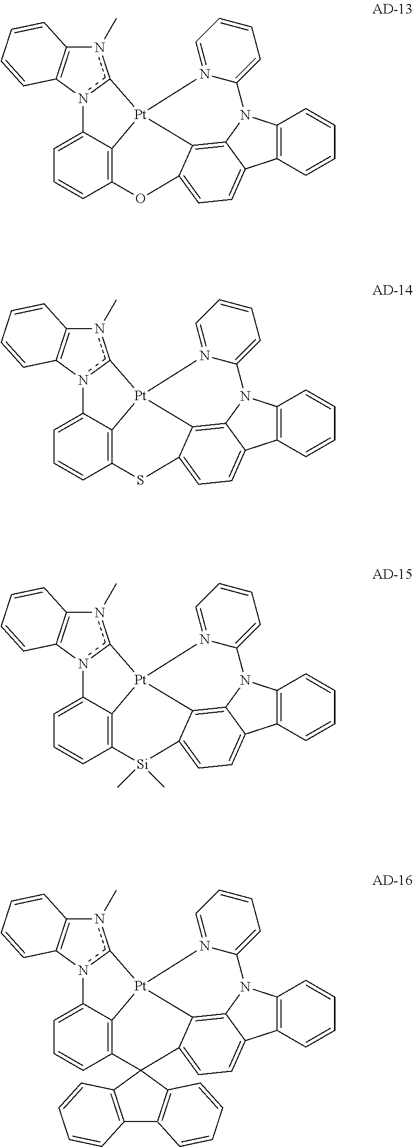

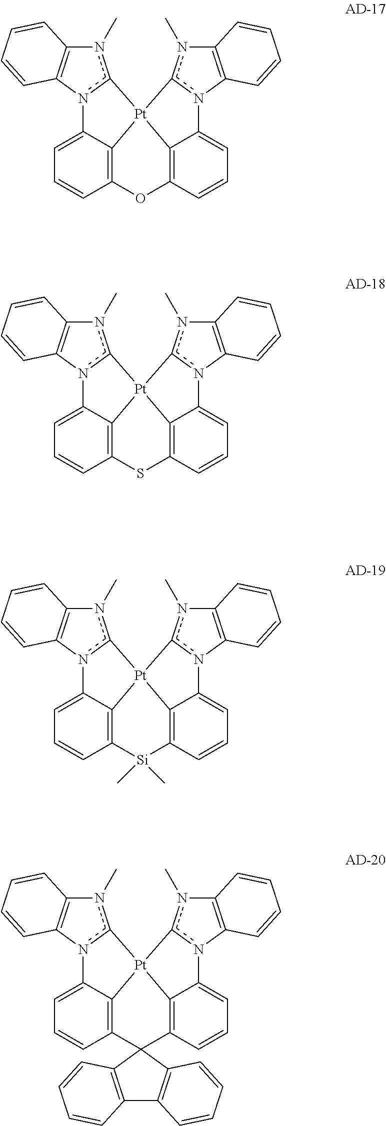

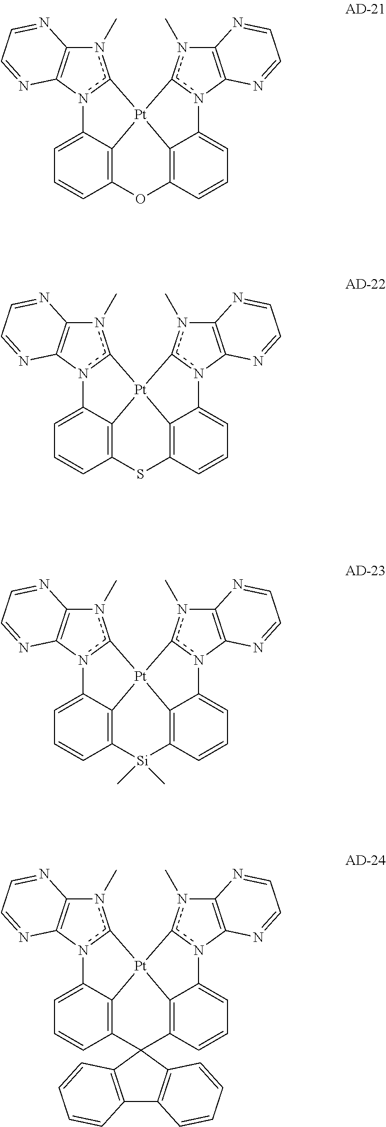

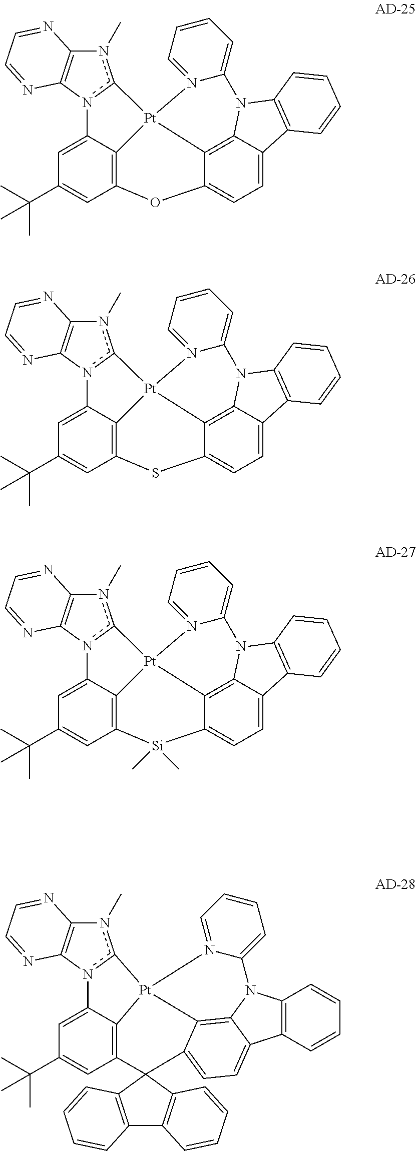

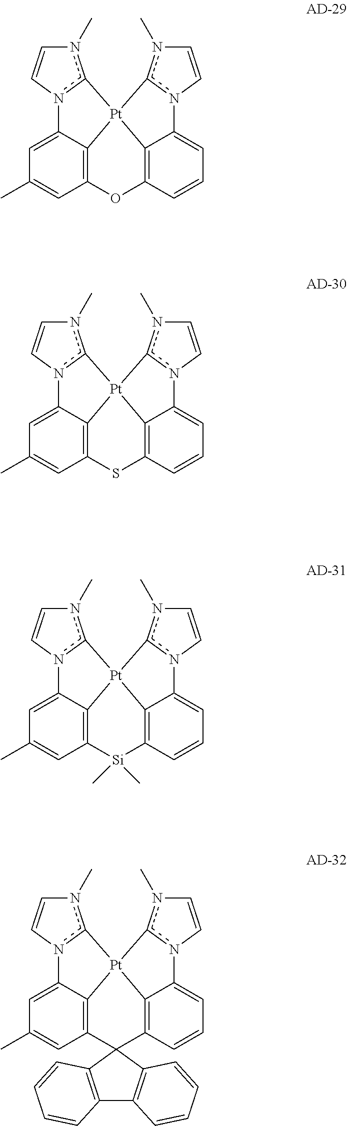

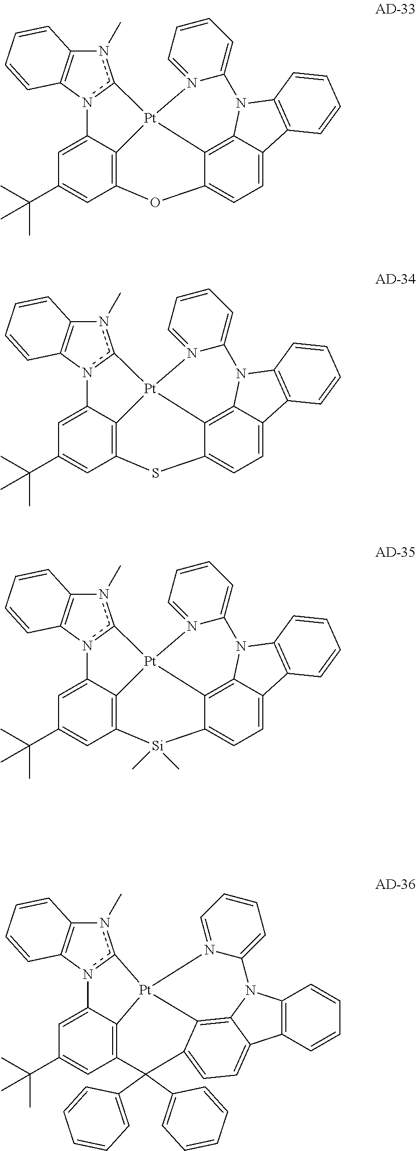

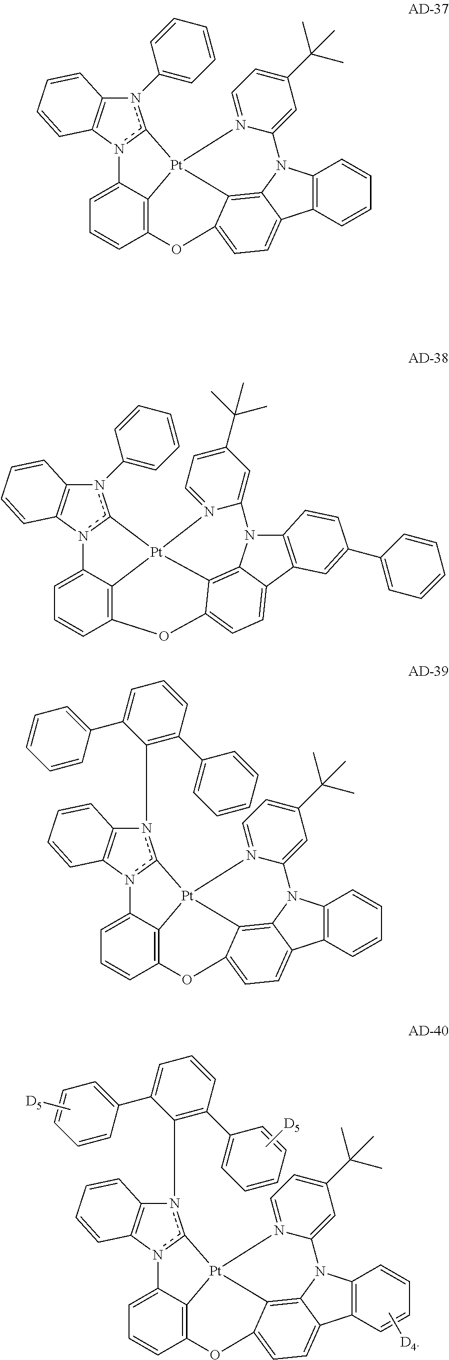

In the compounds suggested in Compound Group 4, “D” refers to a deuterium atom.

In the light emitting element ED of one or more embodiments, when the emission layer EML includes (e.g., all of) the first compound, the second compound and the third compound, the content (e.g., amount) of the first compound may be about 0.1 wt % to about 5 wt % on the basis of the total weight of the first compound, the second compound and the third compound. However, one or more embodiments of the present disclosure is not limited thereto. When the content (e.g., amount) of the first compound satisfies the herein-described ratio, energy transfer from the second compound and the third compound to the first compound may increase, and so, emission efficiency and element lifetime may increase.

In the emission layer EML, the content (e.g., amount) of the second compound and the third compound may be the remainder excluding the weight of the first compound. For example, in the emission layer EML, the content (e.g., amount) of the second compound and the third compound may be about 65 wt % to about 99 wt % on the basis of the total weight of the first compound, the second compound and the third compound.

In the total weight of the second compound and the third compound, the weight ratio of the second compound and the third compound may be about 3:7 to about 7:3.

When the second compound and the third compound satisfy the herein-described content (e.g., amount) ratio, charge balance properties in the emission layer EML may be improved, and emission efficiency and element lifetime may increase. When the content (e.g., amount) of the second compound and the third compound deviate from the herein-described ratio range, charge balance in the emission layer EML may be broken, emission efficiency may be deteriorated, and the element may be easily deteriorated.

When the emission layer EML includes the fourth compound, the content (e.g., amount) of the fourth compound may be about 10 wt % to about 30 wt % on the basis of the total weight of the first compound, the second compound, the third compound and the fourth compound in the emission layer EML. However, one or more embodiments of the present disclosure is not limited thereto. When the content (e.g., amount) of the fourth compound satisfies the herein-described content (e.g., amount), energy transfer from the host to the first compound which is a light emitting dopant may increase, and an emission ratio may increase. Accordingly, the emission efficiency of the emission layer EML may be improved. When the first compound, the second compound, the third compound and the fourth compound included in the emission layer EML satisfy the herein-described content (e.g., amount) ratio, excellent or suitable emission efficiency and long lifetime may be accomplished.

In one or more embodiments, the emission layer EML may include a compound represented by Formula E-2a or Formula E-2b. The compound represented by Formula E-2a or Formula E-2b may be utilized as a phosphorescence host material.

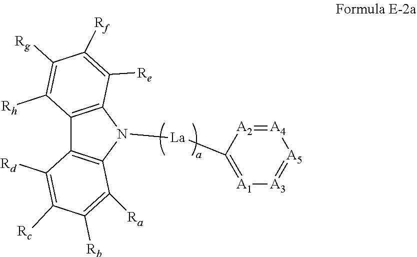

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple Lₐ may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₈ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Each of Rₐ to Rᵢ may be combined with an adjacent group to form a hydrocarbon ring or a heterocycle including N, O, S, and/or the like as a ring-forming atom.

In some embodiments, in Formula E-2a, two or three selected from A₁ to A₅ may be N, and the remainder of A₁ to A₈ may be CRi.

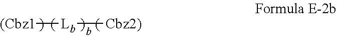

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by at least one selected from among the compounds in Compound Group E-2. However, the compounds listed in Compound Group E-2 are only illustrations, and the compound represented by Formula E-2a or Formula E-2b is not limited to the compounds represented in Compound Group E-2.

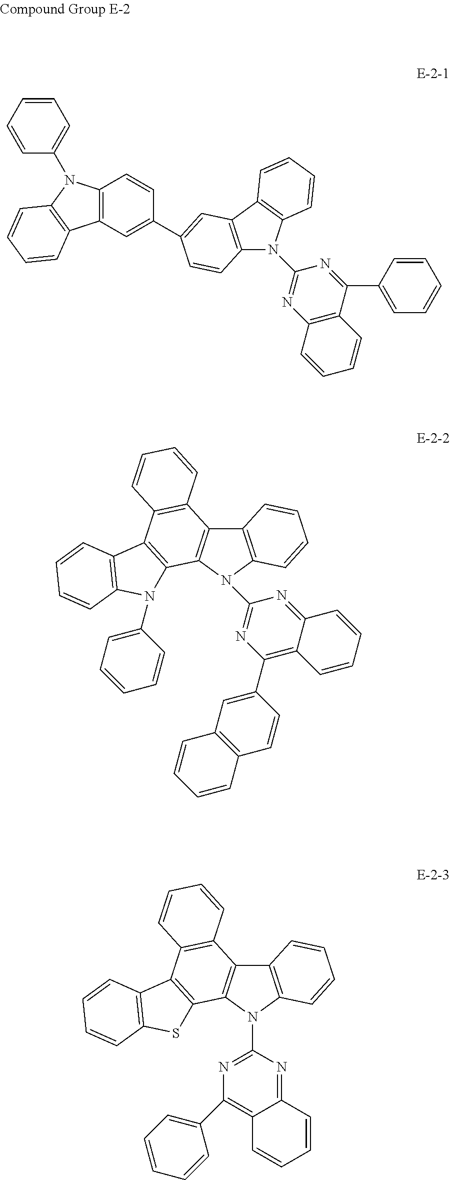 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

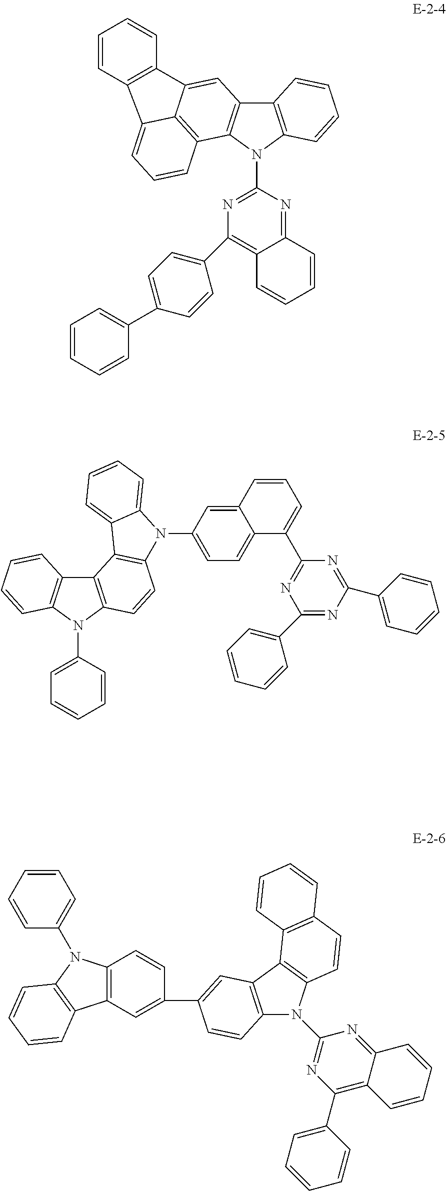 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

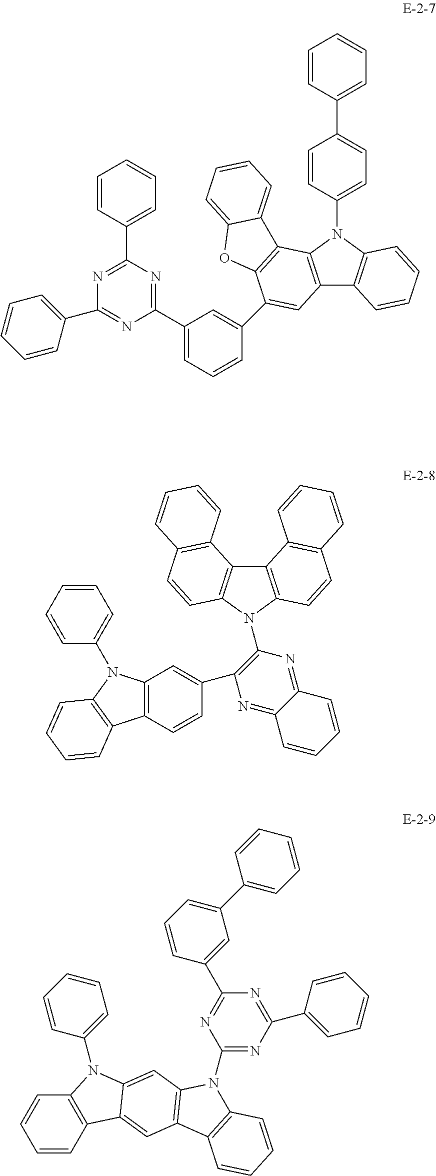 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

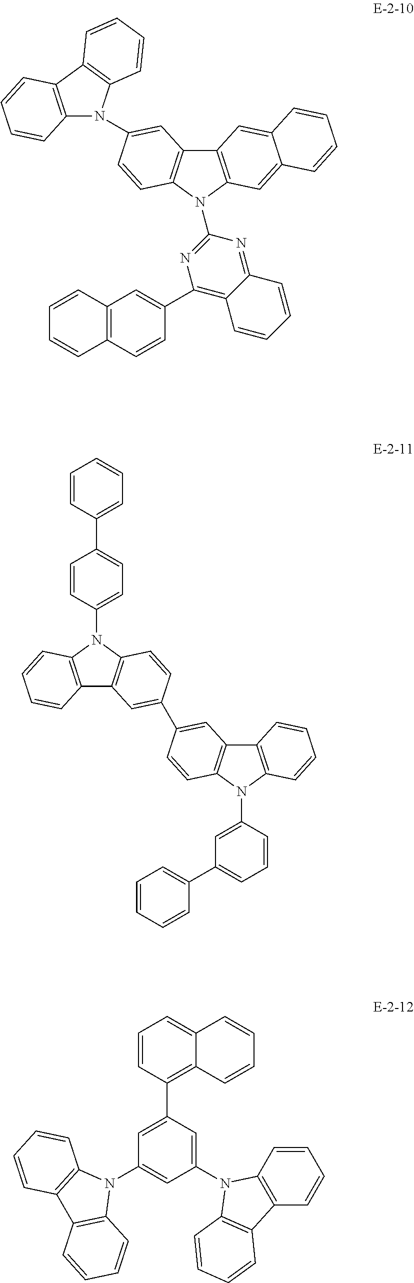 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

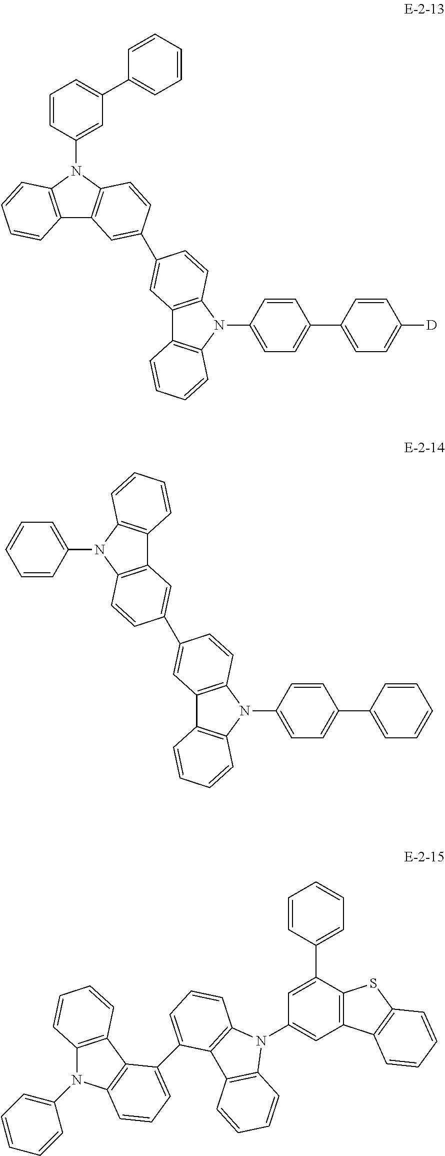 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

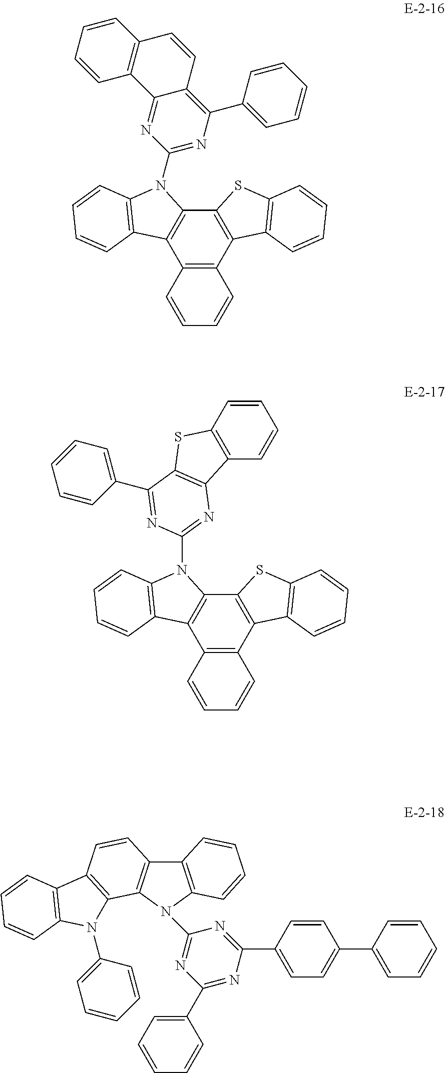 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

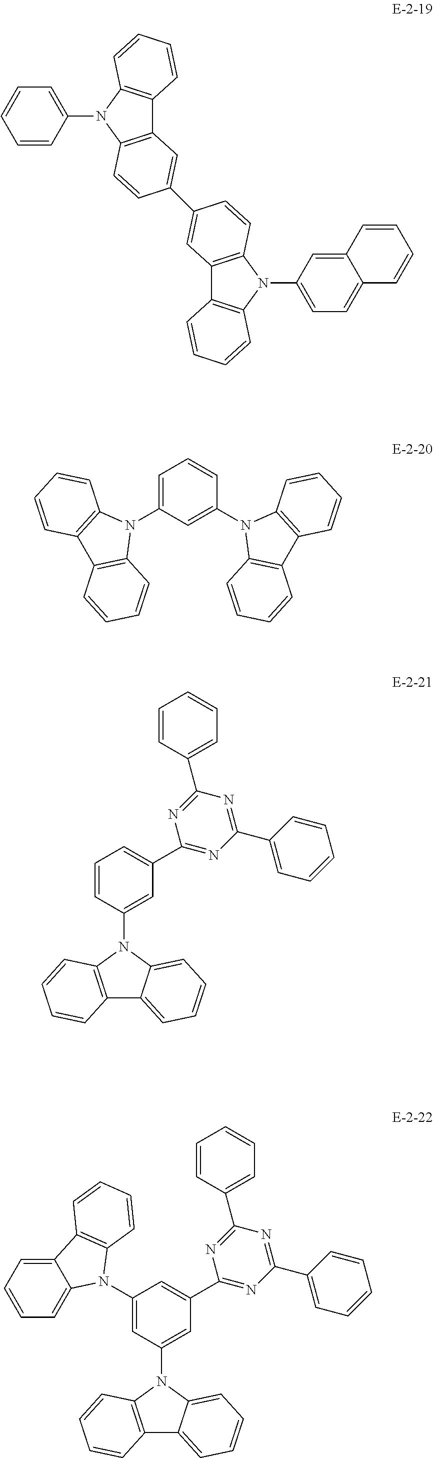 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

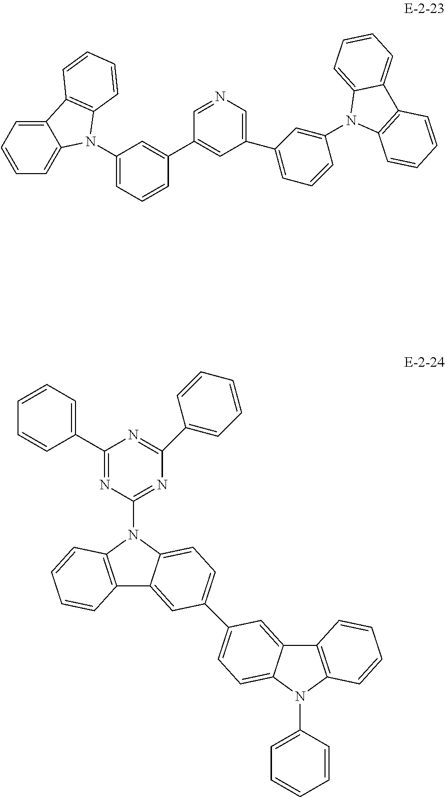 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material well-suitable in the art as a host material. For example, the emission layer EML may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, one or more embodiments of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be utilized as the host material.

The emission layer EML may include a compound represented by Formula M-a. The compound represented by Formula M-a may be utilized as a phosphorescence dopant material.

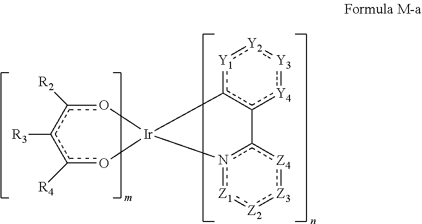

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by at least one selected from among Compounds M-a1 to M-a25. However, Compounds M-a1 to M-a25 are illustrations, and the compound represented by Formula M-a is not limited to the compounds represented by Compounds M-a1 to M-a25.

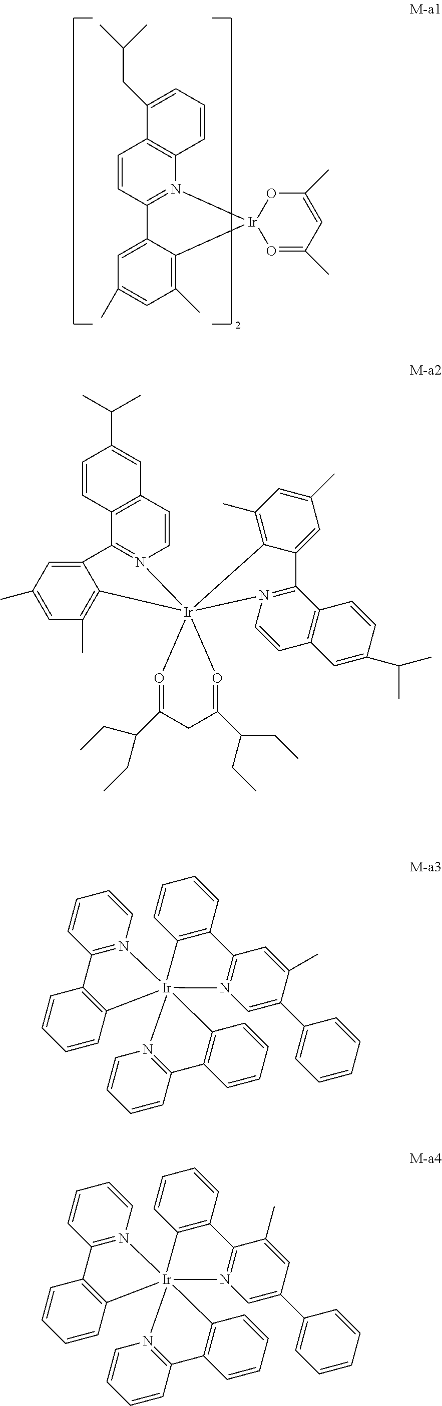

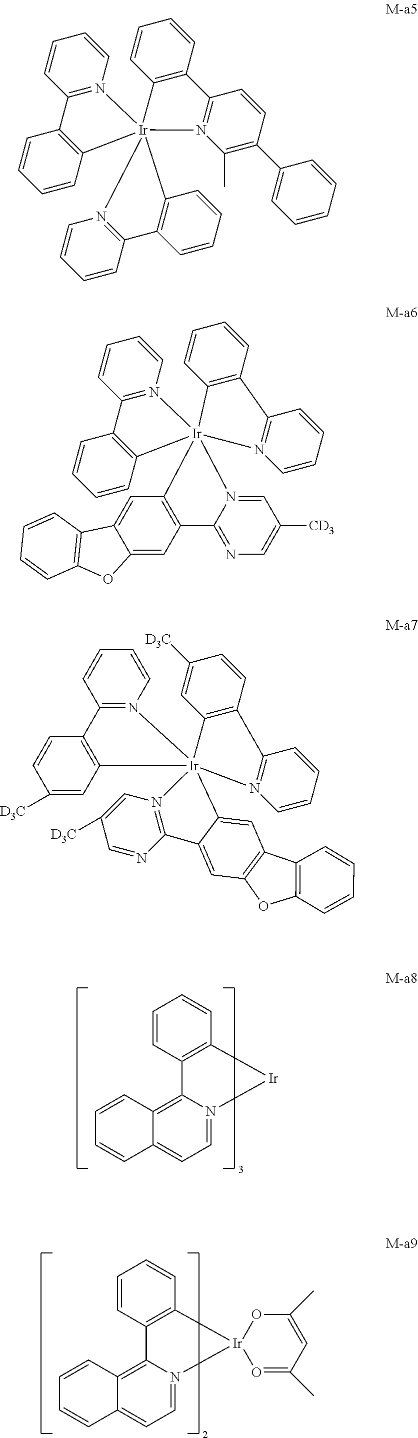

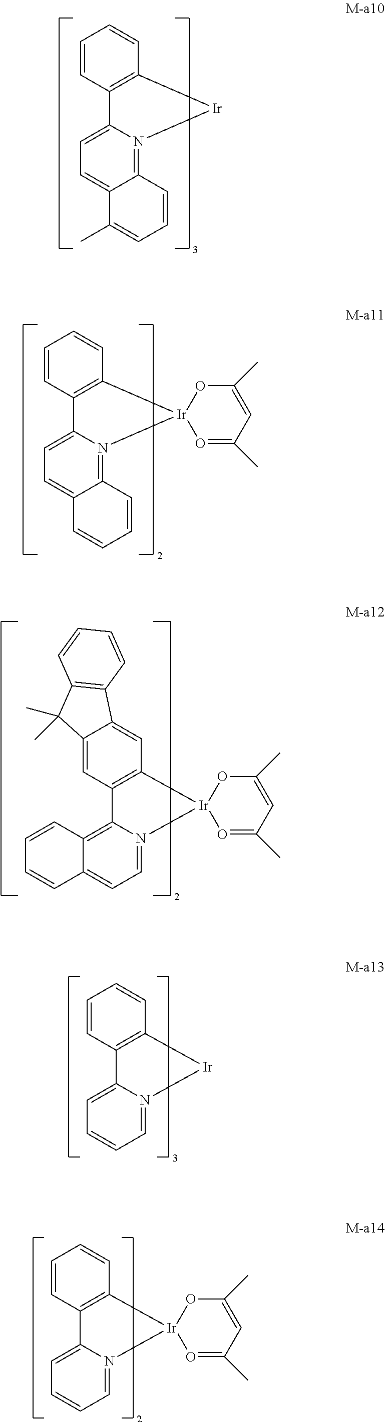

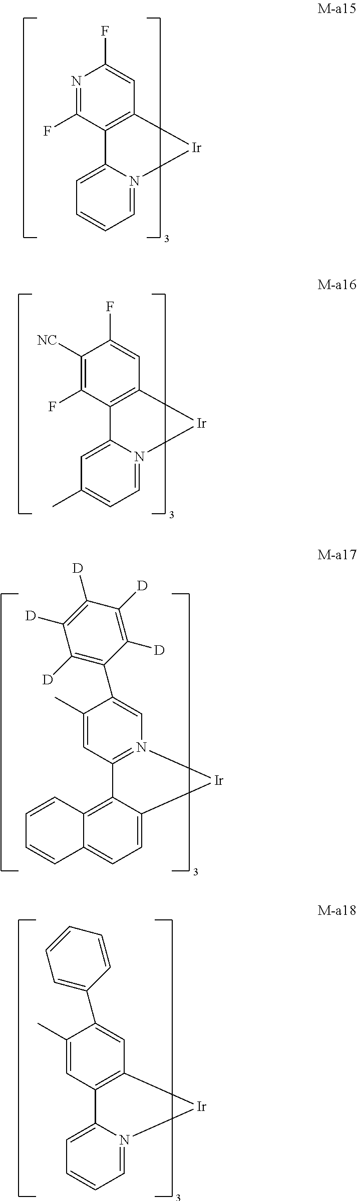

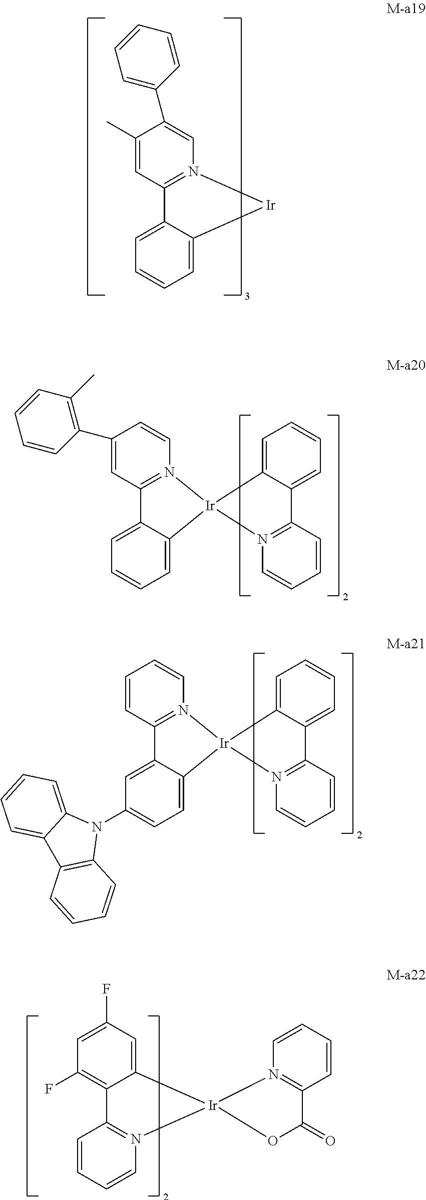

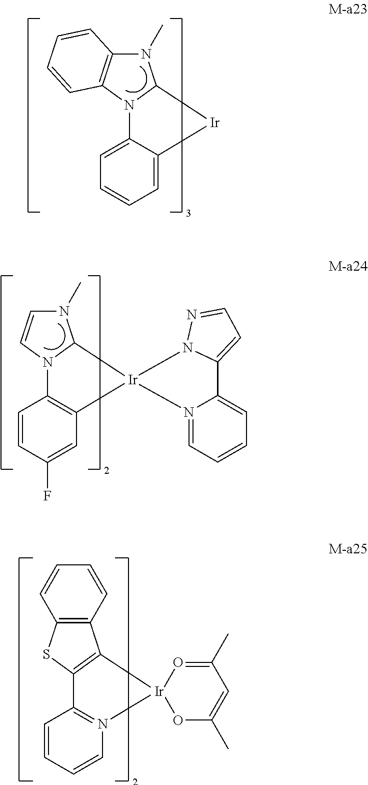

In one or more embodiments, the emission layer EML may include as a suitable dopant material, at least one selected from among styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), and/or the like.

The emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium (III)bis(4,6-difluorophenylpyridinato-N,C2′)picolinate (FIrpic), bis(2,4-difluorophenylpyridinato)-tetrakis(1-pyrazolyl)borate iridium (III) (Fir6), or platinum octaethyl porphyrin (PtOEP) may be utilized as the phosphorescence dopant. However, one or more embodiments of the present disclosure is not limited thereto.

The emission layer EML may include a quantum dot material. The core of the quantum dot may be selected from among II-VI group compounds, III-VI group compounds, I-III-VI group compounds, III-V group compounds, III-II-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, and In₂Se₃, a ternary compound such as InGaS₃, and InGaSe₃, or optional one or more combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include II group metals. For example, InZnP, and/or the like may be selected as a Ill-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In some embodiments, a polynary compound such as the binary compound, the ternary compound and/or the quaternary compound may be present at substantially uniform concentration or at non-substantially uniform concentration in a particle. For example, the chemical formulae described herein may refer to the types (kinds) of elements included, and the atomic ratio in the compound may be different. For example, AgInGaS₂ may refer to AgInₓGa₁₋ₓS₂ (x is a real number between 0-1).

In some embodiments, the quantum dot may have a single structure in which the concentration of each element included in the quantum dot is substantially uniform, or a core-shell double structure. For example, a material included in the core and a material included in the shell may be different from each other.

The shell of the quantum dot may be (e.g., play the role of) a protection layer for preventing or reducing the chemical deformation of the core to maintain semiconductor properties and/or a charging layer for imparting the quantum dot with electrophoretic properties. The shell may have a single layer or a multilayer. The interface of the core and the shell may have a concentration gradient in which the concentration of an element present in the shell is decreased toward the center.

In some embodiments, the quantum dot may have the herein-described core-shell structure including a core including a nanocrystal and a shell wrapping the core. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and/or CoMn₂O₄, but one or more embodiments of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the present disclosure is not limited thereto.

The polynary compound such as the binary compound and/or the ternary compound may be present at substantially uniform concentration or non-substantially uniform concentration in a particle. For example, the chemical formulae described herein may refer to the types (kinds) of elements included, and the atomic ratio in the compound may be different.

The quantum dot may have a full width of half maximum (FWHM) of emission wavelength spectrum of about 45 nm or less, about 40 nm or less, more, about 30 nm or less. Within this range, color purity or color reproducibility may be improved. In some embodiments, light emitted via such quantum dot is emitted in all directions, and light viewing angle properties may be improved.

In some embodiments, the shape of the quantum dot may be generally utilized shapes in the art, without specific limitation. More particularly, the shape of spherical, pyramidal, multi-arm, or cubic nanoparticle, nanotube, nanowire, nanofiber, nanoplate particle, and/or the like may be utilized.

By controlling the size of the quantum dot or by controlling the element ratio in the quantum dot compound, an energy band gap may be controlled or selected, and one or more suitable wavelength bands of light may be obtained from a quantum dot emission layer. Accordingly, by utilizing such a quantum dot (utilizing quantum dots having different sizes or controlling an element ratio in a quantum dot compound differently), a light emitting element emitting one or more suitable wavelengths of light may be accomplished. For example, the size of the quantum dot or the element ratio in the quantum dot compound may be controlled or selected to emit red, green and/or blue light. In some embodiments, the quantum dots may be provided to combine one or more suitable emission colors to emit white light.

In the light emitting elements ED of embodiments, shown in FIG. 3 to FIG. 6, the electron transport region ETR is provided on the emission layer EML. The electron transport region ETR may include at least one of a hole blocking layer HBL, an electron transport layer ETL or an electron injection layer EIL. However, one or more embodiments of the present disclosure is not limited thereto.

The electron transport region ETR may have a single layer including (e.g., formed utilizing) a single material, a single layer including (e.g., formed utilizing) multiple different materials, or a multilayer structure having multiple layers including (e.g., formed utilizing) multiple different materials.

For example, the electron transport region ETR may have a single layer structure of an electron injection layer EIL or an electron transport layer ETL, or a single layer structure including (e.g., formed utilizing) an electron injection material and an electron transport material. Further, the electron transport region ETR may have a single layer structure including (e.g., formed utilizing) multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 400 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The light emitting element ED of one or more embodiments according to the present disclosure includes at least one functional layer provided between the first electrode EL1 and the second electrode EL2, and the at least one functional layer may include the compound represented by Formula 1. In the light emitting element ED of one or more embodiments, the electron transport region ETR may include the compound represented by Formula 1. For example, in the electron transport region ETR of one or more embodiments, the electron transport layer ETL may include the compound represented by Formula 1.

The compound of one or more embodiments may include a core structure in which two phenylene groups are connected via a cycloalkyl group. The compound of one or more embodiments may include both (e.g., simultaneously) a phosphine oxide group and a triazine group, which are combined with the core structure. For example, the phosphine oxide group may be bonded to one phenyl group in the core group and may be connected with the phenylene group of the core structure via a linker. In some embodiments, the triazine group may be directly bonded to the other phenylene group of the core structure.

The compound of one or more embodiments may be represented by Formula 1.

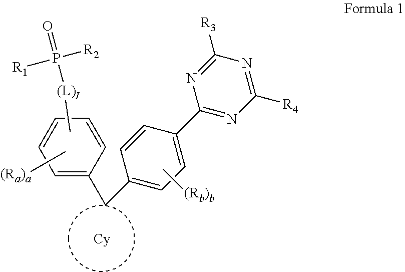

In Formula 1, Cy may be a substituted or unsubstituted cycloalkyl group of 3 to 30 ring-forming carbon atoms. For example, Cy may be an unsubstituted cycloalkyl group of 3 to 10 ring-forming carbon atoms. For example, Cy may be an unsubstituted cyclohexyl group, an unsubstituted bicyclohexyl group, or an unsubstituted adamantyl group.

In Formula 1, L may be a substituted or unsubstituted arylene group of 6 to 30 ring-forming carbon atoms, or a substituted or unsubstituted heteroarylene group of 2 to 30 ring-forming carbon atoms. For example, L may be an unsubstituted arylene group of 6 to 15 ring-forming carbon atoms. For example, L may be an unsubstituted phenylene group, an unsubstituted naphthalene group, or an unsubstituted anthracene group.

In Formula 1, R₁ to R₄ may each independently be a substituted or unsubstituted alkyl group of 1 to 10 carbon atoms, or a substituted or unsubstituted aryl group of 6 to 30 ring-forming carbon atoms. In one or more embodiments, each R₁ to R₄ may be the same, or at least one of R₁ to R₄ may be different from the remainder.

For example, R₁ and R₂ may each independently be an unsubstituted alkyl group of 1 to 4 carbon atoms, or an unsubstituted aryl group of 6 to 10 ring-forming carbon atoms. For example, R₁ and R₂ may each independently be an unsubstituted methyl group, or an unsubstituted phenyl group. In one or more embodiments, R₁ and R₂ may be the same, or different from each other. For example, R₁ and R₂ may be unsubstituted methyl groups, or unsubstituted phenyl groups. In some embodiments, any one among R₁ and R₂ may be an unsubstituted methyl group, and the other one may be an unsubstituted phenyl group.

In some embodiments, particularly, R₃ and R₄ may each independently be a substituted or unsubstituted aryl group of 6 to 20 ring-forming carbon atoms. For example, R₃ and R₄ may each independently be an unsubstituted phenyl group, an unsubstituted biphenyl group, an unsubstituted terphenyl group, an unsubstituted naphthyl group, or a substituted or unsubstituted anthracenyl group. When R₃ and R₄ are substituted anthracenyl groups, each of R₃ and R₄ may be an anthracenyl group substituted with a phenyl group. In one or more embodiments, R₃ and R₄ may be the same or different from each other.

In Formula 1, Rₐ and R_{b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In one or more embodiments, Rₐ and R_{b} may be the same. For example, both (e.g., simultaneously) Rₐ and R_{b} may be all hydrogen atoms.

In Formula 1, “a” and “b” may each independently be an integer of 0 to 4. A case where “a” is 0, may be the same as a case where “a” is 4, and all Rₐ are hydrogen atoms. When “a” is an integer of 2 or more, two or more Rₐ may be the same, or at least one may be different from the remainder. A case where “b” is 0, may be the same as a case where “b” is 4, and all R_{b} are hydrogen atoms. When “b” is an integer of 2 or more, two or more R_{b} may be the same, or at least one may be different from the remainder.

In Formula 1, “l” may be 1 or 2. When “l” is 1, L may be bonded to —P(═O)R₁R₂ and the phenylene group of the core structure. When “l” is 2, two L may be combined with each other, one L may be bonded to —P(═O)R₁R₂, and the other L may be bonded to the phenylene group of Formula 1. When “l” is 2, two L may be different from each other. For example, each of two L may be an unsubstituted phenylene group and an unsubstituted anthracene group. In this case, the unsubstituted phenylene group and the unsubstituted anthracene group may be combined with each other, the unsubstituted phenylene group may be bonded to —P(═O)R₁R₂ of Formula 1, and the unsubstituted anthracene group may be bonded to the phenylene group of Formula 1.

Formula 1 may be represented by any one among Formula 1-1a to Formula 1-1c.

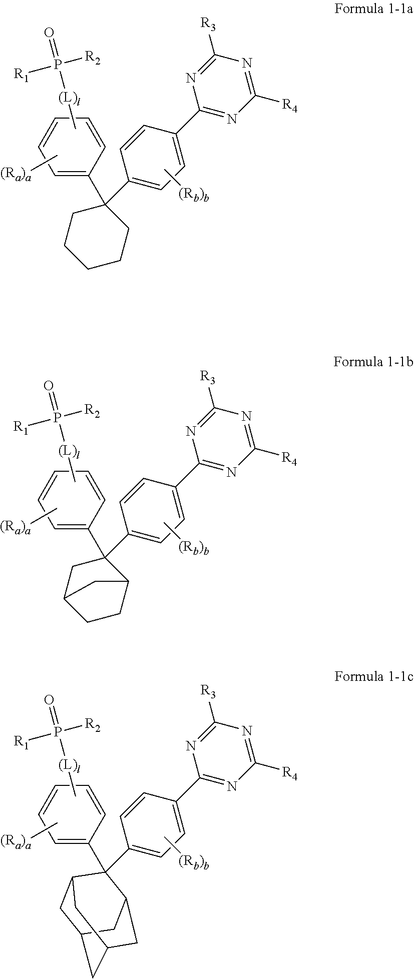

Formula 1-1a to Formula 1-1c represent Formula 1 in which Cy is particularly specified. Formula 1-1a represents a case where Cy is an unsubstituted cyclohexyl group, Formula 1-1b represents a case where Cy is an unsubstituted bicycloheptyl group, and Formula 1-1c represents a case where Cy is an unsubstituted adamantyl group.

In Formula 1-1a to Formula 1-1c, L, R₁ to R₄, Rₐ, R_{b}, “a”, “b”, and “l” may each independently be as defined in Formula 1.

Formula 1 may be represented by Formula 1-2a or Formula 1-2b.

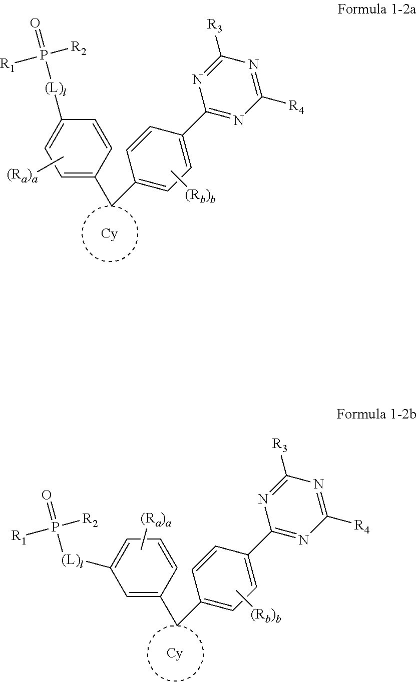

Formula 1-2a and Formula 1-2b represent cases where the position of L bonded to the phenylene group is particularly specified. In Formula 1-2a, L is bonded to the phenylene group in para relation with respect to Cy, and in Formula 1-2b, L is bonded to the phenylene group in meta relation with respect to Cy.

In Formula 1-2a and Formula 1-2b, Cy, L, R₁ to R₄, Rₐ, R_{b}, “a”, “b”, and “l” may each independently be as defined in Formula 1.

The compound represented by Formula 1 may be represented by at least one selected from among the compounds in Compound Group 1. The light emitting element ED of one or more embodiments may include at least one compound selected from among the compounds in Compound Group 1. For example, the light emitting element ED of one or more embodiments may include at least one compound selected from among the compounds in Compound Group 1 in an electron transport region ETR. For example, the light emitting element ED of one or more embodiments may include at least one compound selected from among the compounds in Compound Group 1 in an electron transport layer ETL.

### Compound Group 1

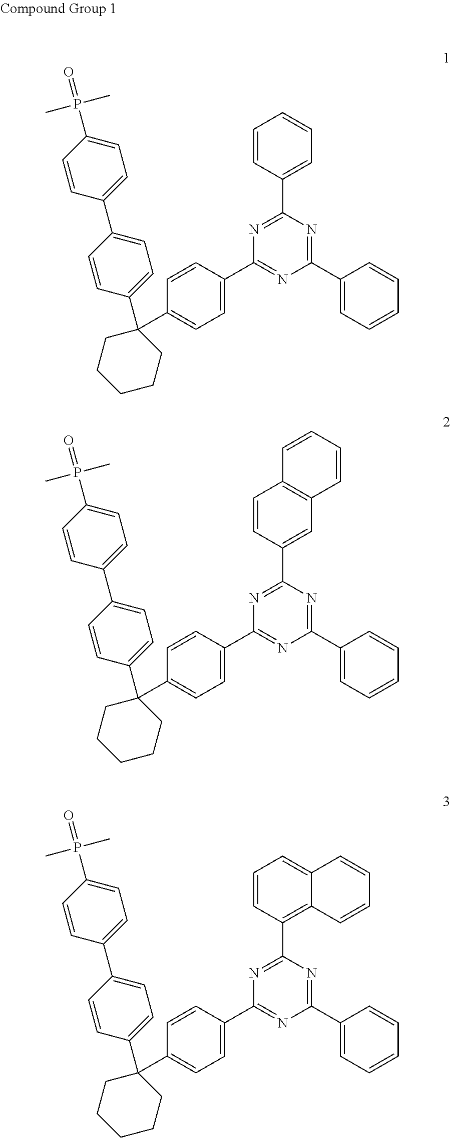 [SMILES: CP(C)(=O)c1ccc(-c2ccc(C3(c4ccc(-c5nc(-c6ccccc6)nc(-c6ccccc6)n5)cc4)CCCCC3)cc2)cc1 ; CP(C)(=O)c1ccc(-c2ccc(C3(c4ccc(-c5nc(-c6ccccc6)nc(-c6ccc7ccccc7c6)n5)cc4)CCCCC3)cc2)cc1 ; CP(C)(=O)c1ccc(-c2ccc(C3(c4ccc(-c5nc(-c6ccccc6)nc(-c6cccc7ccccc67)n5)cc4)CCCCC3)cc2)cc1]

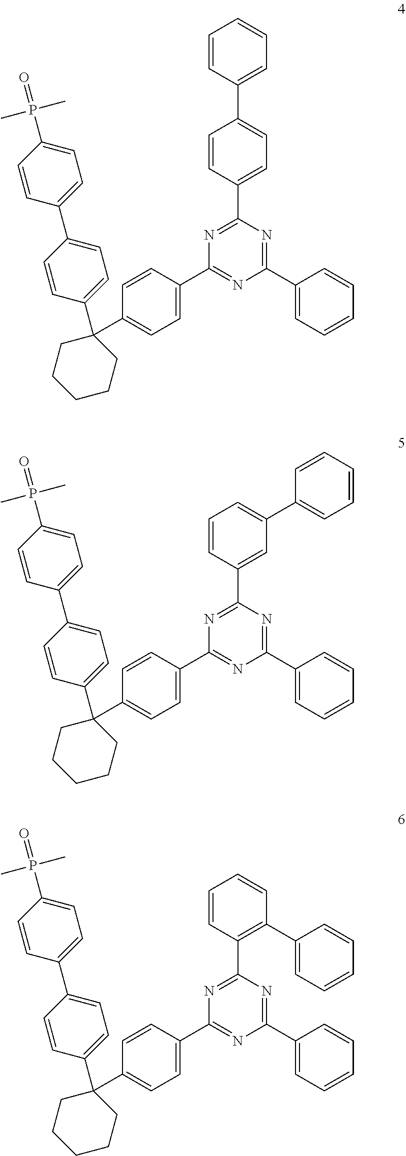 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccccc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccccc6)nc(-c6ccccc6-c6ccccc6)n5)cc4)CCCCC3)cc2)cc1]

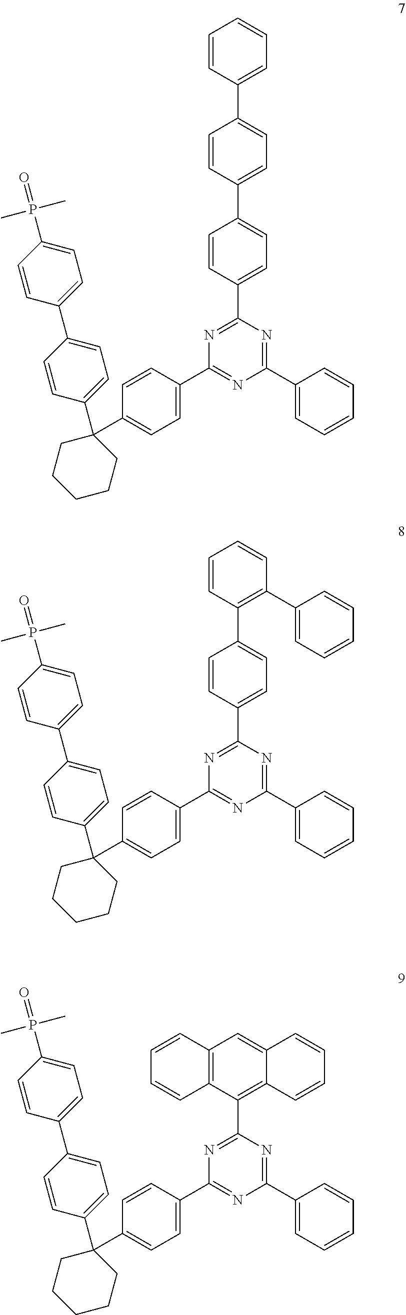 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)cc1 ; CP(C)(=O)c1ccc(-c2ccc(C3(c4ccc(-c5nc(-c6ccccc6)nc(-c6c7ccccc7cc7ccccc67)n5)cc4)CCCCC3)cc2)cc1]

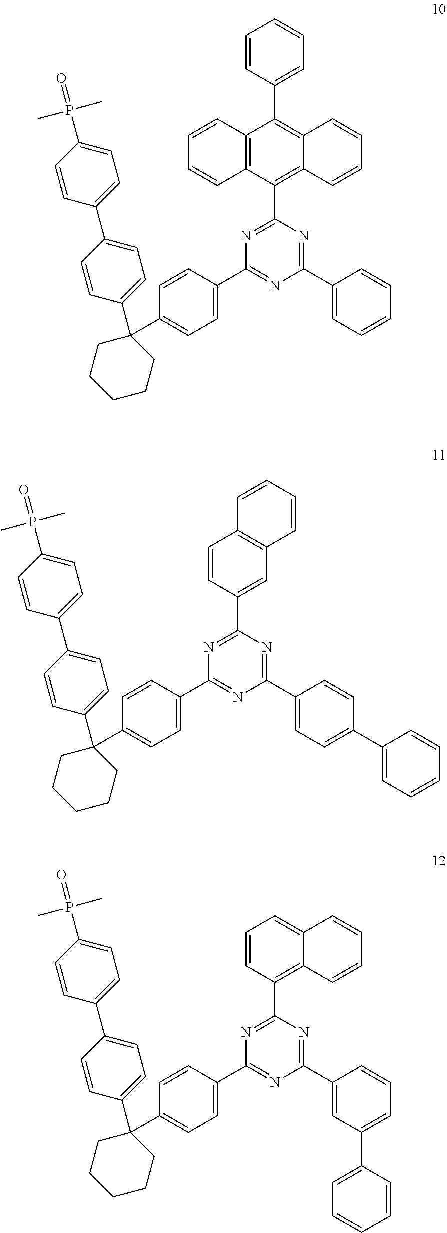 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)cc1]

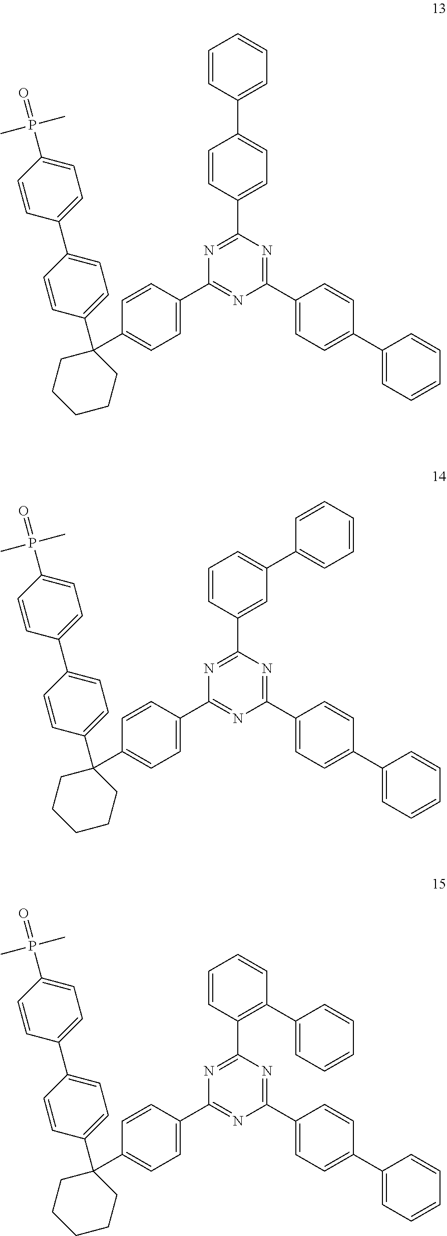 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)cc1]

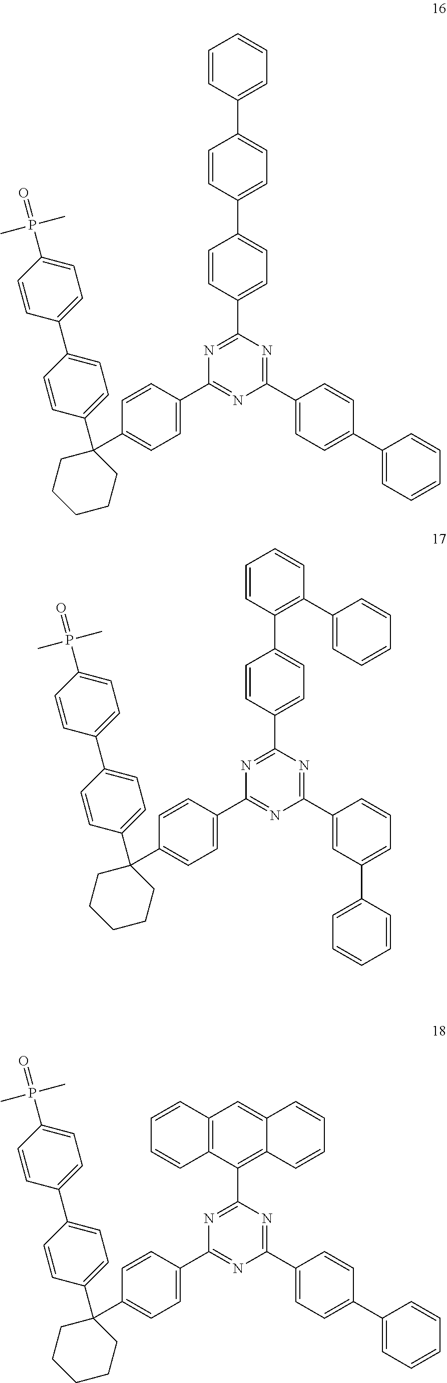 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CCCCC3)cc2)cc1]

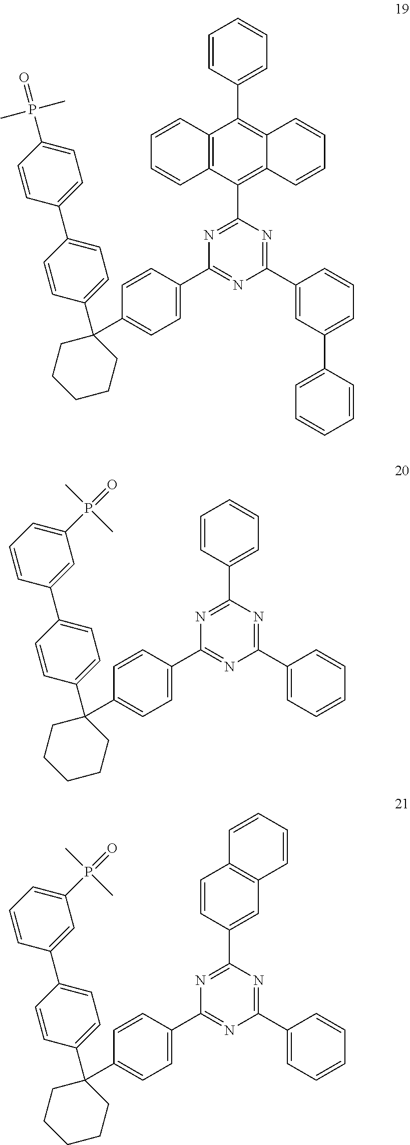 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)cc1 ; CP(C)(=O)c1cccc(-c2ccc(C3(c4ccc(-c5nc(-c6ccccc6)nc(-c6ccccc6)n5)cc4)CCCCC3)cc2)c1 ; CP(C)(=O)c1cccc(-c2ccc(C3(c4ccc(-c5nc(-c6ccccc6)nc(-c6ccc7ccccc7c6)n5)cc4)CCCCC3)cc2)c1]

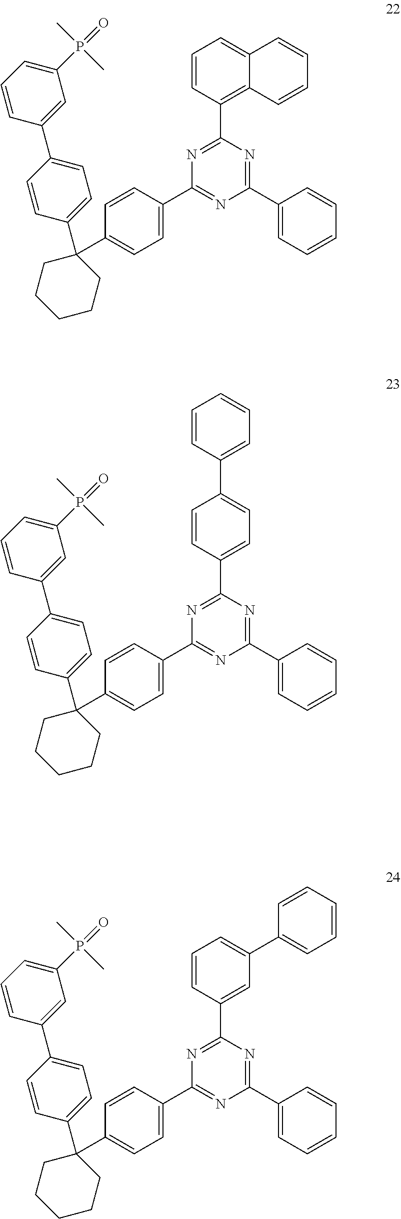 [SMILES: CP(C)(=O)c1cccc(-c2ccc(C3(c4ccc(-c5nc(-c6ccccc6)nc(-c6cccc7ccccc67)n5)cc4)CCCCC3)cc2)c1 ; CP(C)(=O)c1cccc(-c2ccc(C3(c4ccc(-c5nc(-c6ccccc6)nc(-c6ccc(-c7ccccc7)cc6)n5)cc4)CCCCC3)cc2)c1 ; CP(C)(=O)c1cccc(-c2ccc(C3(c4ccc(-c5nc(-c6ccccc6)nc(-c6cccc(-c7ccccc7)c6)n5)cc4)CCCCC3)cc2)c1]

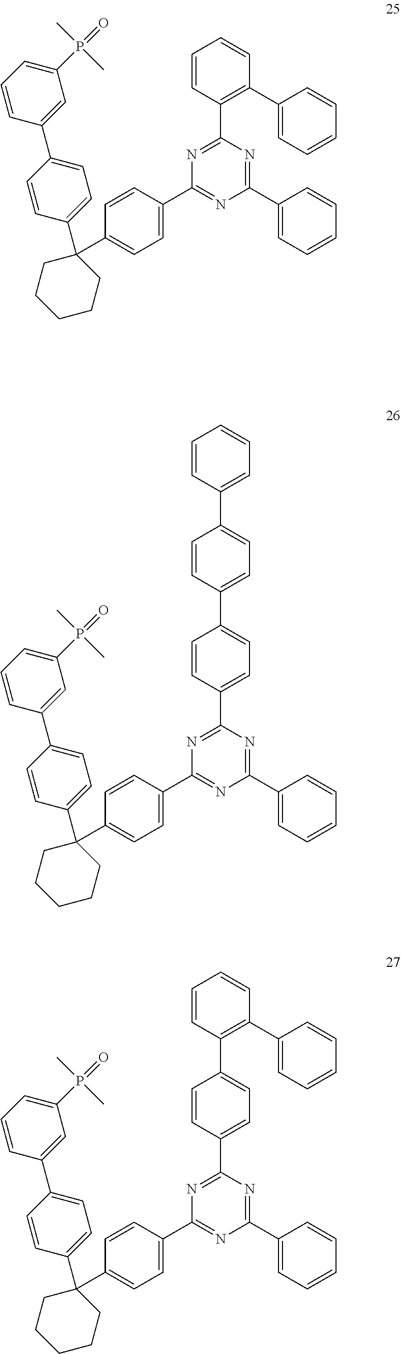 [SMILES: CP(C)(=O)c1cccc(-c2ccc(C3(c4ccc(-c5nc(-c6ccccc6)nc(-c6ccccc6-c6ccccc6)n5)cc4)CCCCC3)cc2)c1 ; CP(C)(=O)c1cccc(-c2ccc(C3(c4ccc(-c5nc(-c6ccccc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CCCCC3)cc2)c1]

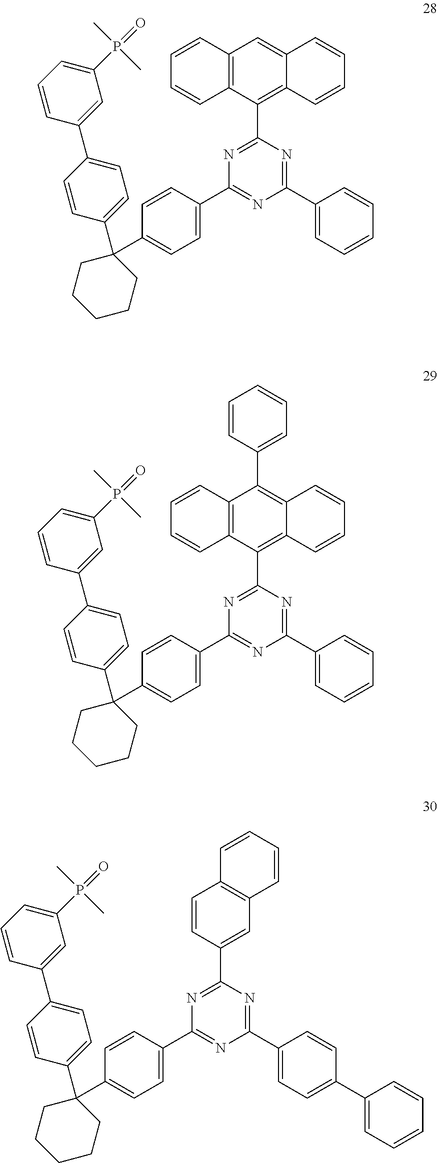 [SMILES: CP(C)(=O)c1cccc(-c2ccc(C3(c4ccc(-c5nc(-c6ccccc6)nc(-c6c7ccccc7cc7ccccc67)n5)cc4)CCCCC3)cc2)c1 ; CP(C)(=O)c1cccc(-c2ccc(C3(c4ccc(-c5nc(-c6ccccc6)nc(-c6c7ccccc7c(-c7ccccc7)c7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CCCCC3)cc2)c1]

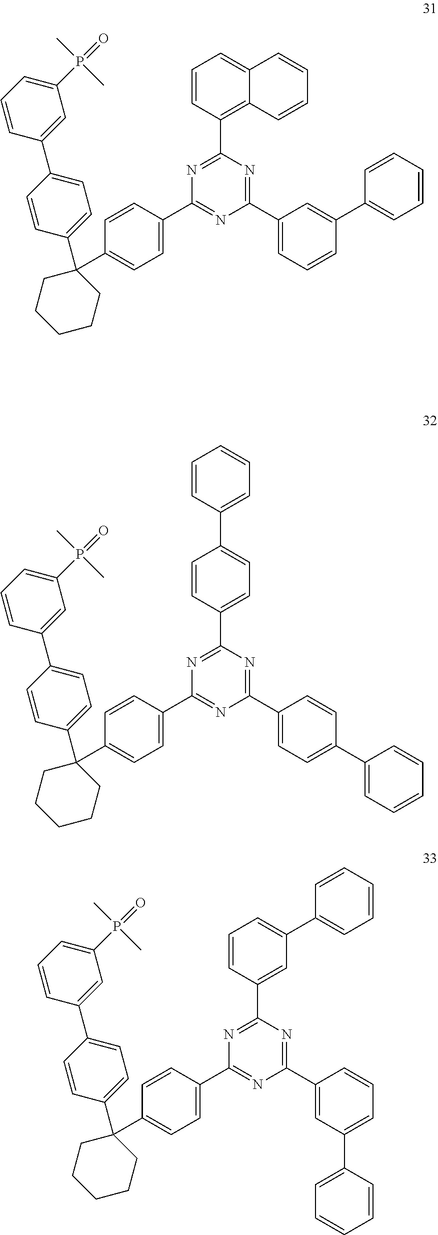 [SMILES: CP(C)(=O)c1cccc(-c2ccc(C3(c4ccc(-c5nc(-c6cccc(-c7ccccc7)c6)nc(-c6cccc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccccc7)cc6)n5)cc4)CCCCC3)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CCCCC3)cc2)c1]

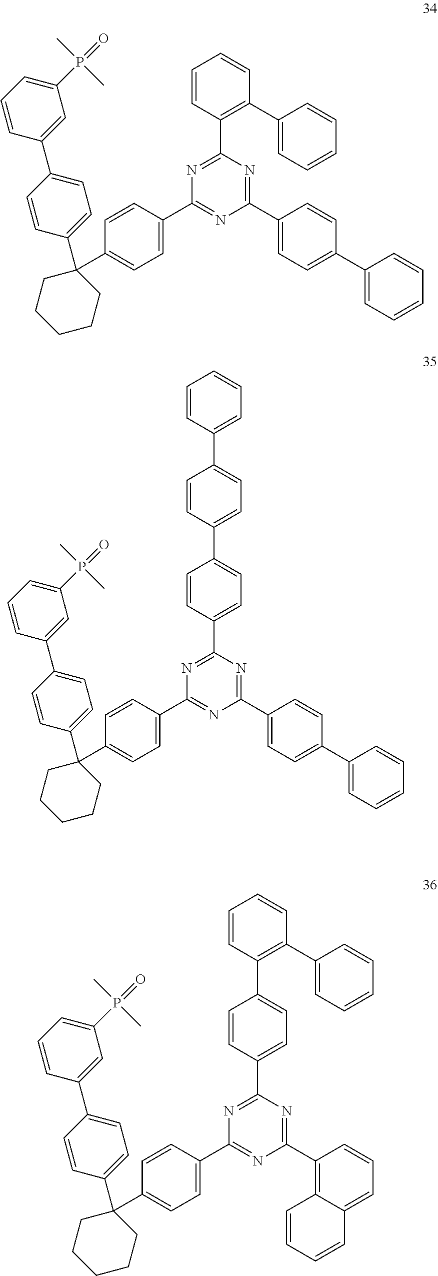 [SMILES: CP(C)(=O)c1cccc(-c2ccc(C3(c4ccc(-c5nc(-c6ccc(-c7ccccc7)cc6)nc(-c6ccccc6-c6ccccc6)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CCCCC3)cc2)c1]

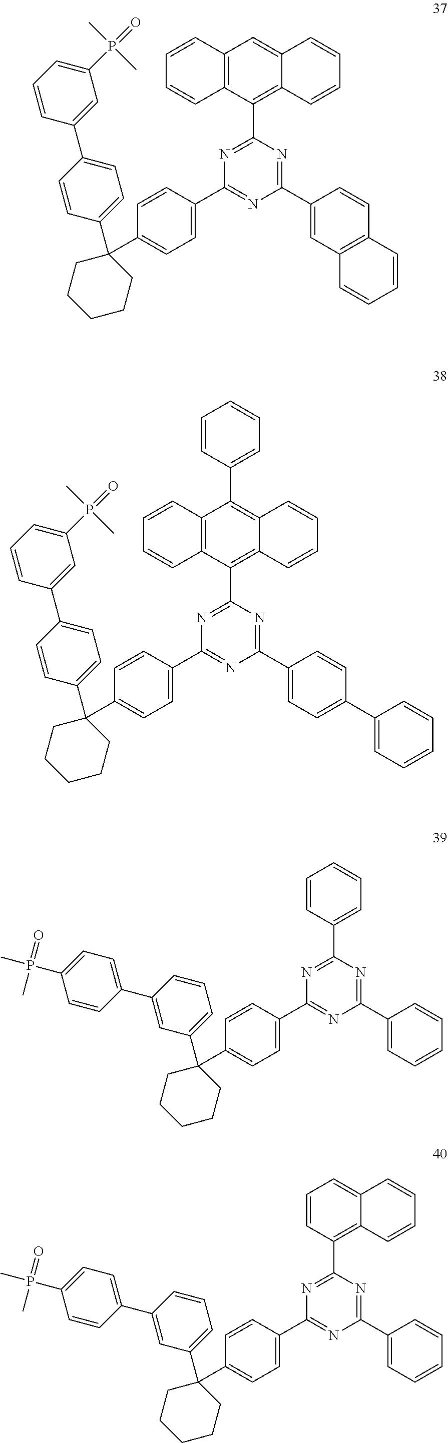 [SMILES: CP(C)(=O)c1cccc(-c2ccc(C3(c4ccc(-c5nc(-c6ccc7ccccc7c6)nc(-c6c7ccccc7cc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CCCCC3)cc2)c1 ; CP(C)(=O)c1ccc(-c2cccc(C3(c4ccc(-c5nc(-c6ccccc6)nc(-c6ccccc6)n5)cc4)CCCCC3)c2)cc1 ; CP(C)(=O)c1ccc(-c2cccc(C3(c4ccc(-c5nc(-c6ccccc6)nc(-c6cccc7ccccc67)n5)cc4)CCCCC3)c2)cc1]

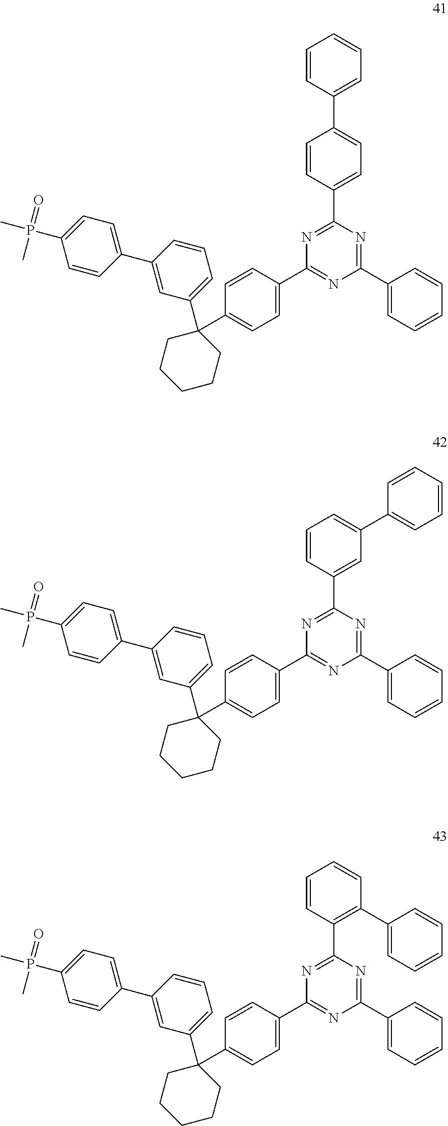 [SMILES: CP(C)(=O)c1ccc(-c2cccc(C3(c4ccc(-c5nc(-c6ccccc6)nc(-c6ccc(-c7ccccc7)cc6)n5)cc4)CCCCC3)c2)cc1 ; CP(C)(=O)c1ccc(-c2cccc(C3(c4ccc(-c5nc(-c6ccccc6)nc(-c6cccc(-c7ccccc7)c6)n5)cc4)CCCCC3)c2)cc1 ; CP(C)(=O)c1ccc(-c2cccc(C3(c4ccc(-c5nc(-c6ccccc6)nc(-c6ccccc6-c6ccccc6)n5)cc4)CCCCC3)c2)cc1]

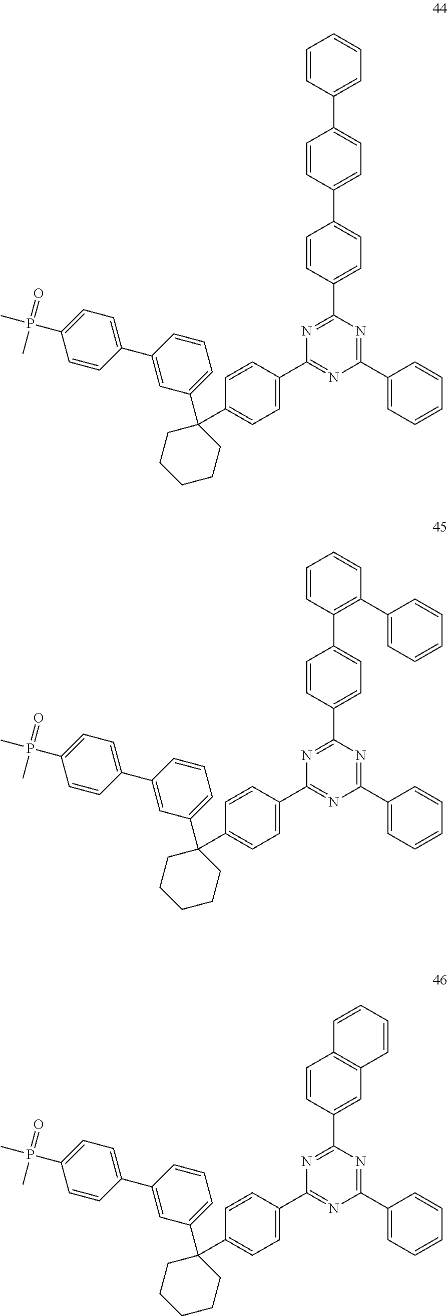 [SMILES: CP(C)(=O)c1ccc(-c2cccc(C3(c4ccc(-c5nc(-c6ccccc6)nc(-c6ccc(-c7ccc(-c8ccccc8)cc7)cc6)n5)cc4)CCCCC3)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CCCCC3)c2)cc1 ; CP(C)(=O)c1ccc(-c2cccc(C3(c4ccc(-c5nc(-c6ccccc6)nc(-c6ccc7ccccc7c6)n5)cc4)CCCCC3)c2)cc1]

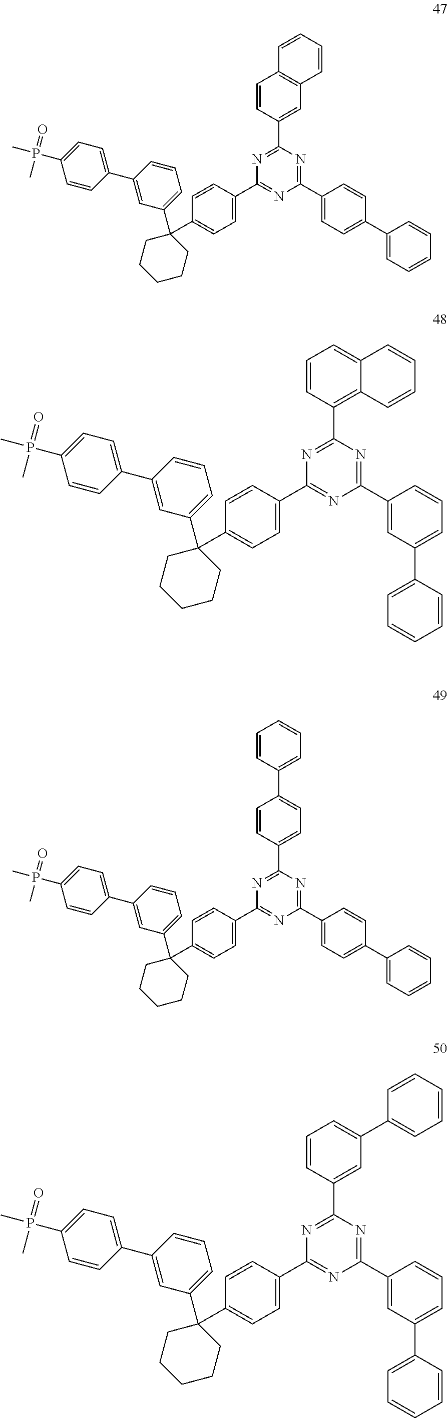 [SMILES: CP(C)(=O)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1]

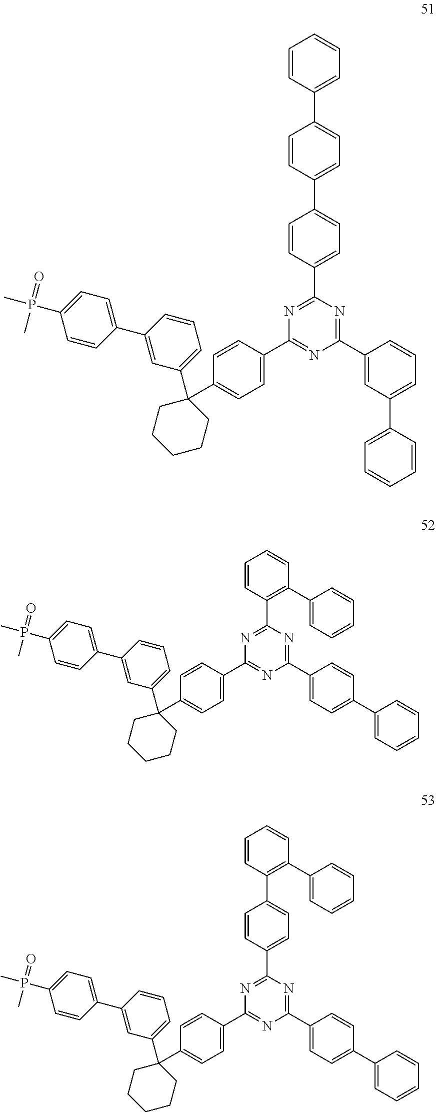 [SMILES: CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1]

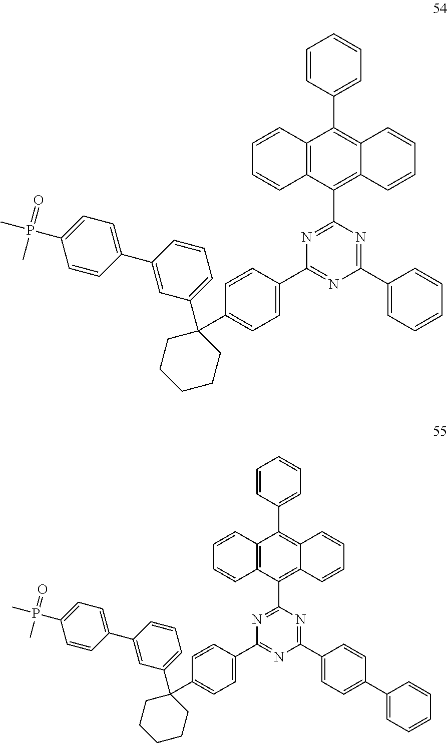 [SMILES: CP(C)(=O)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1]

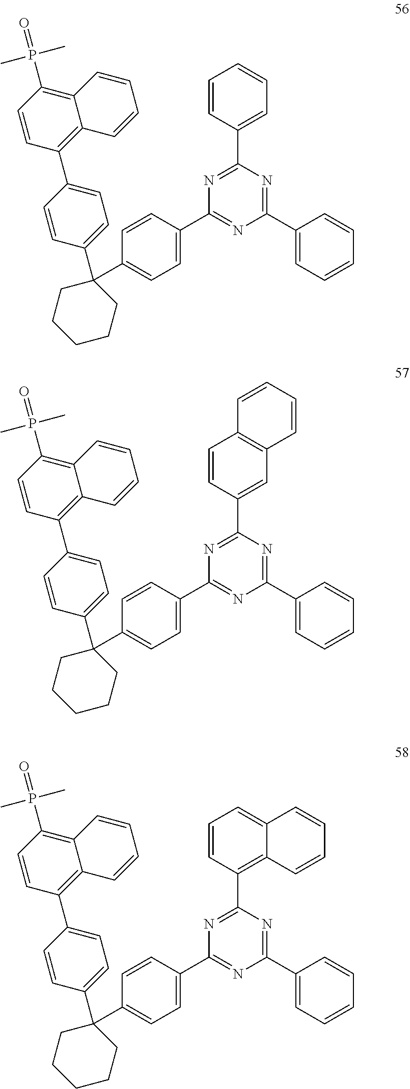 [SMILES: CP(C)(=O)c1ccc(-c2ccc(C3(c4ccc(-c5nc(-c6ccccc6)nc(-c6ccccc6)n5)cc4)CCCCC3)cc2)c2ccccc12 ; CP(C)(=O)c1ccc(-c2ccc(C3(c4ccc(-c5nc(-c6ccccc6)nc(-c6ccc7ccccc7c6)n5)cc4)CCCCC3)cc2)c2ccccc12 ; CP(C)(=O)c1ccc(-c2ccc(C3(c4ccc(-c5nc(-c6ccccc6)nc(-c6cccc7ccccc67)n5)cc4)CCCCC3)cc2)c2ccccc12]

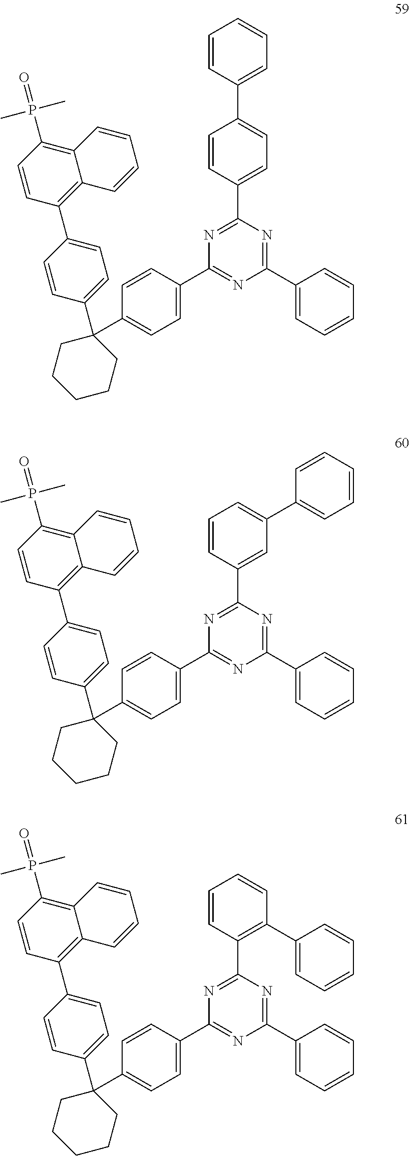 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccccc6)nc(-c6ccccc6-c6ccccc6)n5)cc4)CCCCC3)cc2)c2ccccc12]

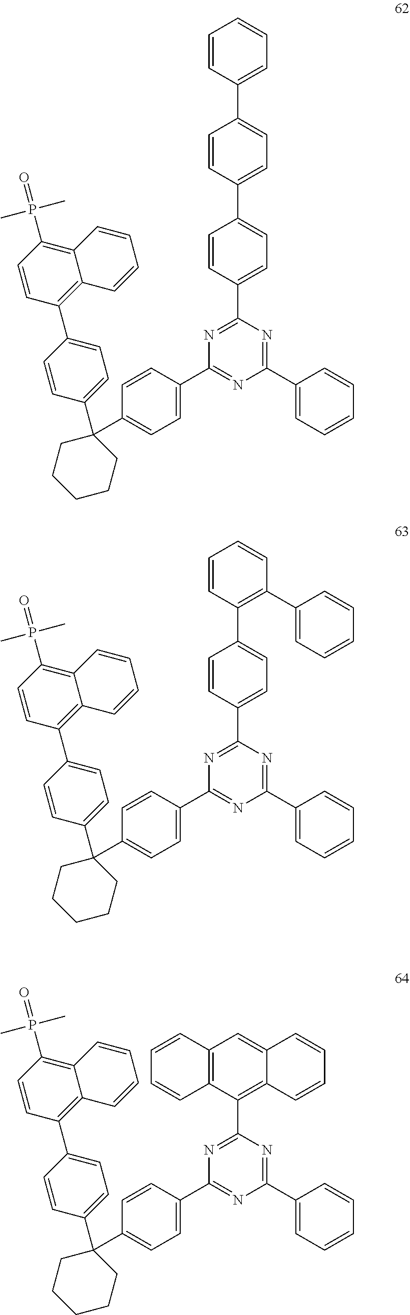 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CCCCC3)cc2)c2ccccc12]

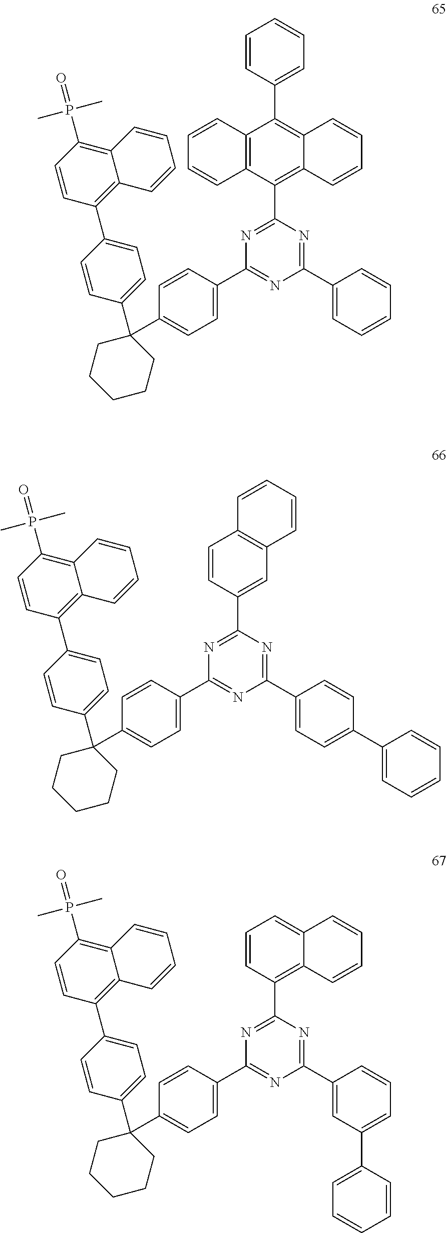 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)c2ccccc12]

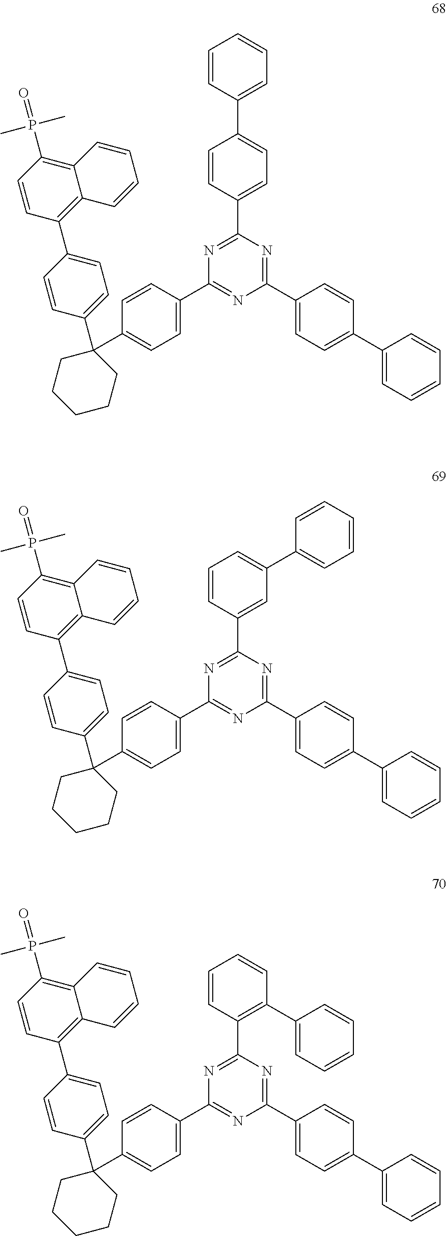 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

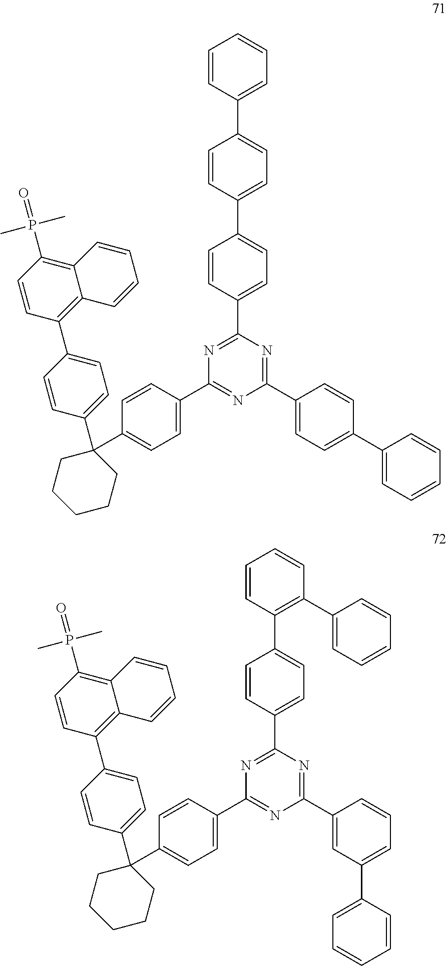 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

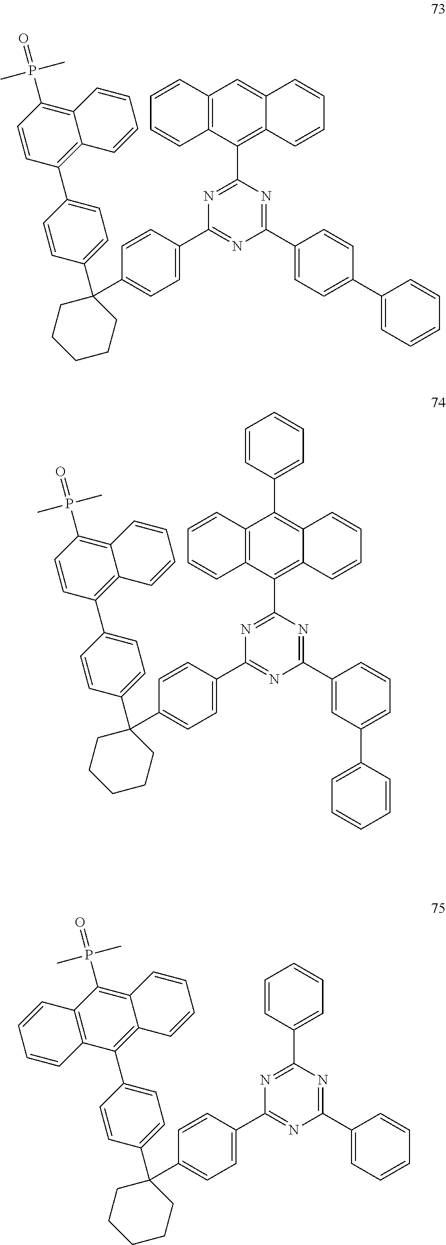 [SMILES: CP(C)(=O)c1ccc(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccccc6)nc(-c6ccccc6)n5)cc4)CCCCC3)cc2)c2ccccc12]

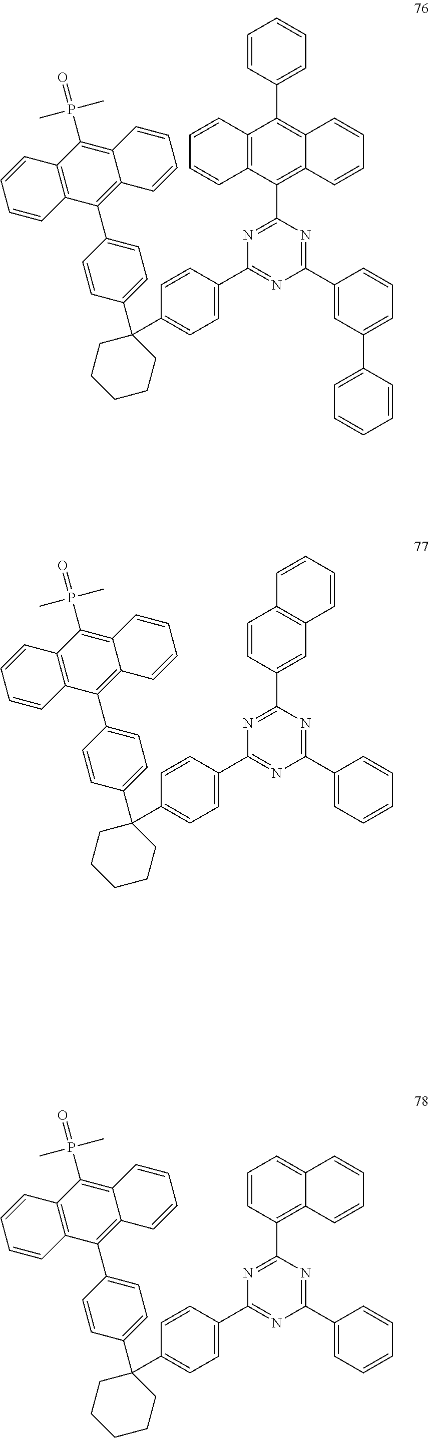 [SMILES: CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccccc6)nc(-c6ccc7ccccc7c6)n5)cc4)CCCCC3)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CCCCC3)cc2)c2ccccc12]

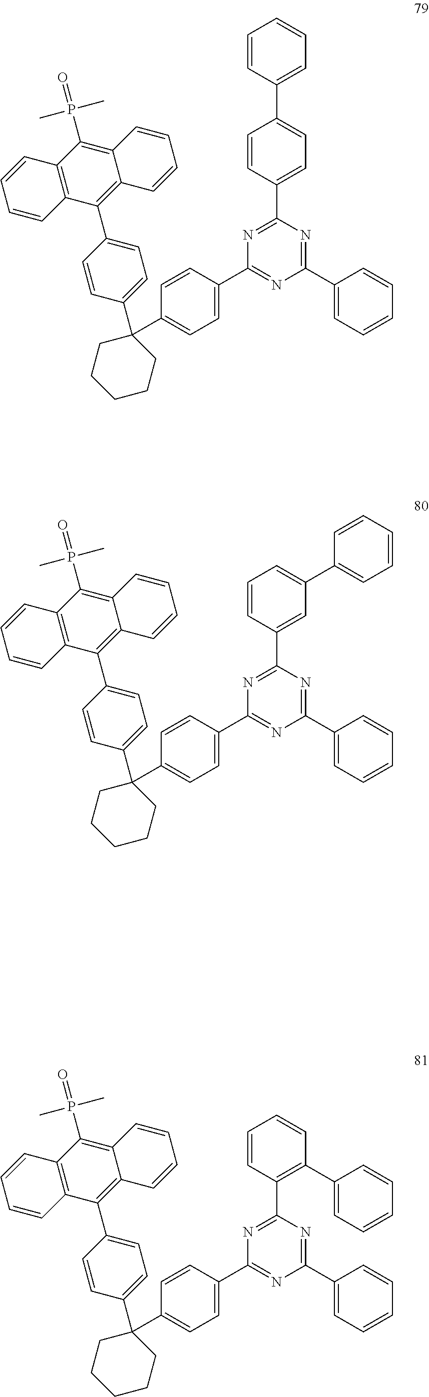 [SMILES: CP(C)(=O)c1c2ccccc2c(-c2ccc(C3(c4ccc(-c5nc(-c6ccccc6)nc(-c6ccc(-c7ccccc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6cccc(-c7ccccc7)c6)n5)cc4)CCCCC3)cc2)c2ccccc12 ; CP(C)(=O)c1c2ccccc2c(-c2ccc(C3(c4ccc(-c5nc(-c6ccccc6)nc(-c6ccccc6-c6ccccc6)n5)cc4)CCCCC3)cc2)c2ccccc12]

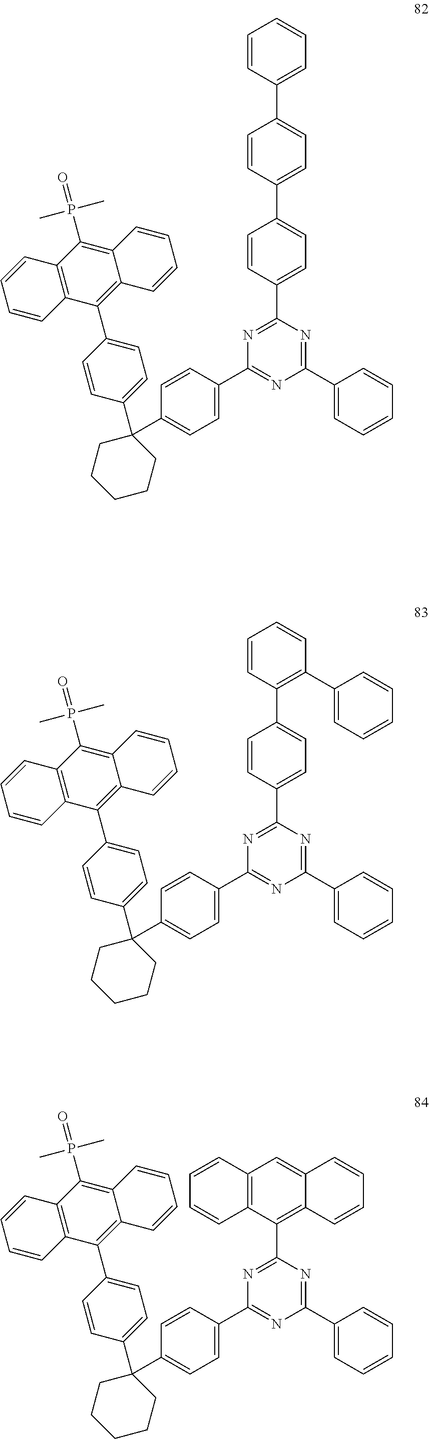 [SMILES: CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)CCCCC3)cc2)c2ccccc12]

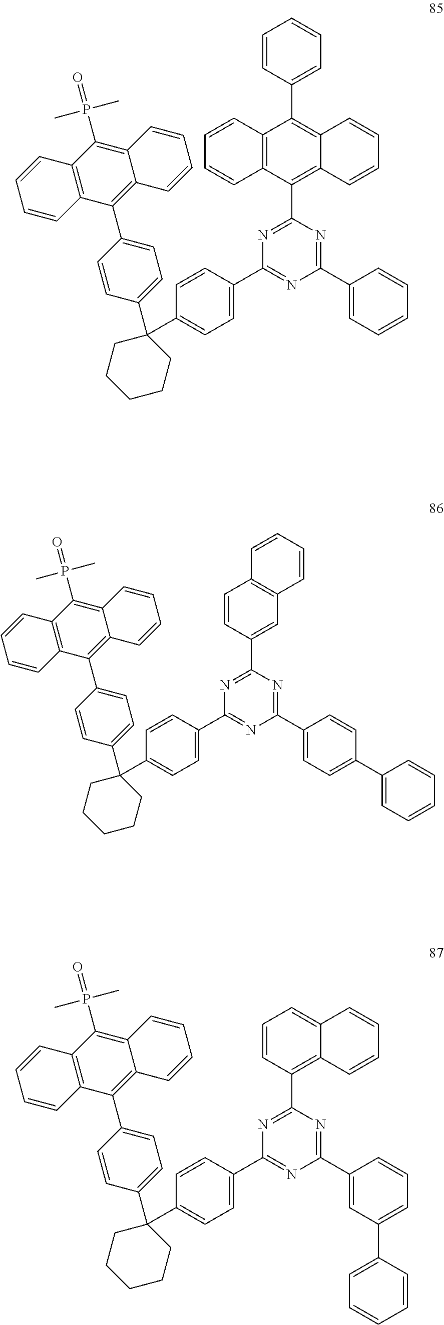 [SMILES: CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6ccc7ccccc7c6)n5)cc4)CCCCC3)cc2)c2ccccc12 ; CP(C)(=O)c1c2ccccc2c(-c2ccc(C3(c4ccc(-c5nc(-c6cccc(-c7ccccc7)c6)nc(-c6cccc7ccccc67)n5)cc4)CCCCC3)cc2)c2ccccc12]

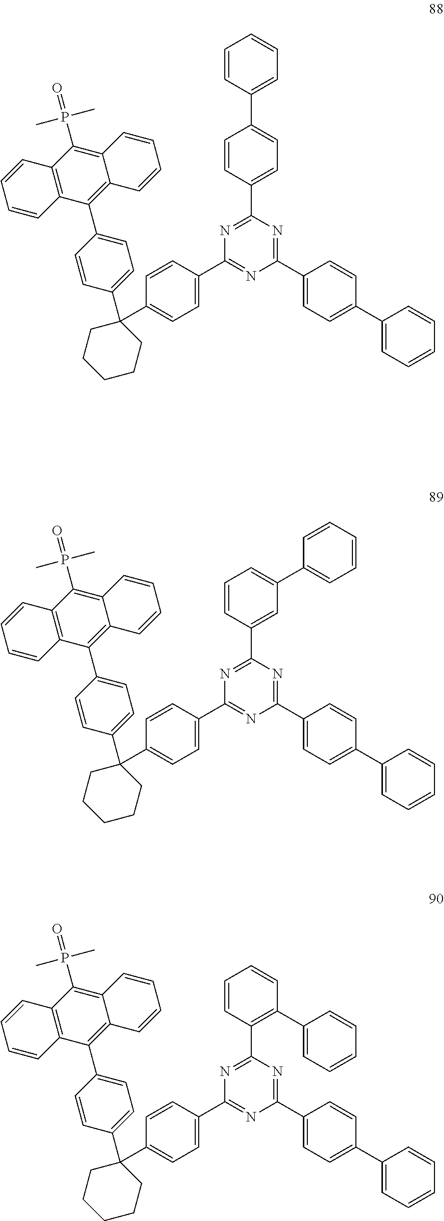 [SMILES: CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

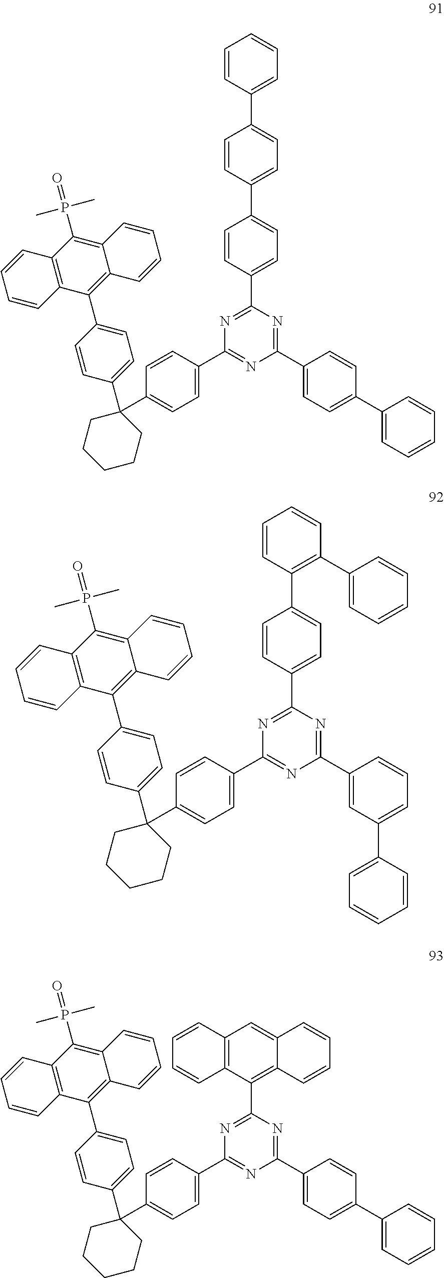 [SMILES: CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12]

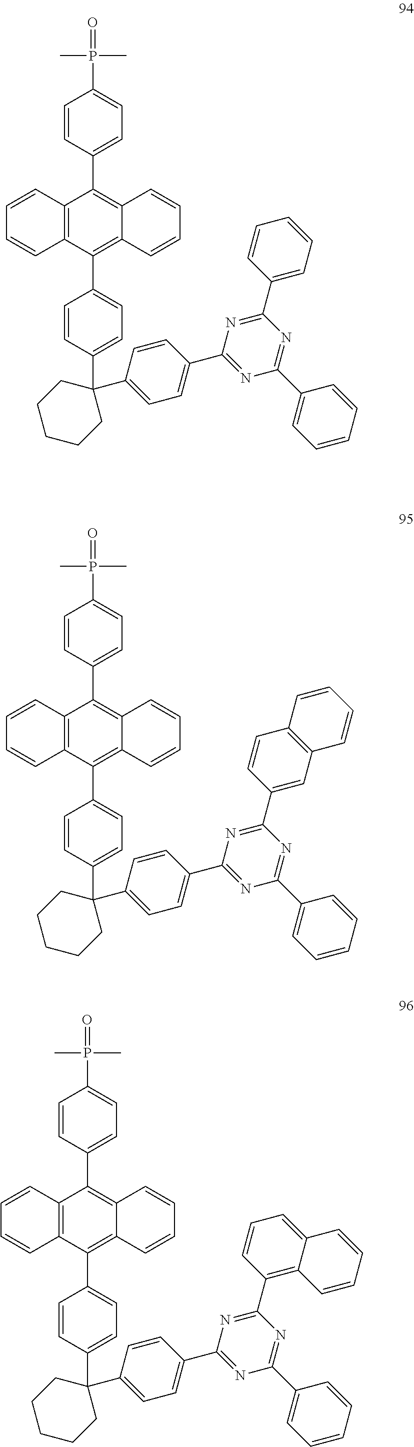 [SMILES: CP(C)(=O)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1]

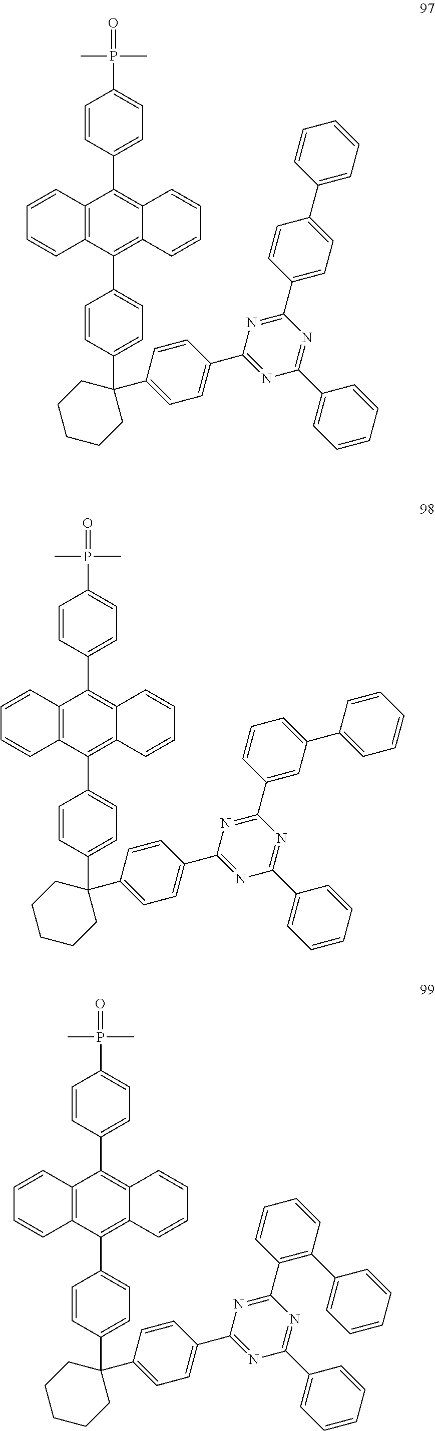 [SMILES: CP(C)(=O)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1]

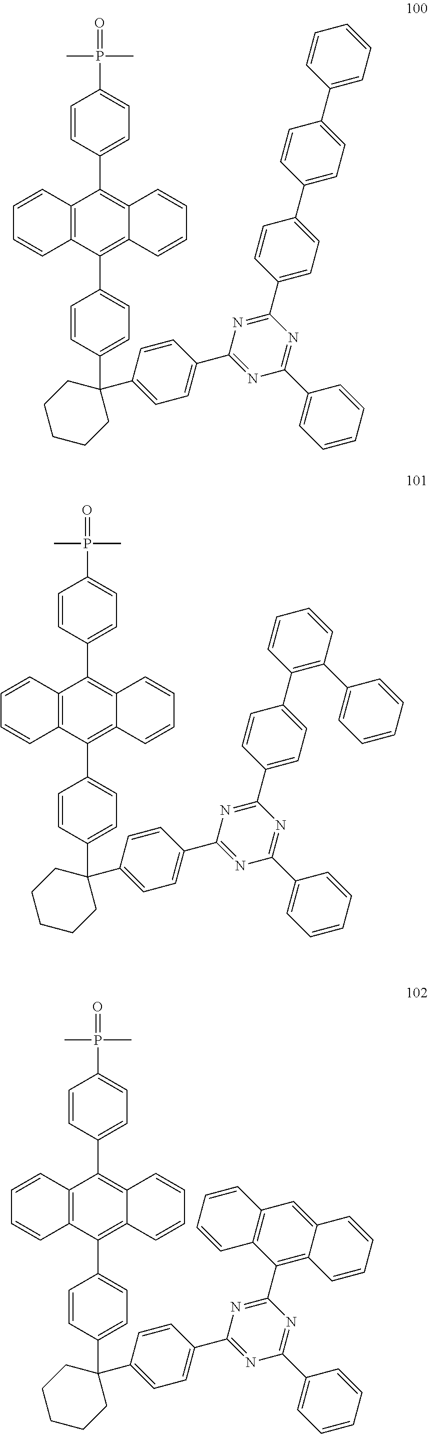 [SMILES: CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)CCCCC4)cc3)c3ccccc23)cc1]

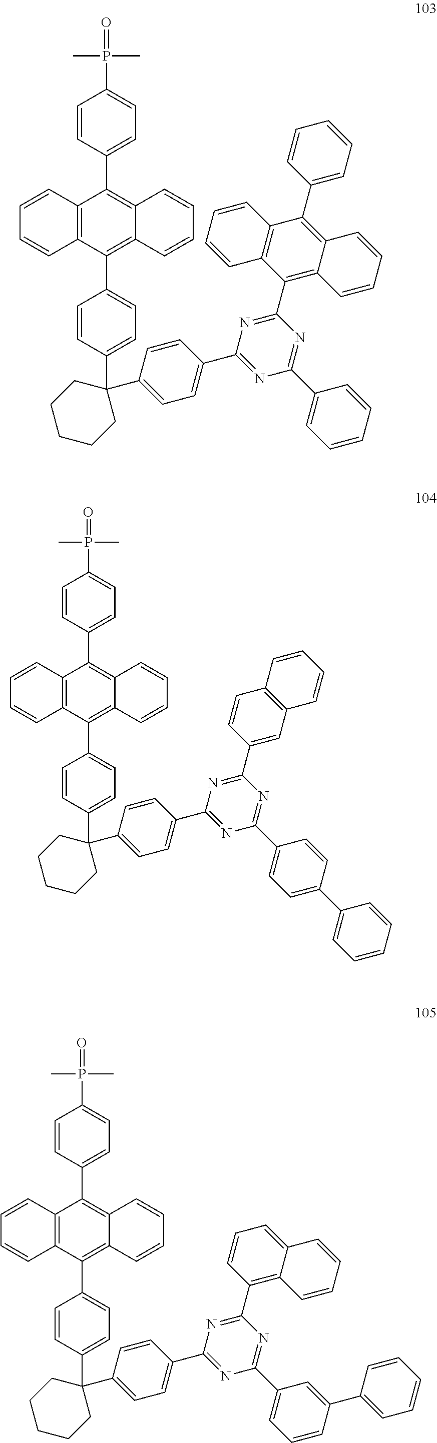 [SMILES: CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1]

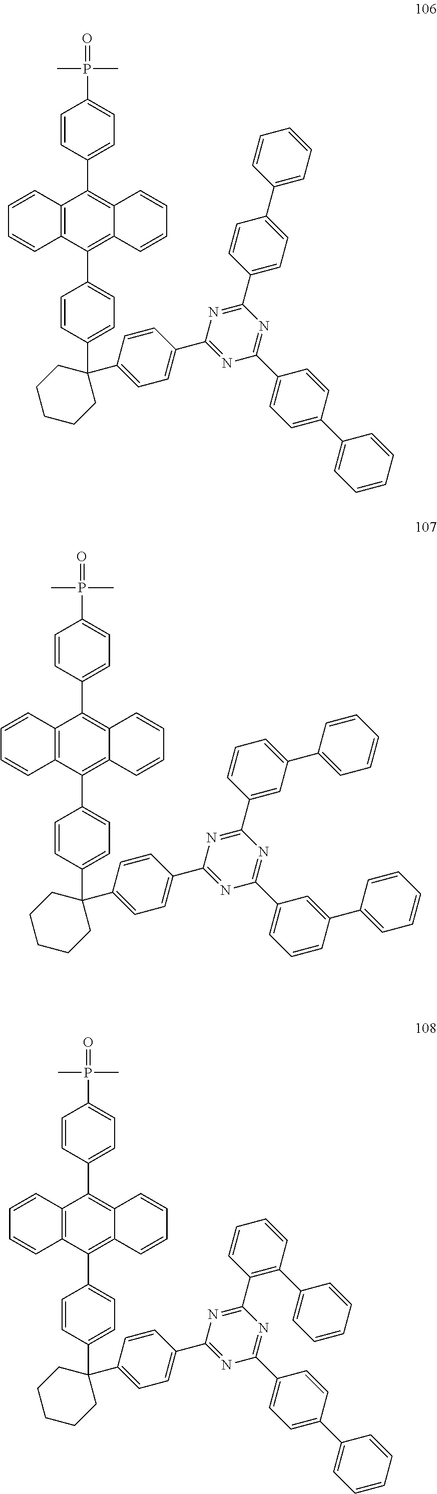 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

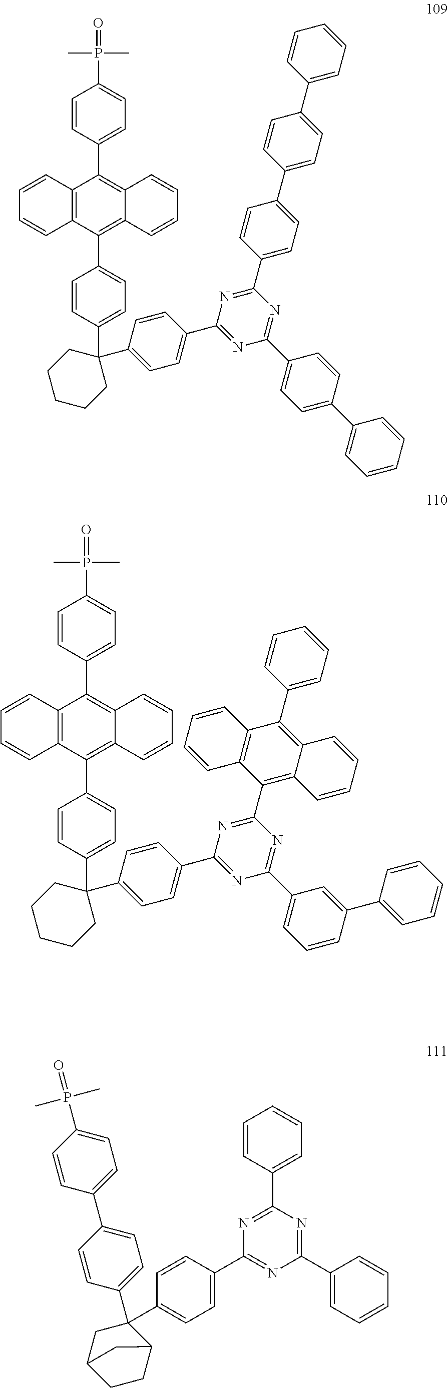 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CCCCC4)cc3)c3ccccc23)cc1 ; CP(C)(=O)c1ccc(-c2ccc(C3(c4ccc(-c5nc(-c6ccccc6)nc(-c6ccccc6)n5)cc4)CC4CCC3C4)cc2)cc1]

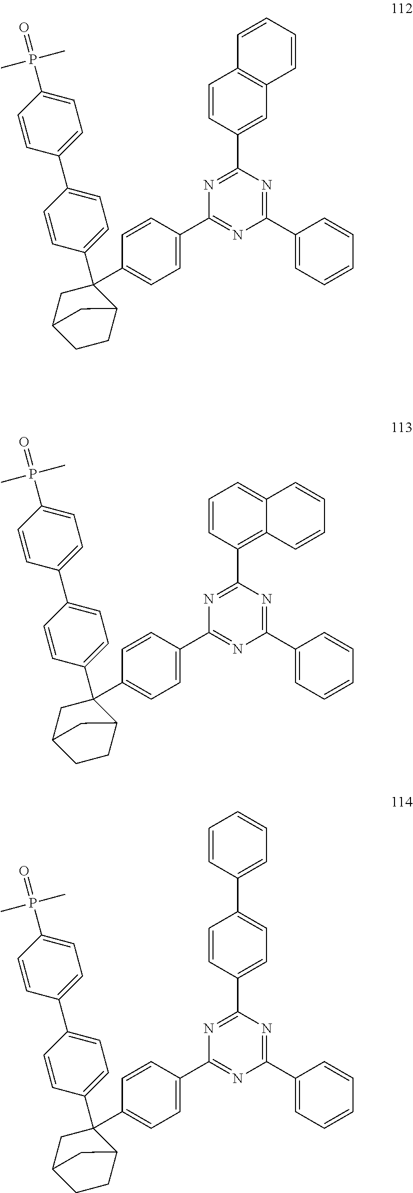 [SMILES: CP(C)(=O)c1ccc(-c2ccc(C3(c4ccc(-c5nc(-c6ccccc6)nc(-c6ccc7ccccc7c6)n5)cc4)CC4CCC3C4)cc2)cc1 ; CP(C)(=O)c1ccc(-c2ccc(C3(c4ccc(-c5nc(-c6ccccc6)nc(-c6cccc7ccccc67)n5)cc4)CC4CCC3C4)cc2)cc1 ; CP(C)(=O)c1ccc(-c2ccc(C3(c4ccc(-c5nc(-c6ccccc6)nc(-c6ccc(-c7ccccc7)cc6)n5)cc4)CC4CCC3C4)cc2)cc1]

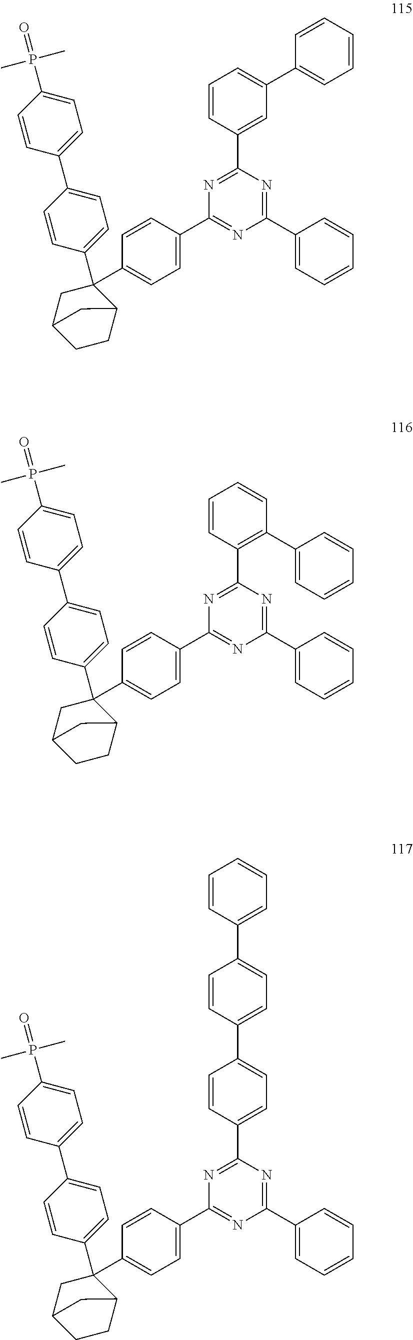 [SMILES: CP(C)(=O)c1ccc(-c2ccc(C3(c4ccc(-c5nc(-c6ccccc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)cc1]

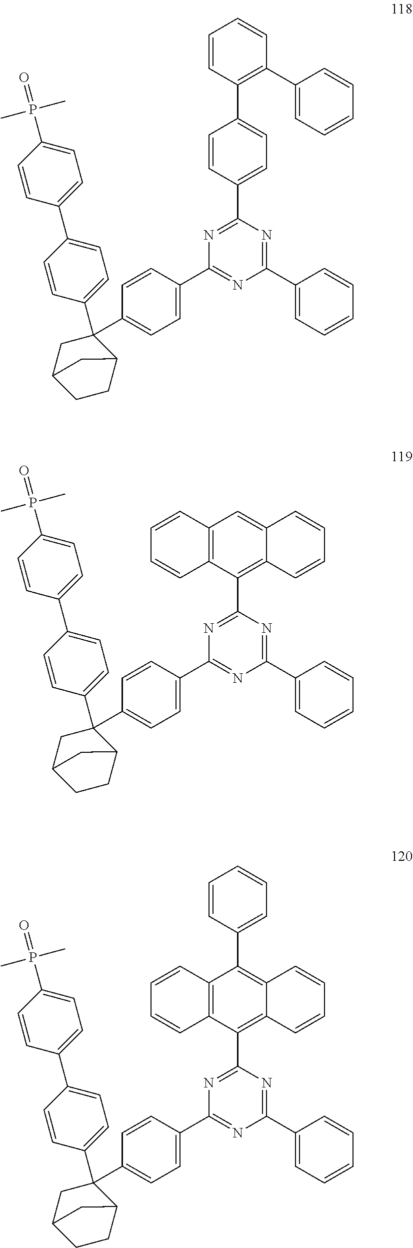 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)CC4CCC3C4)cc2)cc1 ; CP(C)(=O)c1ccc(-c2ccc(C3(c4ccc(-c5nc(-c6ccccc6)nc(-c6c7ccccc7cc7ccccc67)n5)cc4)CC4CCC3C4)cc2)cc1 ; CP(C)(=O)c1ccc(-c2ccc(C3(c4ccc(-c5nc(-c6ccccc6)nc(-c6c7ccccc7c(-c7ccccc7)c7ccccc67)n5)cc4)CC4CCC3C4)cc2)cc1]

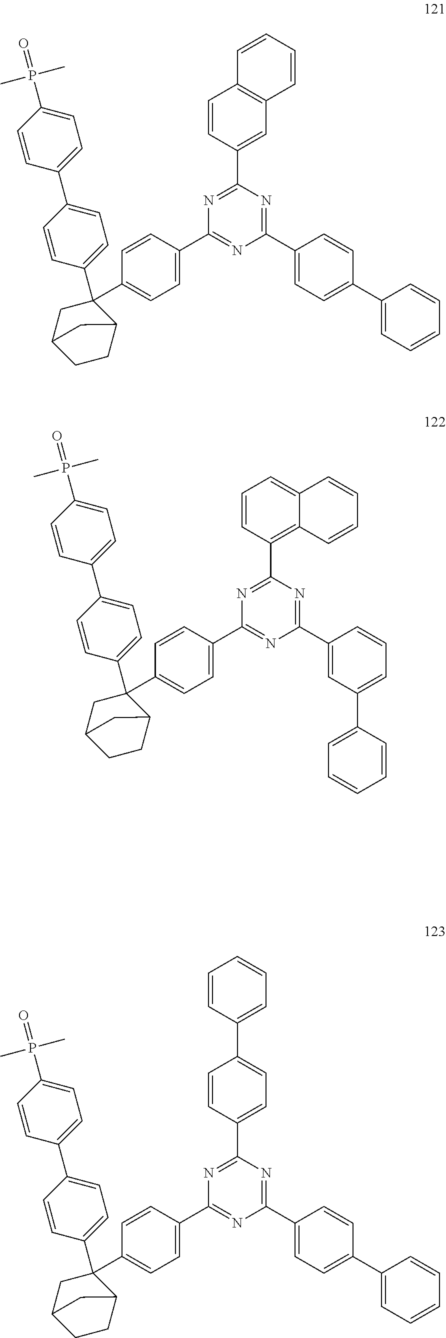 [SMILES: CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)cc1]

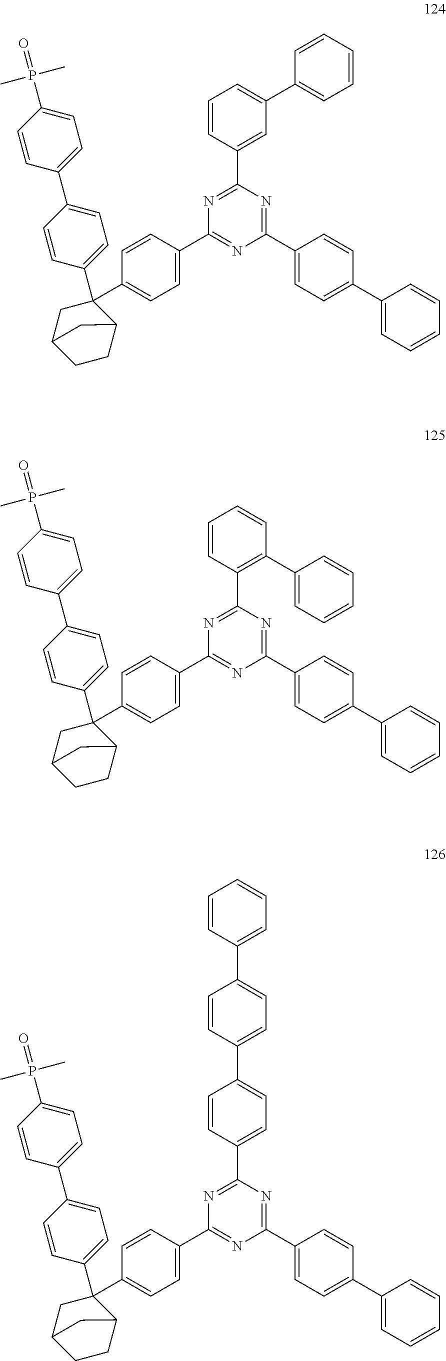 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)cc1]

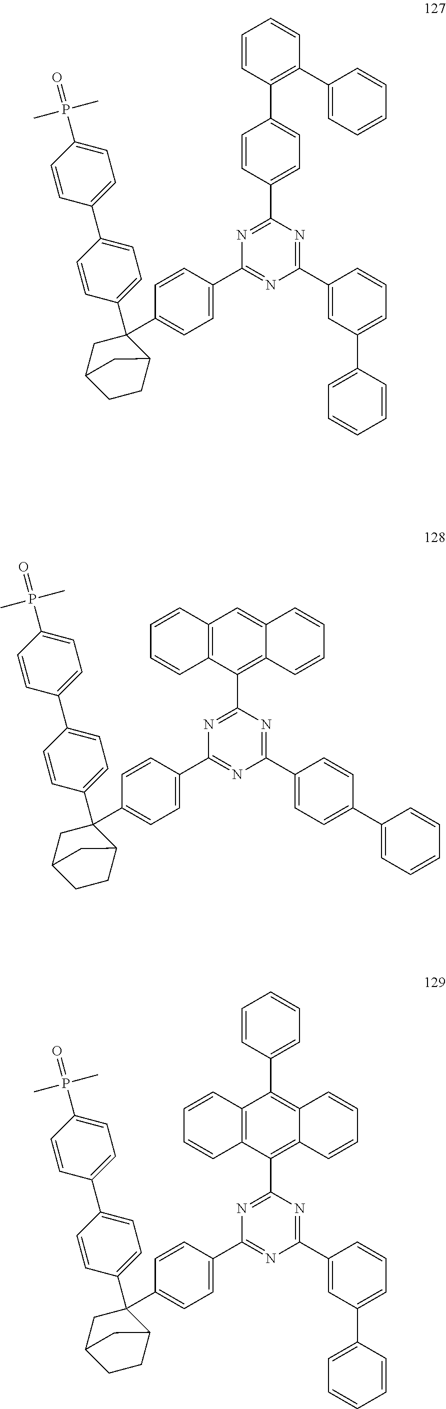 [SMILES: CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)cc1]

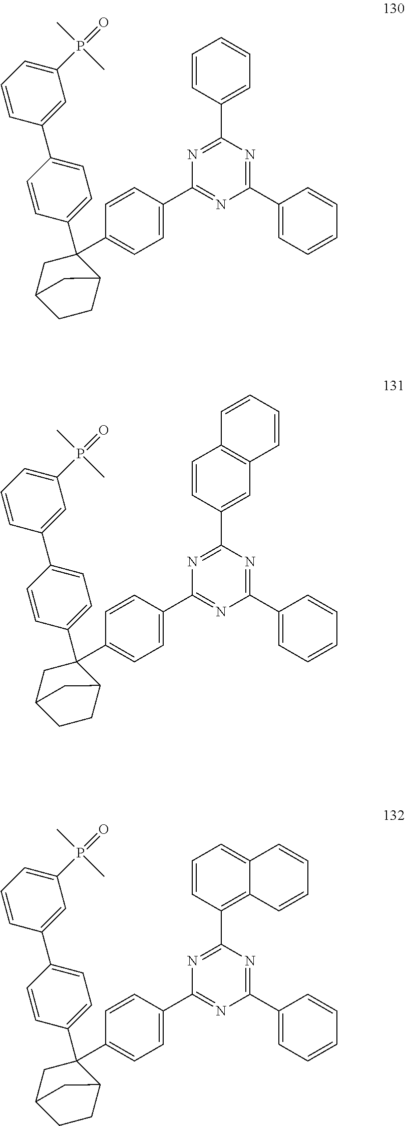 [SMILES: CP(C)(=O)c1cccc(-c2ccc(C3(c4ccc(-c5nc(-c6ccccc6)nc(-c6ccccc6)n5)cc4)CC4CCC3C4)cc2)c1 ; CP(C)(=O)c1cccc(-c2ccc(C3(c4ccc(-c5nc(-c6ccccc6)nc(-c6ccc7ccccc7c6)n5)cc4)CC4CCC3C4)cc2)c1 ; CP(C)(=O)c1cccc(-c2ccc(C3(c4ccc(-c5nc(-c6ccccc6)nc(-c6cccc7ccccc67)n5)cc4)CC4CCC3C4)cc2)c1]

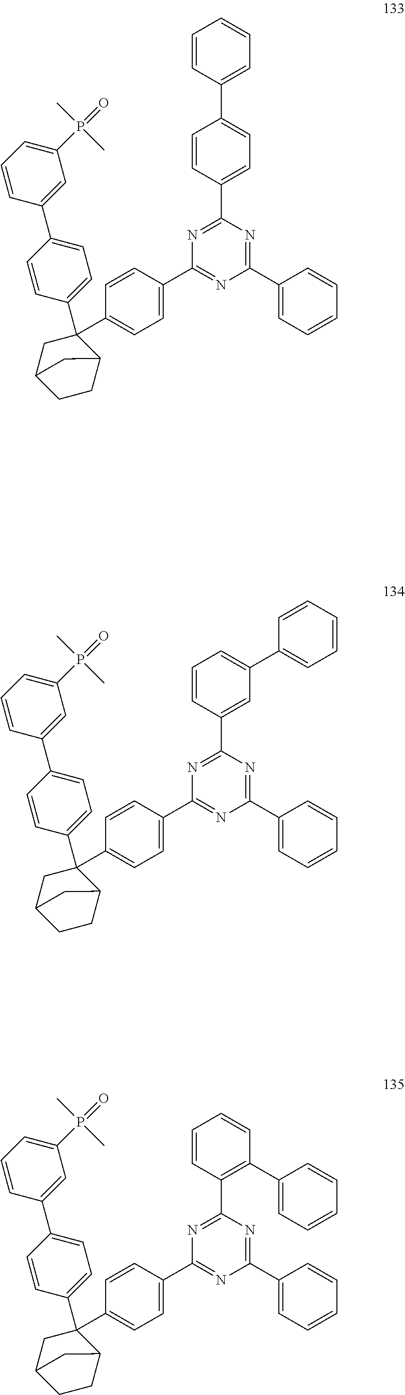 [SMILES: CP(C)(=O)c1cccc(-c2ccc(C3(c4ccc(-c5nc(-c6ccccc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccccc6)nc(-c6ccccc6-c6ccccc6)n5)cc4)CC4CCC3C4)cc2)c1]

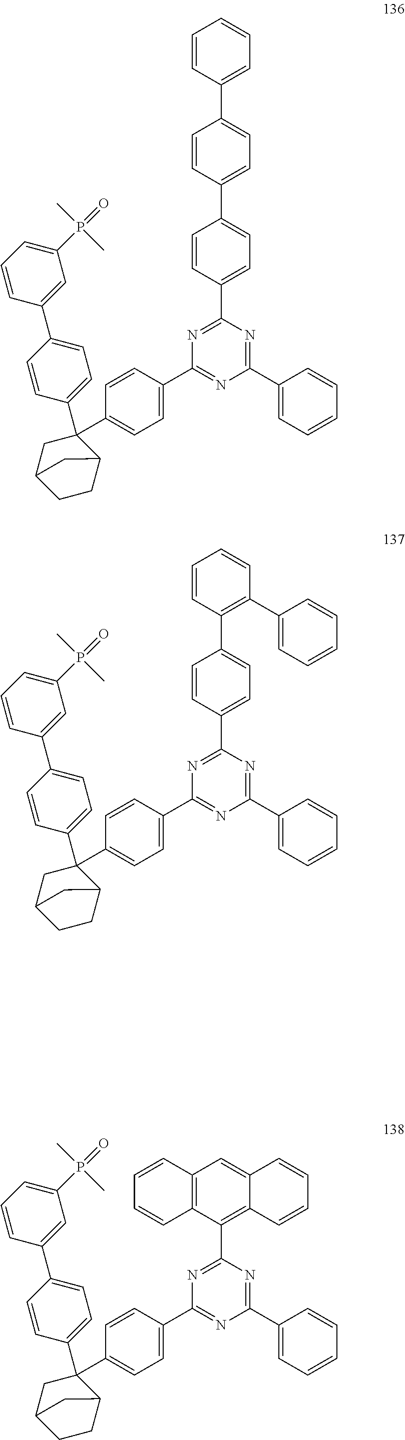 [SMILES: CP(C)(=O)c1cccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6c7ccccc7cc7ccccc67)n5)cc4)CC4CCC3C4)cc2)c1]

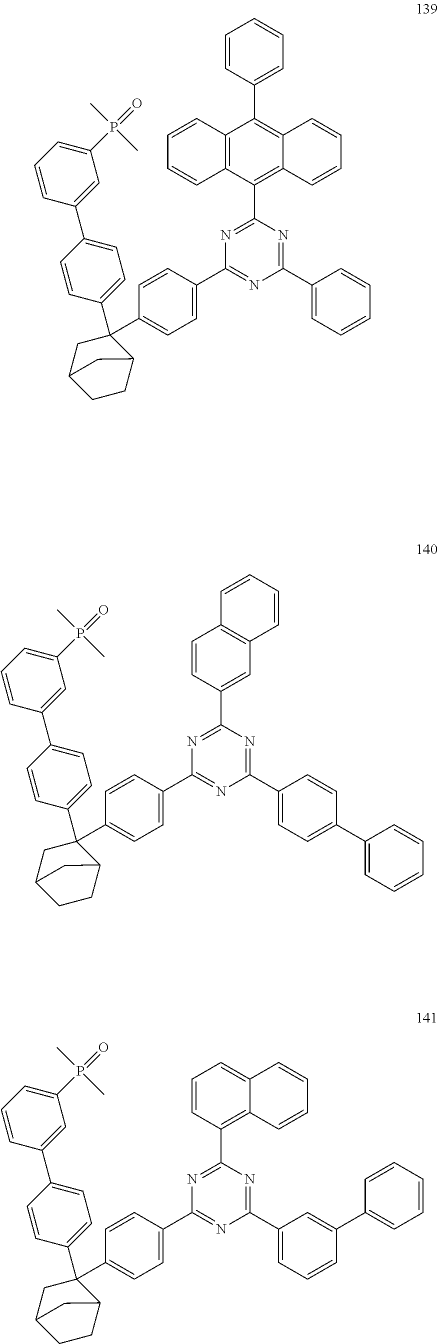 [SMILES: CP(C)(=O)c1cccc(-c2ccc(C3(c4ccc(-c5nc(-c6ccccc6)nc(-c6c7ccccc7c(-c7ccccc7)c7ccccc67)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc7ccccc67)n5)cc4)CC4CCC3C4)cc2)c1]

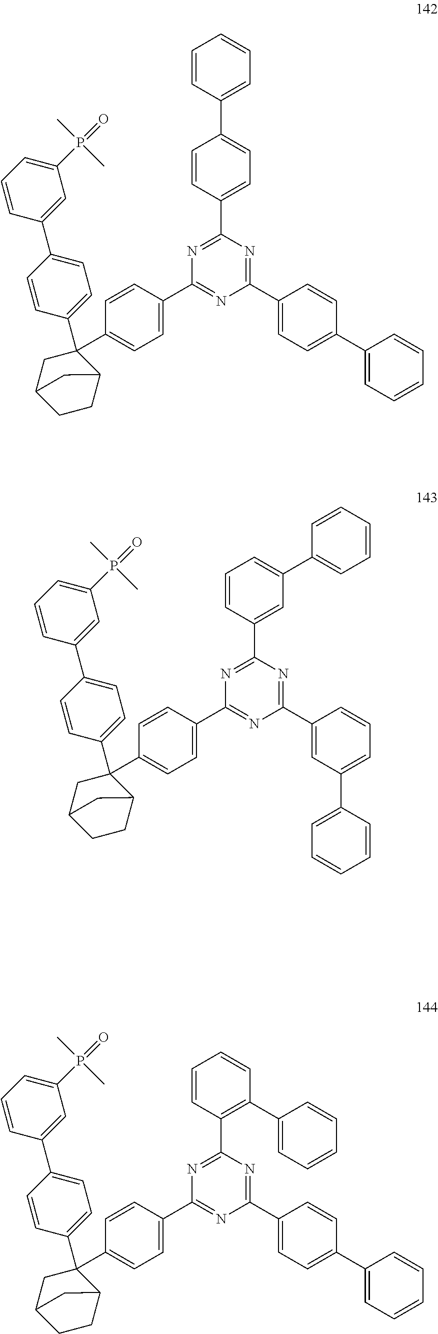 [SMILES: CP(C)(=O)c1cccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccccc6-c6ccccc6)n5)cc4)CC4CCC3C4)cc2)c1]

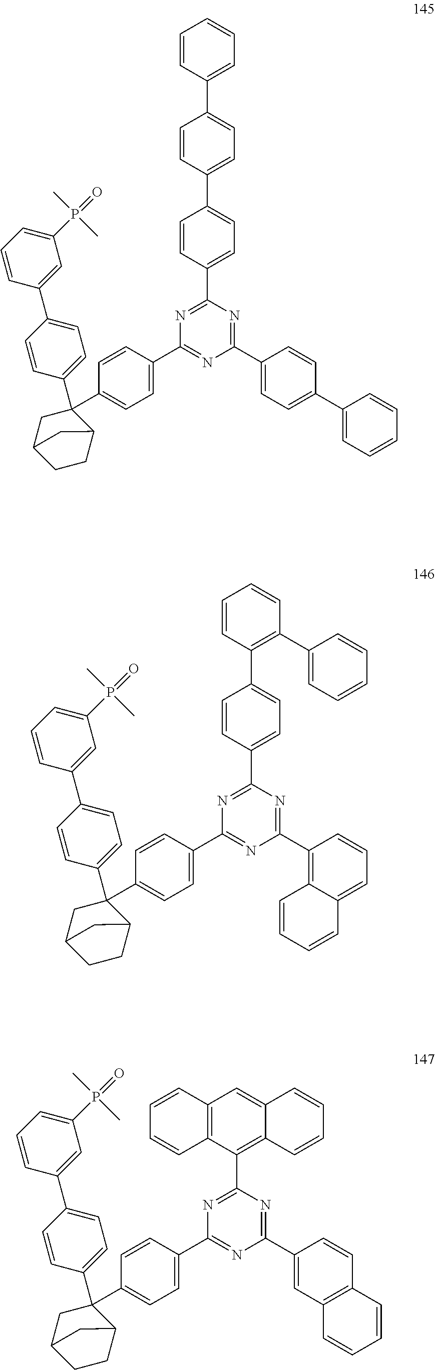 [SMILES: CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CC4CCC3C4)cc2)c1 ; CP(C)(=O)c1cccc(-c2ccc(C3(c4ccc(-c5nc(-c6ccc7ccccc7c6)nc(-c6c7ccccc7cc7ccccc67)n5)cc4)CC4CCC3C4)cc2)c1]

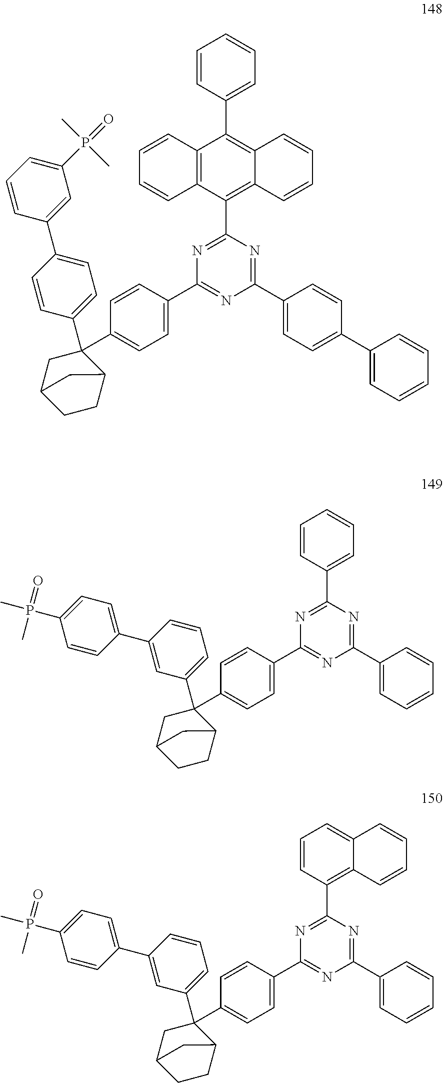 [SMILES: CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CC4CCC3C4)cc2)c1 ; CP(C)(=O)c1ccc(-c2cccc(C3(c4ccc(-c5nc(-c6ccccc6)nc(-c6ccccc6)n5)cc4)CC4CCC3C4)c2)cc1 ; CP(C)(=O)c1ccc(-c2cccc(C3(c4ccc(-c5nc(-c6ccccc6)nc(-c6cccc7ccccc67)n5)cc4)CC4CCC3C4)c2)cc1]

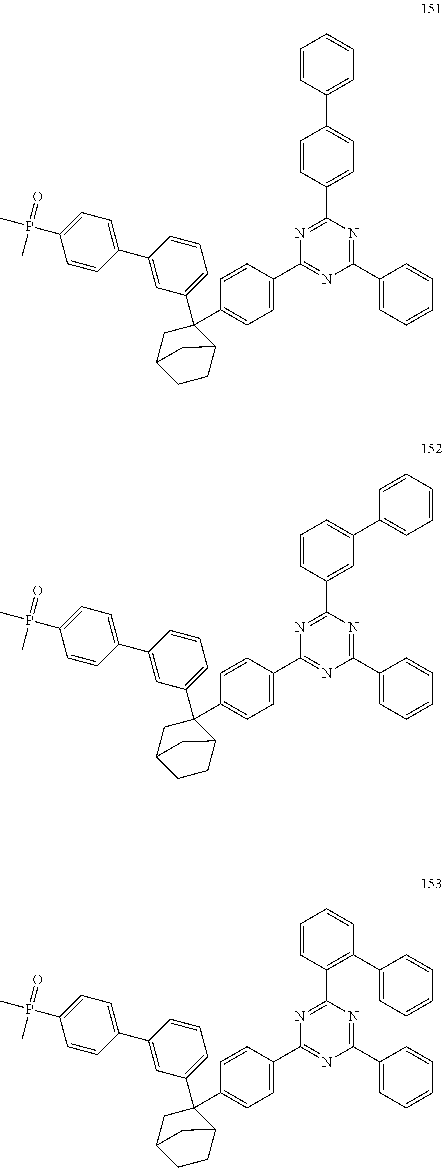 [SMILES: CP(C)(=O)c1ccc(-c2cccc(C3(c4ccc(-c5nc(-c6ccccc6)nc(-c6ccc(-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccccc6)nc(-c6ccccc6-c6ccccc6)n5)cc4)CC4CCC3C4)c2)cc1]

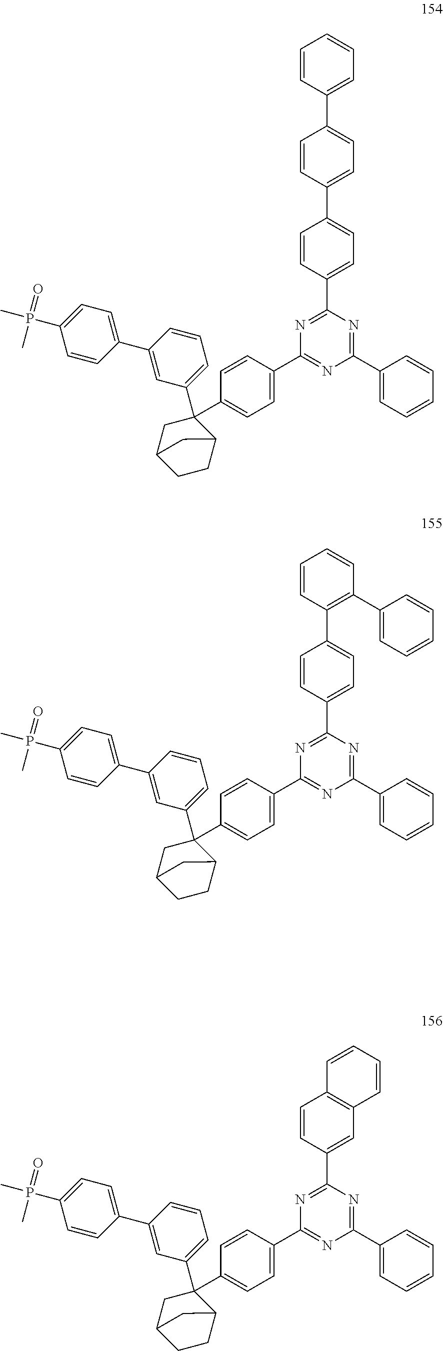 [SMILES: CP(C)(=O)c1ccc(-c2cccc(C3(c4ccc(-c5nc(-c6ccccc6)nc(-c6ccc(-c7ccc(-c8ccccc8)cc7)cc6)n5)cc4)CC4CCC3C4)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6ccc7ccccc7c6)n5)cc4)CC4CCC3C4)c2)cc1]

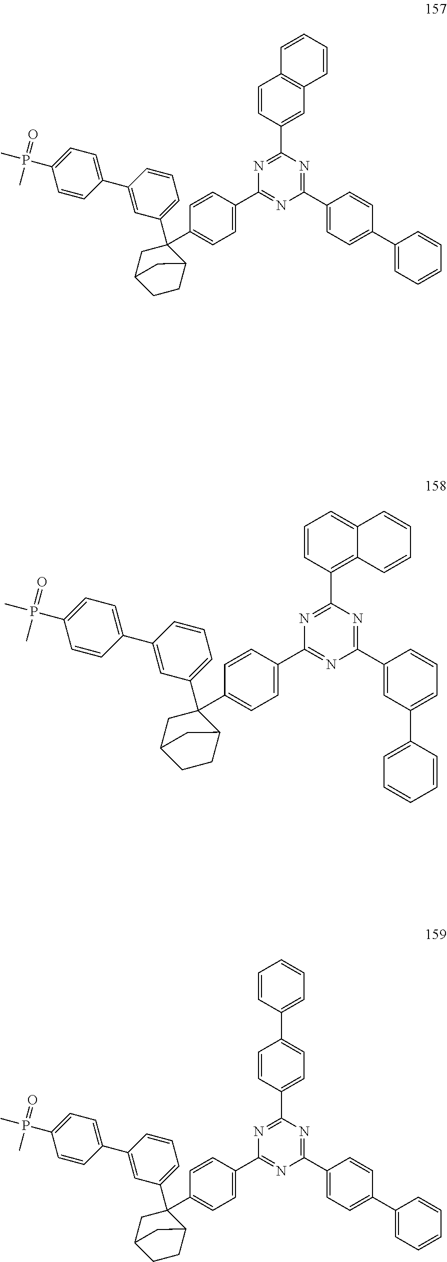 [SMILES: CP(C)(=O)c1ccc(-c2cccc(C3(c4ccc(-c5nc(-c6ccc(-c7ccccc7)cc6)nc(-c6ccc7ccccc7c6)n5)cc4)CC4CCC3C4)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)CC4CCC3C4)c2)cc1]

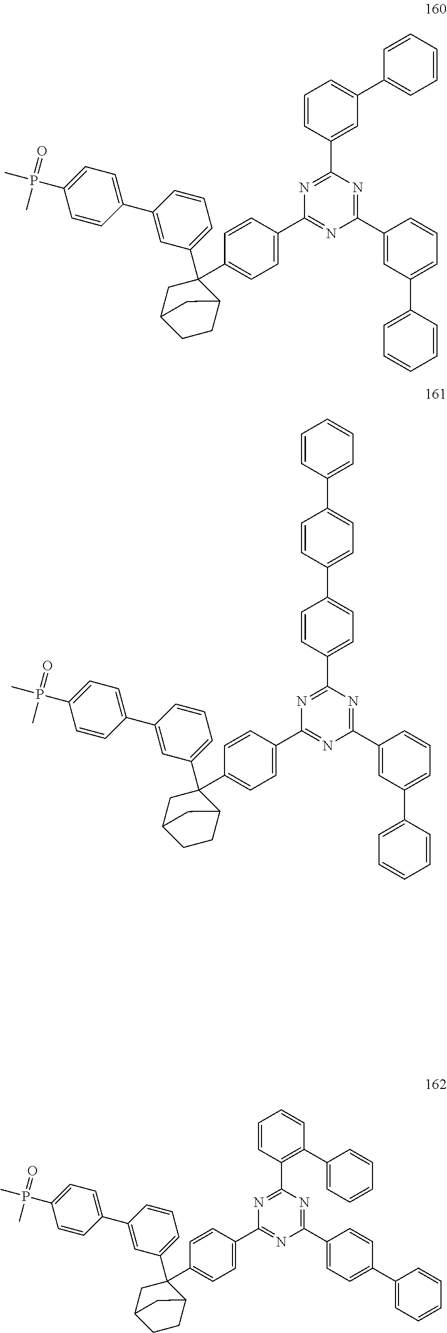 [SMILES: CP(C)(=O)c1ccc(-c2cccc(C3(c4ccc(-c5nc(-c6cccc(-c7ccccc7)c6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)CC4CCC3C4)c2)cc1]

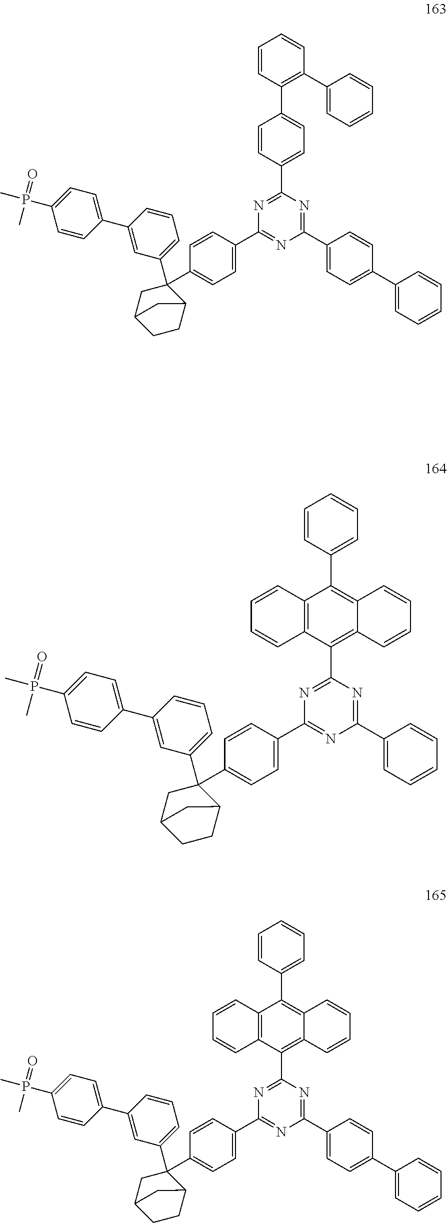 [SMILES: CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6c7ccccc7c(-c7ccccc7)c7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CC4CCC3C4)c2)cc1]

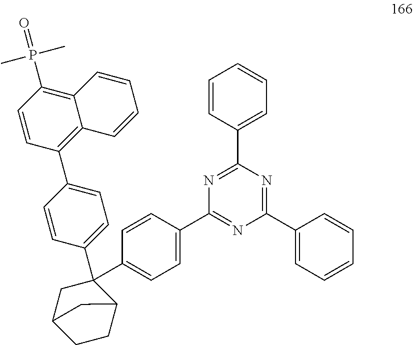 [SMILES: CP(C)(=O)c1ccc(-c2ccc(C3(c4ccc(-c5nc(-c6ccccc6)nc(-c6ccccc6)n5)cc4)CC4CCC3C4)cc2)c2ccccc12]

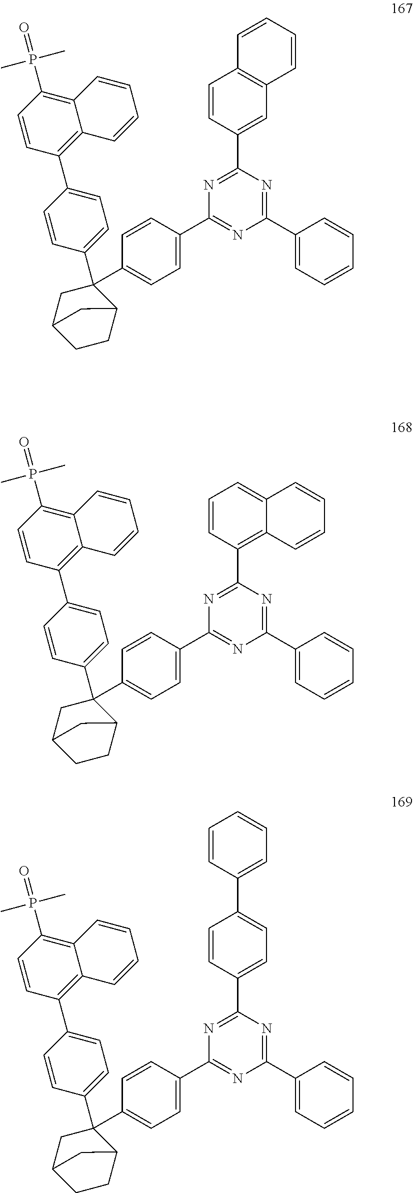 [SMILES: CP(C)(=O)c1ccc(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6ccccc6)nc(-c6cccc7ccccc67)n5)cc4)CC4CCC3C4)cc2)c2ccccc12 ; CP(C)(=O)c1ccc(-c2ccc(C3(c4ccc(-c5nc(-c6ccccc6)nc(-c6ccc(-c7ccccc7)cc6)n5)cc4)CC4CCC3C4)cc2)c2ccccc12]

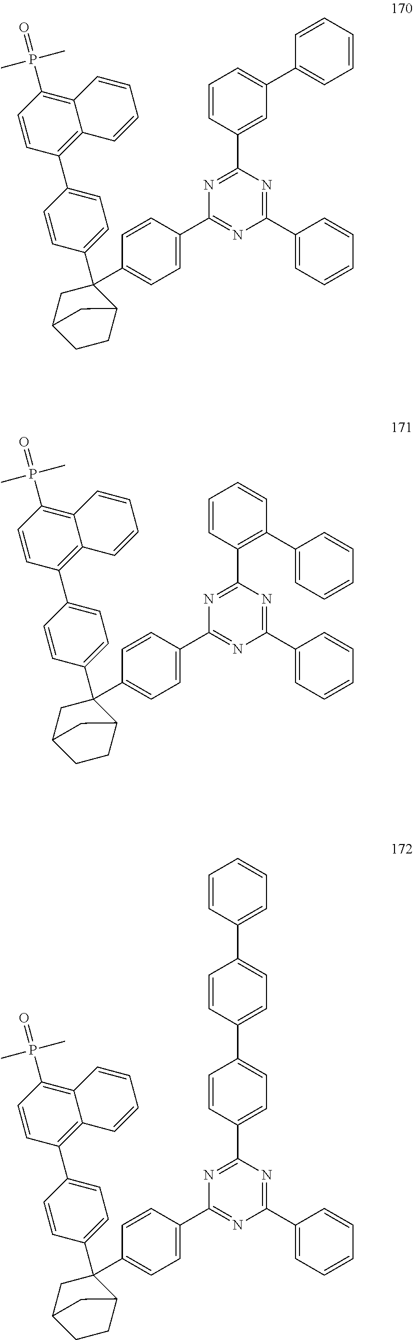 [SMILES: CP(C)(=O)c1ccc(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)c2ccccc12 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12]

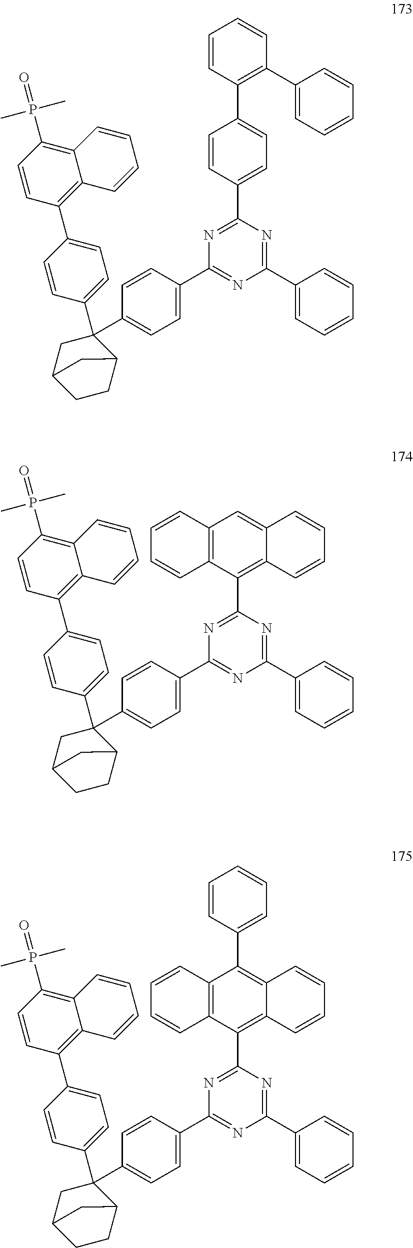 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CC4CCC3C4)cc2)c2ccccc12 ; CP(C)(=O)c1ccc(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12]

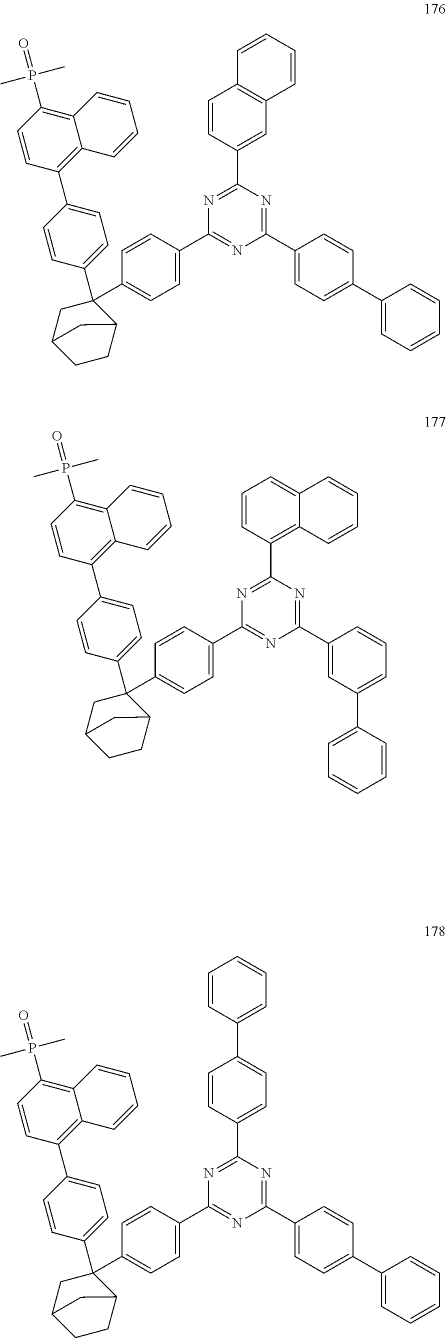 [SMILES: CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12]

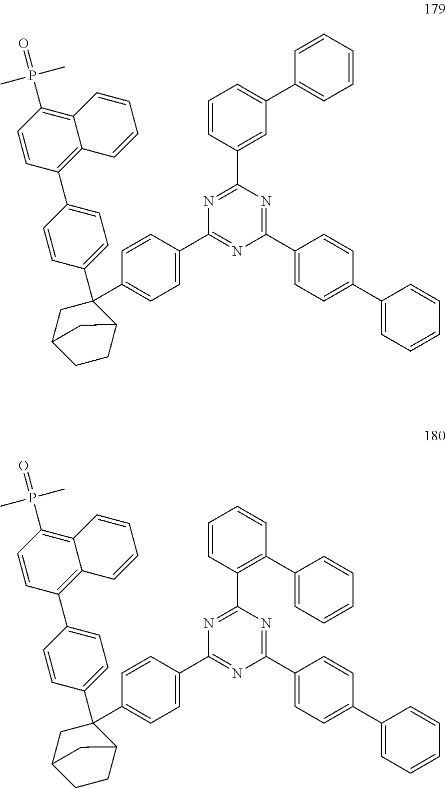 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12]

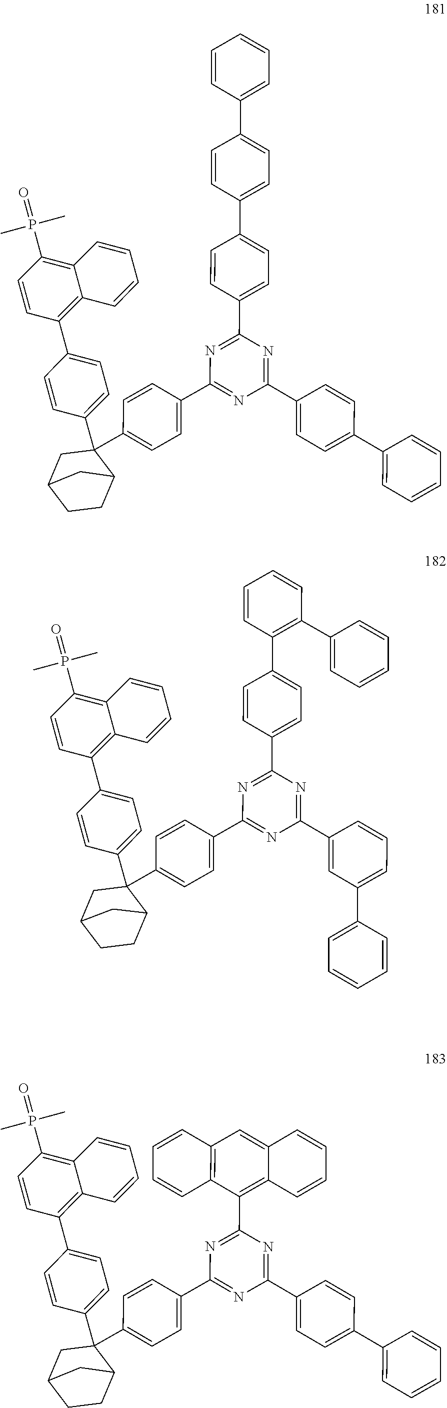 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12]

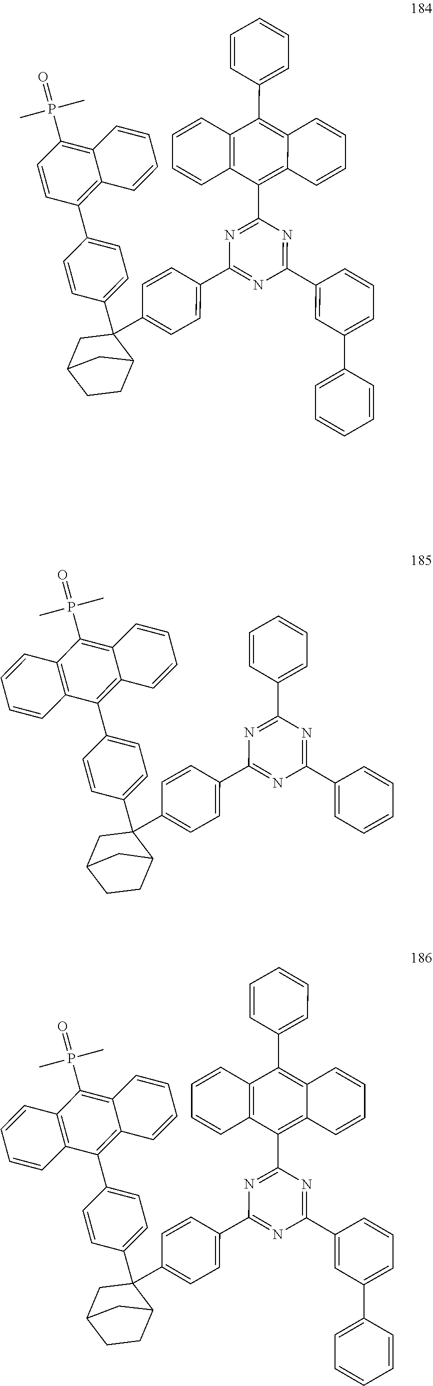 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12]

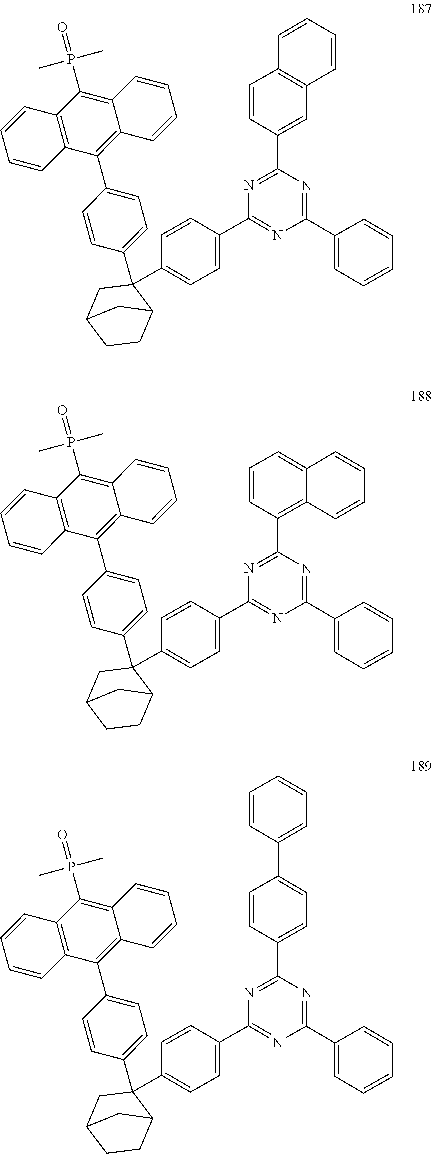 [SMILES: CP(C)(=O)c1c2ccccc2c(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccccc7)cc6)n5)cc4)CC4CCC3C4)cc2)c2ccccc12]

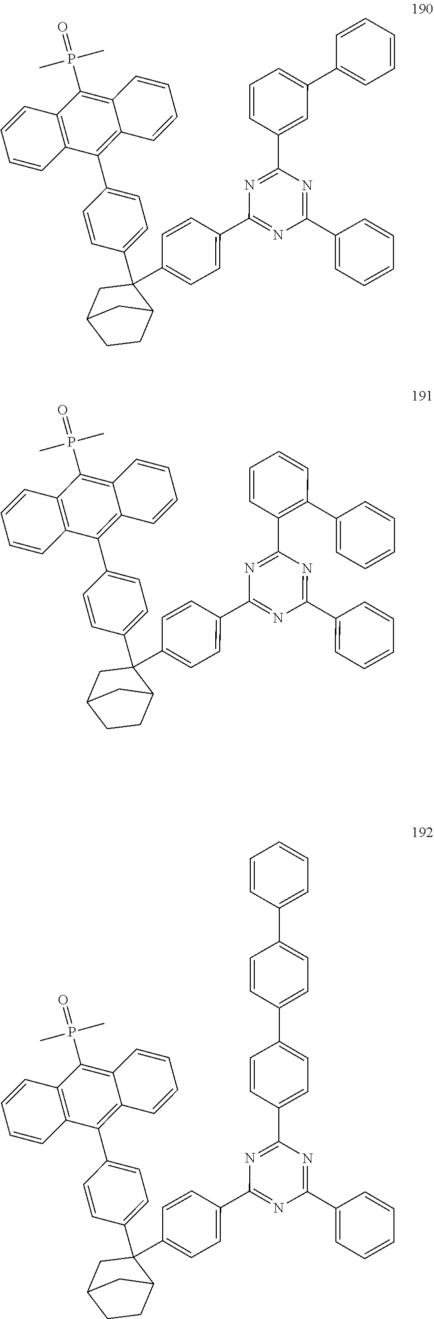 [SMILES: CP(C)(=O)c1c2ccccc2c(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12]

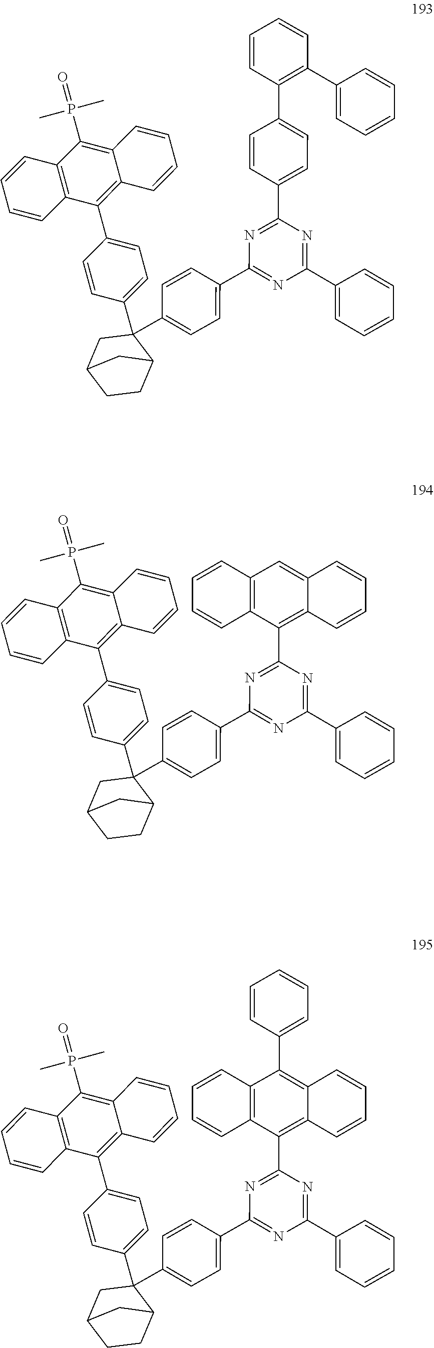 [SMILES: CP(C)(=O)c1c2ccccc2c(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12]

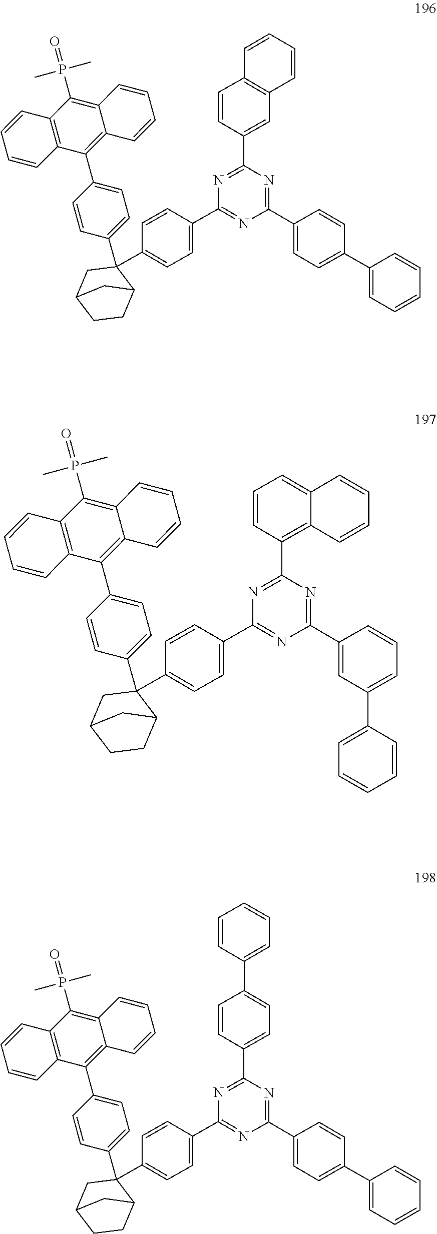 [SMILES: CP(C)(=O)c1c2ccccc2c(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12]

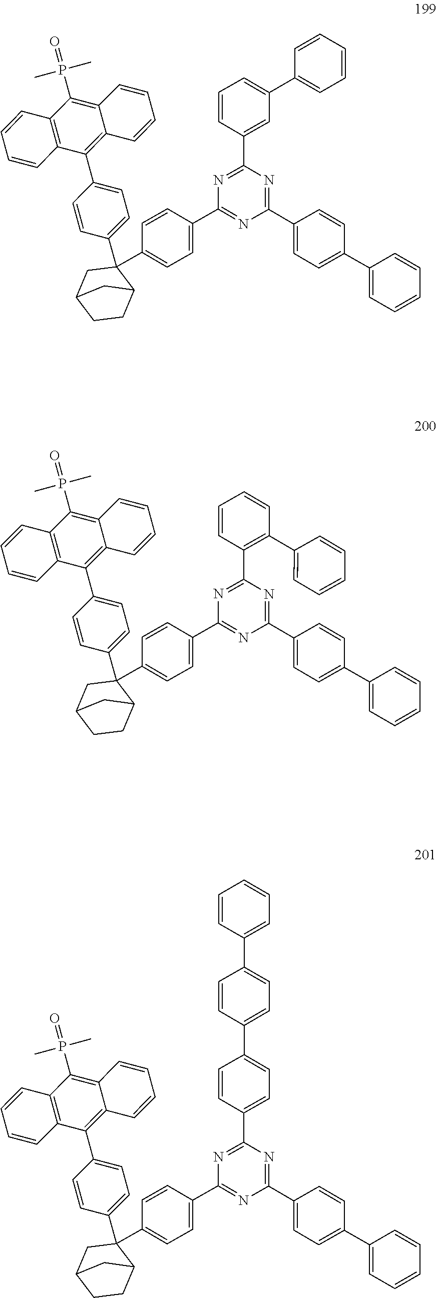 [SMILES: CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12]

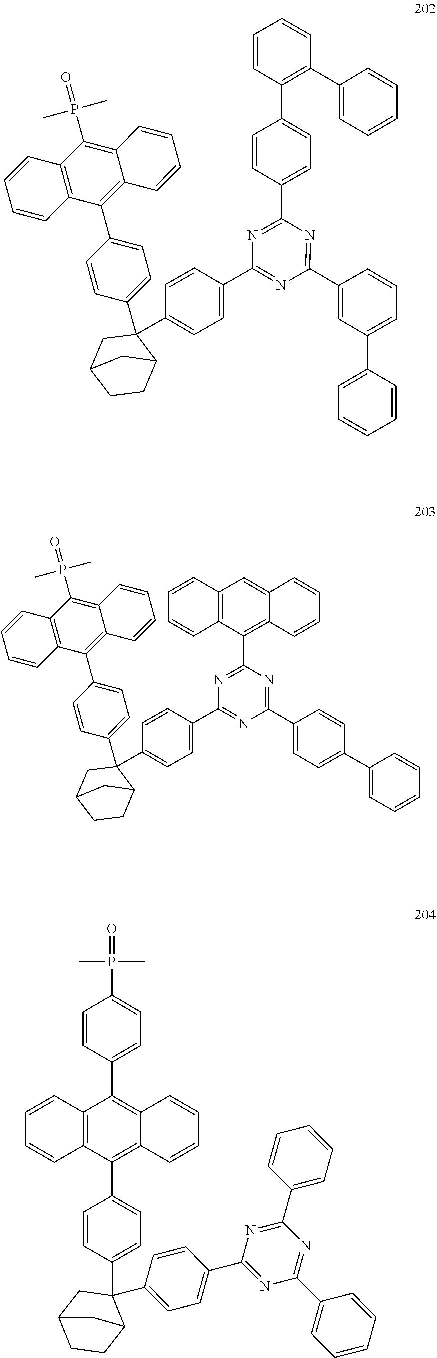 [SMILES: CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12 ; CP(C)(=O)c1ccc(-c2c3ccccc3c(-c3ccc(C4(c5ccc(-c6nc(-c7ccccc7)nc(-c7ccccc7)n6)cc5)CC5CCC4C5)cc3)c3ccccc23)cc1]

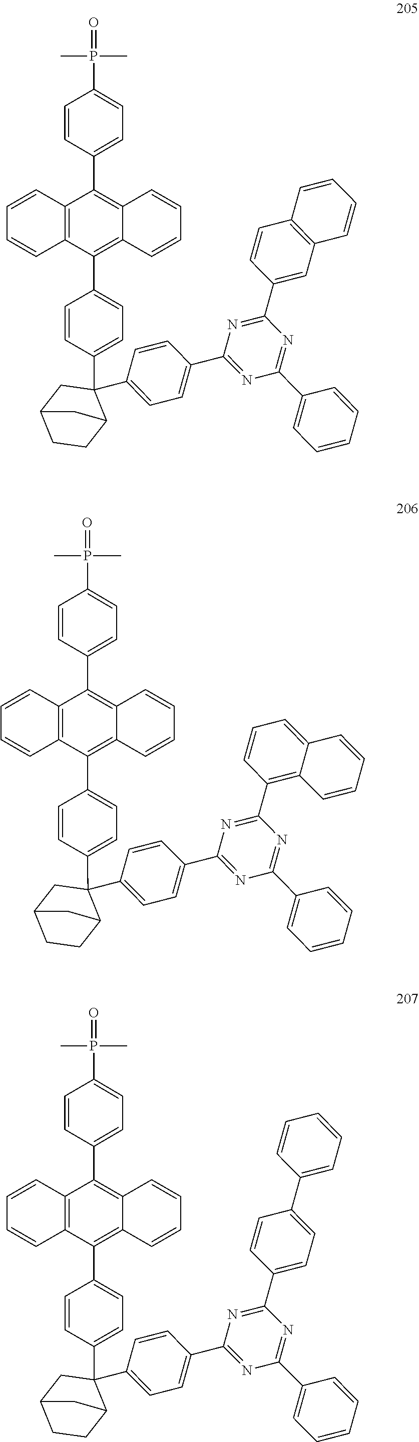 [SMILES: CP(C)(=O)c1ccc(-c2c3ccccc3c(-c3ccc(C4(c5ccc(-c6nc(-c7ccccc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8)cc7)n6)cc5)CC5CCC4C5)cc3)c3ccccc23)cc1]

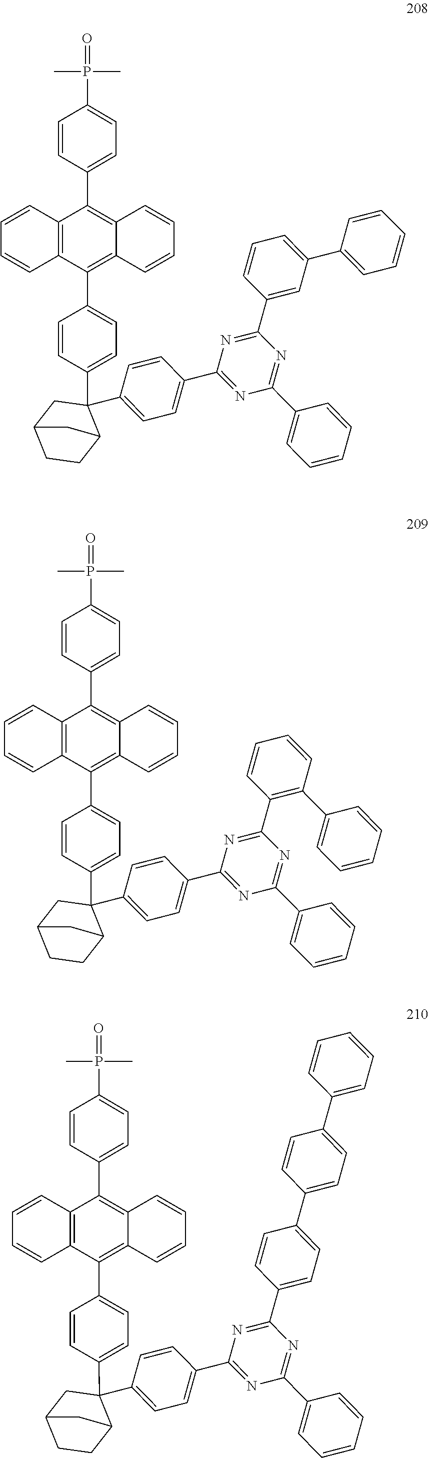 [SMILES: CP(C)(=O)c1ccc(-c2c3ccccc3c(-c3ccc(C4(c5ccc(-c6nc(-c7ccccc7)nc(-c7cccc(-c8ccccc8)c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CC5CCC4C5)cc3)c3ccccc23)cc1]

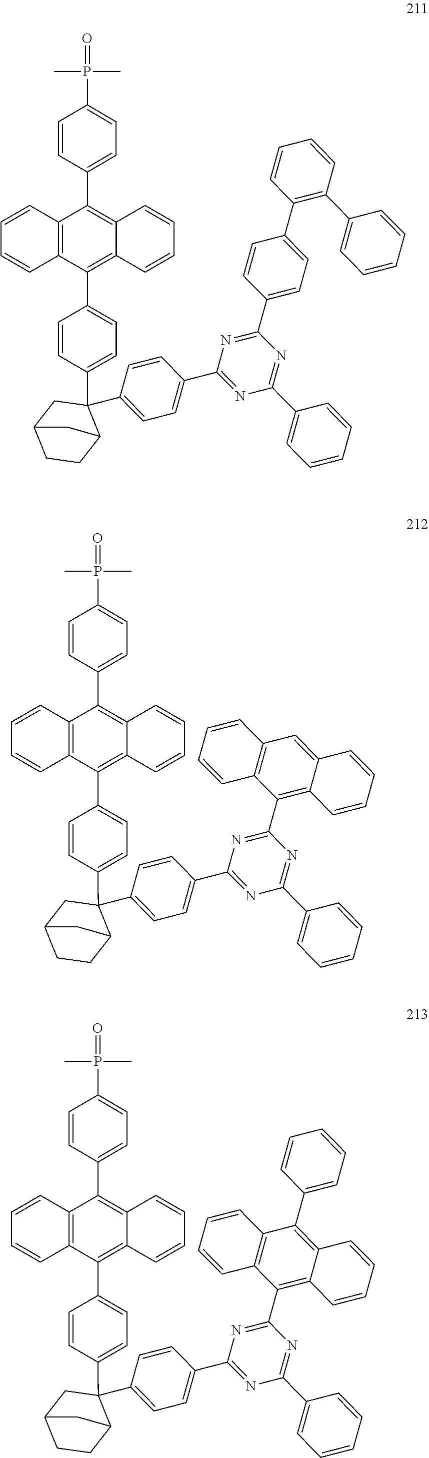 [SMILES: CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CC5CCC4C5)cc3)c3ccccc23)cc1]

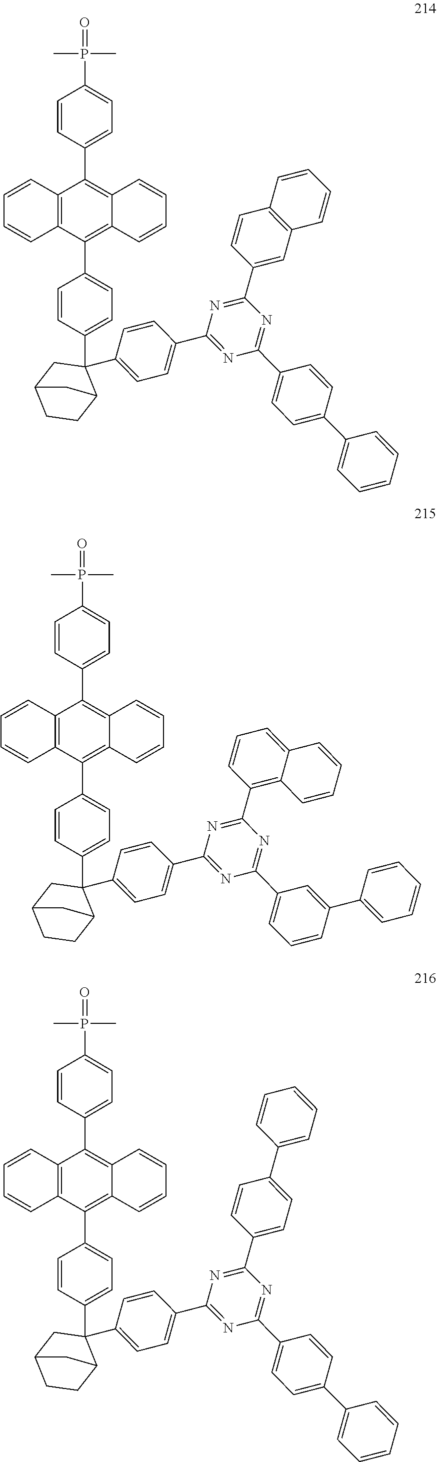 [SMILES: CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CC5CCC4C5)cc3)c3ccccc23)cc1]

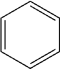

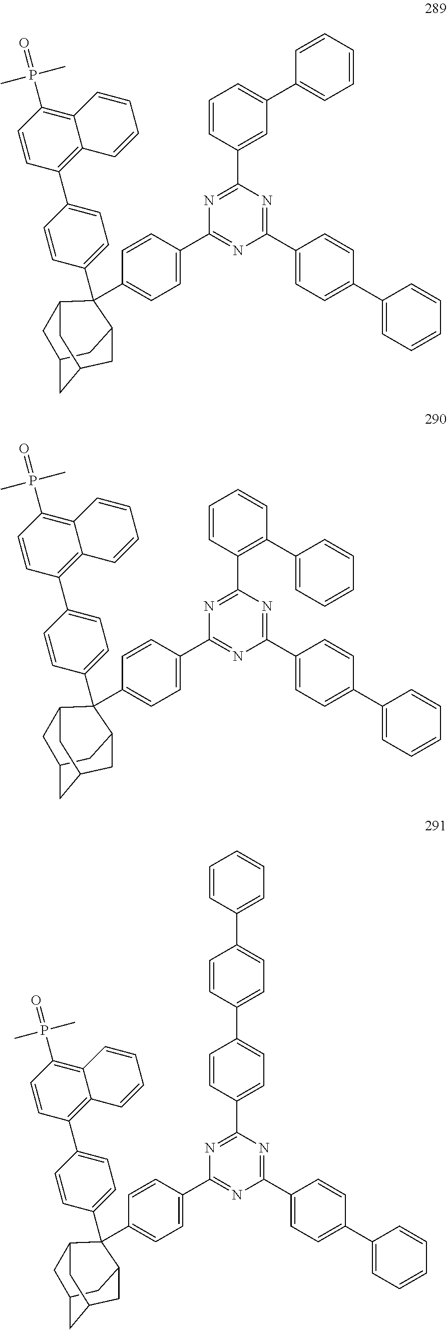 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c2ccccc12]

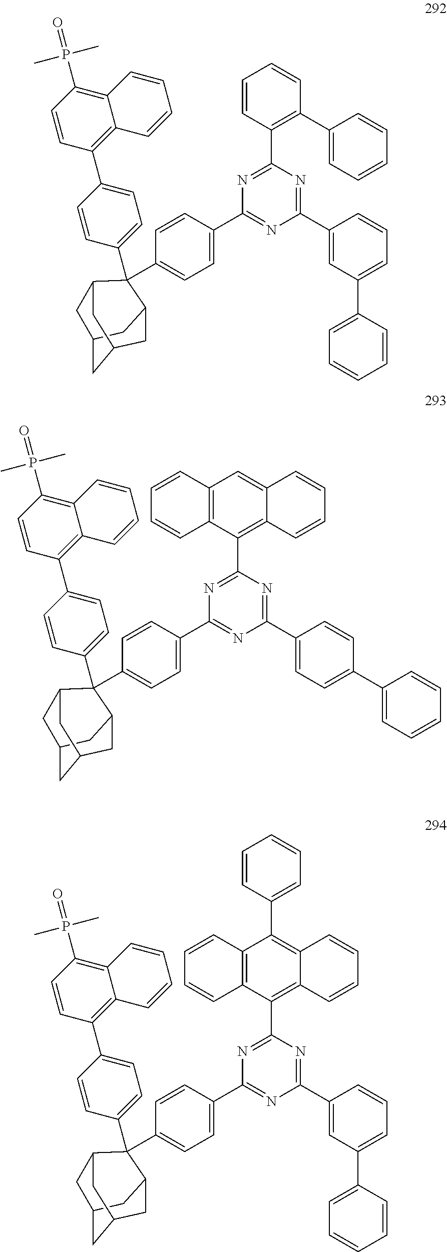 [SMILES: CP(C)(=O)c1ccc(-c2ccc(C3(c4ccc(-c5nc(-c6cccc(-c7ccccc7)c6)nc(-c6ccccc6-c6ccccc6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)c2ccccc12 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)c2ccccc12]

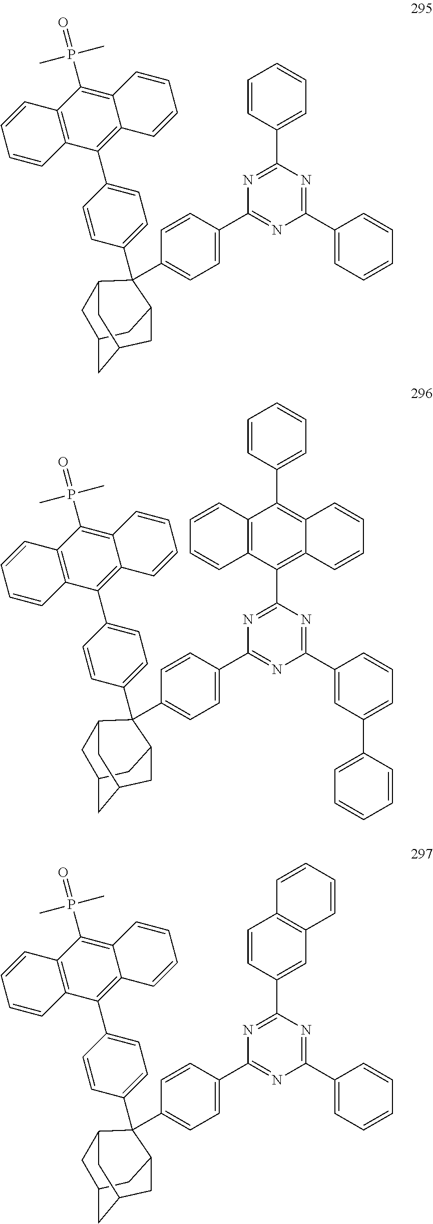 [SMILES: CP(C)(=O)c1c2ccccc2c(-c2ccc(C3(c4ccc(-c5nc(-c6ccccc6)nc(-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc7ccccc7c6)n5)cc4)C4CC5CC(C4)CC3C5)cc2)c2ccccc12]

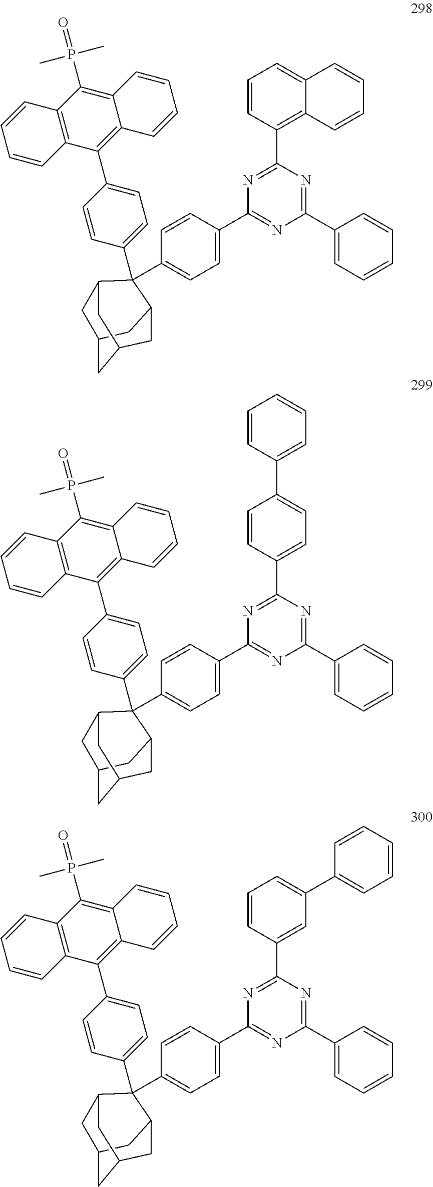 [SMILES: CP(C)(=O)c1c2ccccc2c(-c2ccc(C3(c4ccc(-c5nc(-c6ccccc6)nc(-c6cccc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc(-c7ccccc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6cccc(-c7ccccc7)c6)n5)cc4)C4CC5CC(C4)CC3C5)cc2)c2ccccc12]

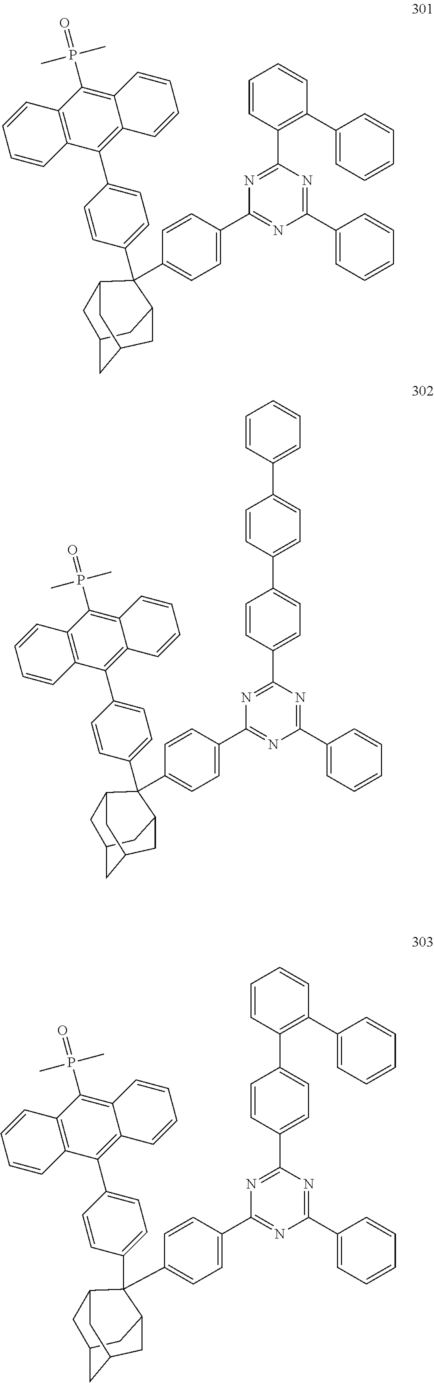 [SMILES: CP(C)(=O)c1c2ccccc2c(-c2ccc(C3(c4ccc(-c5nc(-c6ccccc6)nc(-c6ccccc6-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c2ccccc12]

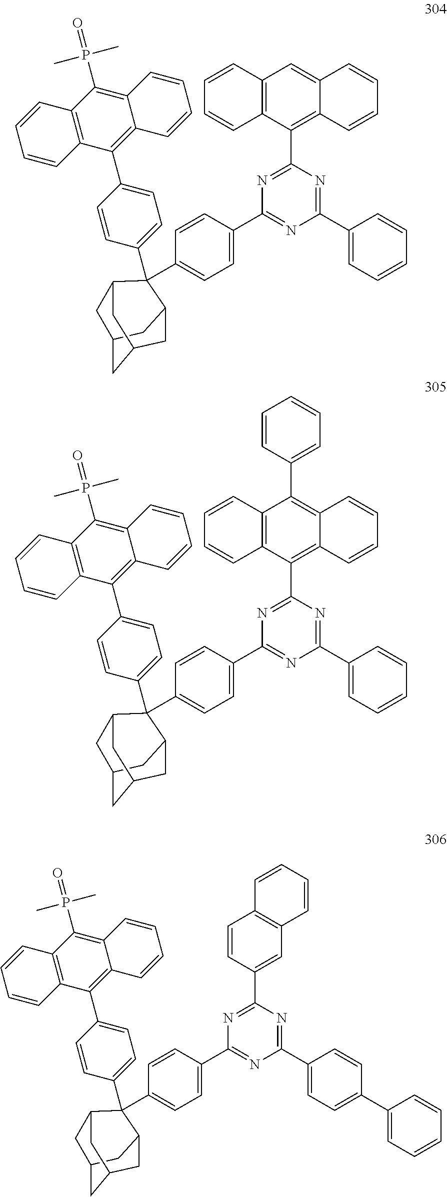 [SMILES: CP(C)(=O)c1c2ccccc2c(-c2ccc(C3(c4ccc(-c5nc(-c6ccccc6)nc(-c6c7ccccc7cc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c2ccccc12]

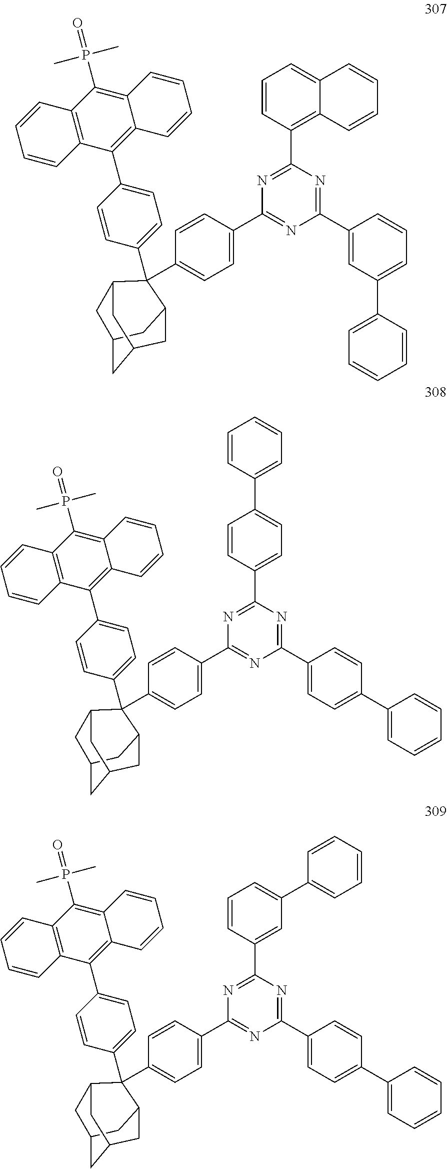 [SMILES: CP(C)(=O)c1c2ccccc2c(-c2ccc(C3(c4ccc(-c5nc(-c6cccc(-c7ccccc7)c6)nc(-c6cccc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)c2ccccc12]

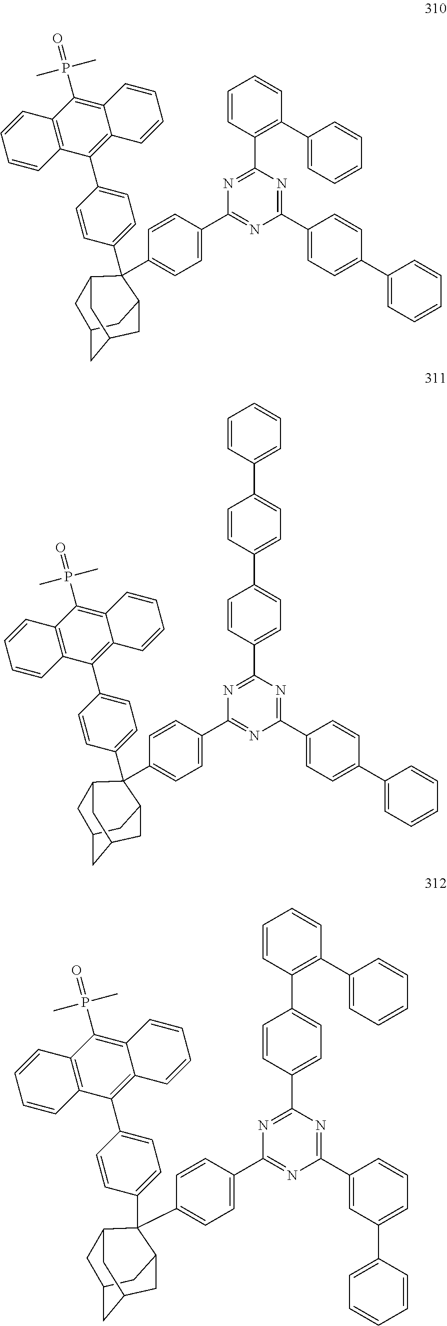 [SMILES: CP(C)(=O)c1c2ccccc2c(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)C4CC5CC(C4)CC3C5)cc2)c2ccccc12]

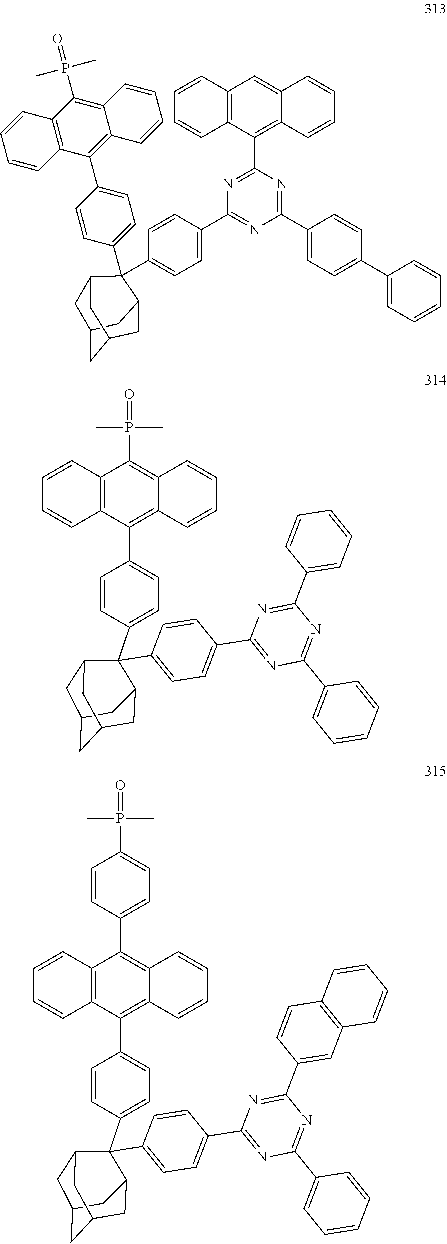 [SMILES: CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccccc6)n5)cc4)C4CC5CC(C4)CC3C5)cc2)c2ccccc12 ; CP(C)(=O)c1ccc(-c2c3ccccc3c(-c3ccc(C4(c5ccc(-c6nc(-c7ccccc7)nc(-c7ccc8ccccc8c7)n6)cc5)C5CC6CC(C5)CC4C6)cc3)c3ccccc23)cc1]

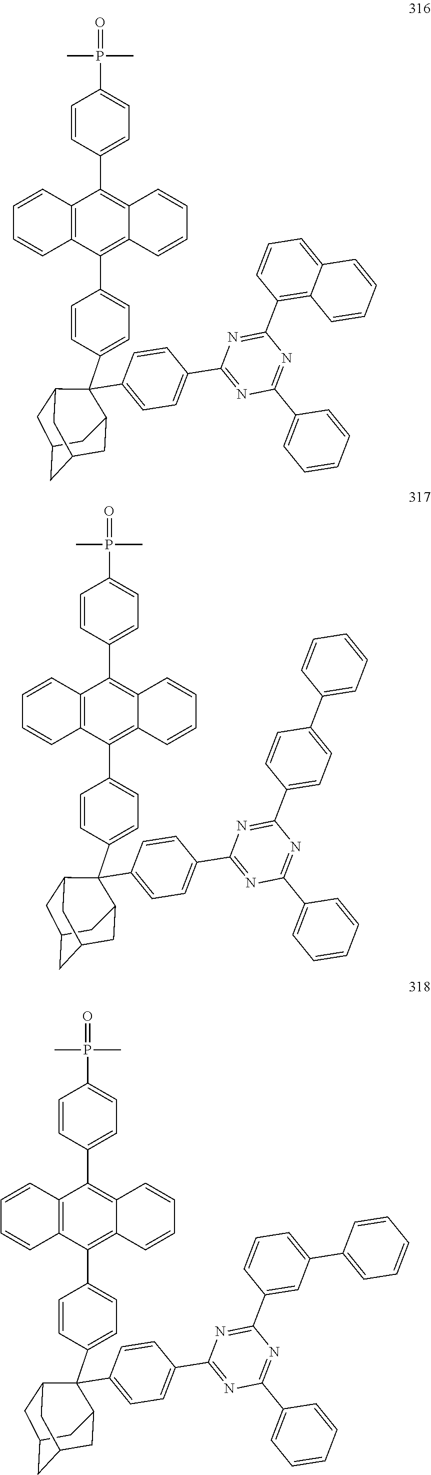 [SMILES: CP(C)(=O)c1ccc(-c2c3ccccc3c(-c3ccc(C4(c5ccc(-c6nc(-c7ccccc7)nc(-c7cccc8ccccc78)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8)cc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7cccc(-c8ccccc8)c7)n6)cc5)C5CC6CC(C5)CC4C6)cc3)c3ccccc23)cc1]

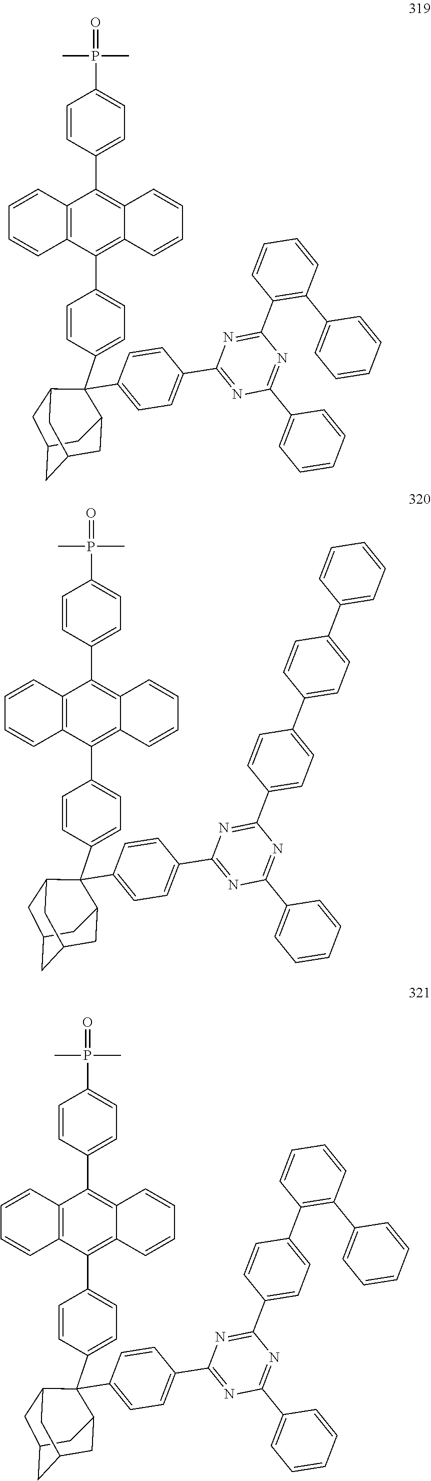 [SMILES: CP(C)(=O)c1ccc(-c2c3ccccc3c(-c3ccc(C4(c5ccc(-c6nc(-c7ccccc7)nc(-c7ccccc7-c7ccccc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)C5CC6CC(C5)CC4C6)cc3)c3ccccc23)cc1]

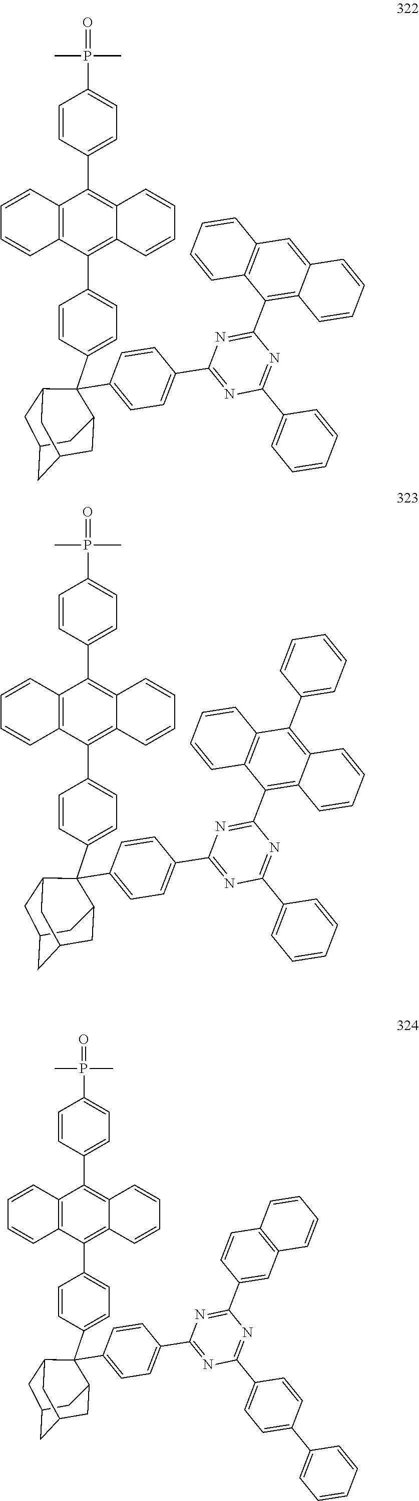 [SMILES: CP(C)(=O)c1ccc(-c2c3ccccc3c(-c3ccc(C4(c5ccc(-c6nc(-c7ccccc7)nc(-c7c8ccccc8cc8ccccc78)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)C5CC6CC(C5)CC4C6)cc3)c3ccccc23)cc1]

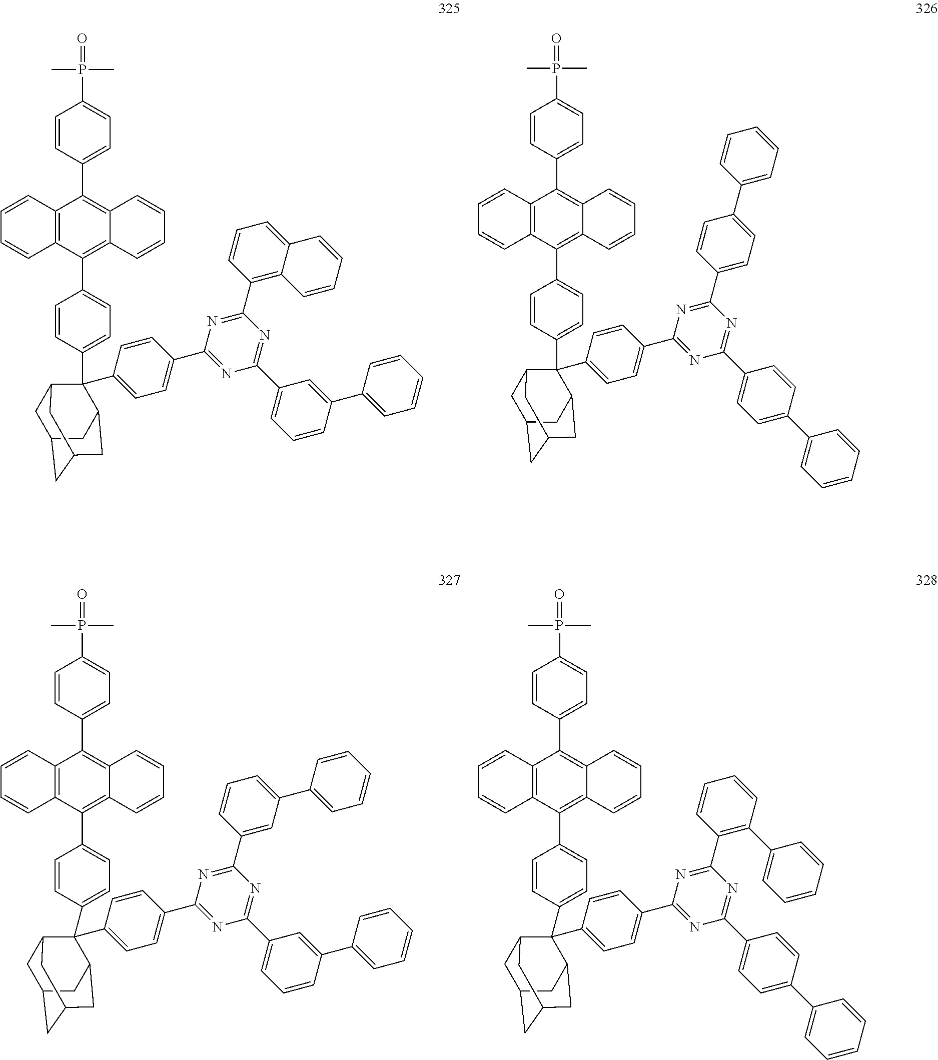

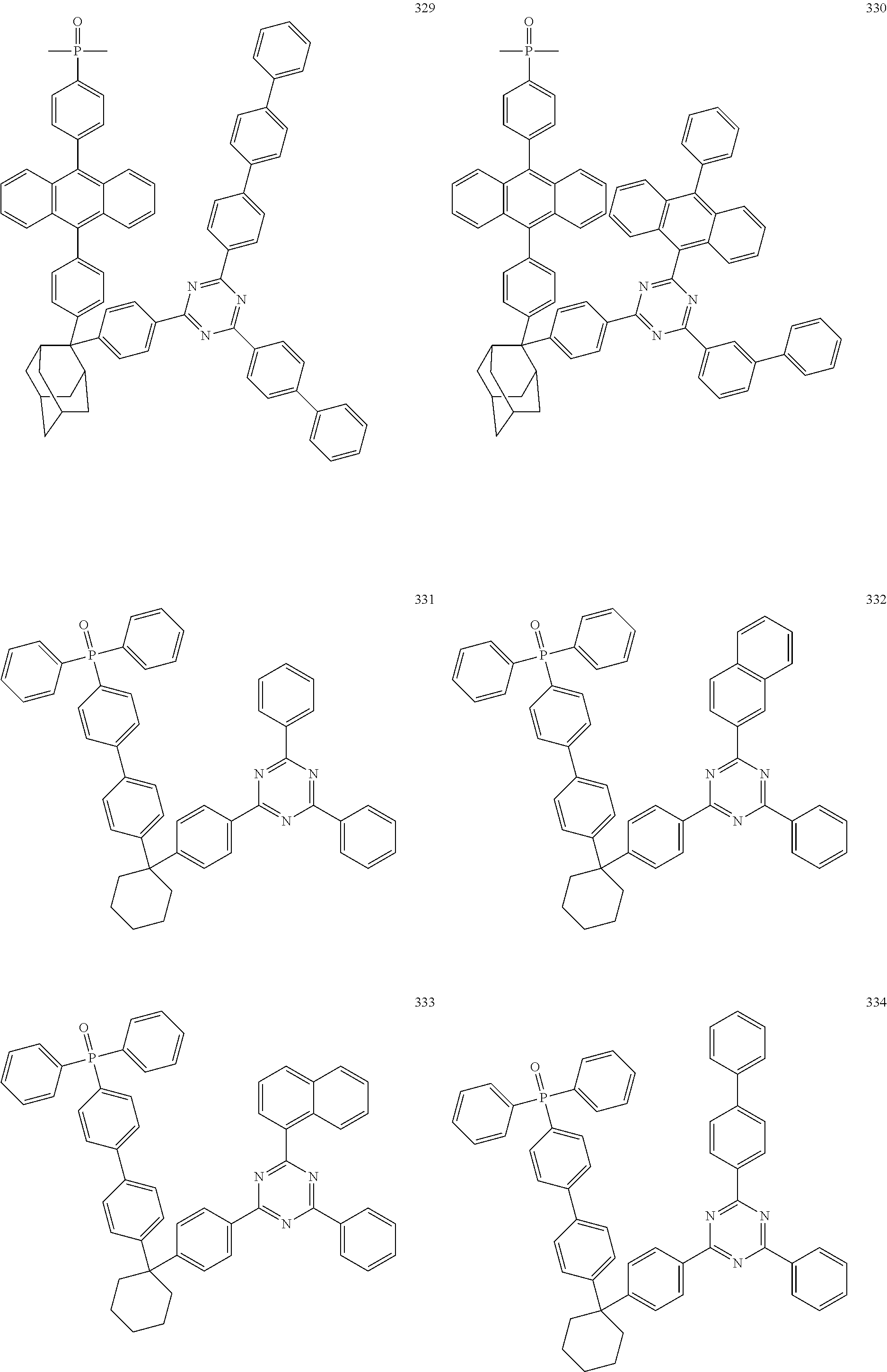

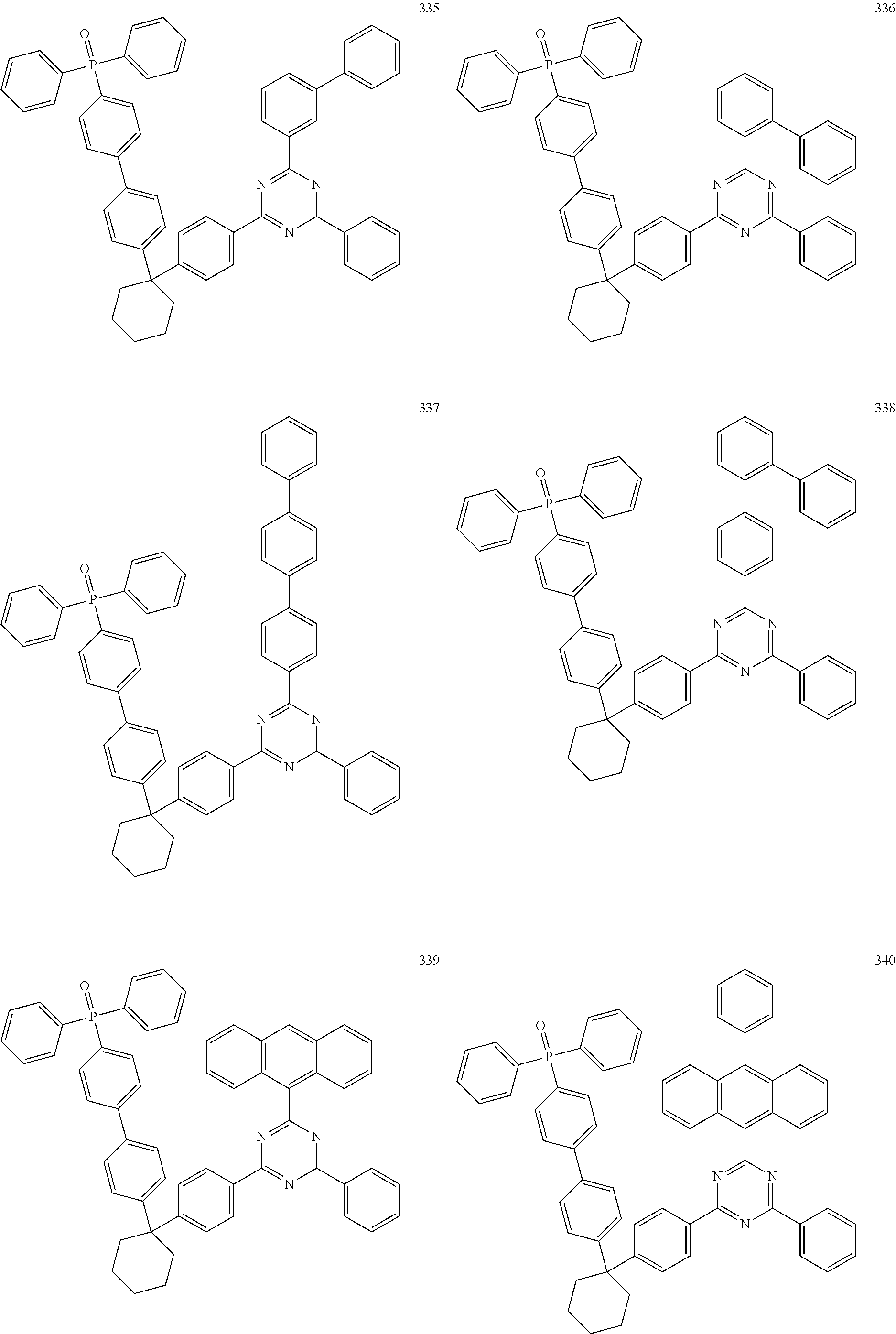

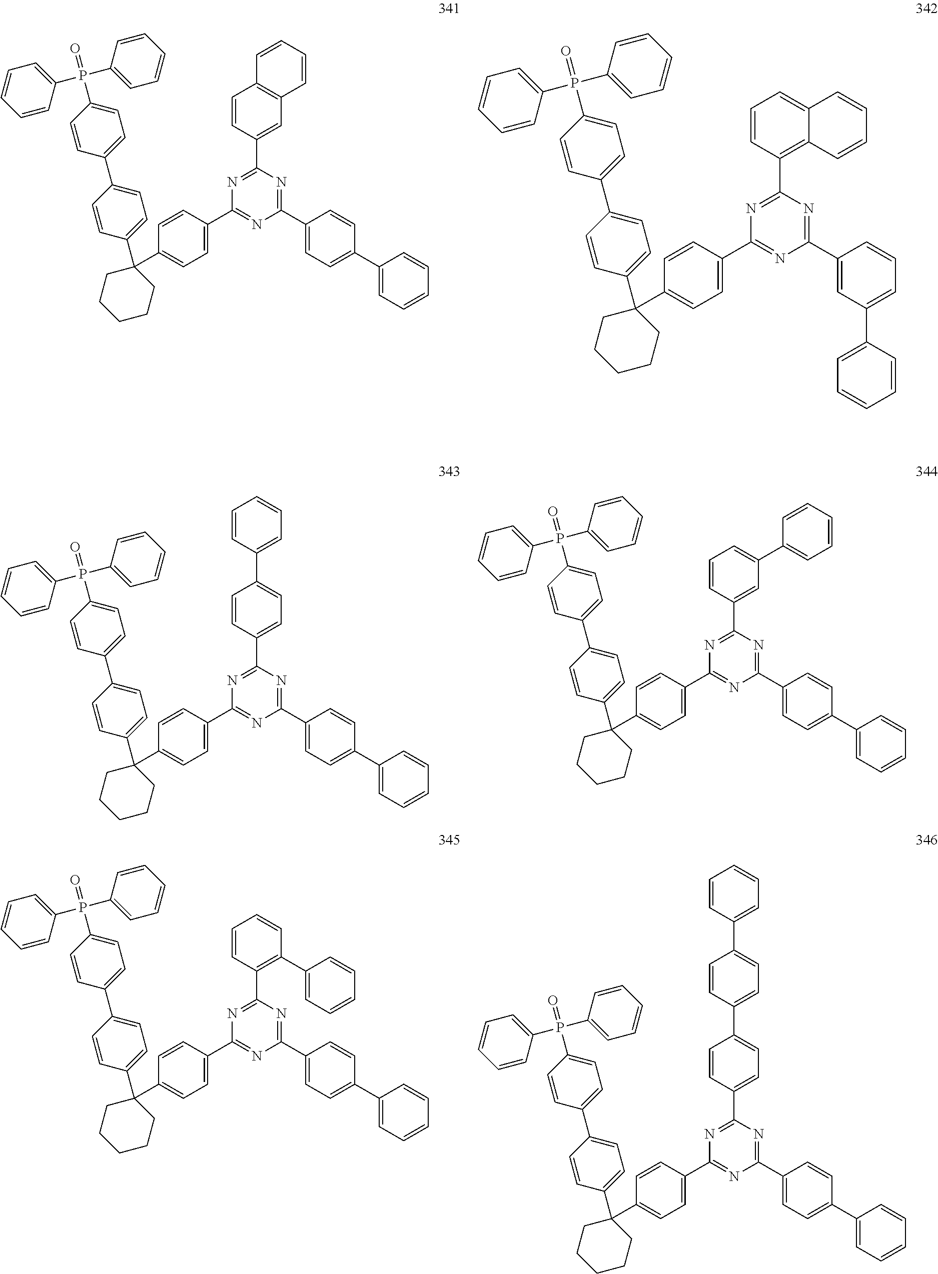

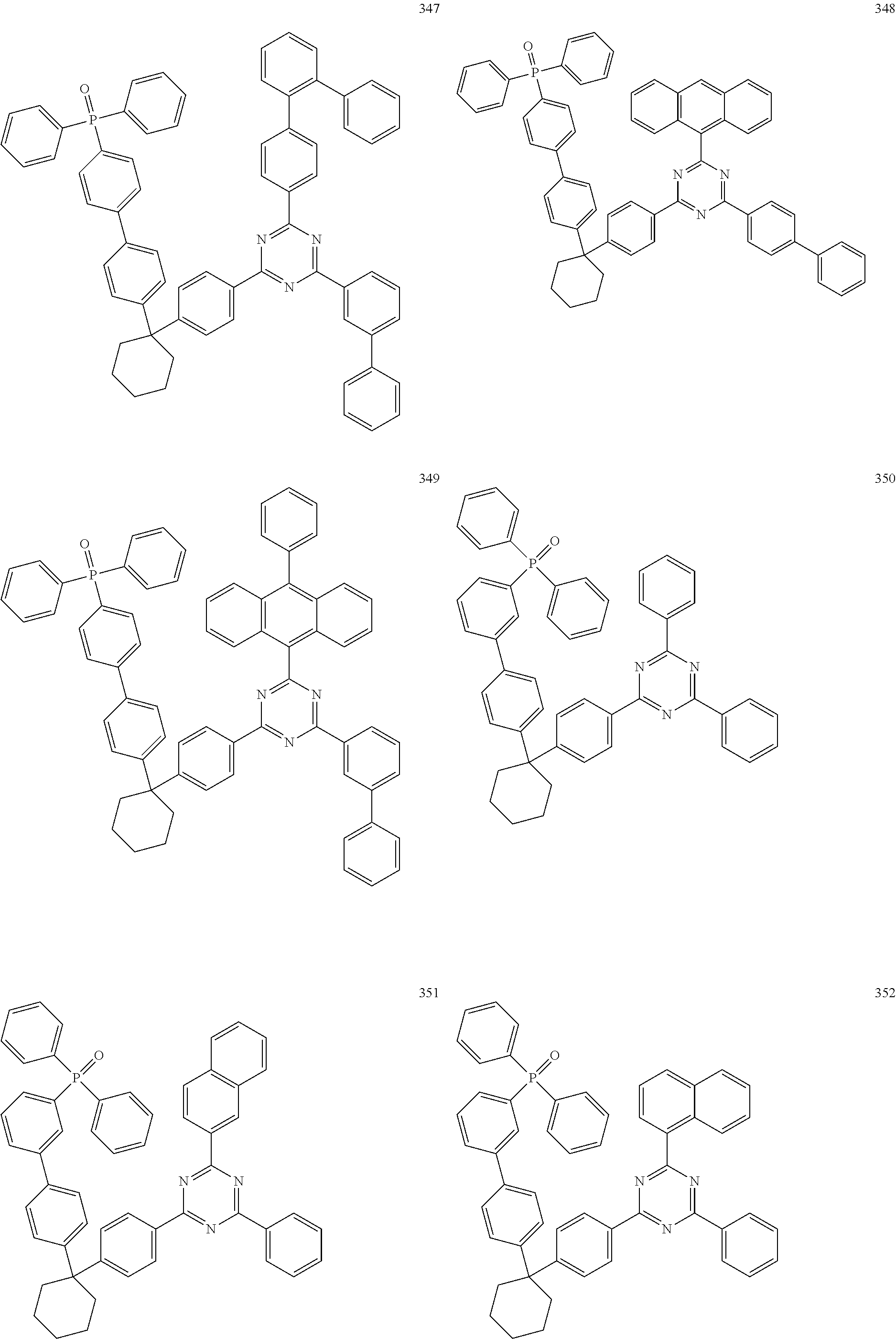

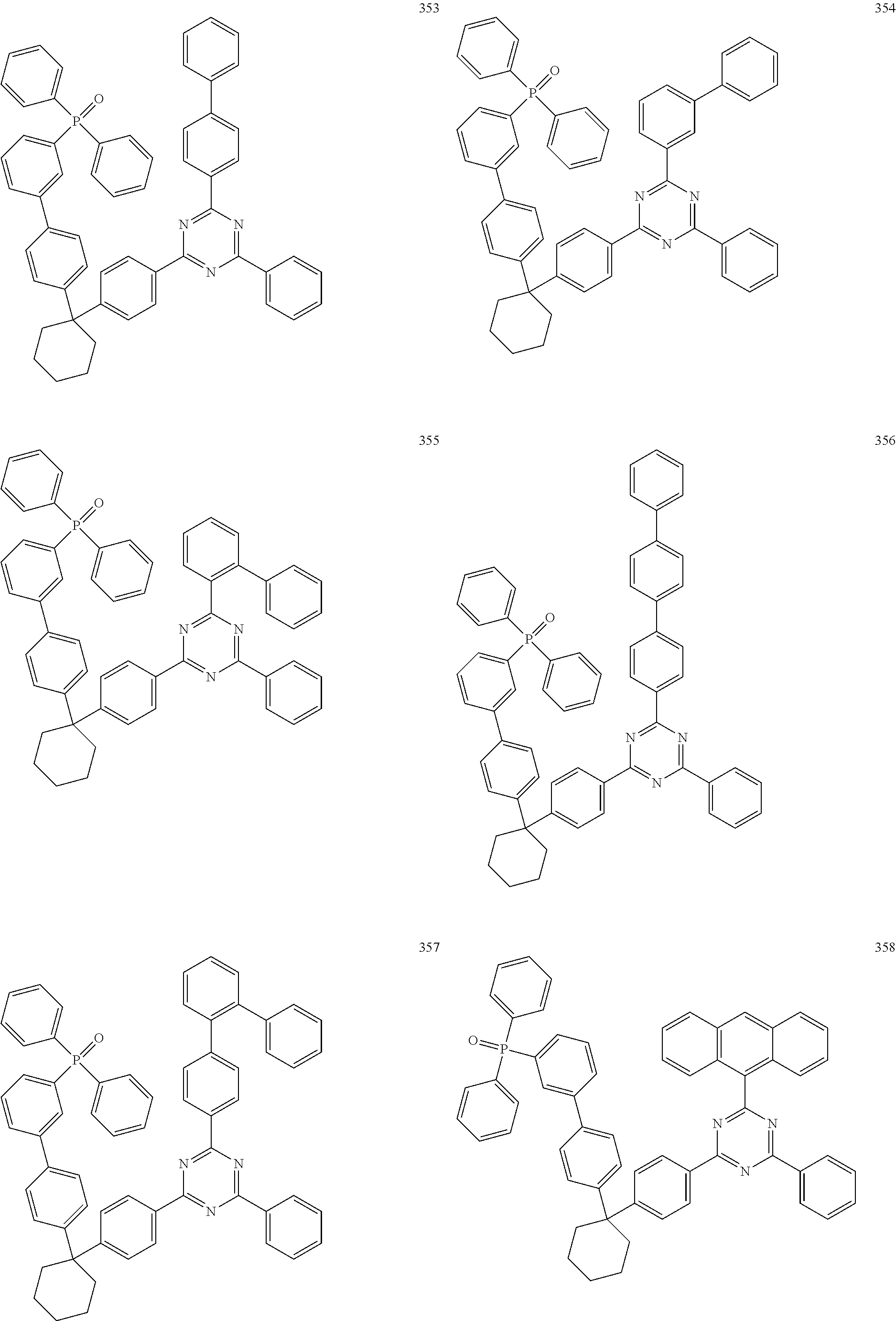

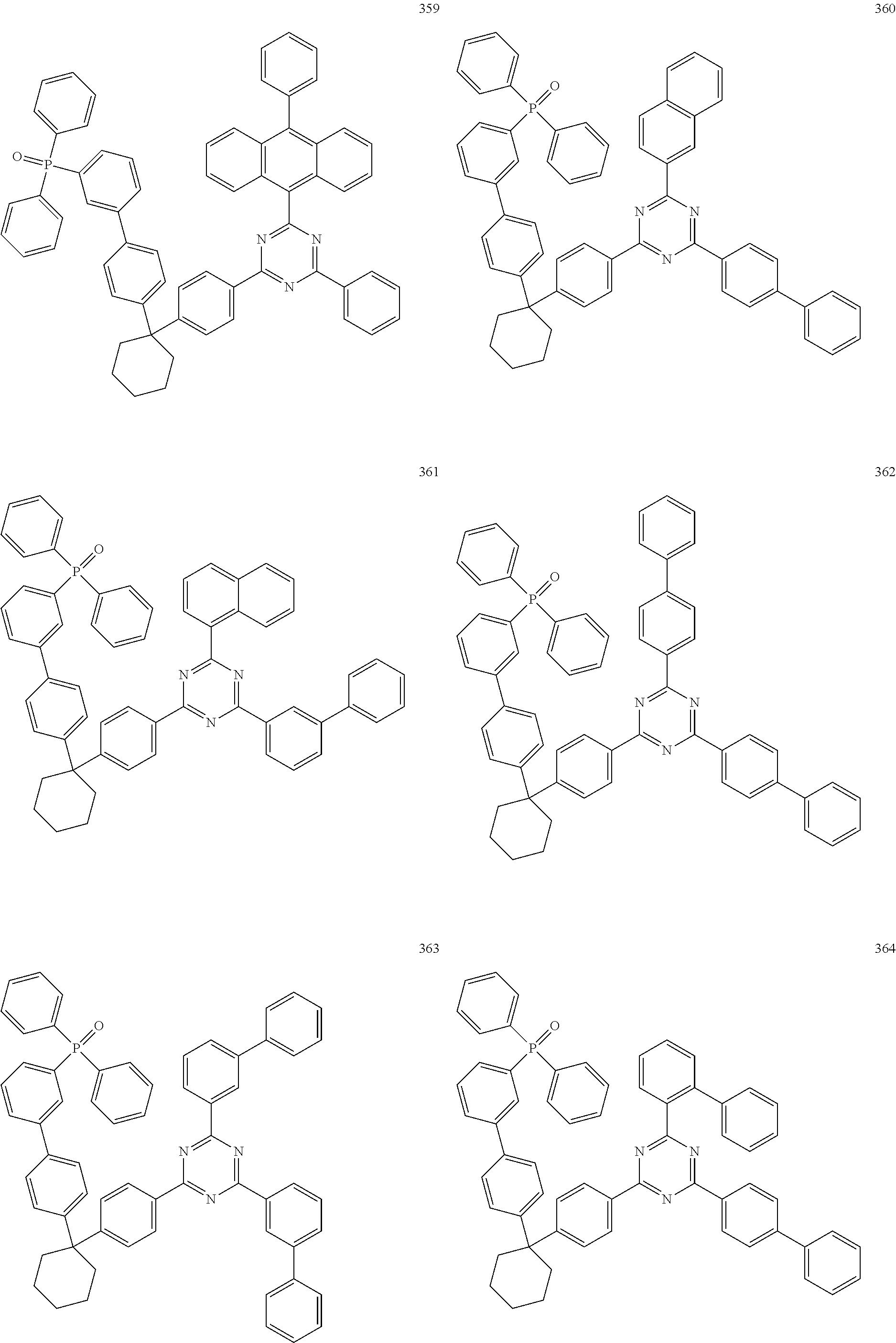

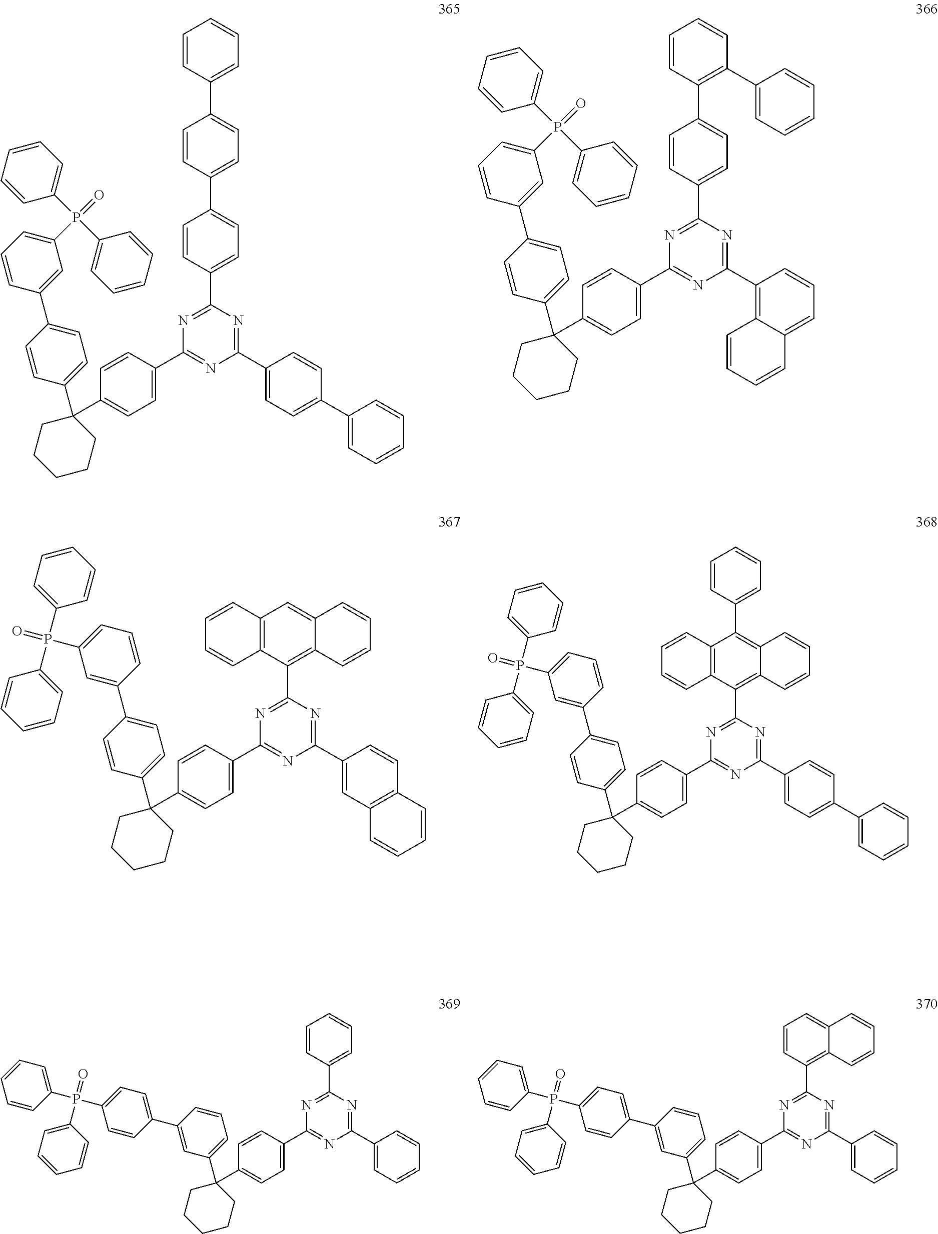

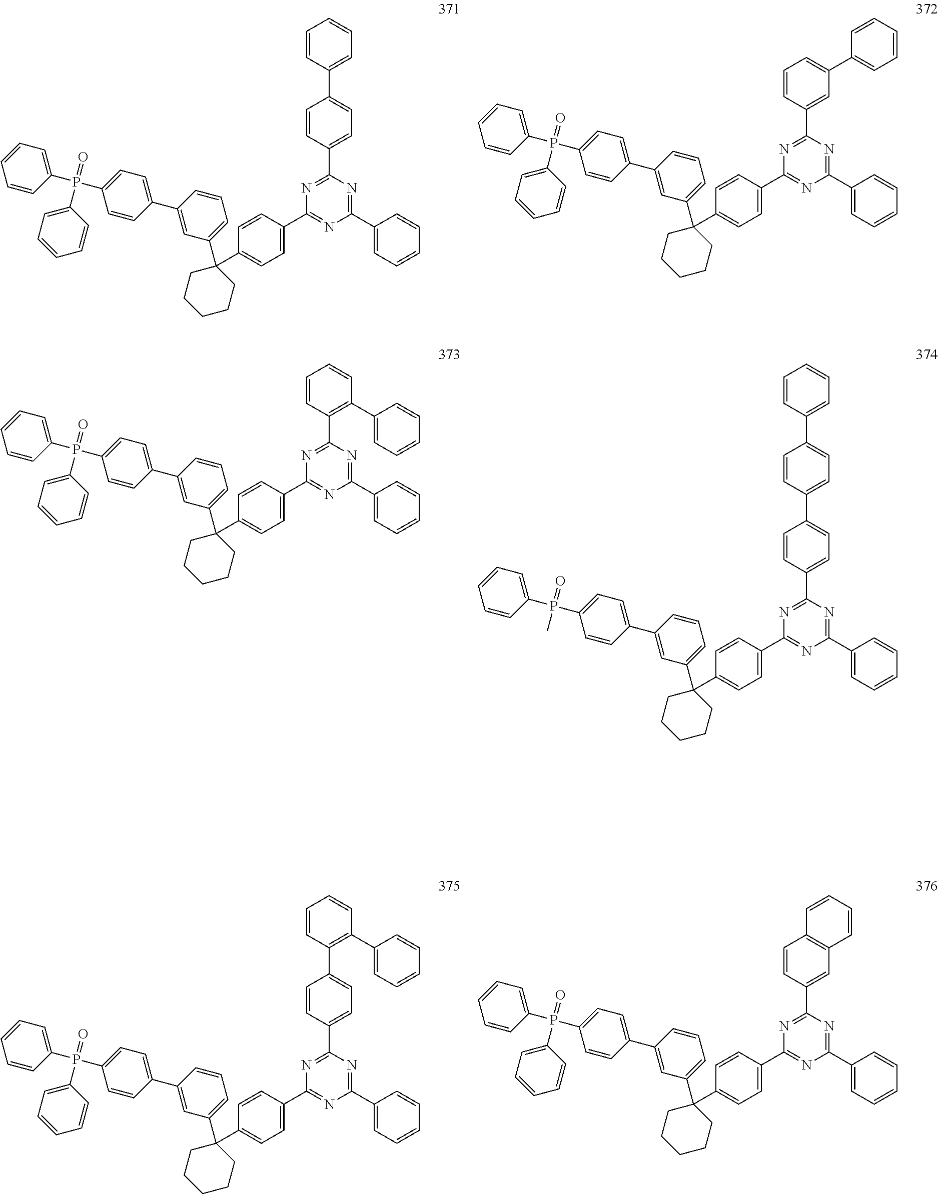

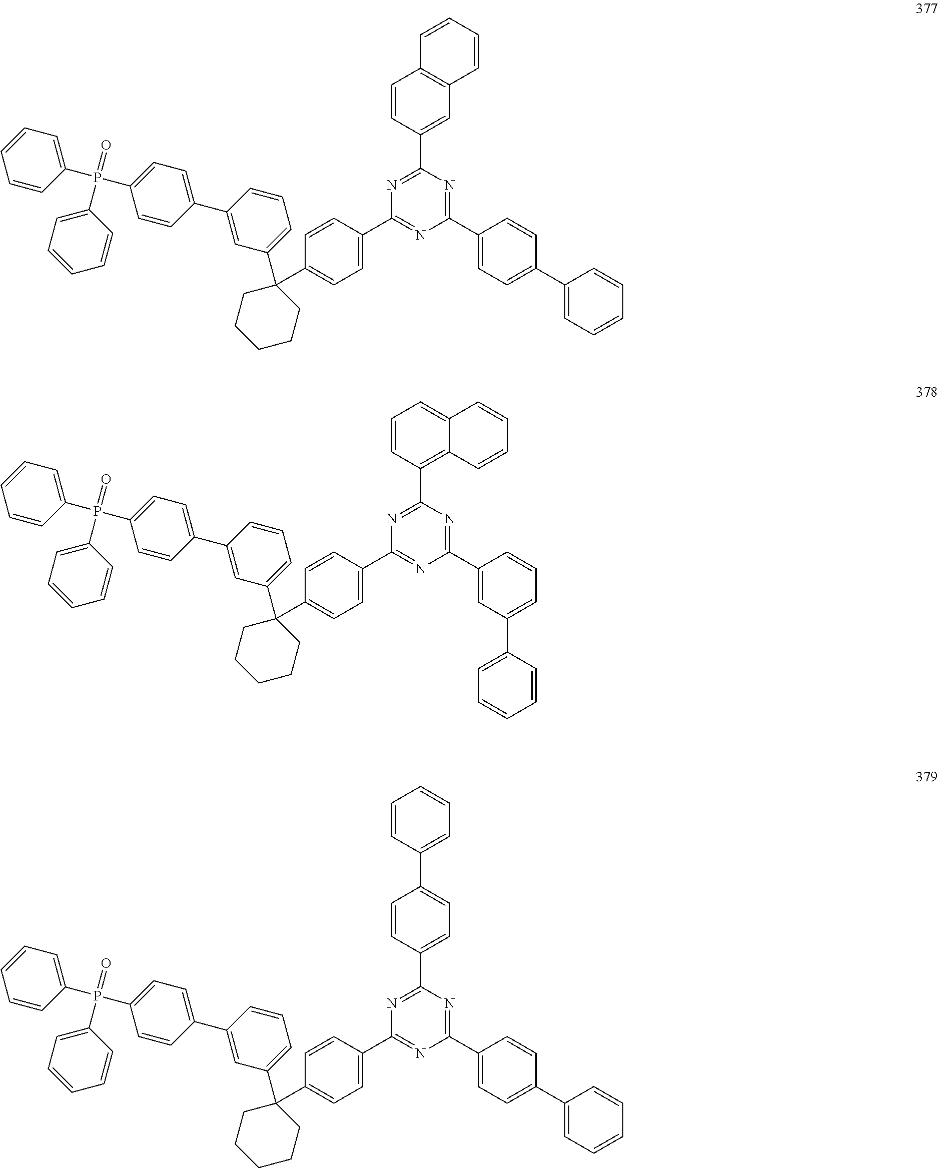 [SMILES: O=P(c1ccccc1)(c1ccccc1)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; O=P(c1ccccc1)(c1ccccc1)c1ccc(-c2cccc(C3(c4ccc(-c5nc(-c6cccc(-c7ccccc7)c6)nc(-c6cccc7ccccc67)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1]

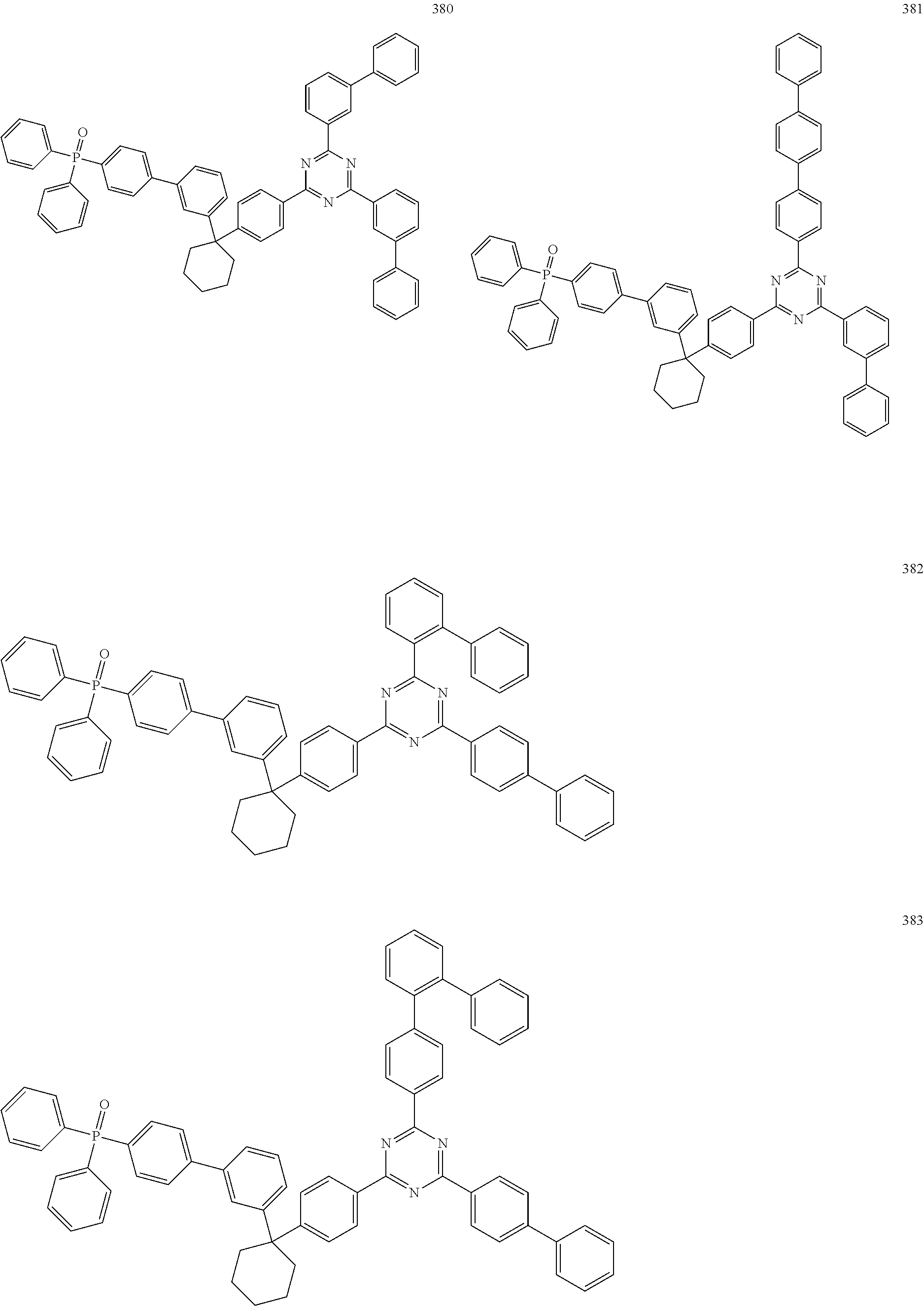 [SMILES: O=P(c1ccccc1)(c1ccccc1)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccccc6-c6ccccc6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1]

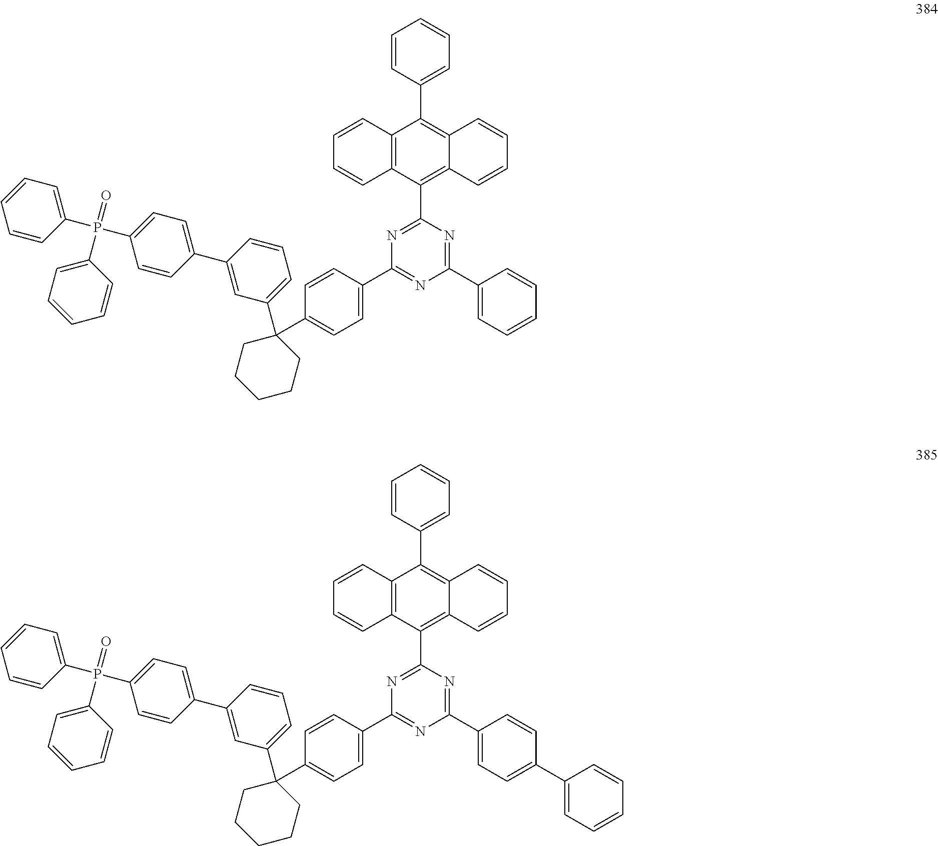 [SMILES: O=P(c1ccccc1)(c1ccccc1)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1]

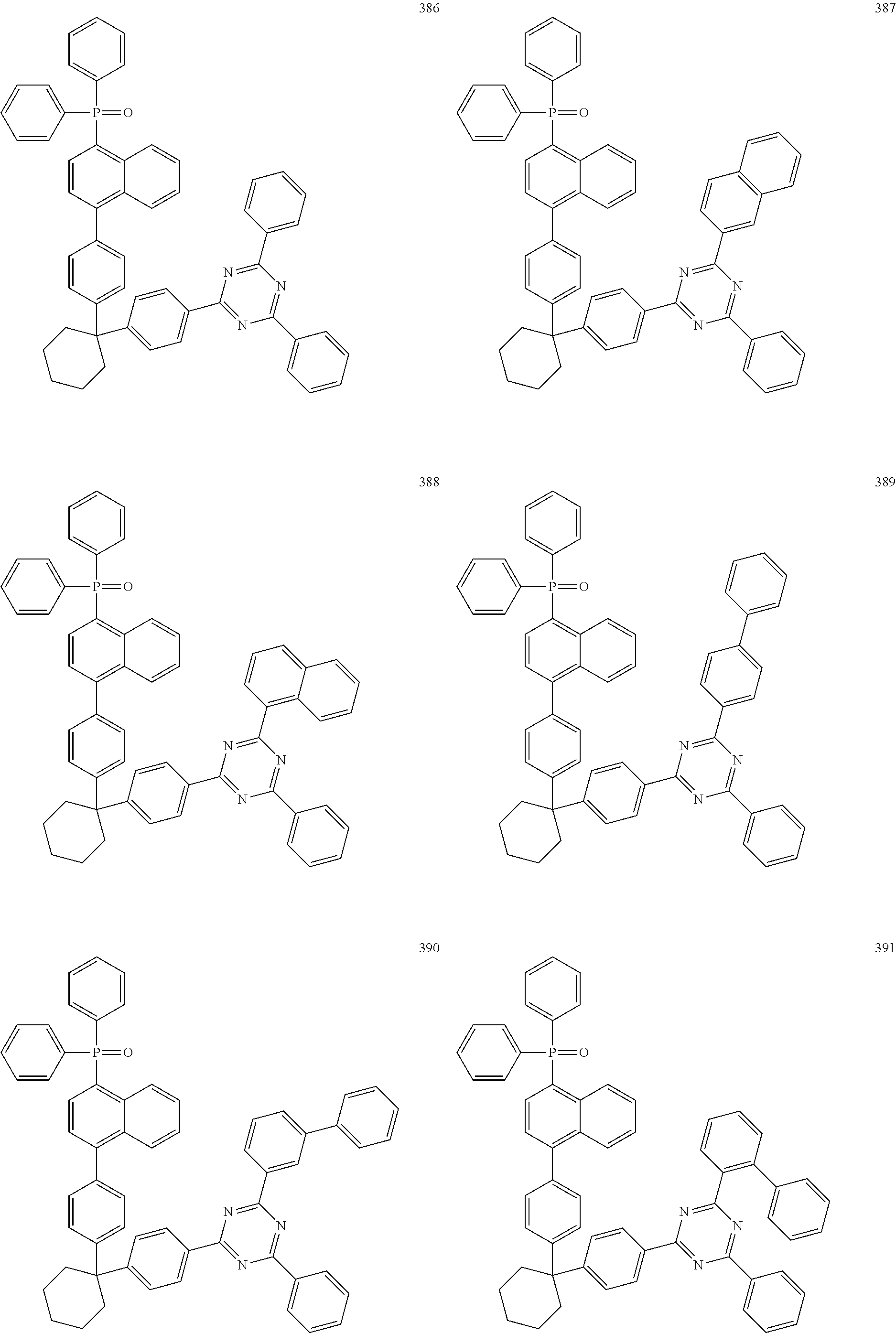

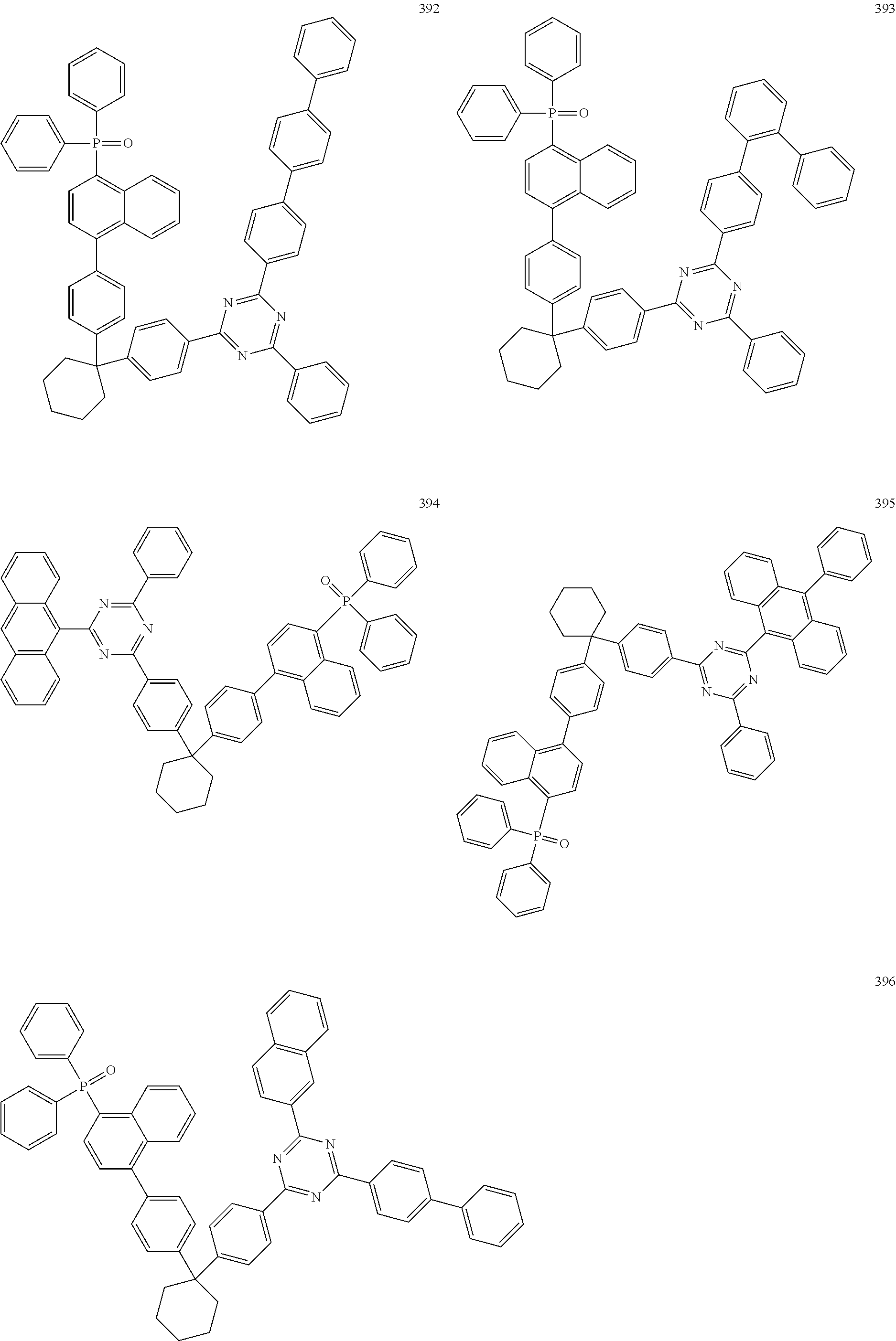

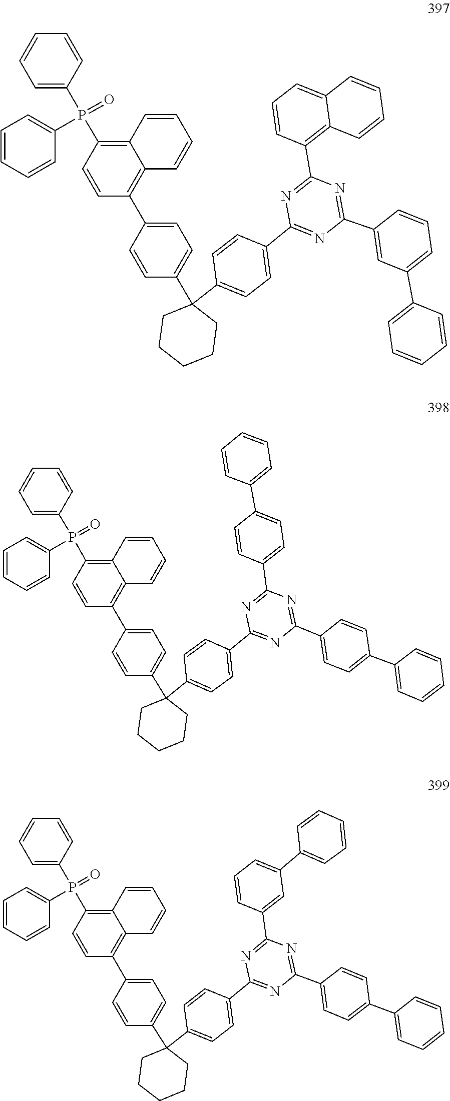 [SMILES: O=P(c1ccccc1)(c1ccccc1)c1ccc(-c2ccc(C3(c4ccc(-c5nc(-c6cccc(-c7ccccc7)c6)nc(-c6cccc7ccccc67)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12]

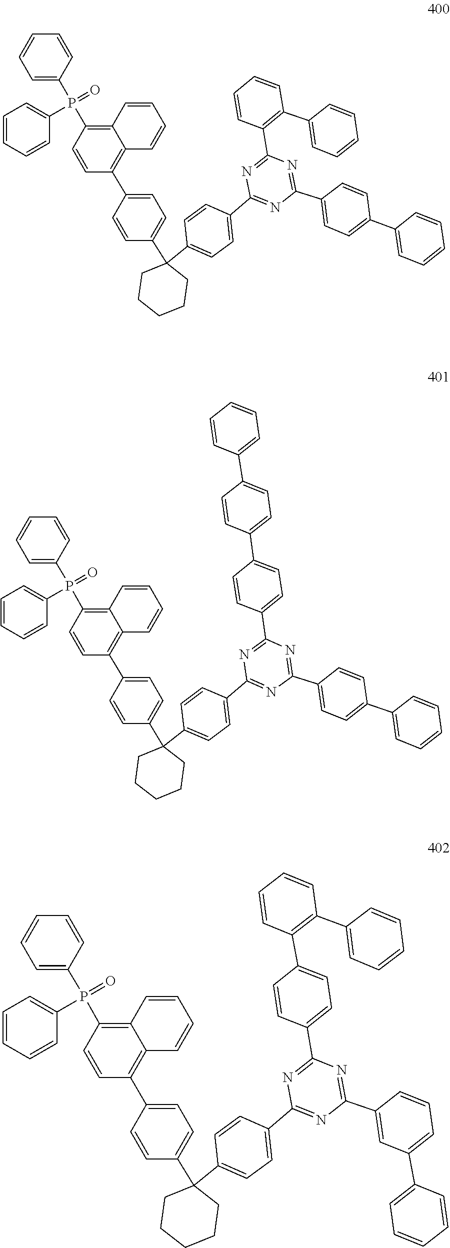 [SMILES: O=P(c1ccccc1)(c1ccccc1)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

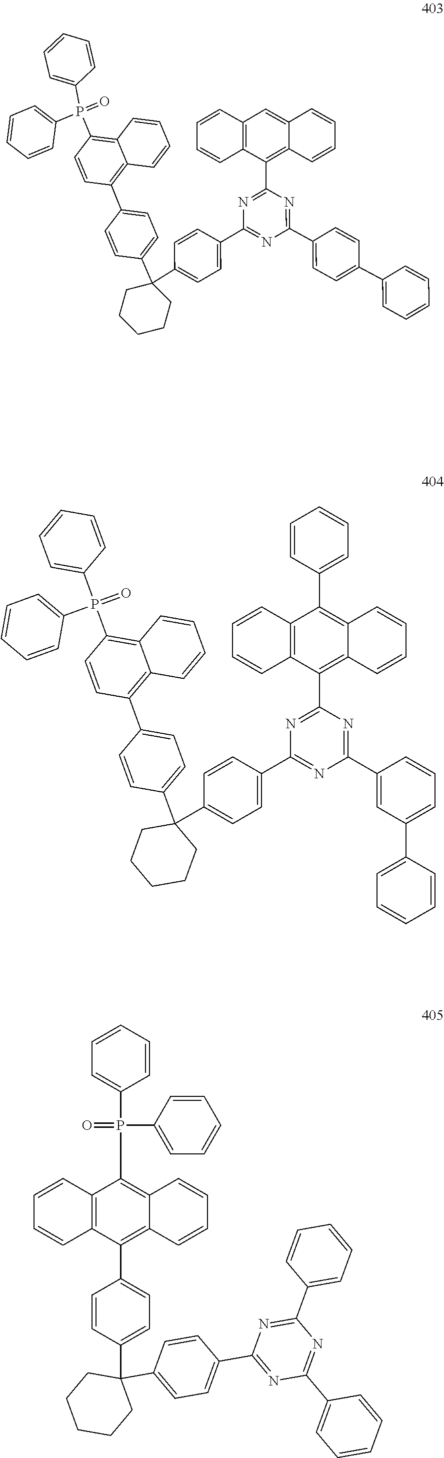 [SMILES: O=P(c1ccccc1)(c1ccccc1)c1ccc(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; O=P(c1ccccc1)(c1ccccc1)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6)n5)cc4)CCCCC3)cc2)c2ccccc12]

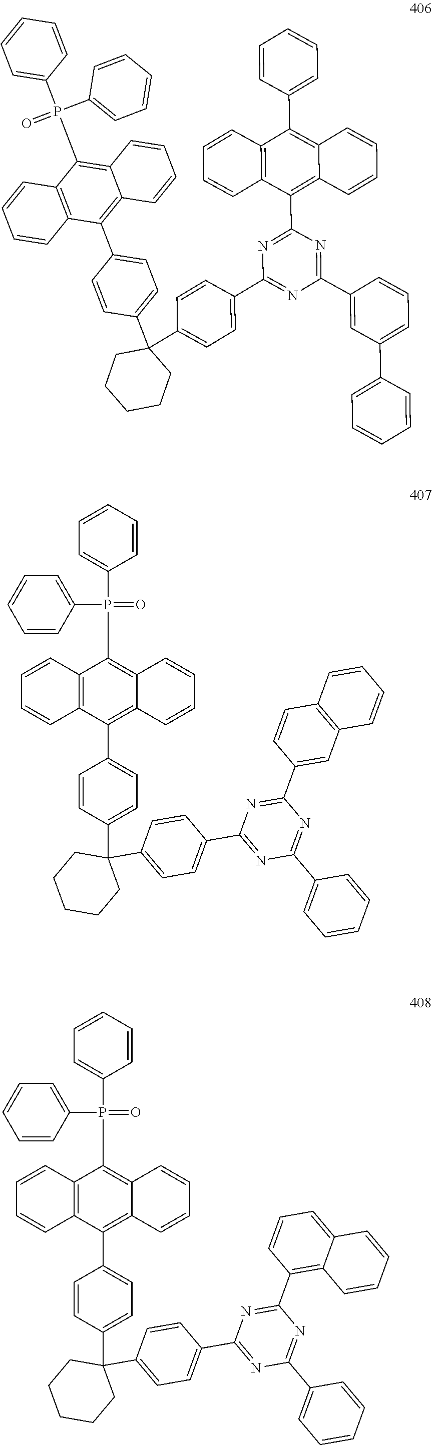 [SMILES: O=P(c1ccccc1)(c1ccccc1)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccc7ccccc7c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6cccc7ccccc67)n5)cc4)CCCCC3)cc2)c2ccccc12]

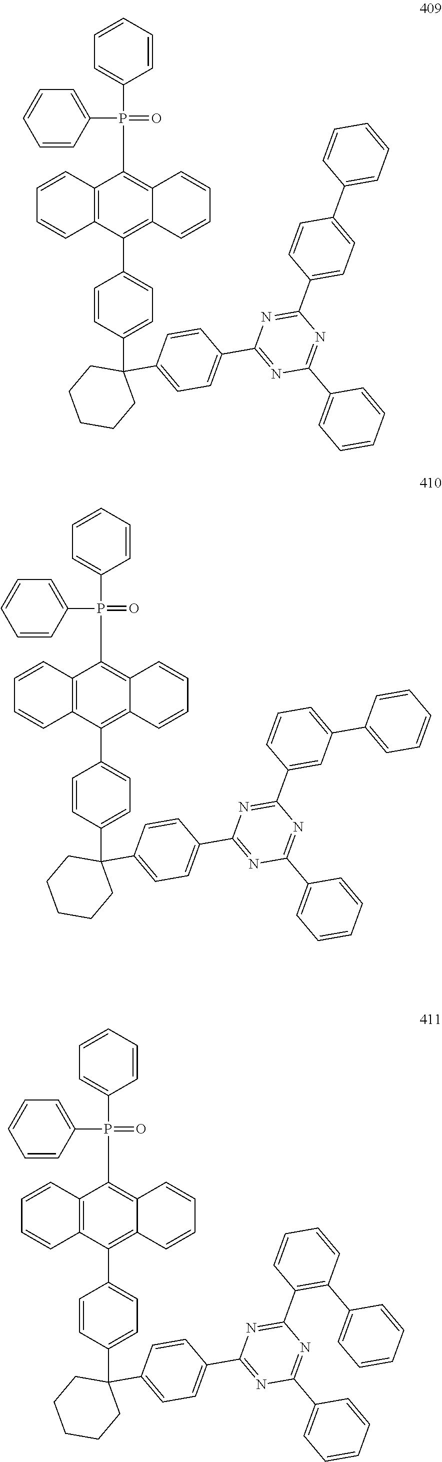 [SMILES: O=P(c1ccccc1)(c1ccccc1)c1c2ccccc2c(-c2ccc(C3(c4ccc(-c5nc(-c6ccccc6)nc(-c6ccc(-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6-c6ccccc6)n5)cc4)CCCCC3)cc2)c2ccccc12]

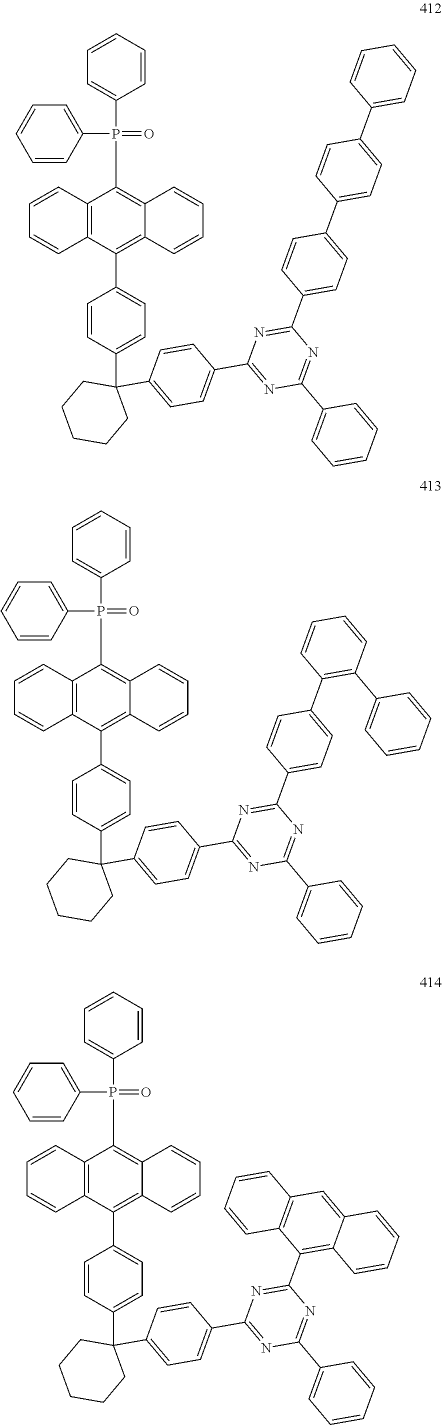 [SMILES: O=P(c1ccccc1)(c1ccccc1)c1c2ccccc2c(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6c7ccccc7cc7ccccc67)n5)cc4)CCCCC3)cc2)c2ccccc12]

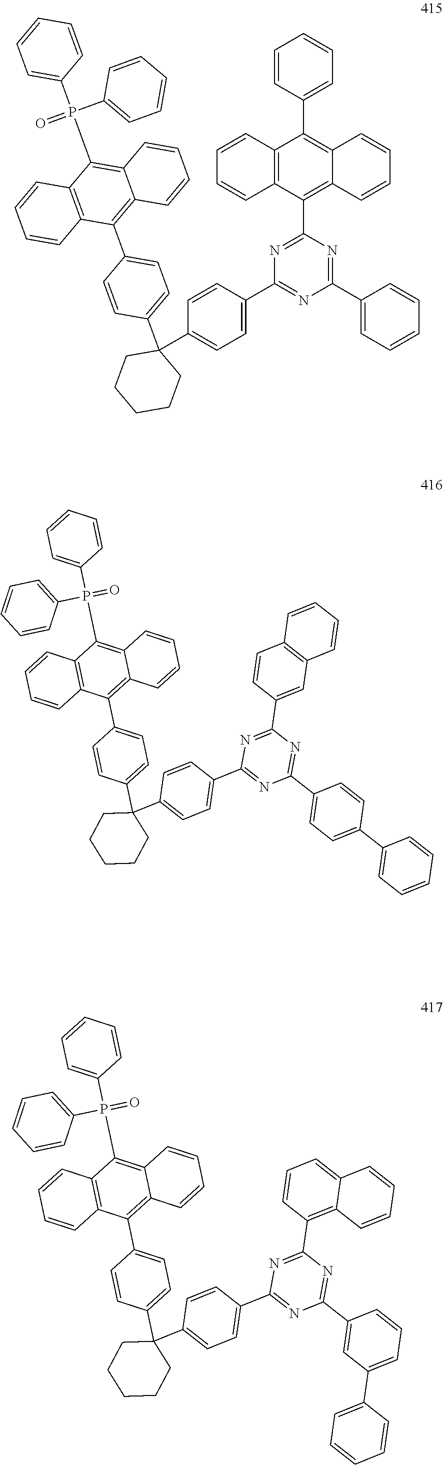 [SMILES: O=P(c1ccccc1)(c1ccccc1)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccc7ccccc7c6)n5)cc4)CCCCC3)cc2)c2ccccc12 ; O=P(c1ccccc1)(c1ccccc1)c1c2ccccc2c(-c2ccc(C3(c4ccc(-c5nc(-c6cccc(-c7ccccc7)c6)nc(-c6cccc7ccccc67)n5)cc4)CCCCC3)cc2)c2ccccc12]

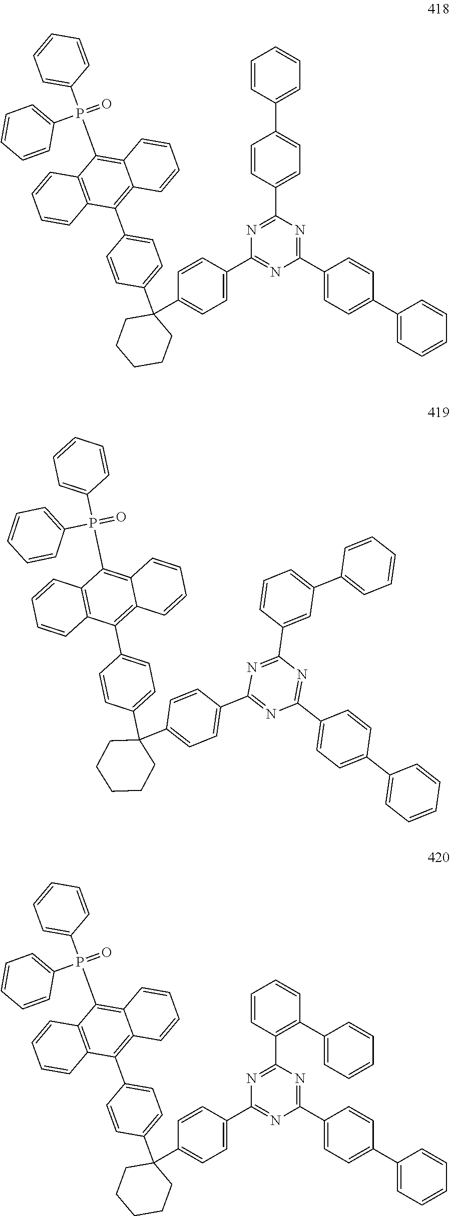 [SMILES: O=P(c1ccccc1)(c1ccccc1)c1c2ccccc2c(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

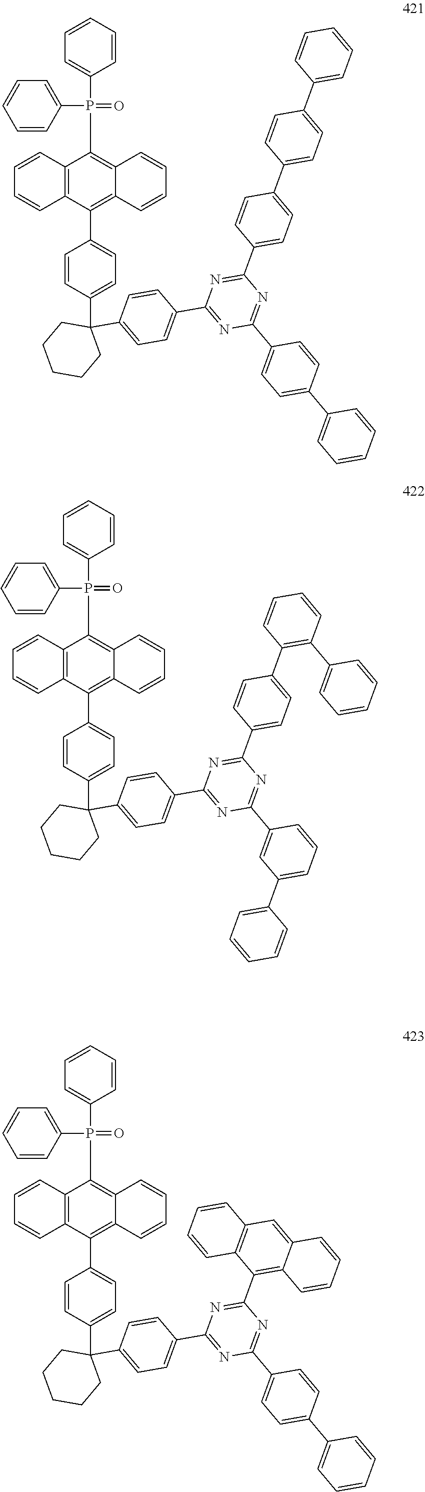

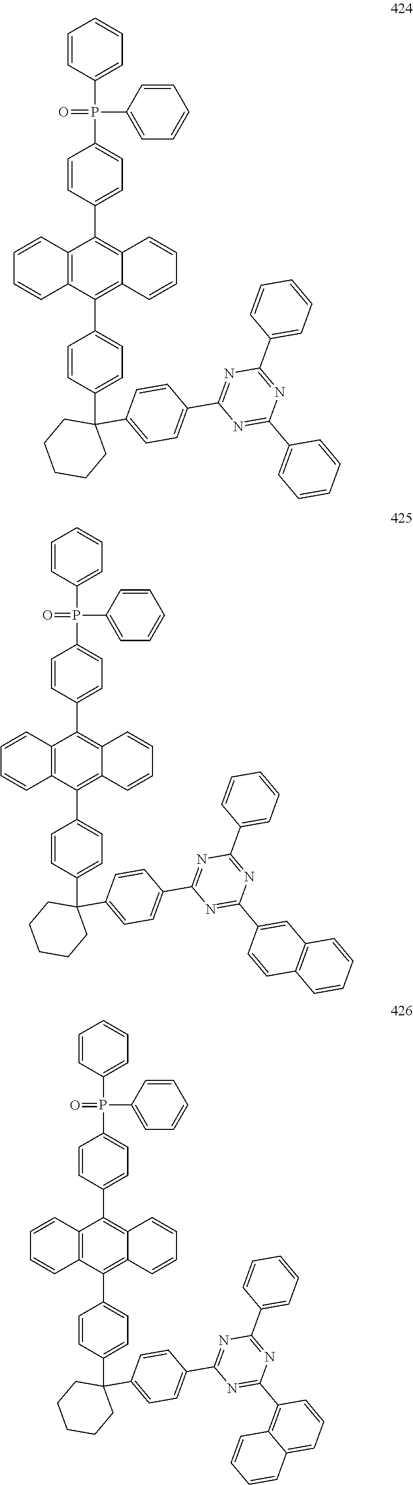 [SMILES: O=P(c1ccccc1)(c1ccccc1)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1]

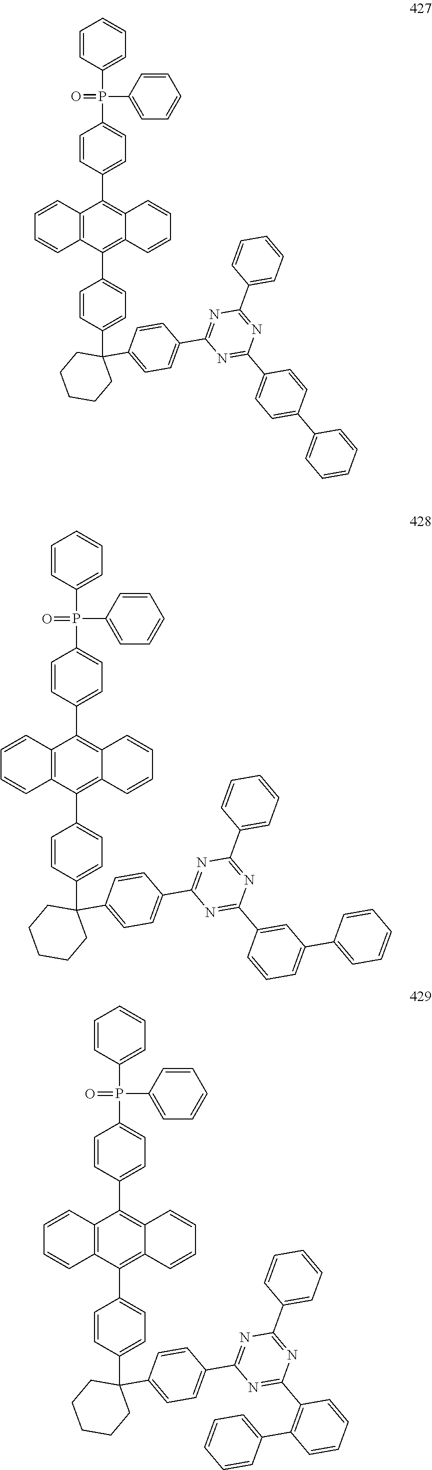 [SMILES: O=P(c1ccccc1)(c1ccccc1)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1]

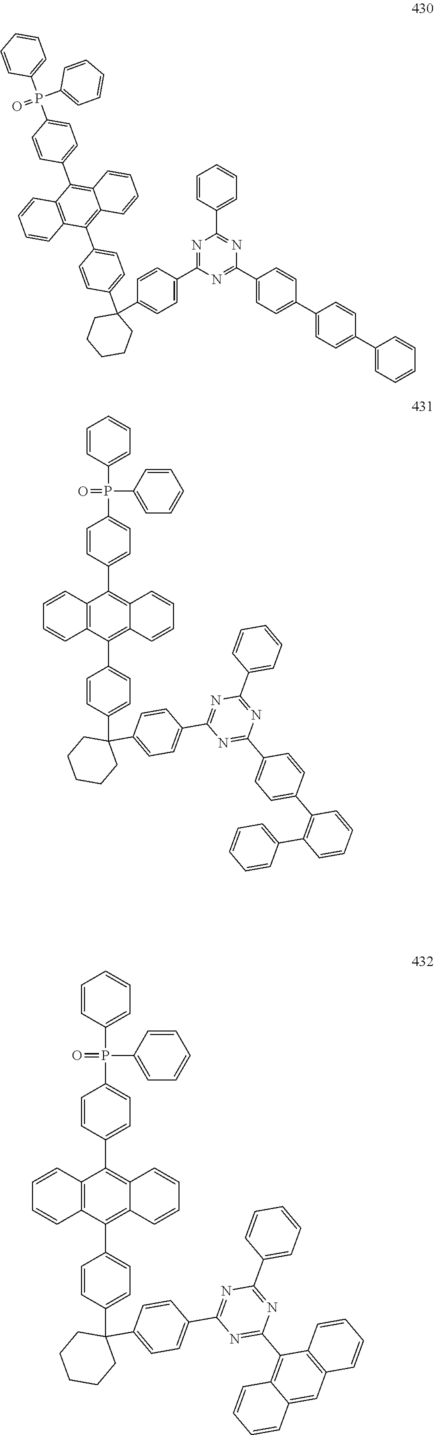 [SMILES: O=P(c1ccccc1)(c1ccccc1)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7c8ccccc8cc8ccccc78)n6)cc5)CCCCC4)cc3)c3ccccc23)cc1]

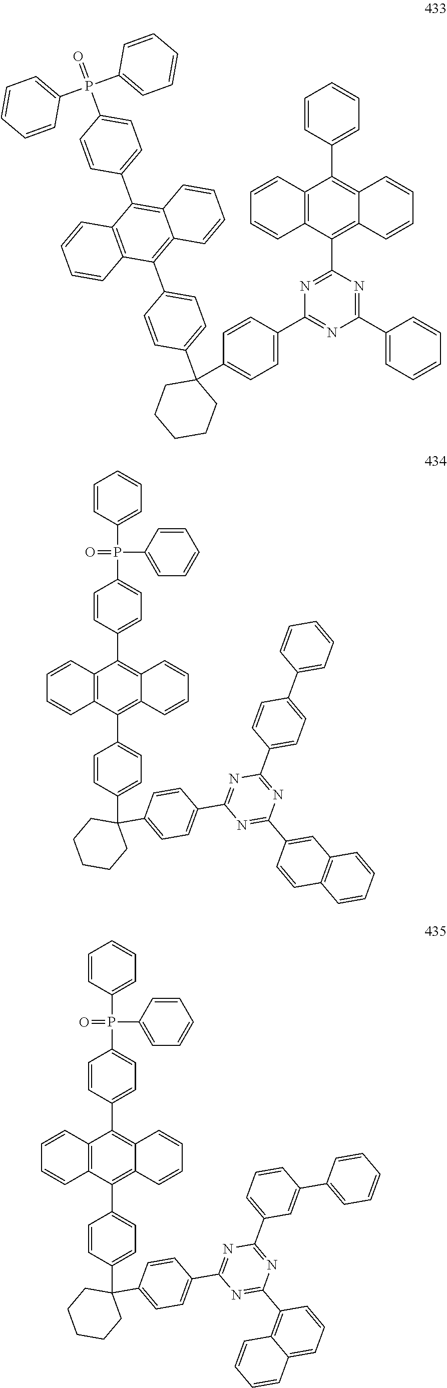 [SMILES: O=P(c1ccccc1)(c1ccccc1)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1]

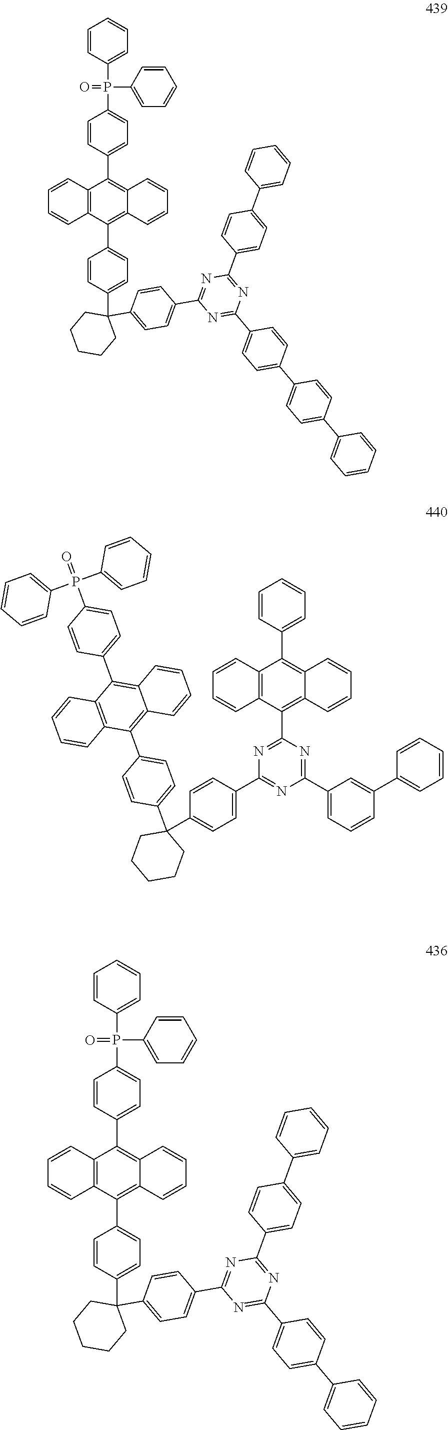 [SMILES: O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CCCCC4)cc3)c3ccccc23)cc1]

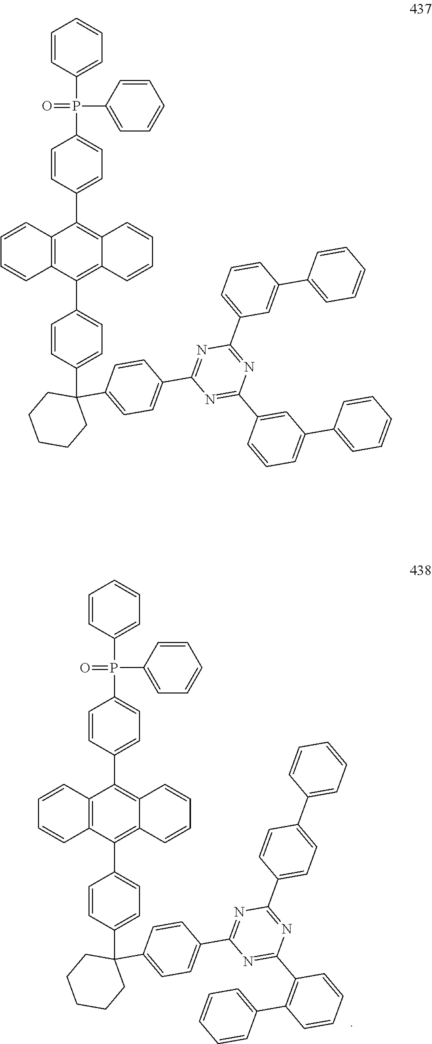 [SMILES: O=P(c1ccccc1)(c1ccccc1)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

The compound represented by Formula 1 according to one or more embodiments of the present disclosure may include a core structure in which two phenylene groups are connected via a cycloalkyl group. In the compound represented by Formula 1, because two phenylene groups are connected via a cycloalkyl group, the conjugation structure of each of two phenylene groups may be discontinued (i.e., unconnected or discontinuous). Accordingly, the compound of one or more embodiments may have (e.g., relatively) high triplet energy, and the quenching of excitons produced in an emission layer EML, in an electron transport region ETR, for example, an electron transport layer ETL, may be prevented or reduced.

In some embodiments, the compound represented by Formula 1 according to one or more embodiments of the present disclosure may include both (e.g., simultaneously) a phosphine oxide group and a triazine group, bonded to the core structure. For example, the phosphine oxide group may be bonded to one phenylene group of the core structure, and may be bonded to the phenylene group of the core structure via a linker. In some embodiments, the triazine group may be directly bonded to the other phenylene group of the core structure. The compound represented by Formula 1 of one or more embodiments includes both (e.g., simultaneously) the phosphine oxide group and the triazine group concurrently (e.g., simultaneously) as substituents, and (e.g., relatively) high charge transport capacity may be exhibited (e.g., shown).

The light emitting element ED according to one or more embodiments of the present disclosure includes the compound represented by Formula 1, and the element properties of a low driving voltage, high emission efficiency and long lifetime may be exhibited (e.g., shown). For example, the compound represented by Formula 1 is included in the electron transport region ETR, for example, an electron transport layer ETL, and may contribute to the improvement of the emission layer and the increase of the lifetime of the light emitting element ED.

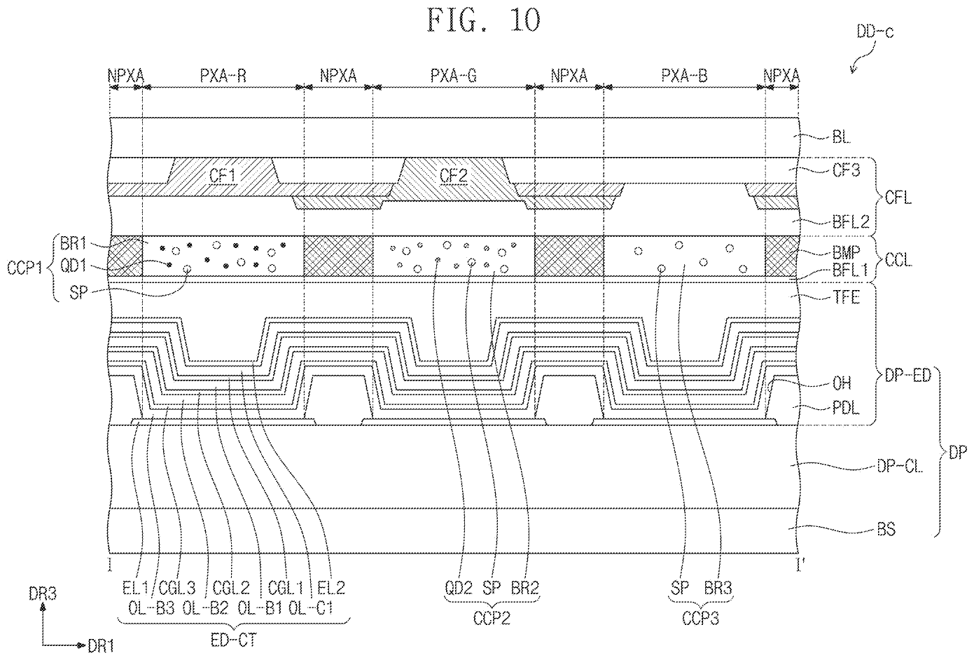

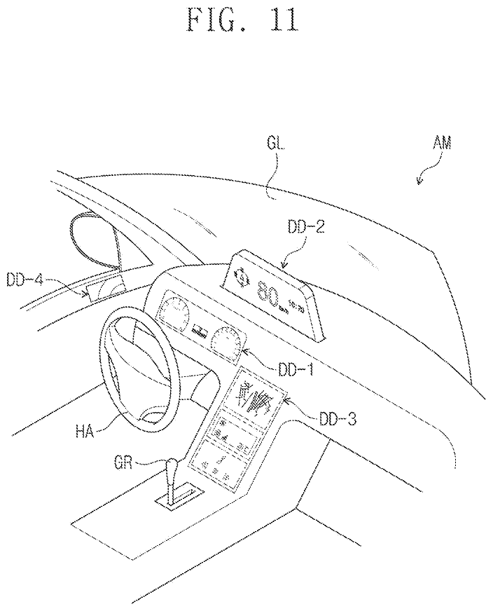

The display devices DD, DD-TD, DD-a, DD-b and DD-c (see FIGS. 1, 2 and 8 to 11) according to embodiments of the present disclosure include the light emitting element ED including the compound represented by Formula 1, and excellent or suitable display quality may be exhibited (e.g., shown).

The electron transport region ETR may include a compound represented by Formula ET-2.

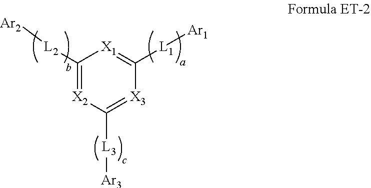

In Formula ET-2, at least one among X₁ to X₃ may be N, and the remainder of X₁ to X₃ may be CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure is not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/o mixture(s) thereof, without limitation.

The electron transport region ETR may include at least one selected from among Compounds ET1 to ET36.

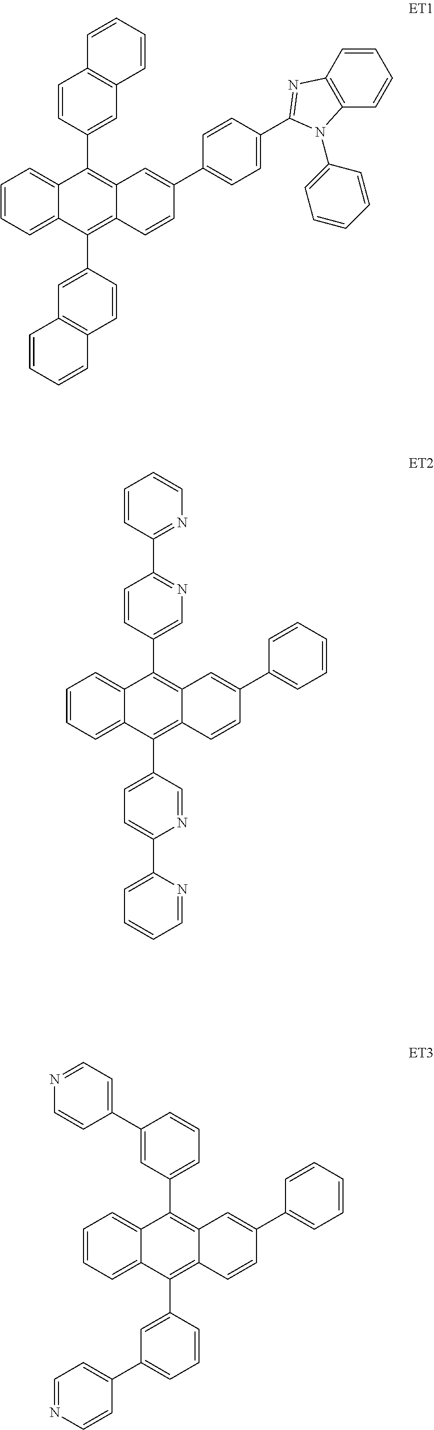 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

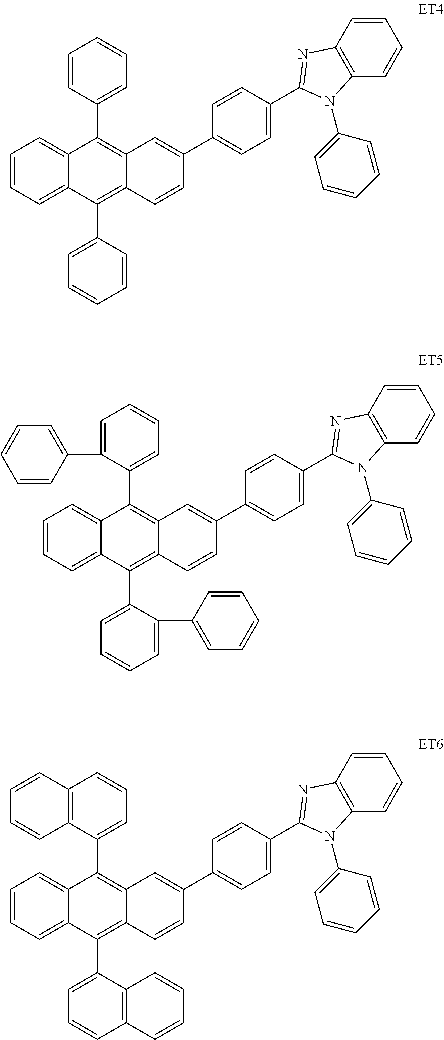 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

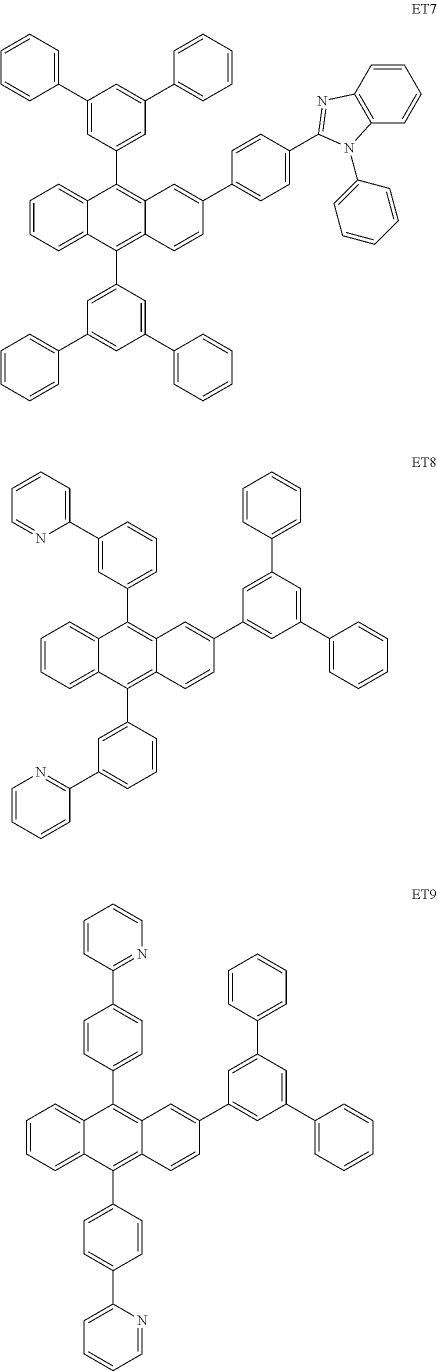 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

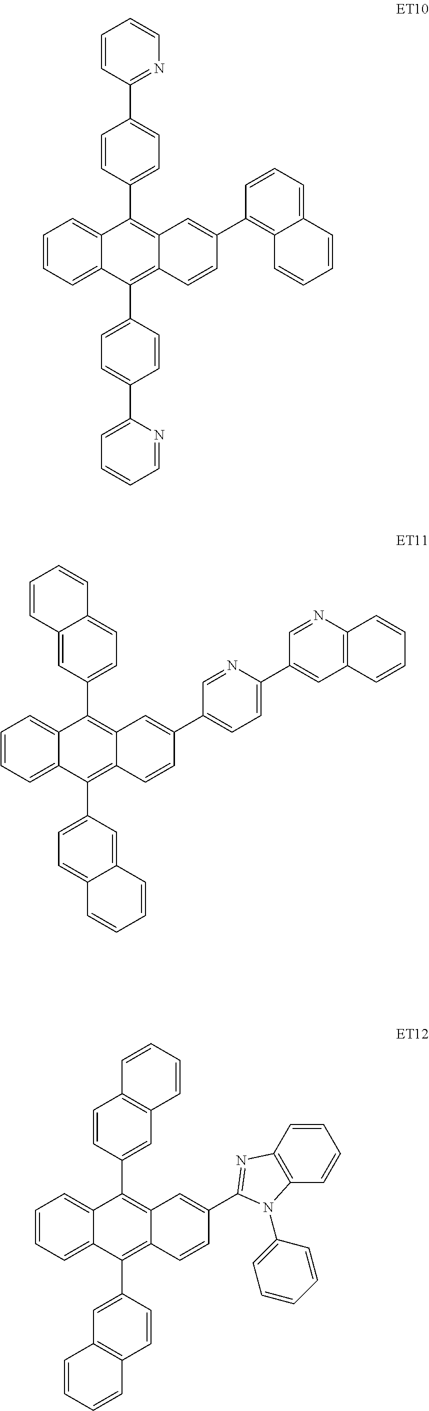 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

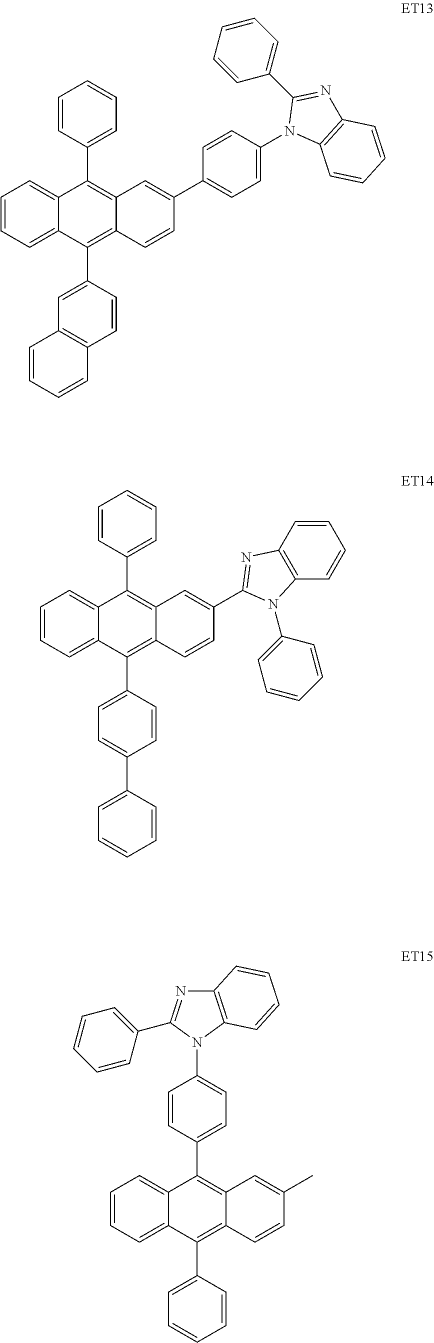 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

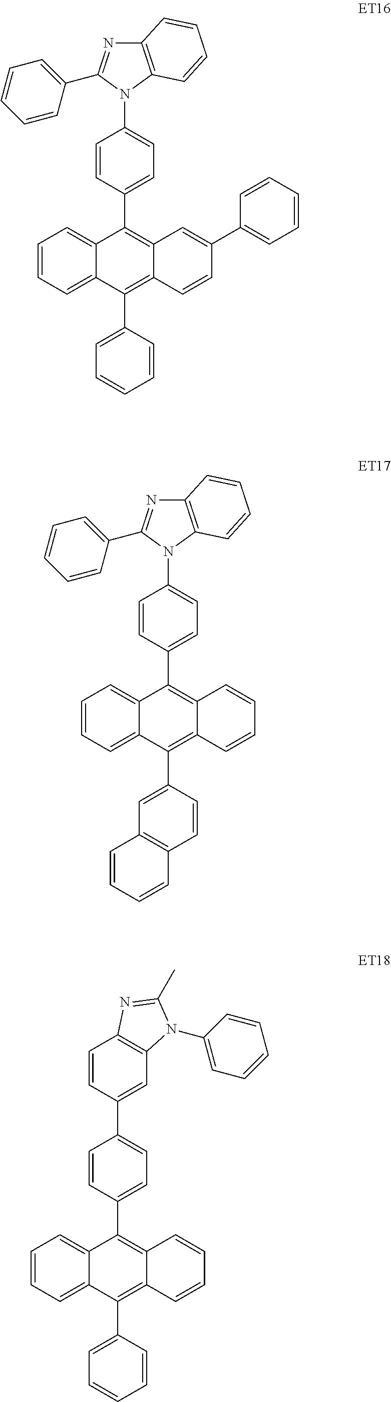 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

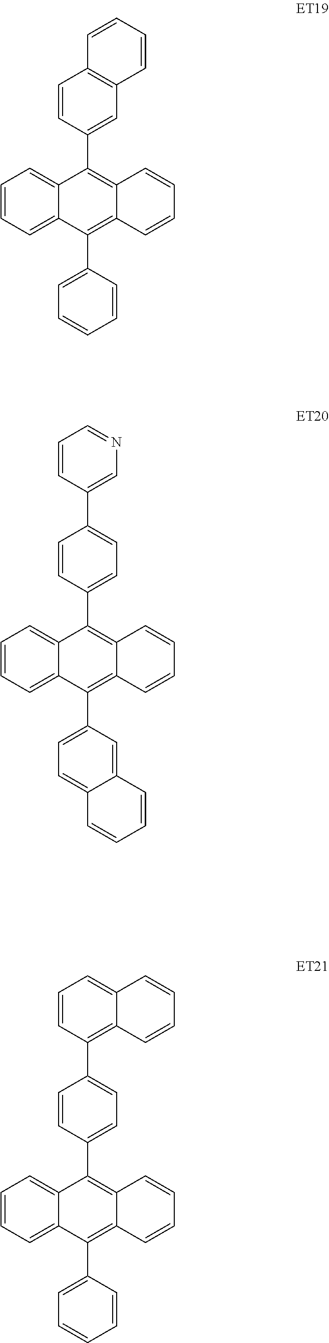

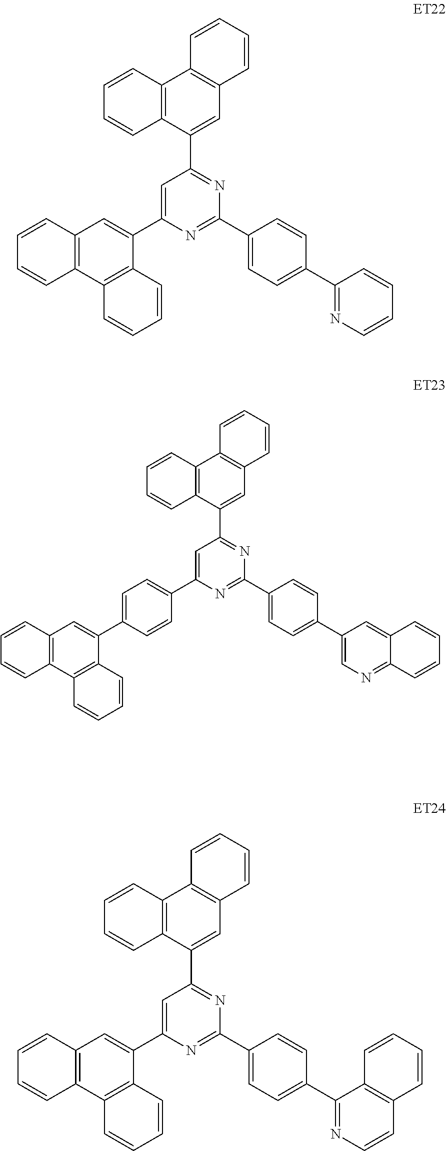 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

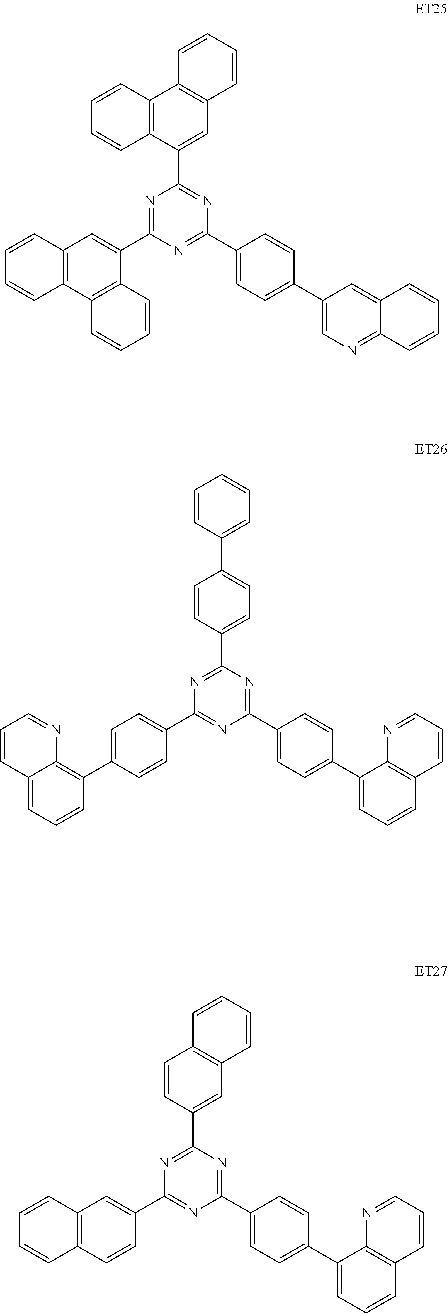 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

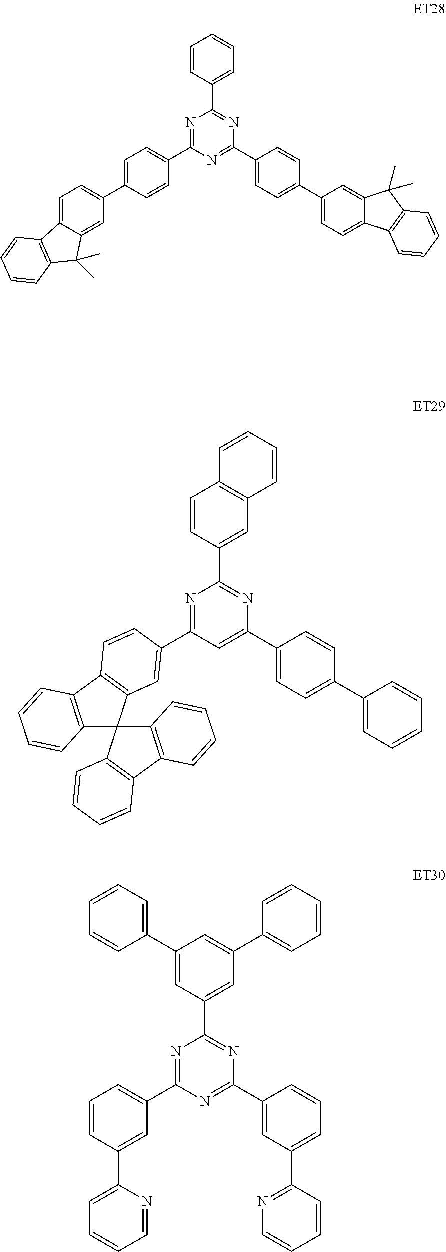 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

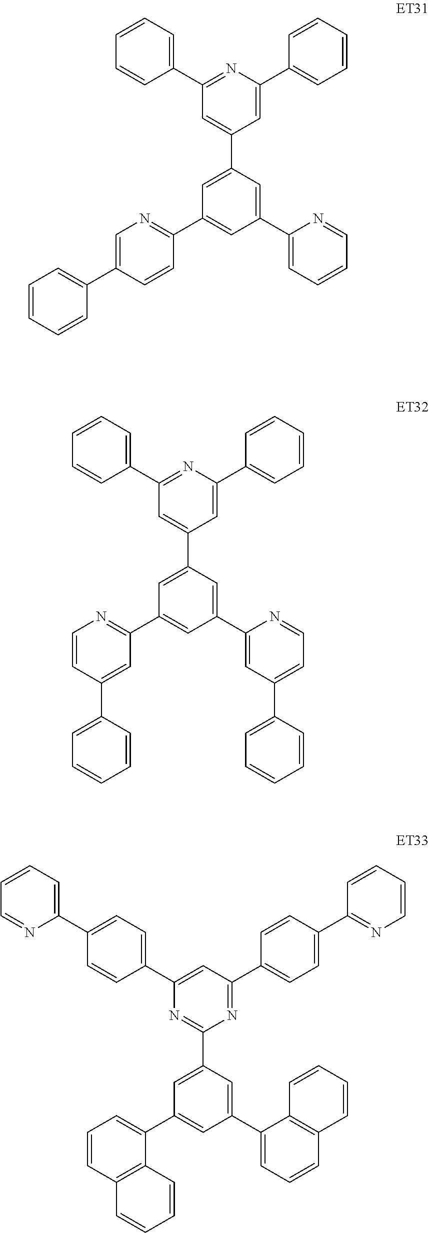 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

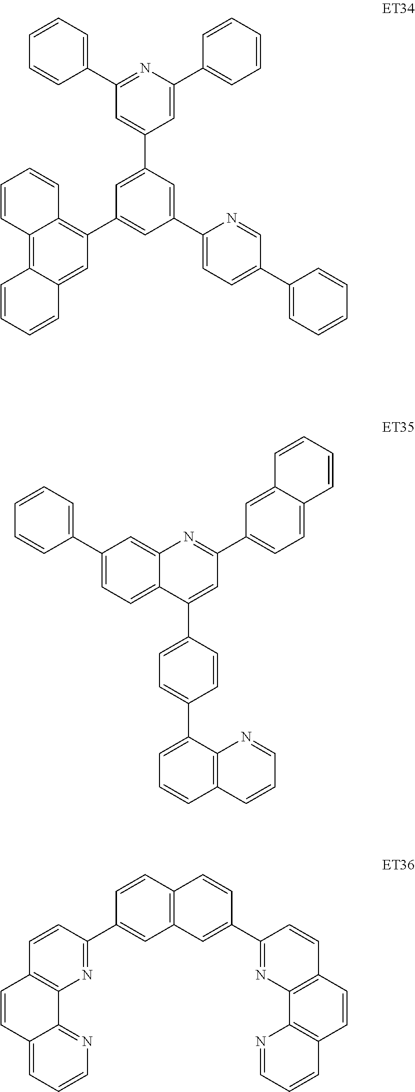 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and KI, a lanthanide metal such as Yb, or a co-depositing material of the metal halide and the lanthanide metal. For example, the electron transport region ETR may include KI:Yb, RbI:Yb, LiF:Yb, and/or the like, as the co-depositing material. In some embodiments, the electron transport region ETR may utilize a metal oxide such as Li₂O and BaO, or 8-hydroxy-lithium quinolate (Liq). However, one or more embodiments of the present disclosure is not limited thereto. The electron transport region ETR also may be formed utilizing a mixture material of an electron transport material and an insulating organo metal salt. The organo metal salt may be a material having an energy band gap of about 4 eV or more. Examples of the organo metal salt may include, for example, metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, one or more embodiments of the present disclosure is not limited thereto.

The electron transport region ETR may include the compounds of the electron transport region in at least one among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the herein-described range, satisfactory electron transport properties may be obtained without substantial increase of a driving voltage. When the electron transport region ETR includes the electron injection layer EIL, the thickness of the electron injection layer EIL may be from about 1 Å to about 100 Å, and from about 3 Å to about 90 Å. When the thickness of the electron injection layer EIL satisfies the herein-described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include (e.g., be formed of) a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). In some embodiments, the second electrode EL2 may have a multilayer structure including a reflective film or a transflective film including (e.g., formed of) the herein-described materials, and a transparent conductive film including (e.g., formed of) ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting device ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, and/or the like.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, the embodiment of the present disclosure is not limited thereto, and the capping layer CPL may include at least one selected from among Compounds P1 to P5:

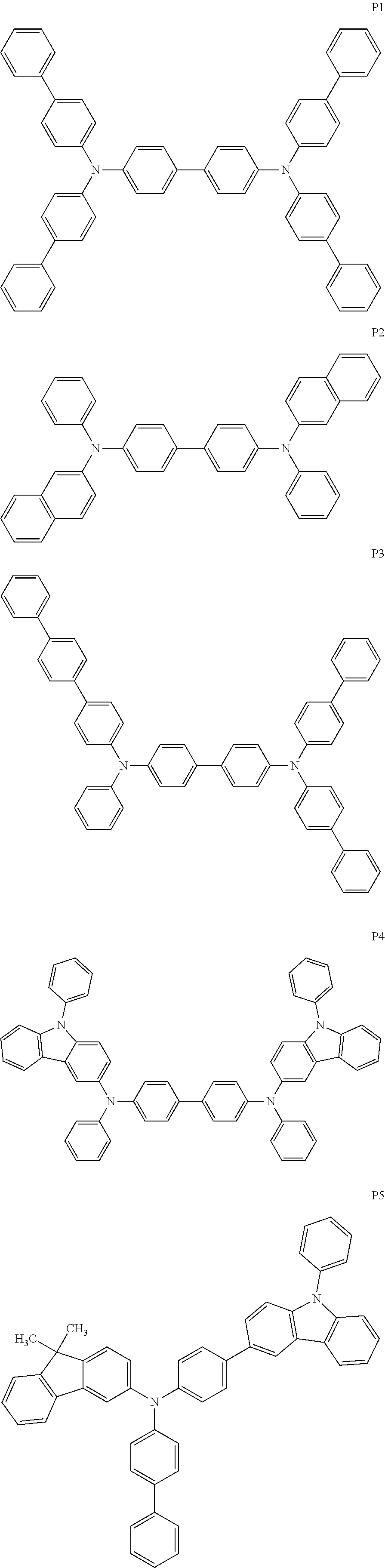

In some embodiments, the refractive index of the capping layer CPL may be about 1.6 or more. For example, the refractive index of the capping layer CPL may be about 1.6 or more with respect to light in a wavelength range of about 550 nm to about 660 nm.

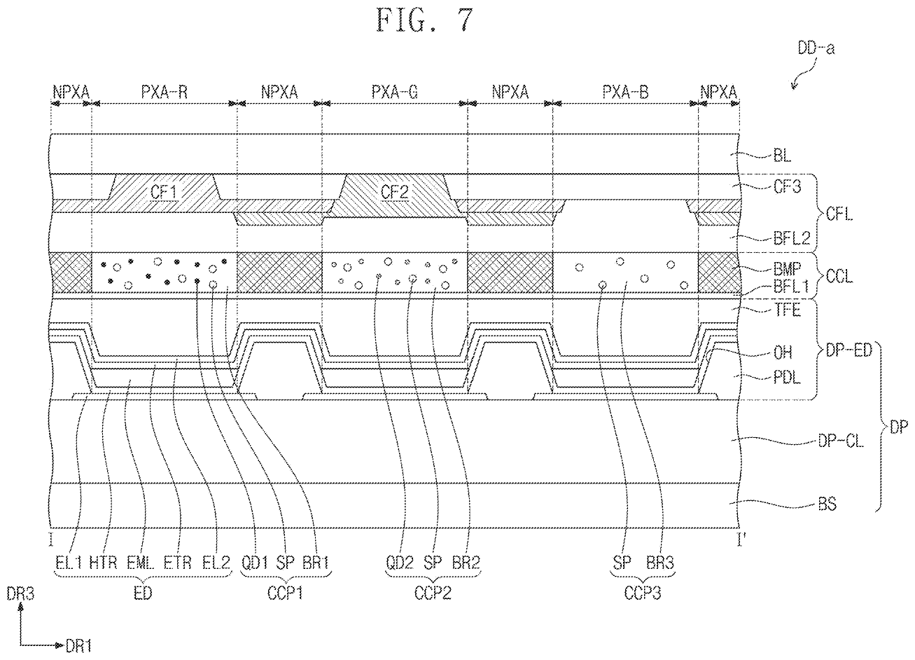

Each of FIGS. 7 to 10 is a cross-sectional view of a display apparatus according to one or more embodiments of the present disclosure. Hereinafter, in describing the display apparatuses of embodiments with reference to FIGS. 7 to 10, the duplicated features which have been described in FIGS. 1 to 6 are not described again, but their differences will be mainly described.

Referring to FIG. 7, the display apparatus DD-a according to one or more embodiments may include a display panel DP including a display element layer DP-ED, a light control layer CCL provided on the display panel DP, and a color filter layer CFL. In one or more embodiments illustrated in FIG. 7, the display panel DP may include a base layer BS, a circuit layer DP-CL provided on the base layer BS, and the display element layer DP-ED, and the display element layer DP-ED may include a light emitting device ED.

The light emitting device ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light emitting devices of FIGS. 3 to 6 as described herein may be equally applied to the structure of the light emitting device ED illustrated in FIG. 7.

Referring to FIG. 7, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit (e.g., configured to emit) light in substantially the same wavelength range. In the display apparatus DD-a of one or more embodiments, the emission layer EML may be to emit (e.g., configured to emit) blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit (e.g., configured to emit) provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 7, divided patterns BMP may be provided between the light control parts CCP1, CCP2 and CCP3 which are spaced and/or apart from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include at least one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3, respectively, in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include (e.g., be formed of) one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may include (e.g., be formed of) a single layer or a plurality of layers.

In the display apparatus DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may include (e.g., be formed of) a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

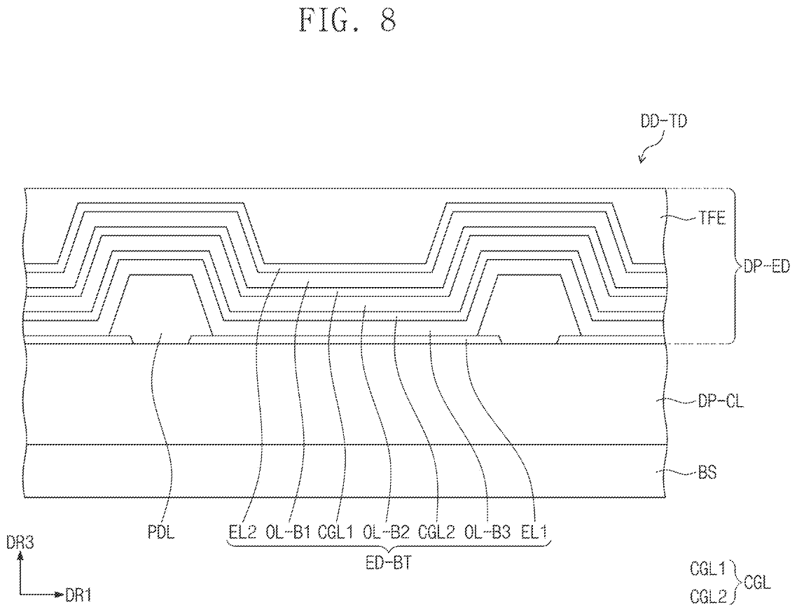

FIG. 8 is a cross-sectional view illustrating a portion of a display apparatus according to one or more embodiments. In the display apparatus DD-TD of one or more embodiments, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR provided with the emission layer EML (FIG. 7) located therebetween.

For example, the light emitting device ED-BT included in the display apparatus DD-TD of one or more embodiments may be a light emitting device having a tandem structure and including a plurality of emission layers.

In one or more embodiments illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may be to emit (e.g., configured to emit) white light.

Charge generation layers CGL1 and CGL2 may be respectively provided between two of the neighboring light emitting structures OL-B1, OL-B2, and OL-B3. The charge generation layers CGL1 and CGL2 may include a p-type or kind charge generation layer and/or an n-type or kind charge generation layer.

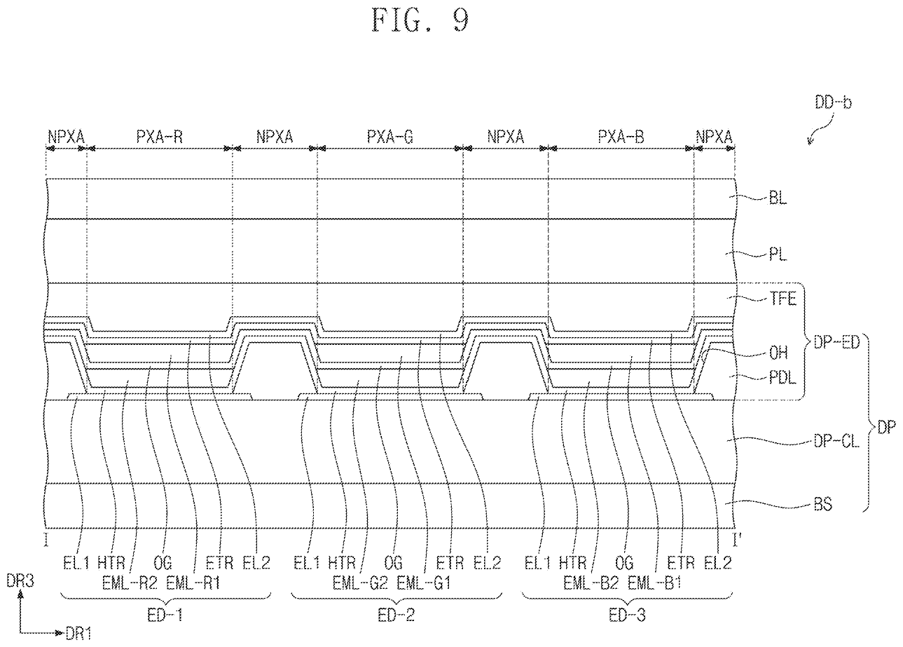

Referring to FIG. 9, the display apparatus DD-b according to one or more embodiments may include light emitting devices ED-1, ED-2, and ED-3 in which two emission layers are stacked. Compared with the display apparatus DD of one or more embodiments illustrated in FIG. 2, one or more embodiments illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R₁ and a second red emission layer EML-R₂. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the hole transport region HTR and the emission auxiliary part OG. The second red emission layer EML-R2, the second green emission layer EML-G2, and the second blue emission layer EML-B2 may be provided between the emission auxiliary part OG and the electron transport region ETR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display element layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display apparatus according to one or more embodiments may not be provided.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions.

The charge generation layers CGL1, CGL2, and CGL3 provided between adjacent light emitting structures OL-B1, OL-B2, OL-B3, and OL-C1 may include a p-type or kind charge generation layer (p-charge generation layer) and/or an n-type or kind charge generation layer (n-charge generation layer).

In one or more embodiments, an electronic apparatus may include a display device including multiple light emitting elements and a control part controlling the display device. The electronic apparatus of one or more embodiments may be an apparatus activated according to electrical signals. The electronic apparatus may include display devices of one or more suitable embodiments. For example, the electronic apparatus may include televisions, monitors, large-size display devices such as outside billboards, personal computers, laptop computers, personal digital terminals, display apparatuses for automobiles, game consoles, portable electronic devices, medium- and small-size display devices such as cameras.

FIG. 11 is a perspective view schematically showing an electronic apparatus EA including the display device according to one or more embodiments. The electronic apparatus EA may include display devices DD-1, DD-2, DD-3 and DD-4.

FIG. 11 is a diagram showing an automobile AM in which first to fourth display devices DD-1, DD-2, DD-3 and DD-4 are provided. At least one among the first to fourth display devices DD-1, DD-2, DD-3 and DD-4 may include configurations as described herein for the display devices DD, DD-TD, DD-a, DD-b and DD-c of embodiments, explained referring to FIGS. 1, 2 and 8 to 11.

In FIG. 11, an automobile AM is shown as an illustration, but this is an illustration, and the first to fourth display devices DD-1, DD-2, DD-3 and DD-4 may be provided in one or more suitable transport refers to such as bicycles, motorcycles, trains, ships, and airplanes. In some embodiments, at least one among the first to fourth display devices DD-1, DD-2, DD-3 and DD-4, including the same configurations as the display devices DD, DD-TD, DD-a, DD-b and DD-c may be employed in personal computers, laptop computers, personal digital terminals, game consoles, portable electronic devices, televisions, monitors, outside billboards, and/or the like. In some embodiments, these are illustrated as embodiments, and the display device may be employed in other electronic apparatuses as long as not deviated from the present disclosure.

At least one among the first to fourth display devices DD-1, DD-2, DD-3 and DD-4 may include the light emitting elements ED described (e.g., explained) referring to FIG. 3 to FIG. 6.

At least one among the first to fourth display devices DD-1, DD-2, DD-3 and DD-4 may include the light emitting elements ED of embodiments explained referring to FIG. 3 to FIG. 6. The light emitting element ED of one or more embodiments may include the compound of one or more embodiments. At least one among the first to fourth display devices DD-1, DD-2, DD-3 and DD-4 may include the light emitting element ED including the compound of one or more embodiments, and may show excellent or suitable display quality.

Referring to FIG. 11, the automobile AM may include a steering wheel HA and a gear GR for the operation of the automobile AM, and a front window GL may be provided to face a driver.

A first display device DD-1 may be provided in a first region overlapping with the steering wheel HA. For example, the first display device DD-1 may be a digital cluster displaying the first information of the automobile AM. The first information may include a first graduation showing the running speed of the automobile AM, and a second graduation showing the number of revolution of an engine (i.e., revolutions per minute (RPM)), and images showing a fuel state. The first graduation and the second graduation may be represented by digital images.

A second display device DD-2 may be provided in a second region facing a driver's seat and overlapping with the front window GL. The driver's seat may be a seat where the steering wheel HA is provided. For example, the second display device DD-2 may be a head up display (HUD) showing the second information of the automobile AM. The second display device DD-2 may be optically clear. The second information may include digital numbers showing the running speed of the automobile AM, and may further include information including the current time, and/or the like. Different from the drawing, the second information of the second display device DD-2 may be projected and displayed on the front window GL.

A third display device DD-3 may be provided in a third region adjacent to the gear GR. For example, the third display device DD-3 may be a center information display (CID) for an automobile, provided between a driver's seat and a passenger seat and showing third information. The passenger seat may be a seat separated from the driver's seat with the gear GR therebetween. The third information may include information on road conditions (for example, navigation information), on playing music or radio, on playing a dynamic image, on the temperature in the automobile AM, and/or the like.

A fourth display device DD-4 may be provided in a fourth region separated from the steering wheel HA and the gear GR, and adjacent to the side of the automobile AM. For example, the fourth display device DD-4 may be a digital wing mirror displaying fourth information. The fourth information may include the external image of the automobile AM, taken by a camera module provided at the outside of the automobile AM. The fourth information may include the external images of the automobile AM.

The herein-described first to fourth information is for illustration, and the first to fourth display devices DD-1, DD-2, DD-3 and DD-4 may further display information on the inside and outside of the automobile. The first to fourth information may include different information from each other. However, one or more embodiments of the present disclosure is not limited thereto, and a portion of the first to fourth information may include the same information.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, referring to embodiments and comparative embodiments, the compound represented by Formula 1 and the light emitting element according to the embodiments of the present disclosure will be explained in particular. In some embodiments, the embodiments are illustrations to assist the understanding of the present disclosure, but the scope of the present disclosure is not limited thereto.

### Examples

### 1. Synthesis of Example Compounds

The synthetic method of the compound according to one or more embodiments will be explained in particular illustrating the synthetic methods of Compounds 1, 20, 79, 111, 204, 240, 320, 355, and 410. In some embodiments, the synthetic methods of the Example Compounds explained hereinafter are embodiments, and the synthetic method of the compound according to one or more embodiments of the present disclosure is not limited to the embodiments.

### (1) Synthesis of Compound 1

Compound 1 may be synthesized by Reaction 1.

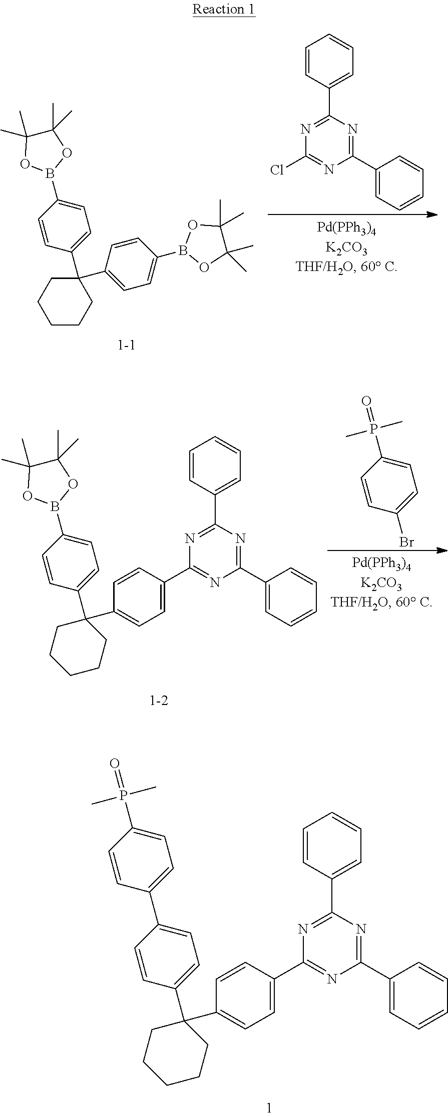

### 1) Synthesis of Intermediate 1-2

Intermediate 1-1 (4.88 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 1-2 (3.02 g, yield: 51%).

### 2) Synthesis of Compound 1

Intermediate 1-2 (5.93 g), Pd(PPh₃)₄ (0.56 g), K₂CO₃ (3.45 g), and (4-bromophenyl)dimethylphosphine oxide (2.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 1 (3.77 g, yield: 61% %%, ESI-LCMS: [M]+: C41H38N3OP, 618.28).

### (2) Synthesis of Compound 20

Compound 20 may be synthesized by Reaction 2.

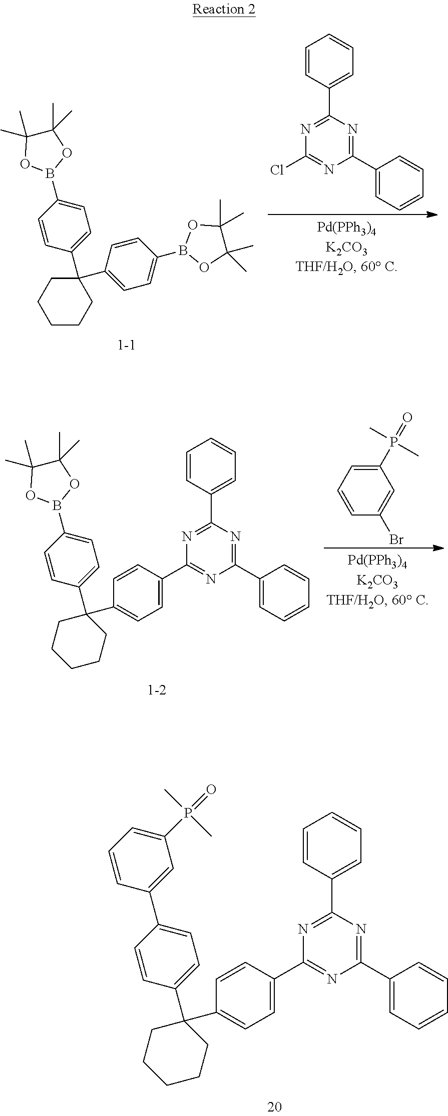

### 1) Synthesis of Intermediate 1-2

Intermediate 1-1 (4.88 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 1-2 (3.02 g, yield: 51%).

### 2) Synthesis of Compound 20

Intermediate 1-2 (5.93 g), Pd(PPh₃)₄ (0.56 g), K₂CO₃ (3.45 g), and (3-bromophenyl)dimethylphosphine oxide (2.33 g) were dissolved in THF/H₂O (100 mL/25 mL) and stirred at about 60° C. for about 12 hours. The temperature of the reaction solution was reduced to room temperature, and the reaction was quenched with water.

The resultant mixture was extracted with ethyl ether three times, and a separated organic layer was dried over anhydrous magnesium sulfate and distilled under a reduced pressure. The residue thus obtained was separated and purified by a column chromatography method to obtain Compound 20 (4.02 g, yield: 65, ESI-LCMS: [M]+: C41H38N3OP, 618.28).

### (3) Synthesis of Compound 79

Compound 79 may be synthesized by Reaction 3.

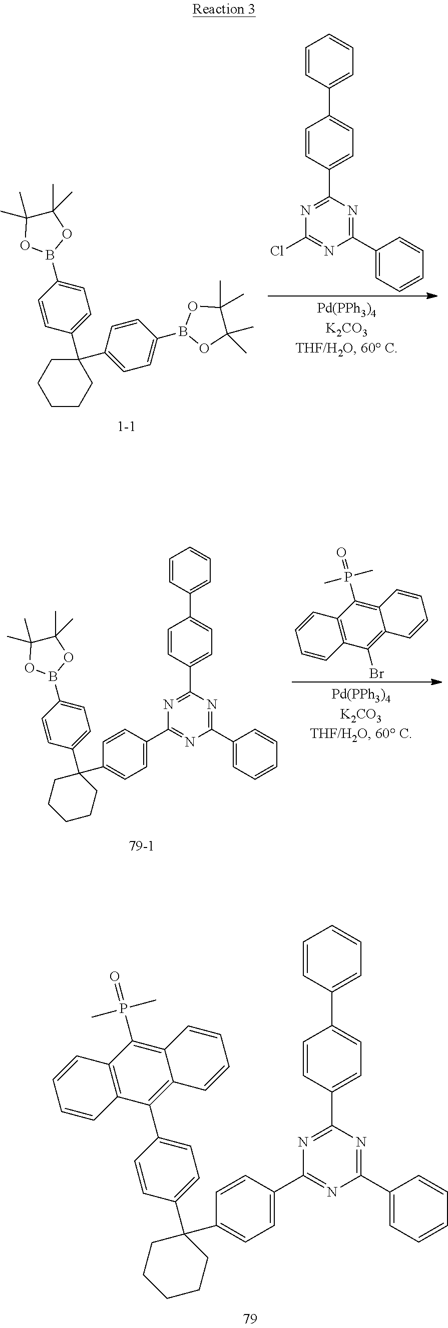

### 1) Synthesis of Intermediate 79-1

Intermediate 1-1 (4.88 g), Pd(PPh₃)₄ (0.56 g), K₂CO₃ (3.45 g), and 2-([1,1′-biphenyl]-4-yl)-4-chloro-6-phenyl-1,3,5-triazine (3.43 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 79-1 (4.68 g, yield: 70%).

### 2) Synthesis of Compound 79

Intermediate 79-1 (6.69 g), Pd(PPh₃)₄ (0.56 g), K₂CO₃ (3.45 g), and (10-bromoanthracen-9-yl)dimethylphosphine oxide (3.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 79 (5.08 g, yield: 64%, ESI-LCMS: [M]+: C55H46N3OP, 794.34).

### (4) Synthesis of Compound 111

Compound 111 may be synthesized by Reaction 4.

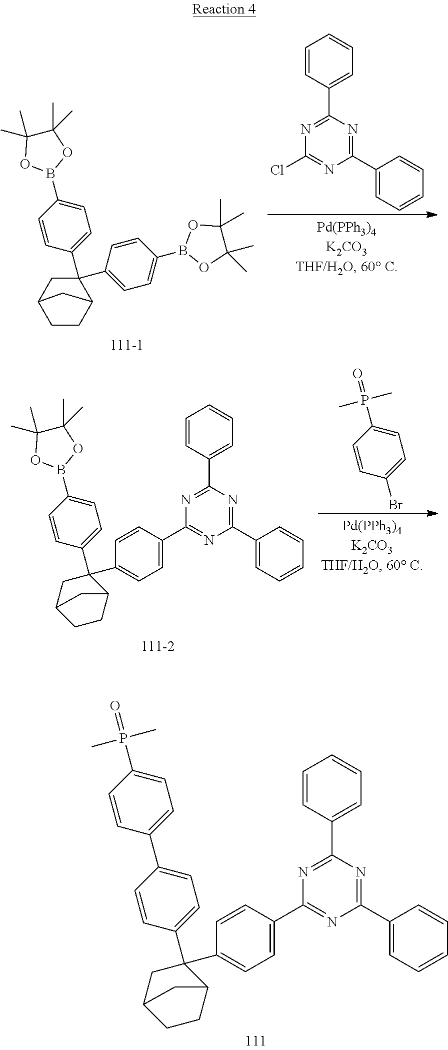

### 1) Synthesis of Intermediate 111-2

Intermediate 111-1 (5.00 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 111-2 (3.56 g, yield: 59%).

### 2) Synthesis of Compound 111

Intermediate 111-2 (6.05 g), Pd(PPh₃)₄ (0.56 g), K₂CO₃ (3.45 g), and (10-bromoanthracen-9-yl)dimethylphosphine oxide (3.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 111 (4.61 g, yield: 73%, ESI-LCMS: [M]+: C42H38N3OP, 630.28).

### (5) Synthesis of Compound 204

Compound 204 may be synthesized by Reaction 5.

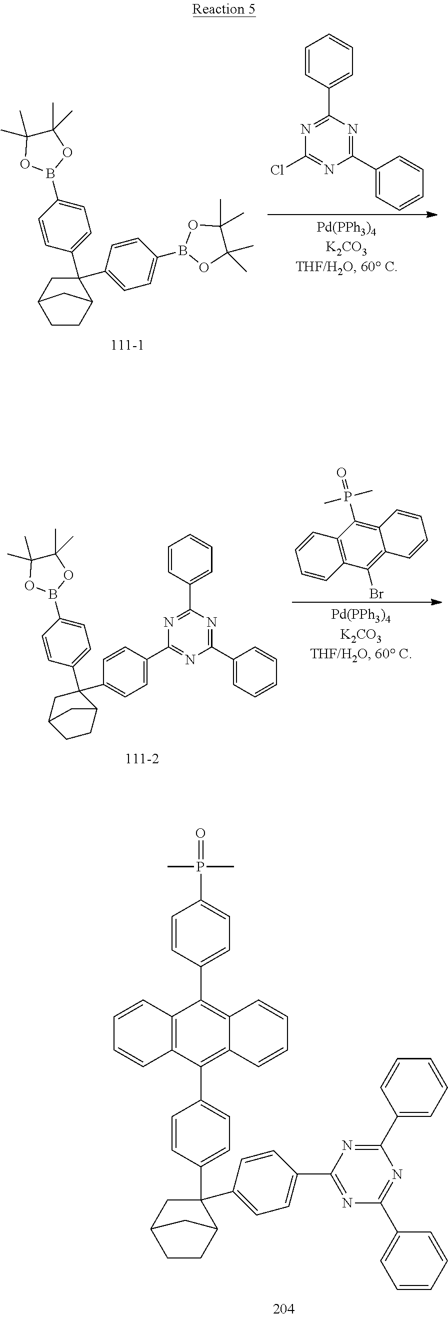

### 1) Synthesis of Intermediate 111-2

Intermediate 111-1 (5.00 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 111-2 (3.56 g, yield: 59%).

### 2) Synthesis of Compound 204

Intermediate 111-2 (6.05 g), Pd(PPh₃)₄ (0.56 g), K₂CO₃ (3.45 g), and (10-bromoanthracen-9-yl)dimethylphosphine oxide (3.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 204 (5.16 g, yield: 64%, ESI-LCMS: [M]+: C56H46N3OP, 806.34).

### (6) Synthesis of Compound 240

Compound 240 may be synthesized by Reaction 6.

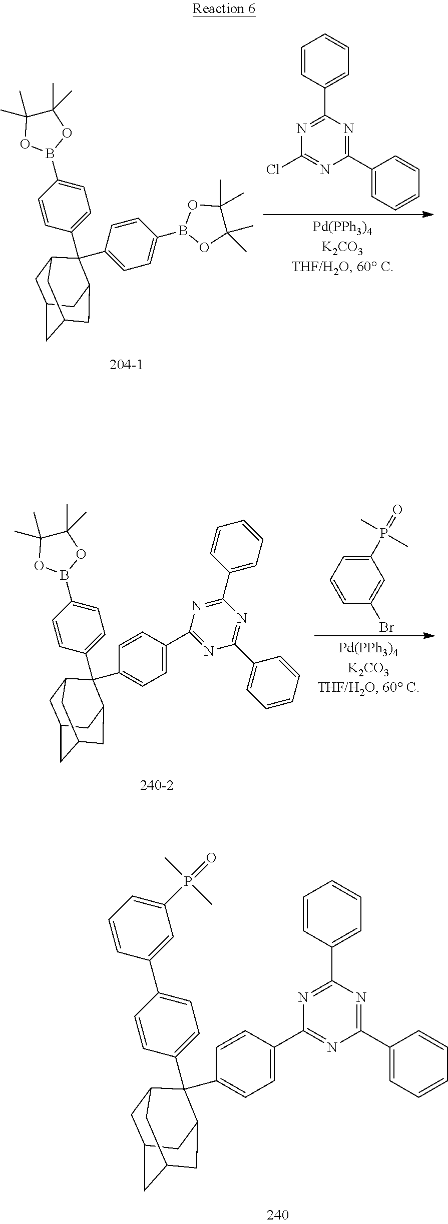

### 1) Synthesis of Intermediate 240-2

Intermediate 240-1 (5.40 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 240-2 (4.15 g, yield: 70%).

### 2) Synthesis of Compound 240

Intermediate 240-2 (6.45 g), Pd(PPh₃)₄ (0.56 g), K₂CO₃ (3.45 g), and (3-bromophenyl)dimethylphosphine oxide (2.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 240 (4.22 g, yield: 63%, ESI-LCMS: [M]+: C45H42N3OP, 670.31).

### (7) Synthesis of Compound 320

Compound 320 may be synthesized by Reaction 7.

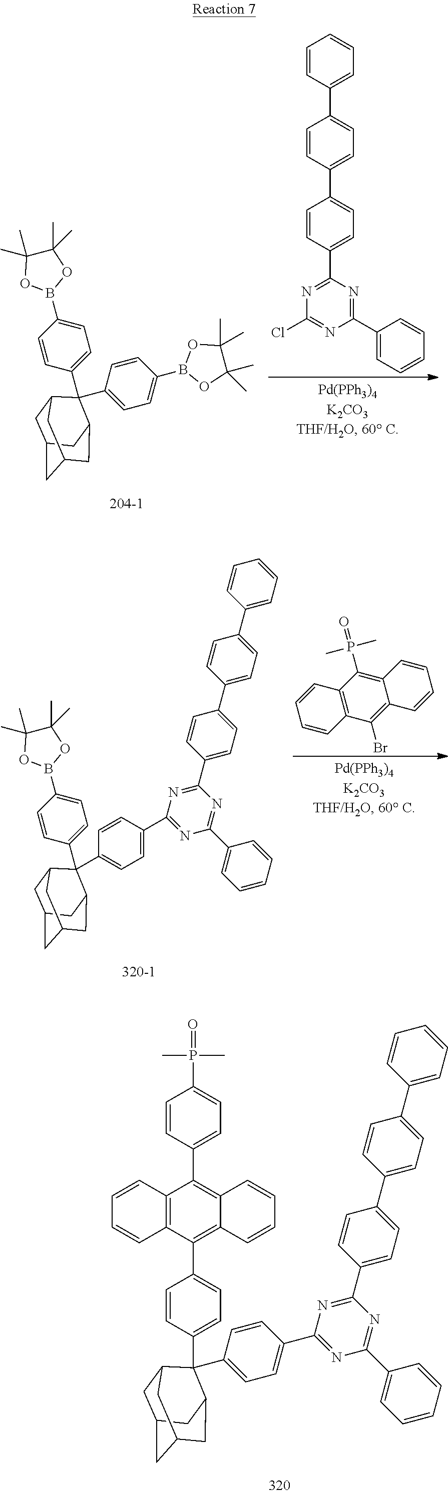

### 1) Synthesis of Intermediate 320-1

Intermediate 240-1 (5.40 g), Pd(PPh₃)₄ (0.56 g), K₂CO₃ (3.45 g), and 2-([1,1′: 4′,1″-terphenyl]-4-yl)-4-chloro-6-phenyl-1,3,5-triazine (4.19 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 320-1 (4.86 g, yield: 61%).

### 2) Synthesis of Compound 320

Intermediate 320-1 (7.97 g), Pd(PPh₃)₄ (0.56 g), K₂CO₃ (3.45 g), and (10-bromoanthracen-9-yl)dimethylphosphine oxide (3.33 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 320 (6.22 g, yield: 62%, ESI-LCMS: [M]+: C71H58N3OP, 998.43).

### (8) Synthesis of Compound 355

Compound 355 may be synthesized by Reaction 8.

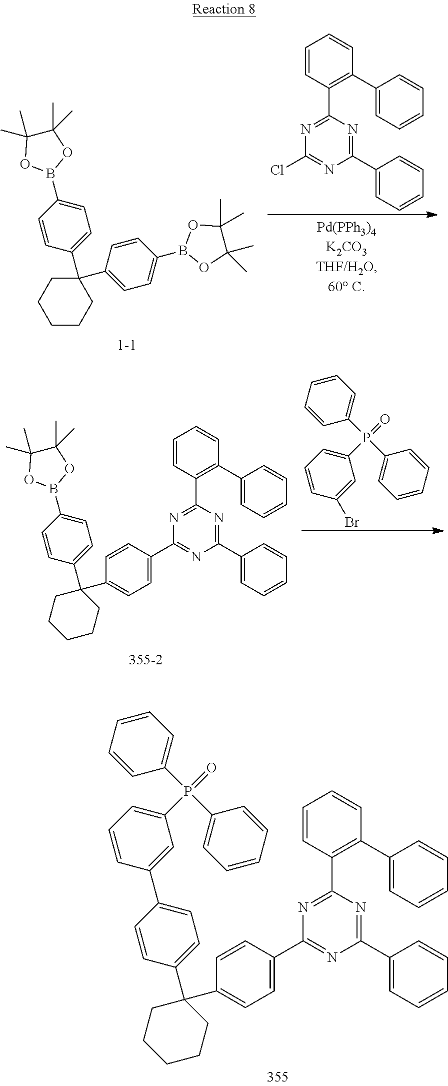

### 1) Synthesis of Intermediate 355-2

Intermediate 1-1 (4.88 g), Pd(PPh₃)₄ (0.56 g), K₂CO₃ (3.45 g), and 2-([1,1′-biphenyl]-2-yl)-4-chloro-6-phenyl-1,3,5-triazine (3.43 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 355-2 (3.94 g, yield: 59%).

### 2) Synthesis of Compound 355

Intermediate 355-2 (6.69 g), Pd(PPh₃)₄ (0.56 g), K₂CO₃ (3.45 g), and (3-bromophenyl)diphenylphosphine oxide (3.57 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 355 (4.58 g, yield: 56% %, ESI-LCMS: [M]+: C57H46N3OP, 818.34).

### (9) Synthesis of Compound 410

Compound 410 may be synthesized by Reaction 9.

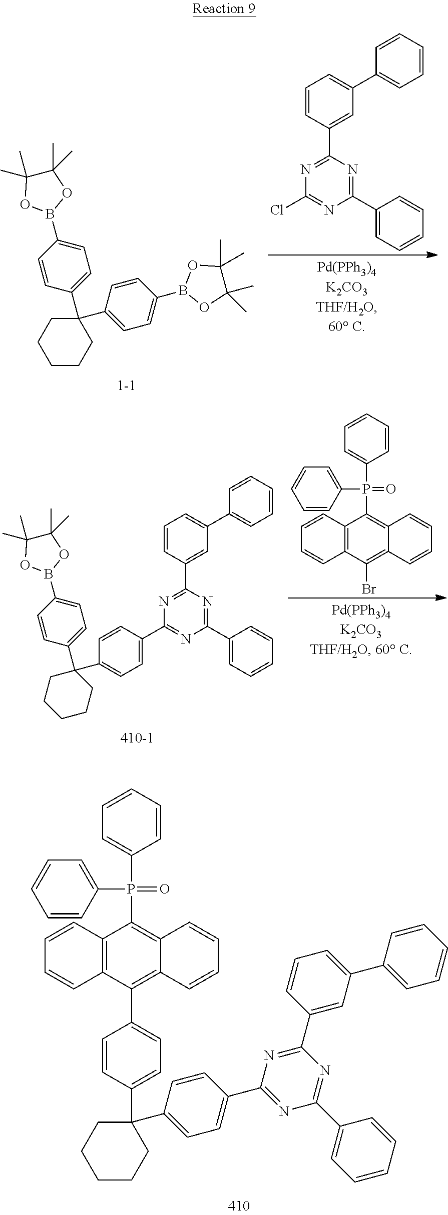

### 1) Synthesis of Intermediate 410-1

Intermediate 1-1 (4.88 g), Pd(PPh₃)₄ (0.56 g), K₂CO₃ (3.45 g), and 2-([1,1′-biphenyl]-3-yl)-4-chloro-6-phenyl-1,3,5-triazine (3.43 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Intermediate 410-1 (3.88 g, yield: 58%).

### 2) Synthesis of Compound 410

Intermediate 410-1 (6.69 g), Pd(PPh₃)₄ (0.56 g), K₂CO₃ (3.45 g), and (10-bromoanthracen-9-yl)diphenylphosphine oxide (4.57 g) were dissolved in THF/H₂O (100 mL/25 mL) and stirred at about 60° C. for about 12 hours. The temperature of the reaction solution was reduced to room temperature, and the reaction was quenched with water. The resultant mixture was extracted with ethyl ether three times, and a separated organic layer was dried over anhydrous magnesium sulfate and distilled under a reduced pressure. The residue thus obtained was separated and purified by a column chromatography method to obtain Compound 410 (6.62 g, yield: 72%, ESI-LCMS: [M]+: C65H50N3OP, 918.37).

### 2. Manufacture and Evaluation of the Properties of Light Emitting Elements

### (1) Manufacture of Light Emitting Elements

Light emitting elements of embodiments including the compounds of an embodiment in the electron transport layers were manufactured by a method described herein. The light emitting elements of Examples 1 to 9 were manufactured utilizing Example Compounds 1, 20, 79, 111, 204, 240, 320, 355 and 410 as the materials of the electron transport layers. Comparative Examples 1 to 5 corresponded to light emitting elements utilizing Comparative Compounds C1 to C5 as the materials of the electron transport layers.

The method of manufacturing the light emitting element of Example 1 is as follows.

As a first electrode, a glass substrate on which an ITO electrode of about 15 ohm per square centimeter (Ω/cm²) (a thickness of 1200 Å) was formed (product of Corning Co.) was cut into a size of 50 millimeter (mm)×50 mm×0.7 mm, washed by ultrasonic waves utilizing isopropyl alcohol and distilled water for about 5 minutes each, and cleaned by irradiating ultraviolet rays for about 30 minutes and then, ozone. After that, the ITO glass substrate was installed in a vacuum deposition apparatus.

On the first electrode, a hole injection layer with a thickness of about 300 Å was formed by depositing NPD, and on the hole injection layer, a hole transport layer with a thickness of about 200 Å was formed by depositing H-1-1. On the hole transport layer, an emission auxiliary layer with a thickness of about 100 Å was formed by depositing CzSi.

On the emission auxiliary layer, a mixture of HT3 and ETH66 in a weight ratio of 1:1 as a host material, AD-38 as a sensitizer, and t-DABNA as a dopant material were co-deposited in a weight ratio of about 64:15:1 to form an emission layer EML with a thickness of about 200 Å. On the emission layer, a hole blocking layer with a thickness of about 200 Å was formed by depositing TSPO1. Then, on the hole blocking layer, an electron transport layer with a thickness of about 300 Å was formed by depositing Example Compound 1, and on the electron transport layer, an electron injection layer with a thickness of about 10 Å was formed by depositing LiF. Then, on the electron injection layer, Al was deposited to form a second electrode with a thickness of about 3000 Å, to form a light emitting element.

The compounds utilized for the manufacture of the light emitting elements of Examples 2 to 9 and Comparative Examples 1 to 5 are shown in Table 1, and other conditions were the same as for the light emitting element of Example 1.

### Example Compounds

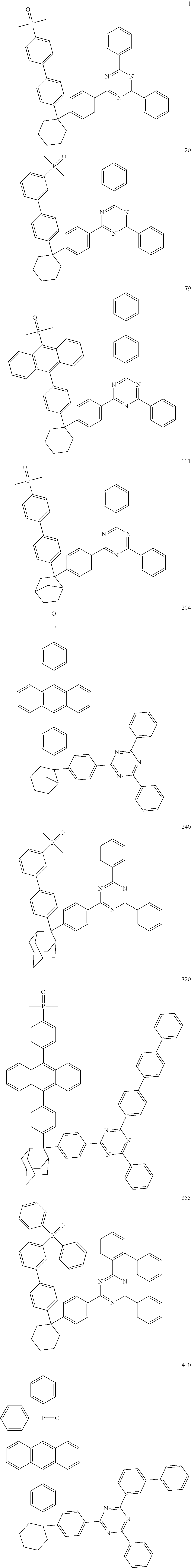

### Comparative Compounds

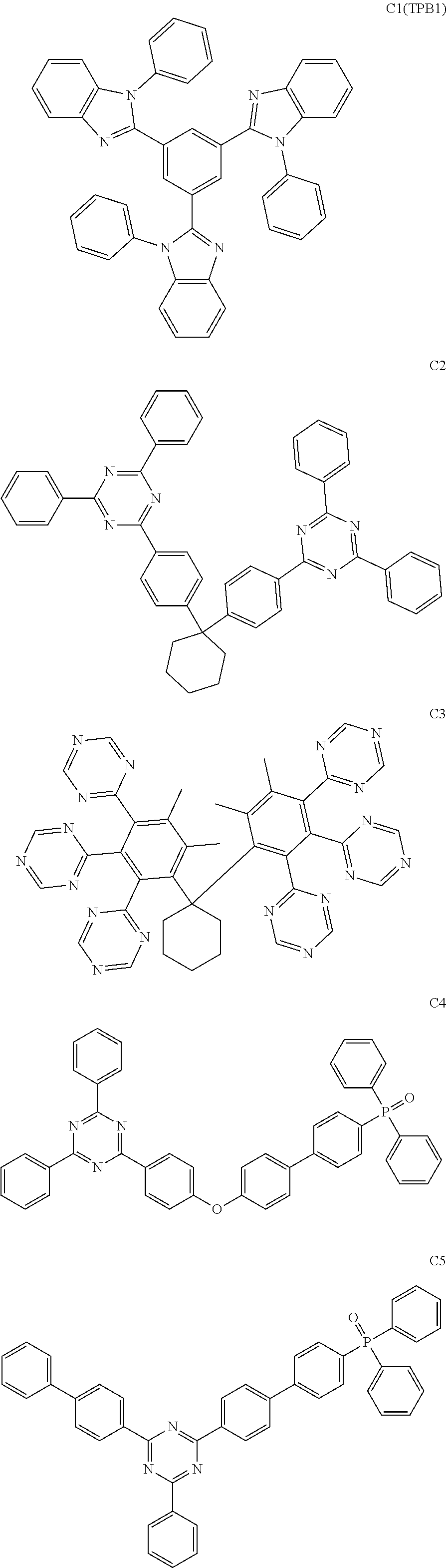 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2nc(-c3ccccc3)nc(-c3ccc(C4(c5ccc(-c6nc(-c7ccccc7)nc(-c7ccccc7)n6)cc5)CCCCC4)cc3)n2)cc1 ; Cc1c(C)c(C2(c3c(C)c(C)c(-c4ncncn4)c(-c4ncncn4)c3-c3ncncn3)CCCCC2)c(-c2ncncn2)c(-c2ncncn2)c1-c1ncncn1 ; O=P(c1ccccc1)(c1ccccc1)c1ccc(-c2ccc(Oc3ccc(-c4nc(-c5ccccc5)nc(-c5ccccc5)n4)cc3)cc2)cc1 ; O=P(c1ccccc1)(c1ccccc1)c1ccc(-c2ccc(-c3nc(-c4ccccc4)nc(-c4ccc(-c5ccccc5)cc4)n3)cc2)cc1]

### Functional Layer Compounds

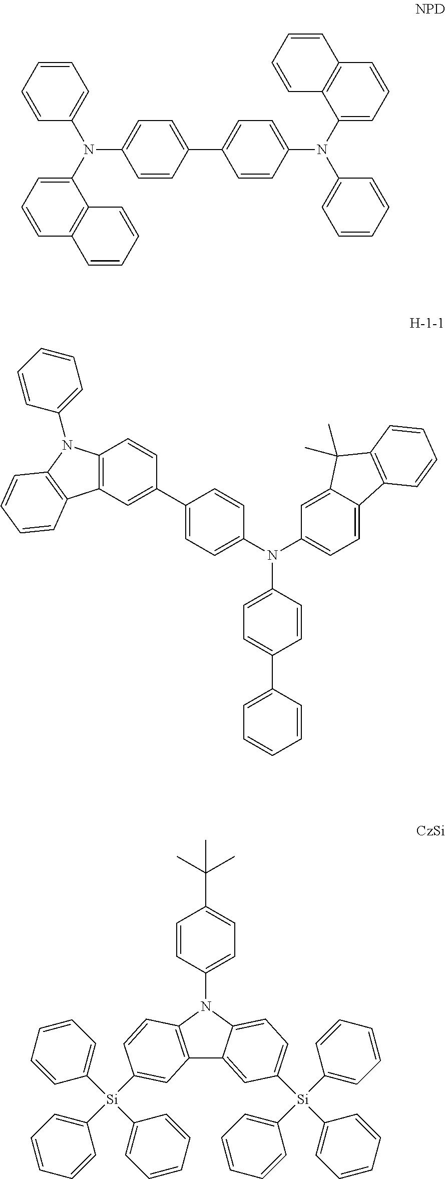 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

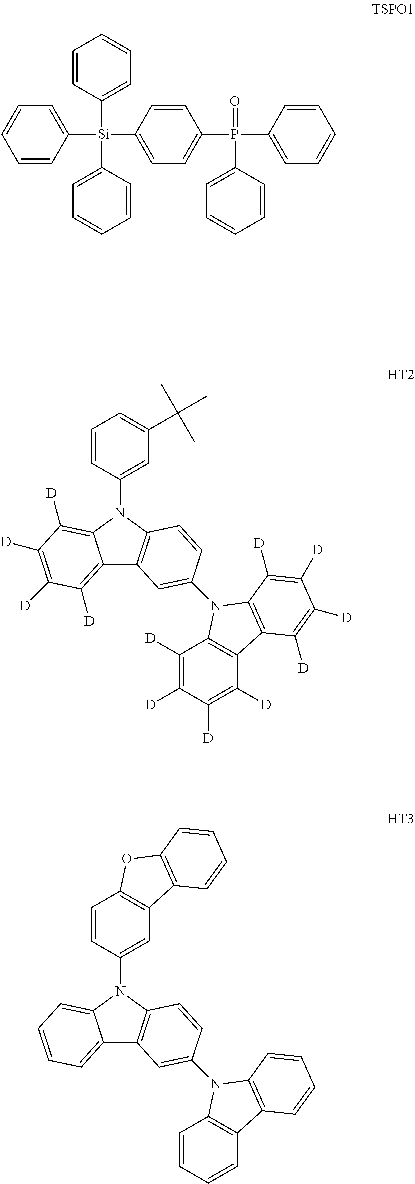 [SMILES: O=P(c1ccccc1)(c1ccccc1)c1ccc([Si](c2ccccc2)(c2ccccc2)c2ccccc2)cc1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

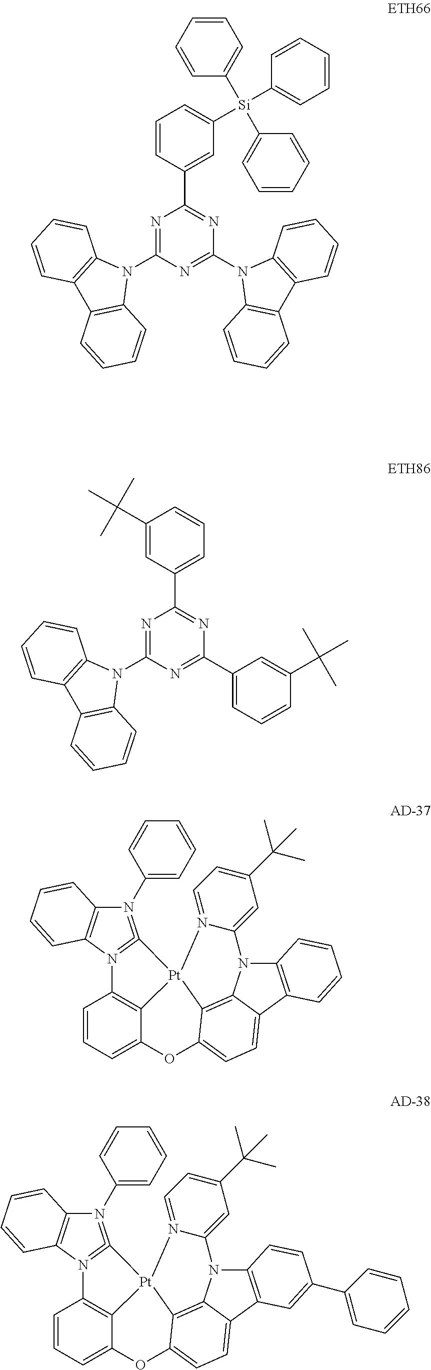

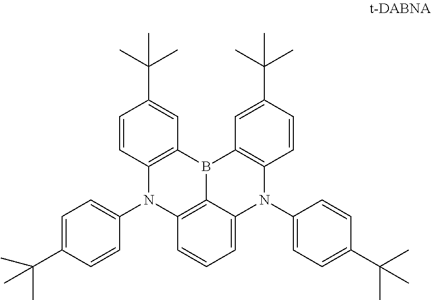 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

### (2) Evaluation of Properties of Light Emitting Elements

The properties of the light emitting elements of Examples 1 to 9 and Comparative Examples 1 to 5 were evaluated. In Table 1, the evaluation results of the light emitting elements of Examples 1 to 9 and Comparative Examples 1 to 5 are shown.

In order to evaluate the properties of the light emitting elements of Examples to 9 and Comparative Examples 1 to 5, driving voltages (V) at a current density of about 1000 (candela per square meter (cd/m²)), emission efficiency (candela per ampere (cd/A)), and lifetime (T95) were measured utilizing Keithley MU 236 and a luminance meter PR650. The lifetime (T95) was obtained by measuring a time consumed to reach about 95% luminance in contrast to an initial luminance. Relative lifetime was calculated based on the light emitting element of Comparative Example 1, and the results are shown in Table 1.

TABLE 1

| | | | | | | Rel- |
|---|---|---|---|---|---|---|
| | Host | | | Driv- | | ative |
| | (1:1 | | Electron | ing | Effi- | life- |
| | wt. | Sen- | transport | voltage | ciency | time |
| | ratio) | sitizer | layer | (V) | (Cd/A) | (T95) |
| Example 1 | HT3/ | AD-38 | Compound | 4.4 | 26.3 | 5.5 |
| | ETH66 | | 1 | | | |
| Example 2 | HT3/ | AD-38 | Compound | 4.5 | 26.5 | 5.7 |
| | ETH66 | | 20 | | | |
| Example 3 | HT3/ | AD-38 | Compound | 4.5 | 27.1 | 4.4 |
| | ETH66 | | 79 | | | |
| Example 4 | HT3/ | AD-38 | Compound | 4.5 | 24.9 | 6.1 |
| | ETH66 | | 111 | | | |
| Example 5 | HT3/ | AD-38 | Compound | 4.4 | 26.1 | 4.7 |
| | ETH66 | | 204 | | | |
| Example 6 | HT3/ | AD-38 | Compound | 4.6 | 26.4 | 5.3 |
| | ETH66 | | 240 | | | |
| Example 7 | HT3/ | AD-38 | Compound | 4.6 | 25.3 | 4.5 |
| | ETH66 | | 320 | | | |
| Example 8 | HT2/ | AD-37 | Compound | 4.5 | 24.5 | 4.2 |
| | ETH86 | | 355 | | | |
| Example 9 | HT2/ | AD-37 | Compound | 4.6 | 24.8 | 3.7 |
| | ETH86 | | 410 | | | |
| Comparative | HT3/ | AD-38 | C1 (TPBI) | 5.6 | 18.8 | 1 |
| Example 1 | ETH66 | | | | | |
| Comparative | HT3/ | AD-38 | C2 | 4.8 | 22.3 | 3.0 |
| Example 2 | ETH66 | | | | | |
| Comparative | HT3/ | AD-38 | C3 | 8.8 | 19.5 | 1.5 |
| Example 3 | ETH66 | | | | | |
| Comparative | HT3/ | AD-38 | C4 | 5.7 | 20.1 | 2.2 |
| Example 4 | ETH66 | | | | | |
| Comparative | HT3/ | AD-38 | C5 | 5.6 | 21.1 | 2.4 |
| Example 5 | ETH66 | | | | | |

Referring to Table 1, the light emitting elements of Examples 1 to 9, applying the compounds according to embodiments of the present disclosure as the electron transport layer materials, showed low driving voltages, high emission efficiency and long lifetime characteristics when compared to the light emitting elements of Comparative Examples 1 to 5.

The Example Compounds include a core structure in which two phenylene groups are connected via a cycloalkyl group. In the Example Compounds, because two phenylene groups are connected via a cycloalkyl group, the conjugation structure of each of two phenylene groups may be discontinued. Accordingly, the Example Compounds may have high triplet energy, and accordingly the quenching of excitons produced in an emission layer in an electron transport layer may be prevented or reduced.

In some embodiments, the Example Compounds include both (e.g., simultaneously) a phosphine oxide group and a triazine group, bonded to the core structure. Because the Example Compounds include the phosphine oxide group and the triazine group concurrently (e.g., simultaneously), high charge transport capacity may be shown.

Accordingly, the light emitting elements of Examples 1 to 9 may exhibit the element properties of low driving voltages, high emission efficiencies and long lifetimes.

In contrast, Comparative Compound C1 (TPBI) which is applied in the electron transport layer of Comparative Example 1 does not include a cycloalkyl group in a core structure, and a conjugation structure is not discontinued, and thus, excitons produced in an emission layer are quenched in the electron transport layer, and it may be observed that emission efficiency and lifetime are low. In some embodiments, Comparative Compound C1 (TPBI) does not include a phosphine oxide group and a triazine group as substituents, and it may be observed that charge transport capacity is low, and a driving voltage is high.

In some embodiments, Comparative Compounds C2 and C3, applied in the electron transport layers of Comparative Examples 2 and 3 include only a triazine group but do not include a phosphine oxide group as a substituent. Accordingly, it may be observed that electron transport capacity is low, and element properties are low.

In some embodiments, in Comparative Compounds C4 and C5, applied in the electron transport layers of Comparative Examples 4 and 5, two phenylene groups included in the core structure are not connected via a cycloalkyl group. In Comparative Compound C4, two phenylene groups are connected via an oxygen atom, and it may be observed that the lowest unoccupied molecular orbital (LUMO) level increases, charge transport capacity to an emission layer is deteriorated, and element properties are not good or suitable. In Comparative Compound C5, two phenylene groups are connected via a direct linkage, and a conjugation structure is not discontinued, triplet energy is low, and excitons provided from the emission layer are quenched. Accordingly, it may be observed that element properties are low.

The light emitting element of one or more embodiments may show the element properties of a low driving voltage, high emission efficiency and long lifetime.

The compound of one or more embodiments is included in the electron transport layer of a light emitting element and may contribute to the improvement of the emission efficiency and the lifetime of the light emitting element.

The display device of one or more embodiments may show excellent or suitable display quality.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed.

Accordingly, the technical scope of the present disclosure is not intended to be limited to the contents set forth in the detailed description of the specification, but is intended to be defined by the appended claims and equivalents thereof.

1. A light emitting element comprising:
a first electrode;
a second electrode on the first electrode; and
at least one functional layer comprising a compound represented by Formula 1, and between the first electrode and the second electrode: 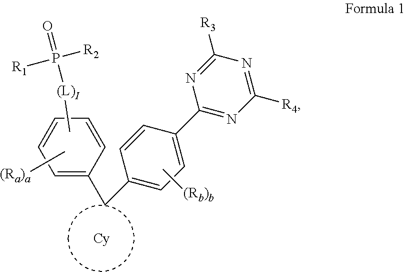
wherein, in Formula 1,
Cy is a substituted or unsubstituted cycloalkyl group of 3 to 30 ring-forming carbon atoms,
L is a substituted or unsubstituted arylene group of 6 to 30 ring-forming carbon atoms, or a substituted or unsubstituted heteroarylene group of 2 to 30 ring-forming carbon atoms,
R₁ to R₄ are each independently a substituted or unsubstituted alkyl group of 1 to 10 carbon atoms, or a substituted or unsubstituted aryl group of 6 to 30 ring-forming carbon atoms,
Rₐ and R_{b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“a” and “b” are each independently an integer of 0 to 4, and
“l” is 1 or 2.

2. The light emitting element of claim 1, wherein Formula 1 is represented by at least one selected from among Formula 1-1a to Formula 1-1c: 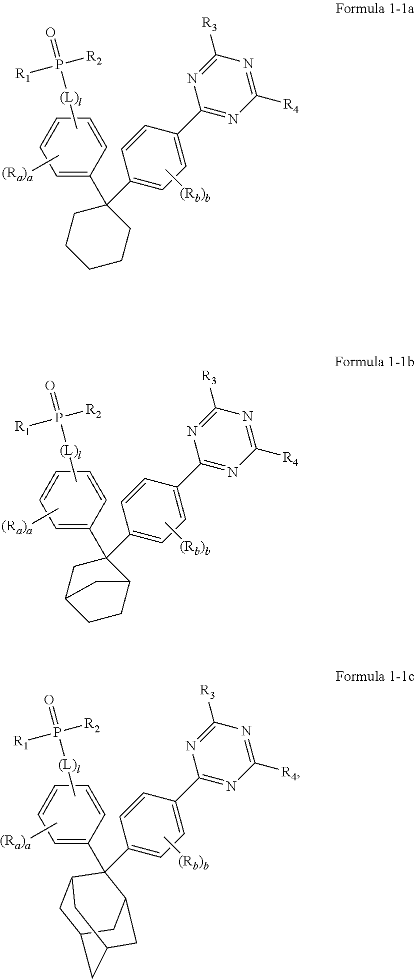
and
in Formula 1-1a to Formula 1-1c,
L, R₁ to R₄, Rₐ, R_{b}, “a”, “b”, and “l” are as defined in Formula 1.

3. The light emitting element of claim 1, wherein R₁ and R₂ are each independently an unsubstituted methyl group or an unsubstituted phenyl group.

4. The light emitting element of claim 1, wherein R₃ and R₄ are each independently an unsubstituted phenyl group, an unsubstituted biphenyl group, an unsubstituted terphenyl group, an unsubstituted naphthyl group, an unsubstituted anthracenyl group, or an anthracenyl group substituted with a phenyl group.

5. The light emitting element of claim 1, wherein L is an unsubstituted phenylene group, an unsubstituted naphthalene group, or an unsubstituted anthracene group.

6. The light emitting element of claim 1, wherein Formula 1 is represented by Formula 1-2a or Formula 1-2b: 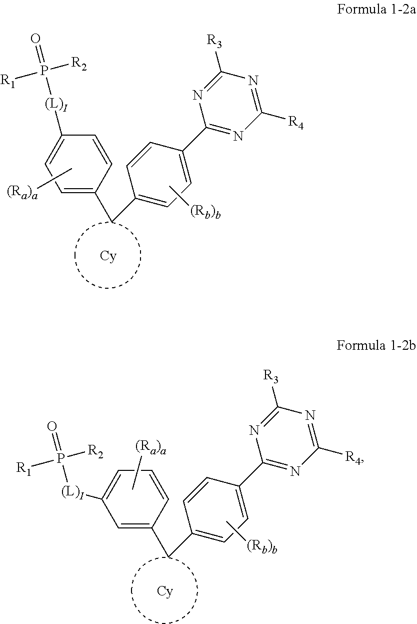
and
in Formula 1-2a and Formula 1-2b,
Cy, L, R₁ to R₄, Rₐ, R_{b}, “a”, “b”, and “l” are as defined in Formula 1.

7. The light emitting element of claim 1, wherein each Rₐ and R_{b} is a hydrogen atom.

8. The light emitting element of claim 1, wherein the at least one functional layer comprises at least one compound selected from among Compound Group 1:
Compound Group 1

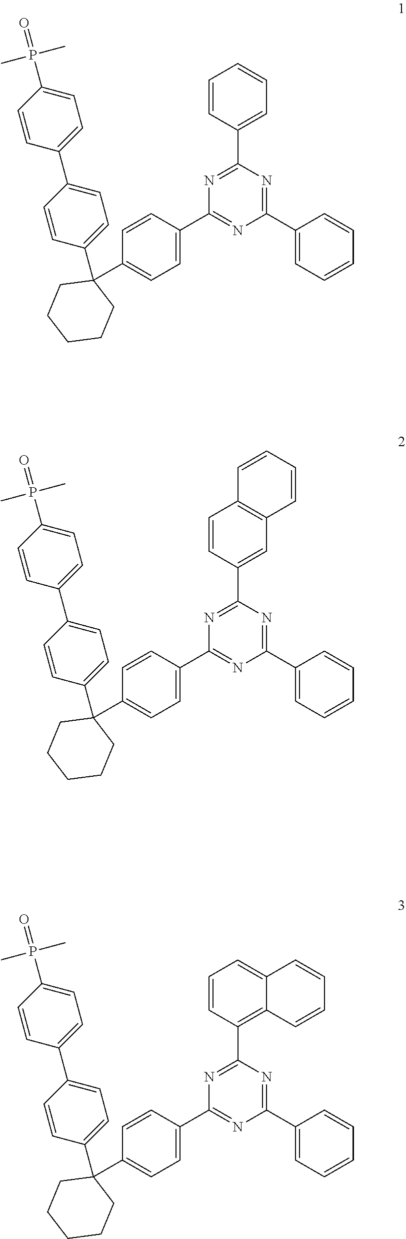 [SMILES: CP(C)(=O)c1ccc(-c2ccc(C3(c4ccc(-c5nc(-c6ccccc6)nc(-c6ccccc6)n5)cc4)CCCCC3)cc2)cc1 ; CP(C)(=O)c1ccc(-c2ccc(C3(c4ccc(-c5nc(-c6ccccc6)nc(-c6ccc7ccccc7c6)n5)cc4)CCCCC3)cc2)cc1 ; CP(C)(=O)c1ccc(-c2ccc(C3(c4ccc(-c5nc(-c6ccccc6)nc(-c6cccc7ccccc67)n5)cc4)CCCCC3)cc2)cc1]

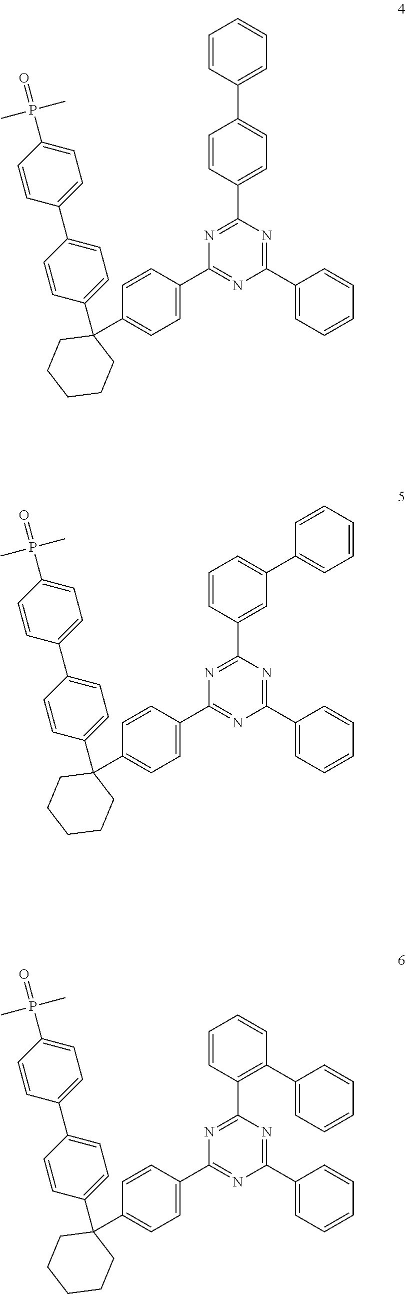 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccccc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccccc6)nc(-c6ccccc6-c6ccccc6)n5)cc4)CCCCC3)cc2)cc1]

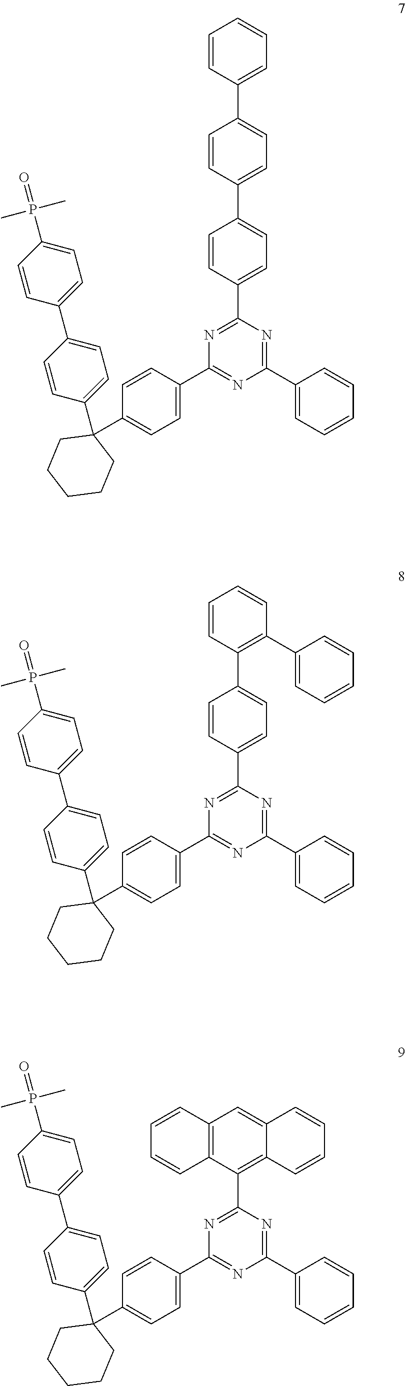 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)cc1 ; CP(C)(=O)c1ccc(-c2ccc(C3(c4ccc(-c5nc(-c6ccccc6)nc(-c6c7ccccc7cc7ccccc67)n5)cc4)CCCCC3)cc2)cc1]

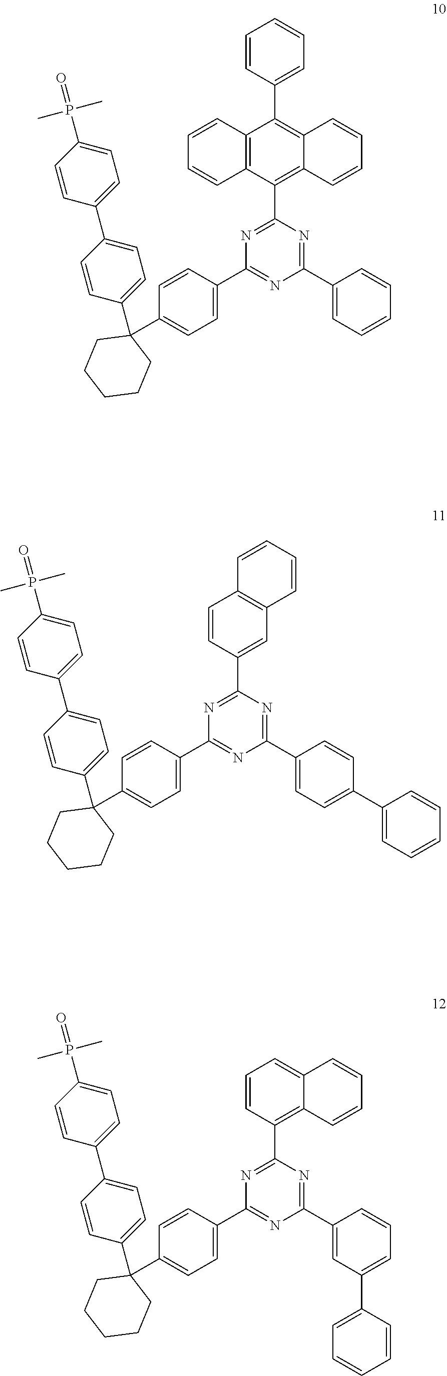 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)cc1]

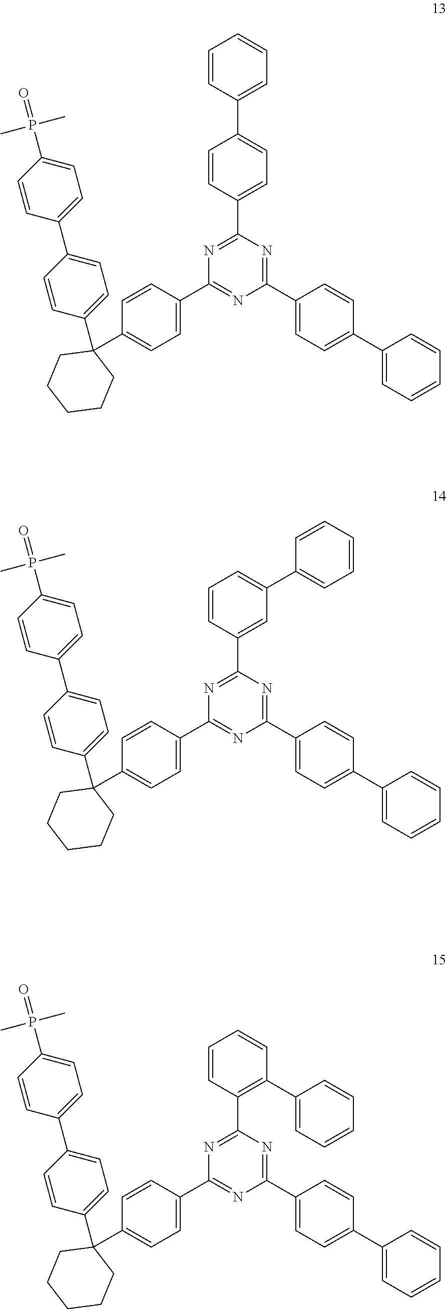 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)cc1]

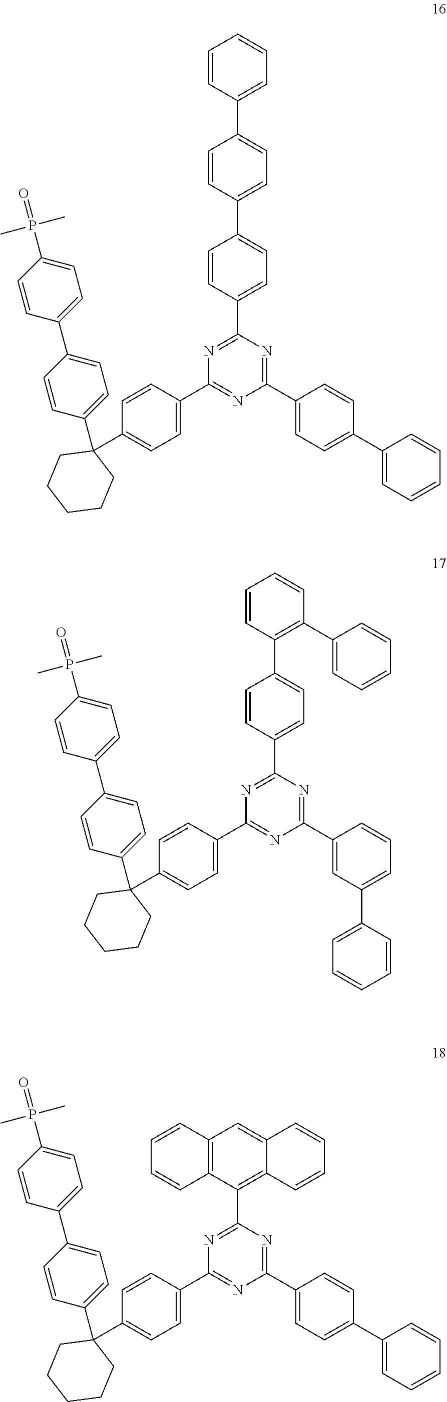 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CCCCC3)cc2)cc1]

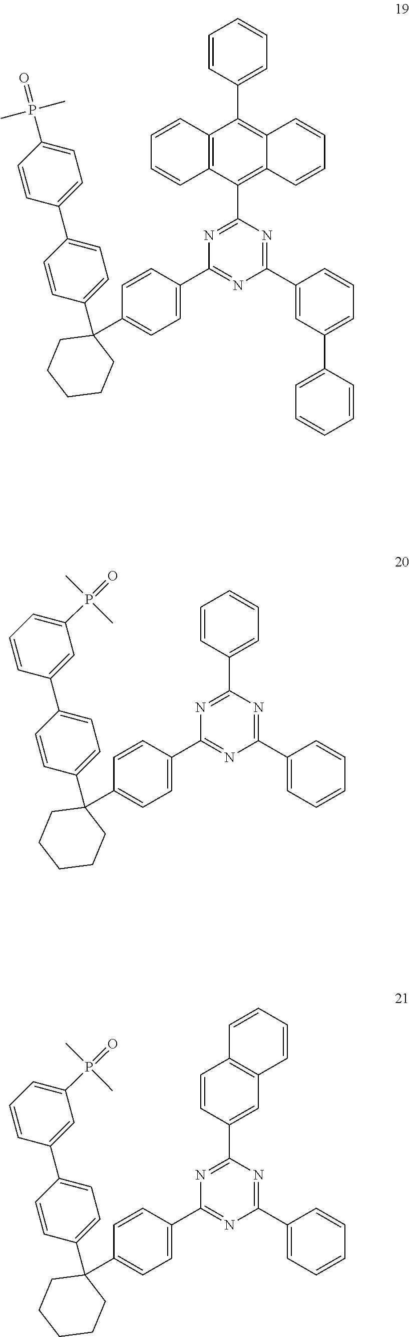 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)cc1 ; CP(C)(=O)c1cccc(-c2ccc(C3(c4ccc(-c5nc(-c6ccccc6)nc(-c6ccccc6)n5)cc4)CCCCC3)cc2)c1 ; CP(C)(=O)c1cccc(-c2ccc(C3(c4ccc(-c5nc(-c6ccccc6)nc(-c6ccc7ccccc7c6)n5)cc4)CCCCC3)cc2)c1]

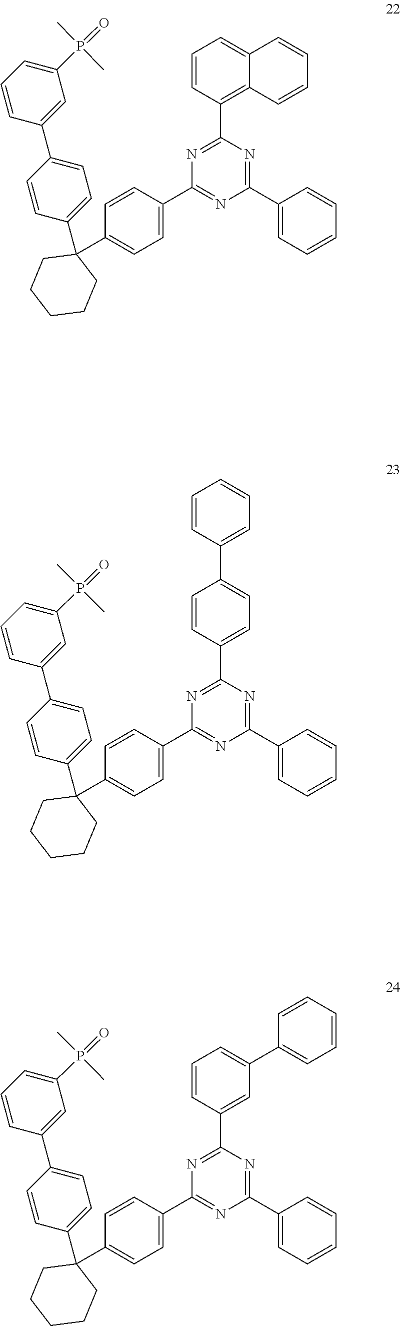 [SMILES: CP(C)(=O)c1cccc(-c2ccc(C3(c4ccc(-c5nc(-c6ccccc6)nc(-c6cccc7ccccc67)n5)cc4)CCCCC3)cc2)c1 ; CP(C)(=O)c1cccc(-c2ccc(C3(c4ccc(-c5nc(-c6ccccc6)nc(-c6ccc(-c7ccccc7)cc6)n5)cc4)CCCCC3)cc2)c1 ; CP(C)(=O)c1cccc(-c2ccc(C3(c4ccc(-c5nc(-c6ccccc6)nc(-c6cccc(-c7ccccc7)c6)n5)cc4)CCCCC3)cc2)c1]

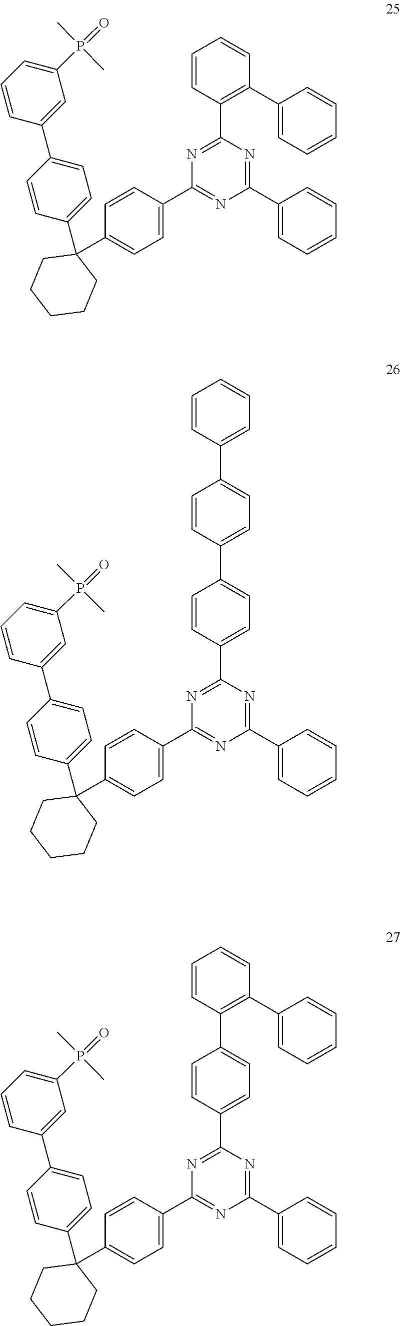 [SMILES: CP(C)(=O)c1cccc(-c2ccc(C3(c4ccc(-c5nc(-c6ccccc6)nc(-c6ccccc6-c6ccccc6)n5)cc4)CCCCC3)cc2)c1 ; CP(C)(=O)c1cccc(-c2ccc(C3(c4ccc(-c5nc(-c6ccccc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CCCCC3)cc2)c1]

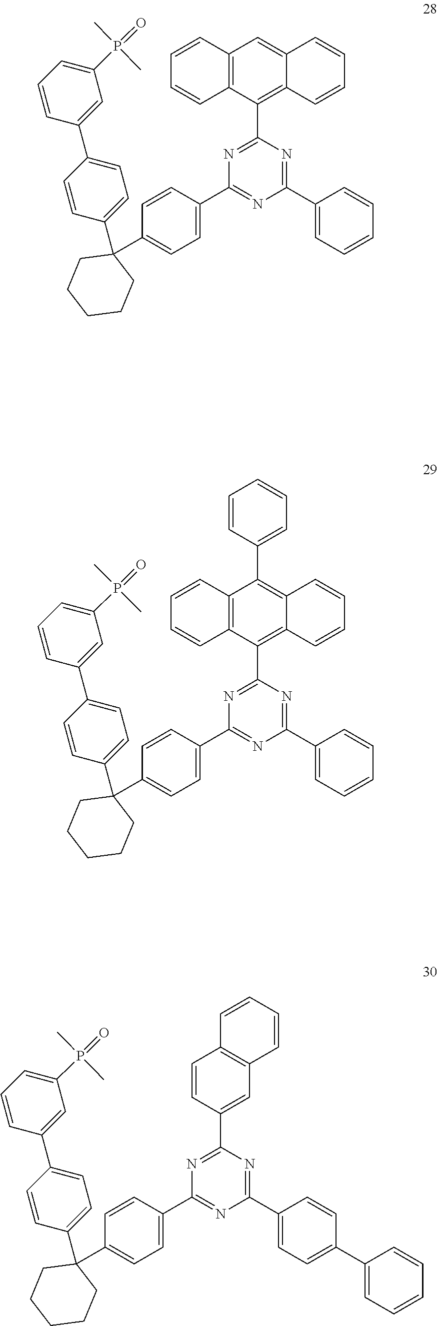 [SMILES: CP(C)(=O)c1cccc(-c2ccc(C3(c4ccc(-c5nc(-c6ccccc6)nc(-c6c7ccccc7cc7ccccc67)n5)cc4)CCCCC3)cc2)c1 ; CP(C)(=O)c1cccc(-c2ccc(C3(c4ccc(-c5nc(-c6ccccc6)nc(-c6c7ccccc7c(-c7ccccc7)c7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CCCCC3)cc2)c1]

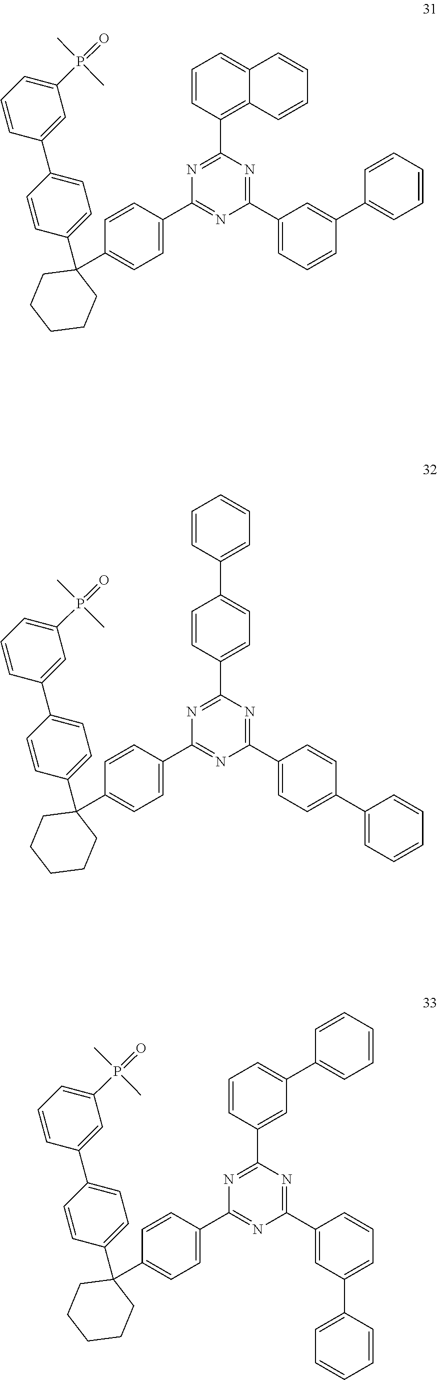 [SMILES: CP(C)(=O)c1cccc(-c2ccc(C3(c4ccc(-c5nc(-c6cccc(-c7ccccc7)c6)nc(-c6cccc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccccc7)cc6)n5)cc4)CCCCC3)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CCCCC3)cc2)c1]

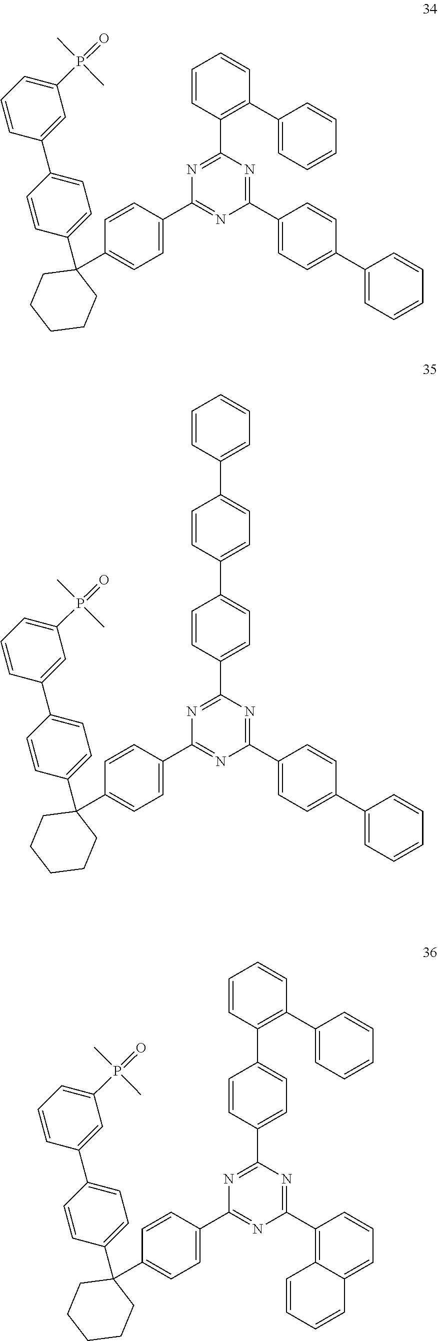 [SMILES: CP(C)(=O)c1cccc(-c2ccc(C3(c4ccc(-c5nc(-c6ccc(-c7ccccc7)cc6)nc(-c6ccccc6-c6ccccc6)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CCCCC3)cc2)c1]

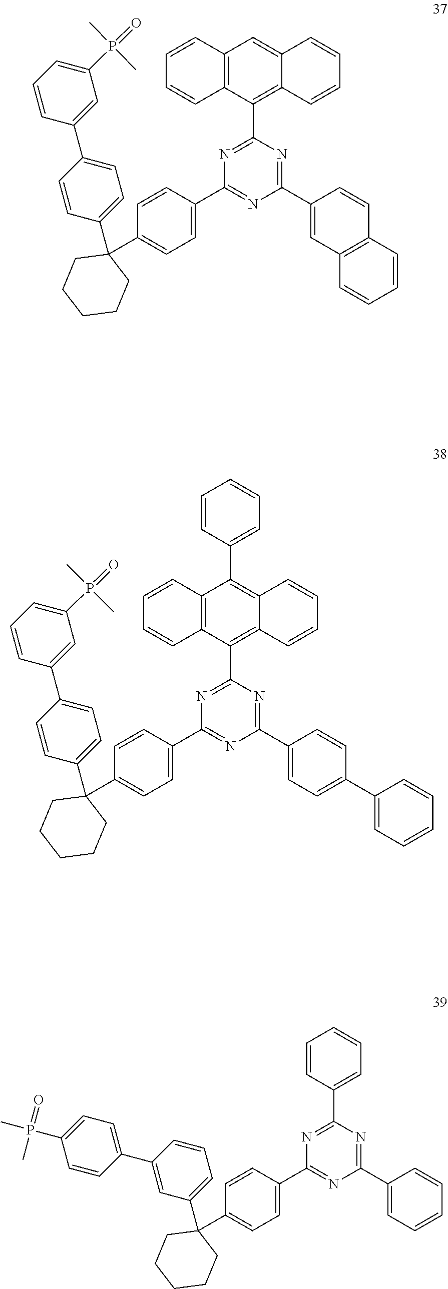 [SMILES: CP(C)(=O)c1cccc(-c2ccc(C3(c4ccc(-c5nc(-c6ccc7ccccc7c6)nc(-c6c7ccccc7cc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CCCCC3)cc2)c1 ; CP(C)(=O)c1ccc(-c2cccc(C3(c4ccc(-c5nc(-c6ccccc6)nc(-c6ccccc6)n5)cc4)CCCCC3)c2)cc1]

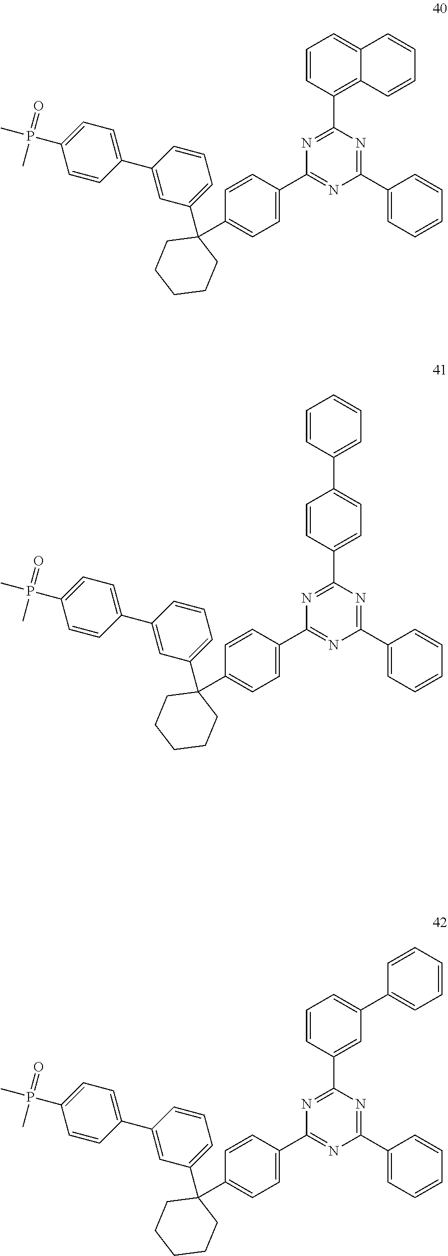 [SMILES: CP(C)(=O)c1ccc(-c2cccc(C3(c4ccc(-c5nc(-c6ccccc6)nc(-c6cccc7ccccc67)n5)cc4)CCCCC3)c2)cc1 ; CP(C)(=O)c1ccc(-c2cccc(C3(c4ccc(-c5nc(-c6ccccc6)nc(-c6ccc(-c7ccccc7)cc6)n5)cc4)CCCCC3)c2)cc1 ; CP(C)(=O)c1ccc(-c2cccc(C3(c4ccc(-c5nc(-c6ccccc6)nc(-c6cccc(-c7ccccc7)c6)n5)cc4)CCCCC3)c2)cc1]

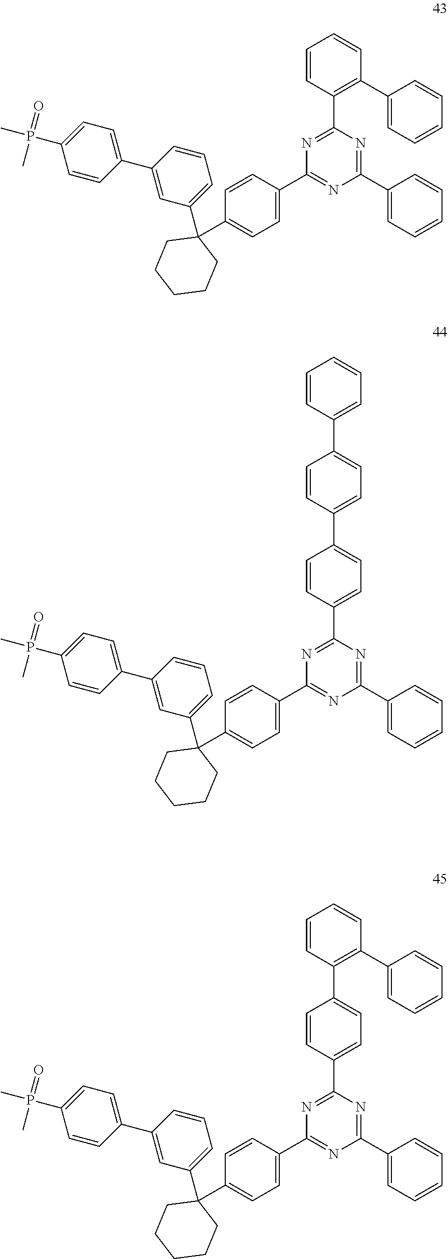 [SMILES: CP(C)(=O)c1ccc(-c2cccc(C3(c4ccc(-c5nc(-c6ccccc6)nc(-c6ccccc6-c6ccccc6)n5)cc4)CCCCC3)c2)cc1 ; CP(C)(=O)c1ccc(-c2cccc(C3(c4ccc(-c5nc(-c6ccccc6)nc(-c6ccc(-c7ccc(-c8ccccc8)cc7)cc6)n5)cc4)CCCCC3)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CCCCC3)c2)cc1]

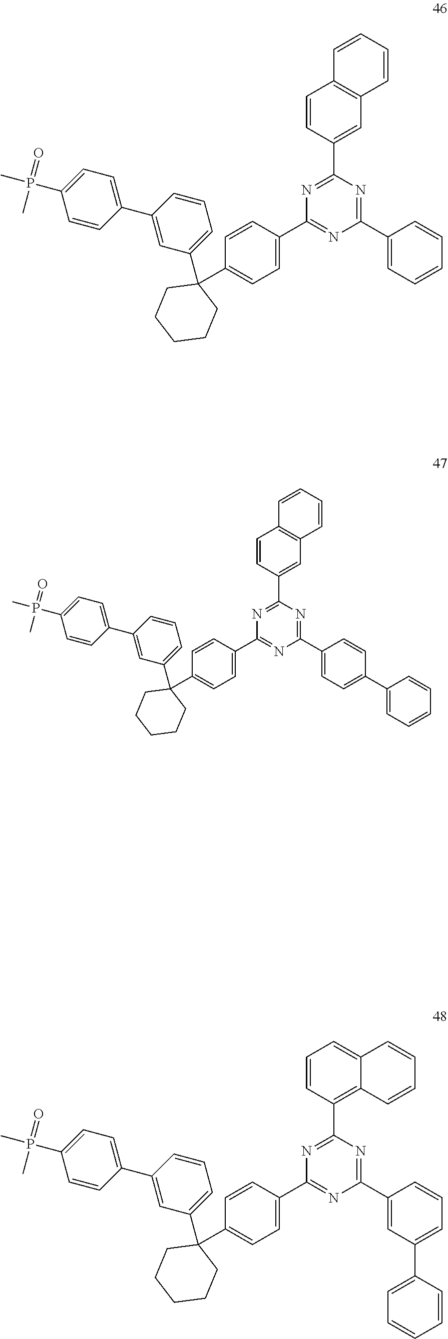 [SMILES: CP(C)(=O)c1ccc(-c2cccc(C3(c4ccc(-c5nc(-c6ccccc6)nc(-c6ccc7ccccc7c6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CCCCC3)c2)cc1]

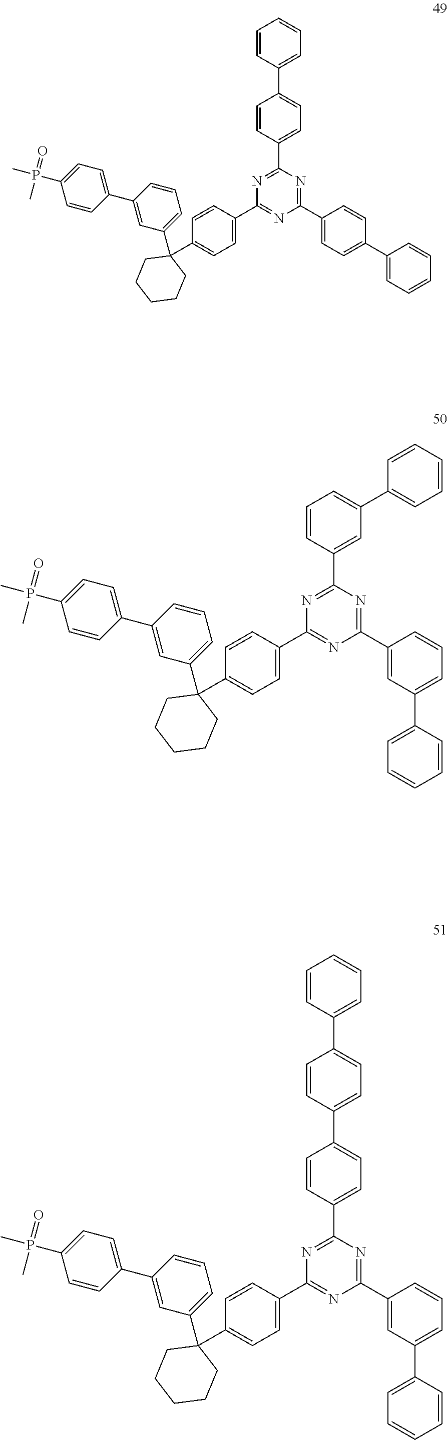 [SMILES: CP(C)(=O)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1 ; CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1]

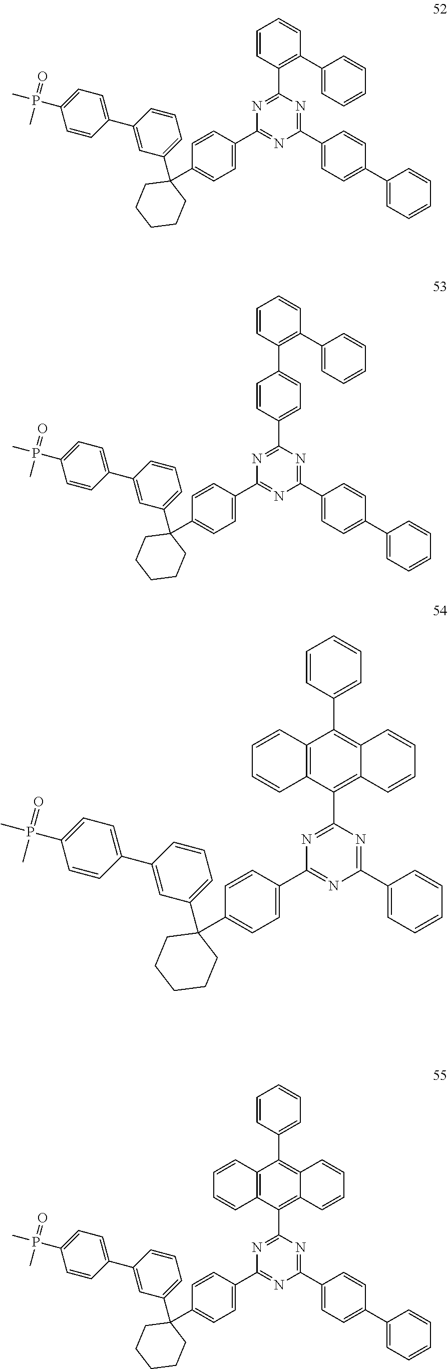 [SMILES: CP(C)(=O)c1ccc(-c2cccc(C3(c4ccc(-c5nc(-c6ccc(-c7ccccc7)cc6)nc(-c6ccccc6-c6ccccc6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1 ; CP(C)(=O)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1]

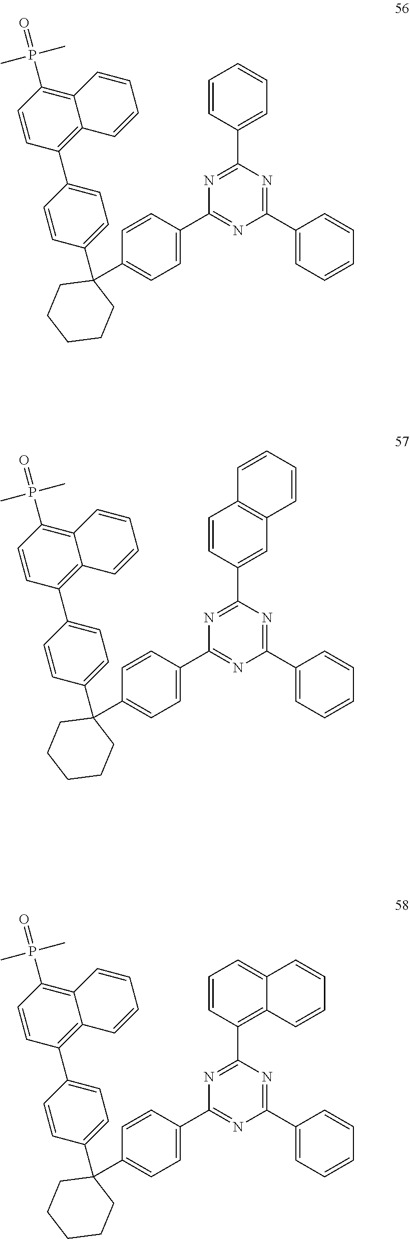 [SMILES: CP(C)(=O)c1ccc(-c2ccc(C3(c4ccc(-c5nc(-c6ccccc6)nc(-c6ccccc6)n5)cc4)CCCCC3)cc2)c2ccccc12 ; CP(C)(=O)c1ccc(-c2ccc(C3(c4ccc(-c5nc(-c6ccccc6)nc(-c6ccc7ccccc7c6)n5)cc4)CCCCC3)cc2)c2ccccc12 ; CP(C)(=O)c1ccc(-c2ccc(C3(c4ccc(-c5nc(-c6ccccc6)nc(-c6cccc7ccccc67)n5)cc4)CCCCC3)cc2)c2ccccc12]

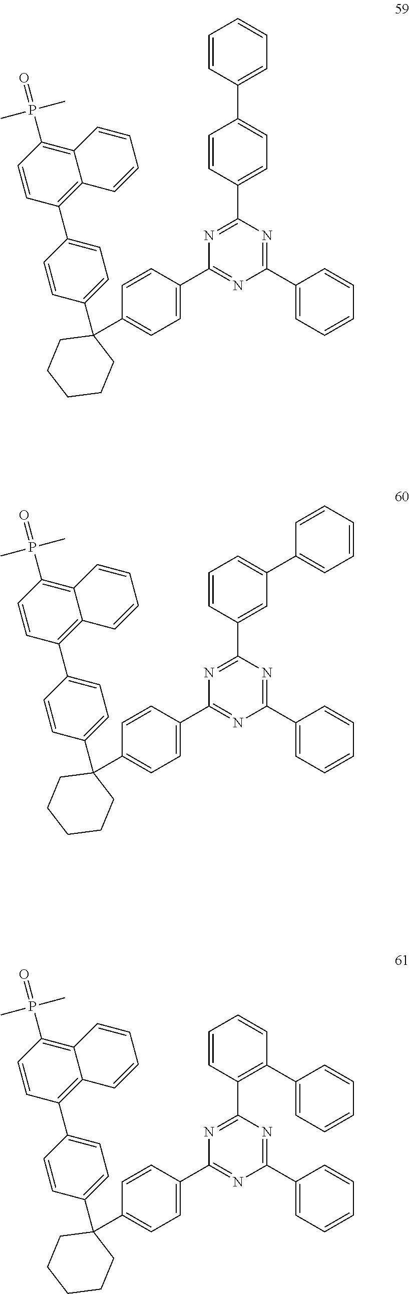 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccccc6)nc(-c6ccccc6-c6ccccc6)n5)cc4)CCCCC3)cc2)c2ccccc12]

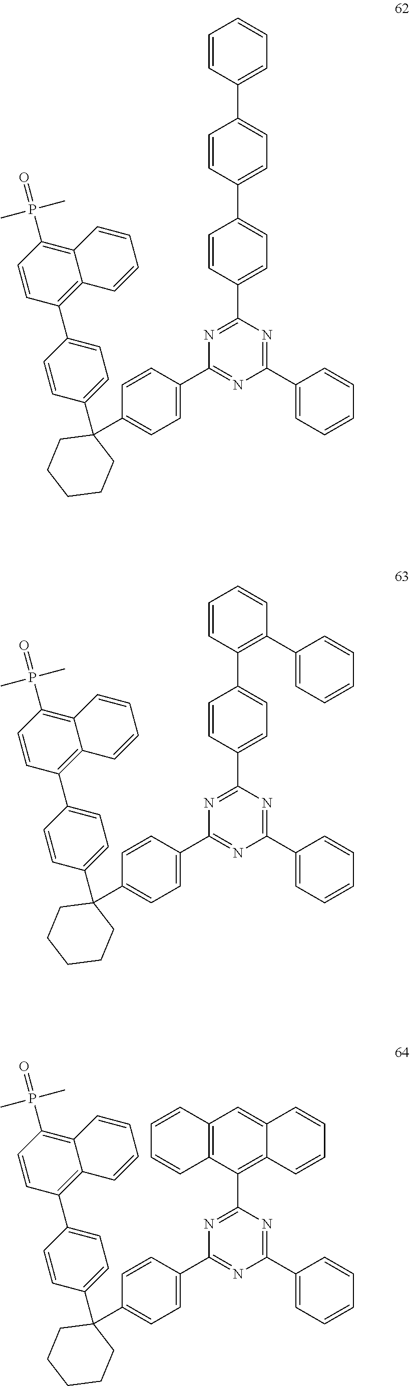 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CCCCC3)cc2)c2ccccc12]

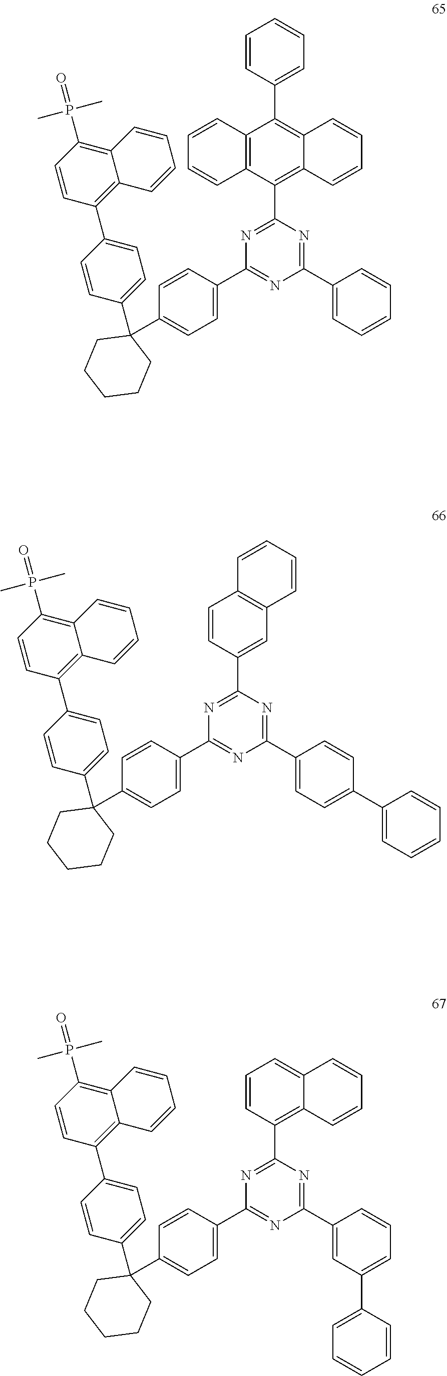 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)c2ccccc12]

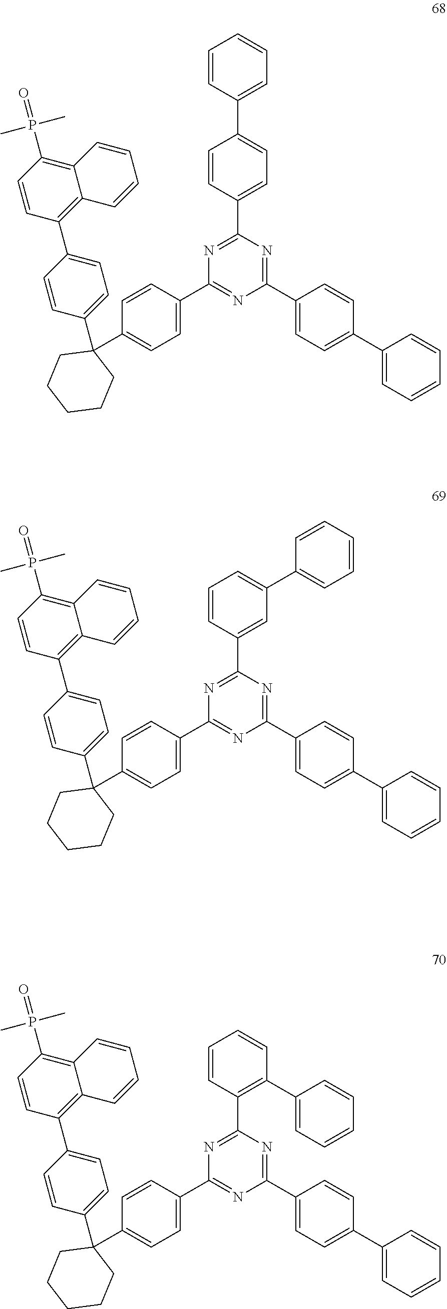 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

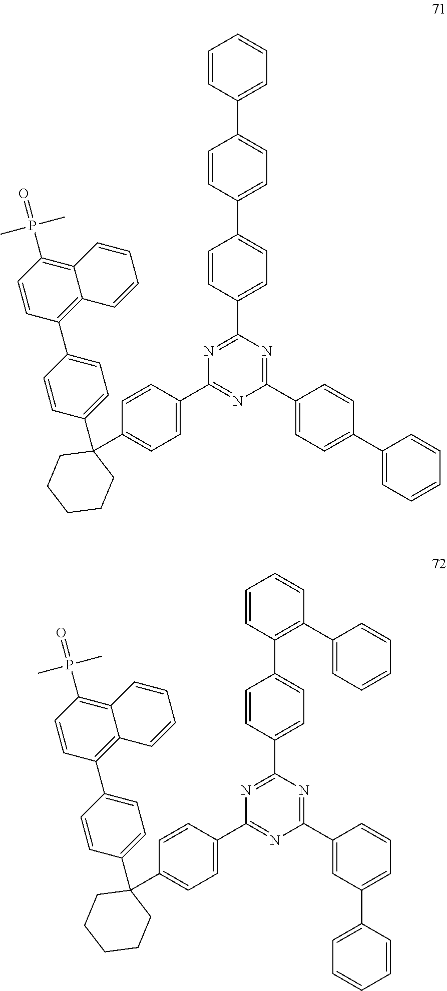 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

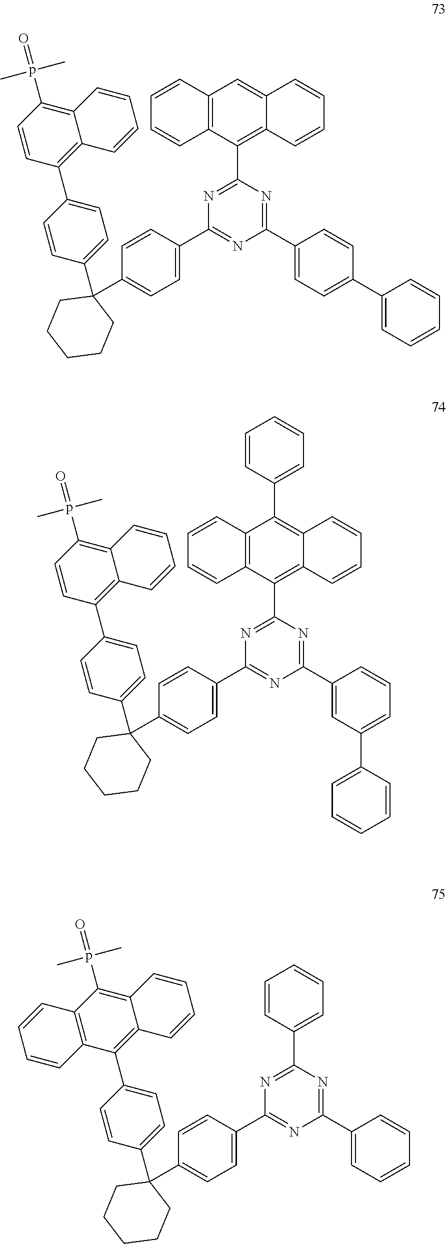

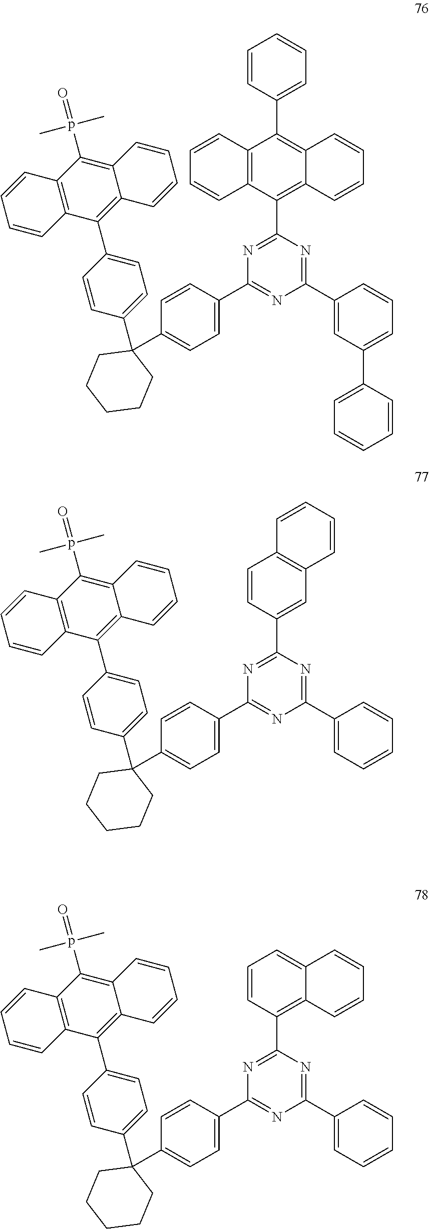

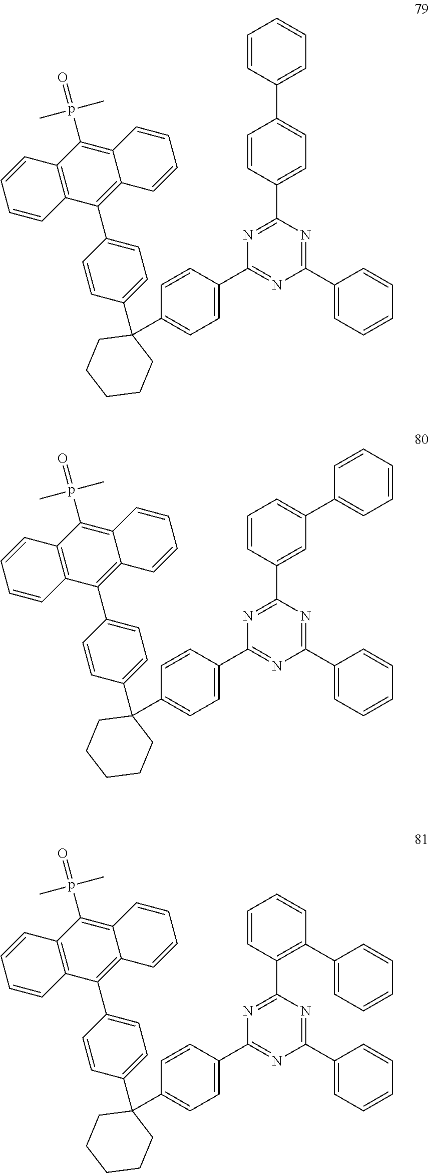

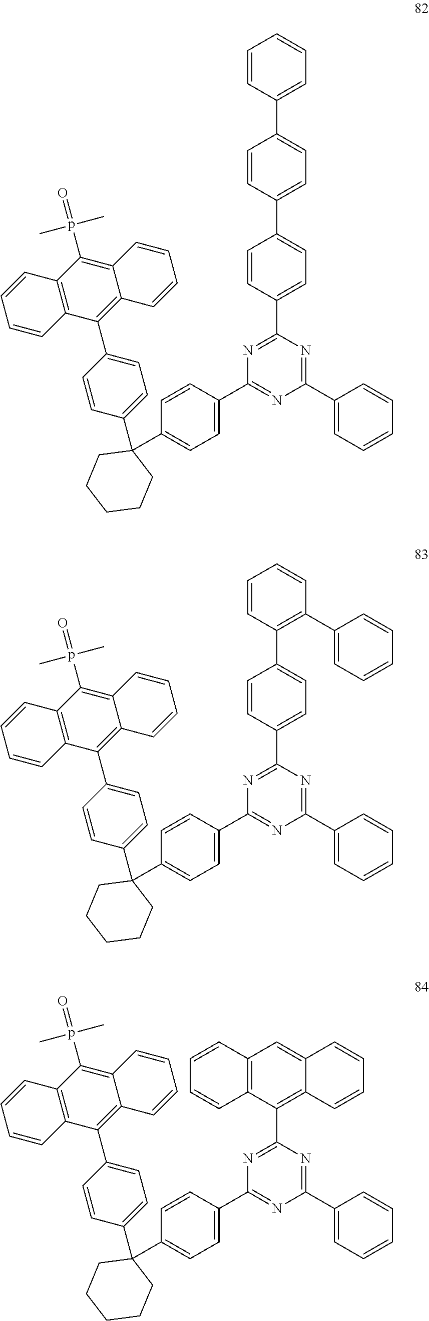

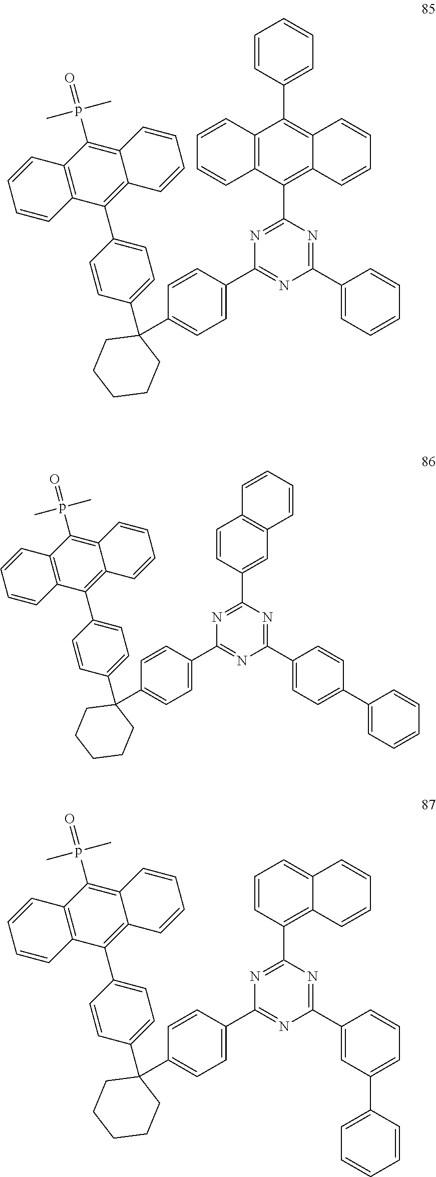

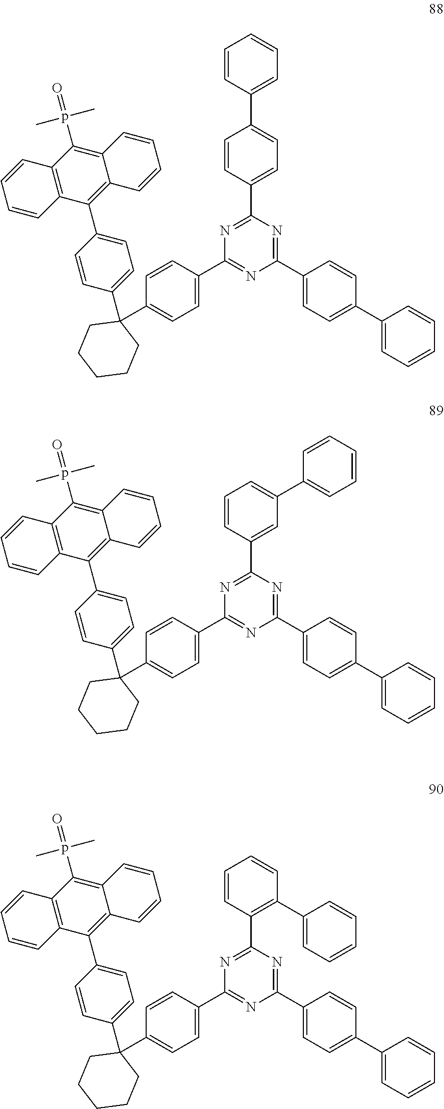

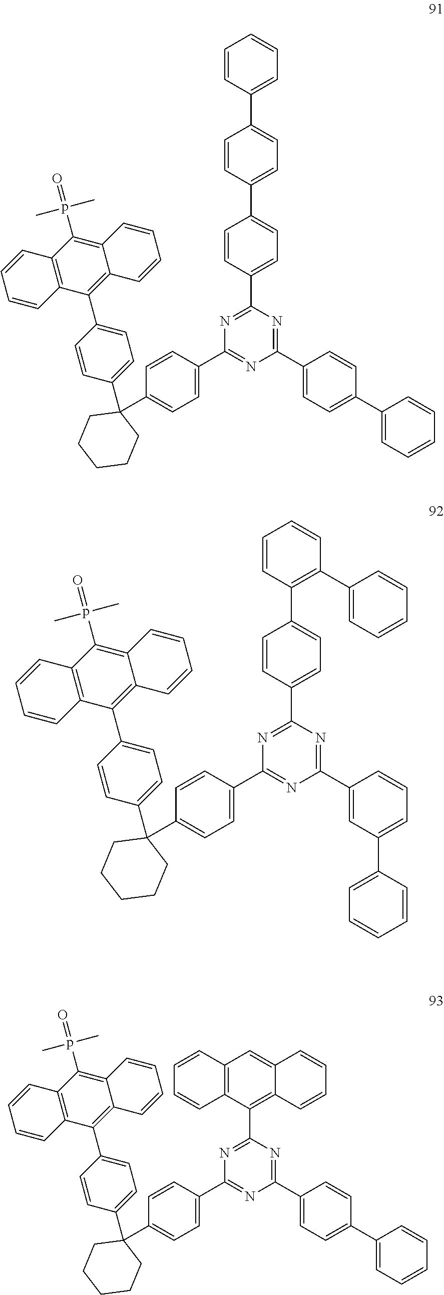

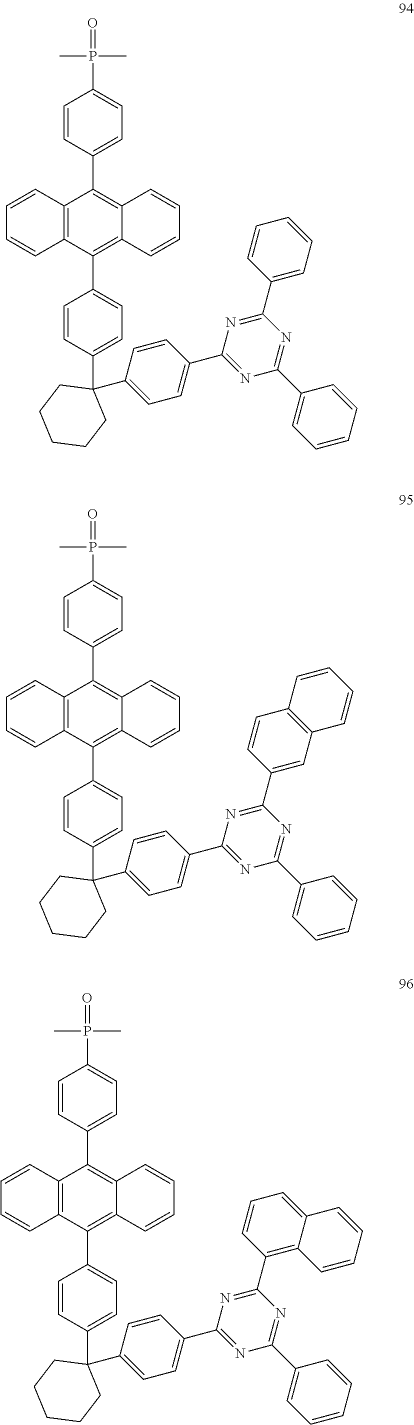 [SMILES: CP(C)(=O)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1]

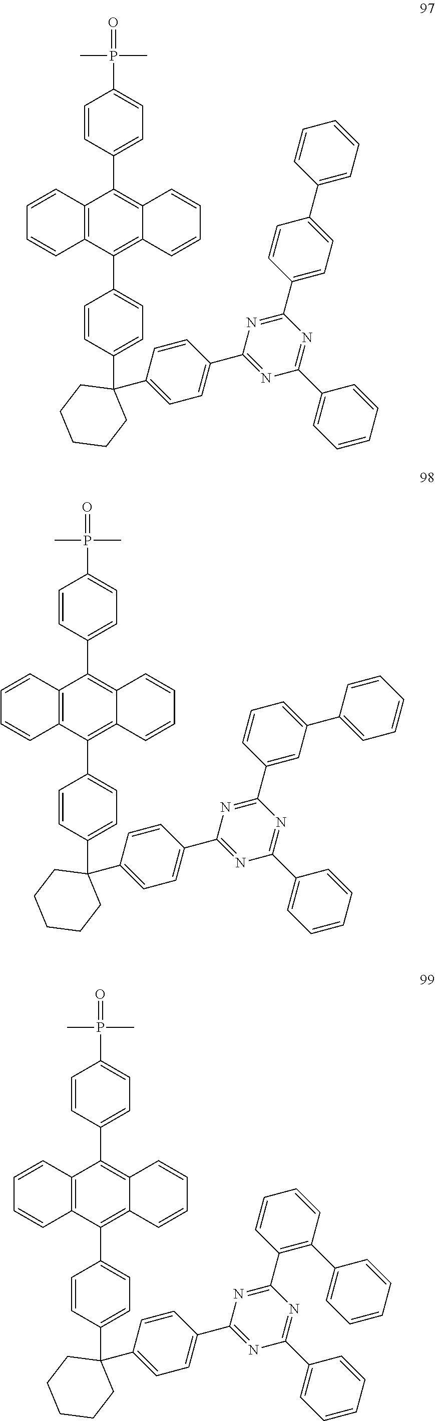 [SMILES: CP(C)(=O)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1]

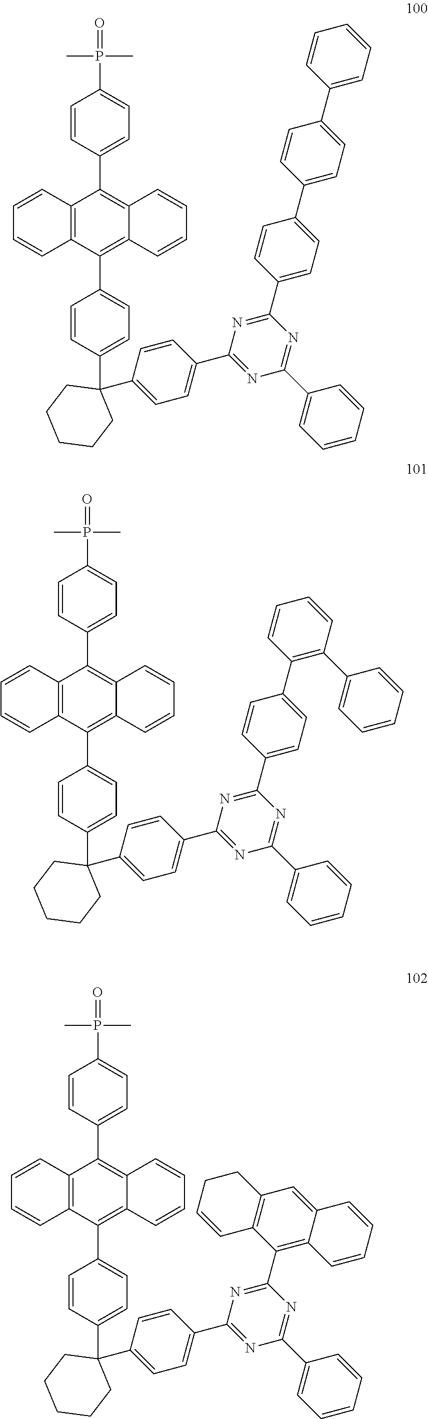 [SMILES: CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7c8c(cc9ccccc79)CCC=C8)n6)cc5)CCCCC4)cc3)c3ccccc23)cc1]

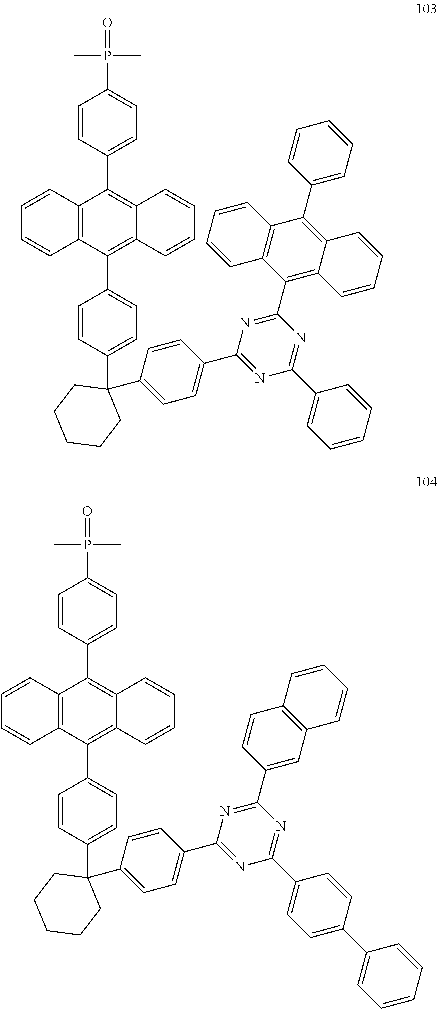 [SMILES: CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1]

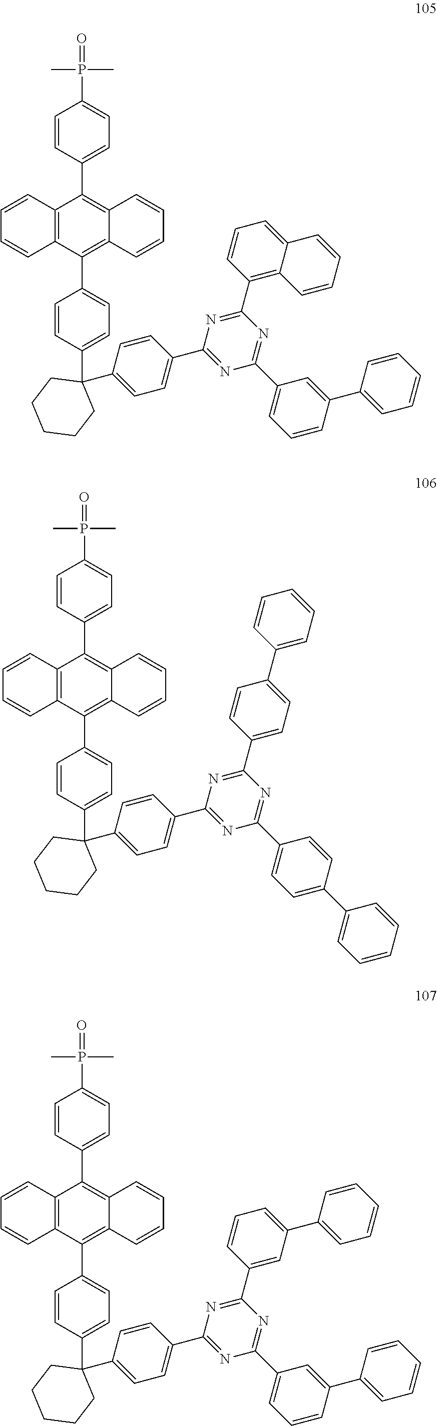 [SMILES: CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CCCCC4)cc3)c3ccccc23)cc1]

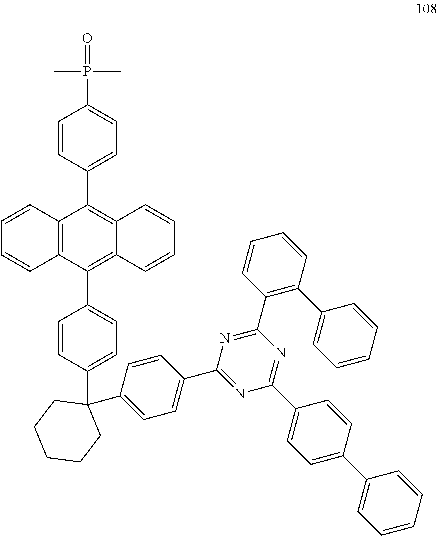 [SMILES: CP(C)(=O)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

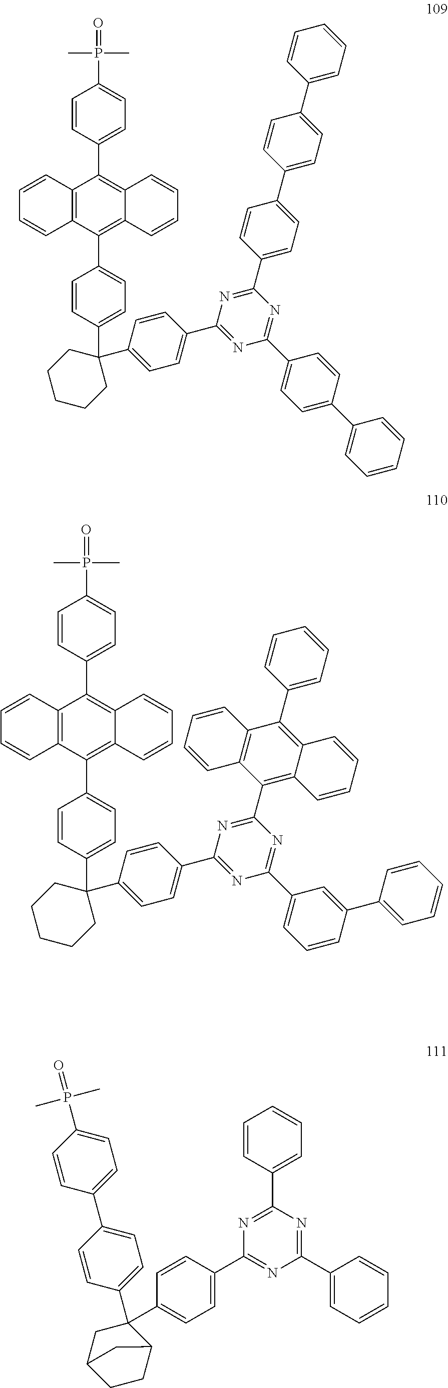 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CCCCC4)cc3)c3ccccc23)cc1 ; CP(C)(=O)c1ccc(-c2ccc(C3(c4ccc(-c5nc(-c6ccccc6)nc(-c6ccccc6)n5)cc4)CC4CCC3C4)cc2)cc1]

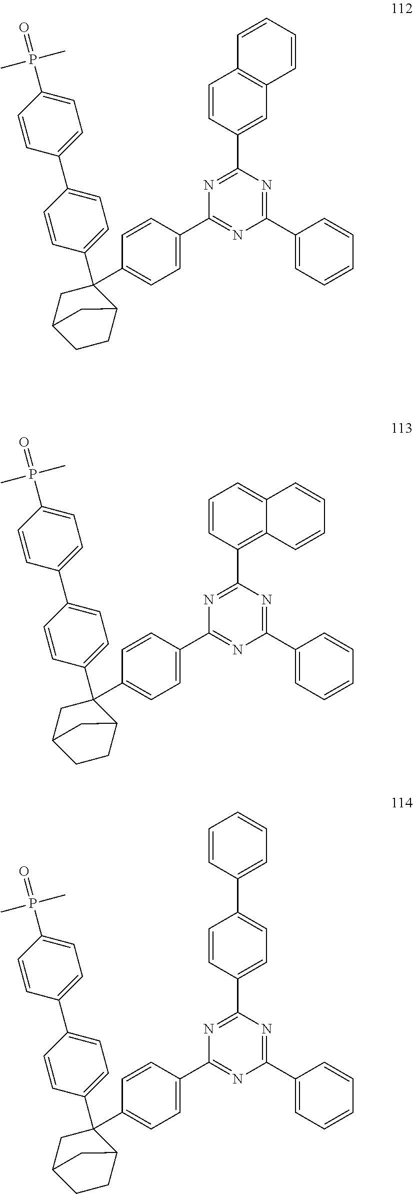 [SMILES: CP(C)(=O)c1ccc(-c2ccc(C3(c4ccc(-c5nc(-c6ccccc6)nc(-c6ccc7ccccc7c6)n5)cc4)CC4CCC3C4)cc2)cc1 ; CP(C)(=O)c1ccc(-c2ccc(C3(c4ccc(-c5nc(-c6ccccc6)nc(-c6cccc7ccccc67)n5)cc4)CC4CCC3C4)cc2)cc1 ; CP(C)(=O)c1ccc(-c2ccc(C3(c4ccc(-c5nc(-c6ccccc6)nc(-c6ccc(-c7ccccc7)cc6)n5)cc4)CC4CCC3C4)cc2)cc1]

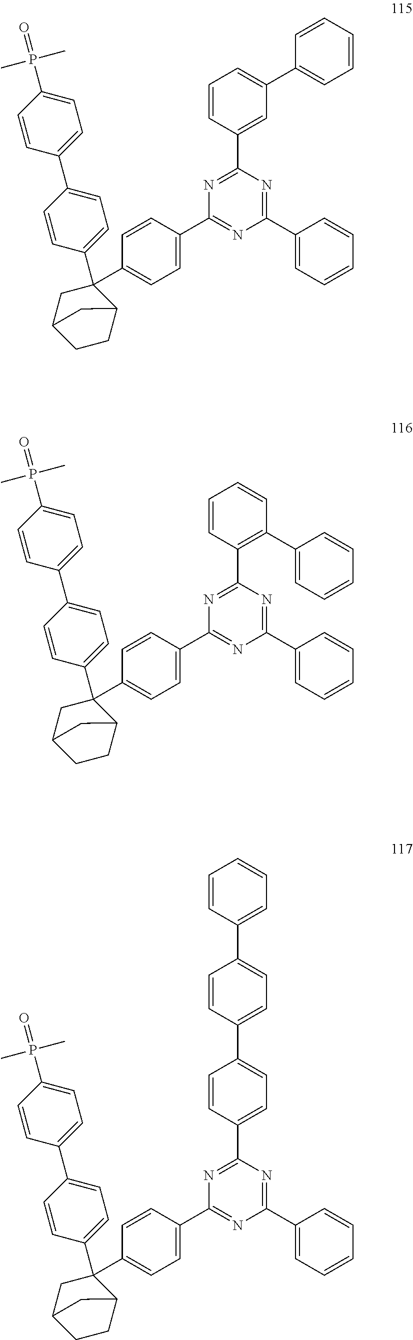 [SMILES: CP(C)(=O)c1ccc(-c2ccc(C3(c4ccc(-c5nc(-c6ccccc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)cc1]

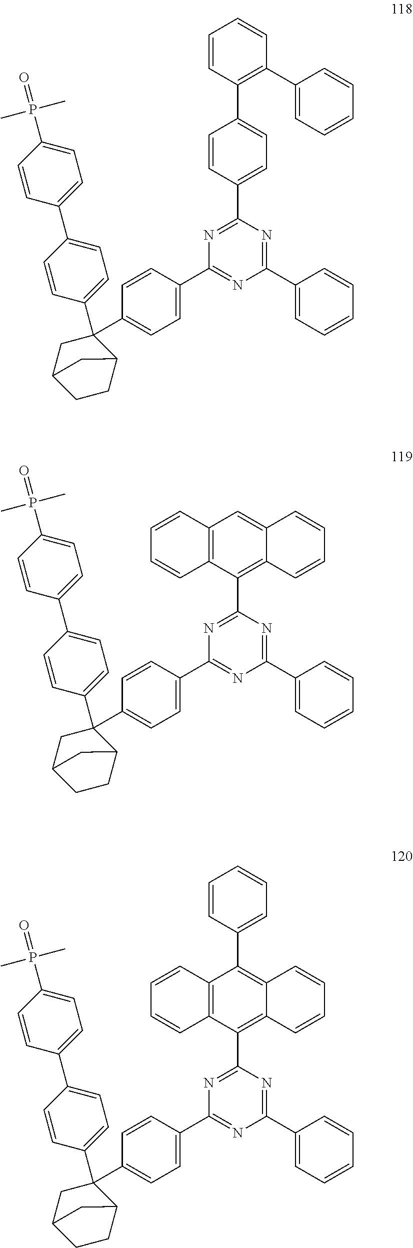 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)CC4CCC3C4)cc2)cc1 ; CP(C)(=O)c1ccc(-c2ccc(C3(c4ccc(-c5nc(-c6ccccc6)nc(-c6c7ccccc7cc7ccccc67)n5)cc4)CC4CCC3C4)cc2)cc1 ; CP(C)(=O)c1ccc(-c2ccc(C3(c4ccc(-c5nc(-c6ccccc6)nc(-c6c7ccccc7c(-c7ccccc7)c7ccccc67)n5)cc4)CC4CCC3C4)cc2)cc1]

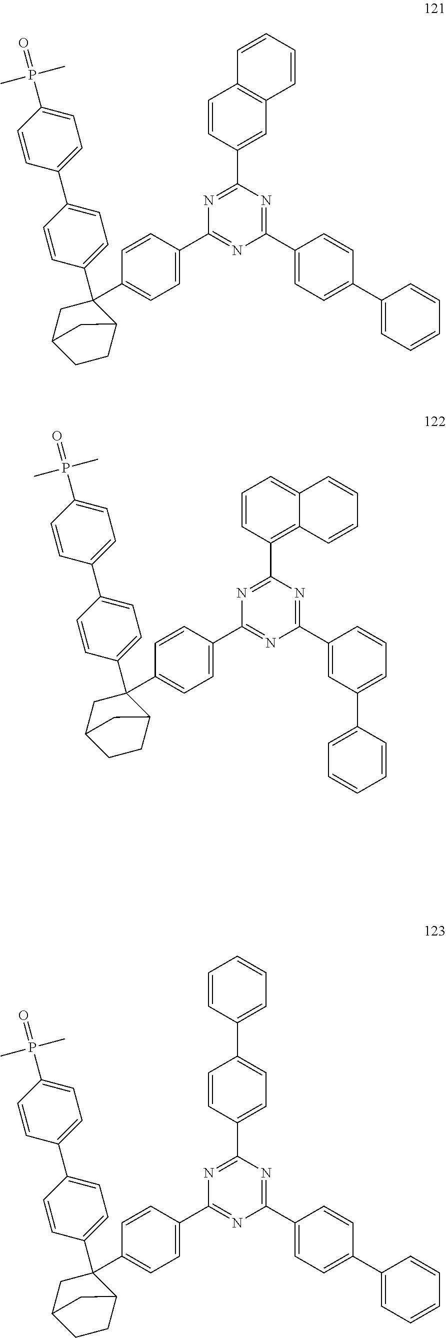 [SMILES: CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)cc1]

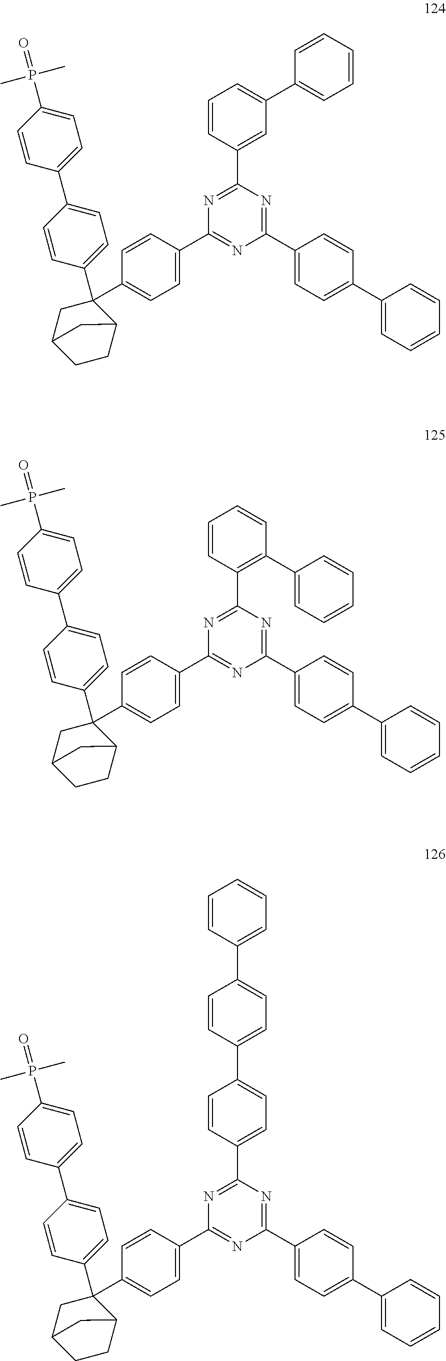 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)cc1]

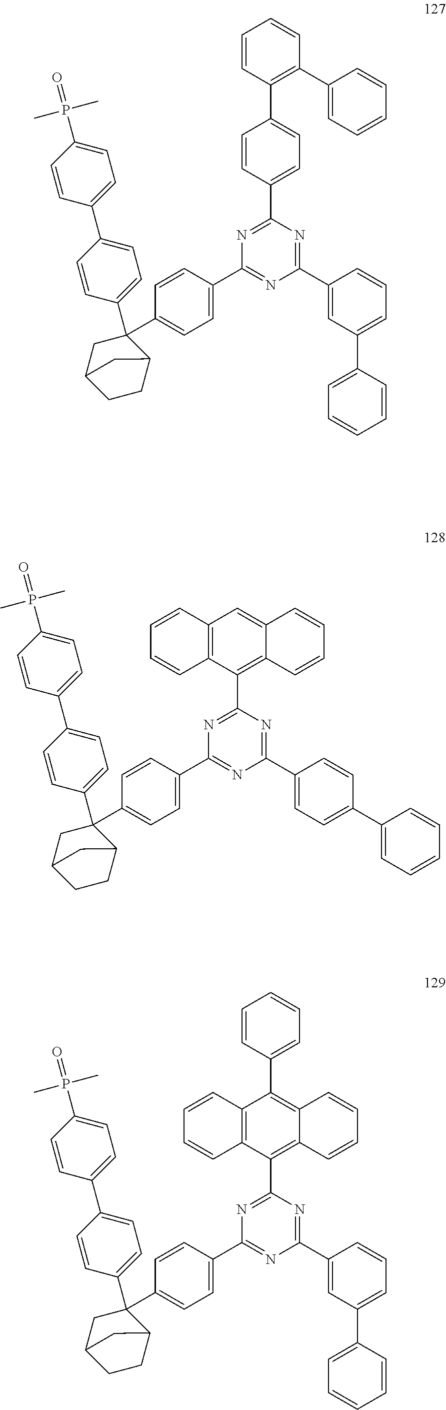 [SMILES: CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)cc1]

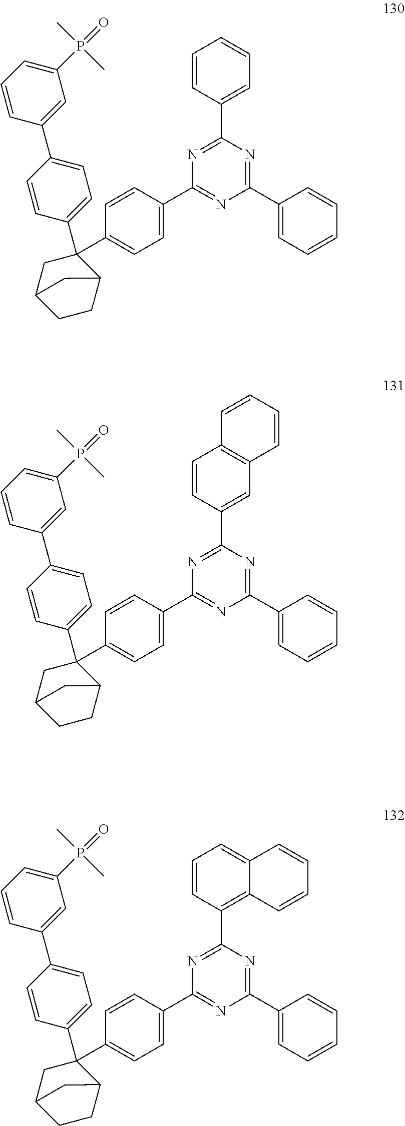 [SMILES: CP(C)(=O)c1cccc(-c2ccc(C3(c4ccc(-c5nc(-c6ccccc6)nc(-c6ccccc6)n5)cc4)CC4CCC3C4)cc2)c1 ; CP(C)(=O)c1cccc(-c2ccc(C3(c4ccc(-c5nc(-c6ccccc6)nc(-c6ccc7ccccc7c6)n5)cc4)CC4CCC3C4)cc2)c1 ; CP(C)(=O)c1cccc(-c2ccc(C3(c4ccc(-c5nc(-c6ccccc6)nc(-c6cccc7ccccc67)n5)cc4)CC4CCC3C4)cc2)c1]

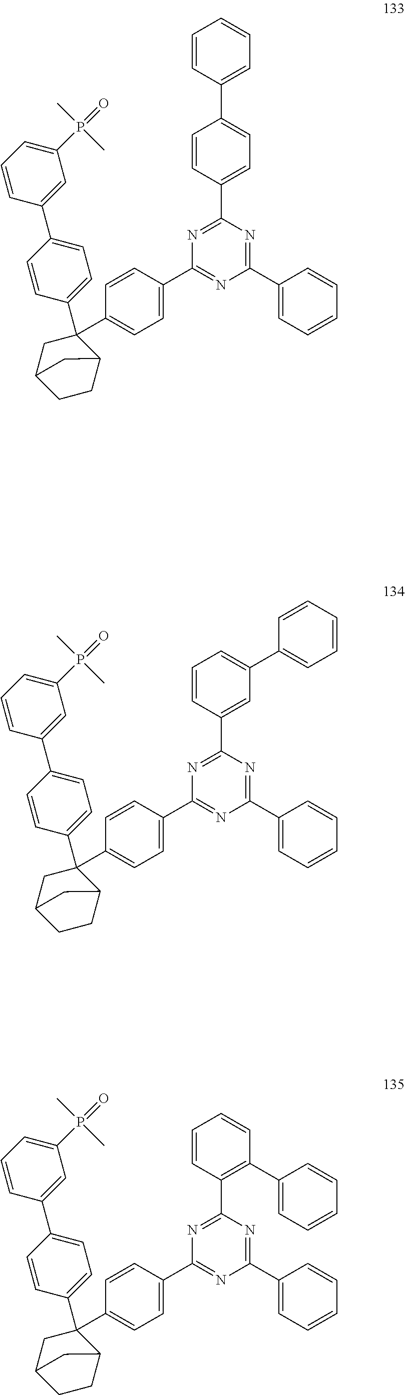 [SMILES: CP(C)(=O)c1cccc(-c2ccc(C3(c4ccc(-c5nc(-c6ccccc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccccc6)nc(-c6ccccc6-c6ccccc6)n5)cc4)CC4CCC3C4)cc2)c1]

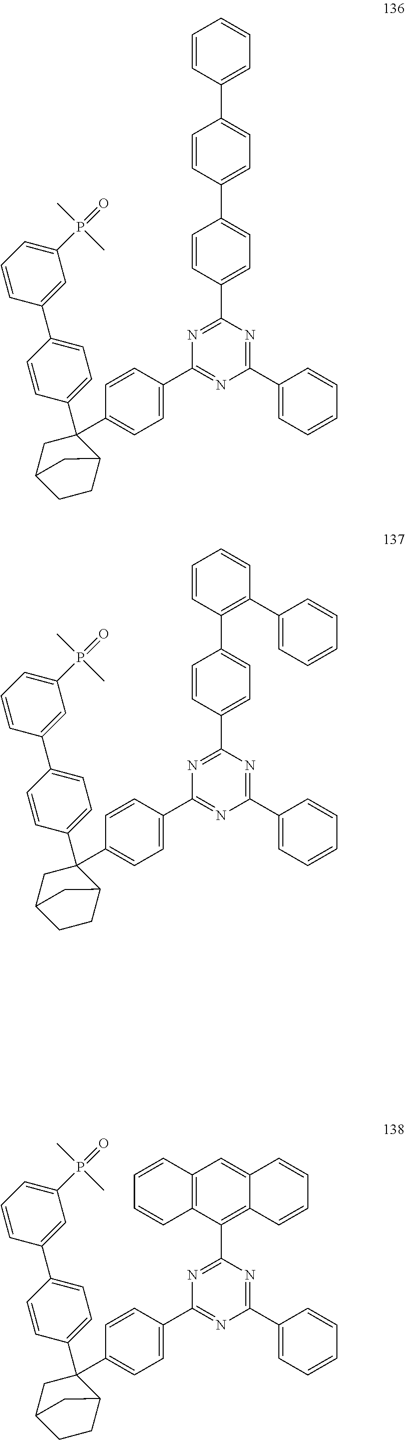 [SMILES: CP(C)(=O)c1cccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6c7ccccc7cc7ccccc67)n5)cc4)CC4CCC3C4)cc2)c1]

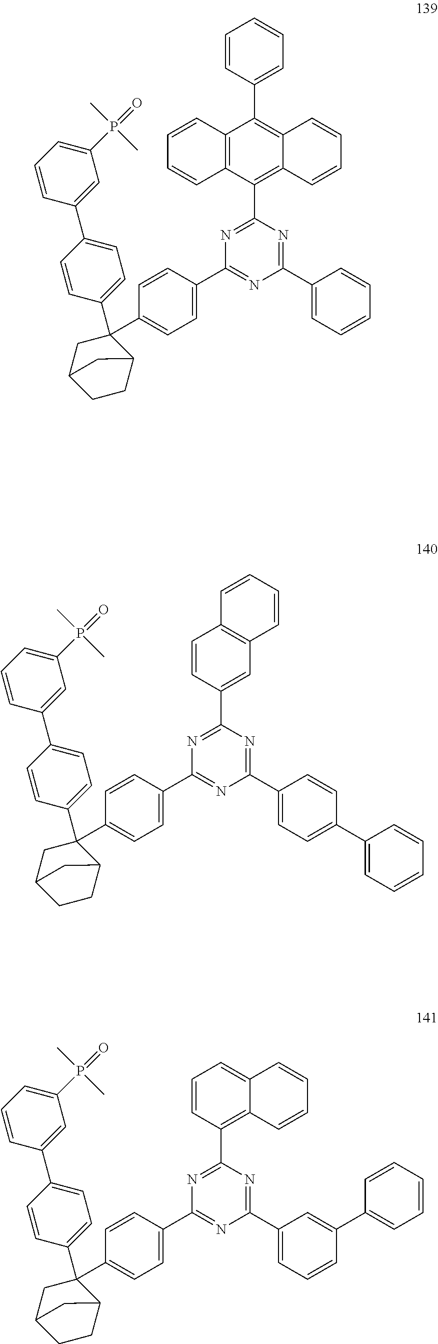 [SMILES: CP(C)(=O)c1cccc(-c2ccc(C3(c4ccc(-c5nc(-c6ccccc6)nc(-c6c7ccccc7c(-c7ccccc7)c7ccccc67)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc7ccccc67)n5)cc4)CC4CCC3C4)cc2)c1]

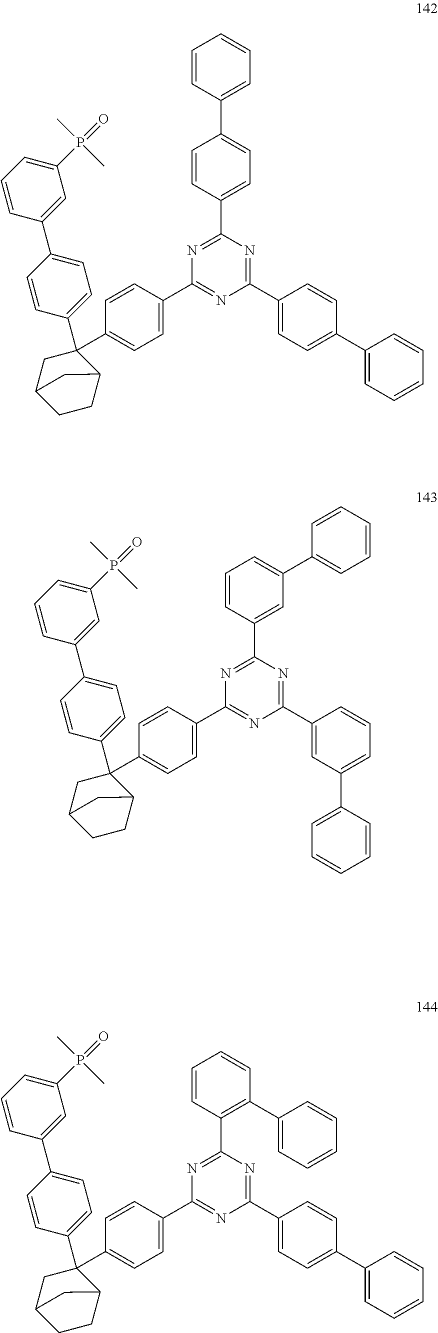 [SMILES: CP(C)(=O)c1cccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccccc6-c6ccccc6)n5)cc4)CC4CCC3C4)cc2)c1]

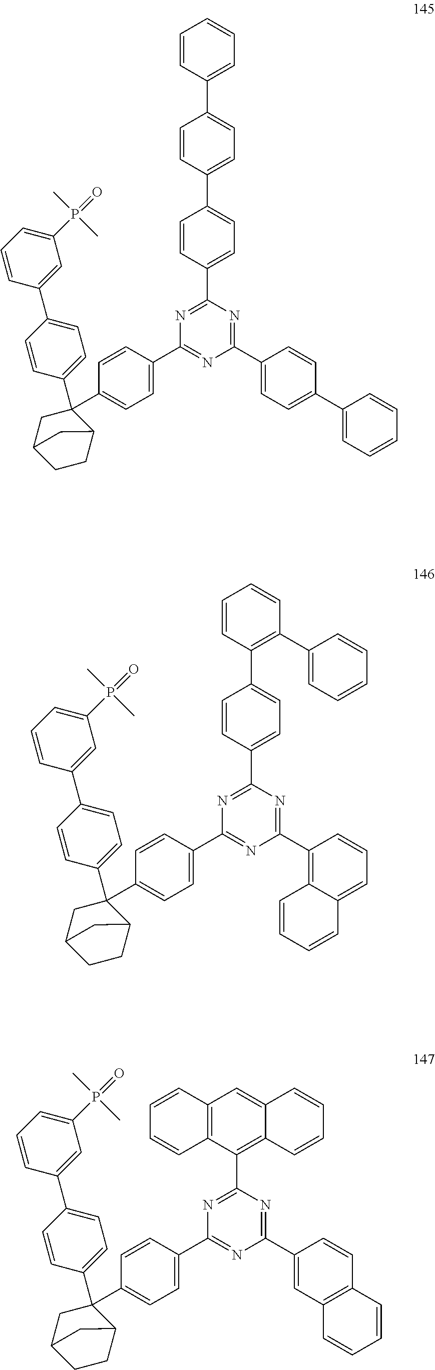 [SMILES: CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CC4CCC3C4)cc2)c1 ; CP(C)(=O)c1cccc(-c2ccc(C3(c4ccc(-c5nc(-c6ccc7ccccc7c6)nc(-c6c7ccccc7cc7ccccc67)n5)cc4)CC4CCC3C4)cc2)c1]

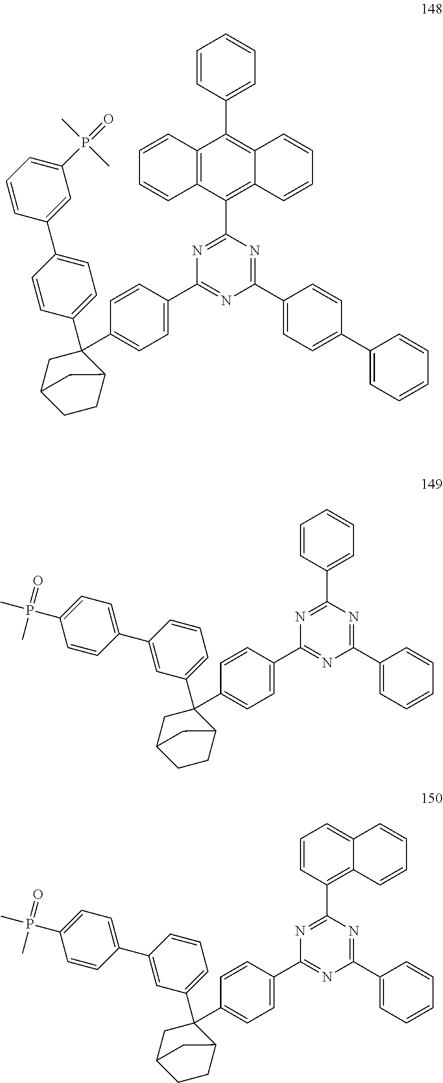 [SMILES: CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CC4CCC3C4)cc2)c1 ; CP(C)(=O)c1ccc(-c2cccc(C3(c4ccc(-c5nc(-c6ccccc6)nc(-c6ccccc6)n5)cc4)CC4CCC3C4)c2)cc1 ; CP(C)(=O)c1ccc(-c2cccc(C3(c4ccc(-c5nc(-c6ccccc6)nc(-c6cccc7ccccc67)n5)cc4)CC4CCC3C4)c2)cc1]

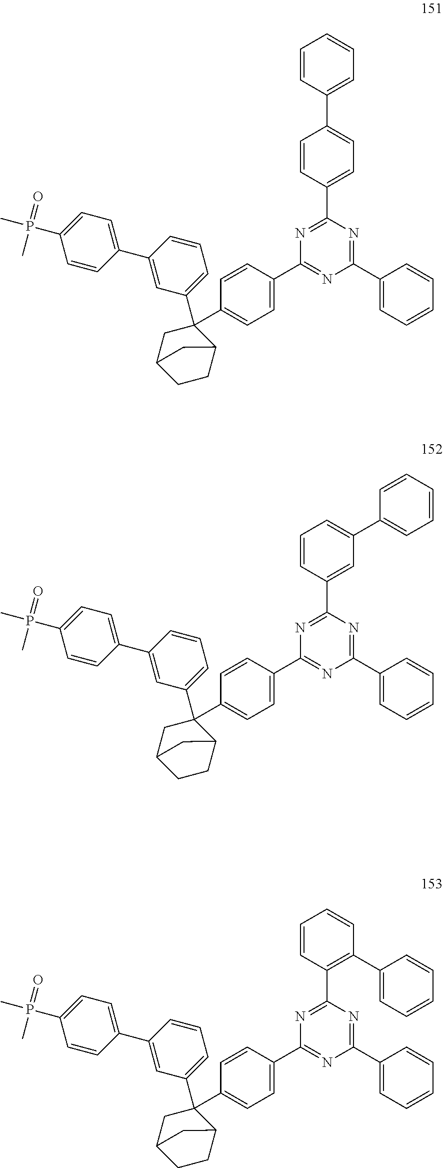 [SMILES: CP(C)(=O)c1ccc(-c2cccc(C3(c4ccc(-c5nc(-c6ccccc6)nc(-c6ccc(-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccccc6)nc(-c6ccccc6-c6ccccc6)n5)cc4)CC4CCC3C4)c2)cc1]

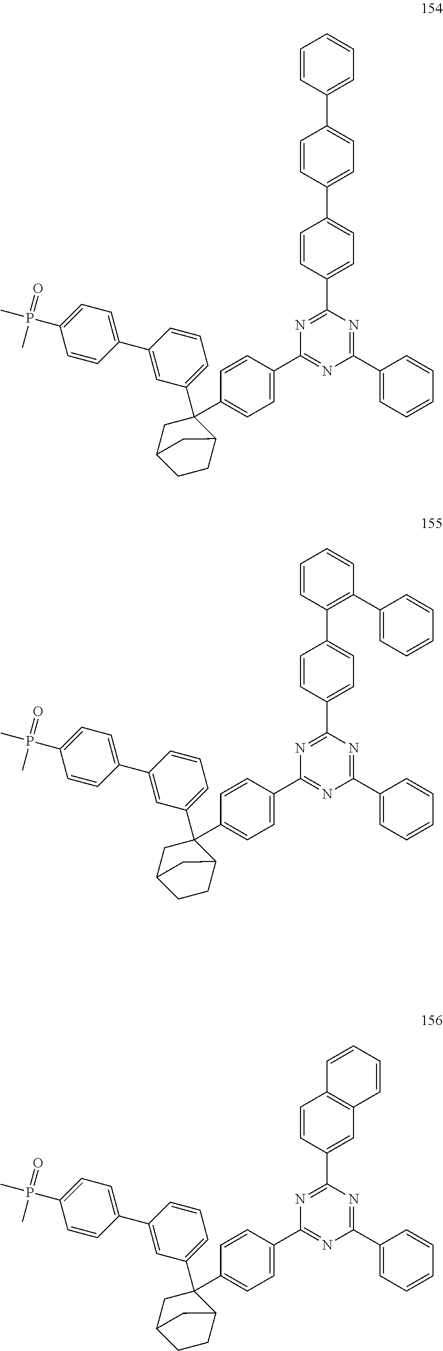 [SMILES: CP(C)(=O)c1ccc(-c2cccc(C3(c4ccc(-c5nc(-c6ccccc6)nc(-c6ccc(-c7ccc(-c8ccccc8)cc7)cc6)n5)cc4)CC4CCC3C4)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6ccc7ccccc7c6)n5)cc4)CC4CCC3C4)c2)cc1]

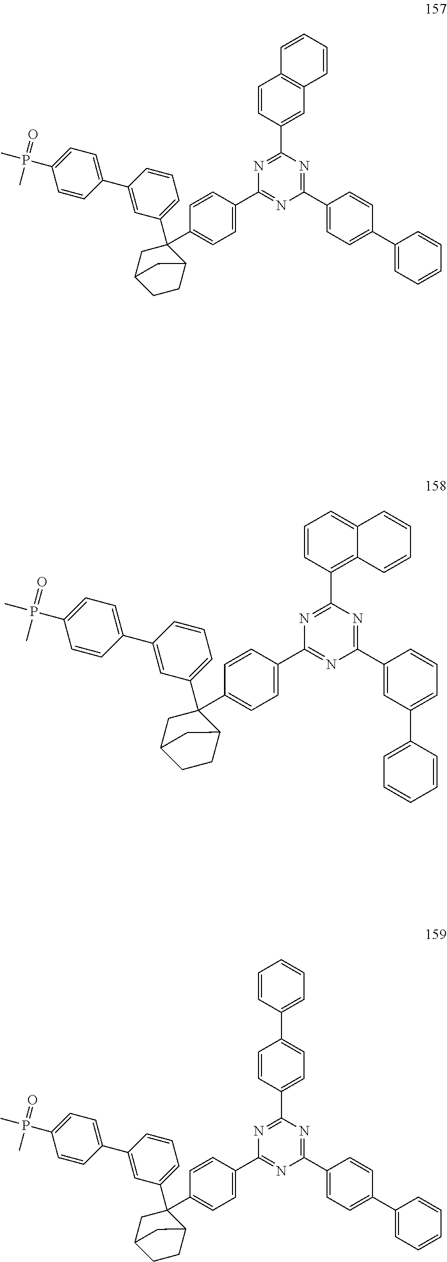 [SMILES: CP(C)(=O)c1ccc(-c2cccc(C3(c4ccc(-c5nc(-c6ccc(-c7ccccc7)cc6)nc(-c6ccc7ccccc7c6)n5)cc4)CC4CCC3C4)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)CC4CCC3C4)c2)cc1]

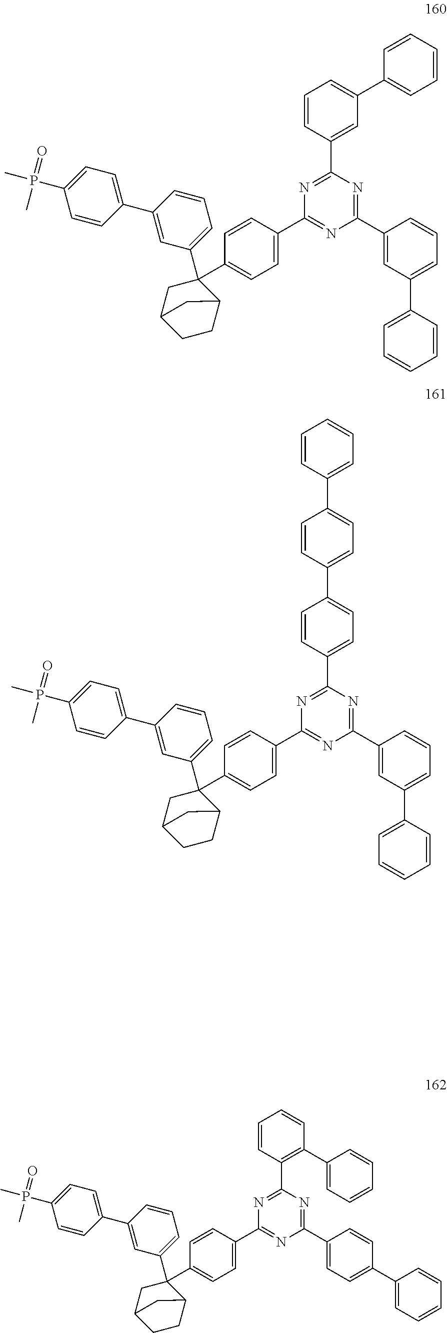 [SMILES: CP(C)(=O)c1ccc(-c2cccc(C3(c4ccc(-c5nc(-c6cccc(-c7ccccc7)c6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)CC4CCC3C4)c2)cc1]

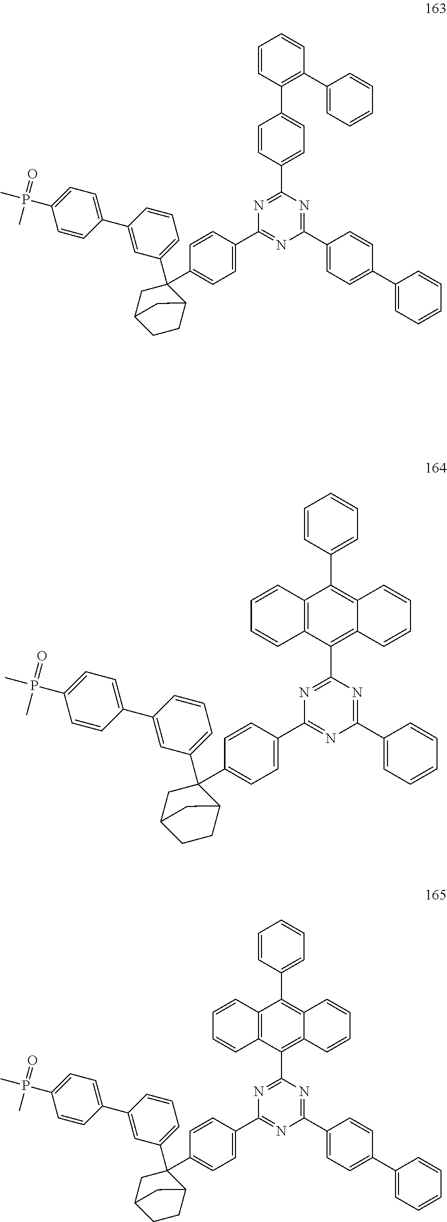 [SMILES: CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6c7ccccc7c(-c7ccccc7)c7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CC4CCC3C4)c2)cc1]

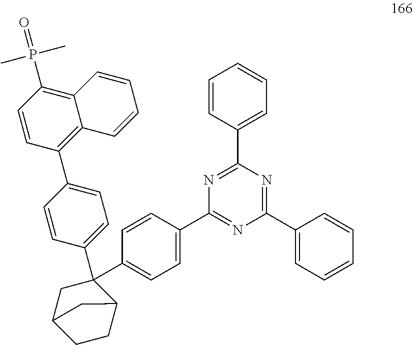 [SMILES: CP(C)(=O)c1ccc(-c2ccc(C3(c4ccc(-c5nc(-c6ccccc6)nc(-c6ccccc6)n5)cc4)CC4CCC3C4)cc2)c2ccccc12]

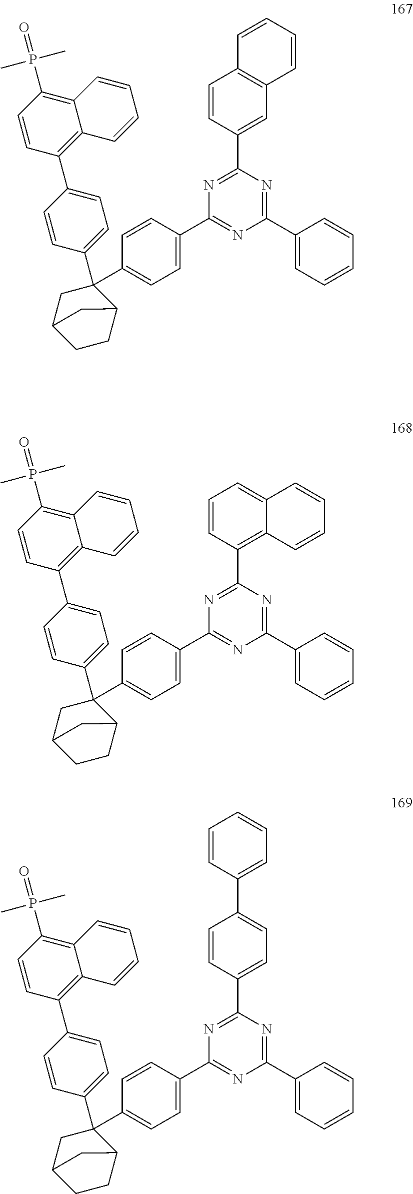 [SMILES: CP(C)(=O)c1ccc(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6ccccc6)nc(-c6cccc7ccccc67)n5)cc4)CC4CCC3C4)cc2)c2ccccc12 ; CP(C)(=O)c1ccc(-c2ccc(C3(c4ccc(-c5nc(-c6ccccc6)nc(-c6ccc(-c7ccccc7)cc6)n5)cc4)CC4CCC3C4)cc2)c2ccccc12]

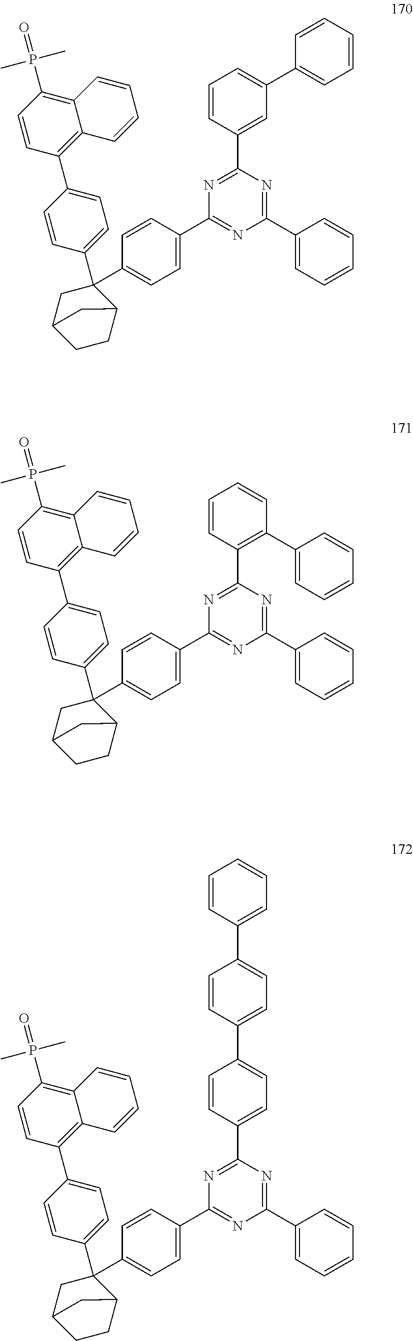 [SMILES: CP(C)(=O)c1ccc(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)c2ccccc12 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12]

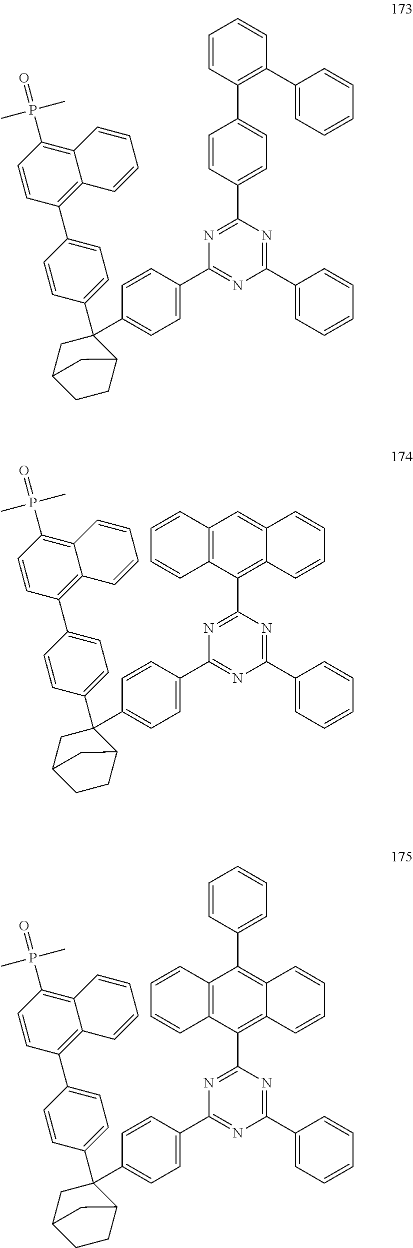 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CC4CCC3C4)cc2)c2ccccc12 ; CP(C)(=O)c1ccc(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12]

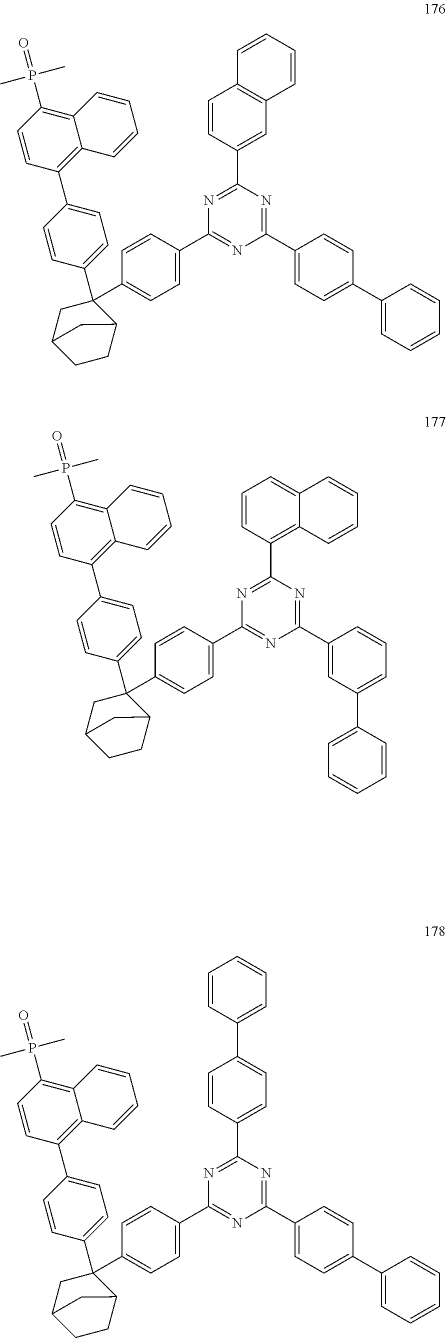 [SMILES: CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12]

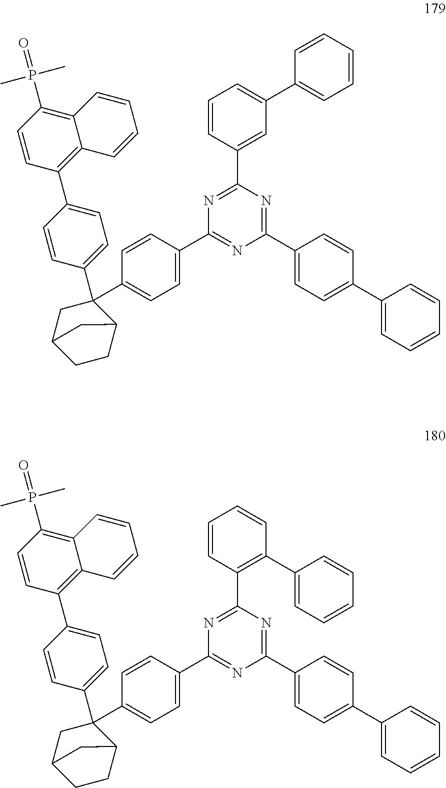 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12]

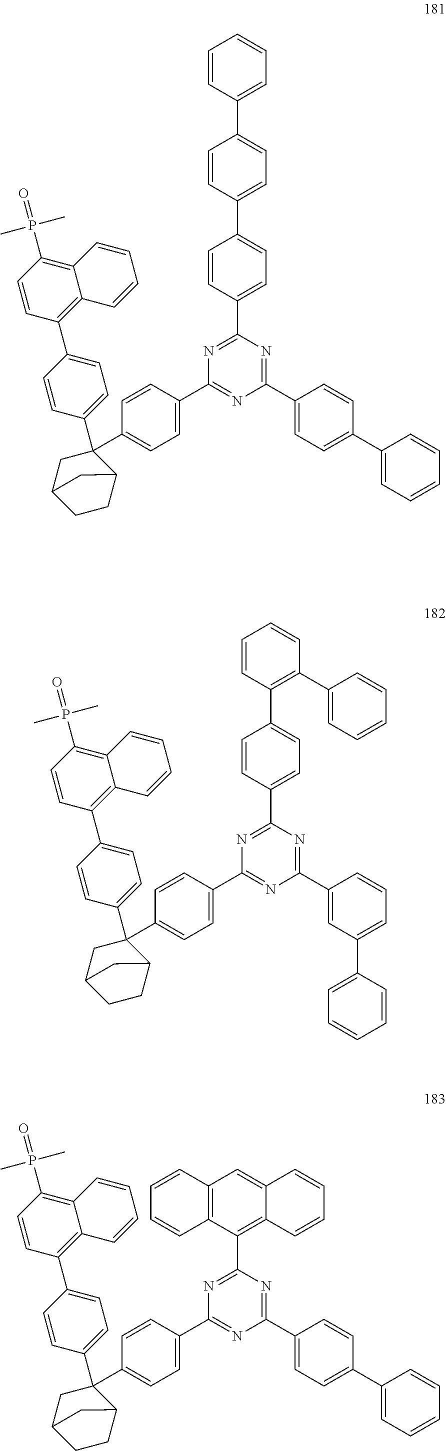 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12]

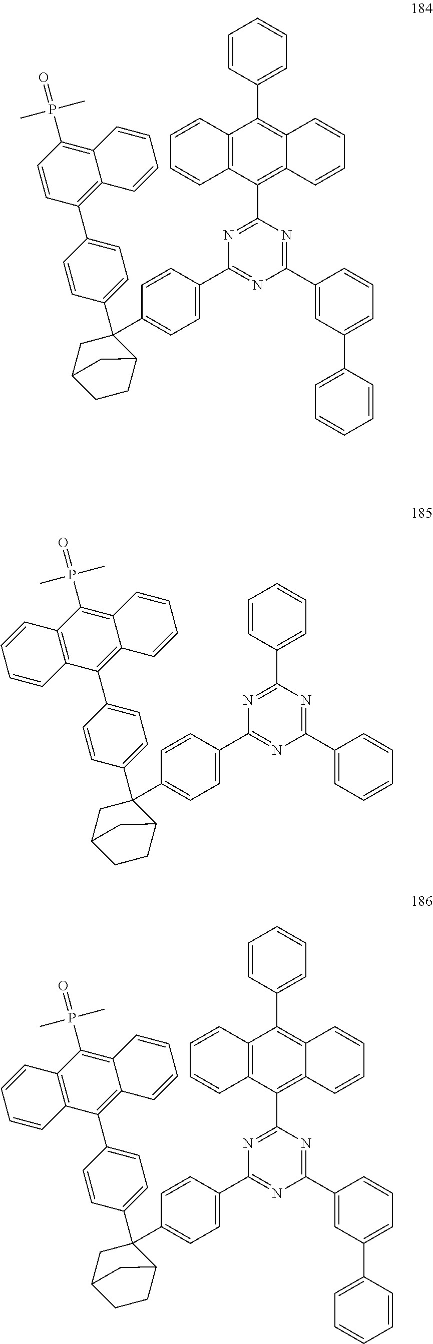 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12]

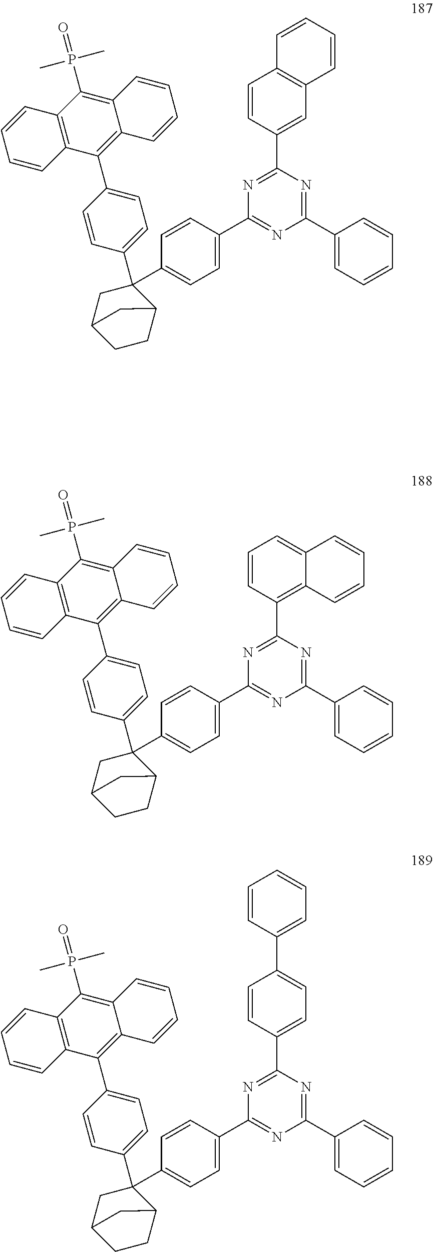 [SMILES: CP(C)(=O)c1c2ccccc2c(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccccc7)cc6)n5)cc4)CC4CCC3C4)cc2)c2ccccc12]

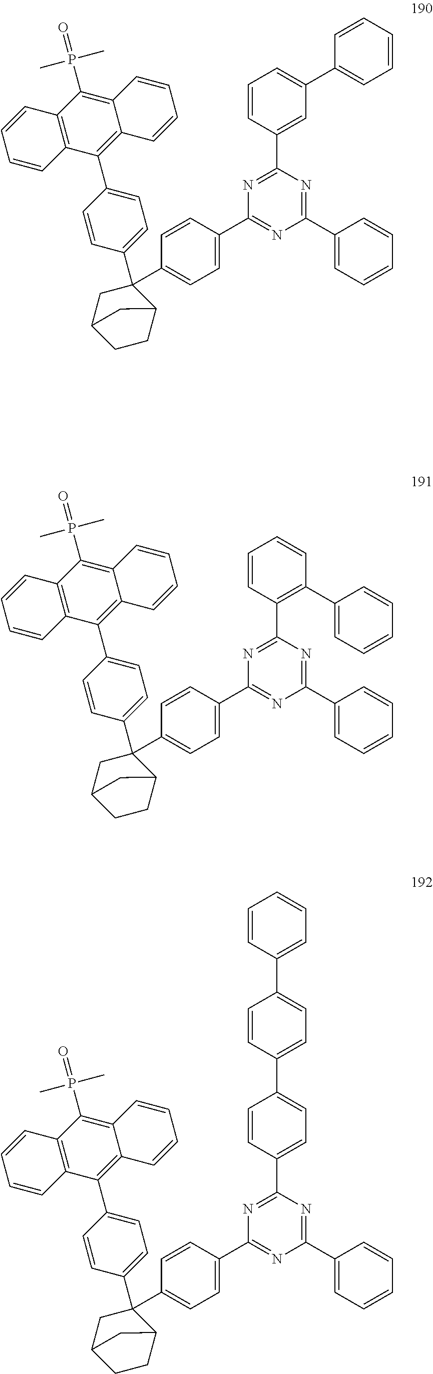 [SMILES: CP(C)(=O)c1c2ccccc2c(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12]

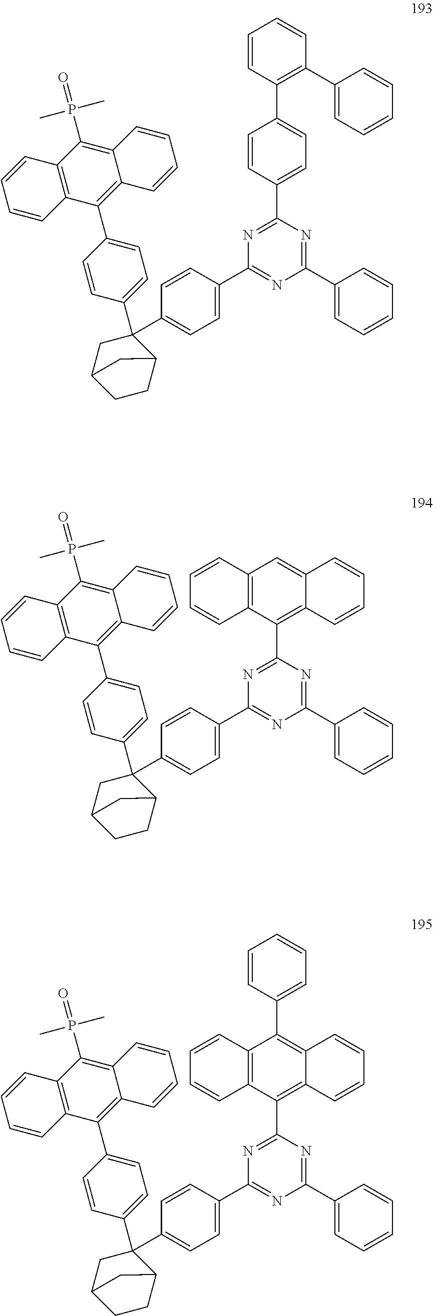 [SMILES: CP(C)(=O)c1c2ccccc2c(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12]

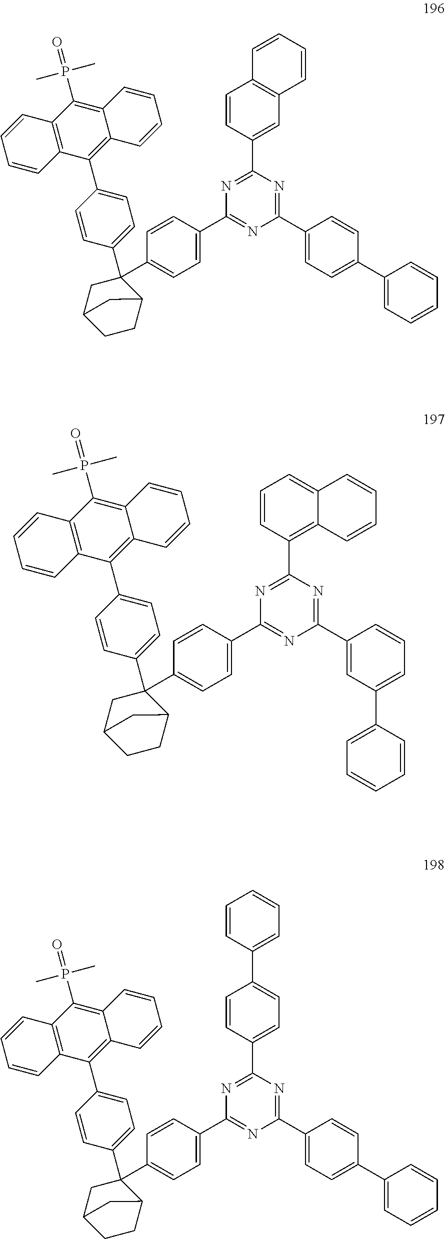 [SMILES: CP(C)(=O)c1c2ccccc2c(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12]

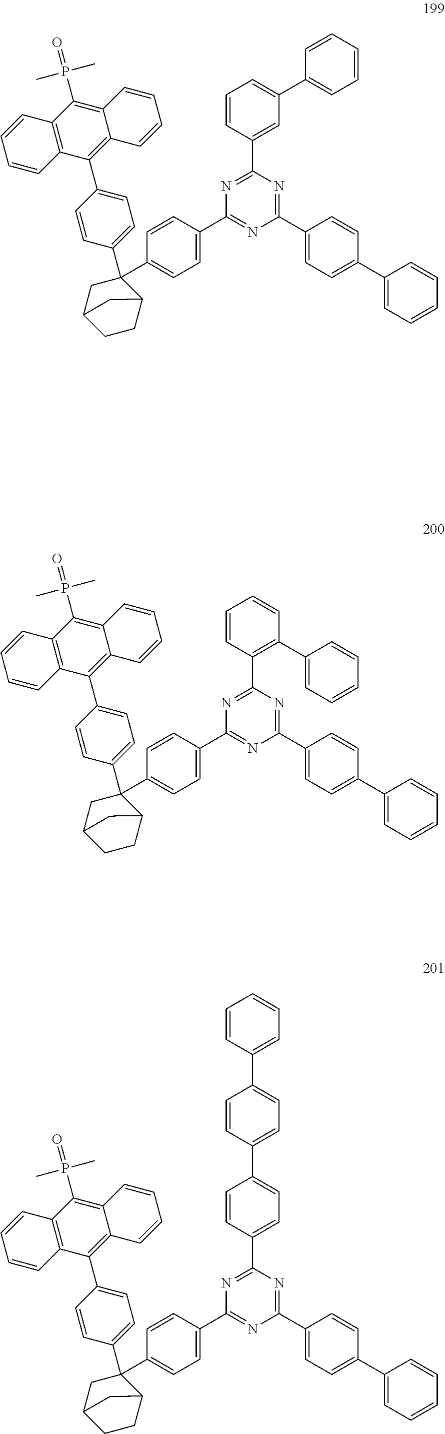 [SMILES: CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12]

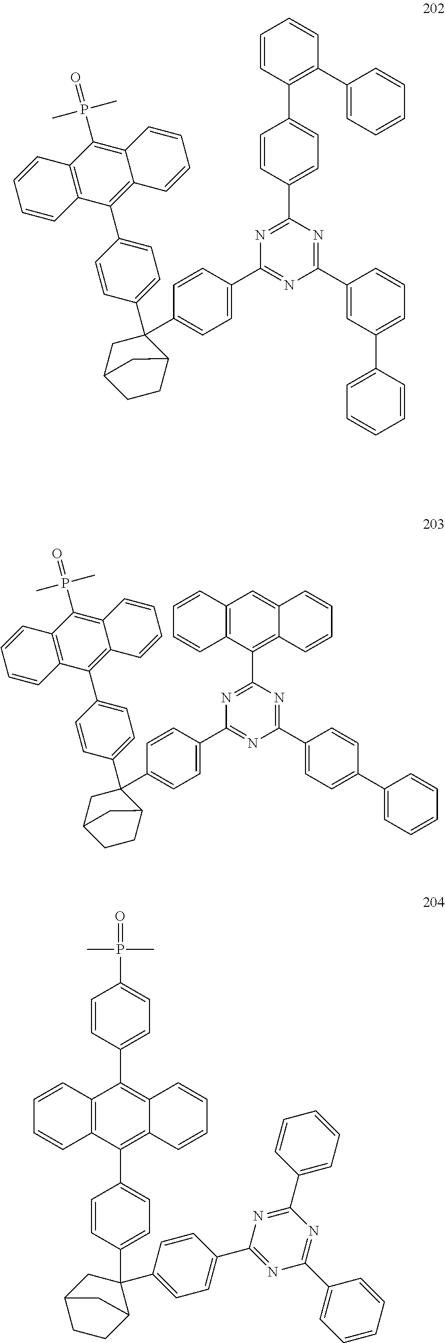 [SMILES: CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12 ; CP(C)(=O)c1ccc(-c2c3ccccc3c(-c3ccc(C4(c5ccc(-c6nc(-c7ccccc7)nc(-c7ccccc7)n6)cc5)CC5CCC4C5)cc3)c3ccccc23)cc1]

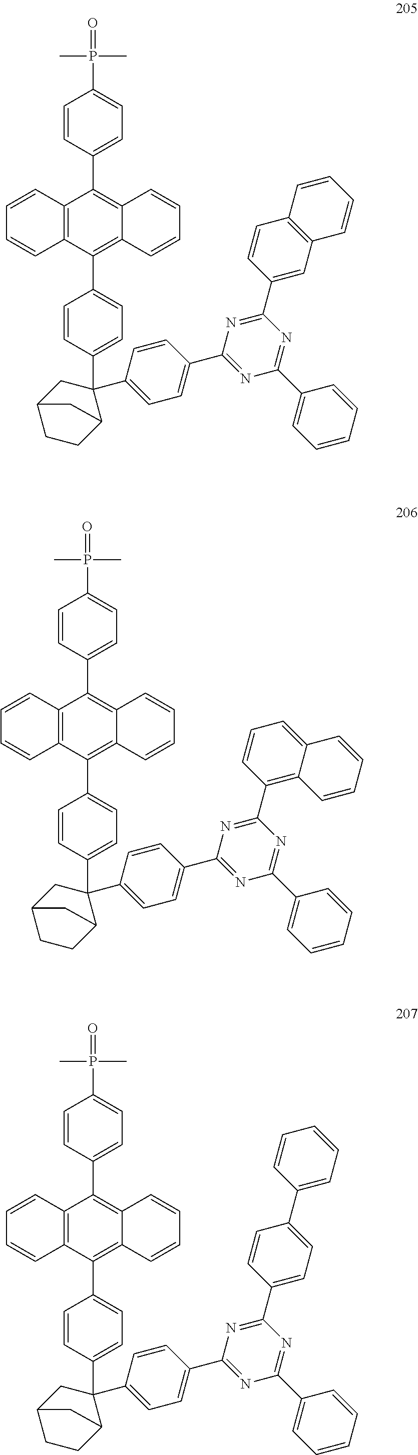 [SMILES: CP(C)(=O)c1ccc(-c2c3ccccc3c(-c3ccc(C4(c5ccc(-c6nc(-c7ccccc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8)cc7)n6)cc5)CC5CCC4C5)cc3)c3ccccc23)cc1]

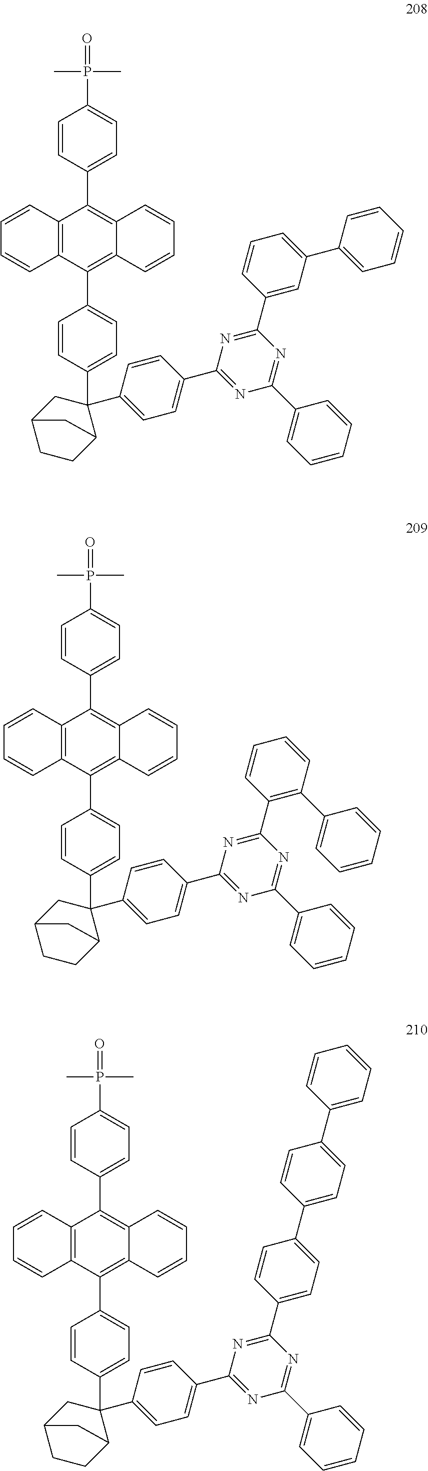 [SMILES: CP(C)(=O)c1ccc(-c2c3ccccc3c(-c3ccc(C4(c5ccc(-c6nc(-c7ccccc7)nc(-c7cccc(-c8ccccc8)c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CC5CCC4C5)cc3)c3ccccc23)cc1]

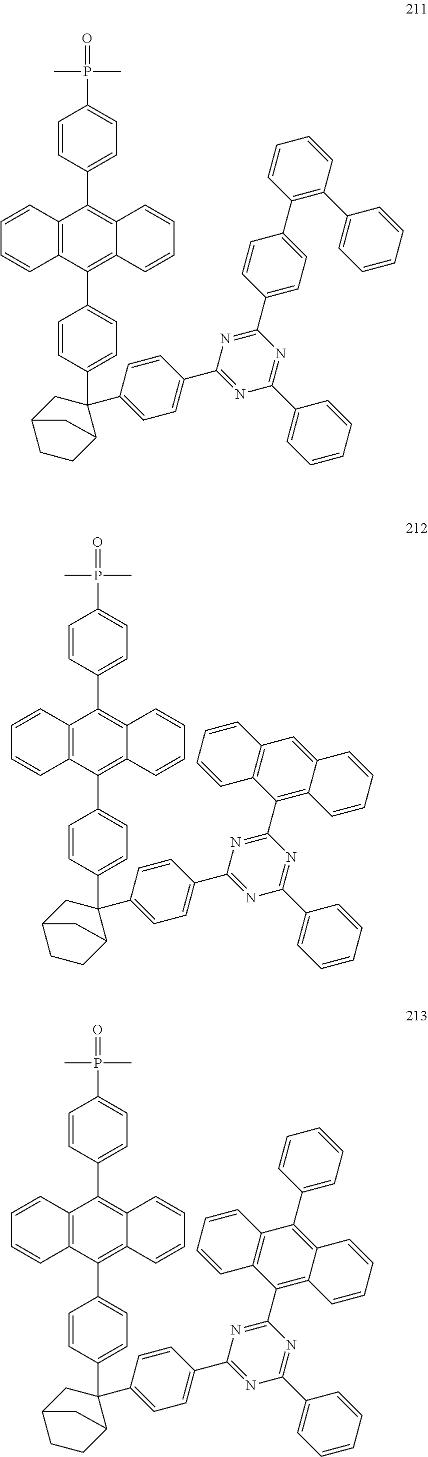 [SMILES: CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CC5CCC4C5)cc3)c3ccccc23)cc1]

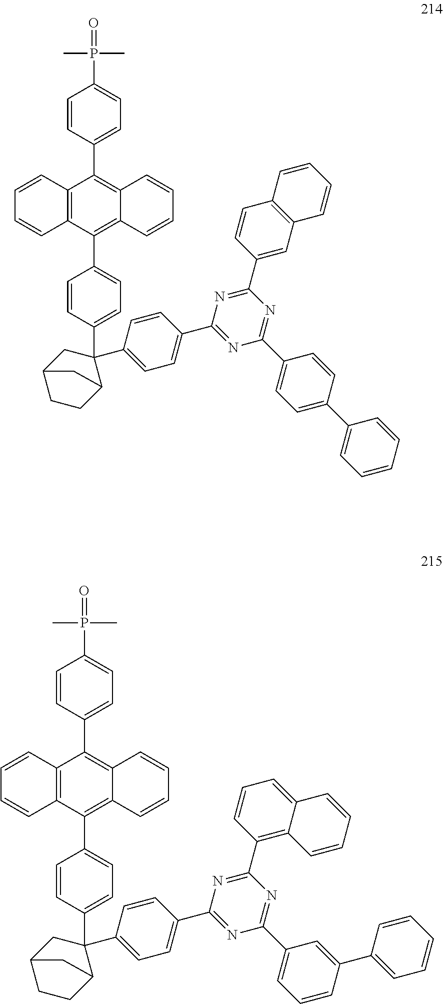 [SMILES: CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CC5CCC4C5)cc3)c3ccccc23)cc1]

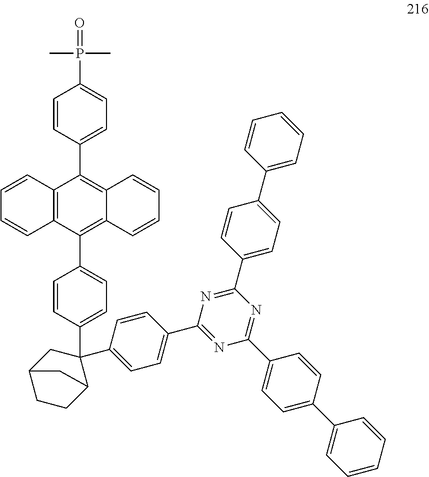 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CC5CCC4C5)cc3)c3ccccc23)cc1]

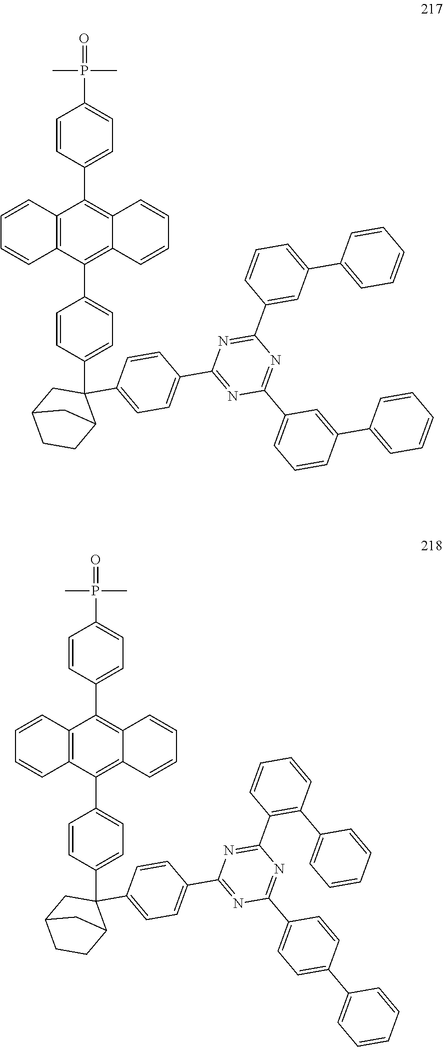 [SMILES: CP(C)(=O)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccccc7-c7ccccc7)n6)cc5)CC5CCC4C5)cc3)c3ccccc23)cc1]

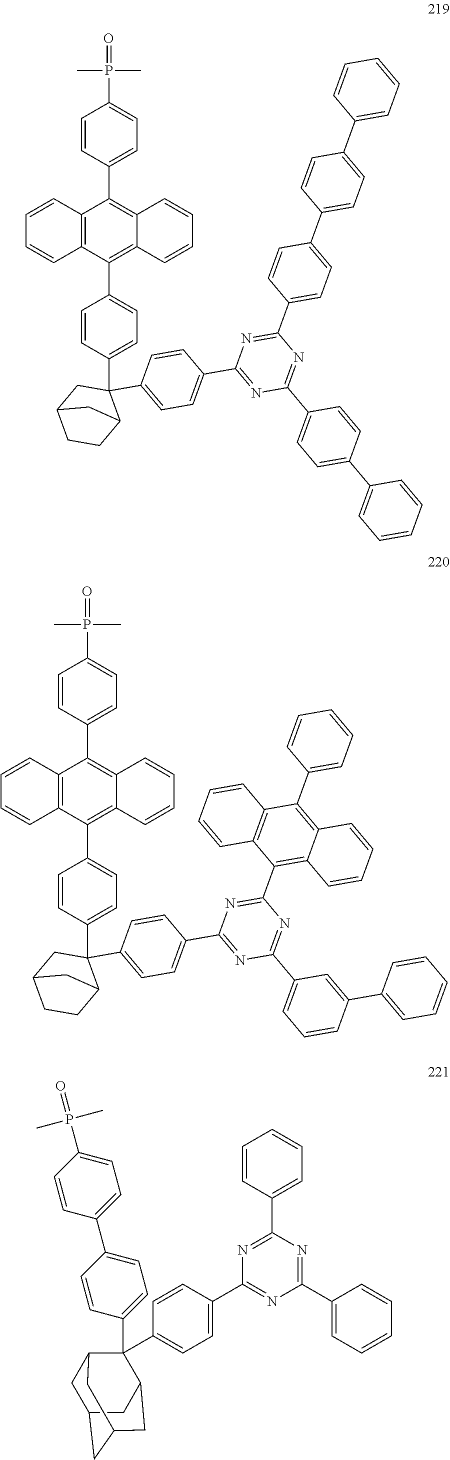 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CC5CCC4C5)cc3)c3ccccc23)cc1 ; CP(C)(=O)c1ccc(-c2ccc(C3(c4ccc(-c5nc(-c6ccccc6)nc(-c6ccccc6)n5)cc4)C4CC5CC(C4)CC3C5)cc2)cc1]

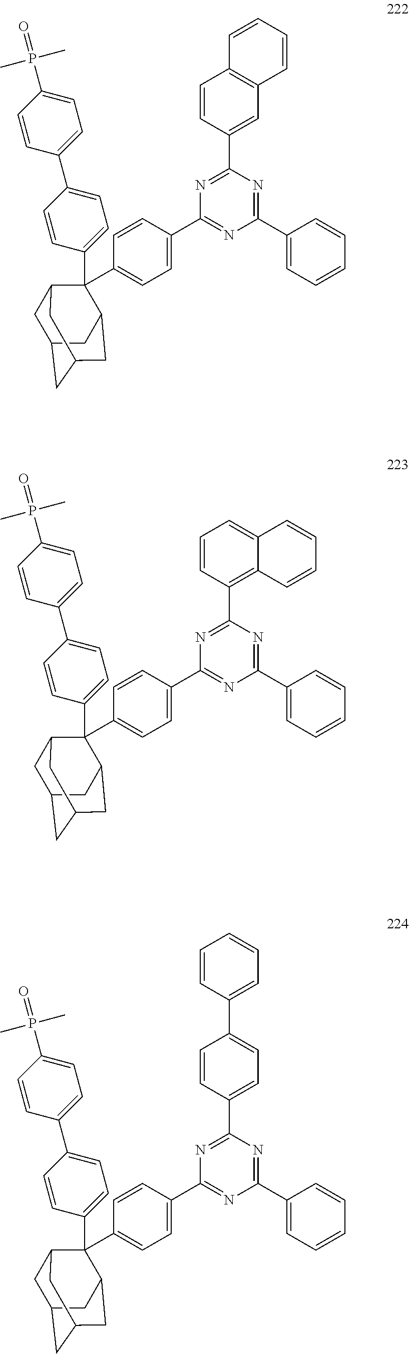 [SMILES: CP(C)(=O)c1ccc(-c2ccc(C3(c4ccc(-c5nc(-c6ccccc6)nc(-c6ccc7ccccc7c6)n5)cc4)C4CC5CC(C4)CC3C5)cc2)cc1 ; CP(C)(=O)c1ccc(-c2ccc(C3(c4ccc(-c5nc(-c6ccccc6)nc(-c6cccc7ccccc67)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc(-c7ccccc7)cc6)n5)cc4)C4CC5CC(C4)CC3C5)cc2)cc1]

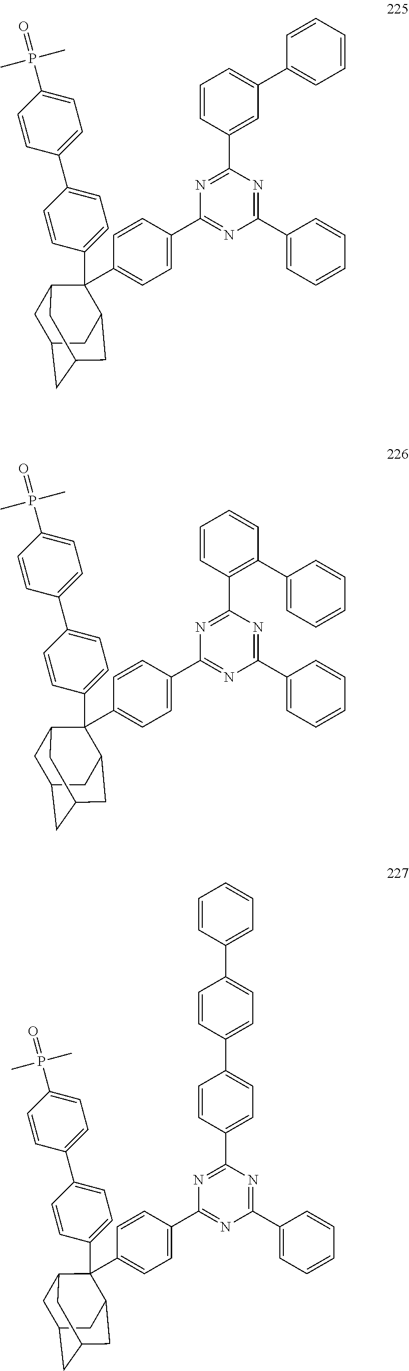 [SMILES: CP(C)(=O)c1ccc(-c2ccc(C3(c4ccc(-c5nc(-c6ccccc6)nc(-c6cccc(-c7ccccc7)c6)n5)cc4)C4CC5CC(C4)CC3C5)cc2)cc1 ; CP(C)(=O)c1ccc(-c2ccc(C3(c4ccc(-c5nc(-c6ccccc6)nc(-c6ccccc6-c6ccccc6)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)cc1]

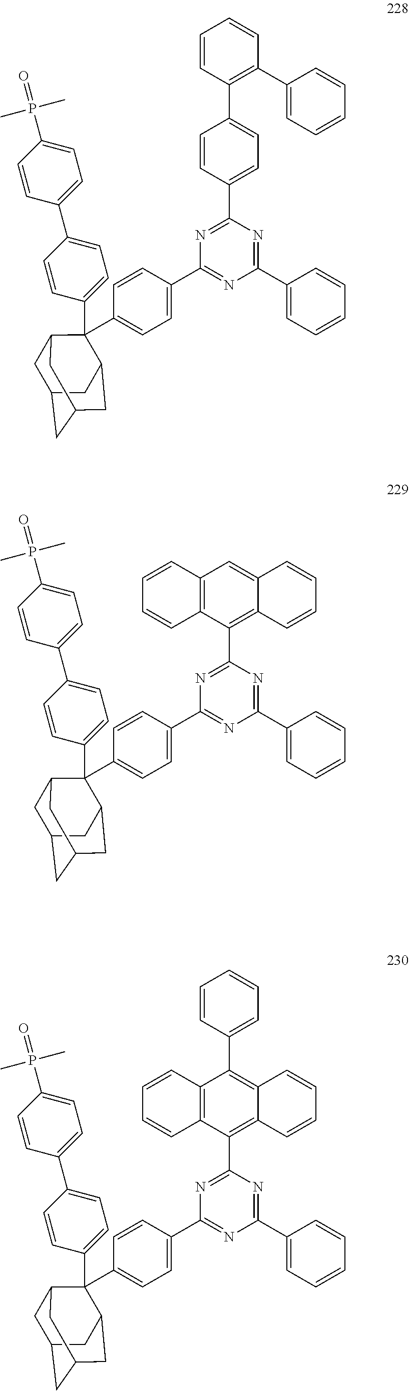 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)cc1 ; CP(C)(=O)c1ccc(-c2ccc(C3(c4ccc(-c5nc(-c6ccccc6)nc(-c6c7ccccc7cc7ccccc67)n5)cc4)C4CC5CC(C4)CC3C5)cc2)cc1 ; CP(C)(=O)c1ccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)cc1]

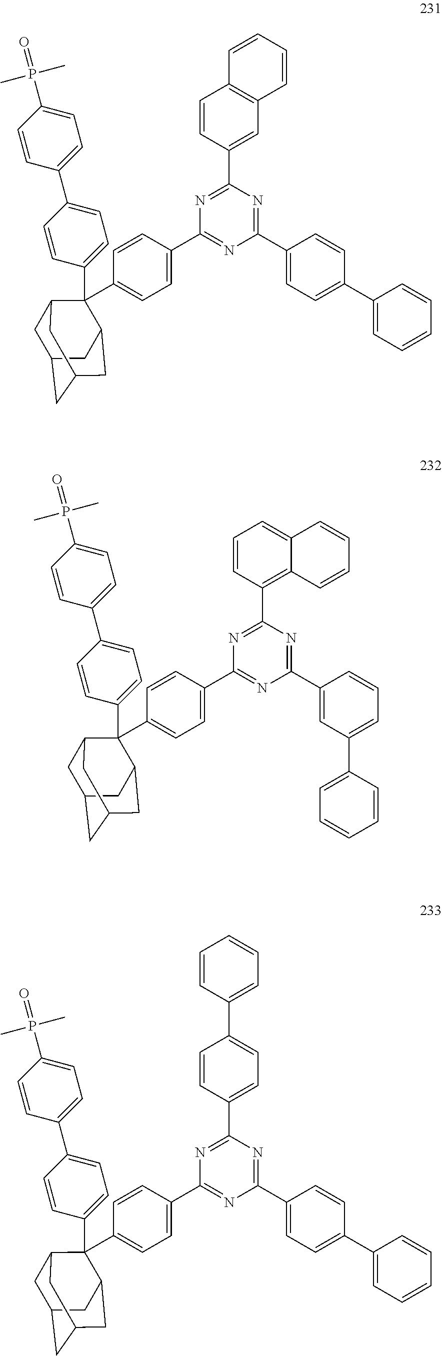 [SMILES: CP(C)(=O)c1ccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)cc1]

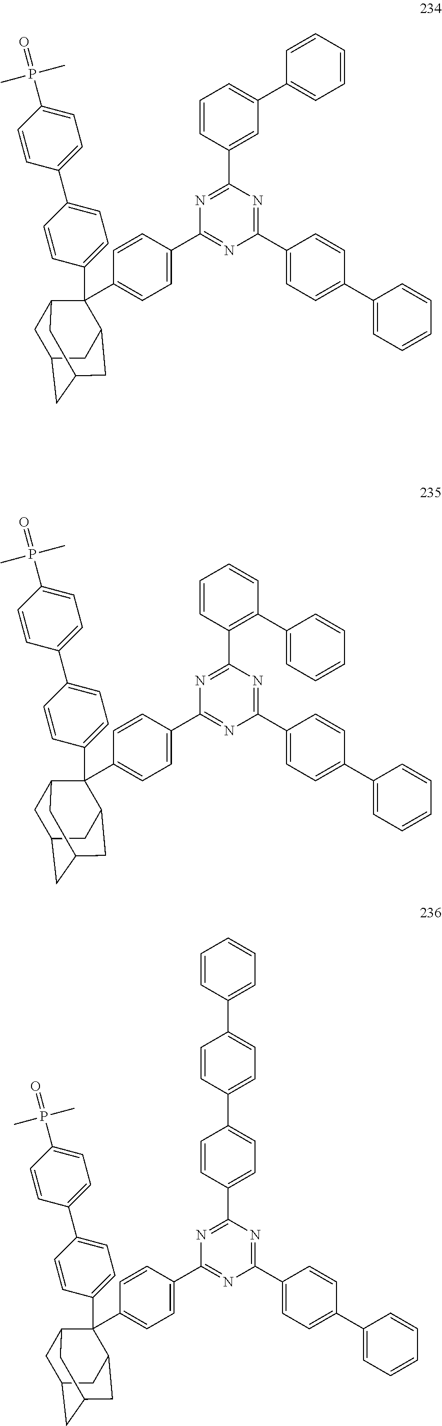 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)cc1]

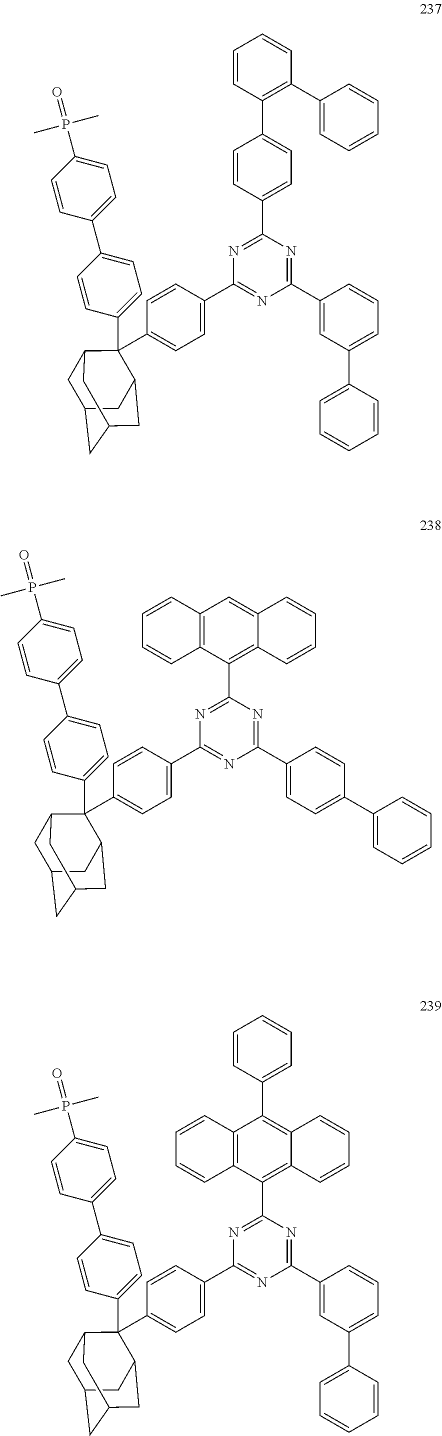 [SMILES: CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)cc1 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)cc1]

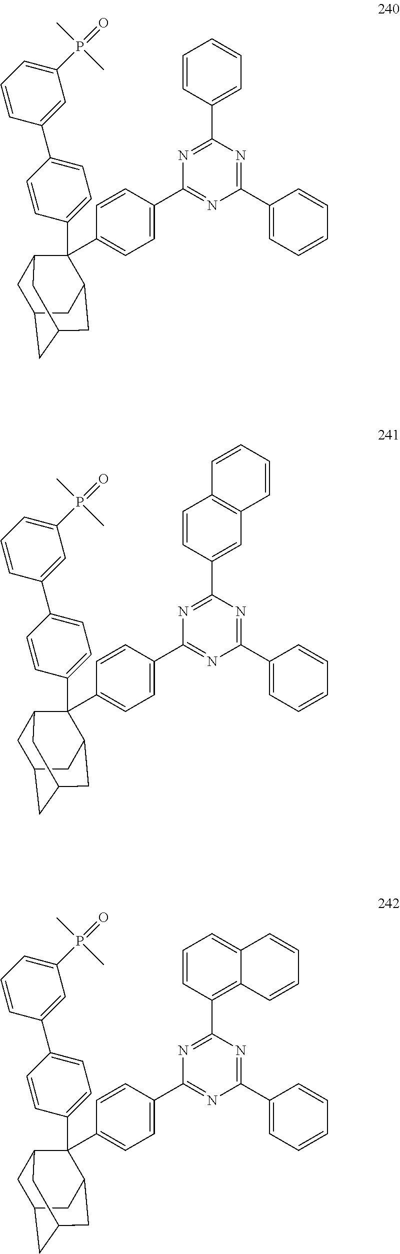 [SMILES: CP(C)(=O)c1cccc(-c2ccc(C3(c4ccc(-c5nc(-c6ccccc6)nc(-c6ccccc6)n5)cc4)C4CC5CC(C4)CC3C5)cc2)c1 ; CP(C)(=O)c1cccc(-c2ccc(C3(c4ccc(-c5nc(-c6ccccc6)nc(-c6ccc7ccccc7c6)n5)cc4)C4CC5CC(C4)CC3C5)cc2)c1 ; CP(C)(=O)c1cccc(-c2ccc(C3(c4ccc(-c5nc(-c6ccccc6)nc(-c6cccc7ccccc67)n5)cc4)C4CC5CC(C4)CC3C5)cc2)c1]

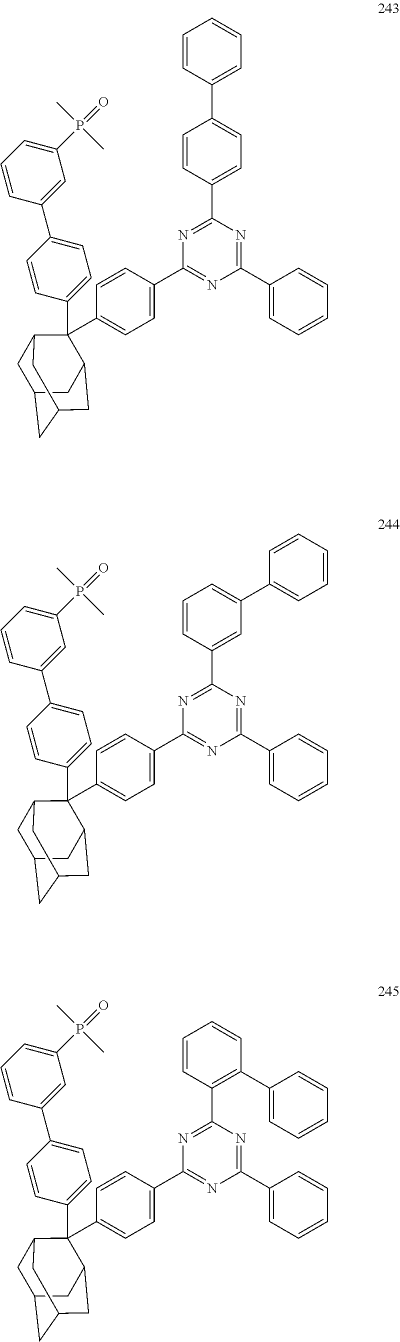 [SMILES: CP(C)(=O)c1cccc(-c2ccc(C3(c4ccc(-c5nc(-c6ccccc6)nc(-c6ccc(-c7ccccc7)cc6)n5)cc4)C4CC5CC(C4)CC3C5)cc2)c1 ; CP(C)(=O)c1cccc(-c2ccc(C3(c4ccc(-c5nc(-c6ccccc6)nc(-c6cccc(-c7ccccc7)c6)n5)cc4)C4CC5CC(C4)CC3C5)cc2)c1 ; CP(C)(=O)c1cccc(-c2ccc(C3(c4ccc(-c5nc(-c6ccccc6)nc(-c6ccccc6-c6ccccc6)n5)cc4)C4CC5CC(C4)CC3C5)cc2)c1]

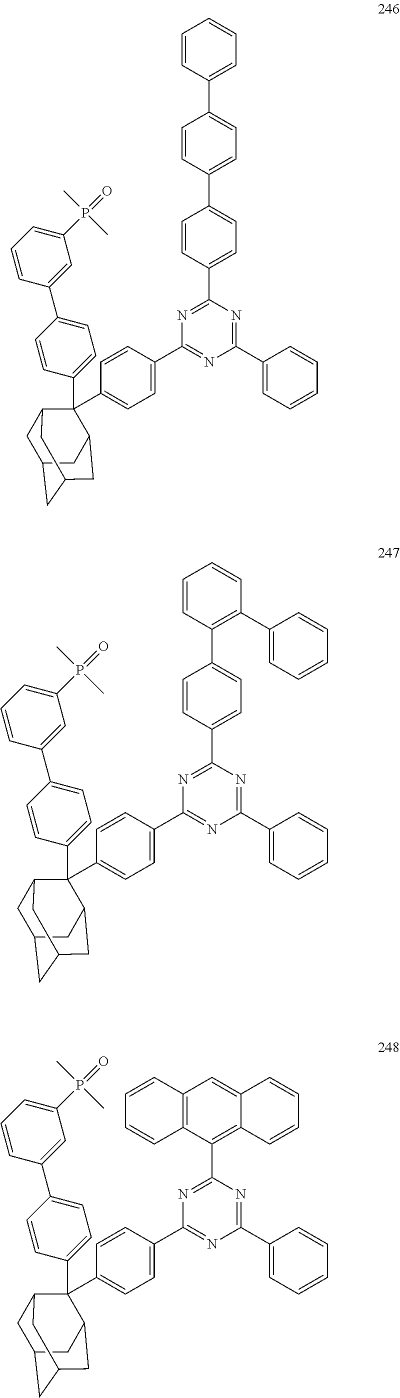 [SMILES: CP(C)(=O)c1cccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c1 ; CP(C)(=O)c1cccc(-c2ccc(C3(c4ccc(-c5nc(-c6ccccc6)nc(-c6c7ccccc7cc7ccccc67)n5)cc4)C4CC5CC(C4)CC3C5)cc2)c1]

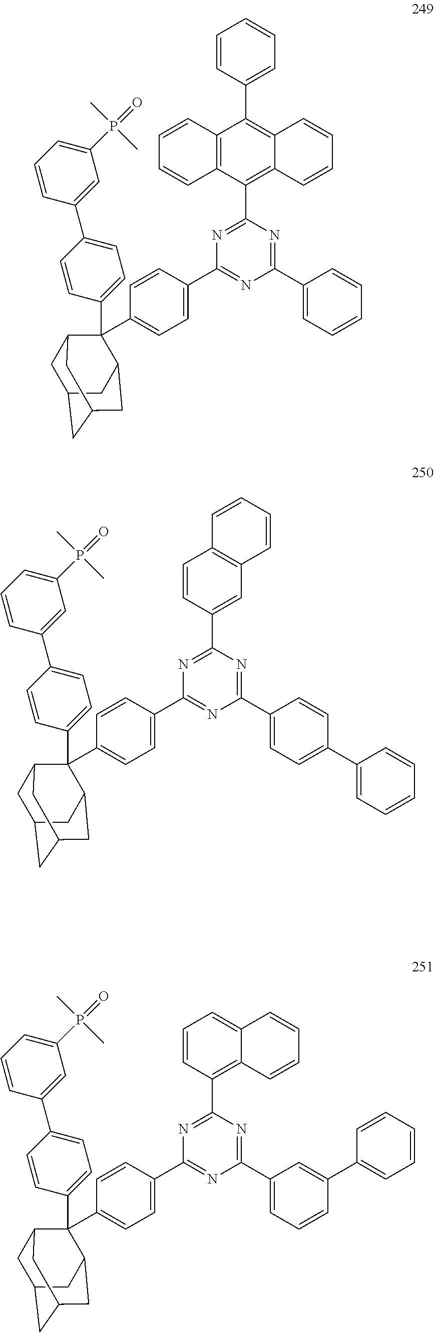 [SMILES: CP(C)(=O)c1cccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c1 ; CP(C)(=O)c1cccc(-c2ccc(C3(c4ccc(-c5nc(-c6cccc(-c7ccccc7)c6)nc(-c6cccc7ccccc67)n5)cc4)C4CC5CC(C4)CC3C5)cc2)c1]

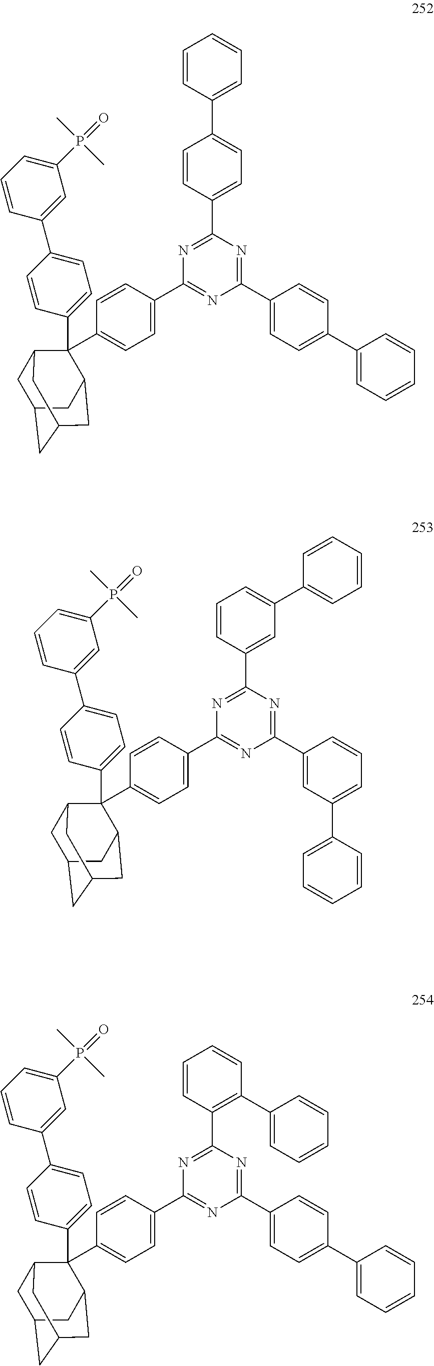 [SMILES: CP(C)(=O)c1cccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c1]

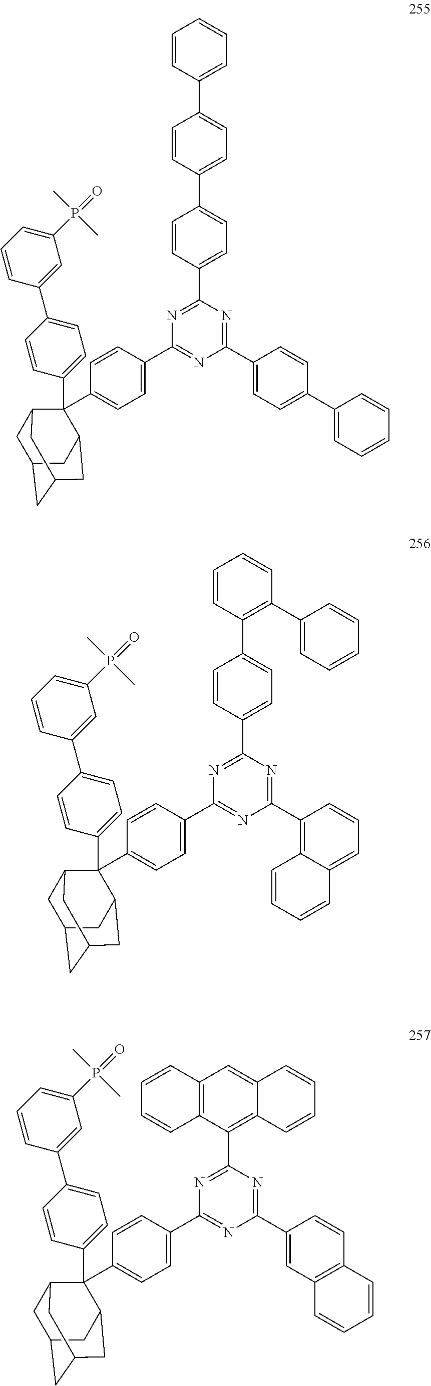 [SMILES: CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)C4CC5CC(C4)CC3C5)cc2)c1 ; CP(C)(=O)c1cccc(-c2ccc(C3(c4ccc(-c5nc(-c6ccc7ccccc7c6)nc(-c6c7ccccc7cc7ccccc67)n5)cc4)C4CC5CC(C4)CC3C5)cc2)c1]

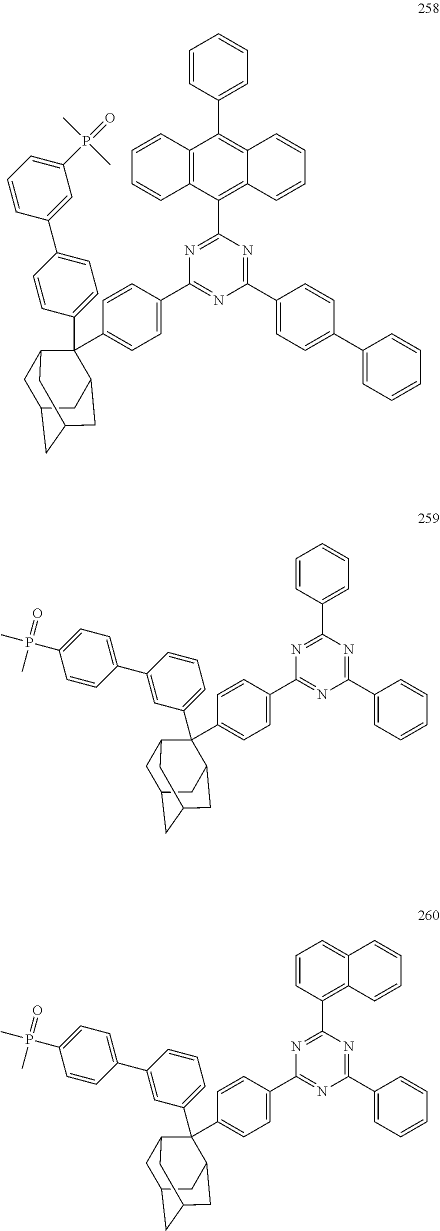 [SMILES: CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)C4CC5CC(C4)CC3C5)cc2)c1 ; CP(C)(=O)c1ccc(-c2cccc(C3(c4ccc(-c5nc(-c6ccccc6)nc(-c6ccccc6)n5)cc4)C4CC5CC(C4)CC3C5)c2)cc1 ; CP(C)(=O)c1ccc(-c2cccc(C3(c4ccc(-c5nc(-c6ccccc6)nc(-c6cccc7ccccc67)n5)cc4)C4CC5CC(C4)CC3C5)c2)cc1]

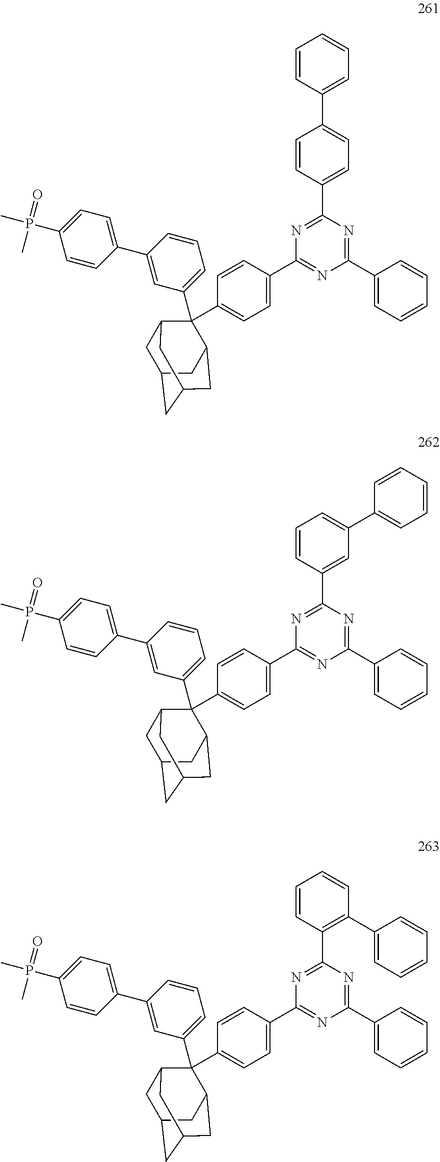 [SMILES: CP(C)(=O)c1ccc(-c2cccc(C3(c4ccc(-c5nc(-c6ccccc6)nc(-c6ccc(-c7ccccc7)cc6)n5)cc4)C4CC5CC(C4)CC3C5)c2)cc1 ; CP(C)(=O)c1ccc(-c2cccc(C3(c4ccc(-c5nc(-c6ccccc6)nc(-c6cccc(-c7ccccc7)c6)n5)cc4)C4CC5CC(C4)CC3C5)c2)cc1 ; CP(C)(=O)c1ccc(-c2cccc(C3(c4ccc(-c5nc(-c6ccccc6)nc(-c6ccccc6-c6ccccc6)n5)cc4)C4CC5CC(C4)CC3C5)c2)cc1]

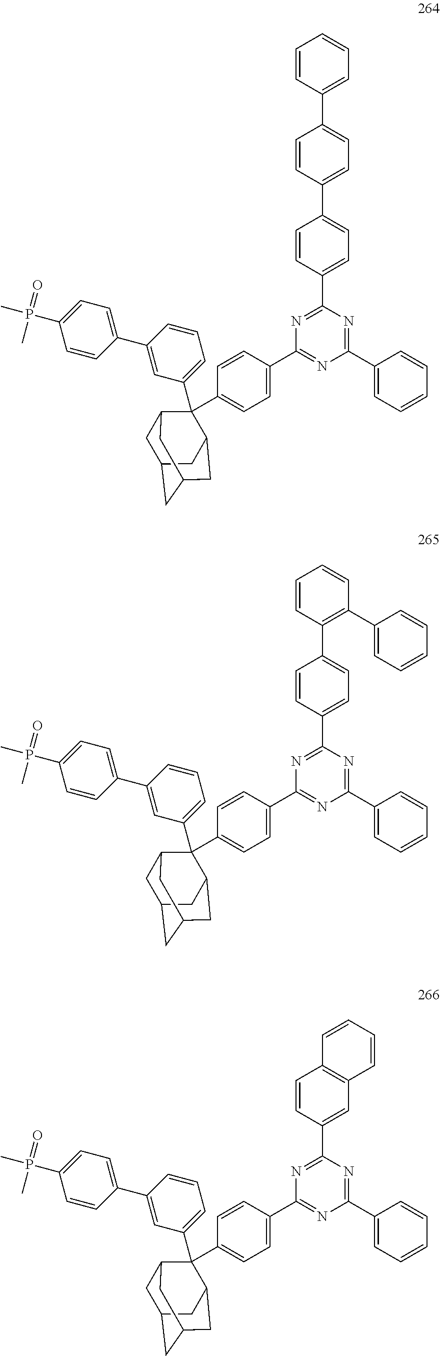 [SMILES: CP(C)(=O)c1ccc(-c2cccc(C3(c4ccc(-c5nc(-c6ccccc6)nc(-c6ccc(-c7ccc(-c8ccccc8)cc7)cc6)n5)cc4)C4CC5CC(C4)CC3C5)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)C4CC5CC(C4)CC3C5)c2)cc1 ; CP(C)(=O)c1ccc(-c2cccc(C3(c4ccc(-c5nc(-c6ccccc6)nc(-c6ccc7ccccc7c6)n5)cc4)C4CC5CC(C4)CC3C5)c2)cc1]

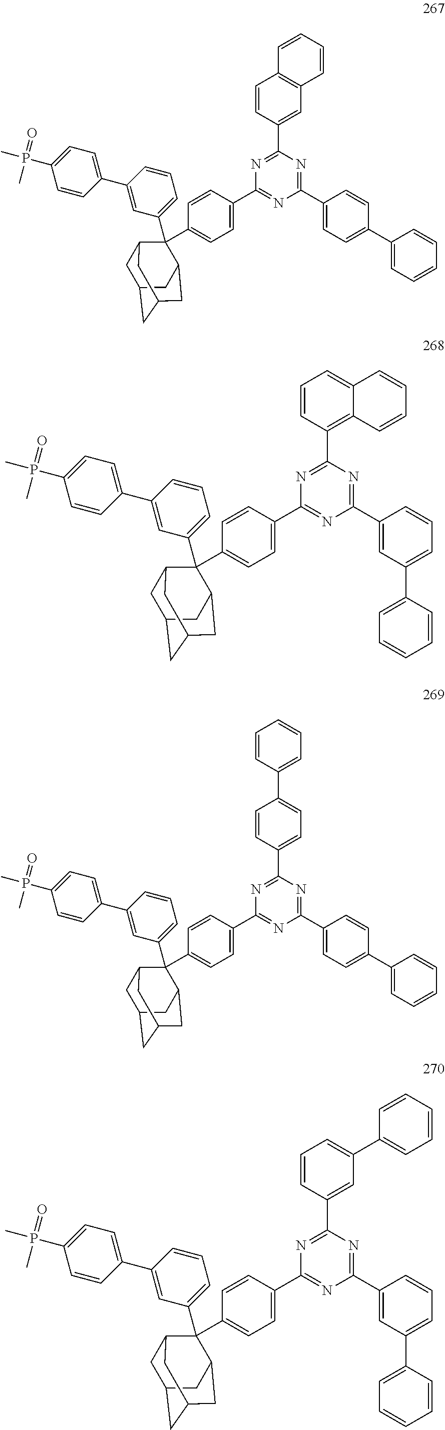 [SMILES: CP(C)(=O)c1ccc(-c2cccc(C3(c4ccc(-c5nc(-c6ccc(-c7ccccc7)cc6)nc(-c6ccc7ccccc7c6)n5)cc4)C4CC5CC(C4)CC3C5)c2)cc1 ; CP(C)(=O)c1ccc(-c2cccc(C3(c4ccc(-c5nc(-c6cccc(-c7ccccc7)c6)nc(-c6cccc7ccccc67)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)C4CC5CC(C4)CC3C5)c2)cc1 ; CP(C)(=O)c1ccc(-c2cccc(C3(c4ccc(-c5nc(-c6cccc(-c7ccccc7)c6)nc(-c6cccc(-c7ccccc7)c6)n5)cc4)C4CC5CC(C4)CC3C5)c2)cc1]

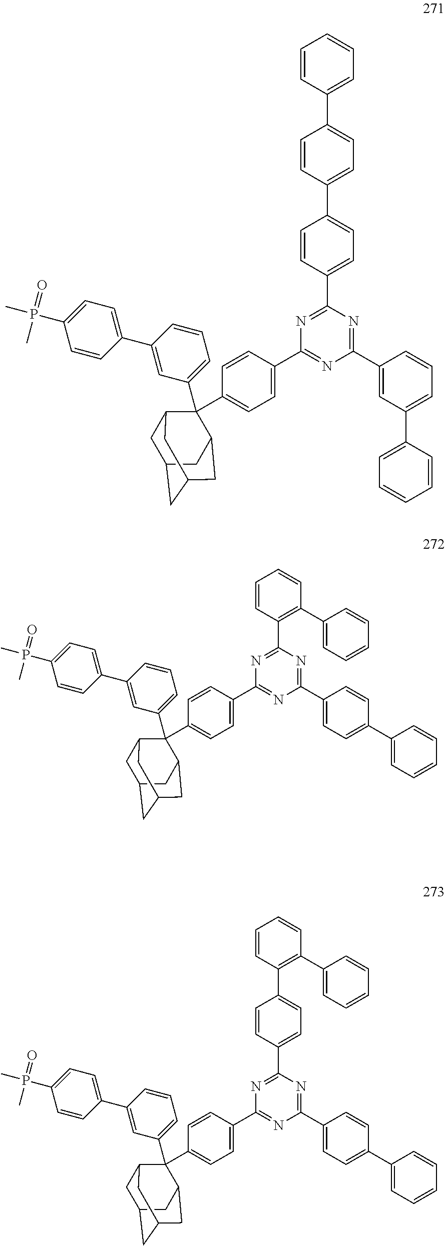 [SMILES: CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)C4CC5CC(C4)CC3C5)c2)cc1]

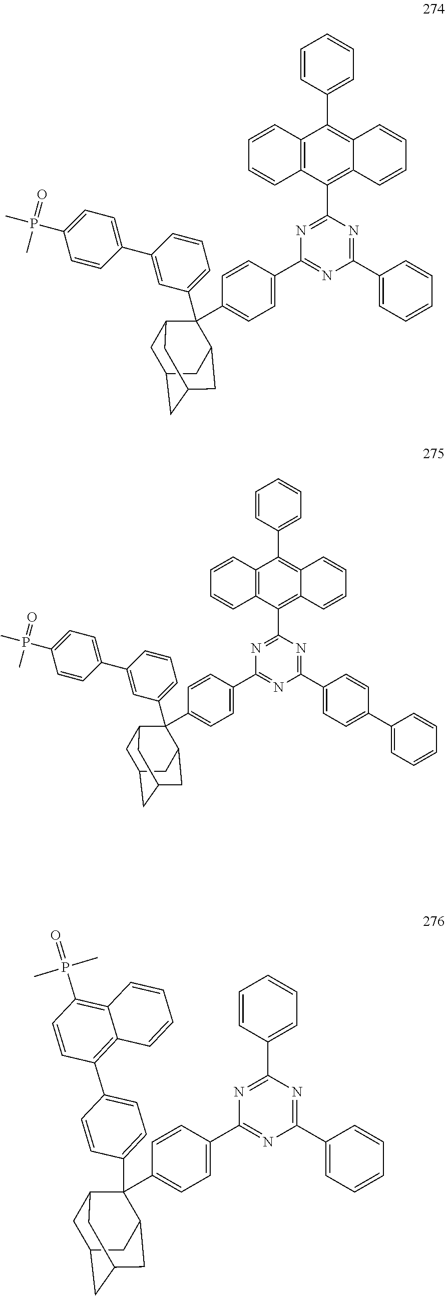 [SMILES: CP(C)(=O)c1ccc(-c2cccc(C3(c4ccc(-c5nc(-c6ccccc6)nc(-c6c7ccccc7c(-c7ccccc7)c7ccccc67)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)C4CC5CC(C4)CC3C5)c2)cc1 ; CP(C)(=O)c1ccc(-c2ccc(C3(c4ccc(-c5nc(-c6ccccc6)nc(-c6ccccc6)n5)cc4)C4CC5CC(C4)CC3C5)cc2)c2ccccc12]

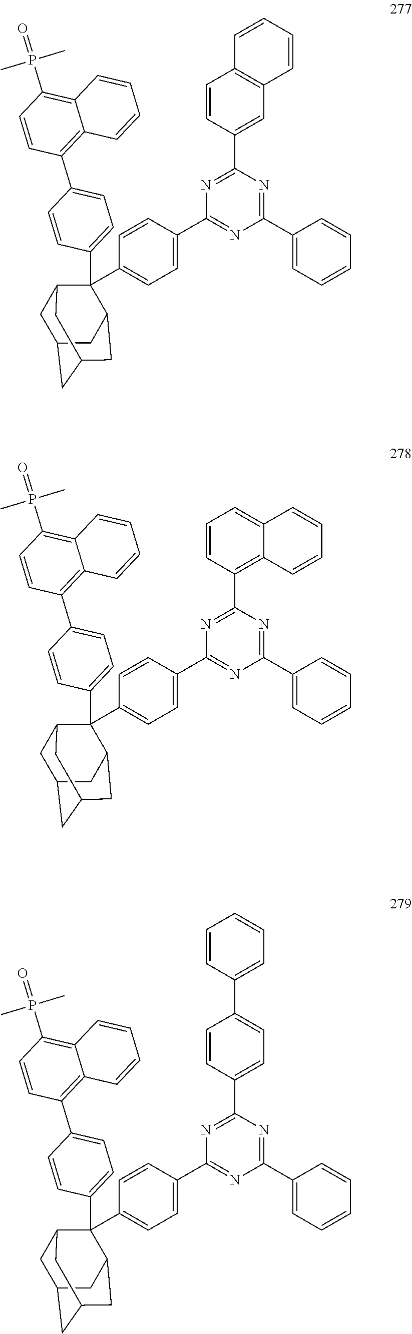 [SMILES: CP(C)(=O)c1ccc(-c2ccc(C3(c4ccc(-c5nc(-c6ccccc6)nc(-c6ccc7ccccc7c6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6cccc7ccccc67)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc(-c7ccccc7)cc6)n5)cc4)C4CC5CC(C4)CC3C5)cc2)c2ccccc12]

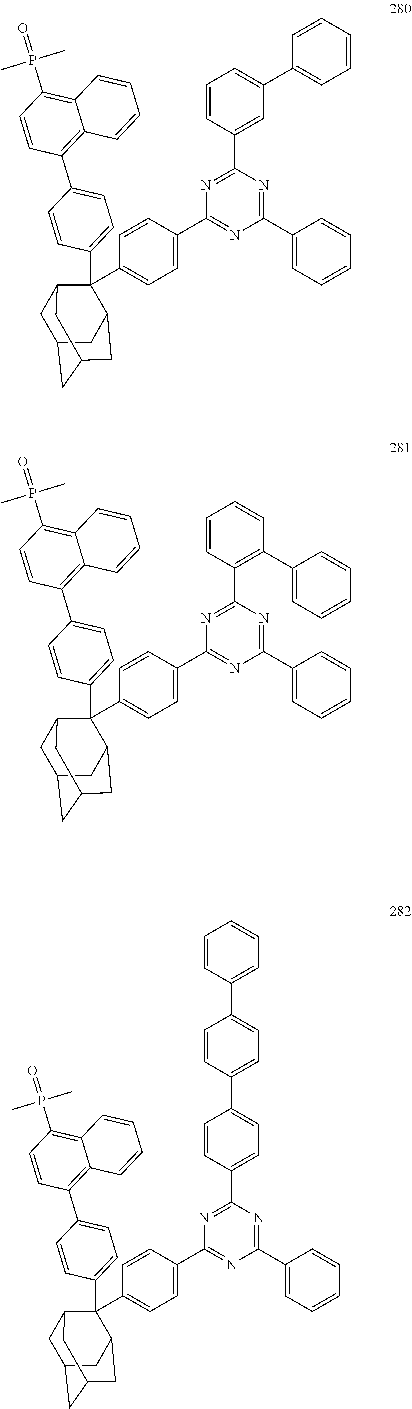 [SMILES: CP(C)(=O)c1ccc(-c2ccc(C3(c4ccc(-c5nc(-c6ccccc6)nc(-c6cccc(-c7ccccc7)c6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccccc6-c6ccccc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c2ccccc12]

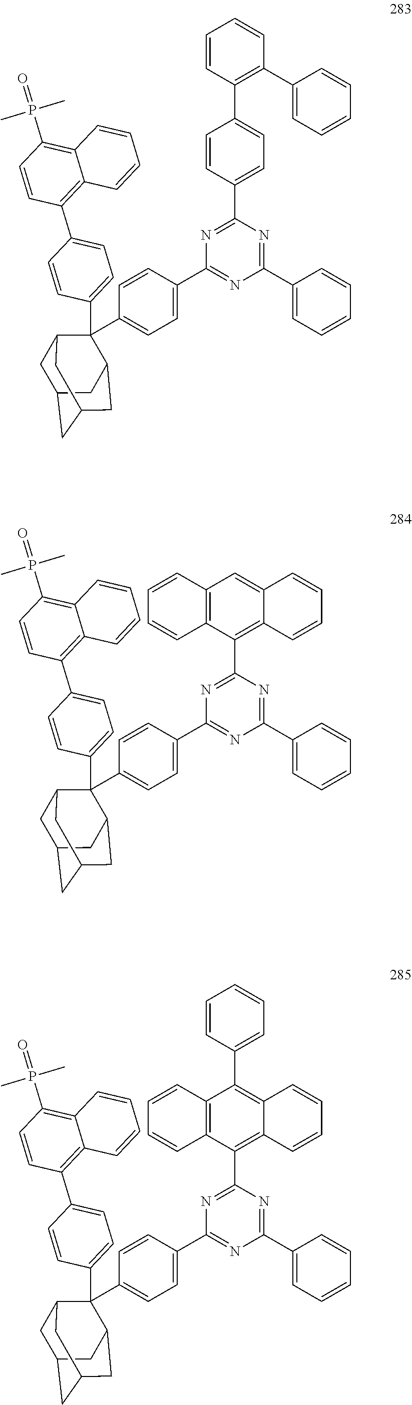 [SMILES: CP(C)(=O)c1ccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c2ccccc12]

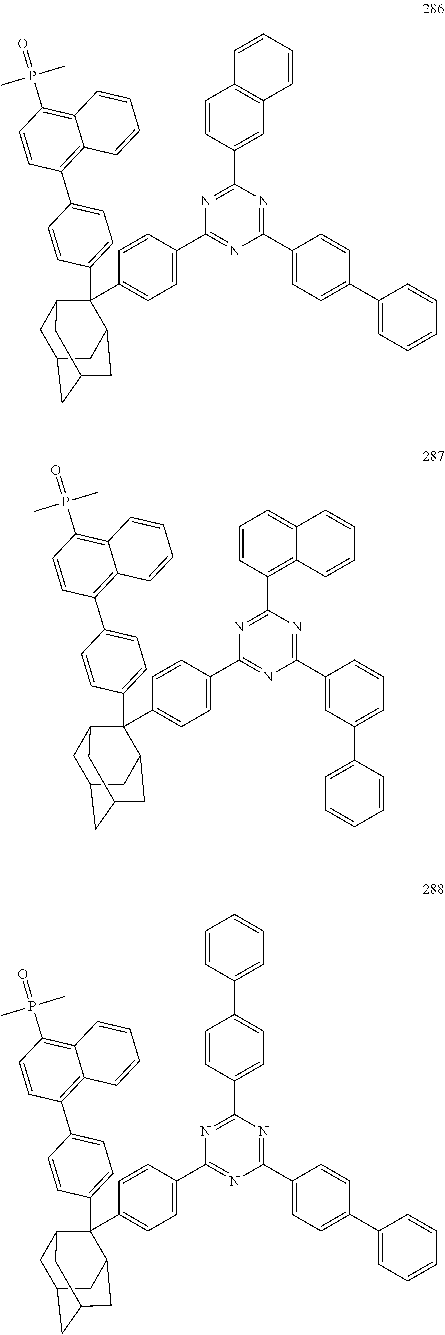 [SMILES: CP(C)(=O)c1ccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c2ccccc12]

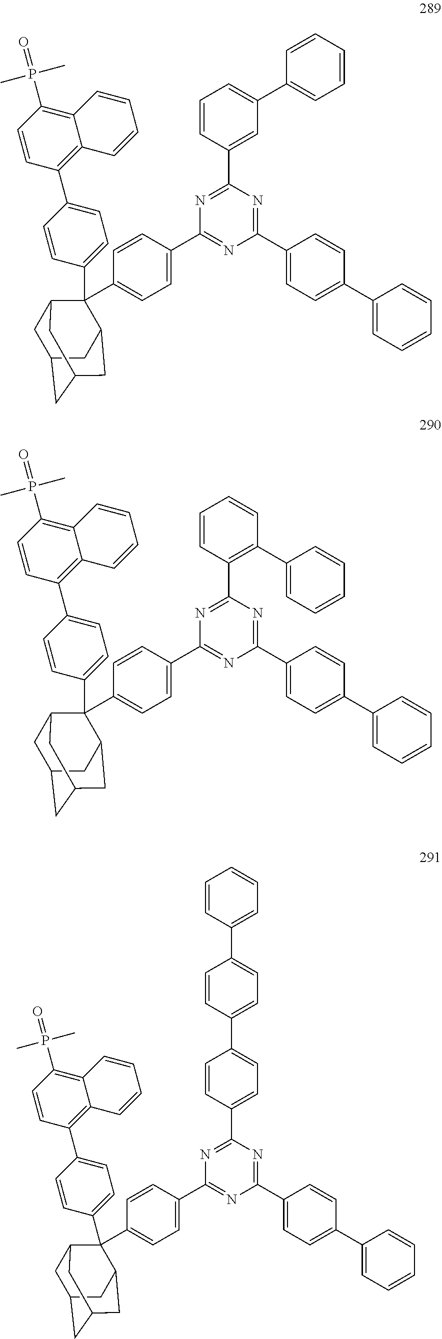 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c2ccccc12]

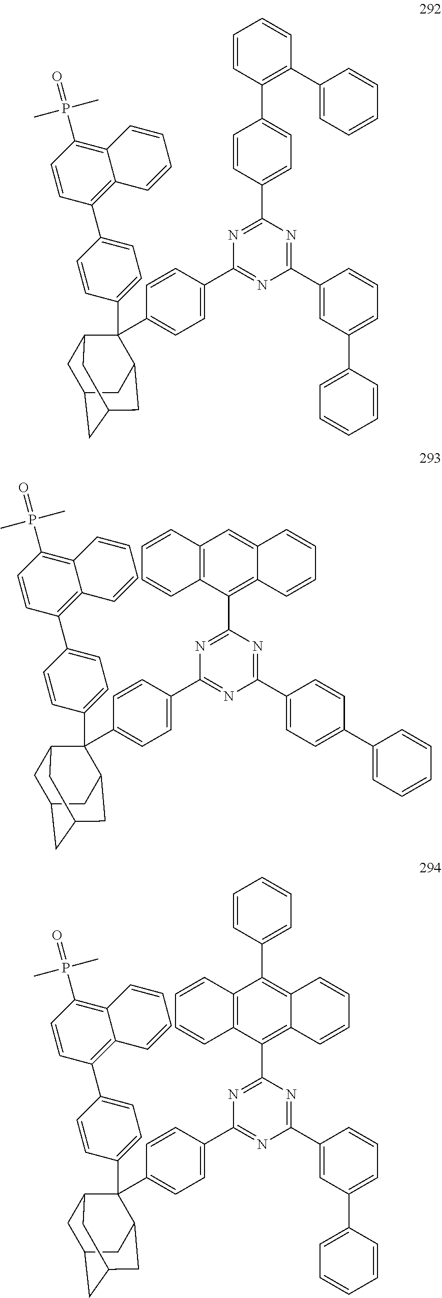 [SMILES: CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)c2ccccc12 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)c2ccccc12]

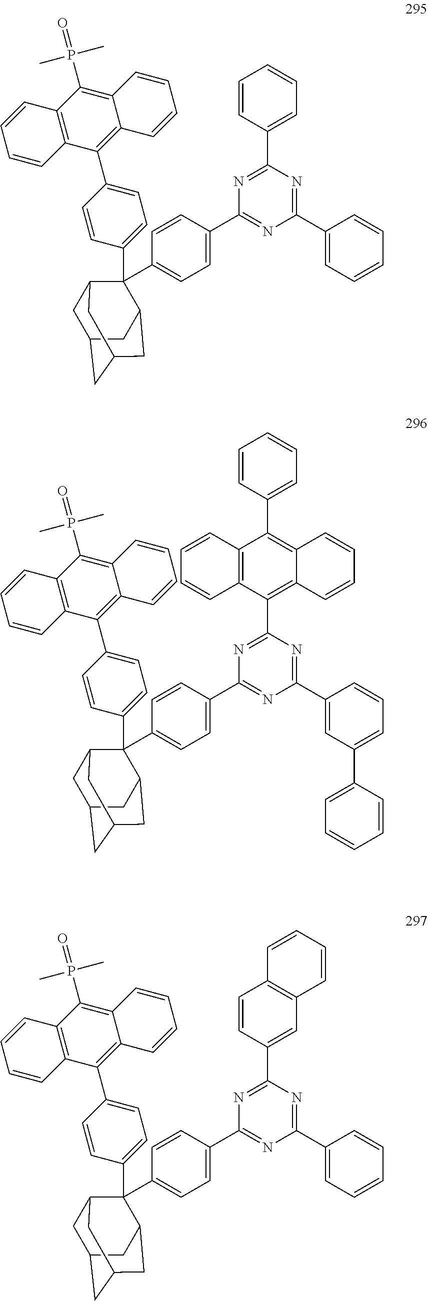 [SMILES: CP(C)(=O)c1c2ccccc2c(-c2ccc(C3(c4ccc(-c5nc(-c6ccccc6)nc(-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc7ccccc7c6)n5)cc4)C4CC5CC(C4)CC3C5)cc2)c2ccccc12]

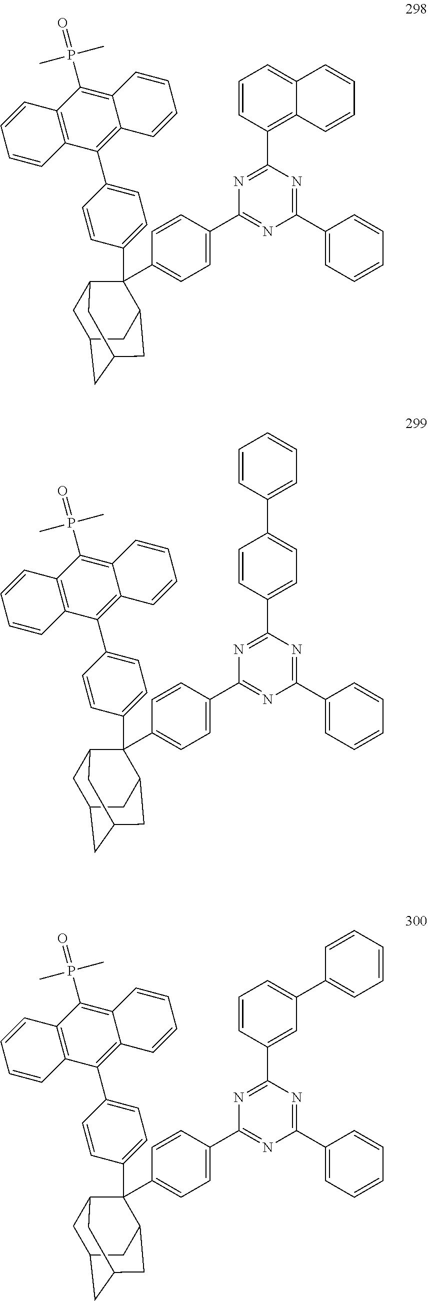 [SMILES: CP(C)(=O)c1c2ccccc2c(-c2ccc(C3(c4ccc(-c5nc(-c6ccccc6)nc(-c6cccc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc(-c7ccccc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6cccc(-c7ccccc7)c6)n5)cc4)C4CC5CC(C4)CC3C5)cc2)c2ccccc12]

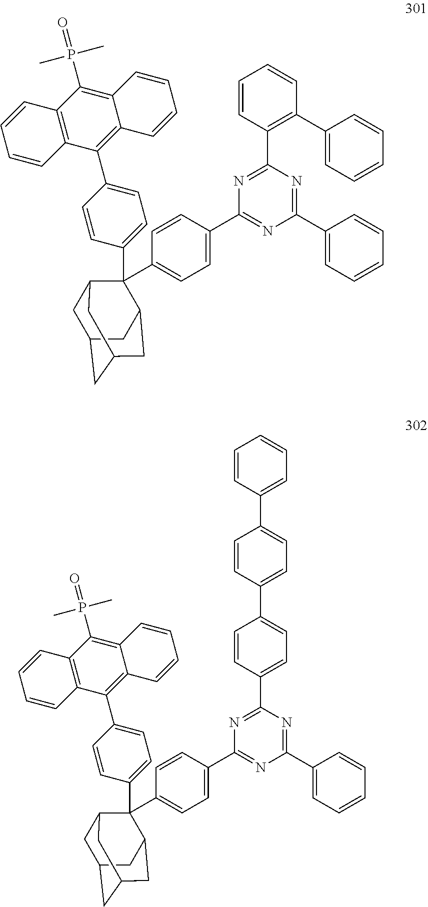 [SMILES: CP(C)(=O)c1c2ccccc2c(-c2ccc(C3(c4ccc(-c5nc(-c6ccccc6)nc(-c6ccccc6-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c2ccccc12]

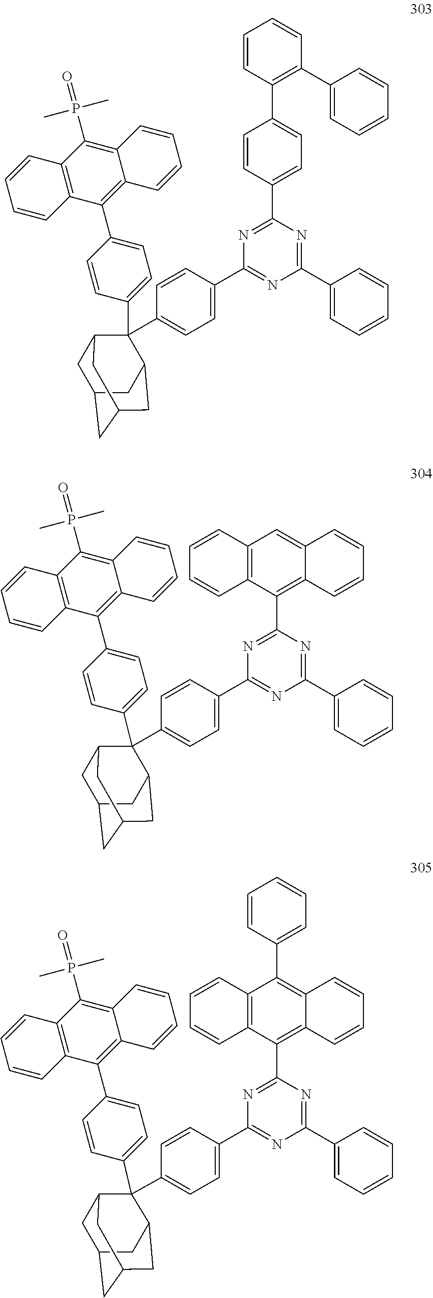 [SMILES: CP(C)(=O)c1c2ccccc2c(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c2ccccc12]

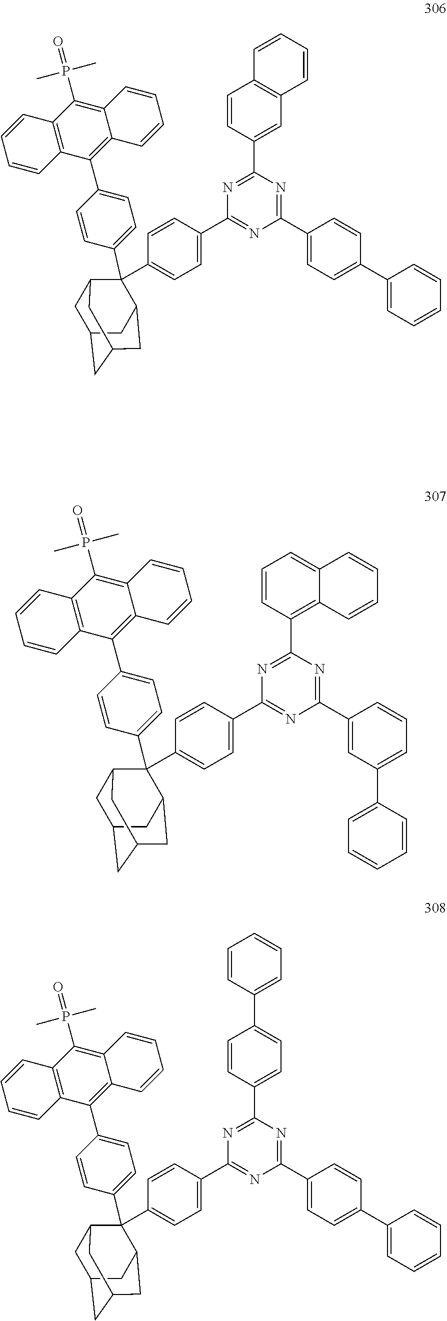 [SMILES: CP(C)(=O)c1c2ccccc2c(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c2ccccc12 ; CP(C)(=O)c1c2ccccc2c(-c2ccc(C3(c4ccc(-c5nc(-c6cccc(-c7ccccc7)c6)nc(-c6cccc7ccccc67)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c2ccccc12]

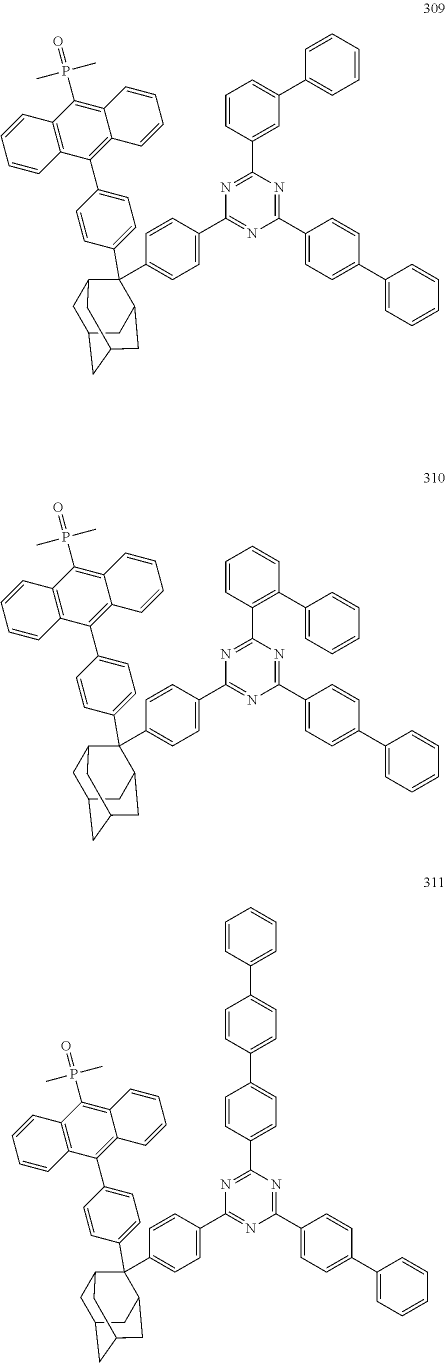 [SMILES: CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c2ccccc12]

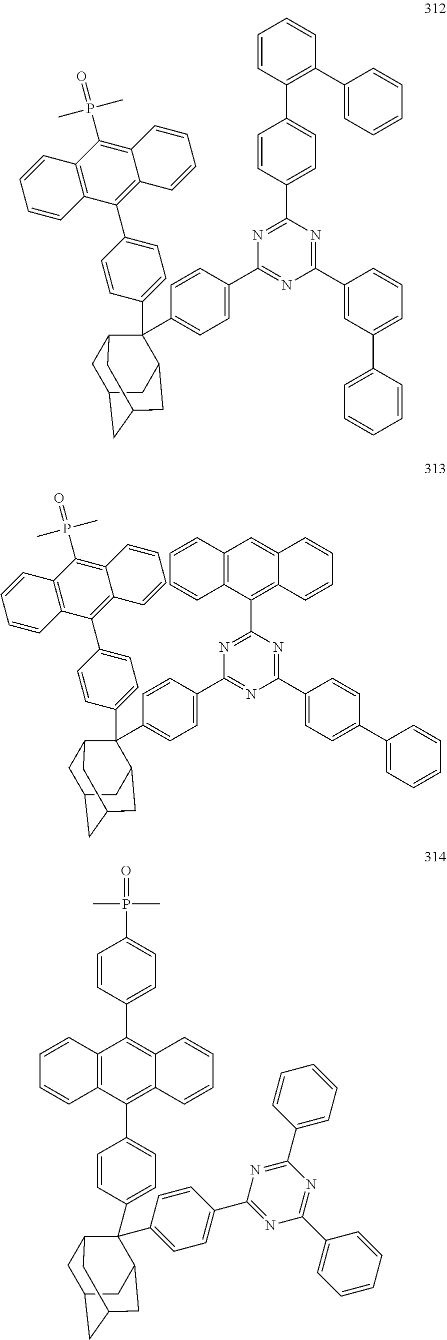 [SMILES: CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)C4CC5CC(C4)CC3C5)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)c2ccccc12 ; CP(C)(=O)c1ccc(-c2c3ccccc3c(-c3ccc(C4(c5ccc(-c6nc(-c7ccccc7)nc(-c7ccccc7)n6)cc5)C5CC6CC(C5)CC4C6)cc3)c3ccccc23)cc1]

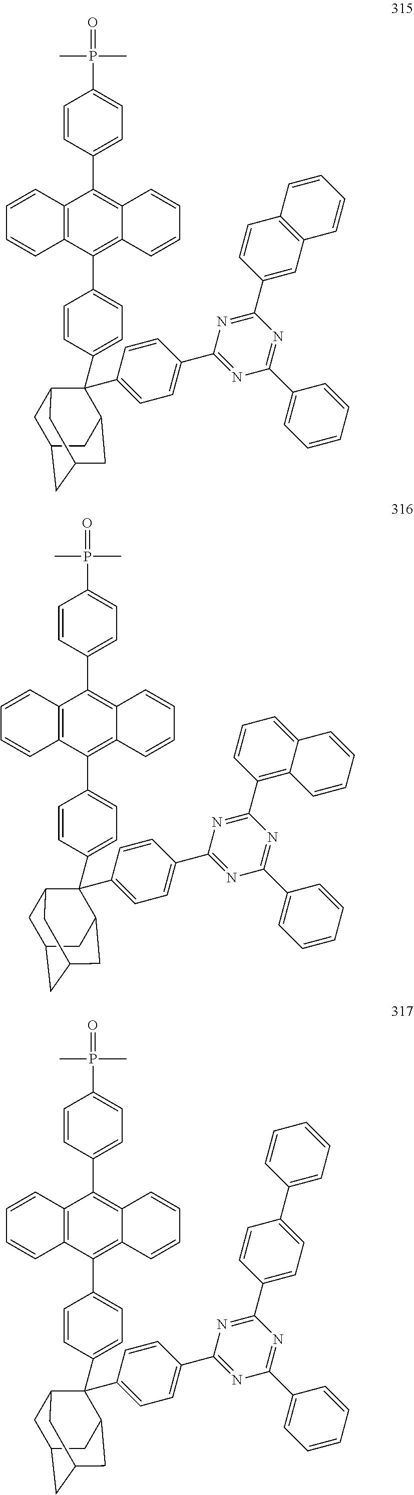

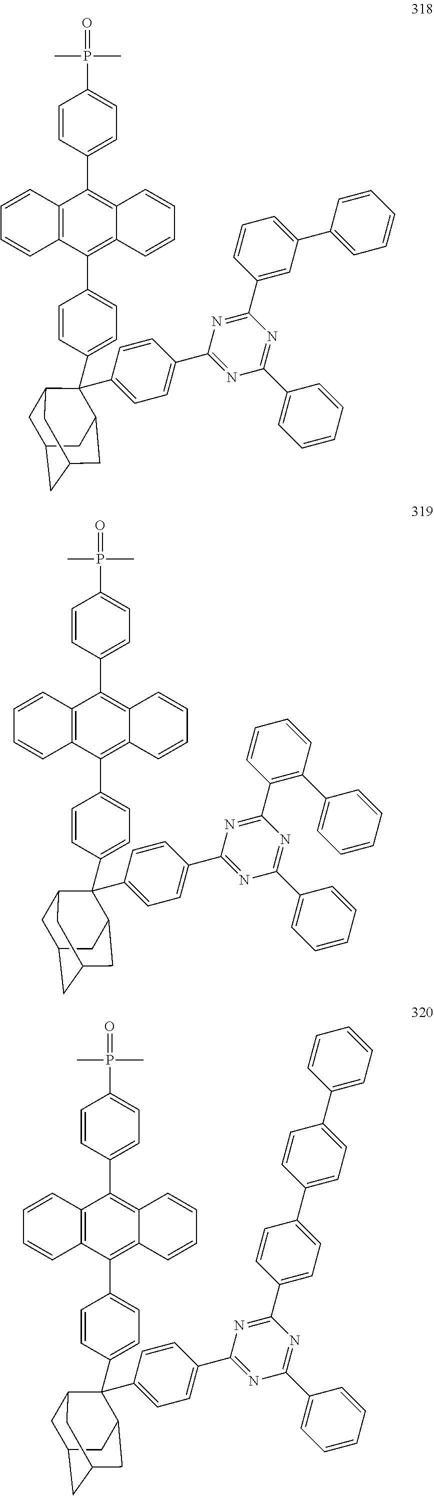 [SMILES: CP(C)(=O)c1ccc(-c2c3ccccc3c(-c3ccc(C4(c5ccc(-c6nc(-c7ccccc7)nc(-c7cccc(-c8ccccc8)c7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)C5CC6CC(C5)CC4C6)cc3)c3ccccc23)cc1]

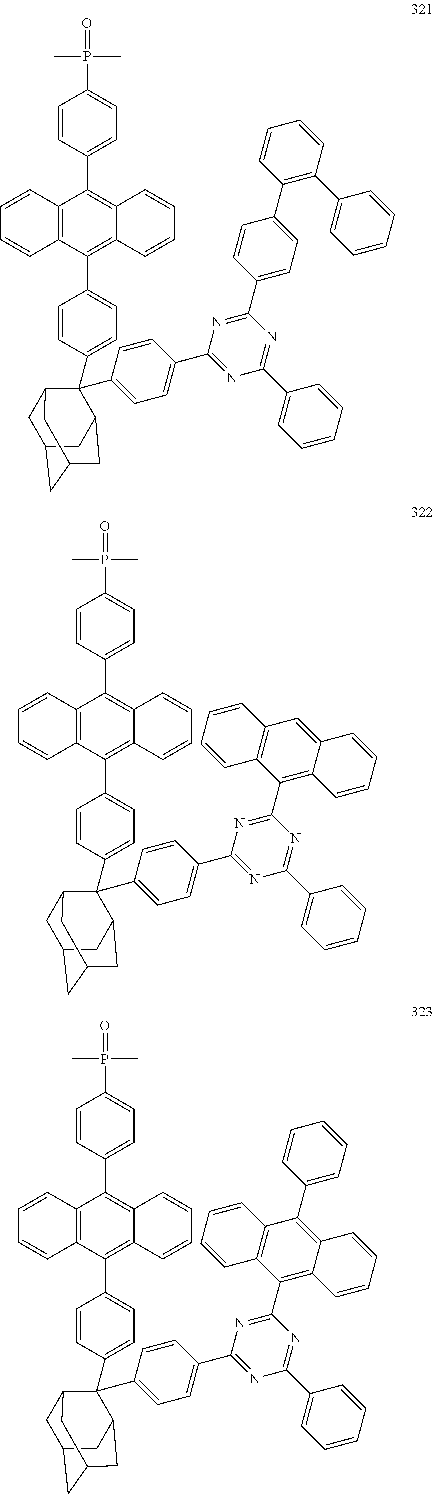 [SMILES: CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)C5CC6CC(C5)CC4C6)cc3)c3ccccc23)cc1]

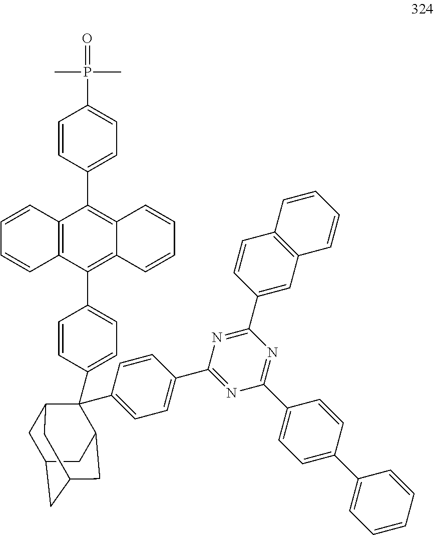 [SMILES: CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)C5CC6CC(C5)CC4C6)cc3)c3ccccc23)cc1]

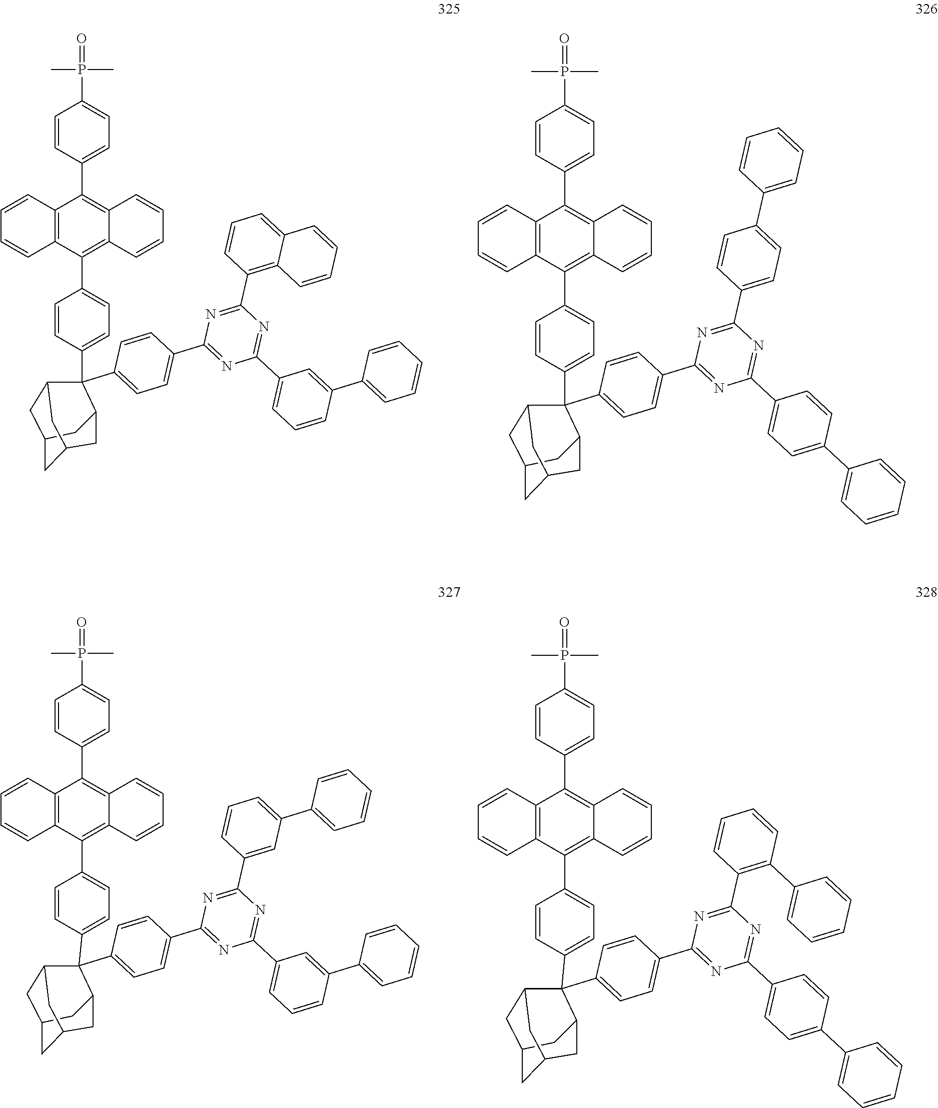

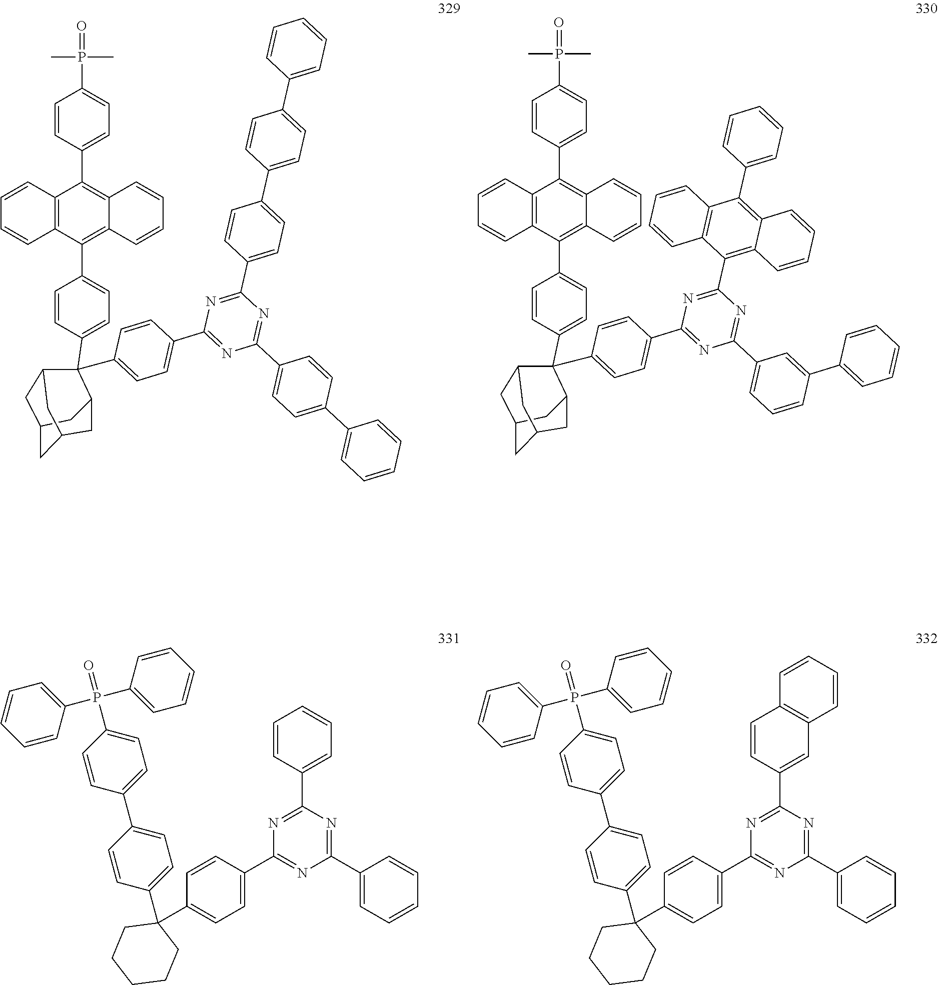 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)C5CC6CC(C5)CC4C6)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)C5CC6CC(C5)CC4C6)cc3)c3ccccc23)cc1 ; O=P(c1ccccc1)(c1ccccc1)c1ccc(-c2ccc(C3(c4ccc(-c5nc(-c6ccccc6)nc(-c6ccccc6)n5)cc4)CCCCC3)cc2)cc1 ; O=P(c1ccccc1)(c1ccccc1)c1ccc(-c2ccc(C3(c4ccc(-c5nc(-c6ccccc6)nc(-c6ccc7ccccc7c6)n5)cc4)CCCCC3)cc2)cc1]

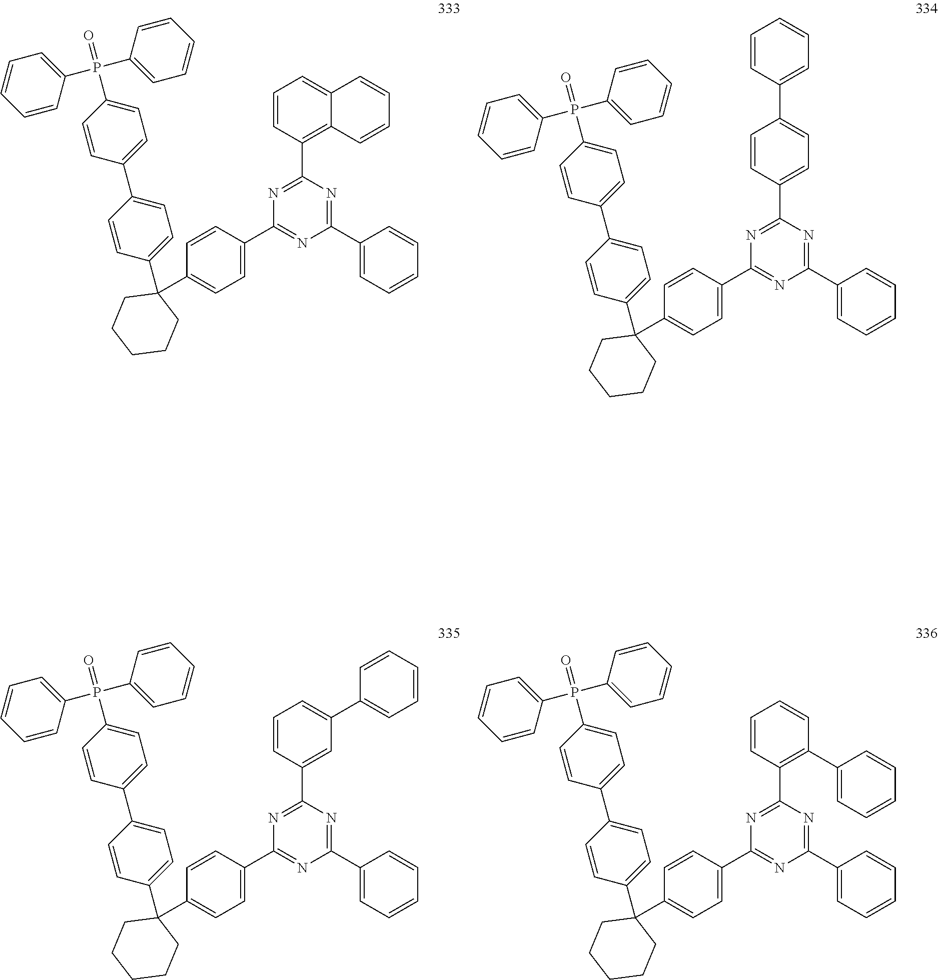 [SMILES: O=P(c1ccccc1)(c1ccccc1)c1ccc(-c2ccc(C3(c4ccc(-c5nc(-c6ccccc6)nc(-c6cccc7ccccc67)n5)cc4)CCCCC3)cc2)cc1 ; O=P(c1ccccc1)(c1ccccc1)c1ccc(-c2ccc(C3(c4ccc(-c5nc(-c6ccccc6)nc(-c6ccc(-c7ccccc7)cc6)n5)cc4)CCCCC3)cc2)cc1 ; O=P(c1ccccc1)(c1ccccc1)c1ccc(-c2ccc(C3(c4ccc(-c5nc(-c6ccccc6)nc(-c6cccc(-c7ccccc7)c6)n5)cc4)CCCCC3)cc2)cc1 ; O=P(c1ccccc1)(c1ccccc1)c1ccc(-c2ccc(C3(c4ccc(-c5nc(-c6ccccc6)nc(-c6ccccc6-c6ccccc6)n5)cc4)CCCCC3)cc2)cc1]

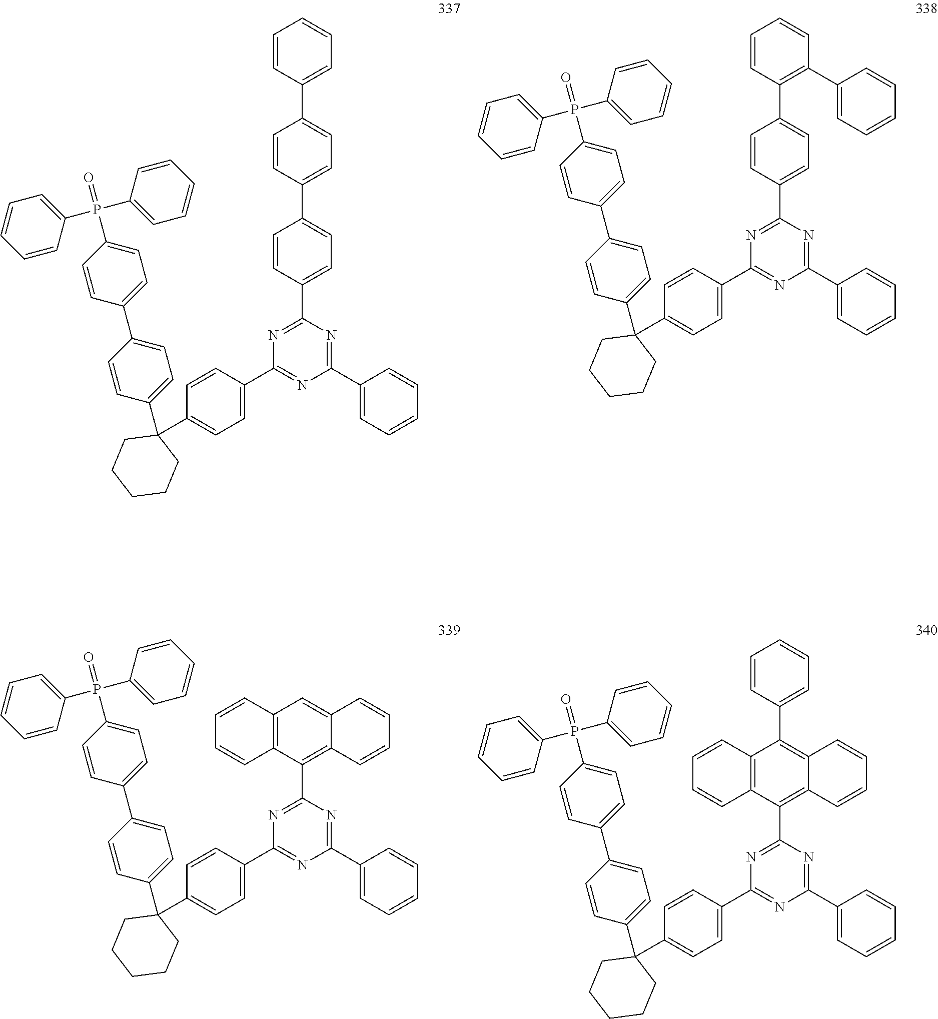 [SMILES: O=P(c1ccccc1)(c1ccccc1)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)cc1 ; O=P(c1ccccc1)(c1ccccc1)c1ccc(-c2ccc(C3(c4ccc(-c5nc(-c6ccccc6)nc(-c6ccc(-c7ccccc7-c7ccccc7)cc6)n5)cc4)CCCCC3)cc2)cc1 ; O=P(c1ccccc1)(c1ccccc1)c1ccc(-c2ccc(C3(c4ccc(-c5nc(-c6ccccc6)nc(-c6c7ccccc7cc7ccccc67)n5)cc4)CCCCC3)cc2)cc1 ; O=P(c1ccccc1)(c1ccccc1)c1ccc(-c2ccc(C3(c4ccc(-c5nc(-c6ccccc6)nc(-c6c7ccccc7c(-c7ccccc7)c7ccccc67)n5)cc4)CCCCC3)cc2)cc1]

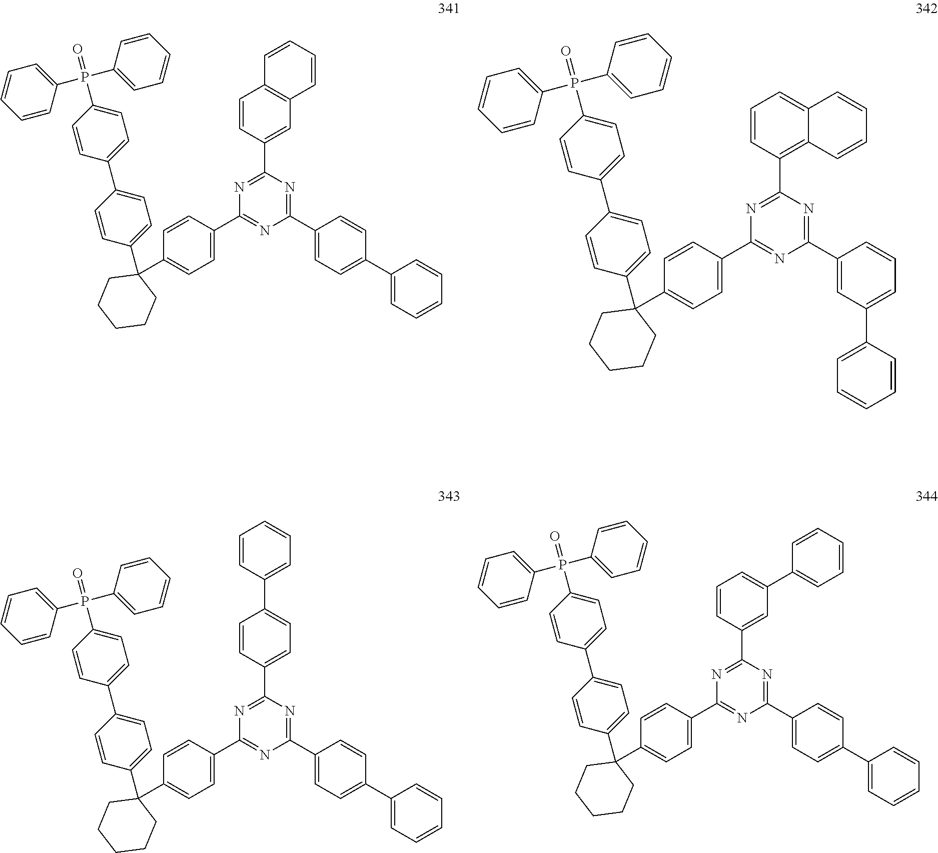 [SMILES: O=P(c1ccccc1)(c1ccccc1)c1ccc(-c2ccc(C3(c4ccc(-c5nc(-c6ccc(-c7ccccc7)cc6)nc(-c6ccc7ccccc7c6)n5)cc4)CCCCC3)cc2)cc1 ; O=P(c1ccccc1)(c1ccccc1)c1ccc(-c2ccc(C3(c4ccc(-c5nc(-c6cccc(-c7ccccc7)c6)nc(-c6cccc7ccccc67)n5)cc4)CCCCC3)cc2)cc1 ; O=P(c1ccccc1)(c1ccccc1)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)cc1 ; O=P(c1ccccc1)(c1ccccc1)c1ccc(-c2ccc(C3(c4ccc(-c5nc(-c6ccc(-c7ccccc7)cc6)nc(-c6cccc(-c7ccccc7)c6)n5)cc4)CCCCC3)cc2)cc1]

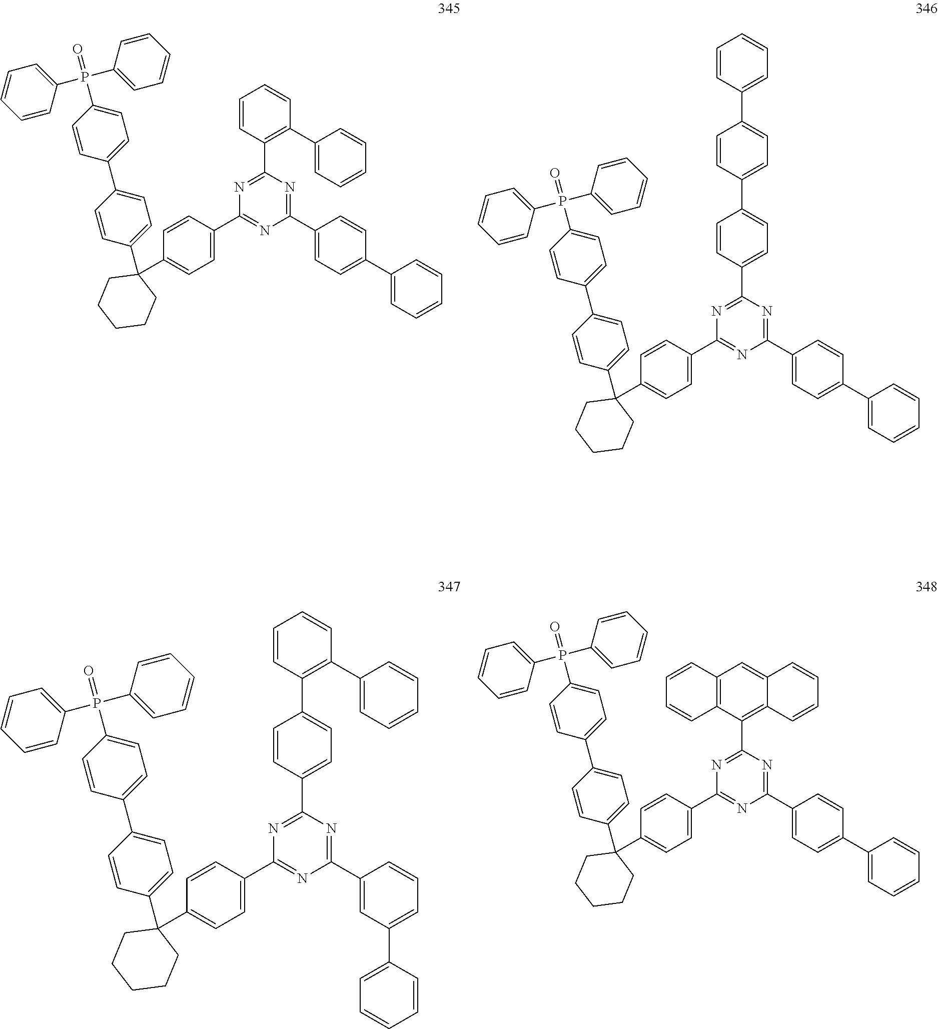 [SMILES: O=P(c1ccccc1)(c1ccccc1)c1ccc(-c2ccc(C3(c4ccc(-c5nc(-c6ccc(-c7ccccc7)cc6)nc(-c6ccccc6-c6ccccc6)n5)cc4)CCCCC3)cc2)cc1 ; O=P(c1ccccc1)(c1ccccc1)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)cc1 ; O=P(c1ccccc1)(c1ccccc1)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)cc1 ; O=P(c1ccccc1)(c1ccccc1)c1ccc(-c2ccc(C3(c4ccc(-c5nc(-c6ccc(-c7ccccc7)cc6)nc(-c6c7ccccc7cc7ccccc67)n5)cc4)CCCCC3)cc2)cc1]

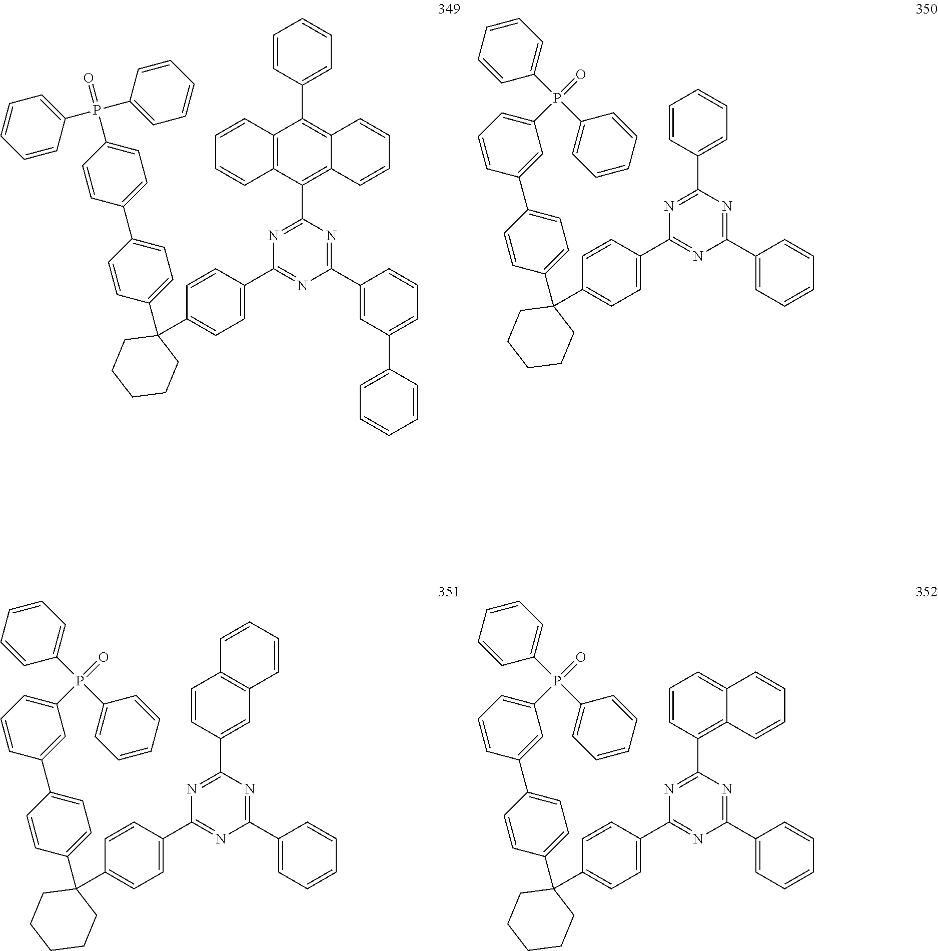 [SMILES: O=P(c1ccccc1)(c1ccccc1)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)cc1 ; O=P(c1ccccc1)(c1ccccc1)c1cccc(-c2ccc(C3(c4ccc(-c5nc(-c6ccccc6)nc(-c6ccccc6)n5)cc4)CCCCC3)cc2)c1 ; O=P(c1ccccc1)(c1ccccc1)c1cccc(-c2ccc(C3(c4ccc(-c5nc(-c6ccccc6)nc(-c6ccc7ccccc7c6)n5)cc4)CCCCC3)cc2)c1 ; O=P(c1ccccc1)(c1ccccc1)c1cccc(-c2ccc(C3(c4ccc(-c5nc(-c6ccccc6)nc(-c6cccc7ccccc67)n5)cc4)CCCCC3)cc2)c1]

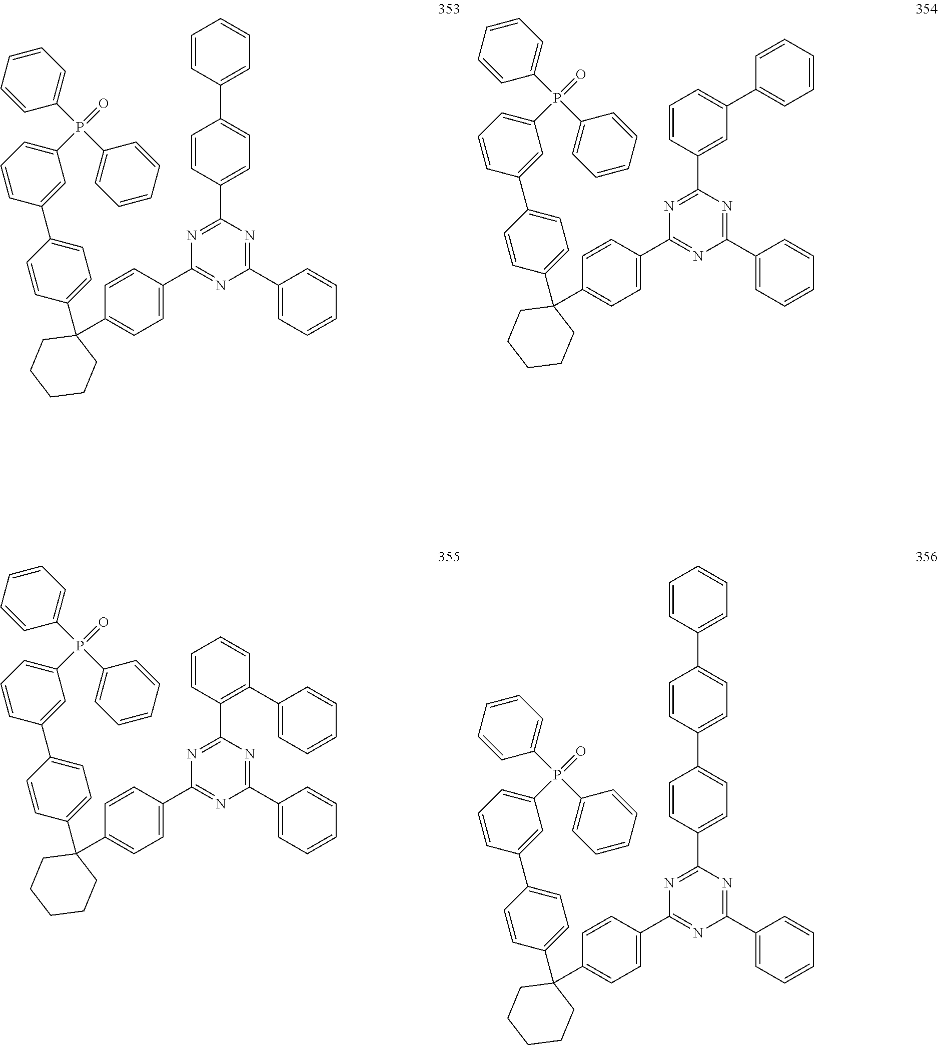 [SMILES: O=P(c1ccccc1)(c1ccccc1)c1cccc(-c2ccc(C3(c4ccc(-c5nc(-c6ccccc6)nc(-c6ccc(-c7ccccc7)cc6)n5)cc4)CCCCC3)cc2)c1 ; O=P(c1ccccc1)(c1ccccc1)c1cccc(-c2ccc(C3(c4ccc(-c5nc(-c6ccccc6)nc(-c6cccc(-c7ccccc7)c6)n5)cc4)CCCCC3)cc2)c1 ; O=P(c1ccccc1)(c1ccccc1)c1cccc(-c2ccc(C3(c4ccc(-c5nc(-c6ccccc6)nc(-c6ccccc6-c6ccccc6)n5)cc4)CCCCC3)cc2)c1 ; O=P(c1ccccc1)(c1ccccc1)c1cccc(-c2ccc(C3(c4ccc(-c5nc(-c6ccccc6)nc(-c6ccc(-c7ccc(-c8ccccc8)cc7)cc6)n5)cc4)CCCCC3)cc2)c1]

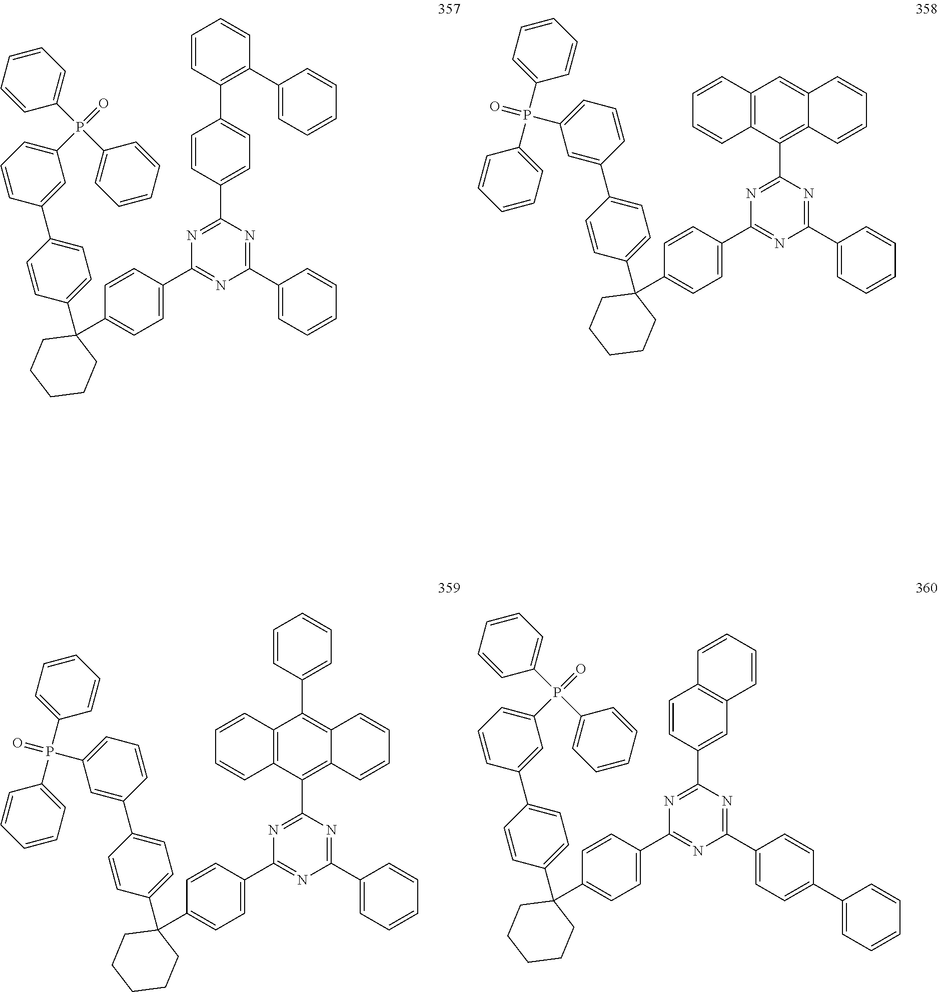 [SMILES: O=P(c1ccccc1)(c1ccccc1)c1cccc(-c2ccc(C3(c4ccc(-c5nc(-c6ccccc6)nc(-c6ccc(-c7ccccc7-c7ccccc7)cc6)n5)cc4)CCCCC3)cc2)c1 ; O=P(c1ccccc1)(c1ccccc1)c1cccc(-c2ccc(C3(c4ccc(-c5nc(-c6ccccc6)nc(-c6c7ccccc7cc7ccccc67)n5)cc4)CCCCC3)cc2)c1 ; O=P(c1ccccc1)(c1ccccc1)c1cccc(-c2ccc(C3(c4ccc(-c5nc(-c6ccccc6)nc(-c6c7ccccc7c(-c7ccccc7)c7ccccc67)n5)cc4)CCCCC3)cc2)c1 ; O=P(c1ccccc1)(c1ccccc1)c1cccc(-c2ccc(C3(c4ccc(-c5nc(-c6ccc(-c7ccccc7)cc6)nc(-c6ccc7ccccc7c6)n5)cc4)CCCCC3)cc2)c1]

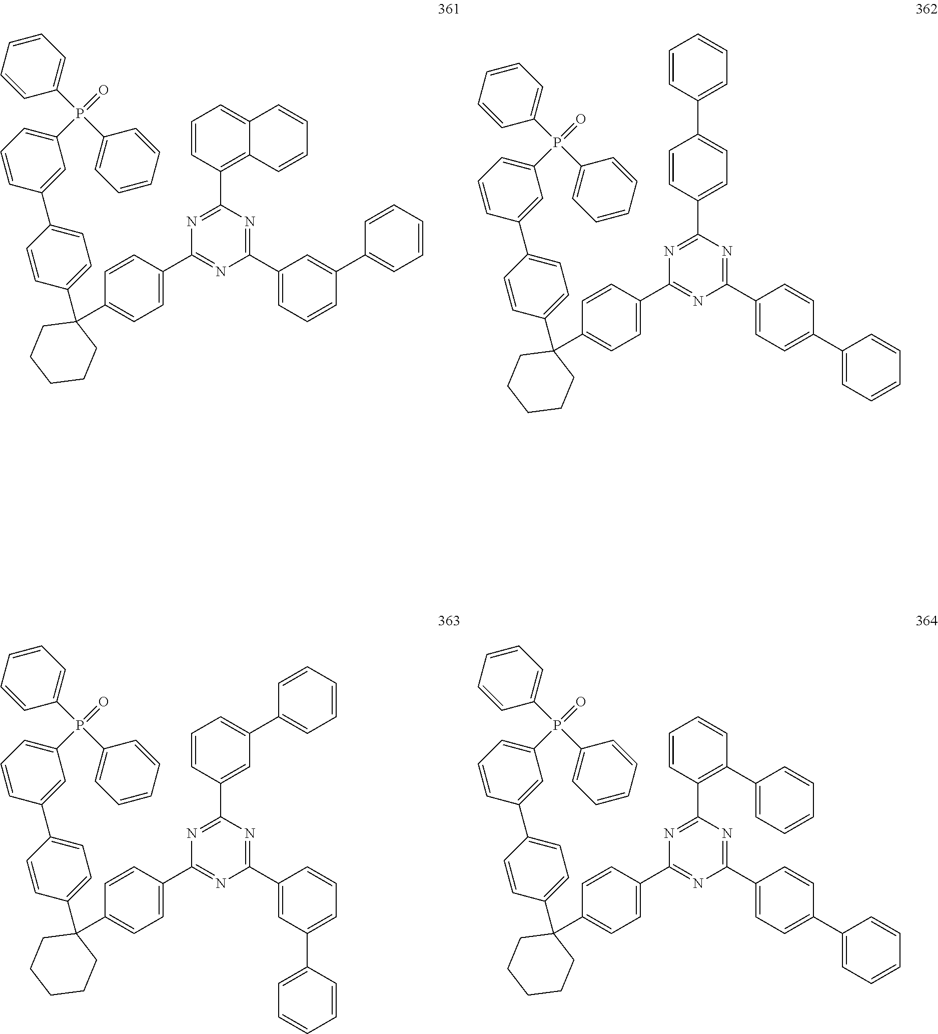 [SMILES: O=P(c1ccccc1)(c1ccccc1)c1cccc(-c2ccc(C3(c4ccc(-c5nc(-c6cccc(-c7ccccc7)c6)nc(-c6cccc7ccccc67)n5)cc4)CCCCC3)cc2)c1 ; O=P(c1ccccc1)(c1ccccc1)c1cccc(-c2ccc(C3(c4ccc(-c5nc(-c6ccc(-c7ccccc7)cc6)nc(-c6ccc(-c7ccccc7)cc6)n5)cc4)CCCCC3)cc2)c1 ; O=P(c1ccccc1)(c1ccccc1)c1cccc(-c2ccc(C3(c4ccc(-c5nc(-c6cccc(-c7ccccc7)c6)nc(-c6cccc(-c7ccccc7)c6)n5)cc4)CCCCC3)cc2)c1 ; O=P(c1ccccc1)(c1ccccc1)c1cccc(-c2ccc(C3(c4ccc(-c5nc(-c6ccc(-c7ccccc7)cc6)nc(-c6ccccc6-c6ccccc6)n5)cc4)CCCCC3)cc2)c1]

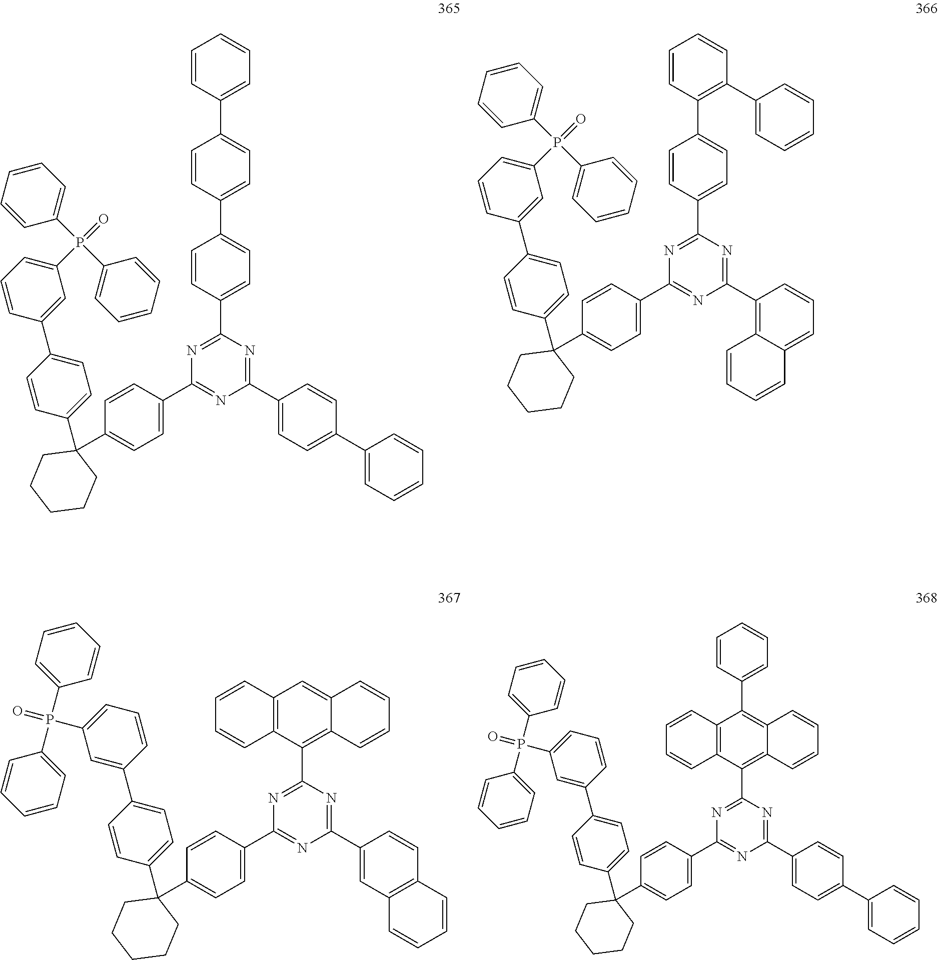 [SMILES: O=P(c1ccccc1)(c1ccccc1)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c1 ; O=P(c1ccccc1)(c1ccccc1)c1cccc(-c2ccc(C3(c4ccc(-c5nc(-c6ccc(-c7ccccc7-c7ccccc7)cc6)nc(-c6cccc7ccccc67)n5)cc4)CCCCC3)cc2)c1 ; O=P(c1ccccc1)(c1ccccc1)c1cccc(-c2ccc(C3(c4ccc(-c5nc(-c6ccc7ccccc7c6)nc(-c6c7ccccc7cc7ccccc67)n5)cc4)CCCCC3)cc2)c1 ; O=P(c1ccccc1)(c1ccccc1)c1cccc(-c2ccc(C3(c4ccc(-c5nc(-c6ccc(-c7ccccc7)cc6)nc(-c6c7ccccc7c(-c7ccccc7)c7ccccc67)n5)cc4)CCCCC3)cc2)c1]

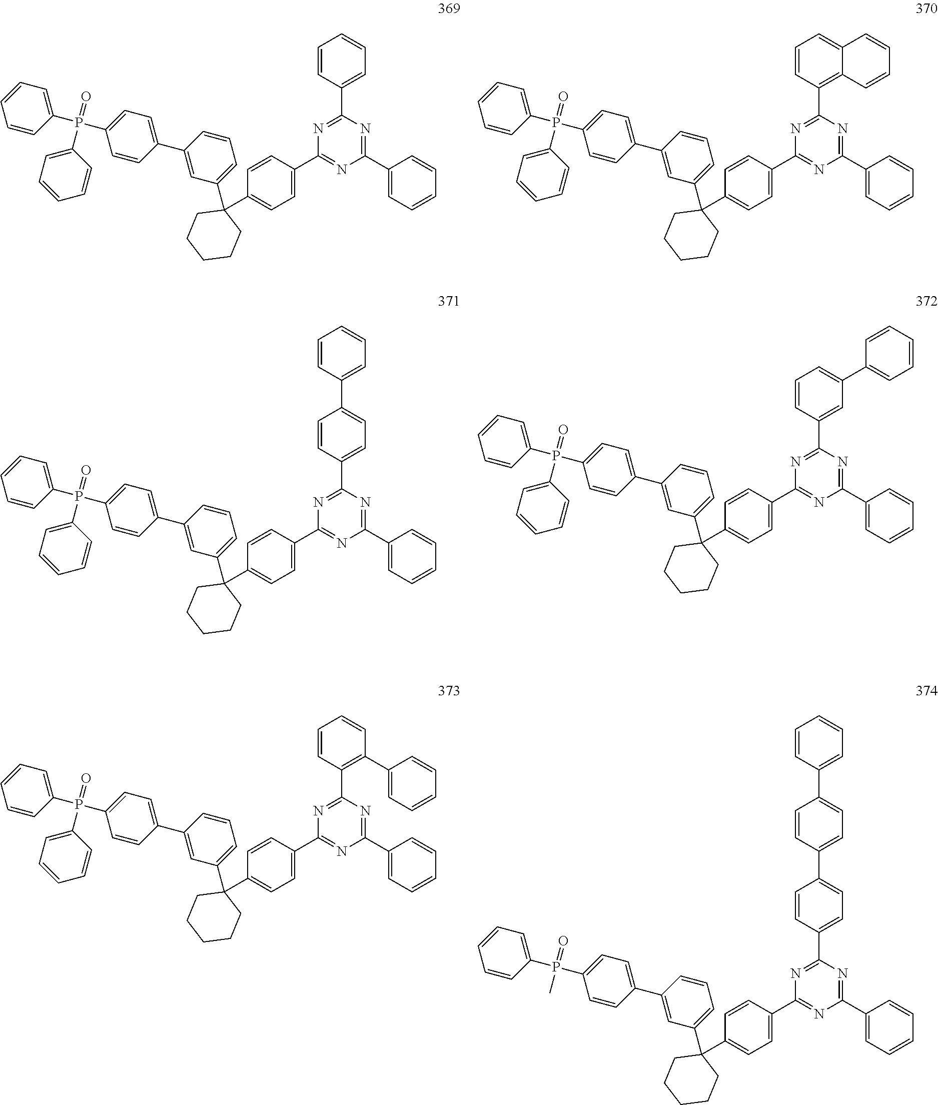

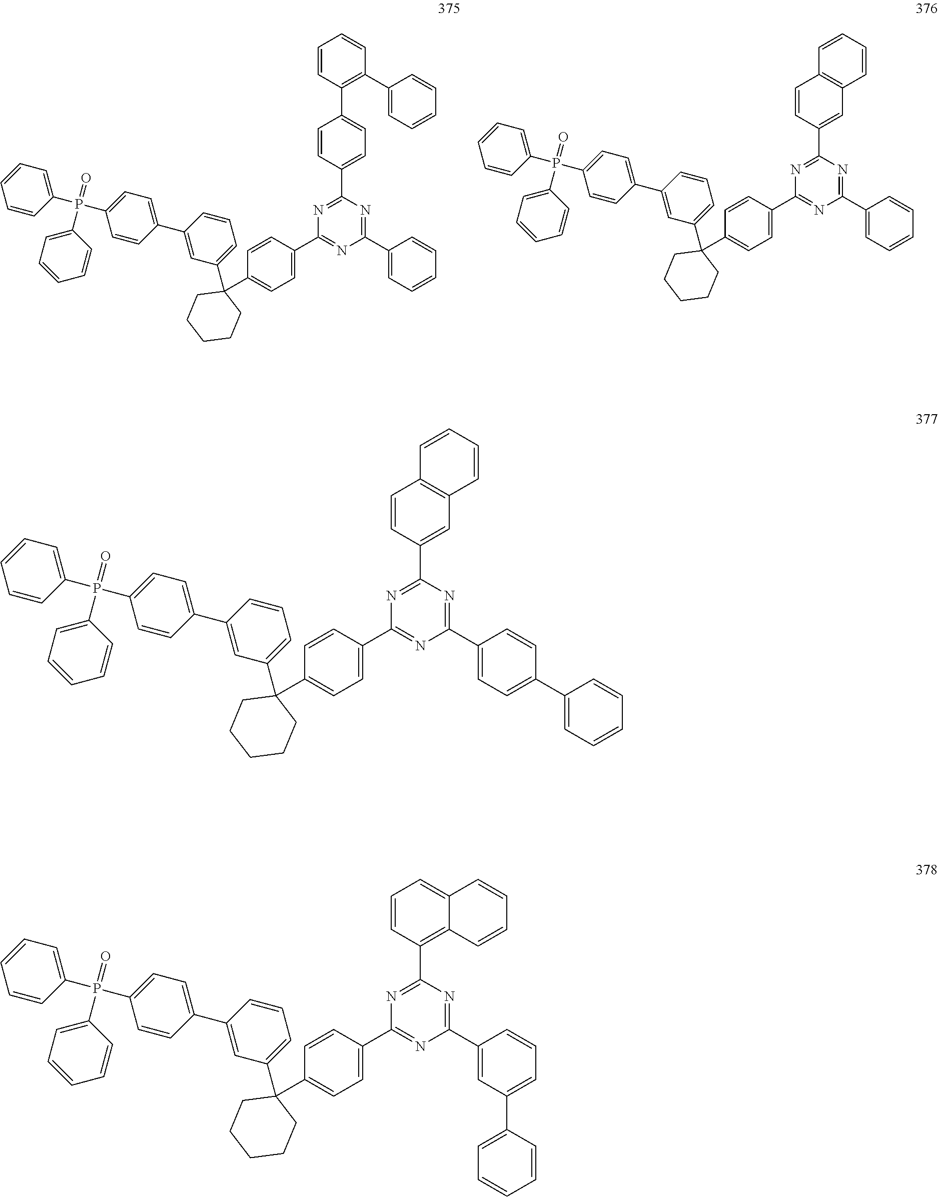 [SMILES: O=P(c1ccccc1)(c1ccccc1)c1ccc(-c2cccc(C3(c4ccc(-c5nc(-c6ccccc6)nc(-c6ccc(-c7ccccc7-c7ccccc7)cc6)n5)cc4)CCCCC3)c2)cc1 ; O=P(c1ccccc1)(c1ccccc1)c1ccc(-c2cccc(C3(c4ccc(-c5nc(-c6ccccc6)nc(-c6ccc7ccccc7c6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; O=P(c1ccccc1)(c1ccccc1)c1ccc(-c2cccc(C3(c4ccc(-c5nc(-c6cccc(-c7ccccc7)c6)nc(-c6cccc7ccccc67)n5)cc4)CCCCC3)c2)cc1]

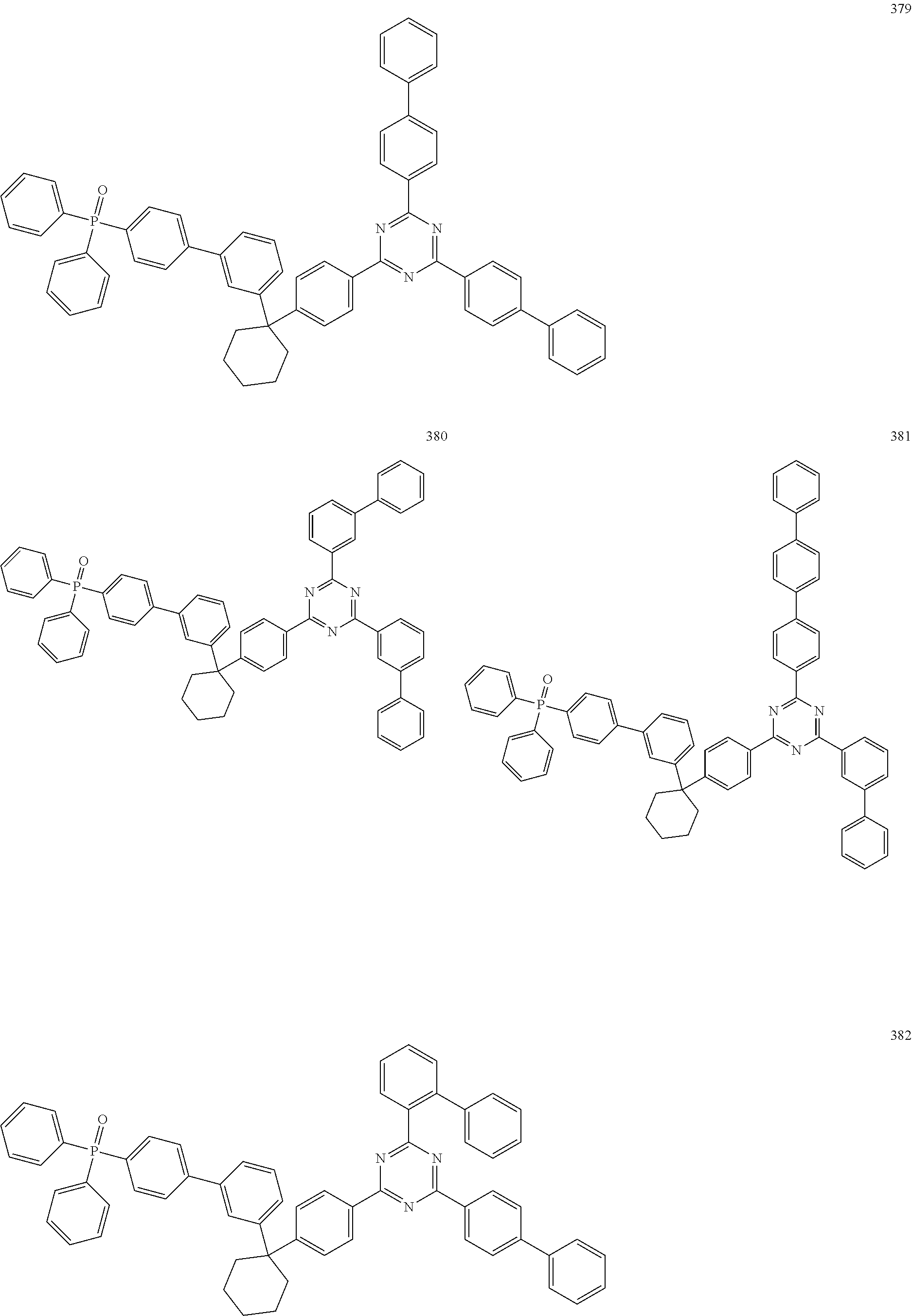 [SMILES: O=P(c1ccccc1)(c1ccccc1)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1 ; O=P(c1ccccc1)(c1ccccc1)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccccc6-c6ccccc6)n5)cc4)CCCCC3)c2)cc1]

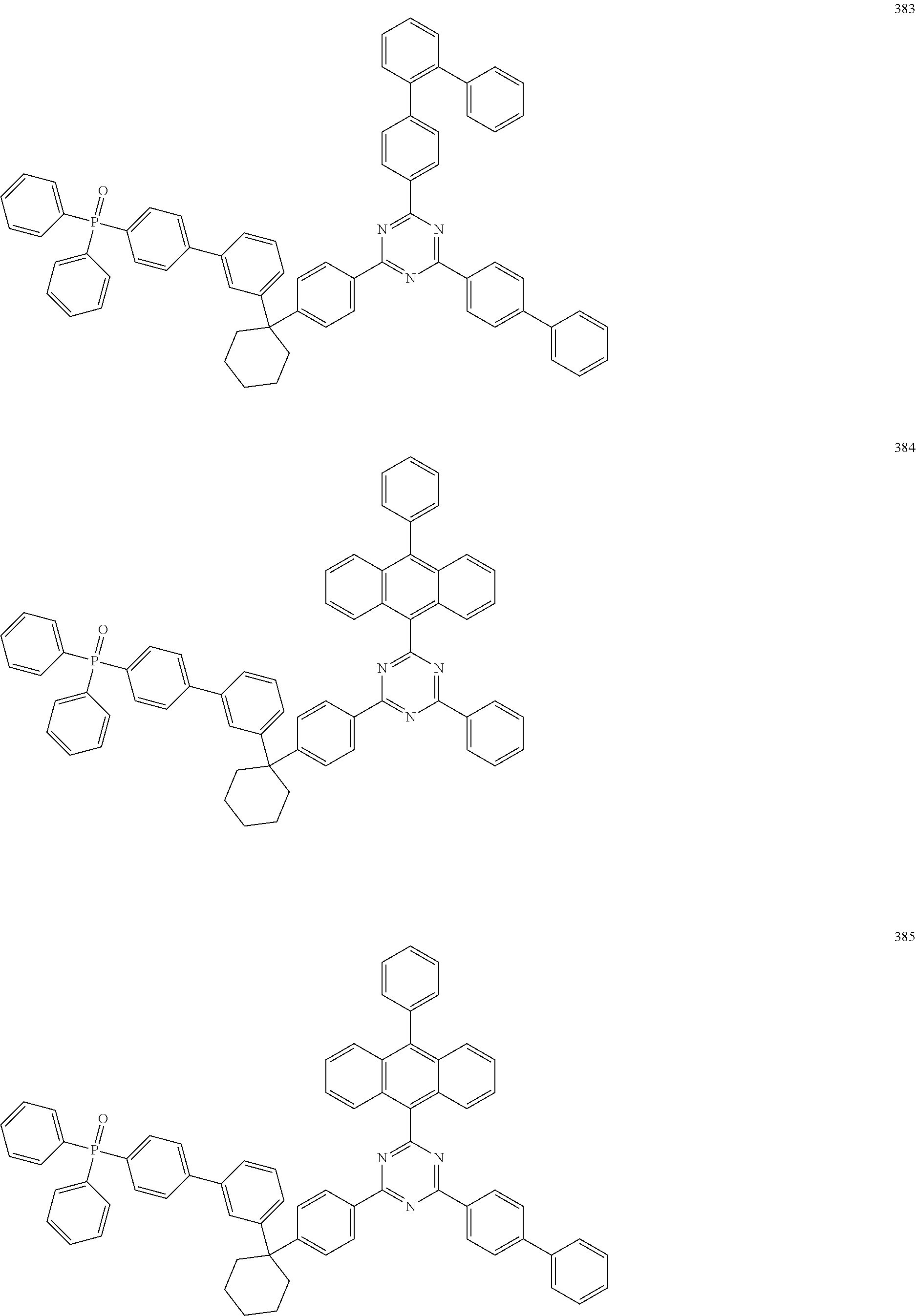 [SMILES: O=P(c1ccccc1)(c1ccccc1)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1 ; O=P(c1ccccc1)(c1ccccc1)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1]

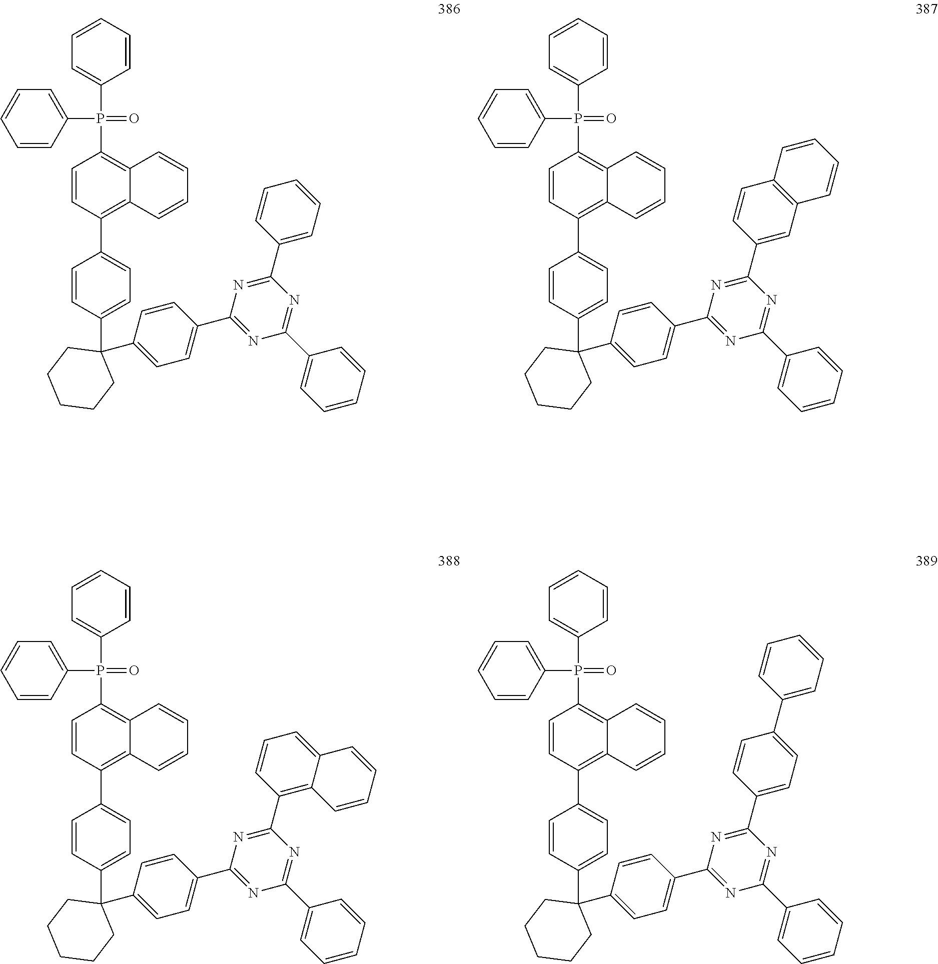 [SMILES: O=P(c1ccccc1)(c1ccccc1)c1ccc(-c2ccc(C3(c4ccc(-c5nc(-c6ccccc6)nc(-c6ccccc6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccc7ccccc7c6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6cccc7ccccc67)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccc(-c7ccccc7)cc6)n5)cc4)CCCCC3)cc2)c2ccccc12]

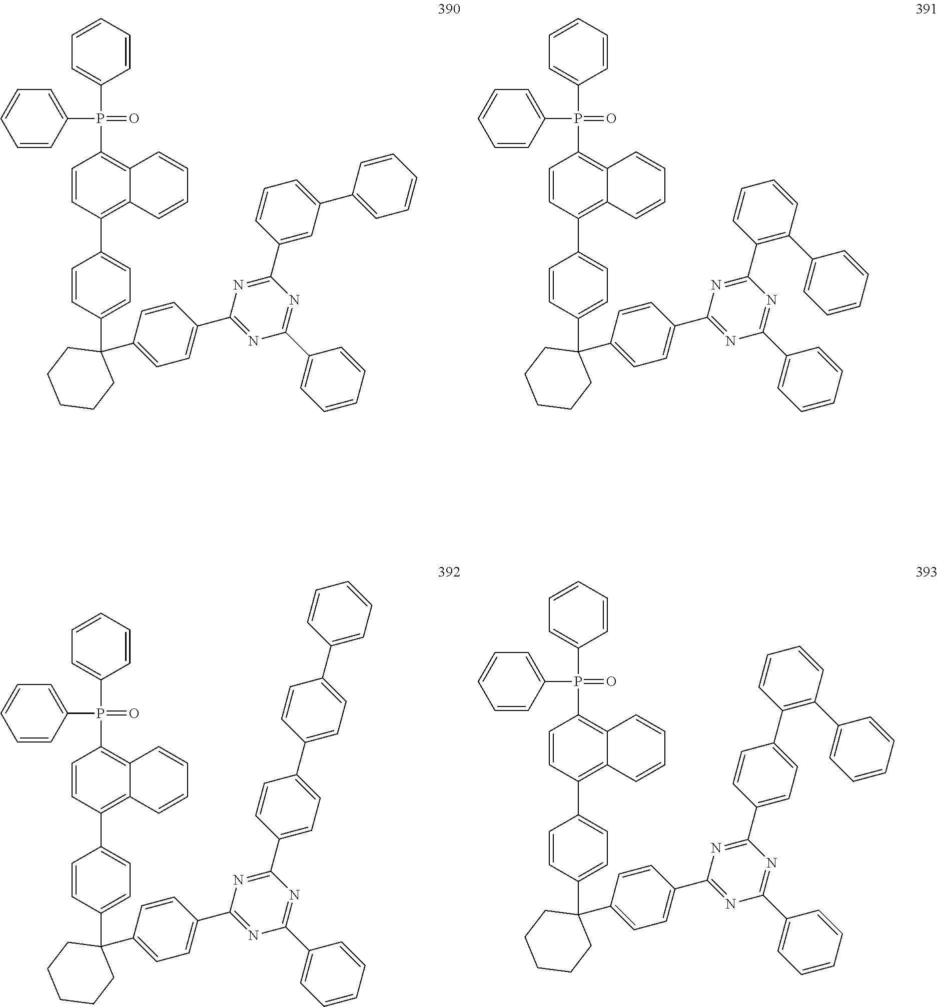 [SMILES: O=P(c1ccccc1)(c1ccccc1)c1ccc(-c2ccc(C3(c4ccc(-c5nc(-c6ccccc6)nc(-c6cccc(-c7ccccc7)c6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccccc6-c6ccccc6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccc(-c7ccccc7-c7ccccc7)cc6)n5)cc4)CCCCC3)cc2)c2ccccc12]

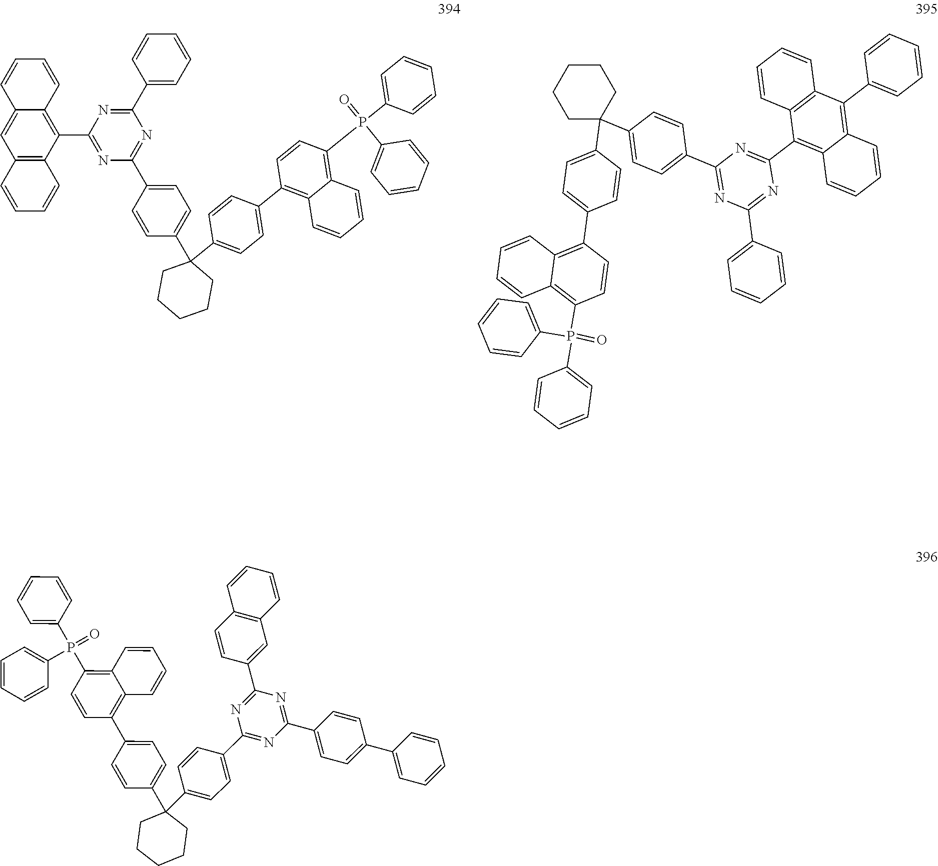 [SMILES: O=P(c1ccccc1)(c1ccccc1)c1ccc(-c2ccc(C3(c4ccc(-c5nc(-c6ccccc6)nc(-c6c7ccccc7cc7ccccc67)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc7ccccc7c6)n5)cc4)CCCCC3)cc2)c2ccccc12]

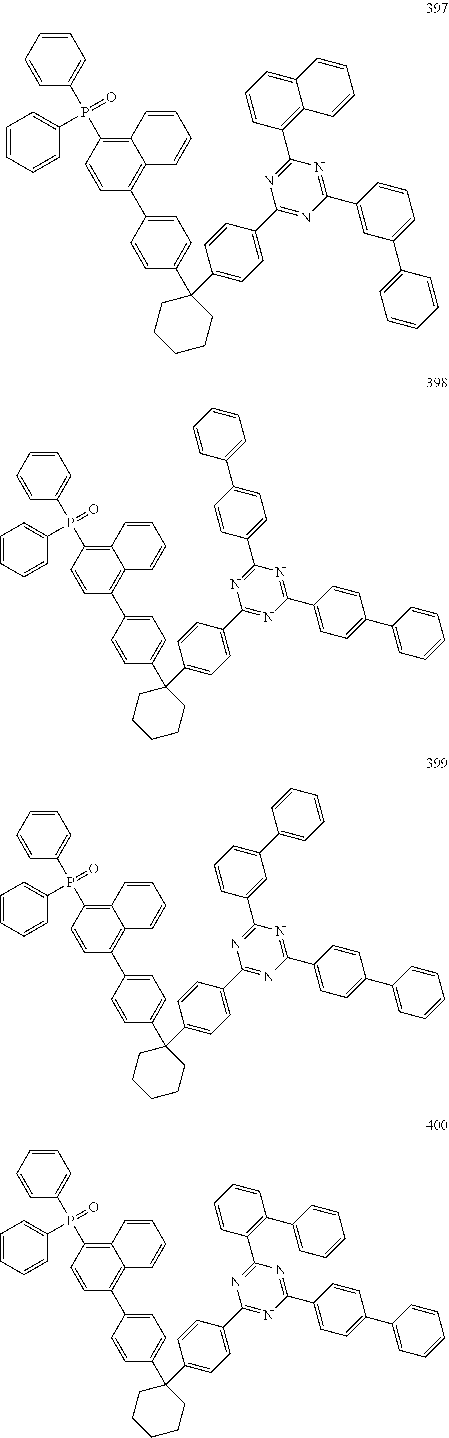 [SMILES: O=P(c1ccccc1)(c1ccccc1)c1ccc(-c2ccc(C3(c4ccc(-c5nc(-c6cccc(-c7ccccc7)c6)nc(-c6cccc7ccccc67)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

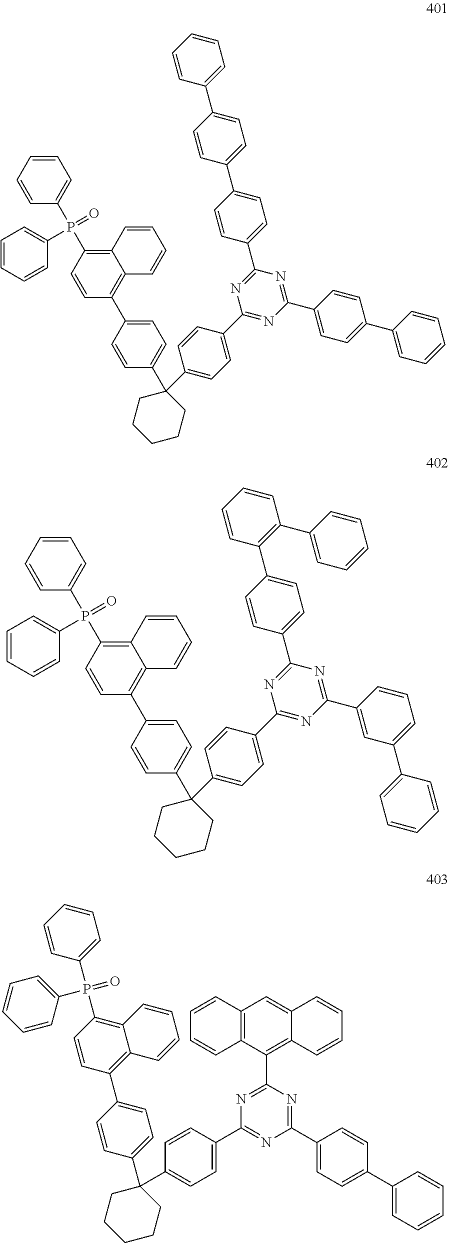 [SMILES: O=P(c1ccccc1)(c1ccccc1)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12]

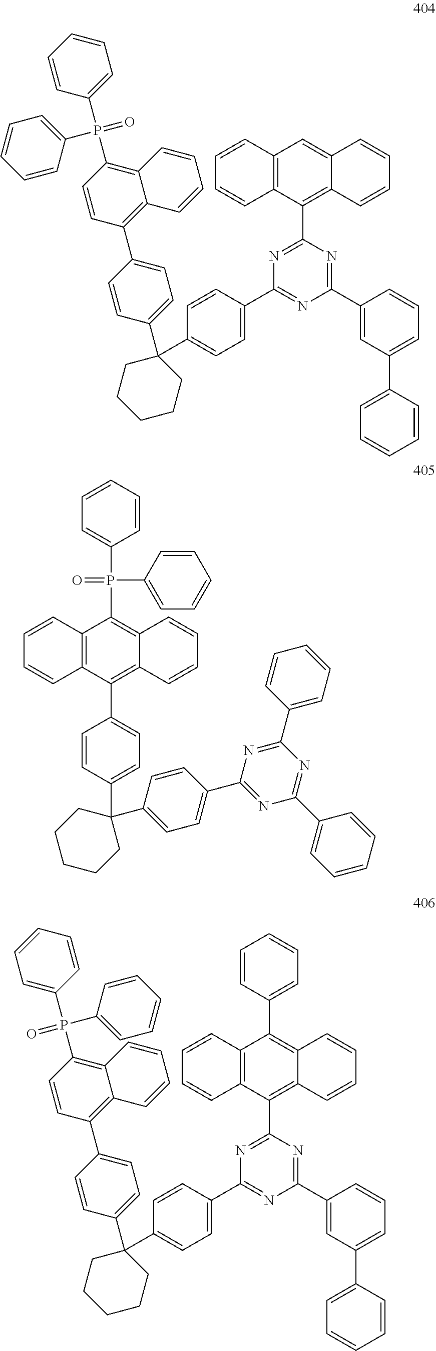 [SMILES: O=P(c1ccccc1)(c1ccccc1)c1ccc(-c2ccc(C3(c4ccc(-c5nc(-c6cccc(-c7ccccc7)c6)nc(-c6c7ccccc7cc7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6)n5)cc4)CCCCC3)cc2)c2ccccc12 ; O=P(c1ccccc1)(c1ccccc1)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12]

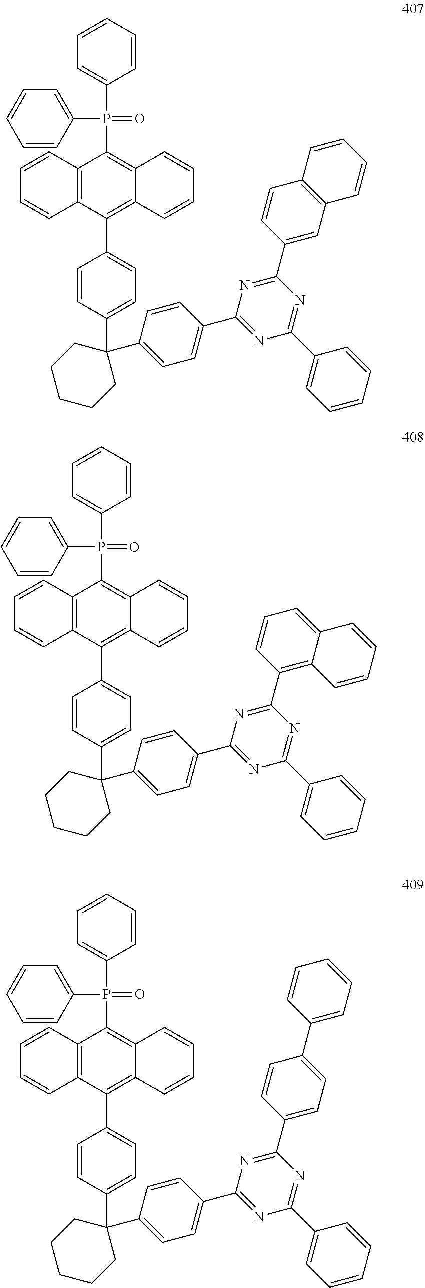

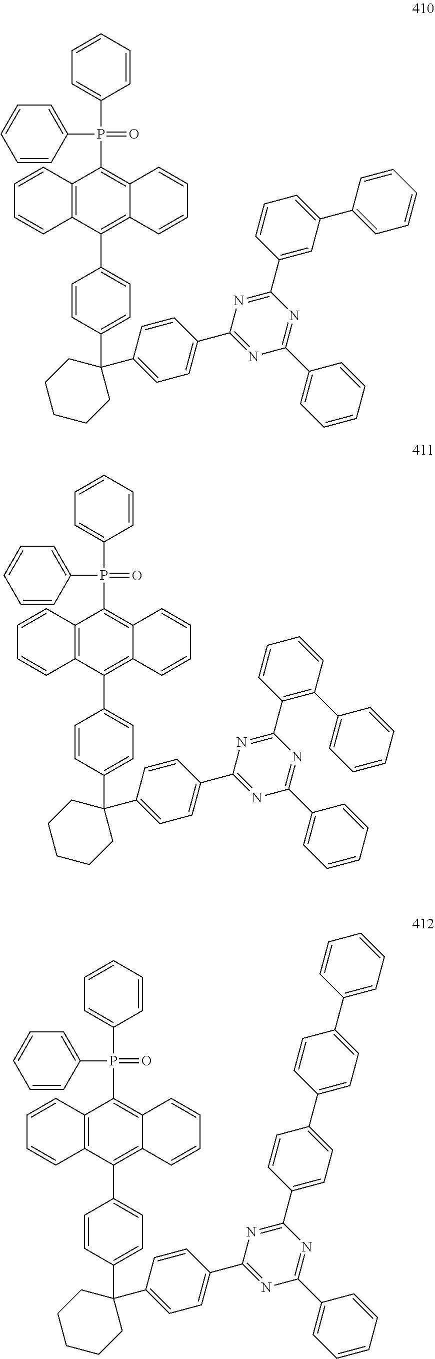 [SMILES: O=P(c1ccccc1)(c1ccccc1)c1c2ccccc2c(-c2ccc(C3(c4ccc(-c5nc(-c6ccccc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6-c6ccccc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12]

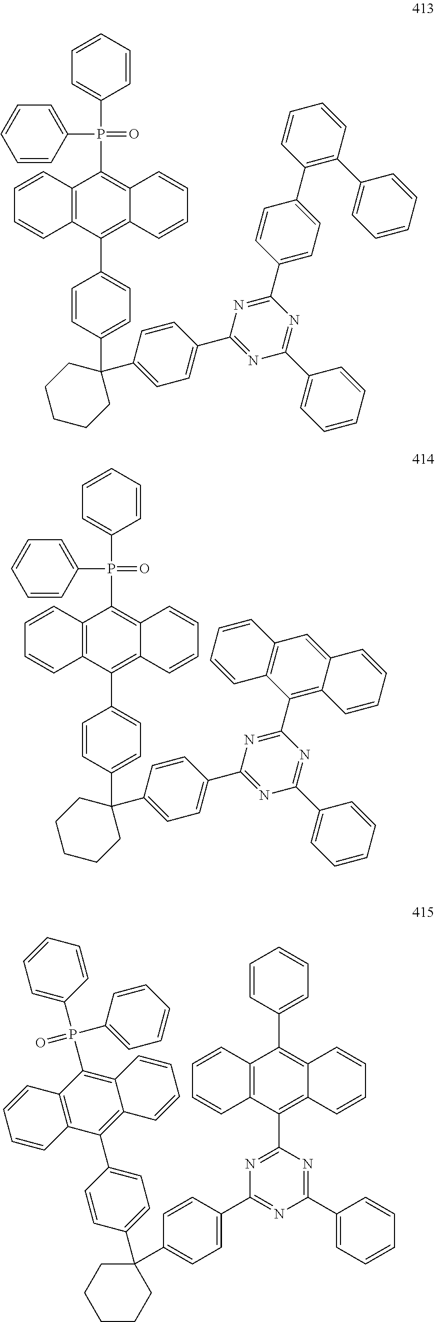 [SMILES: O=P(c1ccccc1)(c1ccccc1)c1c2ccccc2c(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6c7ccccc7cc7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12]

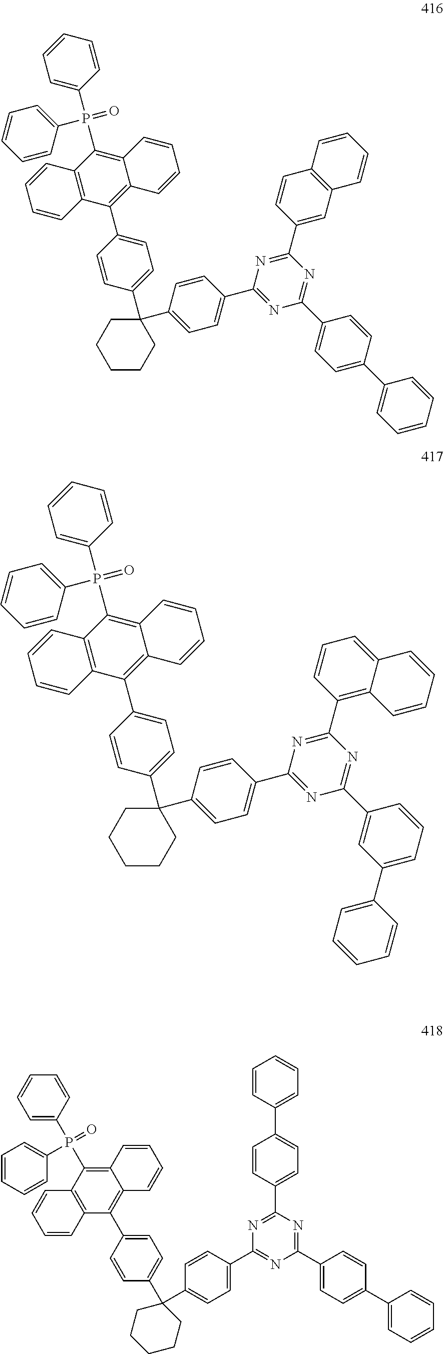 [SMILES: O=P(c1ccccc1)(c1ccccc1)c1c2ccccc2c(-c2ccc(C3(c4ccc(-c5nc(-c6ccc(-c7ccccc7)cc6)nc(-c6ccc7ccccc7c6)n5)cc4)CCCCC3)cc2)c2ccccc12 ; O=P(c1ccccc1)(c1ccccc1)c1c2ccccc2c(-c2ccc(C3(c4ccc(-c5nc(-c6cccc(-c7ccccc7)c6)nc(-c6cccc7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12]

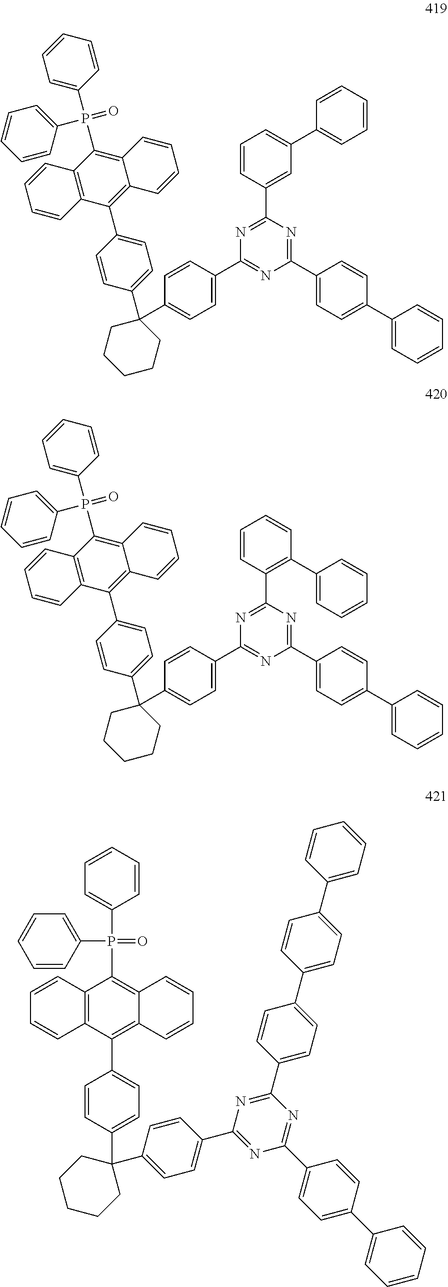 [SMILES: O=P(c1ccccc1)(c1ccccc1)c1c2ccccc2c(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccccc6-c6ccccc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12]

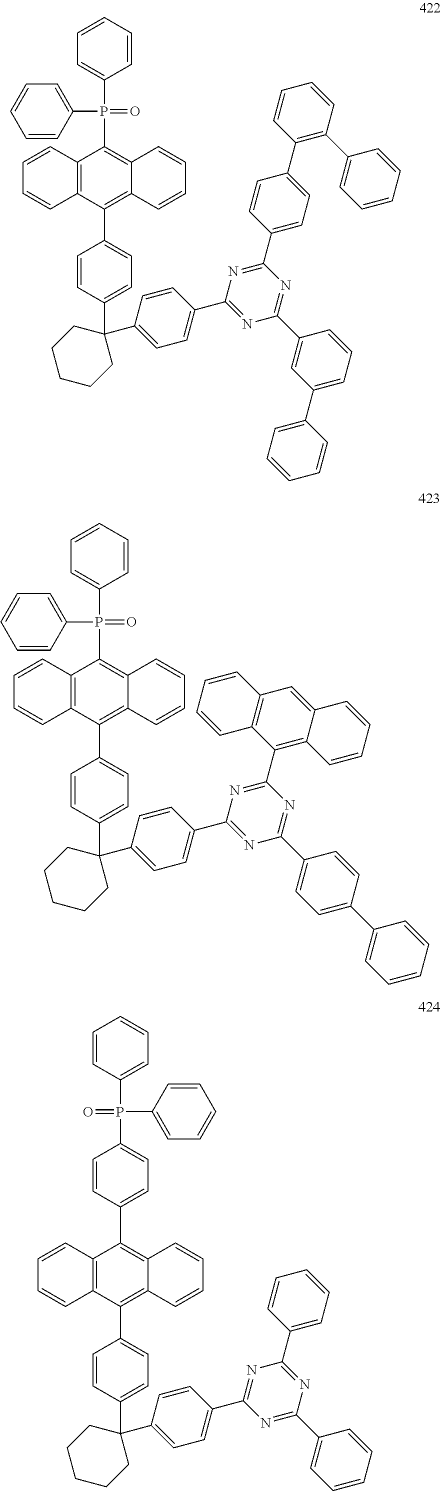 [SMILES: O=P(c1ccccc1)(c1ccccc1)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; O=P(c1ccccc1)(c1ccccc1)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1]

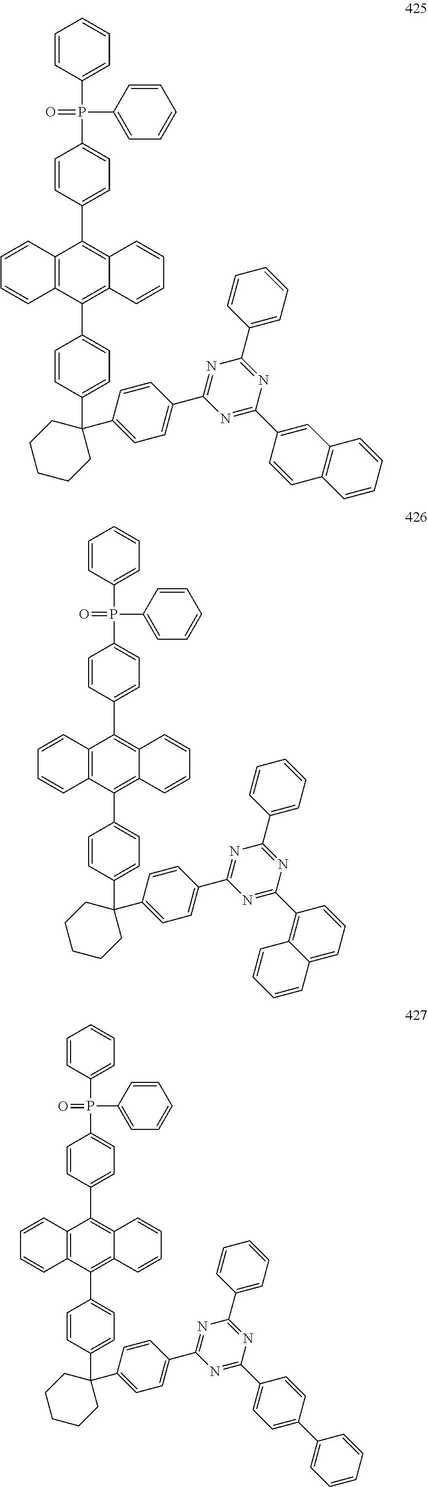 [SMILES: O=P(c1ccccc1)(c1ccccc1)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1]

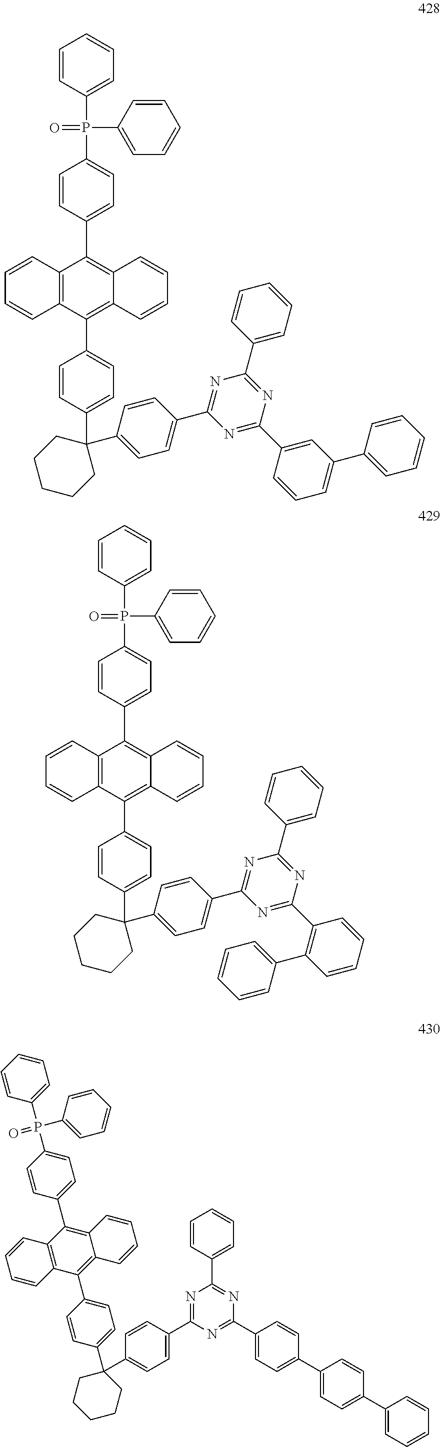 [SMILES: O=P(c1ccccc1)(c1ccccc1)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1]

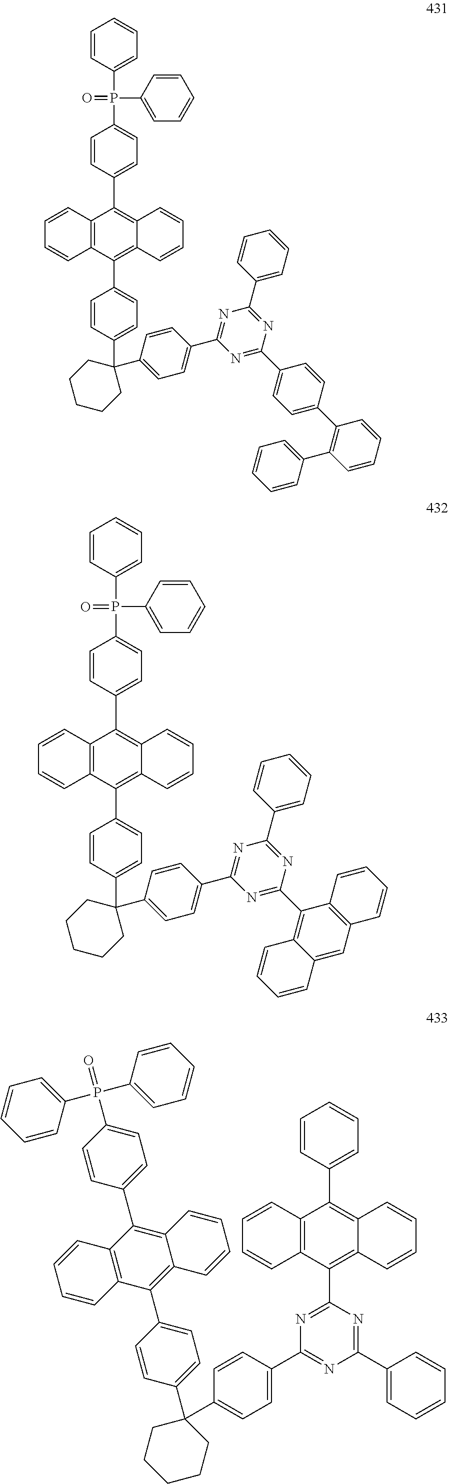 [SMILES: O=P(c1ccccc1)(c1ccccc1)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7c8ccccc8cc8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1]

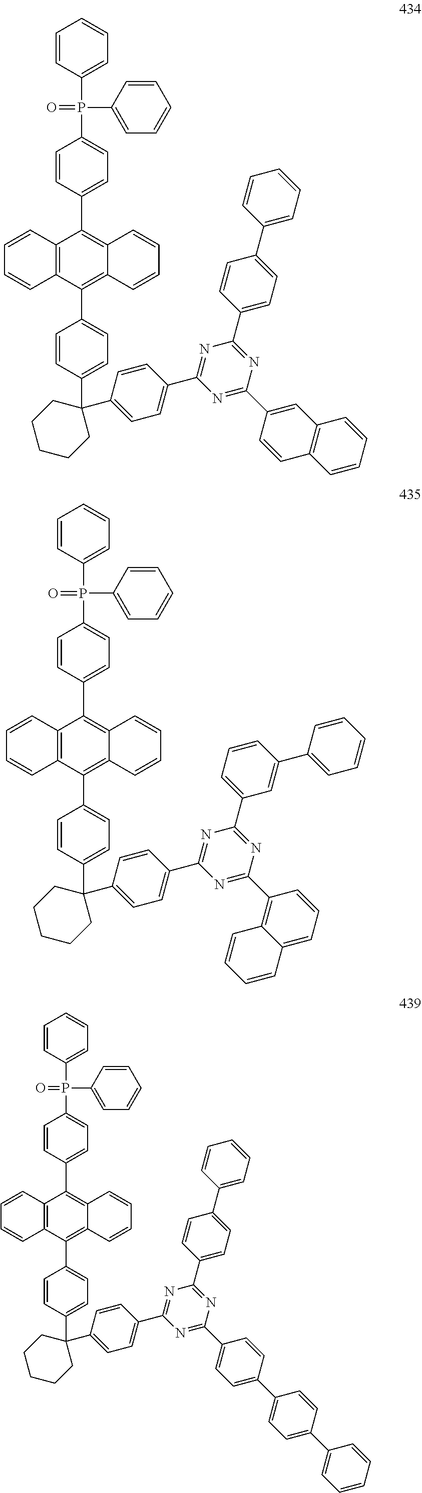 [SMILES: O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1]

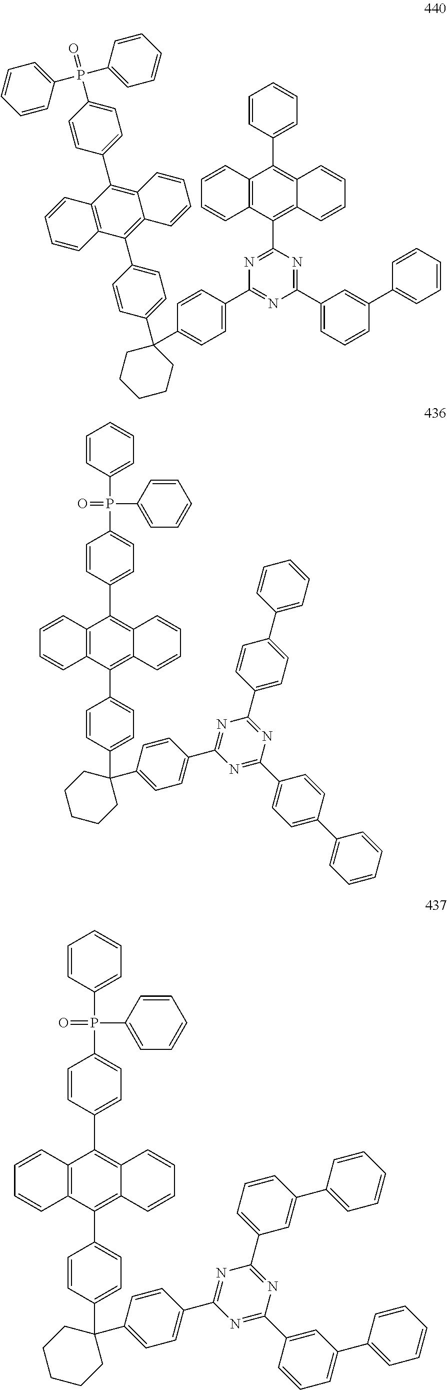

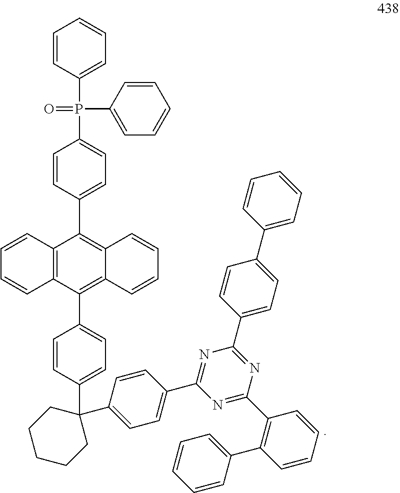 [SMILES: O=P(c1ccccc1)(c1ccccc1)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

9. The light emitting element of claim 1, wherein the at least one functional layer comprises an emission layer, a hole transport region between the first electrode and the emission layer, and an electron transport region between the emission layer and the second electrode, and
the electron transport region comprises the compound represented by Formula 1.

10. A compound represented by Formula 1: 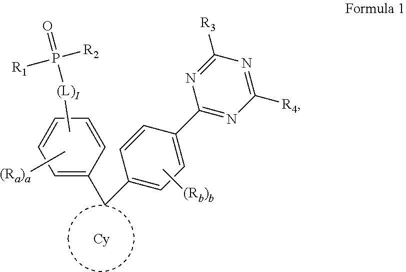
and
in Formula 1,
Cy is a substituted or unsubstituted cycloalkyl group of 3 to 30 ring-forming carbon atoms,
L is a substituted or unsubstituted arylene group of 6 to 30 ring-forming carbon atoms, or a substituted or unsubstituted heteroarylene group of 2 to 30 ring-forming carbon atoms,
R₁ to R₄ are each independently a substituted or unsubstituted alkyl group of 1 to 10 carbon atoms, or a substituted or unsubstituted aryl group of 6 to 30 ring-forming carbon atoms,
Rₐ and R_{b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“a” and “b” are each independently an integer of 0 to 4, and
“l” is 1 or 2.

11. The compound of claim 10, wherein Formula 1 is represented by at least one selected from among Formula 1-1a to Formula 1-1c: 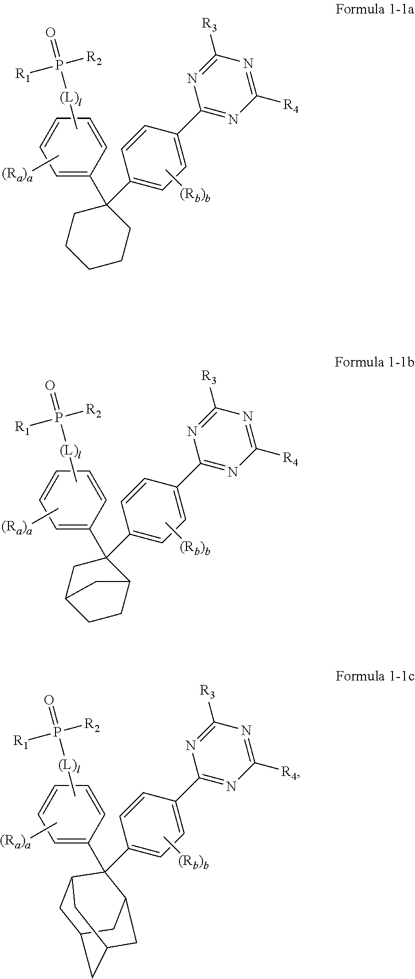
and
in Formula 1-1a to Formula 1-1c,
L, R₁ to R₄, Rₐ, R_{b}, “a”, “b”, and “l” are as defined in Formula 1.

12. The compound of claim 10, wherein R₁ and R₂ are each independently an unsubstituted methyl group or an unsubstituted phenyl group.

13. The compound of claim 10, wherein R₃ and R₄ are each independently an unsubstituted phenyl group, an unsubstituted biphenyl group, an unsubstituted terphenyl group, an unsubstituted naphthyl group, an unsubstituted anthracenyl group, or an anthracenyl group substituted with a phenyl group.

14. The compound of claim 10, wherein L is an unsubstituted phenylene group, an unsubstituted naphthalene group, or an unsubstituted anthracene group.

15. The compound of claim 10, wherein Formula 1 is represented by Formula 1-2a or Formula 1-2b: 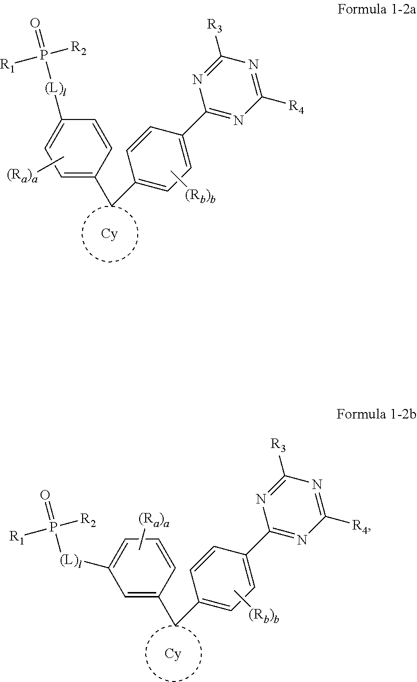
and
in Formula 1-2a and Formula 1-2b,
Cy, L, R₁ to R₄, Rₐ, R_{b}, “a”, “b”, and “l” are as defined in Formula 1.

16. The compound of claim 10, wherein each Rₐ and R_{b} is a hydrogen atom.

17. The compound of claim 10, wherein the compound represented by Formula 1 is represented by at least one compound selected from among Compound Group 1:
Compound Group 1

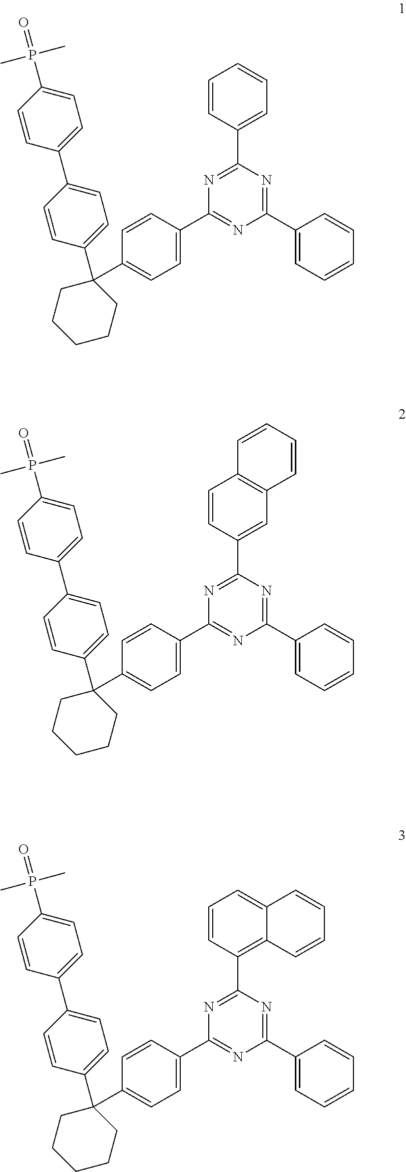 [SMILES: CP(C)(=O)c1ccc(-c2ccc(C3(c4ccc(-c5nc(-c6ccccc6)nc(-c6ccccc6)n5)cc4)CCCCC3)cc2)cc1 ; CP(C)(=O)c1ccc(-c2ccc(C3(c4ccc(-c5nc(-c6ccccc6)nc(-c6ccc7ccccc7c6)n5)cc4)CCCCC3)cc2)cc1 ; CP(C)(=O)c1ccc(-c2ccc(C3(c4ccc(-c5nc(-c6ccccc6)nc(-c6cccc7ccccc67)n5)cc4)CCCCC3)cc2)cc1]

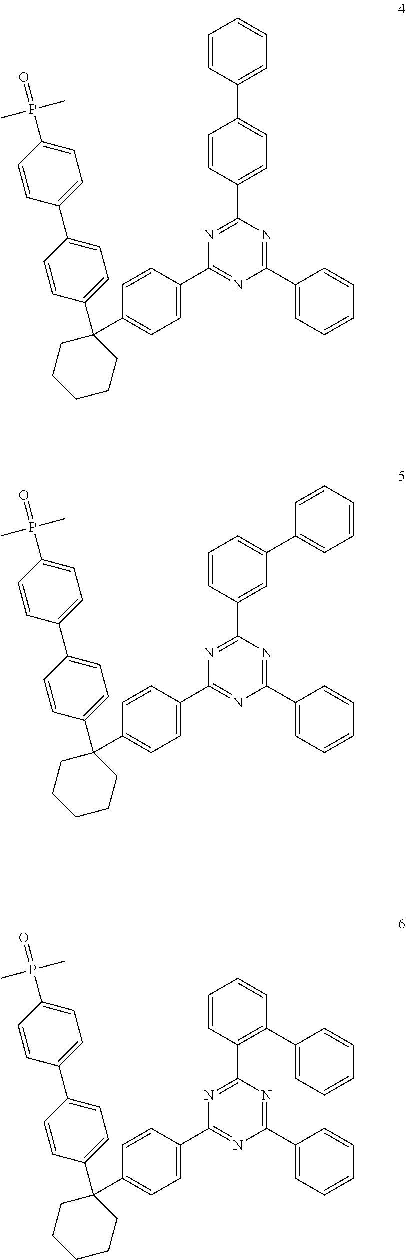 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccccc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccccc6)nc(-c6ccccc6-c6ccccc6)n5)cc4)CCCCC3)cc2)cc1]

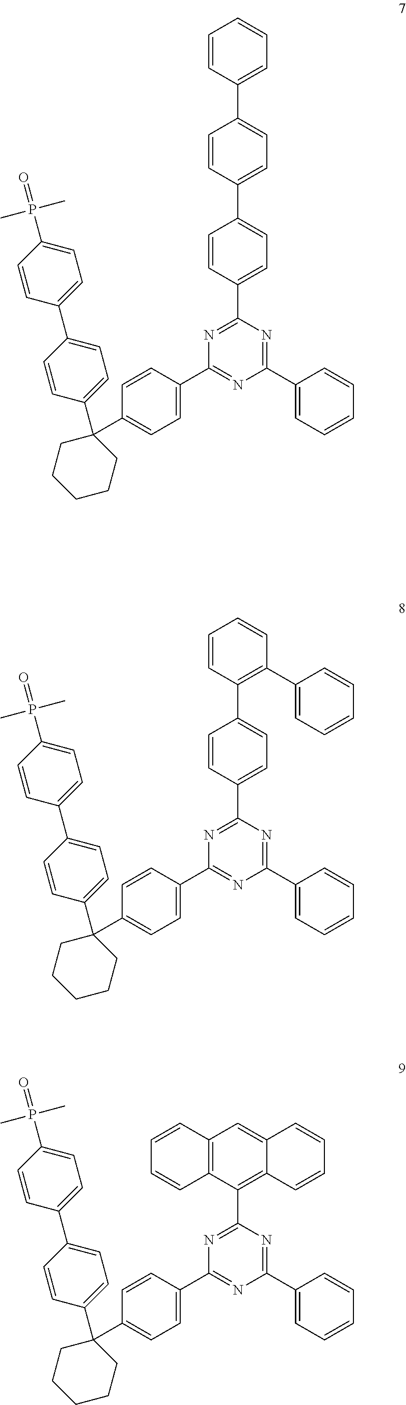 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)cc1 ; CP(C)(=O)c1ccc(-c2ccc(C3(c4ccc(-c5nc(-c6ccccc6)nc(-c6c7ccccc7cc7ccccc67)n5)cc4)CCCCC3)cc2)cc1]

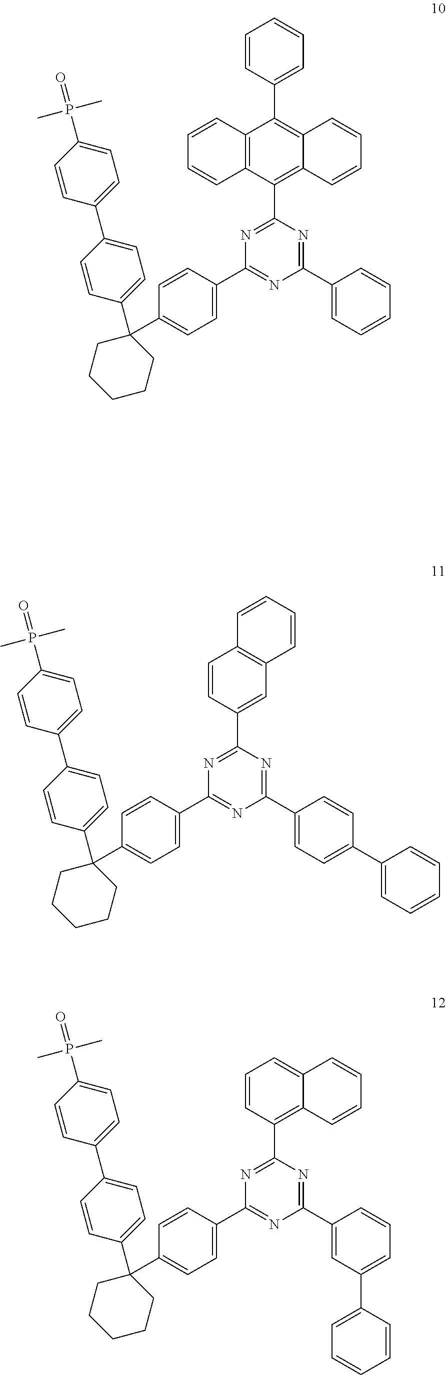 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)cc1]

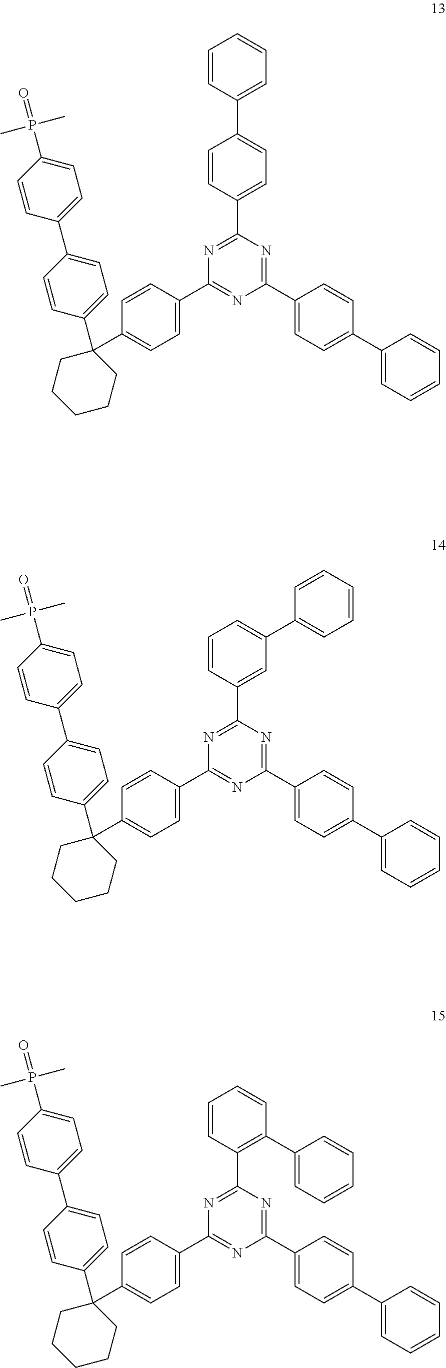 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)cc1 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)cc1]

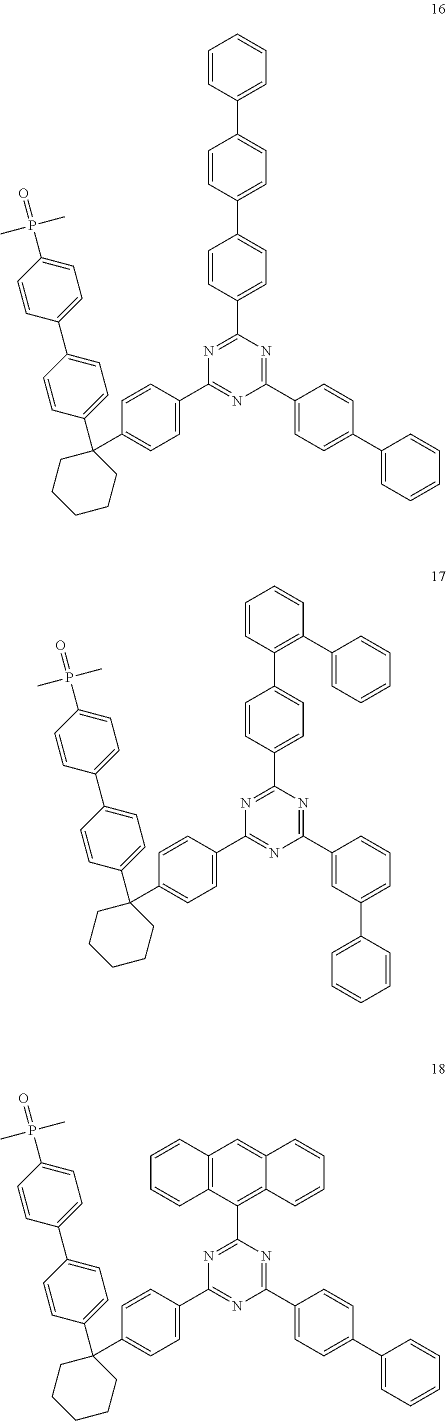 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)cc1 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CCCCC3)cc2)cc1]

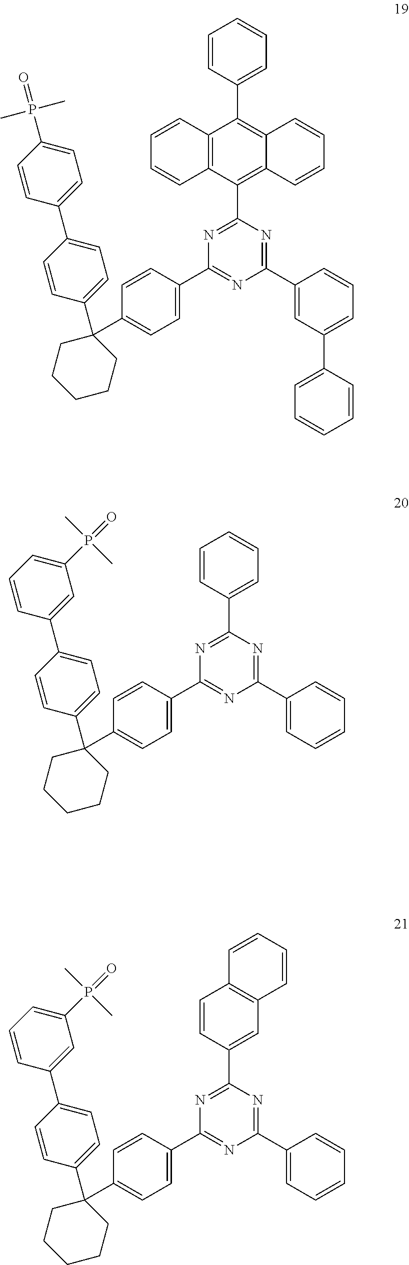 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)cc1 ; CP(C)(=O)c1cccc(-c2ccc(C3(c4ccc(-c5nc(-c6ccccc6)nc(-c6ccccc6)n5)cc4)CCCCC3)cc2)c1 ; CP(C)(=O)c1cccc(-c2ccc(C3(c4ccc(-c5nc(-c6ccccc6)nc(-c6ccc7ccccc7c6)n5)cc4)CCCCC3)cc2)c1]

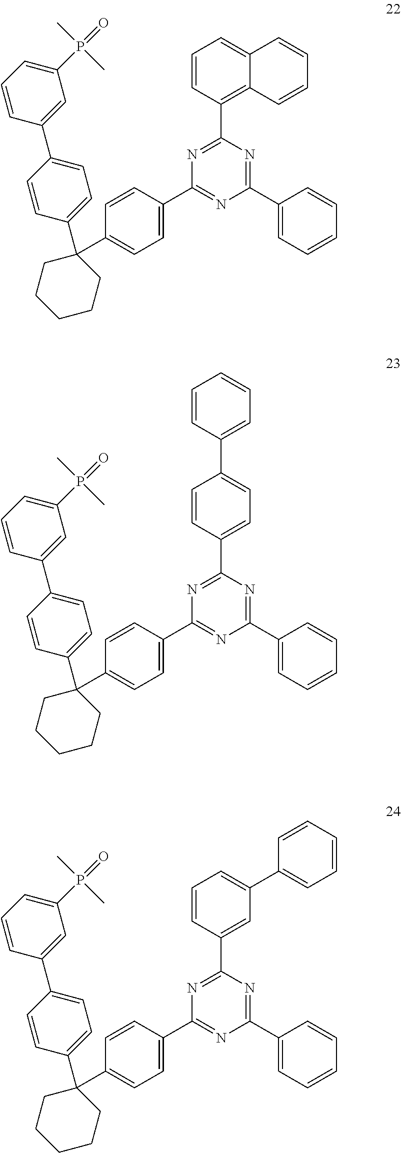 [SMILES: CP(C)(=O)c1cccc(-c2ccc(C3(c4ccc(-c5nc(-c6ccccc6)nc(-c6cccc7ccccc67)n5)cc4)CCCCC3)cc2)c1 ; CP(C)(=O)c1cccc(-c2ccc(C3(c4ccc(-c5nc(-c6ccccc6)nc(-c6ccc(-c7ccccc7)cc6)n5)cc4)CCCCC3)cc2)c1 ; CP(C)(=O)c1cccc(-c2ccc(C3(c4ccc(-c5nc(-c6ccccc6)nc(-c6cccc(-c7ccccc7)c6)n5)cc4)CCCCC3)cc2)c1]

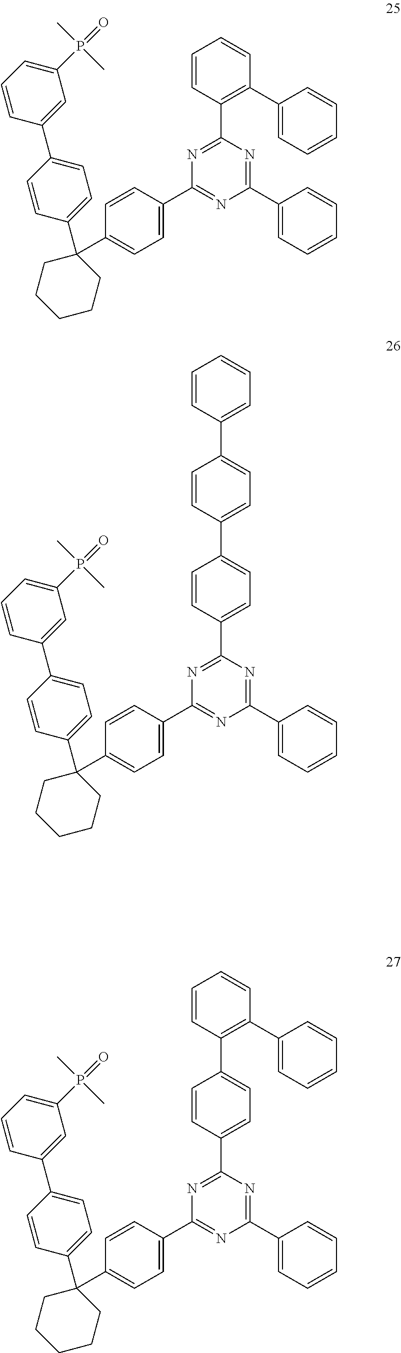 [SMILES: CP(C)(=O)c1cccc(-c2ccc(C3(c4ccc(-c5nc(-c6ccccc6)nc(-c6ccccc6-c6ccccc6)n5)cc4)CCCCC3)cc2)c1 ; CP(C)(=O)c1cccc(-c2ccc(C3(c4ccc(-c5nc(-c6ccccc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CCCCC3)cc2)c1]

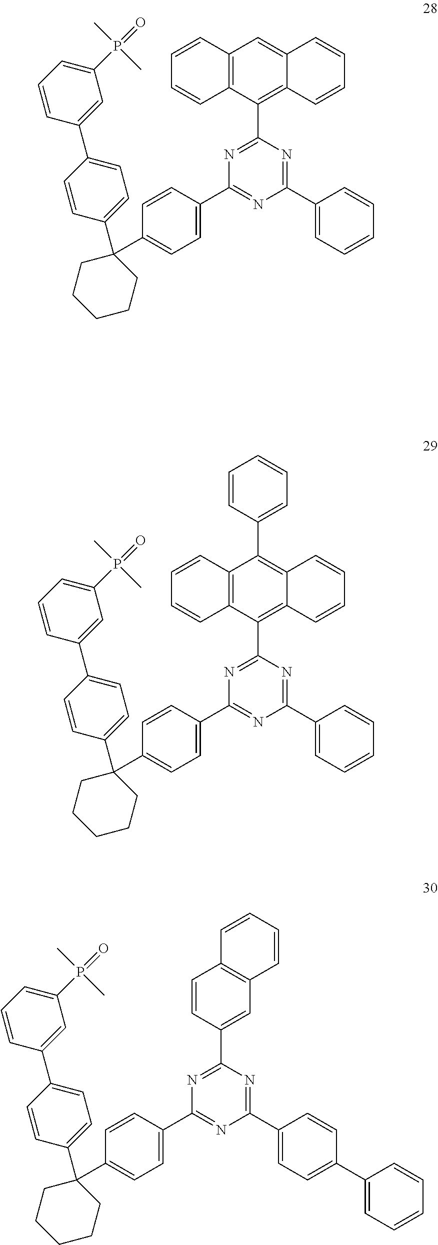 [SMILES: CP(C)(=O)c1cccc(-c2ccc(C3(c4ccc(-c5nc(-c6ccccc6)nc(-c6c7ccccc7cc7ccccc67)n5)cc4)CCCCC3)cc2)c1 ; CP(C)(=O)c1cccc(-c2ccc(C3(c4ccc(-c5nc(-c6ccccc6)nc(-c6c7ccccc7c(-c7ccccc7)c7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CCCCC3)cc2)c1]

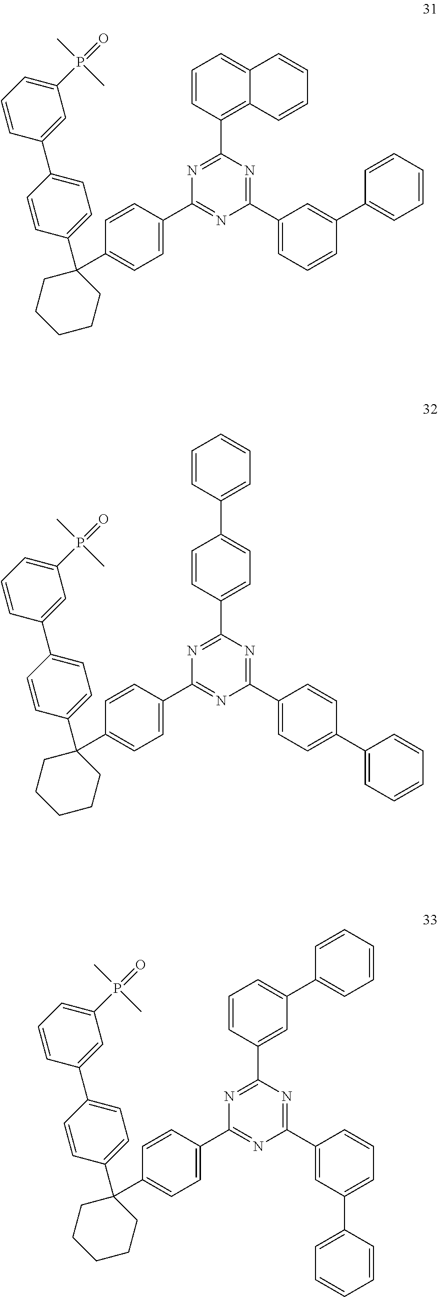 [SMILES: CP(C)(=O)c1cccc(-c2ccc(C3(c4ccc(-c5nc(-c6cccc(-c7ccccc7)c6)nc(-c6cccc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccccc7)cc6)n5)cc4)CCCCC3)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CCCCC3)cc2)c1]

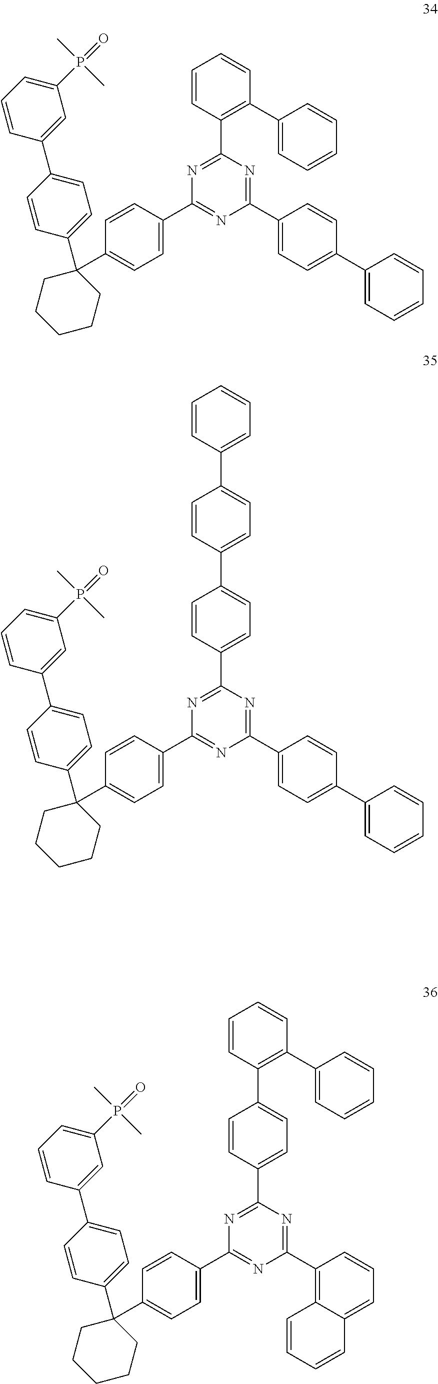 [SMILES: CP(C)(=O)c1cccc(-c2ccc(C3(c4ccc(-c5nc(-c6ccc(-c7ccccc7)cc6)nc(-c6ccccc6-c6ccccc6)n5)cc4)CCCCC3)cc2)c1 ; CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CCCCC3)cc2)c1]

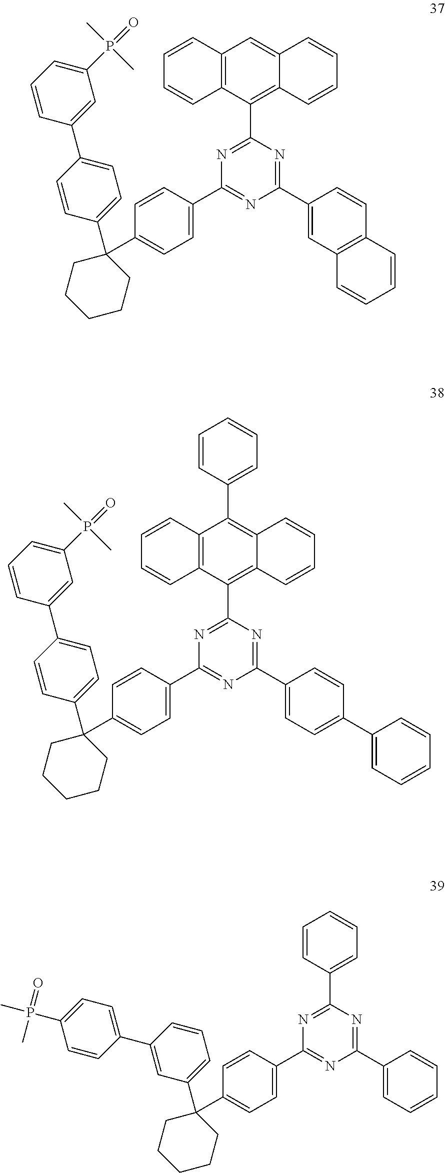 [SMILES: CP(C)(=O)c1cccc(-c2ccc(C3(c4ccc(-c5nc(-c6ccc7ccccc7c6)nc(-c6c7ccccc7cc7ccccc67)n5)cc4)CCCCC3)cc2)c1 ; CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CCCCC3)cc2)c1 ; CP(C)(=O)c1ccc(-c2cccc(C3(c4ccc(-c5nc(-c6ccccc6)nc(-c6ccccc6)n5)cc4)CCCCC3)c2)cc1]

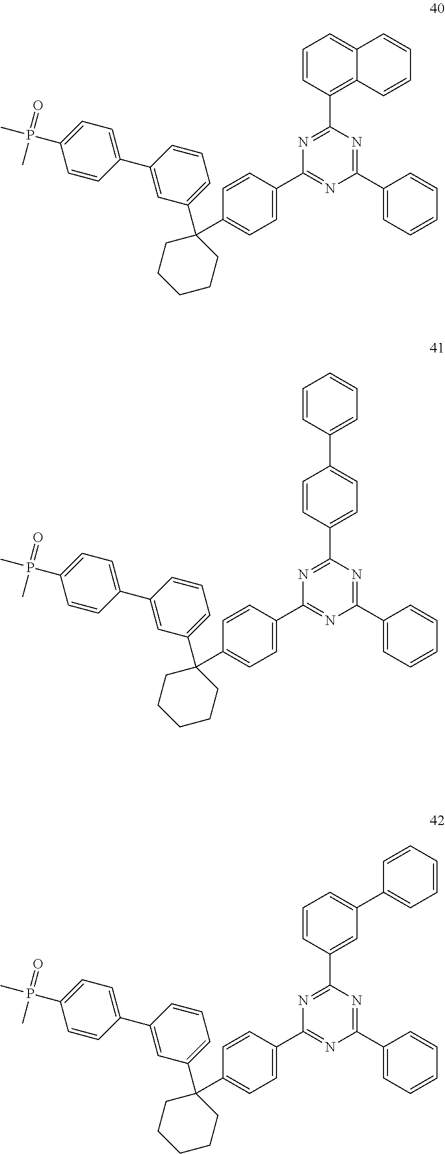 [SMILES: CP(C)(=O)c1ccc(-c2cccc(C3(c4ccc(-c5nc(-c6ccccc6)nc(-c6cccc7ccccc67)n5)cc4)CCCCC3)c2)cc1 ; CP(C)(=O)c1ccc(-c2cccc(C3(c4ccc(-c5nc(-c6ccccc6)nc(-c6ccc(-c7ccccc7)cc6)n5)cc4)CCCCC3)c2)cc1 ; CP(C)(=O)c1ccc(-c2cccc(C3(c4ccc(-c5nc(-c6ccccc6)nc(-c6cccc(-c7ccccc7)c6)n5)cc4)CCCCC3)c2)cc1]

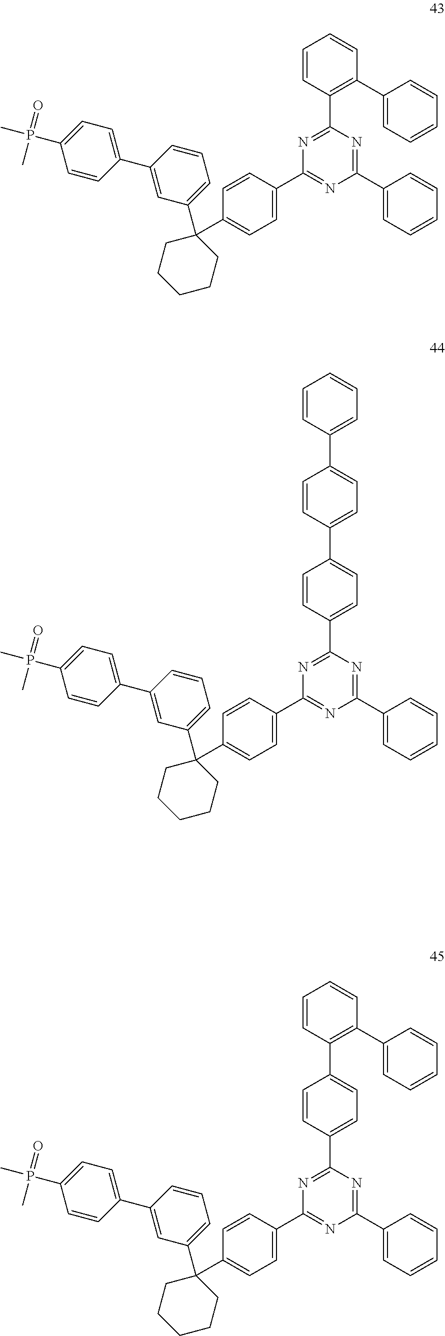 [SMILES: CP(C)(=O)c1ccc(-c2cccc(C3(c4ccc(-c5nc(-c6ccccc6)nc(-c6ccccc6-c6ccccc6)n5)cc4)CCCCC3)c2)cc1 ; CP(C)(=O)c1ccc(-c2cccc(C3(c4ccc(-c5nc(-c6ccccc6)nc(-c6ccc(-c7ccc(-c8ccccc8)cc7)cc6)n5)cc4)CCCCC3)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CCCCC3)c2)cc1]

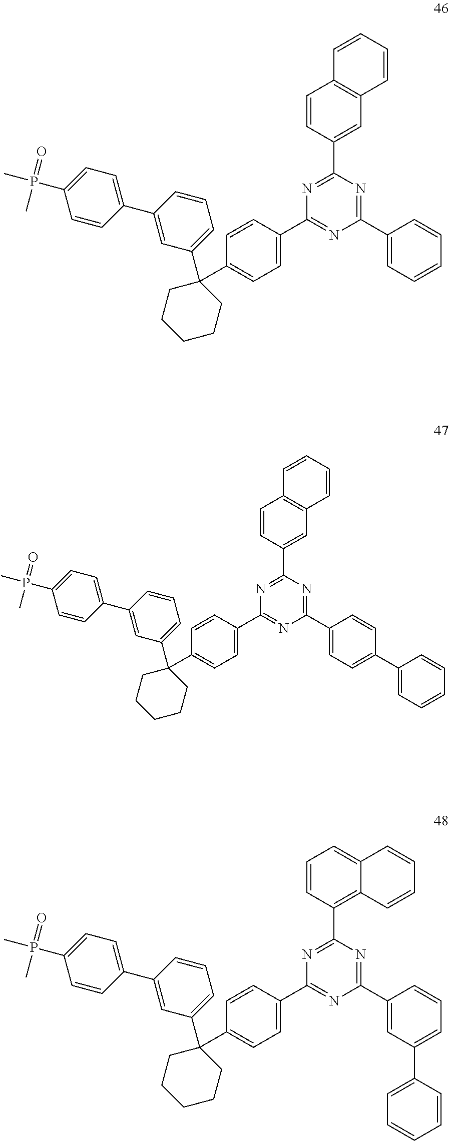 [SMILES: CP(C)(=O)c1ccc(-c2cccc(C3(c4ccc(-c5nc(-c6ccccc6)nc(-c6ccc7ccccc7c6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CCCCC3)c2)cc1]

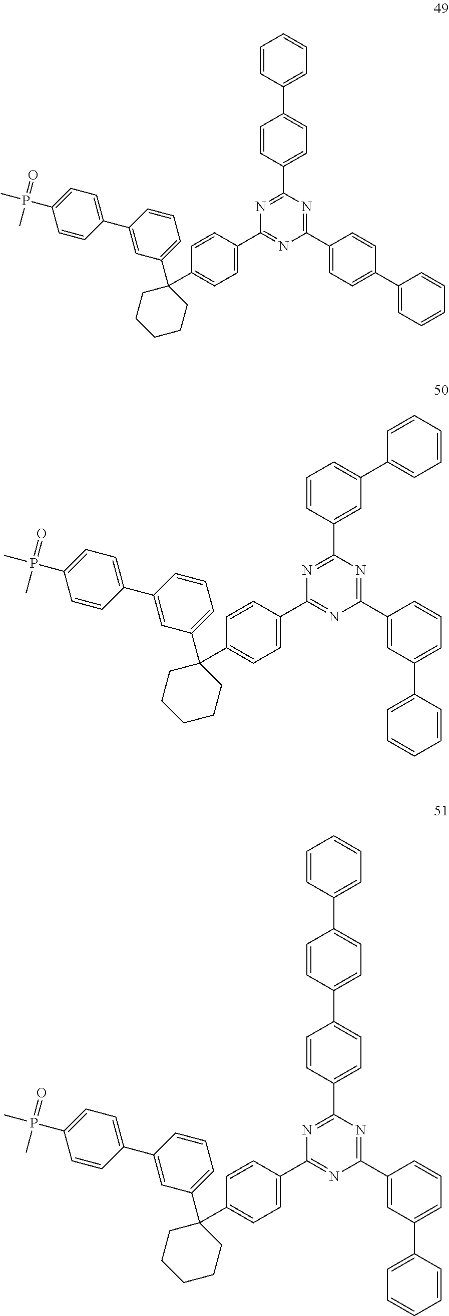 [SMILES: CP(C)(=O)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1 ; CP(C)(=O)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1 ; CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1]

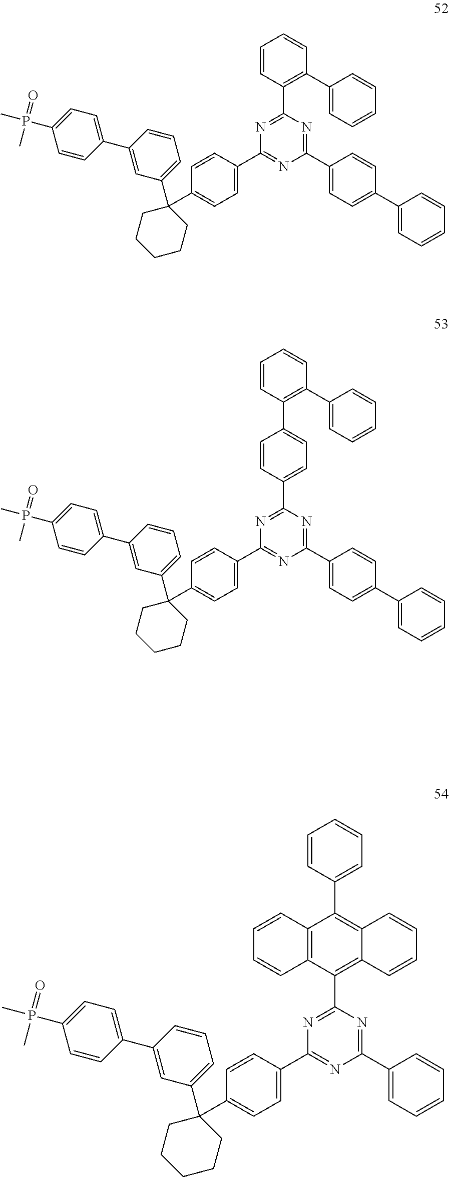 [SMILES: CP(C)(=O)c1ccc(-c2cccc(C3(c4ccc(-c5nc(-c6ccc(-c7ccccc7)cc6)nc(-c6ccccc6-c6ccccc6)n5)cc4)CCCCC3)c2)cc1 ; CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1 ; CP(C)(=O)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1]

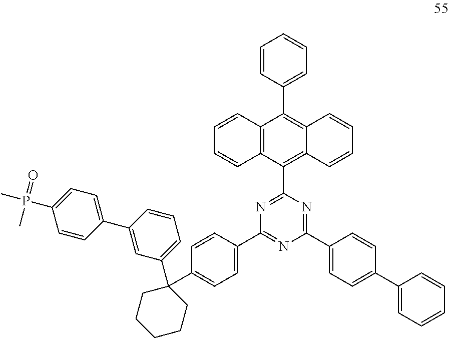 [SMILES: CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1]

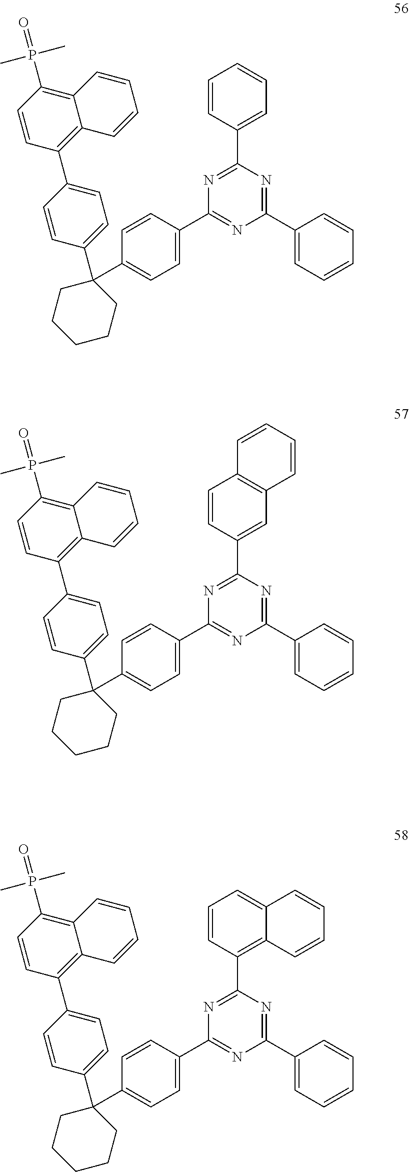 [SMILES: CP(C)(=O)c1ccc(-c2ccc(C3(c4ccc(-c5nc(-c6ccccc6)nc(-c6ccccc6)n5)cc4)CCCCC3)cc2)c2ccccc12 ; CP(C)(=O)c1ccc(-c2ccc(C3(c4ccc(-c5nc(-c6ccccc6)nc(-c6ccc7ccccc7c6)n5)cc4)CCCCC3)cc2)c2ccccc12 ; CP(C)(=O)c1ccc(-c2ccc(C3(c4ccc(-c5nc(-c6ccccc6)nc(-c6cccc7ccccc67)n5)cc4)CCCCC3)cc2)c2ccccc12]

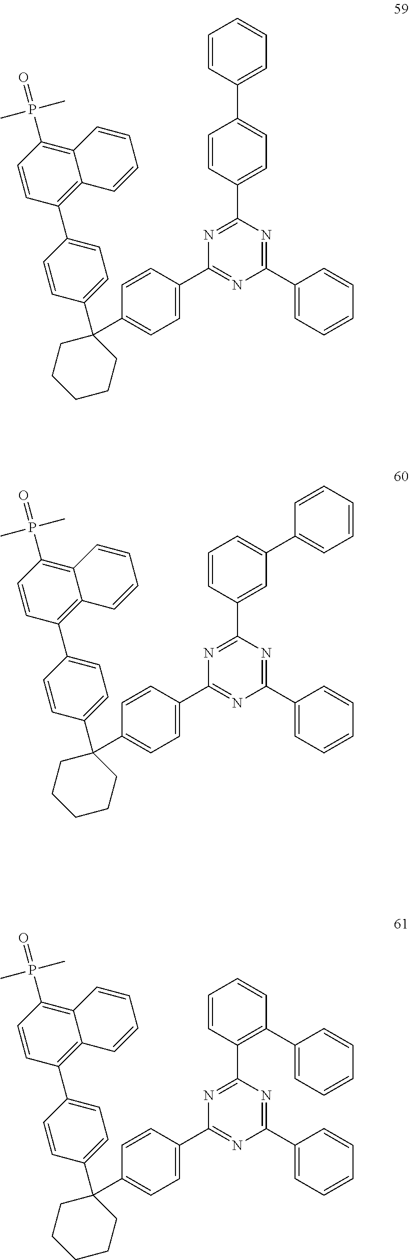 [SMILES: CP(C)(=O)c1ccc(-c2ccc(C3(c4ccc(-c5nc(-c6ccccc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccccc6)nc(-c6ccccc6-c6ccccc6)n5)cc4)CCCCC3)cc2)c2ccccc12]

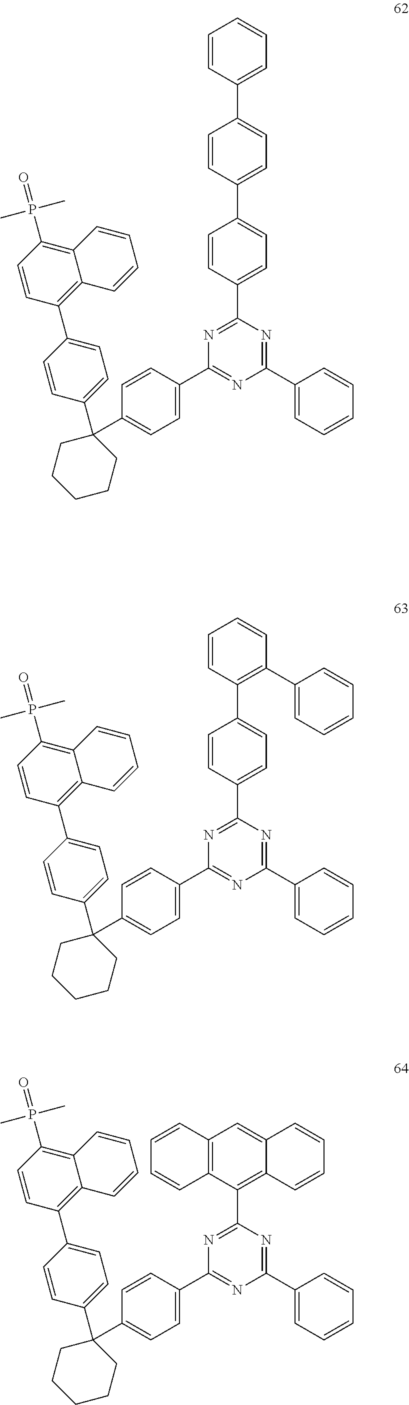 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CCCCC3)cc2)c2ccccc12]

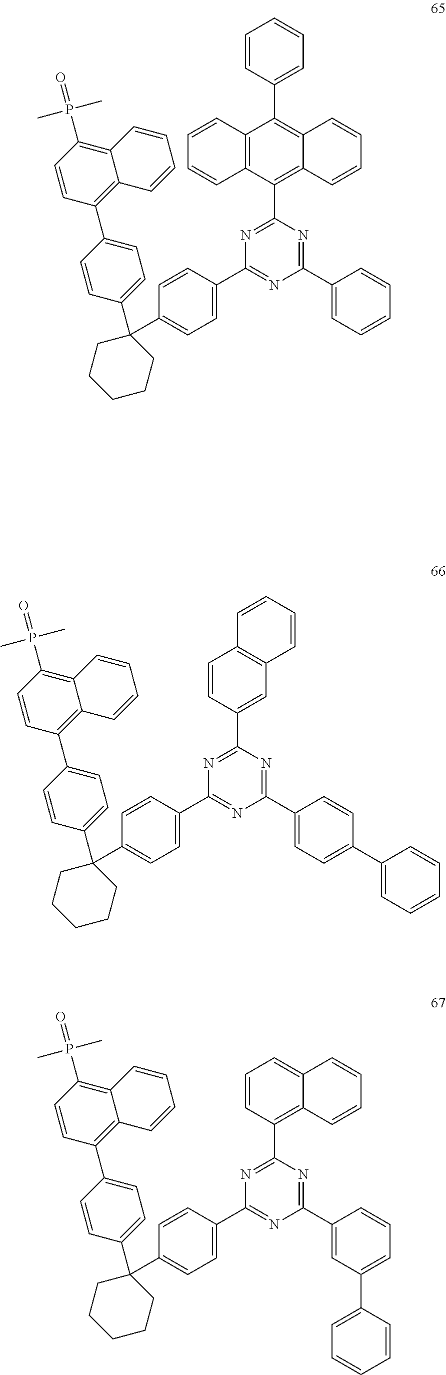 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccc7ccccc7c6)n5)cc4)CCCCC3)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CCCCC3)cc2)c2ccccc12]

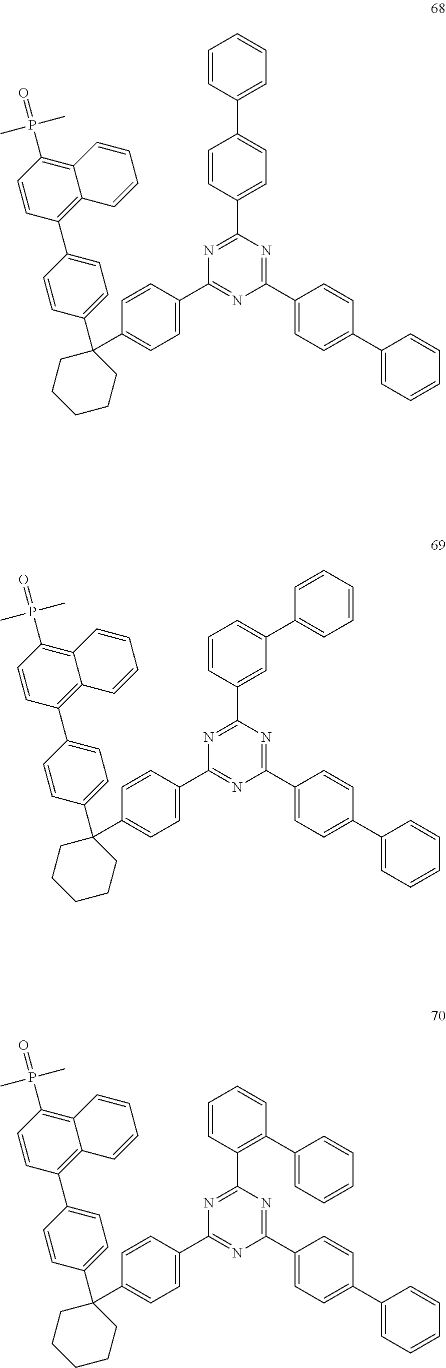 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

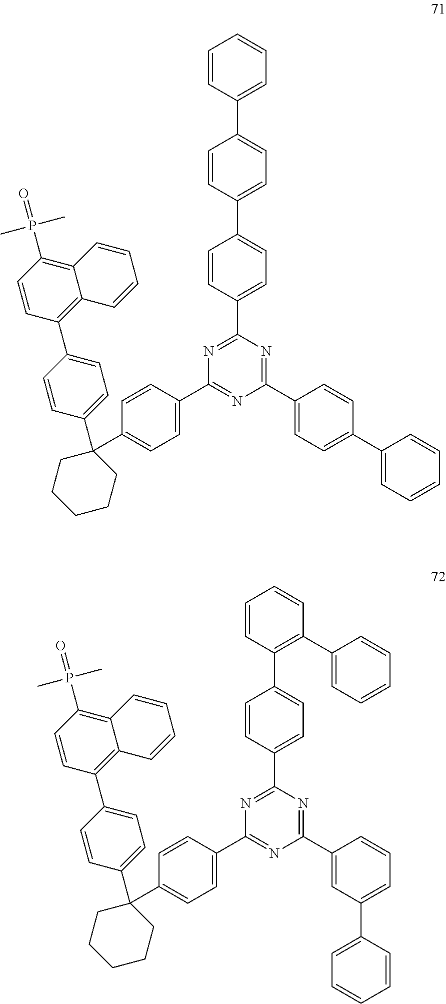 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

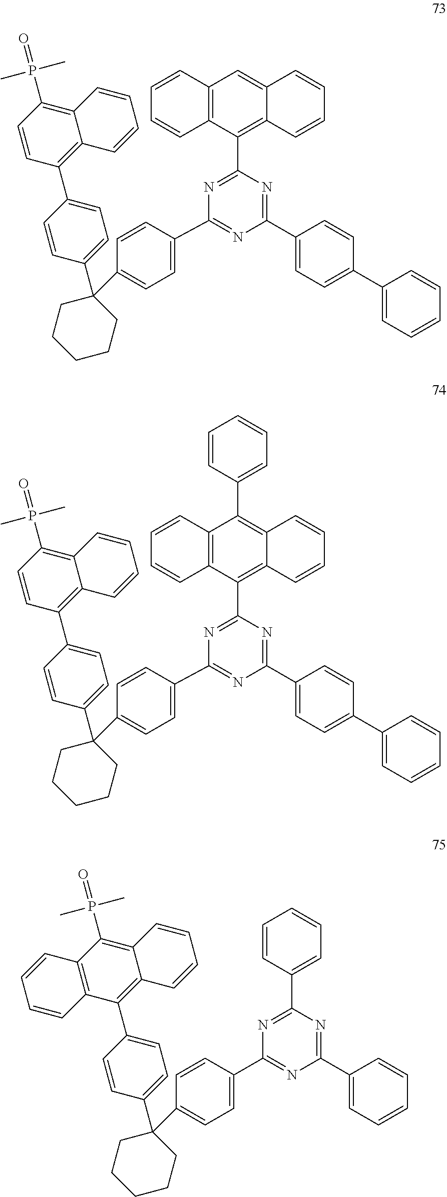 [SMILES: CP(C)(=O)c1ccc(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; CP(C)(=O)c1ccc(-c2ccc(C3(c4ccc(-c5nc(-c6ccc(-c7ccccc7)cc6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccccc6)nc(-c6ccccc6)n5)cc4)CCCCC3)cc2)c2ccccc12]

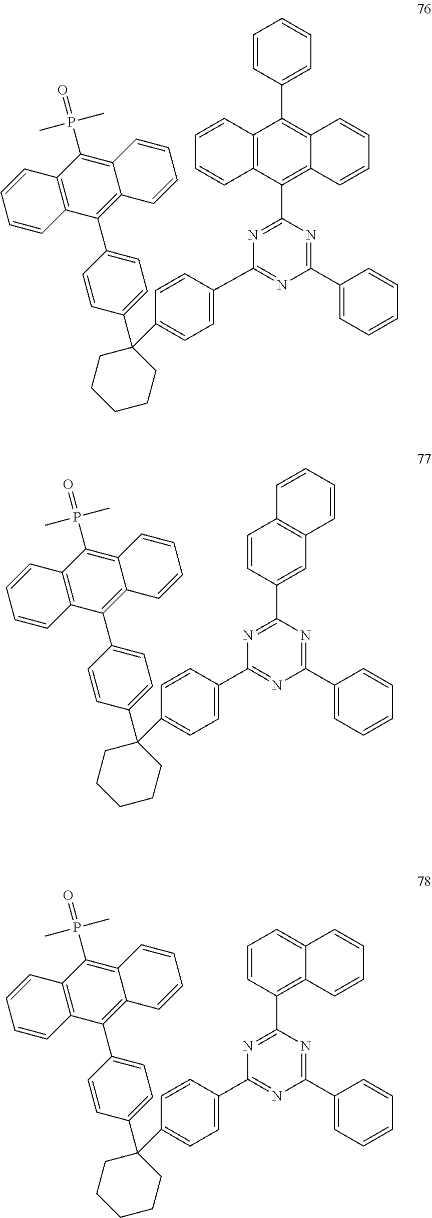 [SMILES: CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccccc6)nc(-c6ccc7ccccc7c6)n5)cc4)CCCCC3)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CCCCC3)cc2)c2ccccc12]

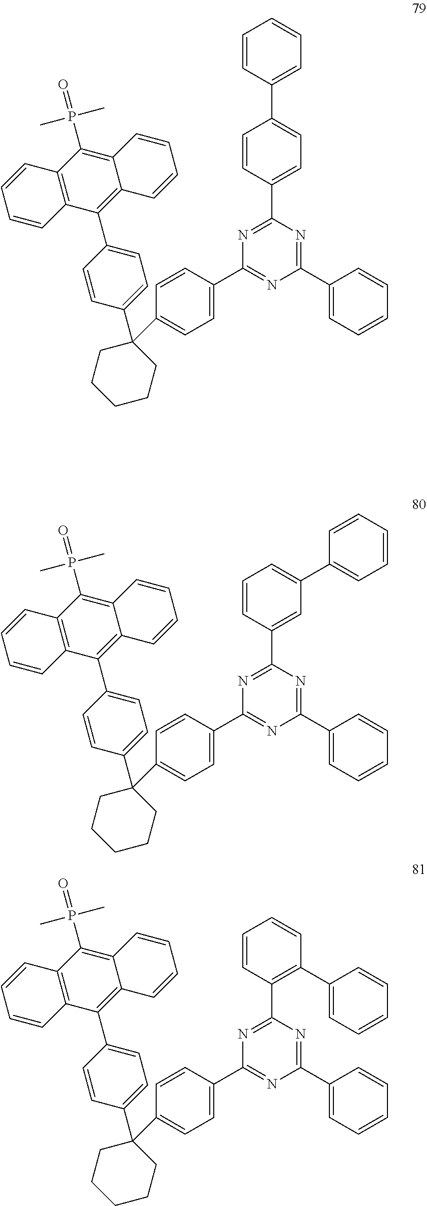 [SMILES: CP(C)(=O)c1c2ccccc2c(-c2ccc(C3(c4ccc(-c5nc(-c6ccccc6)nc(-c6ccc(-c7ccccc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6cccc(-c7ccccc7)c6)n5)cc4)CCCCC3)cc2)c2ccccc12 ; CP(C)(=O)c1c2ccccc2c(-c2ccc(C3(c4ccc(-c5nc(-c6ccccc6)nc(-c6ccccc6-c6ccccc6)n5)cc4)CCCCC3)cc2)c2ccccc12]

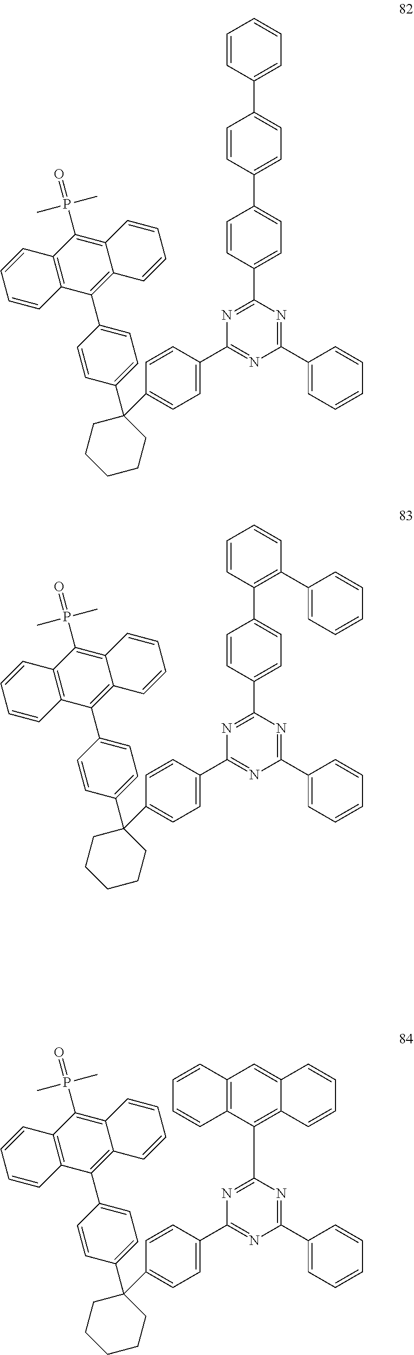 [SMILES: CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)CCCCC3)cc2)c2ccccc12]

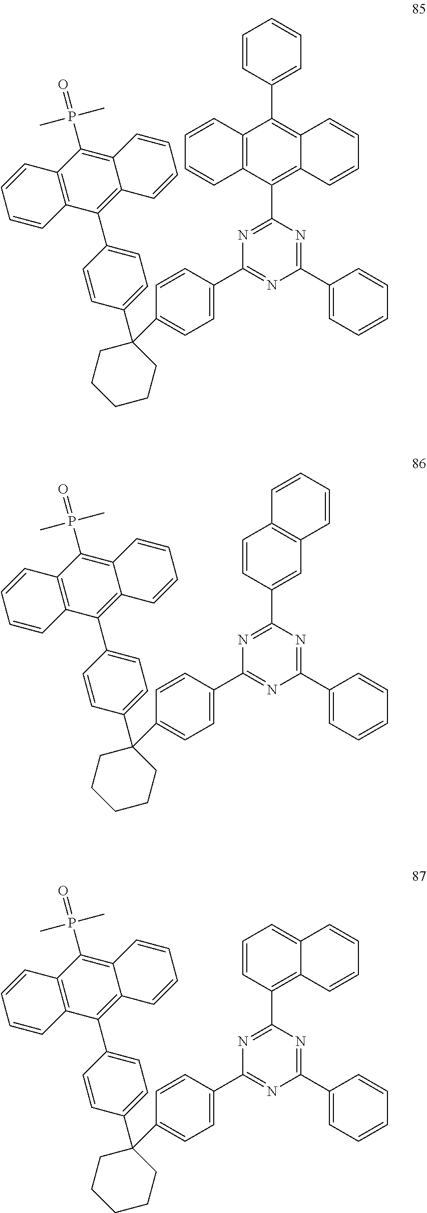 [SMILES: CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; CP(C)(=O)c1c2ccccc2c(-c2ccc(C3(c4ccc(-c5nc(-c6ccccc6)nc(-c6ccc7ccccc7c6)n5)cc4)CCCCC3)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CCCCC3)cc2)c2ccccc12]

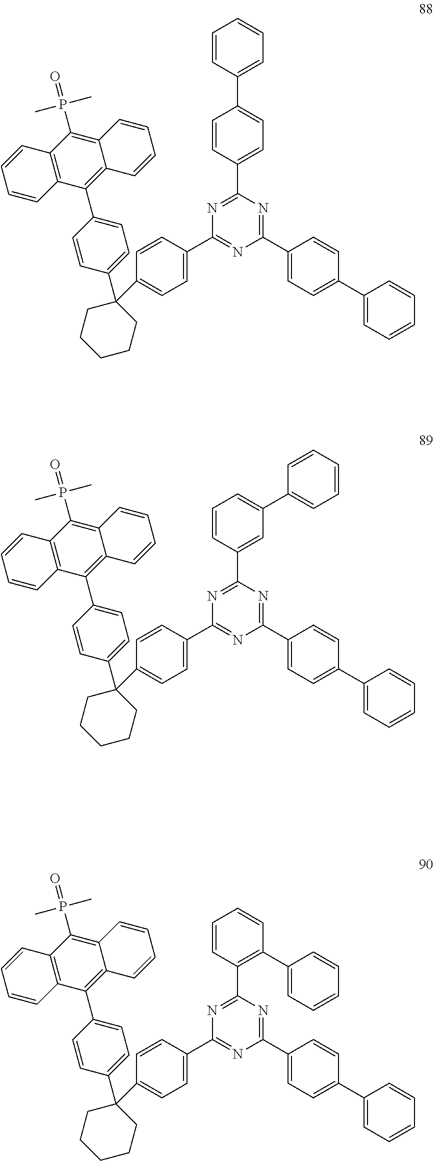 [SMILES: CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

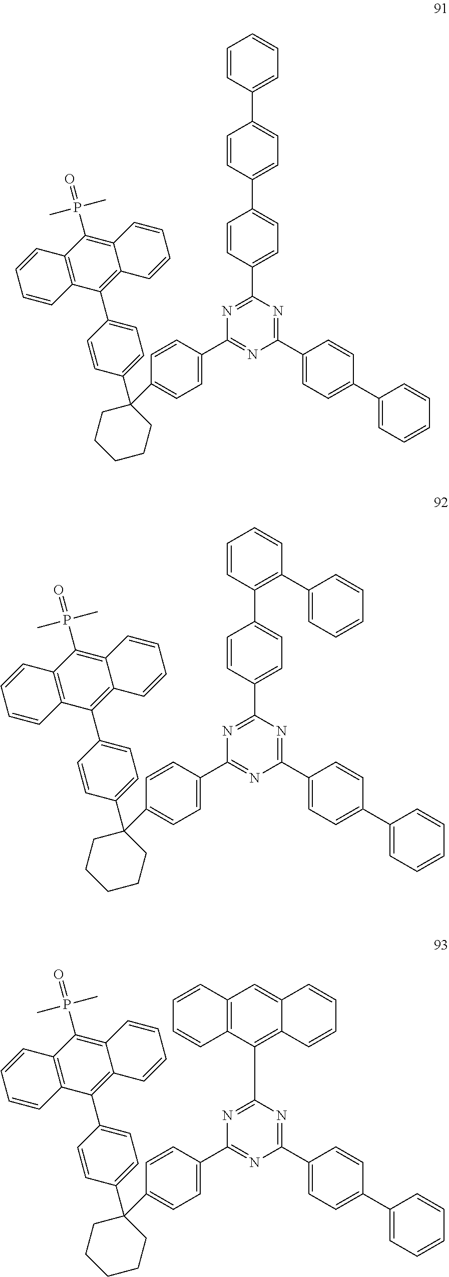 [SMILES: CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7-c7ccccc7)cc6)n5)cc4)CCCCC3)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12]

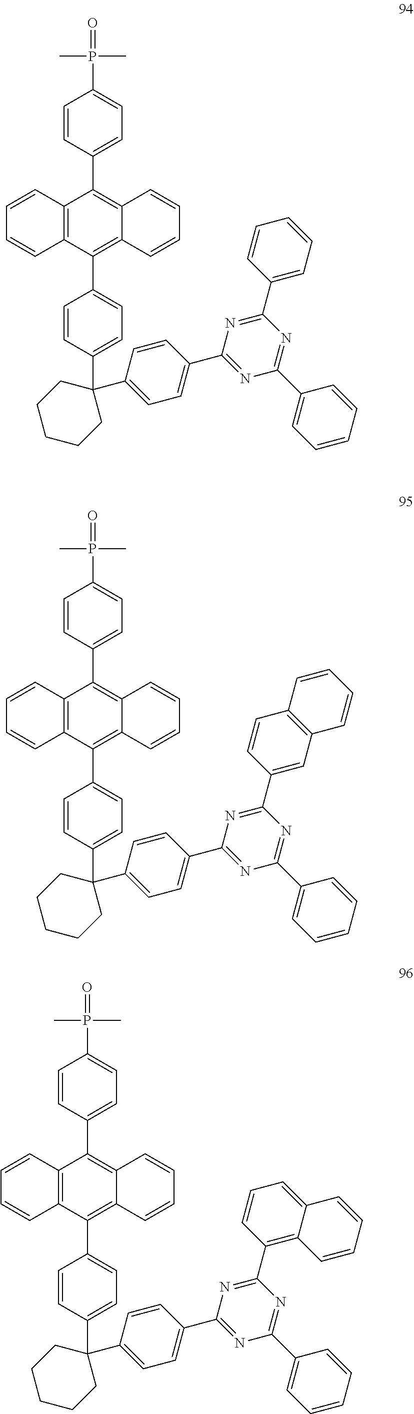 [SMILES: CP(C)(=O)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1]

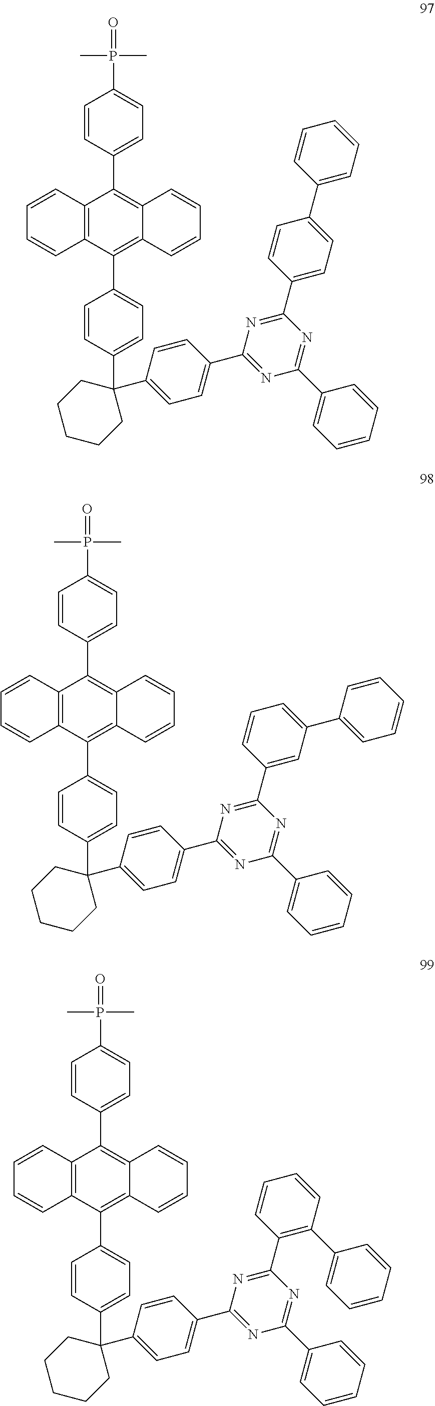 [SMILES: CP(C)(=O)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1]

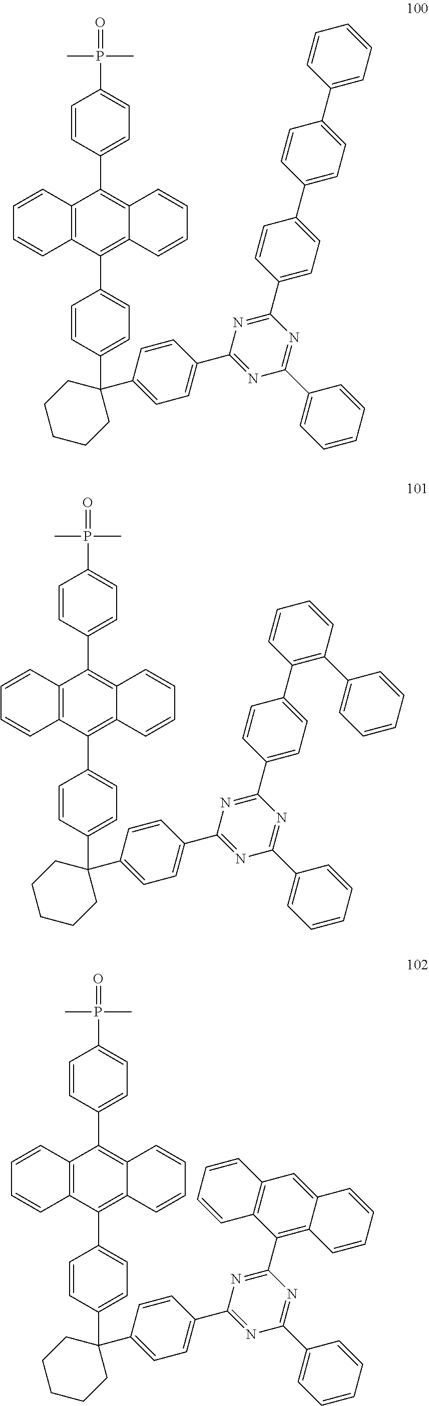 [SMILES: CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)CCCCC4)cc3)c3ccccc23)cc1]

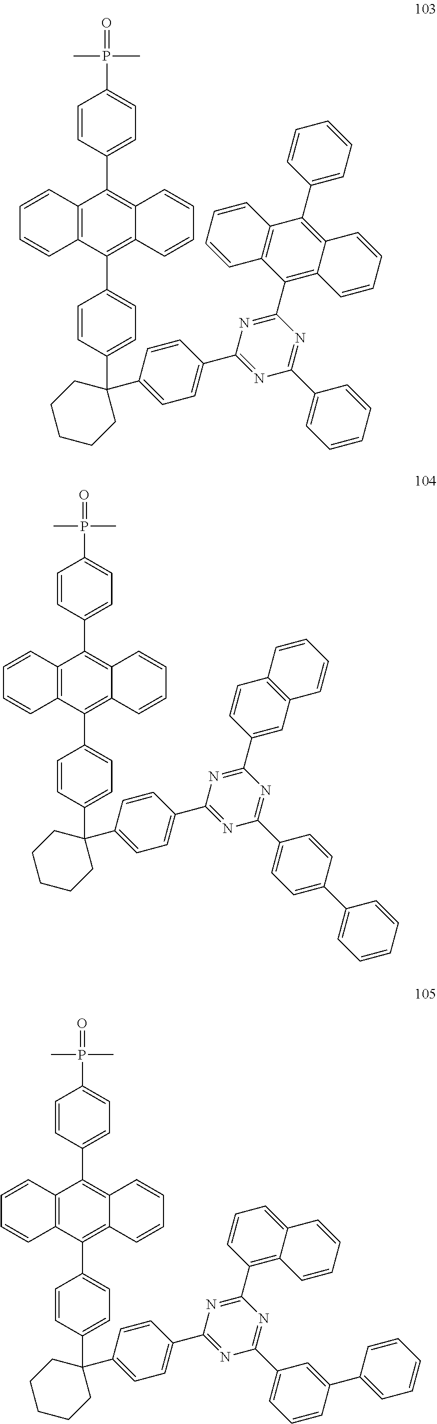 [SMILES: CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1]

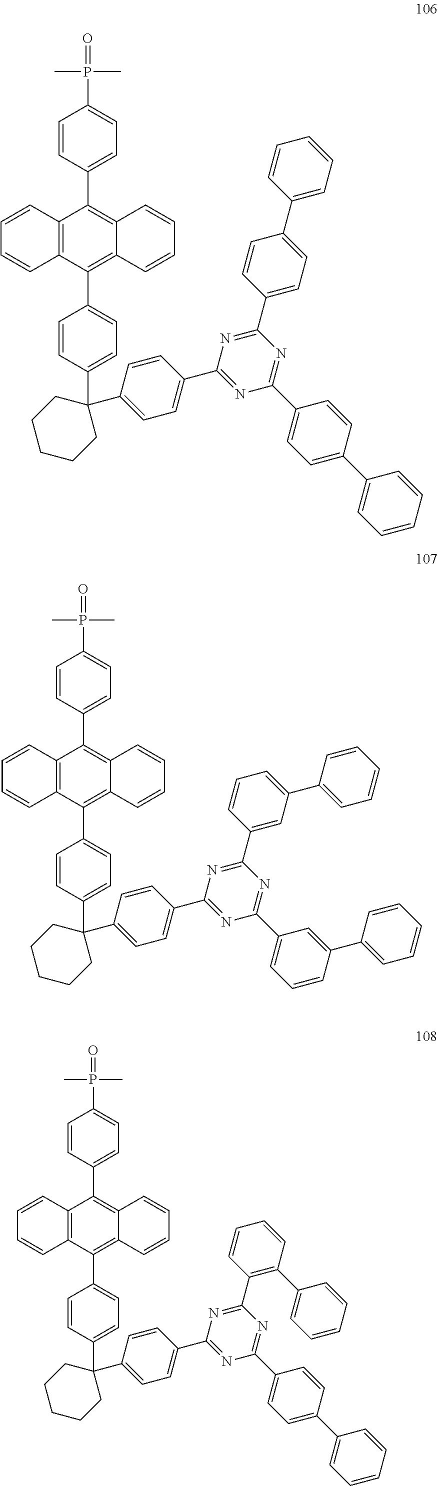 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CCCCC4)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

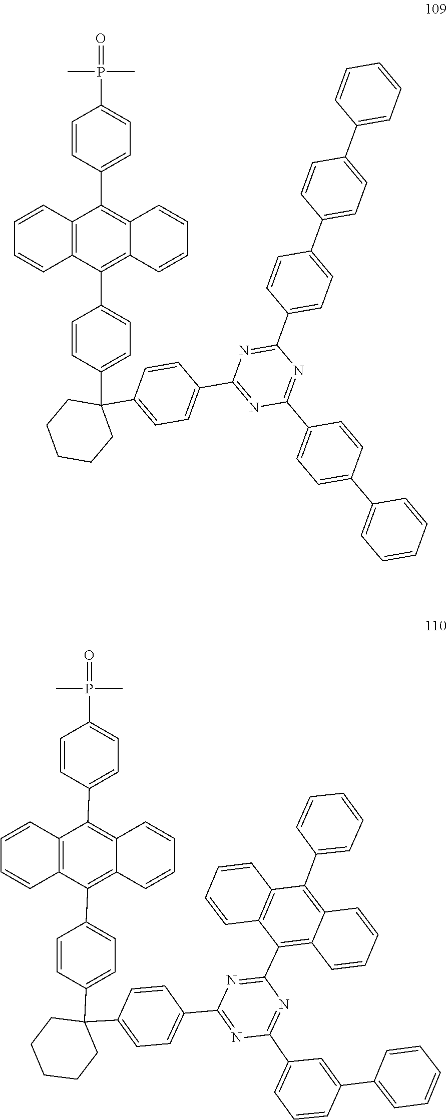 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CCCCC4)cc3)c3ccccc23)cc1]

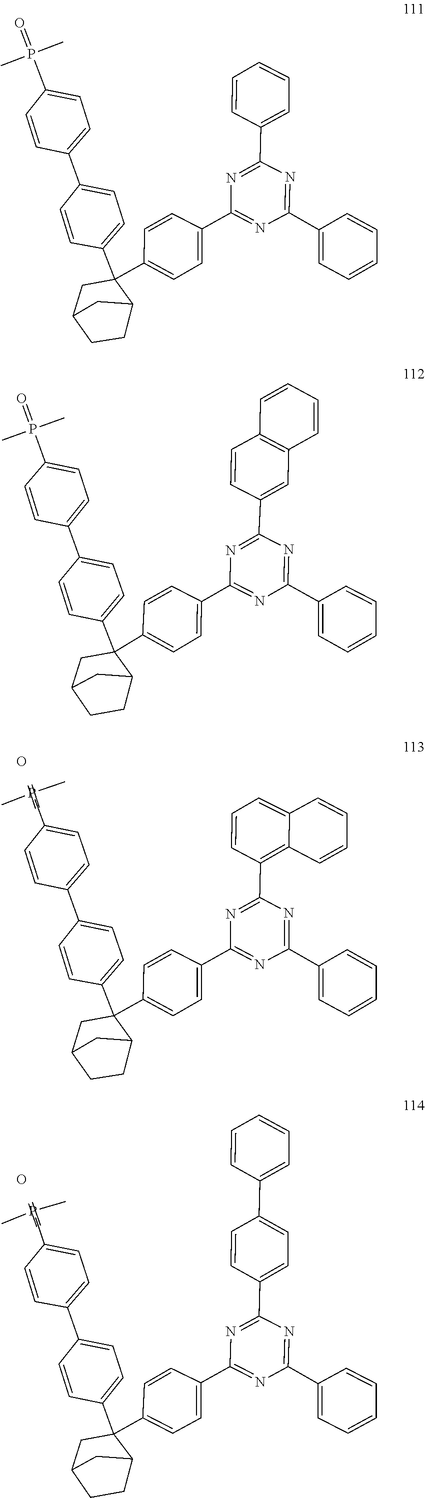

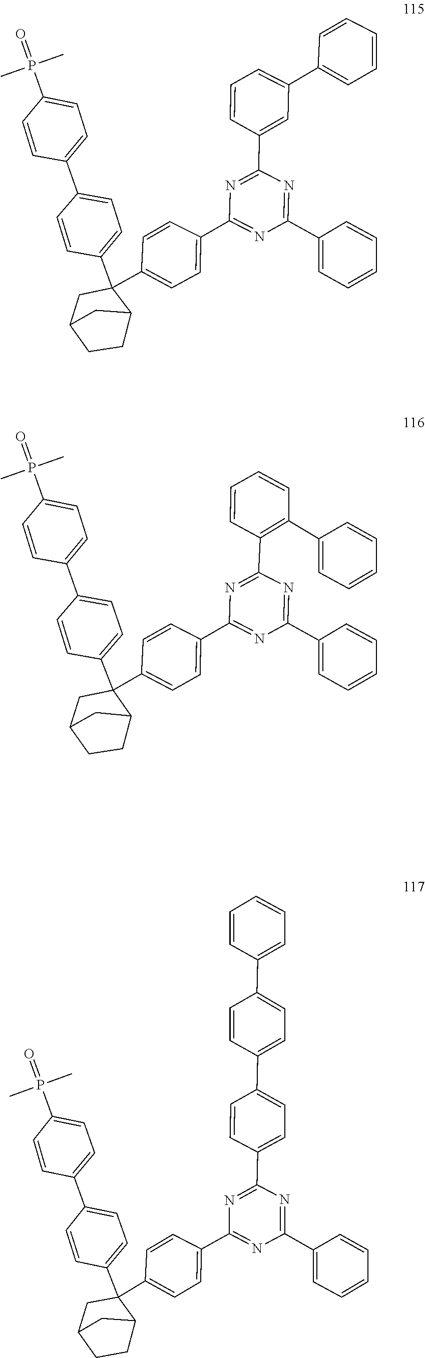 [SMILES: CP(C)(=O)c1ccc(-c2ccc(C3(c4ccc(-c5nc(-c6ccccc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)cc1]

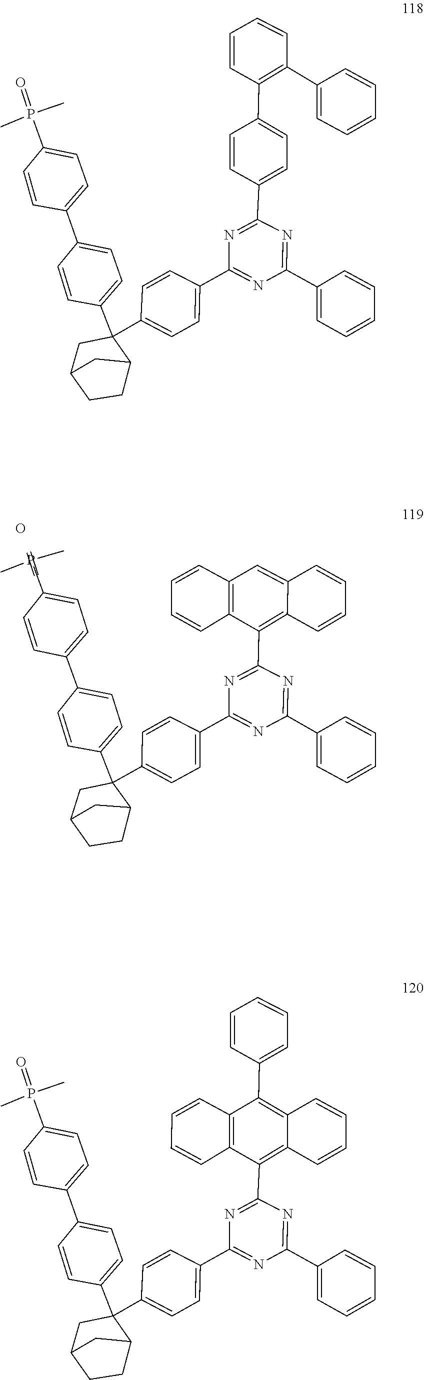

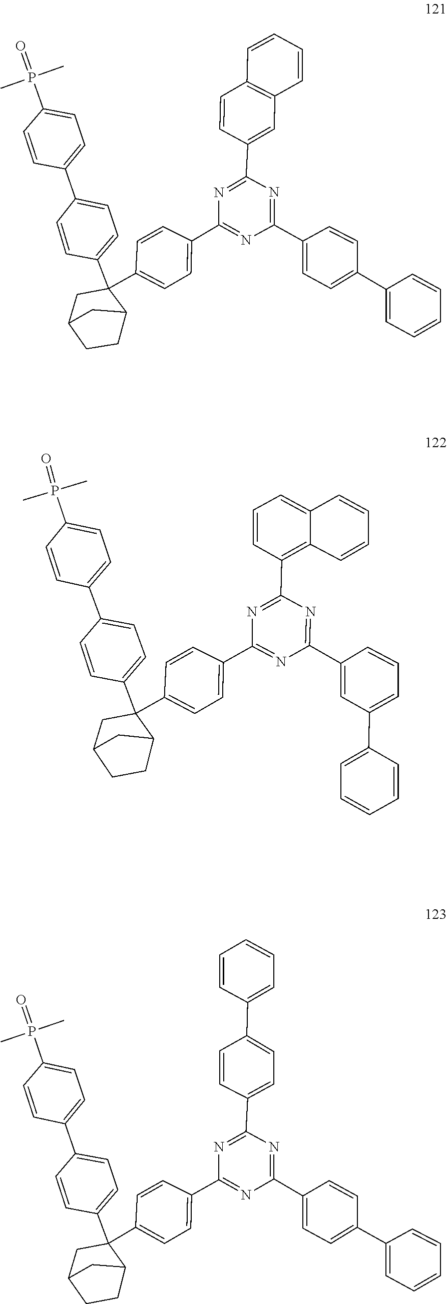 [SMILES: CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)cc1]

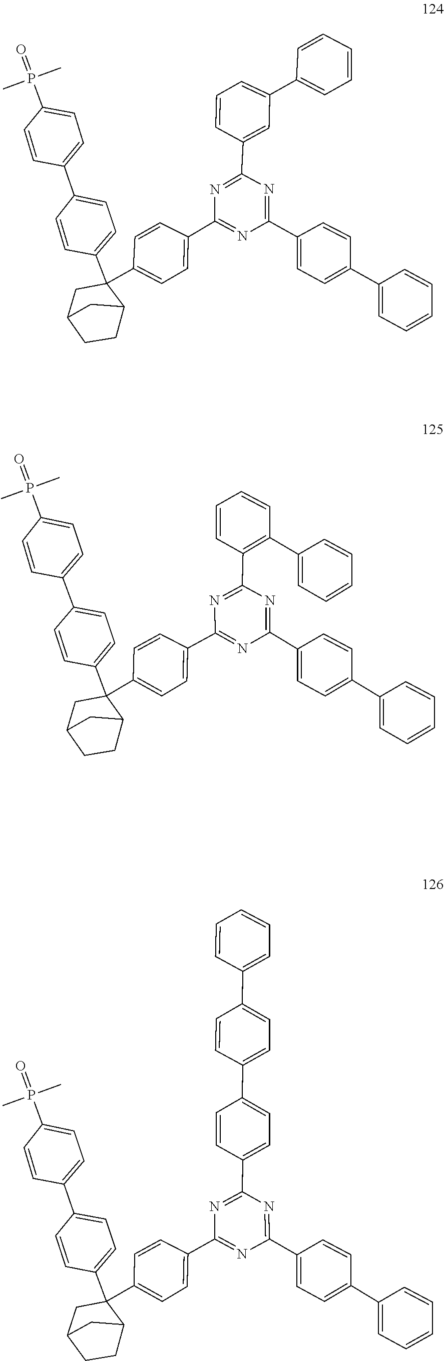 [SMILES: CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)cc1]

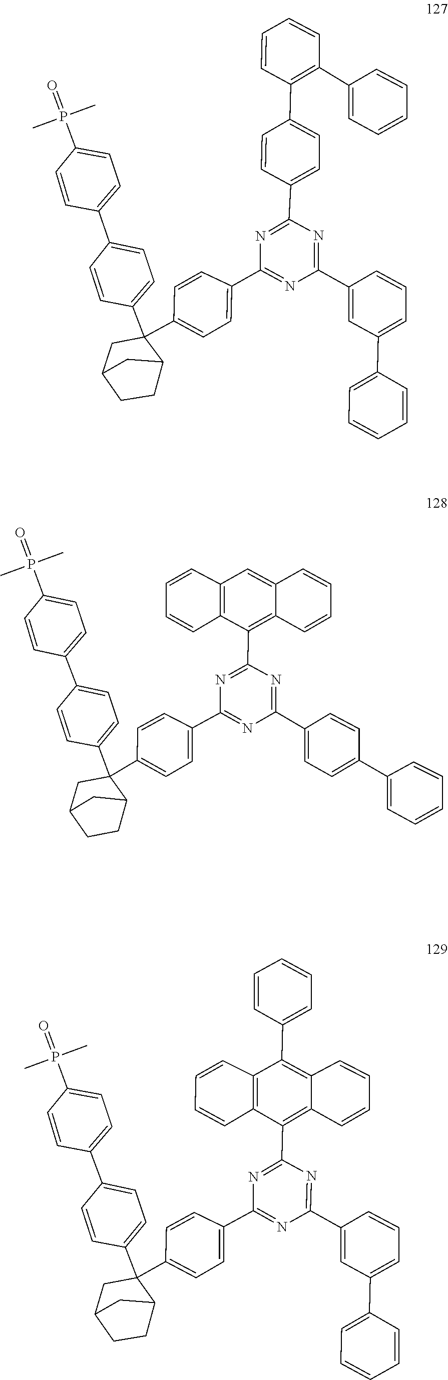 [SMILES: CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)cc1 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)cc1 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)cc1]

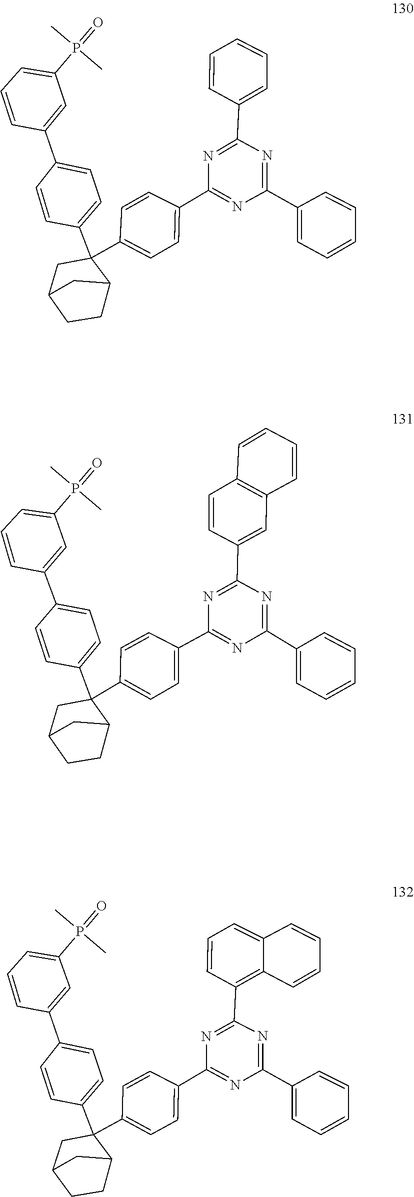 [SMILES: CP(C)(=O)c1cccc(-c2ccc(C3(c4ccc(-c5nc(-c6ccccc6)nc(-c6ccccc6)n5)cc4)CC4CCC3C4)cc2)c1 ; CP(C)(=O)c1cccc(-c2ccc(C3(c4ccc(-c5nc(-c6ccccc6)nc(-c6ccc7ccccc7c6)n5)cc4)CC4CCC3C4)cc2)c1 ; CP(C)(=O)c1cccc(-c2ccc(C3(c4ccc(-c5nc(-c6ccccc6)nc(-c6cccc7ccccc67)n5)cc4)CC4CCC3C4)cc2)c1]

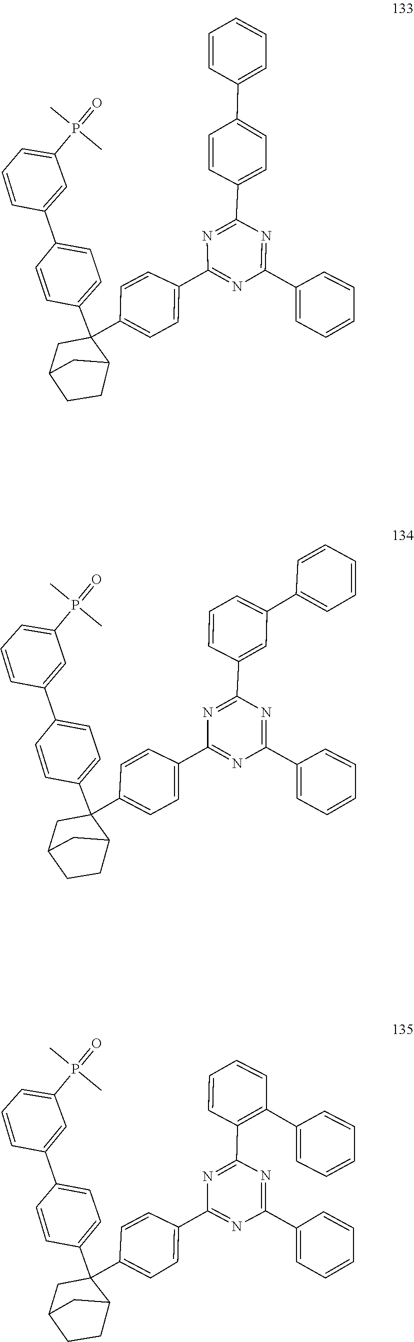 [SMILES: CP(C)(=O)c1cccc(-c2ccc(C3(c4ccc(-c5nc(-c6ccccc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccccc6)nc(-c6ccccc6-c6ccccc6)n5)cc4)CC4CCC3C4)cc2)c1]

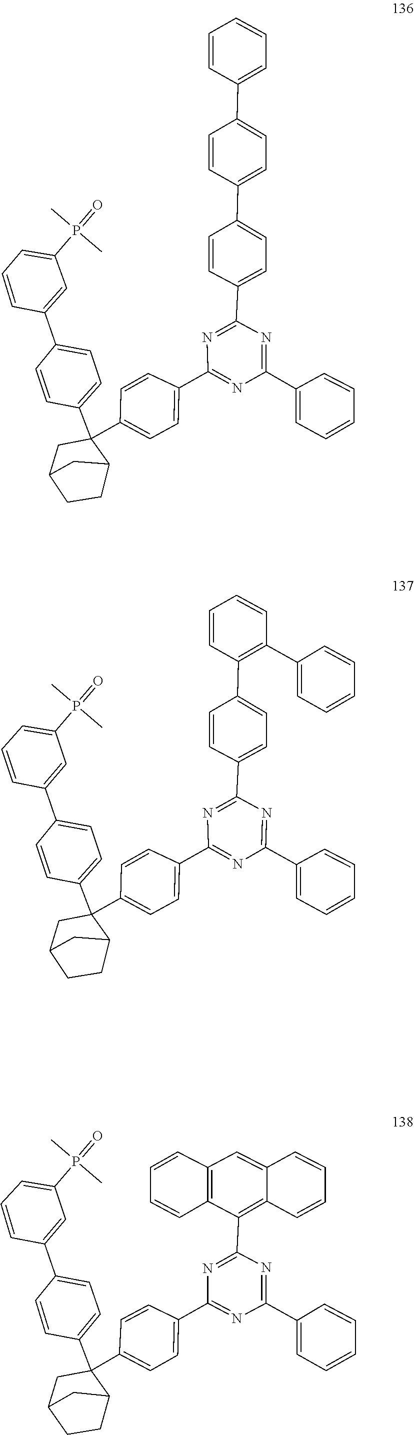 [SMILES: CP(C)(=O)c1cccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccccc6)nc(-c6ccc(-c7ccccc7-c7ccccc7)cc6)n5)cc4)CC4CCC3C4)cc2)c1 ; CP(C)(=O)c1cccc(-c2ccc(C3(c4ccc(-c5nc(-c6ccccc6)nc(-c6c7ccccc7cc7ccccc67)n5)cc4)CC4CCC3C4)cc2)c1]

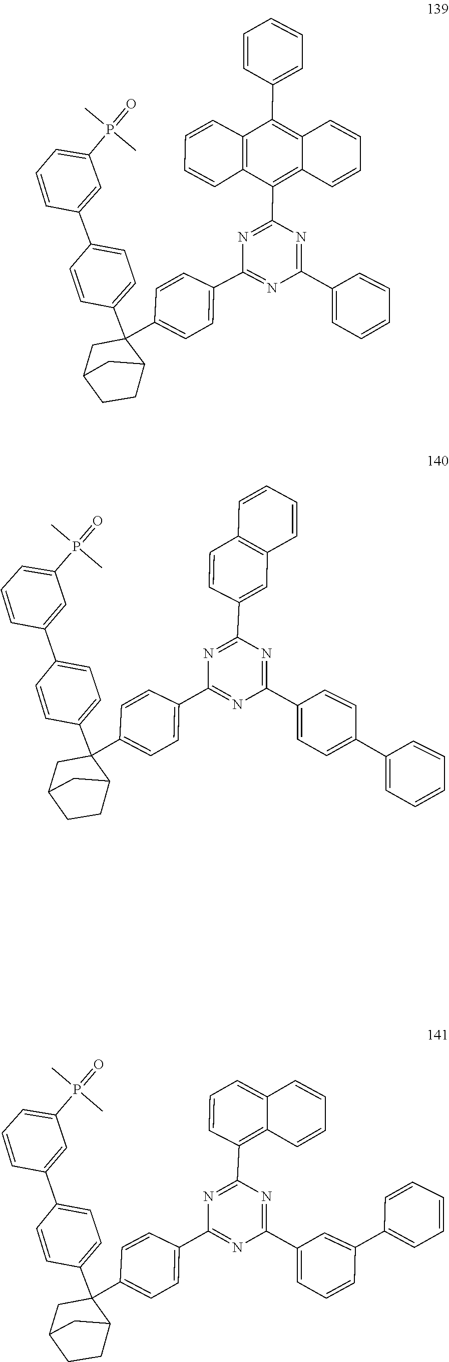 [SMILES: CP(C)(=O)c1cccc(-c2ccc(C3(c4ccc(-c5nc(-c6ccccc6)nc(-c6c7ccccc7c(-c7ccccc7)c7ccccc67)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccc7ccccc7c6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc7ccccc67)n5)cc4)CC4CCC3C4)cc2)c1]

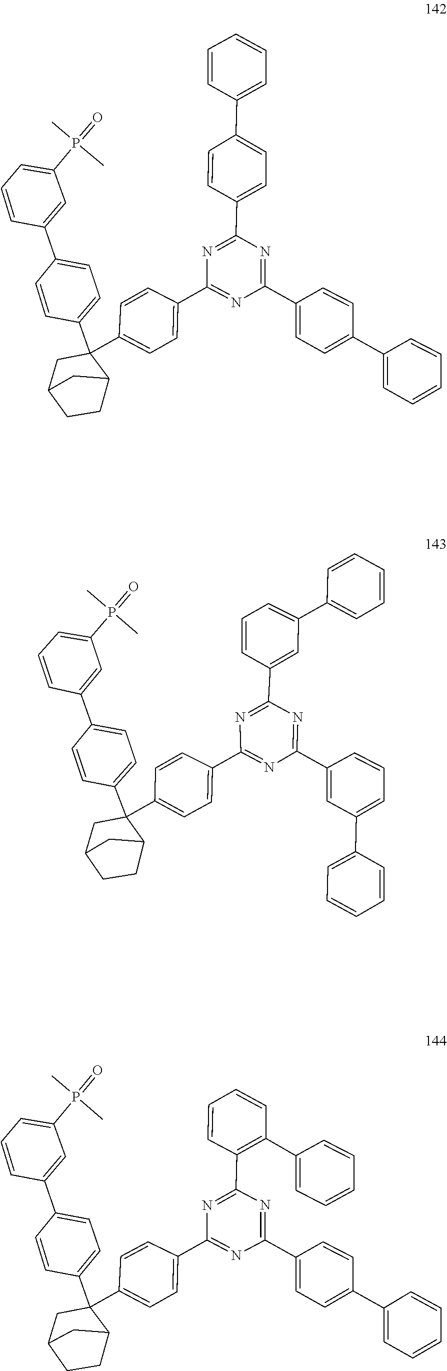 [SMILES: CP(C)(=O)c1cccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c1 ; CP(C)(=O)c1cccc(-c2ccc(C3(c4ccc(-c5nc(-c6cccc(-c7ccccc7)c6)nc(-c6cccc(-c7ccccc7)c6)n5)cc4)CC4CCC3C4)cc2)c1 ; CP(C)(=O)c1cccc(-c2ccc(C3(c4ccc(-c5nc(-c6ccc(-c7ccccc7)cc6)nc(-c6ccccc6-c6ccccc6)n5)cc4)CC4CCC3C4)cc2)c1]

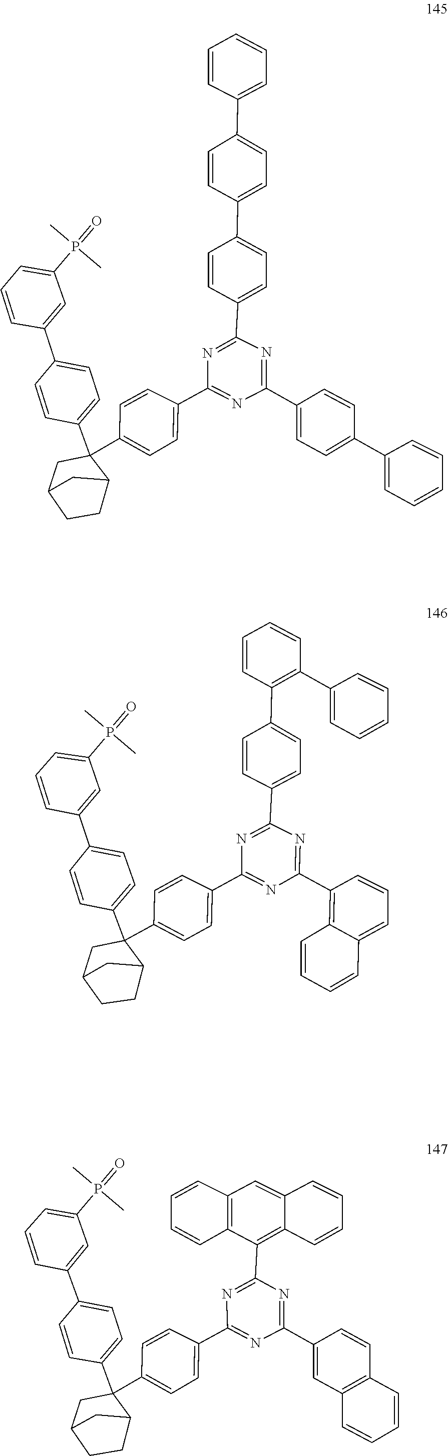 [SMILES: CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c1 ; CP(C)(=O)c1cccc(-c2ccc(C3(c4ccc(-c5nc(-c6ccc(-c7ccccc7-c7ccccc7)cc6)nc(-c6cccc7ccccc67)n5)cc4)CC4CCC3C4)cc2)c1 ; CP(C)(=O)c1cccc(-c2ccc(C3(c4ccc(-c5nc(-c6ccc7ccccc7c6)nc(-c6c7ccccc7cc7ccccc67)n5)cc4)CC4CCC3C4)cc2)c1]

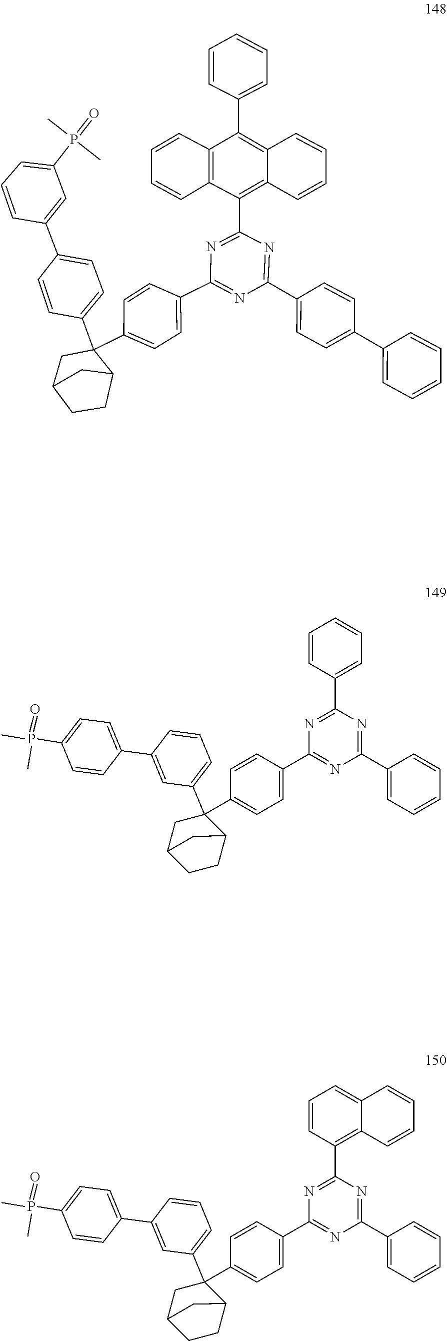 [SMILES: CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)CC4CCC3C4)cc2)c1 ; CP(C)(=O)c1ccc(-c2cccc(C3(c4ccc(-c5nc(-c6ccccc6)nc(-c6ccccc6)n5)cc4)CC4CCC3C4)c2)cc1 ; CP(C)(=O)c1ccc(-c2cccc(C3(c4ccc(-c5nc(-c6ccccc6)nc(-c6cccc7ccccc67)n5)cc4)CC4CCC3C4)c2)cc1]

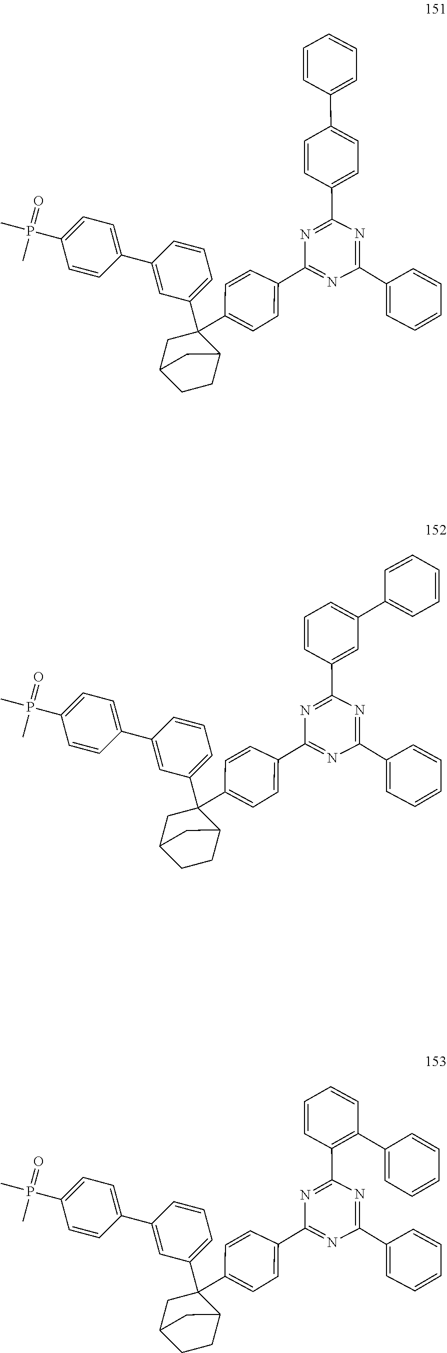 [SMILES: CP(C)(=O)c1ccc(-c2cccc(C3(c4ccc(-c5nc(-c6ccccc6)nc(-c6ccc(-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccccc6)nc(-c6ccccc6-c6ccccc6)n5)cc4)CC4CCC3C4)c2)cc1]

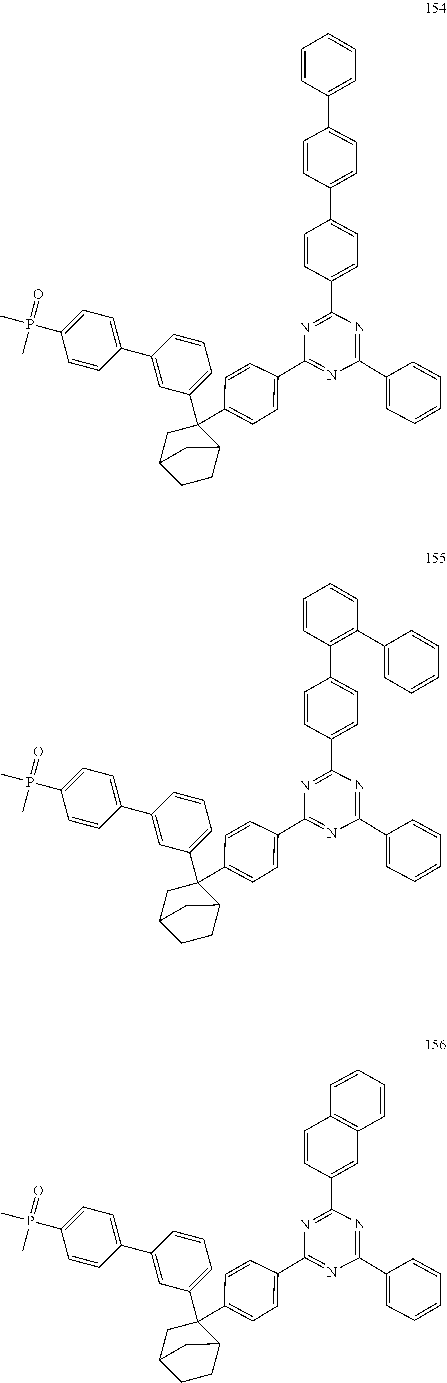 [SMILES: CP(C)(=O)c1ccc(-c2cccc(C3(c4ccc(-c5nc(-c6ccccc6)nc(-c6ccc(-c7ccc(-c8ccccc8)cc7)cc6)n5)cc4)CC4CCC3C4)c2)cc1 ; CP(C)(=O)c1ccc(-c2cccc(C3(c4ccc(-c5nc(-c6ccccc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6ccc7ccccc7c6)n5)cc4)CC4CCC3C4)c2)cc1]

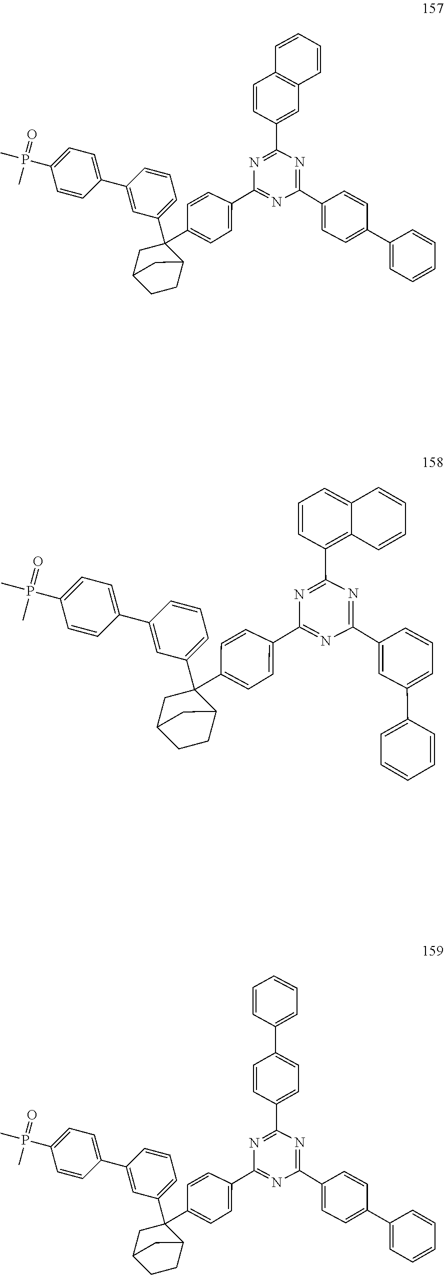 [SMILES: CP(C)(=O)c1ccc(-c2cccc(C3(c4ccc(-c5nc(-c6ccc(-c7ccccc7)cc6)nc(-c6ccc7ccccc7c6)n5)cc4)CC4CCC3C4)c2)cc1 ; CP(C)(=O)c1ccc(-c2cccc(C3(c4ccc(-c5nc(-c6cccc(-c7ccccc7)c6)nc(-c6cccc7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)CC4CCC3C4)c2)cc1]

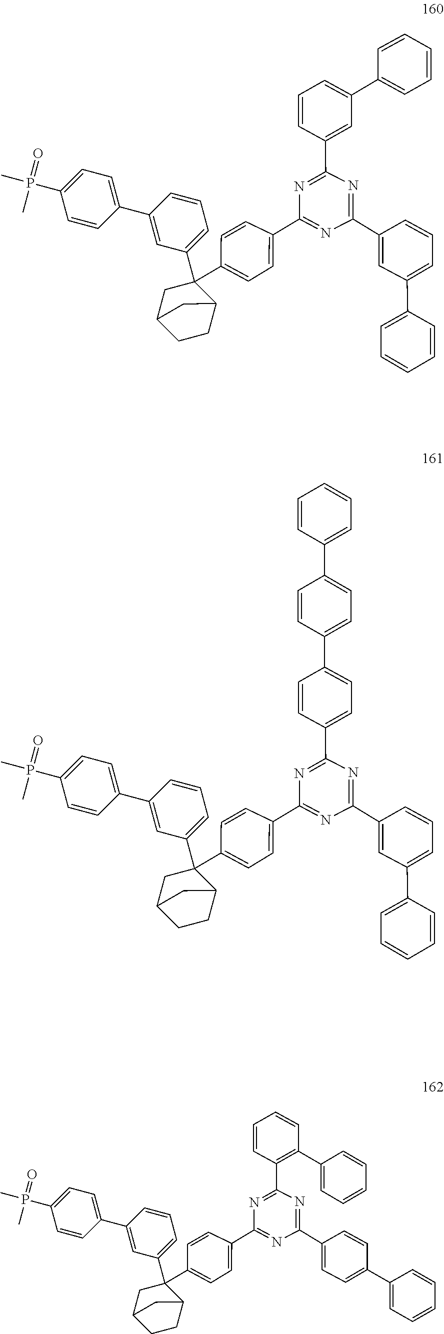 [SMILES: CP(C)(=O)c1ccc(-c2cccc(C3(c4ccc(-c5nc(-c6cccc(-c7ccccc7)c6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)CC4CCC3C4)c2)cc1]

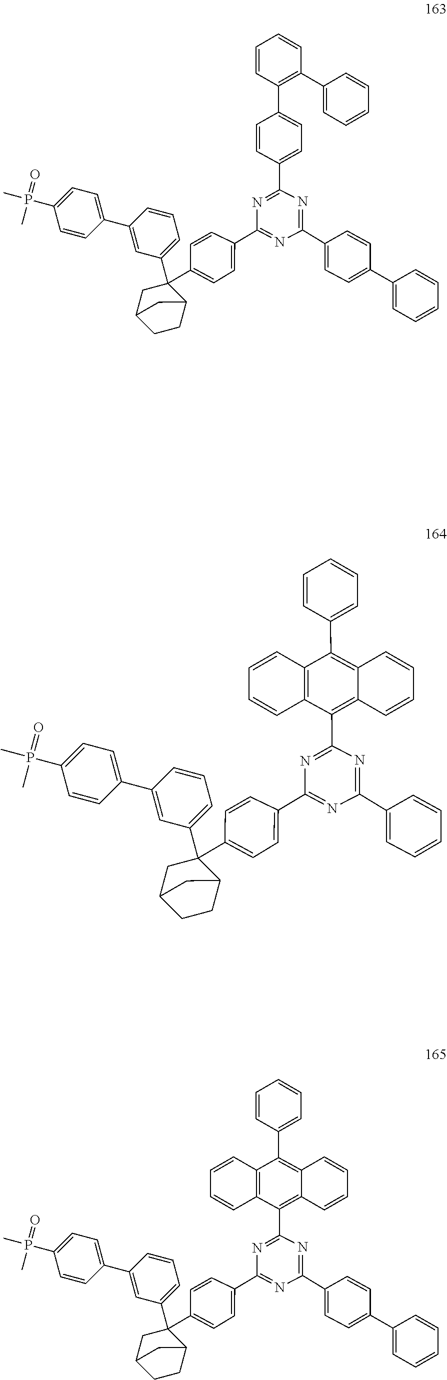 [SMILES: CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)CC4CCC3C4)c2)cc1 ; CP(C)(=O)c1ccc(-c2cccc(C3(c4ccc(-c5nc(-c6ccccc6)nc(-c6c7ccccc7c(-c7ccccc7)c7ccccc67)n5)cc4)CC4CCC3C4)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)CC4CCC3C4)c2)cc1]

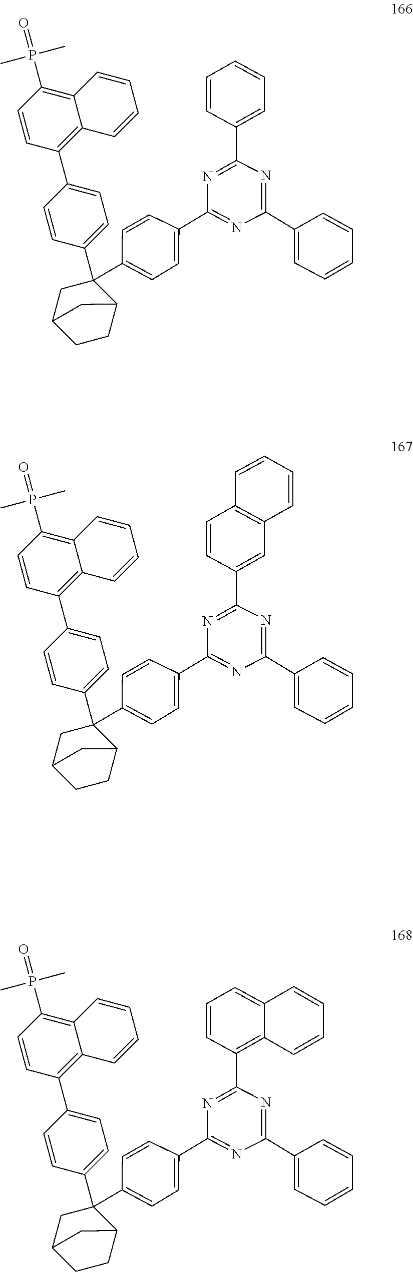 [SMILES: CP(C)(=O)c1ccc(-c2ccc(C3(c4ccc(-c5nc(-c6ccccc6)nc(-c6ccccc6)n5)cc4)CC4CCC3C4)cc2)c2ccccc12 ; CP(C)(=O)c1ccc(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6ccccc6)nc(-c6cccc7ccccc67)n5)cc4)CC4CCC3C4)cc2)c2ccccc12]

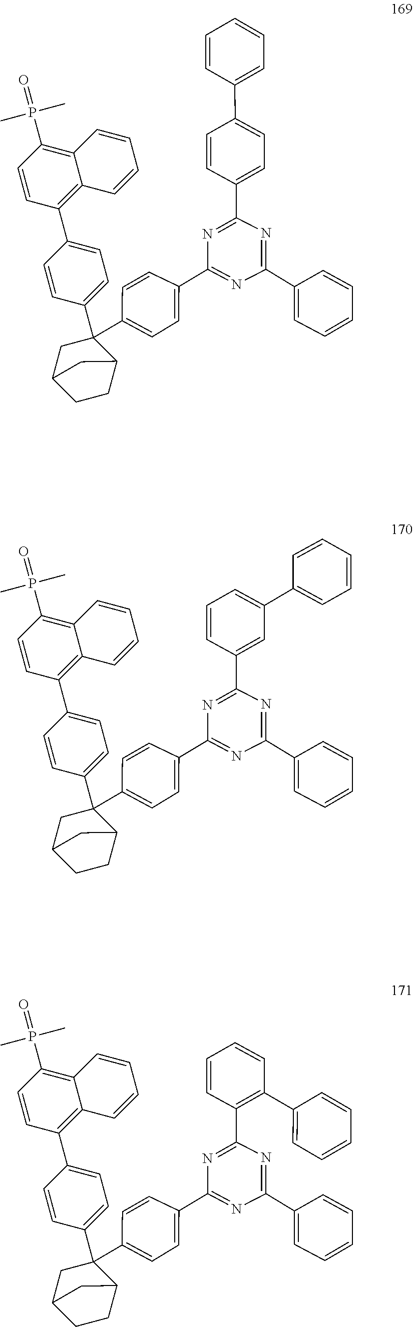 [SMILES: CP(C)(=O)c1ccc(-c2ccc(C3(c4ccc(-c5nc(-c6ccccc6)nc(-c6ccc(-c7ccccc7)cc6)n5)cc4)CC4CCC3C4)cc2)c2ccccc12 ; CP(C)(=O)c1ccc(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccccc6)nc(-c6ccccc6-c6ccccc6)n5)cc4)CC4CCC3C4)cc2)c2ccccc12]

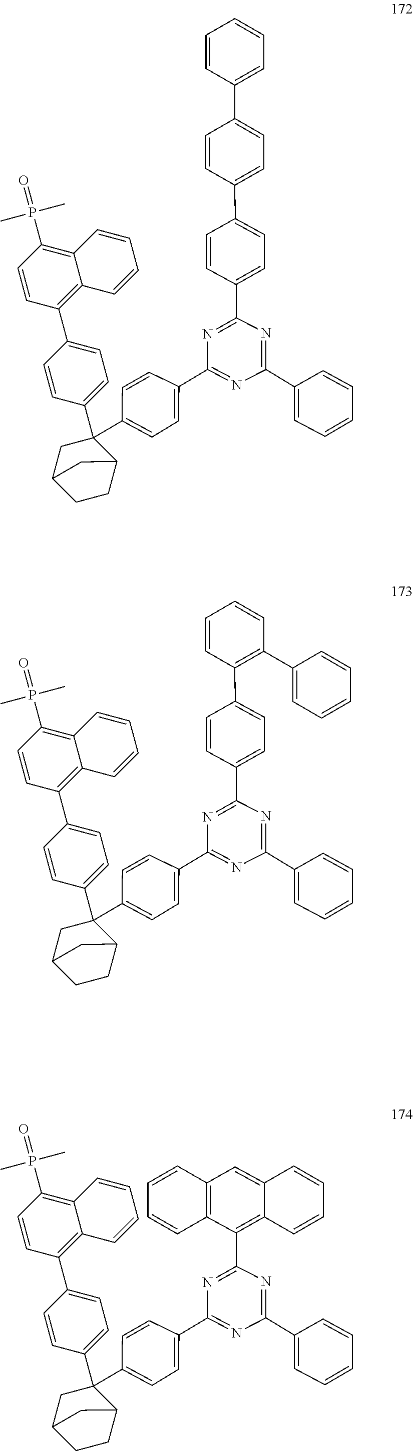 [SMILES: CP(C)(=O)c1ccc(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12 ; CP(C)(=O)c1ccc(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1ccc(-c2ccc(C3(c4ccc(-c5nc(-c6ccccc6)nc(-c6c7ccccc7cc7ccccc67)n5)cc4)CC4CCC3C4)cc2)c2ccccc12]

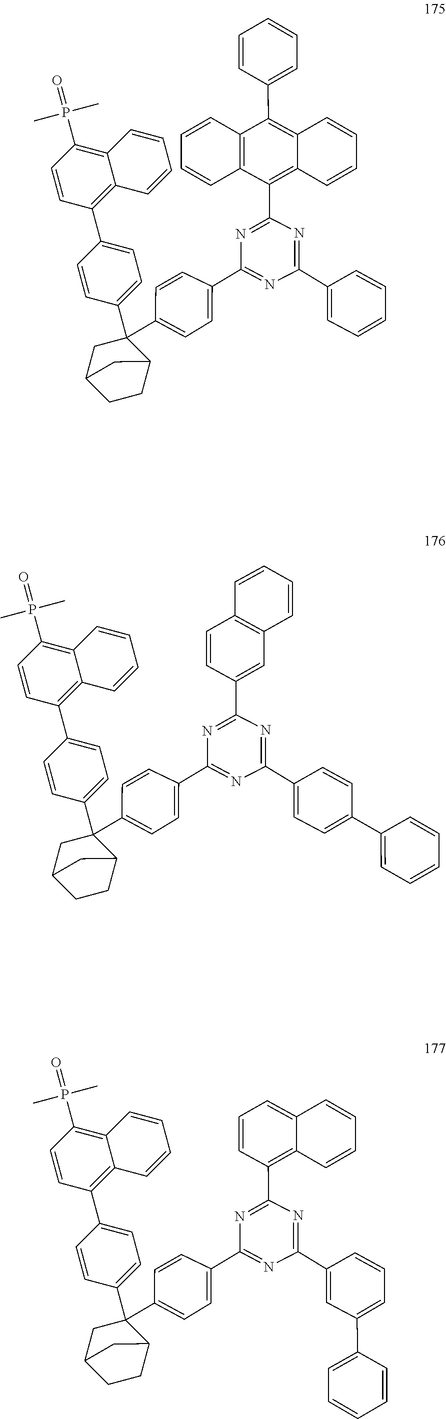 [SMILES: CP(C)(=O)c1ccc(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1ccc(-c2ccc(C3(c4ccc(-c5nc(-c6cccc(-c7ccccc7)c6)nc(-c6cccc7ccccc67)n5)cc4)CC4CCC3C4)cc2)c2ccccc12]

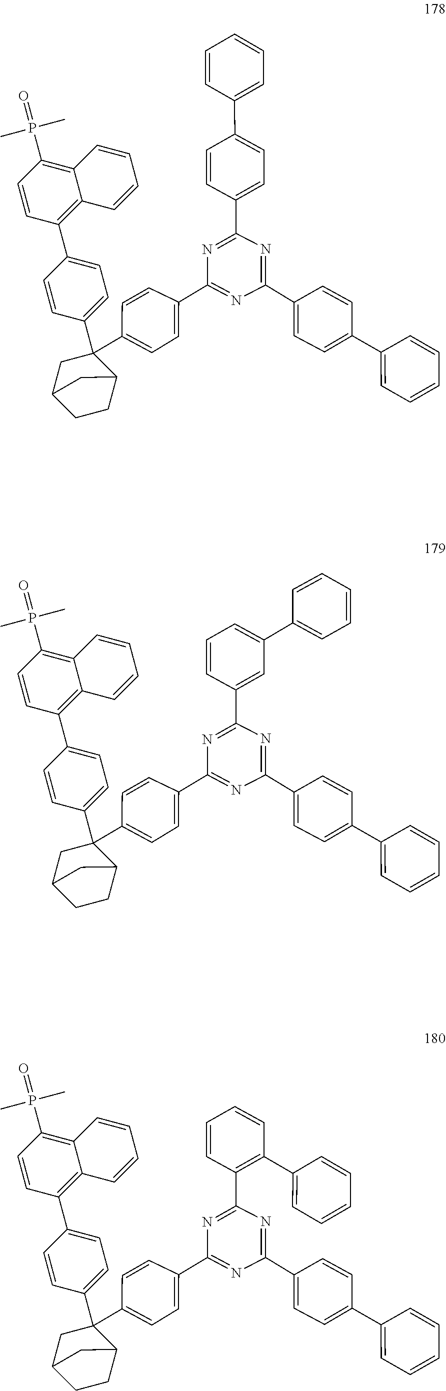 [SMILES: CP(C)(=O)c1ccc(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12]

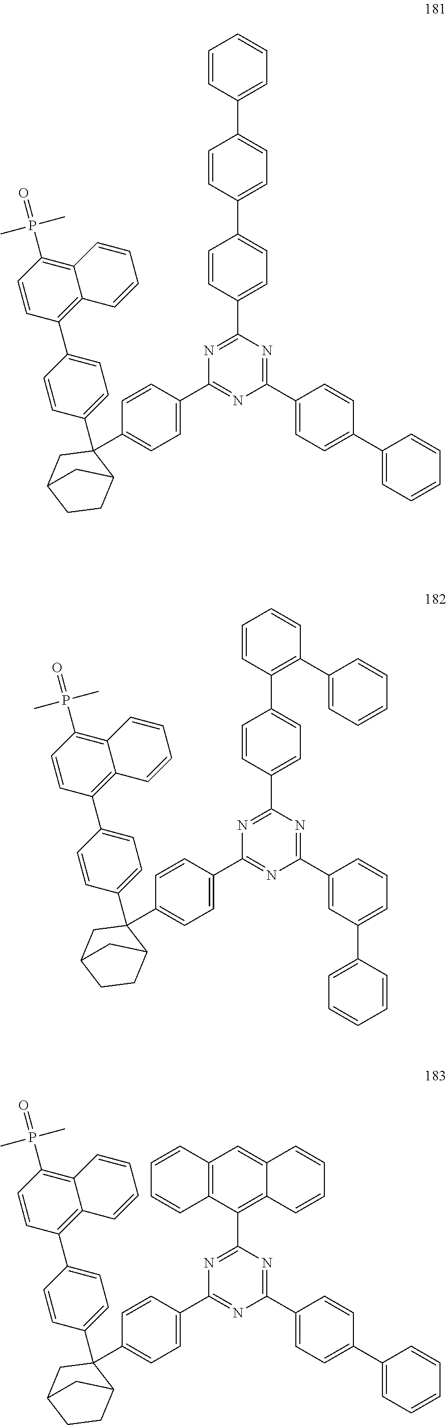 [SMILES: CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1ccc(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12]

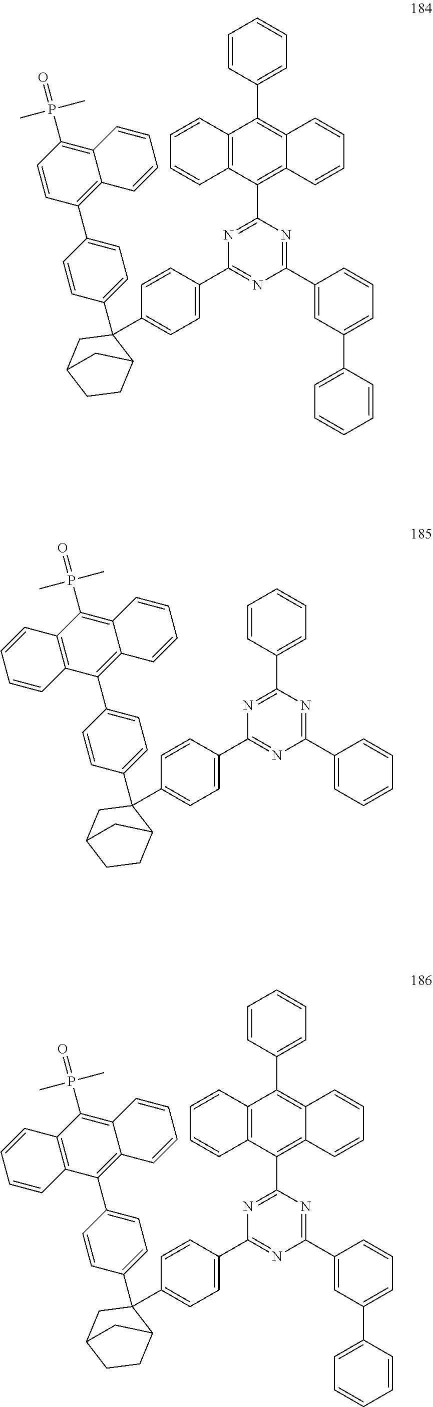 [SMILES: CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CC4CCC3C4)cc2)c2ccccc12]

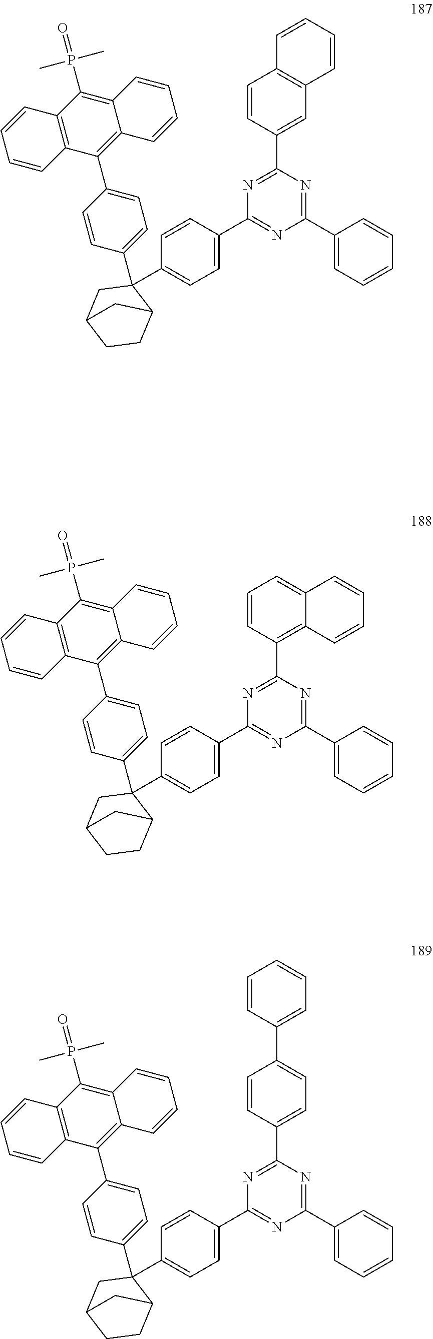 [SMILES: CP(C)(=O)c1c2ccccc2c(-c2ccc(C3(c4ccc(-c5nc(-c6ccccc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccccc7)cc6)n5)cc4)CC4CCC3C4)cc2)c2ccccc12]

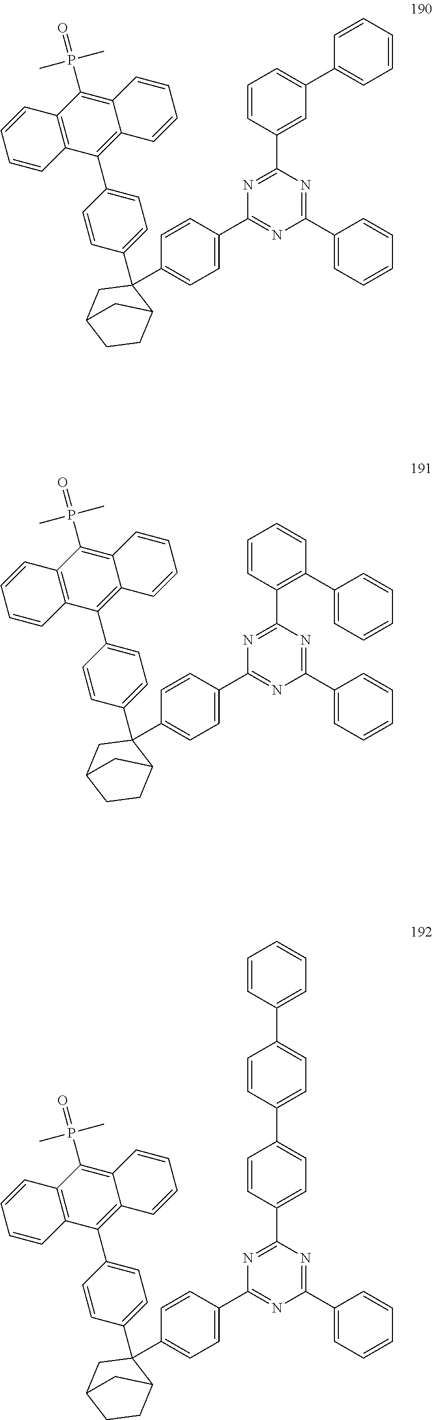 [SMILES: CP(C)(=O)c1c2ccccc2c(-c2ccc(C3(c4ccc(-c5nc(-c6ccccc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6ccc(-c7ccc(-c8ccccc8)cc7)cc6)n5)cc4)CC4CCC3C4)cc2)c2ccccc12]

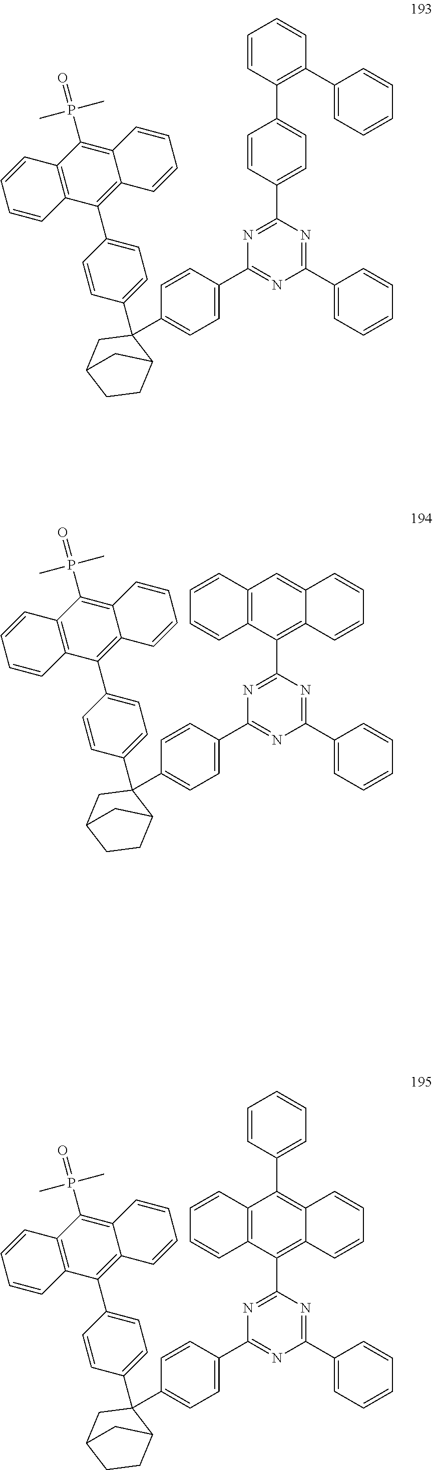 [SMILES: CP(C)(=O)c1c2ccccc2c(-c2ccc(C3(c4ccc(-c5nc(-c6ccccc6)nc(-c6ccc(-c7ccccc7-c7ccccc7)cc6)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7cc7ccccc67)n5)cc4)CC4CCC3C4)cc2)c2ccccc12 ; CP(C)(=O)c1c2ccccc2c(-c2ccc(C3(c4ccc(-c5nc(-c6ccccc6)nc(-c6c7ccccc7c(-c7ccccc7)c7ccccc67)n5)cc4)CC4CCC3C4)cc2)c2ccccc12]

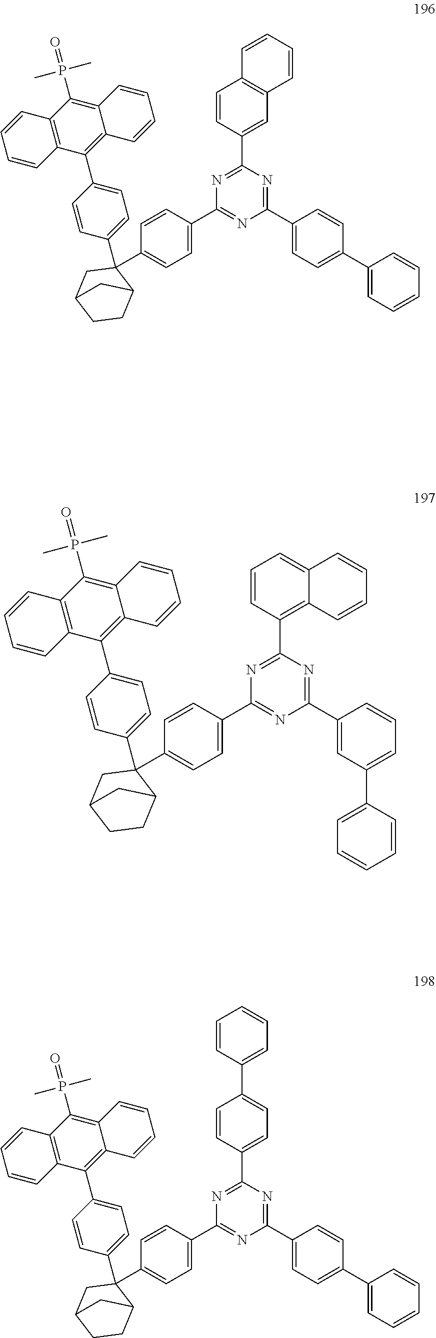 [SMILES: CP(C)(=O)c1c2ccccc2c(-c2ccc(C3(c4ccc(-c5nc(-c6ccc(-c7ccccc7)cc6)nc(-c6ccc7ccccc7c6)n5)cc4)CC4CCC3C4)cc2)c2ccccc12 ; CP(C)(=O)c1c2ccccc2c(-c2ccc(C3(c4ccc(-c5nc(-c6cccc(-c7ccccc7)c6)nc(-c6cccc7ccccc67)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccccc7)cc6)n5)cc4)CC4CCC3C4)cc2)c2ccccc12]

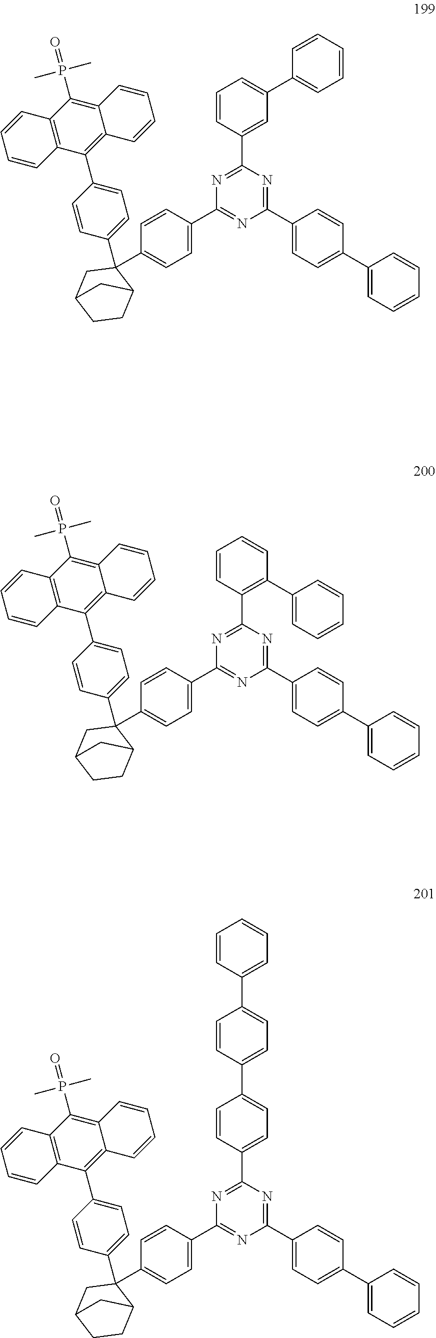 [SMILES: CP(C)(=O)c1c2ccccc2c(-c2ccc(C3(c4ccc(-c5nc(-c6ccc(-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccccc6-c6ccccc6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CC4CCC3C4)cc2)c2ccccc12]

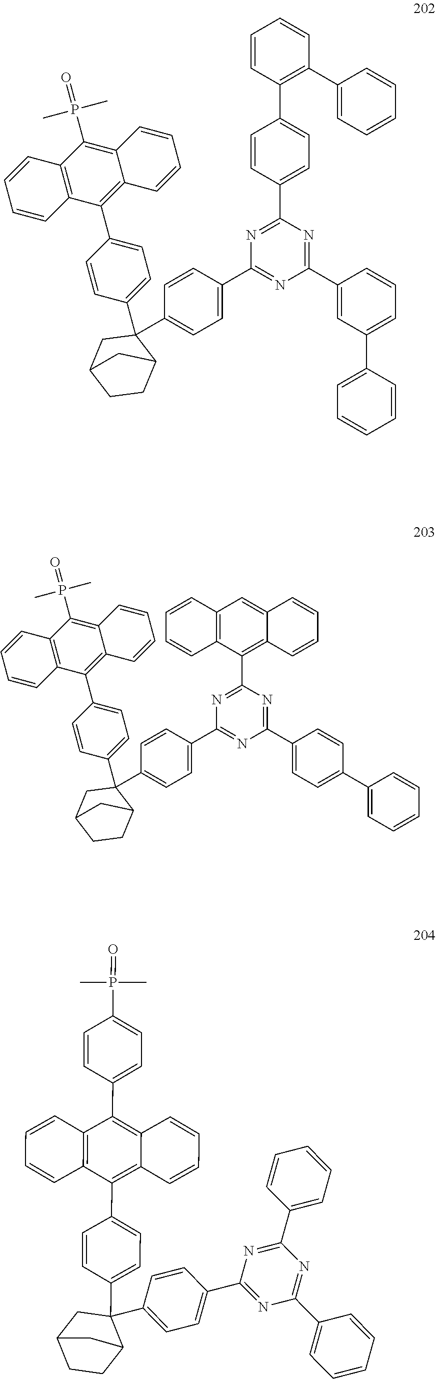 [SMILES: CP(C)(=O)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CC4CCC3C4)cc2)c2ccccc12 ; CP(C)(=O)c1c2ccccc2c(-c2ccc(C3(c4ccc(-c5nc(-c6ccc(-c7ccccc7)cc6)nc(-c6c7ccccc7cc7ccccc67)n5)cc4)CC4CCC3C4)cc2)c2ccccc12 ; CP(C)(=O)c1ccc(-c2c3ccccc3c(-c3ccc(C4(c5ccc(-c6nc(-c7ccccc7)nc(-c7ccccc7)n6)cc5)CC5CCC4C5)cc3)c3ccccc23)cc1]

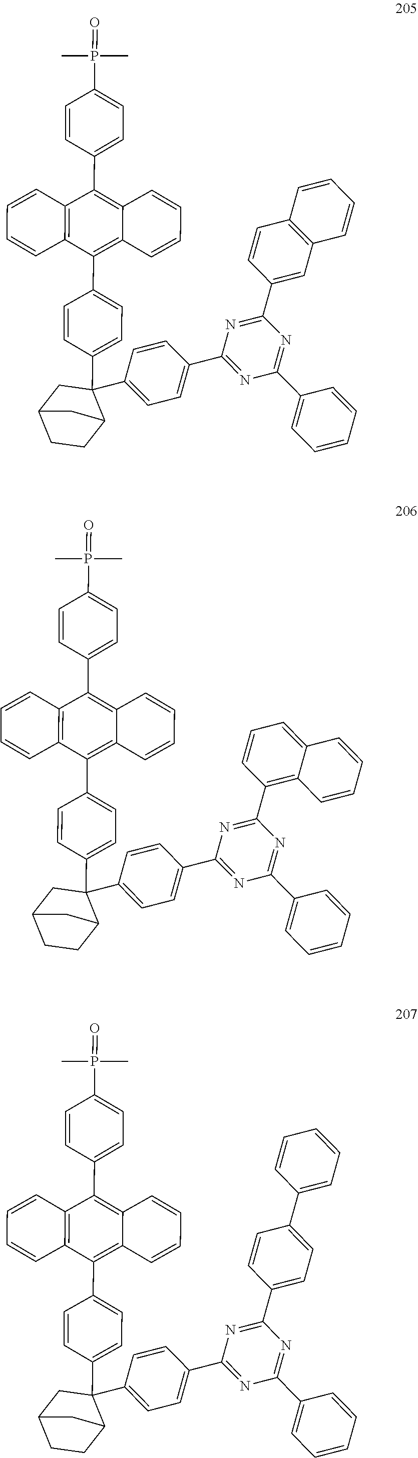 [SMILES: CP(C)(=O)c1ccc(-c2c3ccccc3c(-c3ccc(C4(c5ccc(-c6nc(-c7ccccc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7cccc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccccc8)cc7)n6)cc5)CC5CCC4C5)cc3)c3ccccc23)cc1]

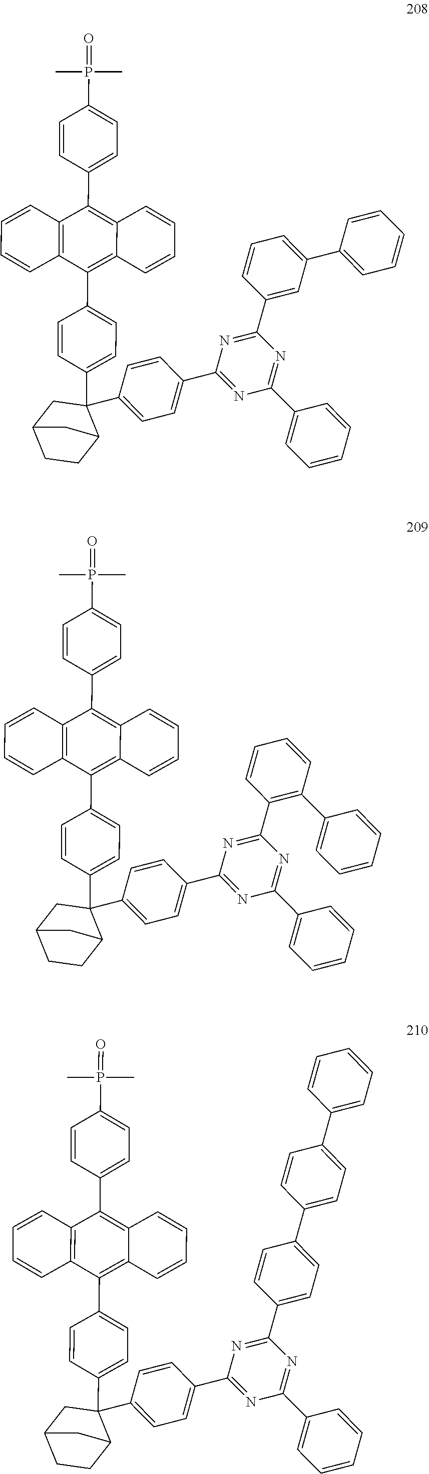 [SMILES: CP(C)(=O)c1ccc(-c2c3ccccc3c(-c3ccc(C4(c5ccc(-c6nc(-c7ccccc7)nc(-c7cccc(-c8ccccc8)c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccccc7-c7ccccc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CC5CCC4C5)cc3)c3ccccc23)cc1]

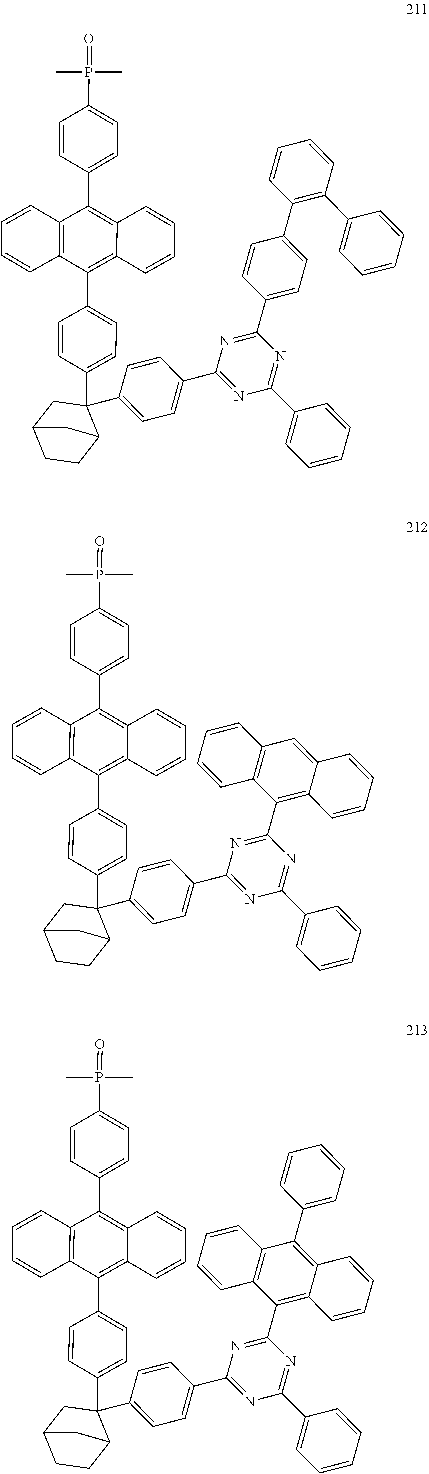 [SMILES: CP(C)(=O)c1ccc(-c2c3ccccc3c(-c3ccc(C4(c5ccc(-c6nc(-c7ccccc7)nc(-c7ccc(-c8ccccc8-c8ccccc8)cc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8cc8ccccc78)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CC5CCC4C5)cc3)c3ccccc23)cc1]

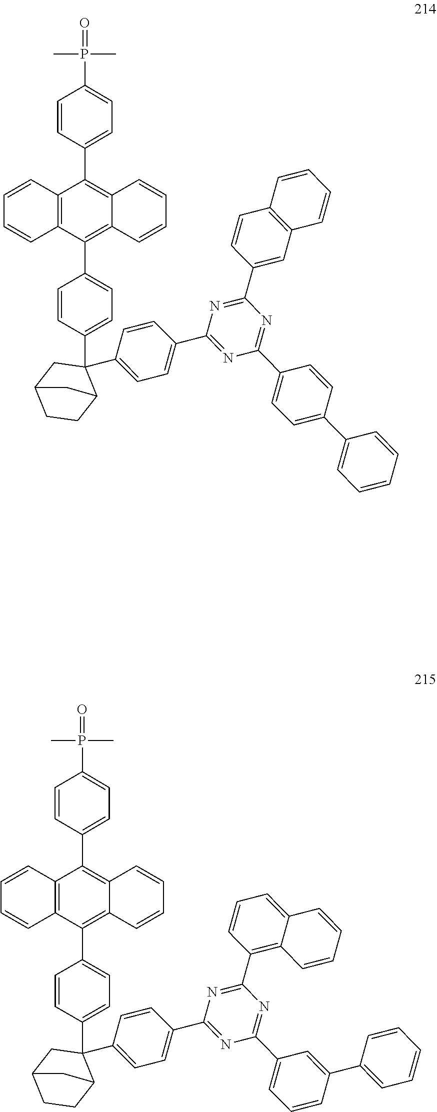 [SMILES: CP(C)(=O)c1ccc(-c2c3ccccc3c(-c3ccc(C4(c5ccc(-c6nc(-c7ccc(-c8ccccc8)cc7)nc(-c7ccc8ccccc8c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7cccc(-c8ccccc8)c7)nc(-c7cccc8ccccc78)n6)cc5)CC5CCC4C5)cc3)c3ccccc23)cc1]

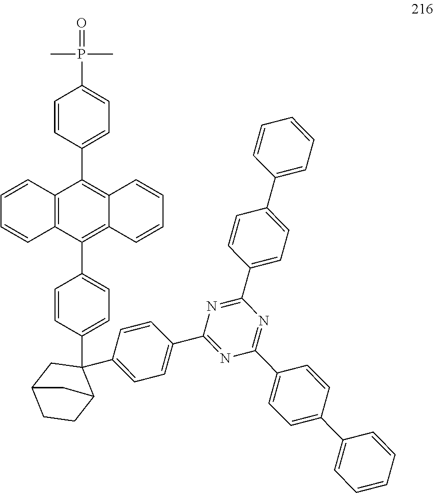 [SMILES: CP(C)(=O)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CC5CCC4C5)cc3)c3ccccc23)cc1]

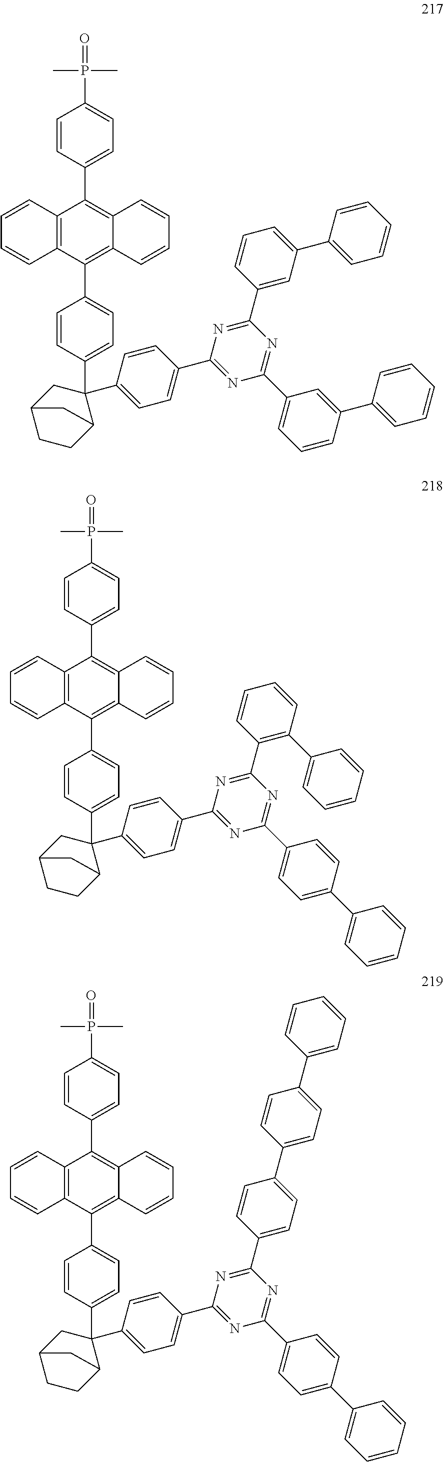 [SMILES: CP(C)(=O)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccccc7-c7ccccc7)n6)cc5)CC5CCC4C5)cc3)c3ccccc23)cc1 ; CP(C)(=O)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CC5CCC4C5)cc3)c3ccccc23)cc1]

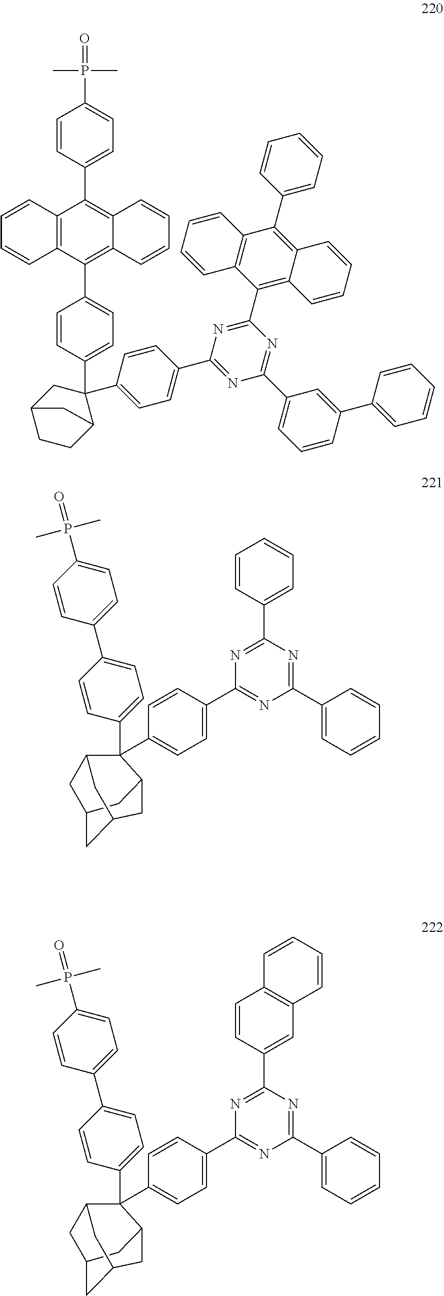 [SMILES: CP(C)(=O)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CC5CCC4C5)cc3)c3ccccc23)cc1 ; CP(C)(=O)c1ccc(-c2ccc(C3(c4ccc(-c5nc(-c6ccccc6)nc(-c6ccccc6)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc7ccccc7c6)n5)cc4)C4CC5CC(C4)CC3C5)cc2)cc1]

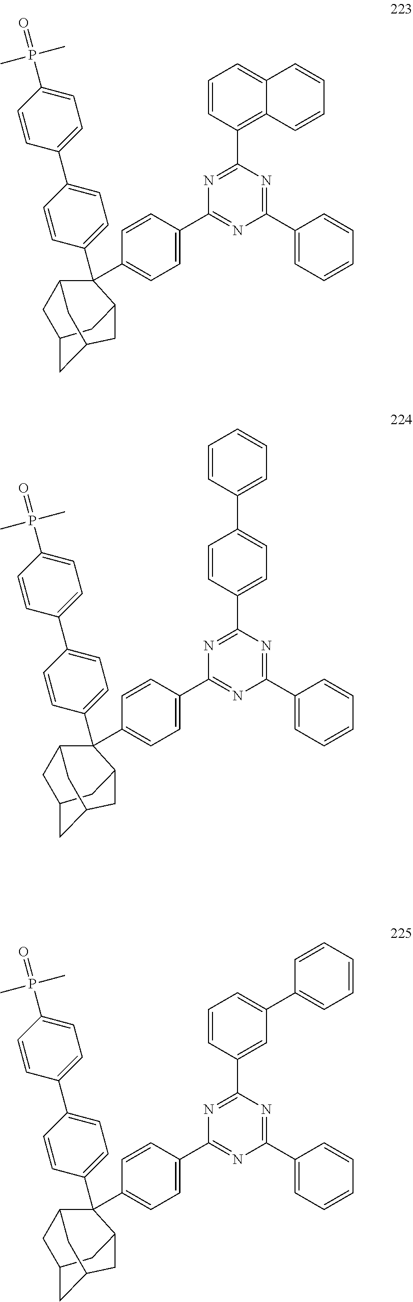 [SMILES: CP(C)(=O)c1ccc(-c2ccc(C3(c4ccc(-c5nc(-c6ccccc6)nc(-c6cccc7ccccc67)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc(-c7ccccc7)cc6)n5)cc4)C4CC5CC(C4)CC3C5)cc2)cc1 ; CP(C)(=O)c1ccc(-c2ccc(C3(c4ccc(-c5nc(-c6ccccc6)nc(-c6cccc(-c7ccccc7)c6)n5)cc4)C4CC5CC(C4)CC3C5)cc2)cc1]

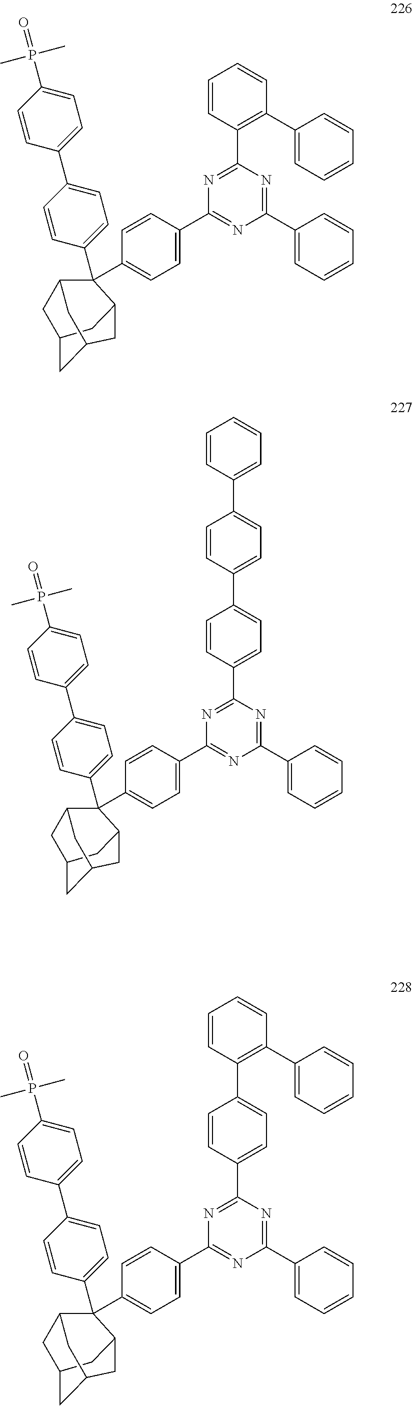 [SMILES: CP(C)(=O)c1ccc(-c2ccc(C3(c4ccc(-c5nc(-c6ccccc6)nc(-c6ccccc6-c6ccccc6)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)cc1 ; CP(C)(=O)c1ccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)cc1]

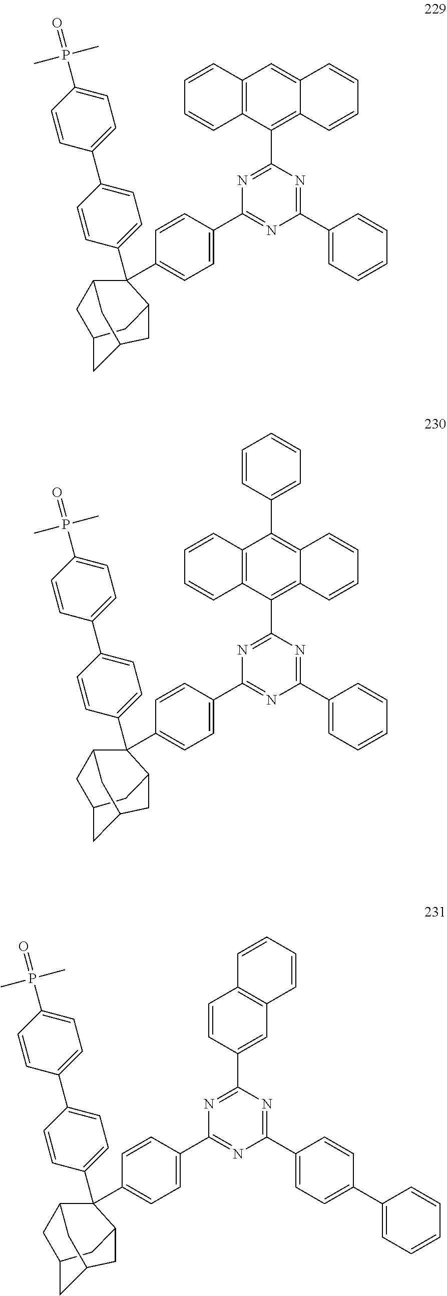 [SMILES: CP(C)(=O)c1ccc(-c2ccc(C3(c4ccc(-c5nc(-c6ccccc6)nc(-c6c7ccccc7cc7ccccc67)n5)cc4)C4CC5CC(C4)CC3C5)cc2)cc1 ; CP(C)(=O)c1ccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)cc1]

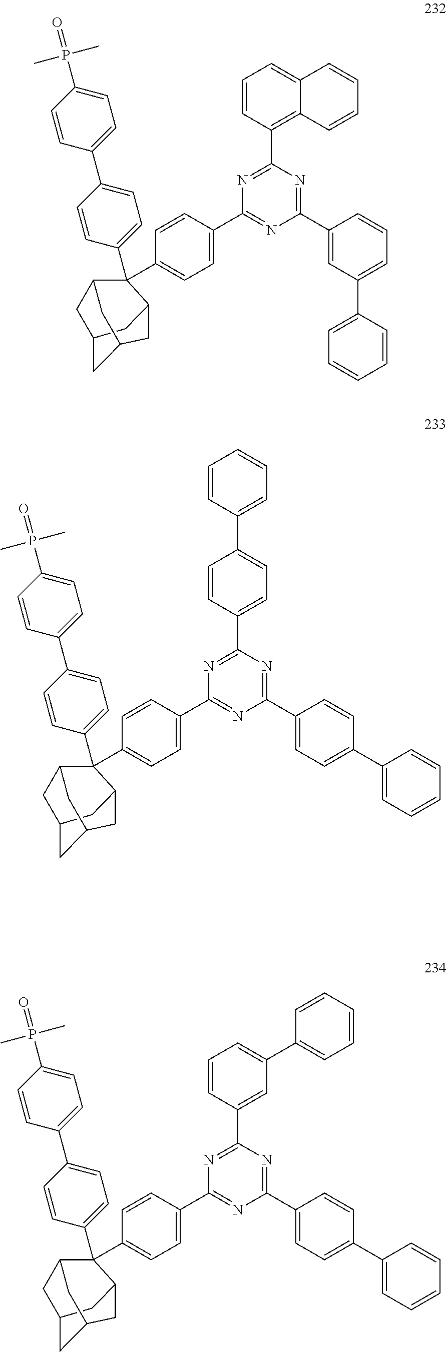 [SMILES: CP(C)(=O)c1ccc(-c2ccc(C3(c4ccc(-c5nc(-c6cccc(-c7ccccc7)c6)nc(-c6cccc7ccccc67)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)cc1]

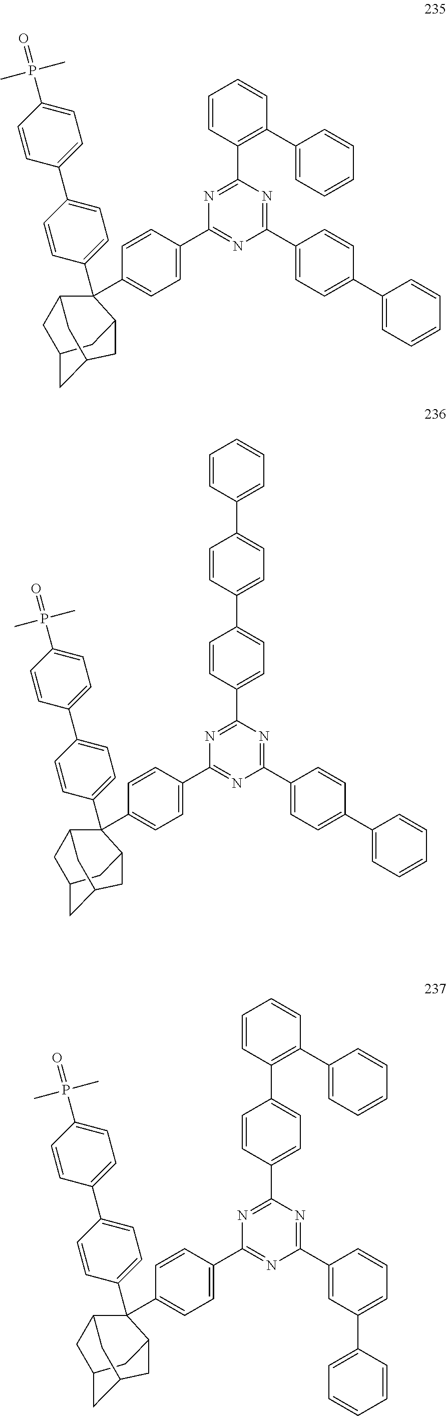 [SMILES: CP(C)(=O)c1ccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)cc1 ; CP(C)(=O)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)cc1 ; CP(C)(=O)c1ccc(-c2ccc(C3(c4ccc(-c5nc(-c6ccc(-c7ccccc7-c7ccccc7)cc6)nc(-c6cccc(-c7ccccc7)c6)n5)cc4)C4CC5CC(C4)CC3C5)cc2)cc1]

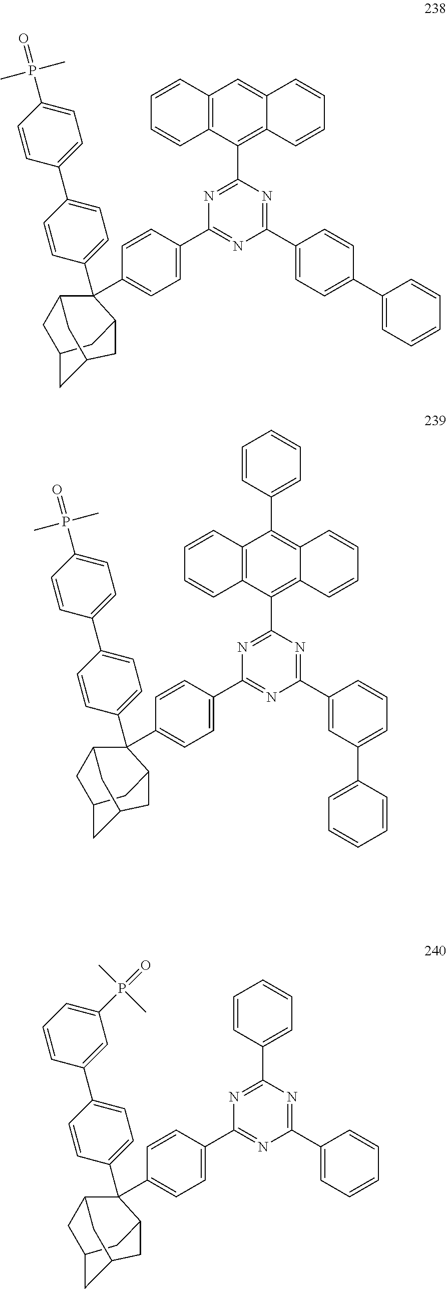 [SMILES: CP(C)(=O)c1ccc(-c2ccc(C3(c4ccc(-c5nc(-c6ccc(-c7ccccc7)cc6)nc(-c6c7ccccc7cc7ccccc67)n5)cc4)C4CC5CC(C4)CC3C5)cc2)cc1 ; CP(C)(=O)c1ccc(-c2ccc(C3(c4ccc(-c5nc(-c6cccc(-c7ccccc7)c6)nc(-c6c7ccccc7c(-c7ccccc7)c7ccccc67)n5)cc4)C4CC5CC(C4)CC3C5)cc2)cc1 ; CP(C)(=O)c1cccc(-c2ccc(C3(c4ccc(-c5nc(-c6ccccc6)nc(-c6ccccc6)n5)cc4)C4CC5CC(C4)CC3C5)cc2)c1]

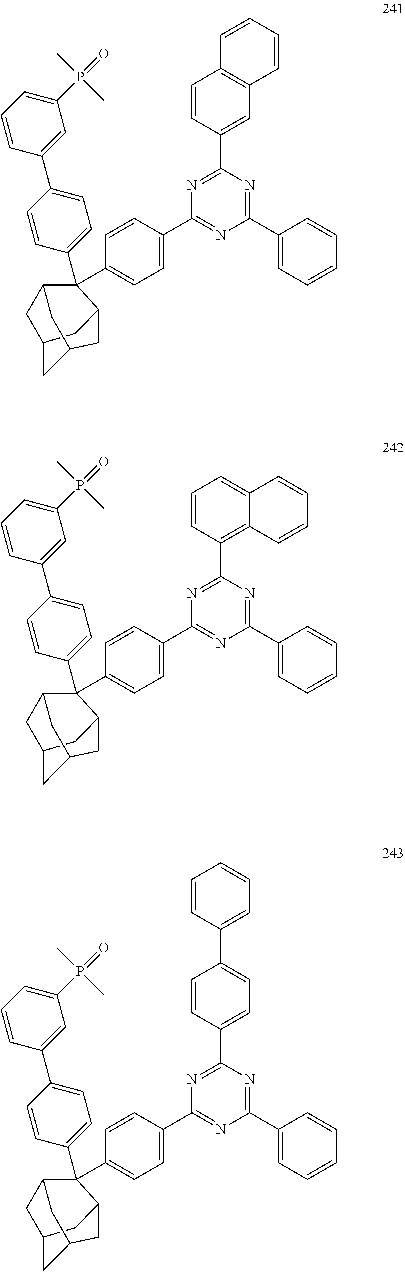 [SMILES: CP(C)(=O)c1cccc(-c2ccc(C3(c4ccc(-c5nc(-c6ccccc6)nc(-c6ccc7ccccc7c6)n5)cc4)C4CC5CC(C4)CC3C5)cc2)c1 ; CP(C)(=O)c1cccc(-c2ccc(C3(c4ccc(-c5nc(-c6ccccc6)nc(-c6cccc7ccccc67)n5)cc4)C4CC5CC(C4)CC3C5)cc2)c1 ; CP(C)(=O)c1cccc(-c2ccc(C3(c4ccc(-c5nc(-c6ccccc6)nc(-c6ccc(-c7ccccc7)cc6)n5)cc4)C4CC5CC(C4)CC3C5)cc2)c1]

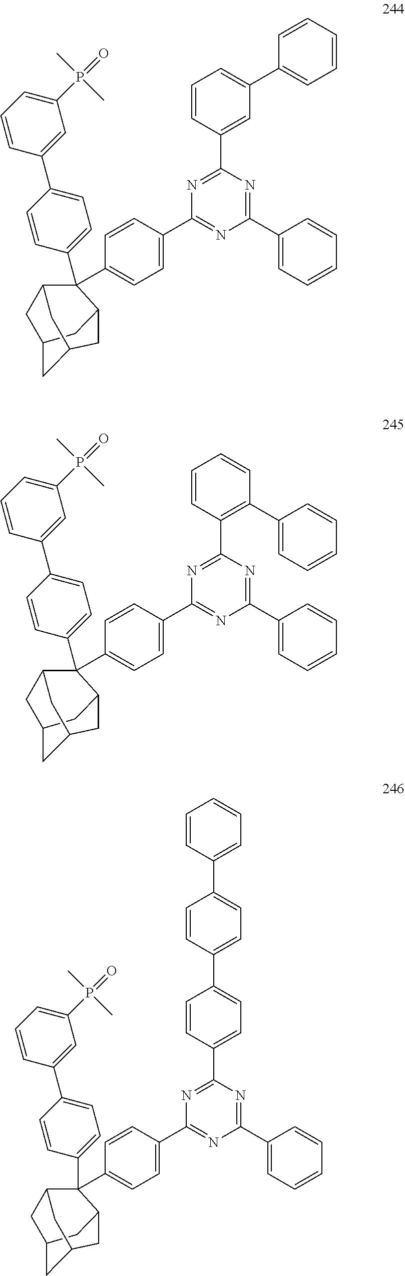 [SMILES: CP(C)(=O)c1cccc(-c2ccc(C3(c4ccc(-c5nc(-c6ccccc6)nc(-c6cccc(-c7ccccc7)c6)n5)cc4)C4CC5CC(C4)CC3C5)cc2)c1 ; CP(C)(=O)c1cccc(-c2ccc(C3(c4ccc(-c5nc(-c6ccccc6)nc(-c6ccccc6-c6ccccc6)n5)cc4)C4CC5CC(C4)CC3C5)cc2)c1 ; CP(C)(=O)c1cccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c1]

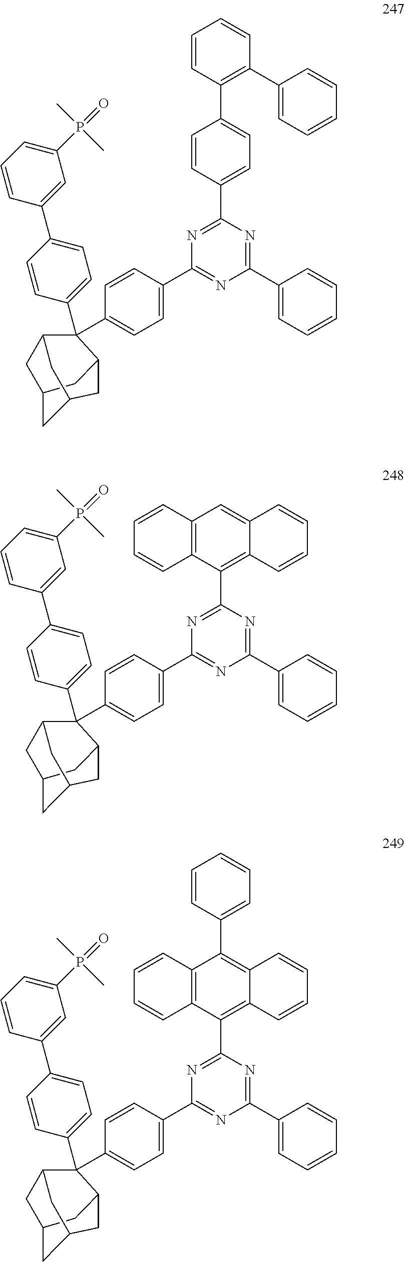 [SMILES: CP(C)(=O)c1cccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c1 ; CP(C)(=O)c1cccc(-c2ccc(C3(c4ccc(-c5nc(-c6ccccc6)nc(-c6c7ccccc7cc7ccccc67)n5)cc4)C4CC5CC(C4)CC3C5)cc2)c1 ; CP(C)(=O)c1cccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c1]

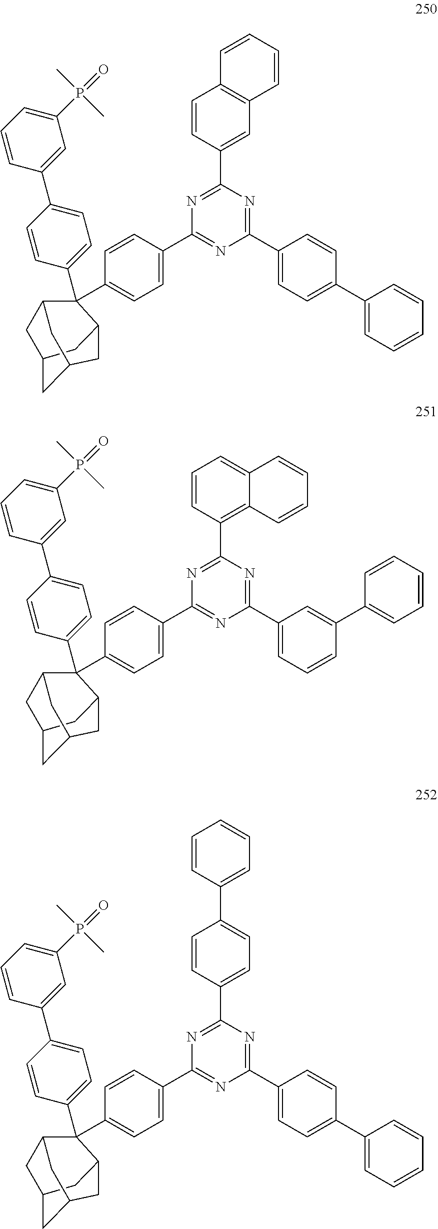 [SMILES: CP(C)(=O)c1cccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c1 ; CP(C)(=O)c1cccc(-c2ccc(C3(c4ccc(-c5nc(-c6cccc(-c7ccccc7)c6)nc(-c6cccc7ccccc67)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c1]

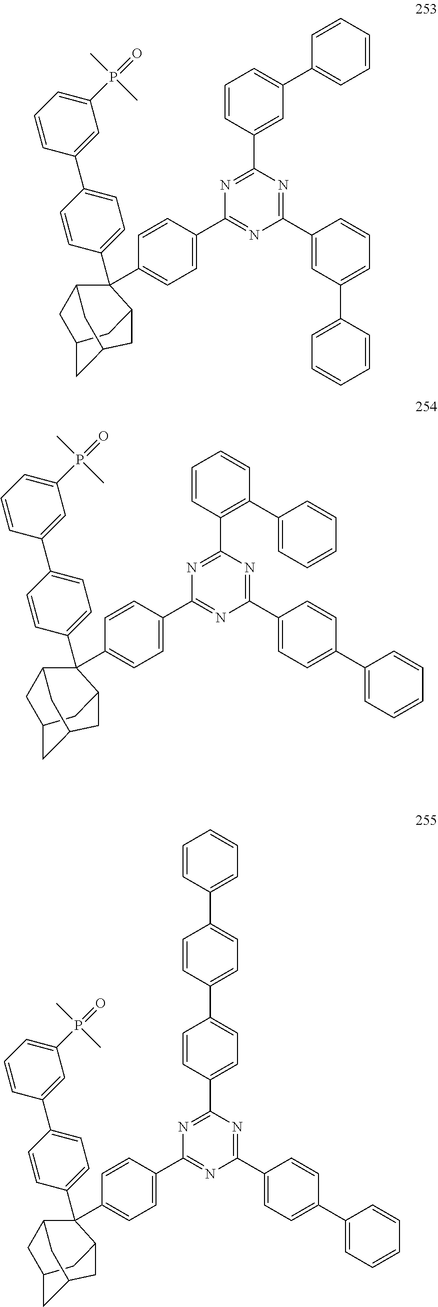 [SMILES: CP(C)(=O)c1cccc(-c2ccc(C3(c4ccc(-c5nc(-c6cccc(-c7ccccc7)c6)nc(-c6cccc(-c7ccccc7)c6)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6ccccc6-c6ccccc6)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6ccc(-c7ccc(-c8ccccc8)cc7)cc6)n5)cc4)C4CC5CC(C4)CC3C5)cc2)c1]

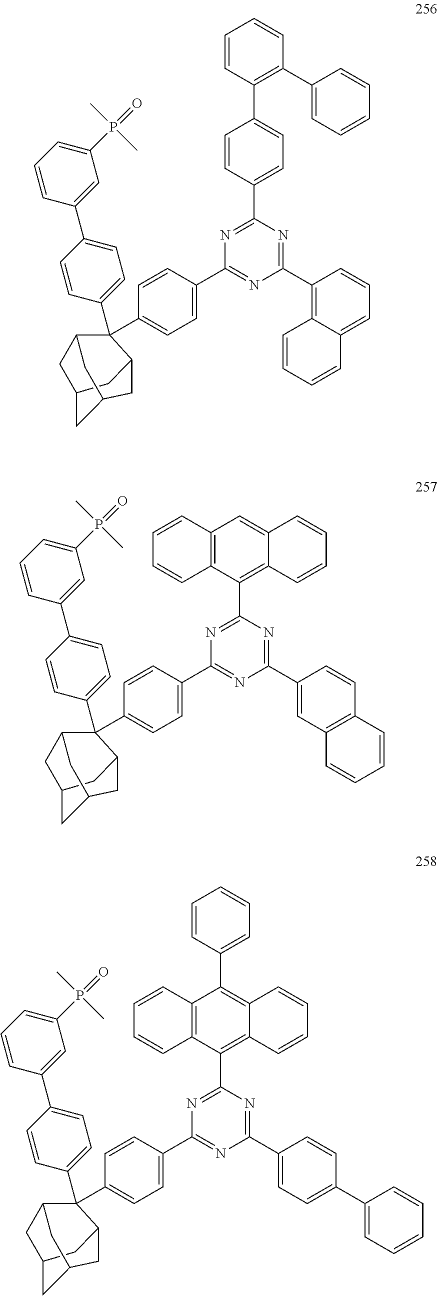 [SMILES: CP(C)(=O)c1cccc(-c2ccc(C3(c4ccc(-c5nc(-c6ccc(-c7ccccc7-c7ccccc7)cc6)nc(-c6cccc7ccccc67)n5)cc4)C4CC5CC(C4)CC3C5)cc2)c1 ; CP(C)(=O)c1cccc(-c2ccc(C3(c4ccc(-c5nc(-c6ccc7ccccc7c6)nc(-c6c7ccccc7cc7ccccc67)n5)cc4)C4CC5CC(C4)CC3C5)cc2)c1 ; CP(C)(=O)c1cccc(-c2ccc(C3(c4ccc(-c5nc(-c6ccc(-c7ccccc7)cc6)nc(-c6c7ccccc7c(-c7ccccc7)c7ccccc67)n5)cc4)C4CC5CC(C4)CC3C5)cc2)c1]

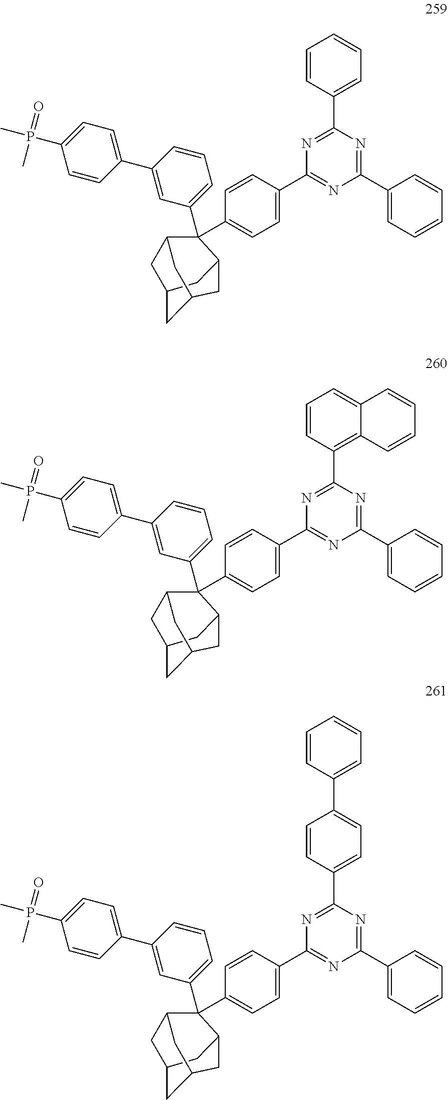 [SMILES: CP(C)(=O)c1ccc(-c2cccc(C3(c4ccc(-c5nc(-c6ccccc6)nc(-c6ccccc6)n5)cc4)C4CC5CC(C4)CC3C5)c2)cc1 ; CP(C)(=O)c1ccc(-c2cccc(C3(c4ccc(-c5nc(-c6ccccc6)nc(-c6cccc7ccccc67)n5)cc4)C4CC5CC(C4)CC3C5)c2)cc1 ; CP(C)(=O)c1ccc(-c2cccc(C3(c4ccc(-c5nc(-c6ccccc6)nc(-c6ccc(-c7ccccc7)cc6)n5)cc4)C4CC5CC(C4)CC3C5)c2)cc1]

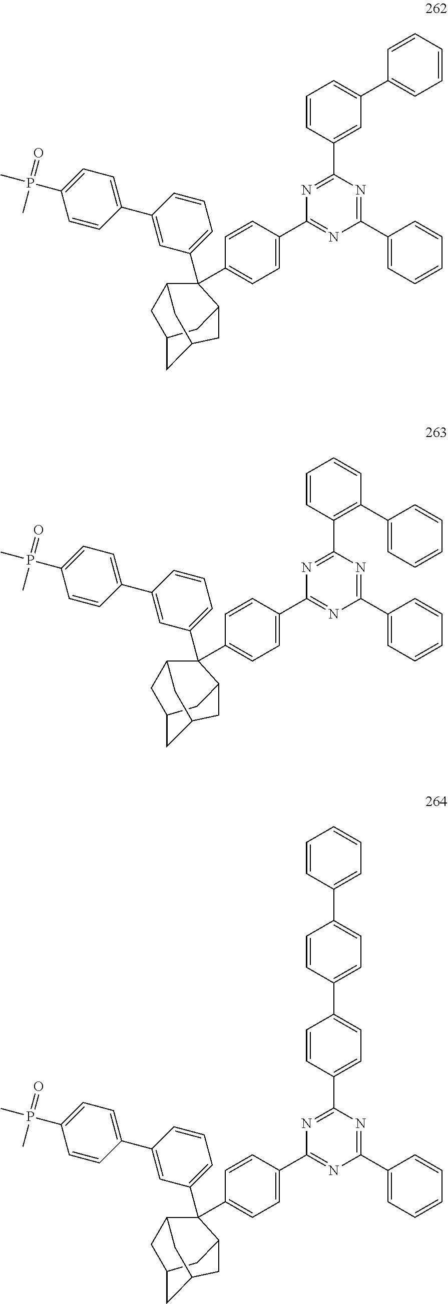 [SMILES: CP(C)(=O)c1ccc(-c2cccc(C3(c4ccc(-c5nc(-c6ccccc6)nc(-c6cccc(-c7ccccc7)c6)n5)cc4)C4CC5CC(C4)CC3C5)c2)cc1 ; CP(C)(=O)c1ccc(-c2cccc(C3(c4ccc(-c5nc(-c6ccccc6)nc(-c6ccccc6-c6ccccc6)n5)cc4)C4CC5CC(C4)CC3C5)c2)cc1 ; CP(C)(=O)c1ccc(-c2cccc(C3(c4ccc(-c5nc(-c6ccccc6)nc(-c6ccc(-c7ccc(-c8ccccc8)cc7)cc6)n5)cc4)C4CC5CC(C4)CC3C5)c2)cc1]

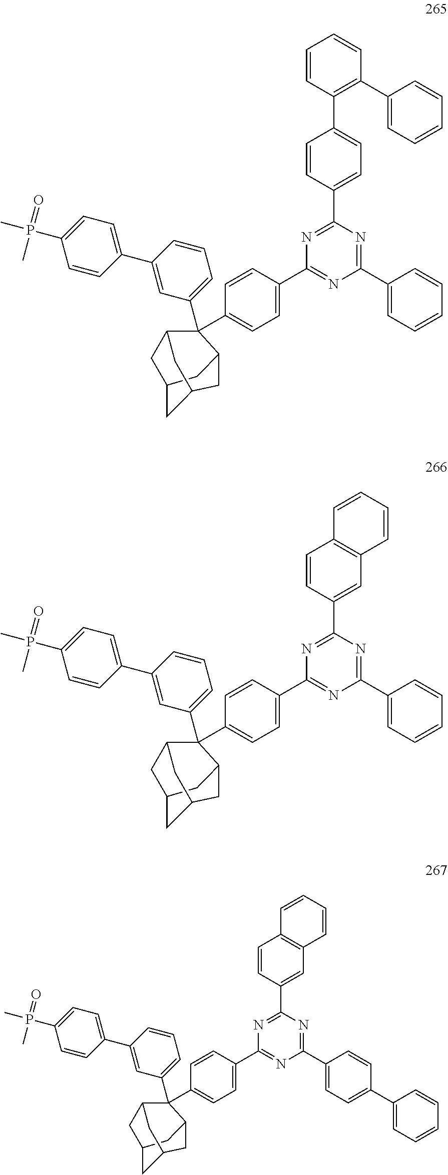 [SMILES: CP(C)(=O)c1ccc(-c2cccc(C3(c4ccc(-c5nc(-c6ccccc6)nc(-c6ccc(-c7ccccc7-c7ccccc7)cc6)n5)cc4)C4CC5CC(C4)CC3C5)c2)cc1 ; CP(C)(=O)c1ccc(-c2cccc(C3(c4ccc(-c5nc(-c6ccccc6)nc(-c6ccc7ccccc7c6)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccc7ccccc7c6)n5)cc4)C4CC5CC(C4)CC3C5)c2)cc1]

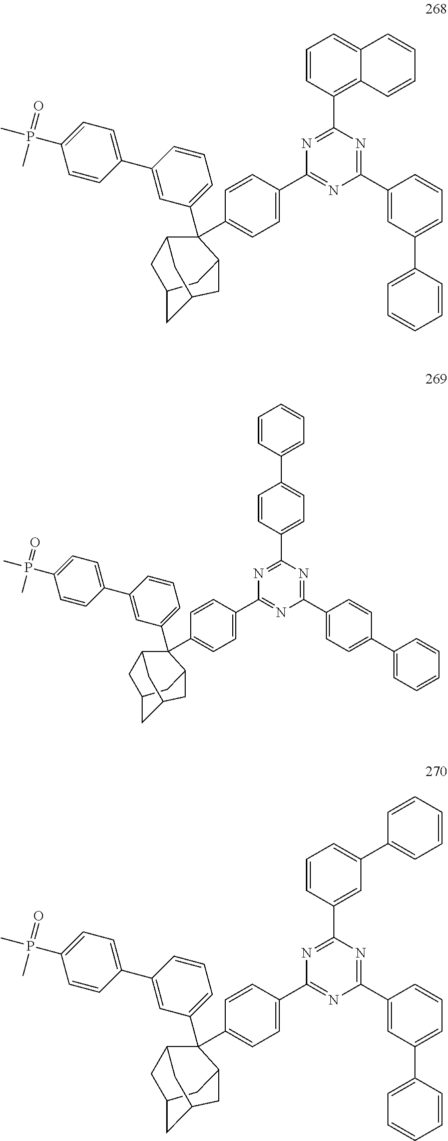 [SMILES: CP(C)(=O)c1ccc(-c2cccc(C3(c4ccc(-c5nc(-c6cccc(-c7ccccc7)c6)nc(-c6cccc7ccccc67)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccc(-c7ccccc7)cc6)n5)cc4)C4CC5CC(C4)CC3C5)c2)cc1 ; CP(C)(=O)c1ccc(-c2cccc(C3(c4ccc(-c5nc(-c6cccc(-c7ccccc7)c6)nc(-c6cccc(-c7ccccc7)c6)n5)cc4)C4CC5CC(C4)CC3C5)c2)cc1]

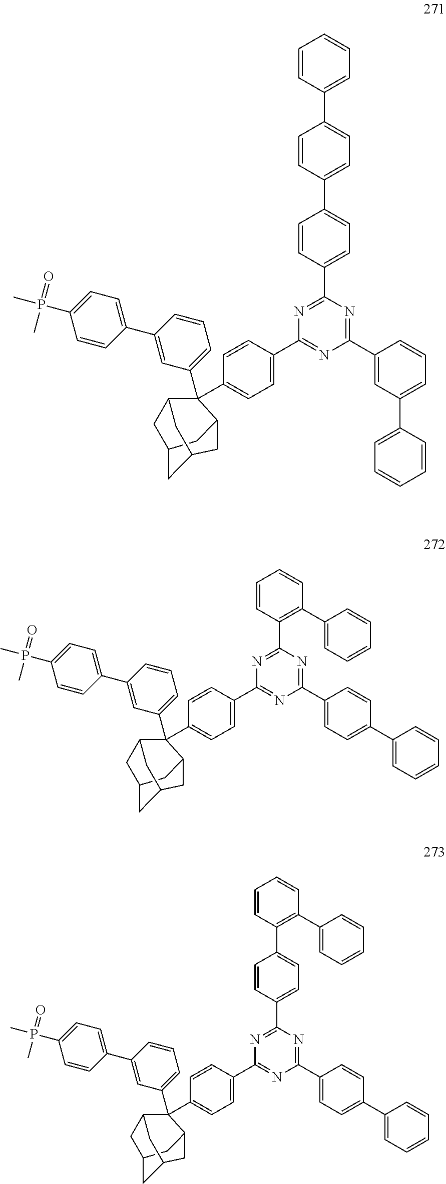 [SMILES: CP(C)(=O)c1ccc(-c2cccc(C3(c4ccc(-c5nc(-c6ccc(-c7ccc(-c8ccccc8)cc7)cc6)nc(-c6cccc(-c7ccccc7)c6)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccccc6-c6ccccc6)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6ccc(-c7ccccc7-c7ccccc7)cc6)n5)cc4)C4CC5CC(C4)CC3C5)c2)cc1]

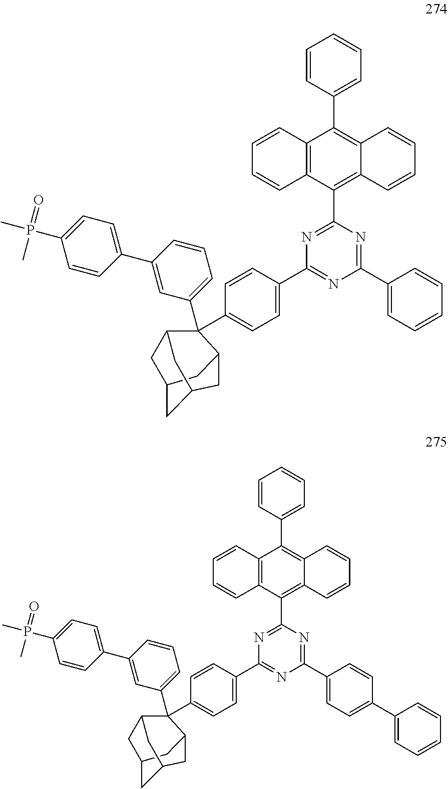 [SMILES: CP(C)(=O)c1ccc(-c2cccc(C3(c4ccc(-c5nc(-c6ccccc6)nc(-c6c7ccccc7c(-c7ccccc7)c7ccccc67)n5)cc4)C4CC5CC(C4)CC3C5)c2)cc1 ; CP(C)(=O)c1ccc(-c2cccc(C3(c4ccc(-c5nc(-c6ccc(-c7ccccc7)cc6)nc(-c6c7ccccc7c(-c7ccccc7)c7ccccc67)n5)cc4)C4CC5CC(C4)CC3C5)c2)cc1]

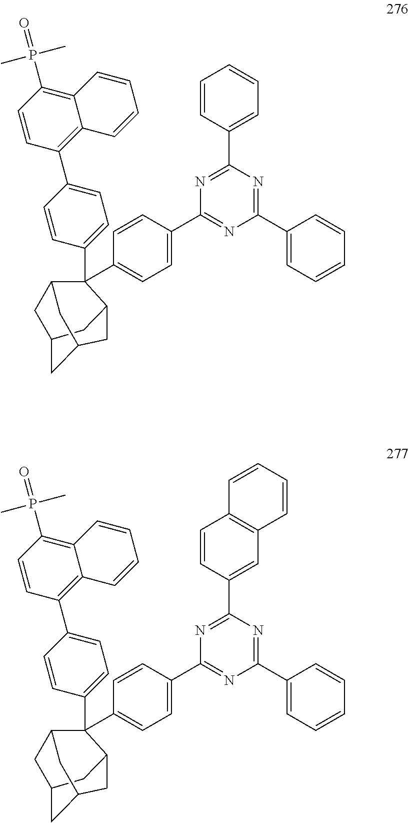 [SMILES: CP(C)(=O)c1ccc(-c2ccc(C3(c4ccc(-c5nc(-c6ccccc6)nc(-c6ccccc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc7ccccc7c6)n5)cc4)C4CC5CC(C4)CC3C5)cc2)c2ccccc12]

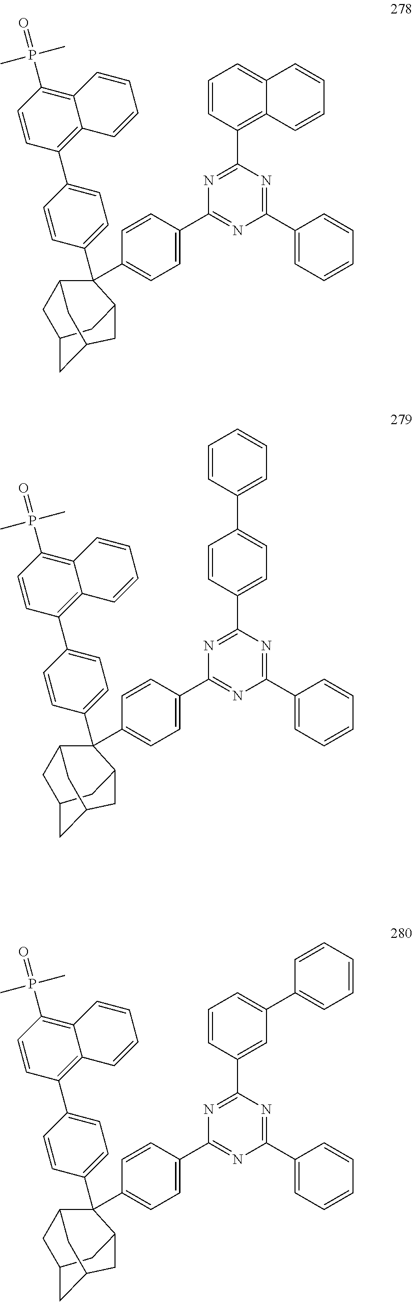 [SMILES: CP(C)(=O)c1ccc(-c2ccc(C3(c4ccc(-c5nc(-c6ccccc6)nc(-c6cccc7ccccc67)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc(-c7ccccc7)cc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6cccc(-c7ccccc7)c6)n5)cc4)C4CC5CC(C4)CC3C5)cc2)c2ccccc12]

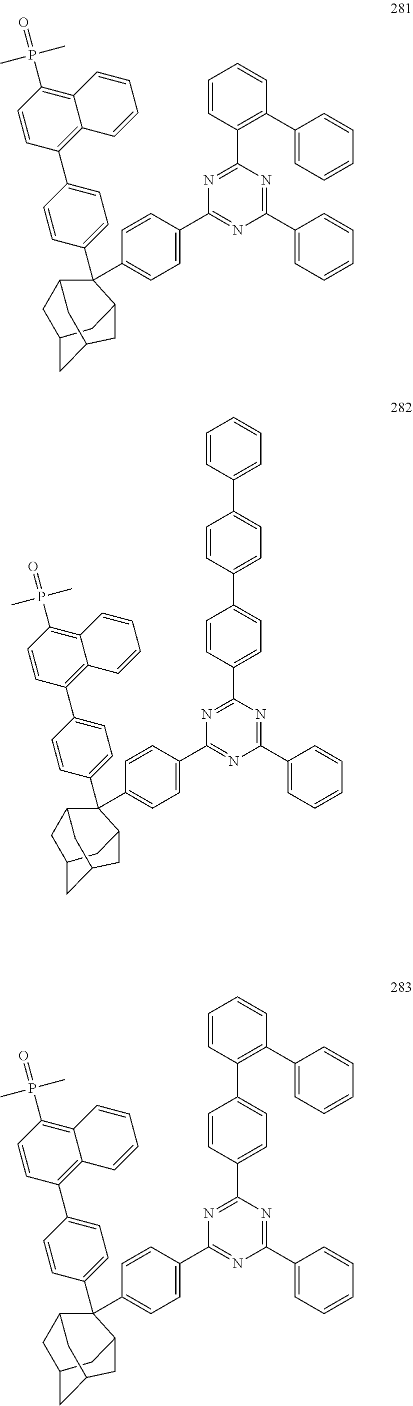 [SMILES: CP(C)(=O)c1ccc(-c2ccc(C3(c4ccc(-c5nc(-c6ccccc6)nc(-c6ccccc6-c6ccccc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc(-c7ccc(-c8ccccc8)cc7)cc6)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6ccc(-c7ccccc7-c7ccccc7)cc6)n5)cc4)C4CC5CC(C4)CC3C5)cc2)c2ccccc12]

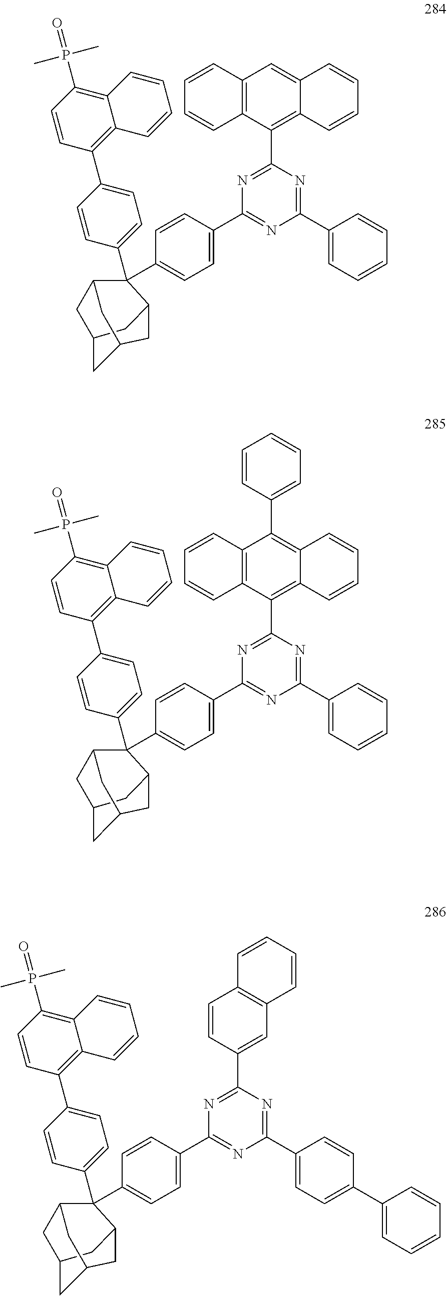 [SMILES: CP(C)(=O)c1ccc(-c2ccc(C3(c4ccc(-c5nc(-c6ccccc6)nc(-c6c7ccccc7cc7ccccc67)n5)cc4)C4CC5CC(C4)CC3C5)cc2)c2ccccc12 ; CP(C)(=O)c1ccc(-c2ccc(C3(c4ccc(-c5nc(-c6ccccc6)nc(-c6c7ccccc7c(-c7ccccc7)c7ccccc67)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccc7ccccc7c6)n5)cc4)C4CC5CC(C4)CC3C5)cc2)c2ccccc12]

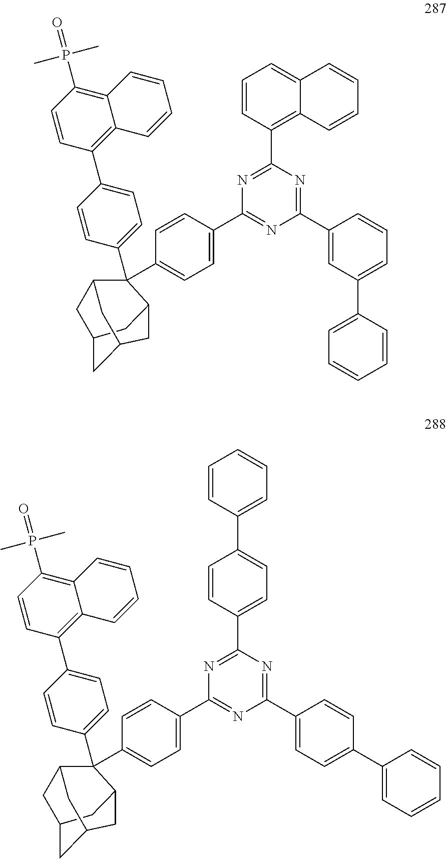 [SMILES: CP(C)(=O)c1ccc(-c2ccc(C3(c4ccc(-c5nc(-c6cccc(-c7ccccc7)c6)nc(-c6cccc7ccccc67)n5)cc4)C4CC5CC(C4)CC3C5)cc2)c2ccccc12 ; CP(C)(=O)c1ccc(-c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c2ccccc12]

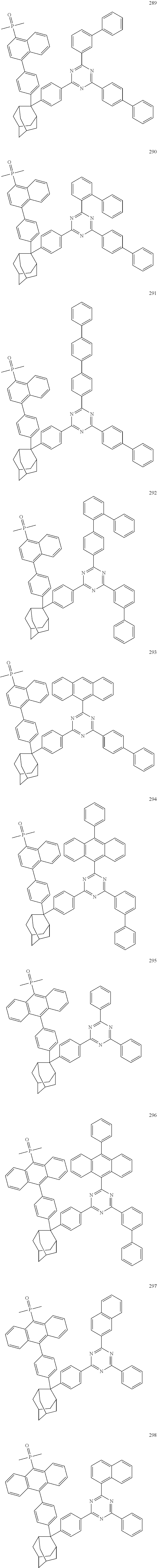

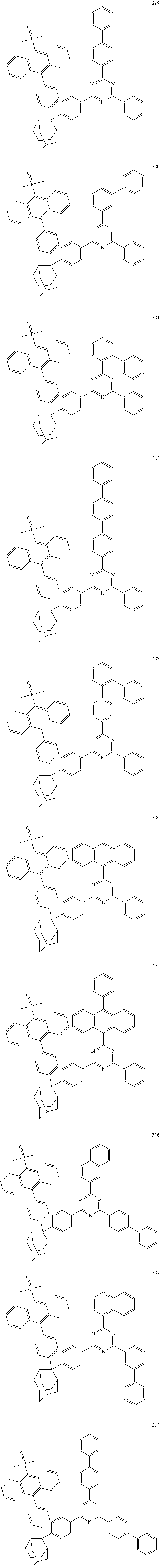

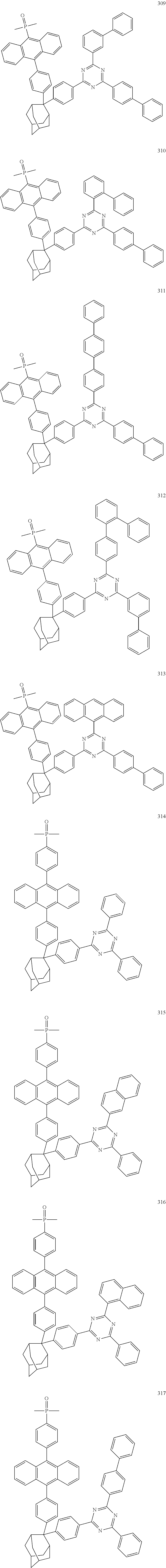

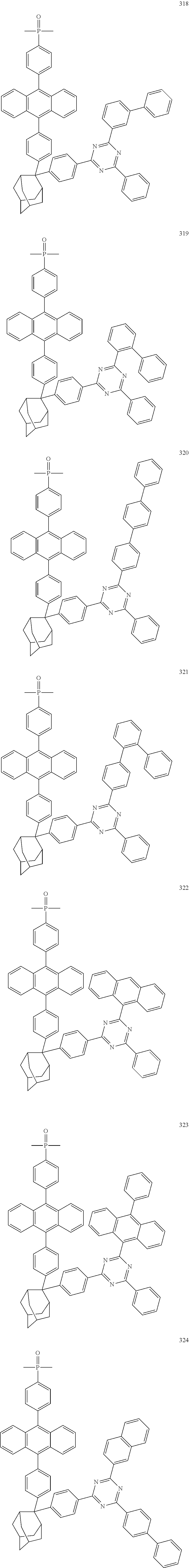

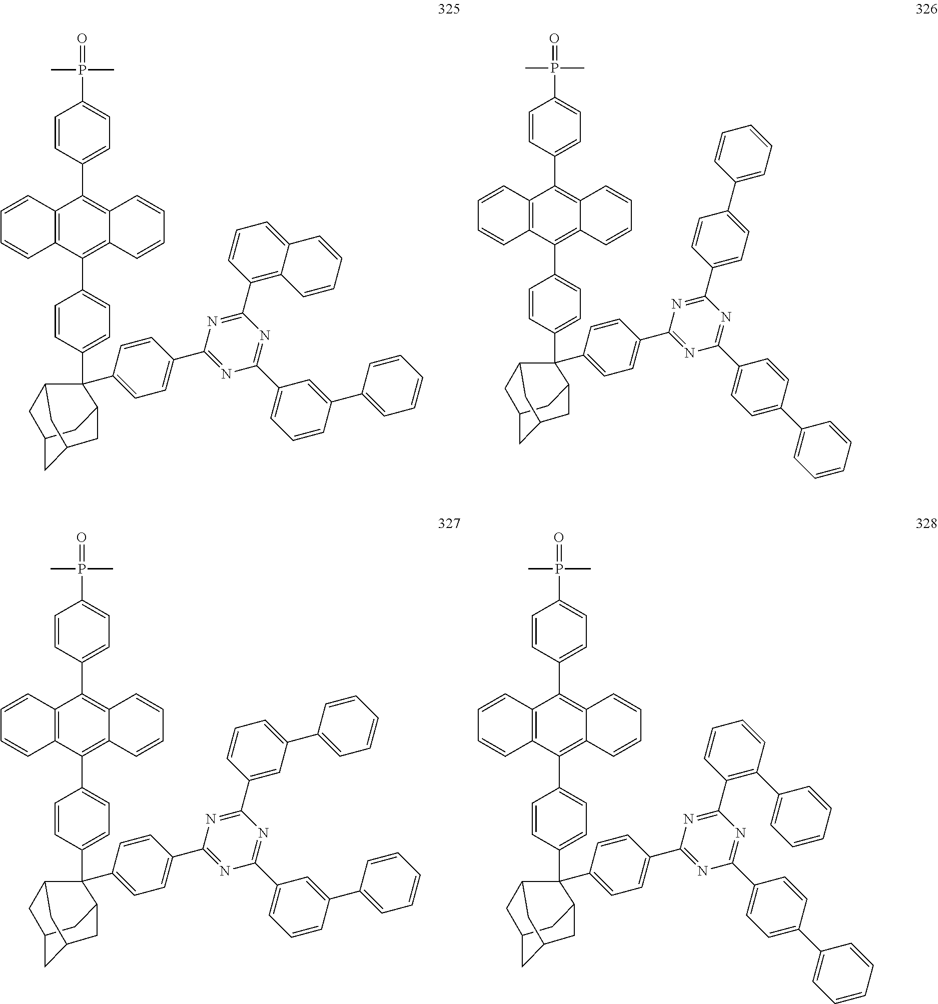

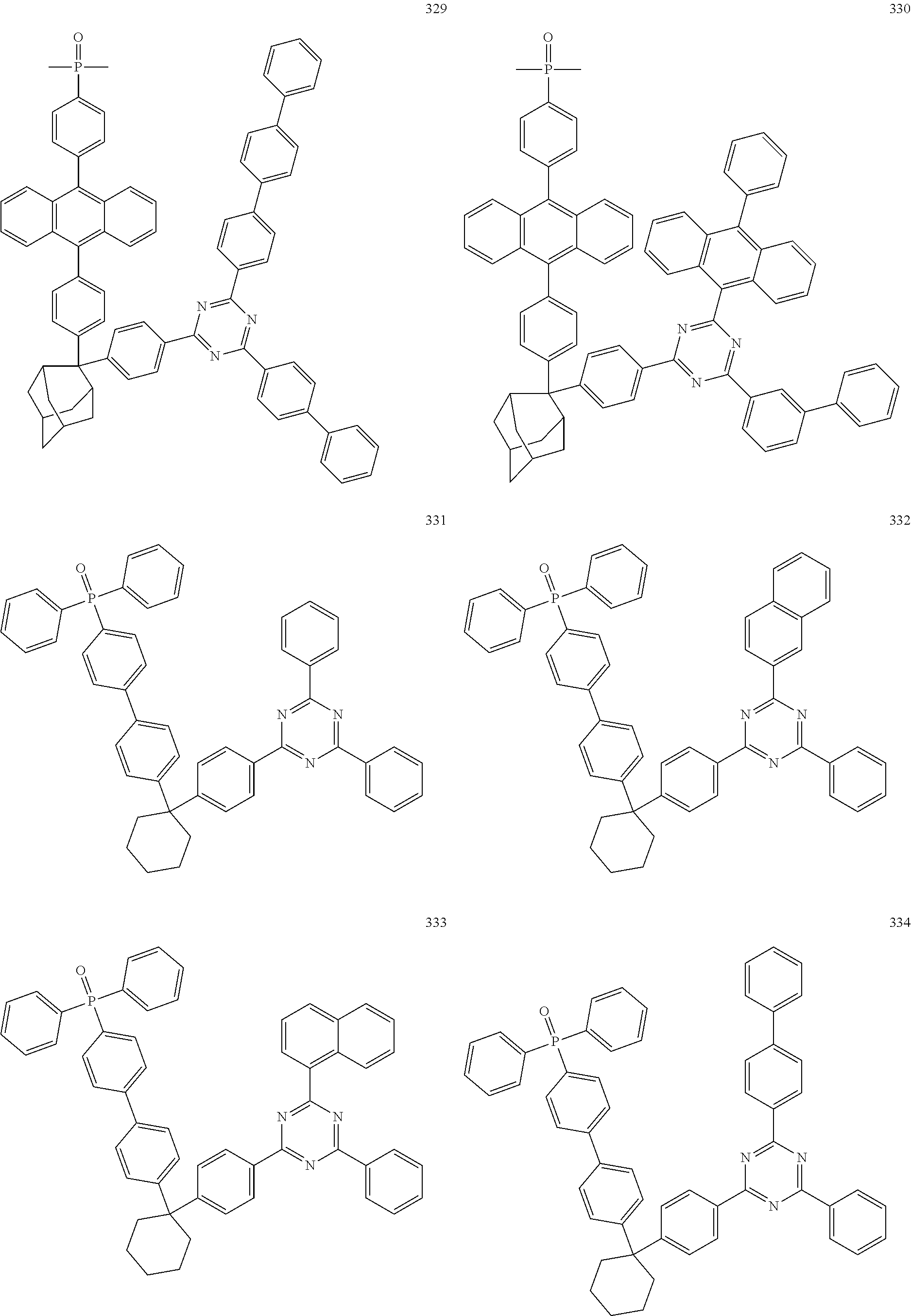

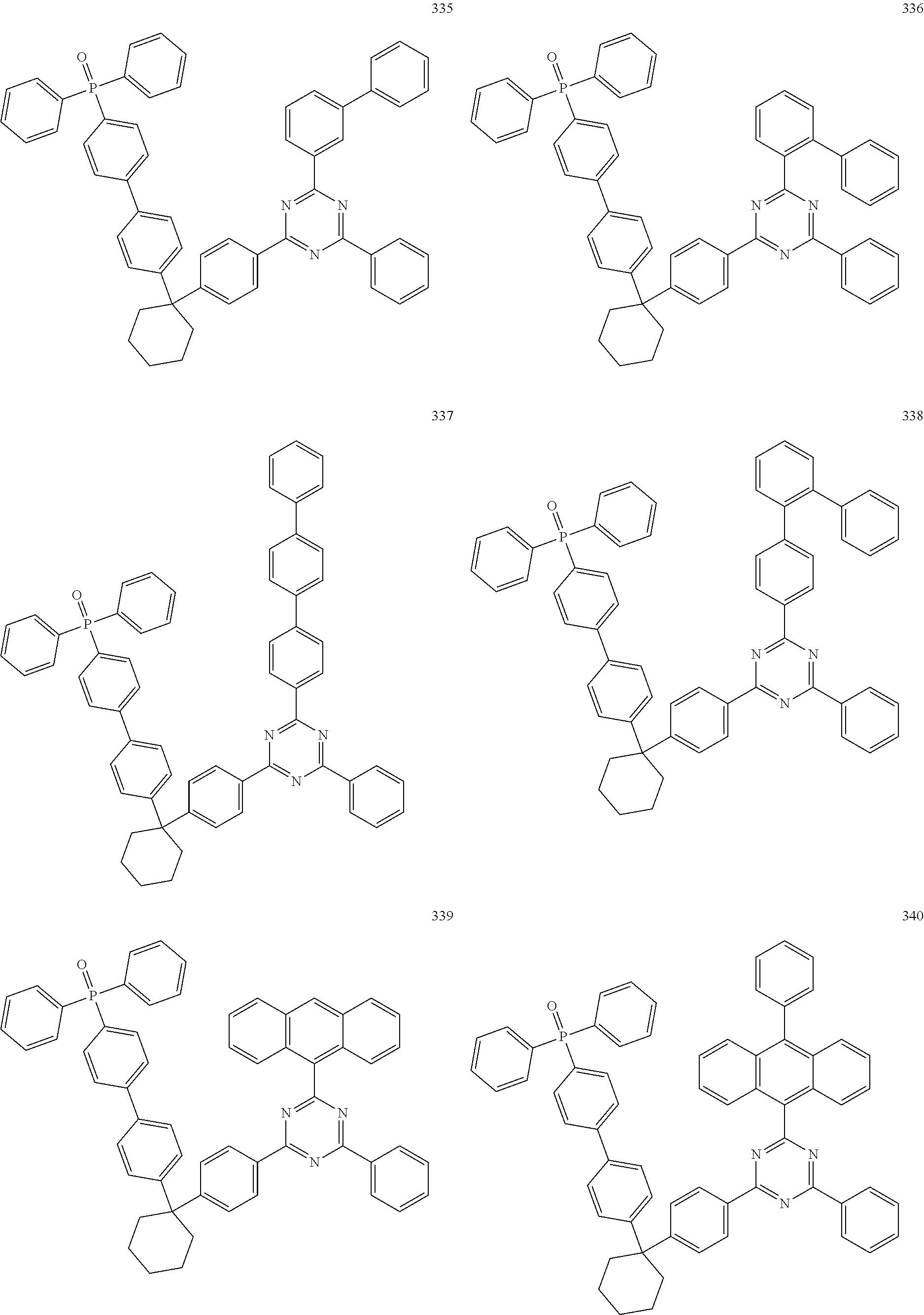

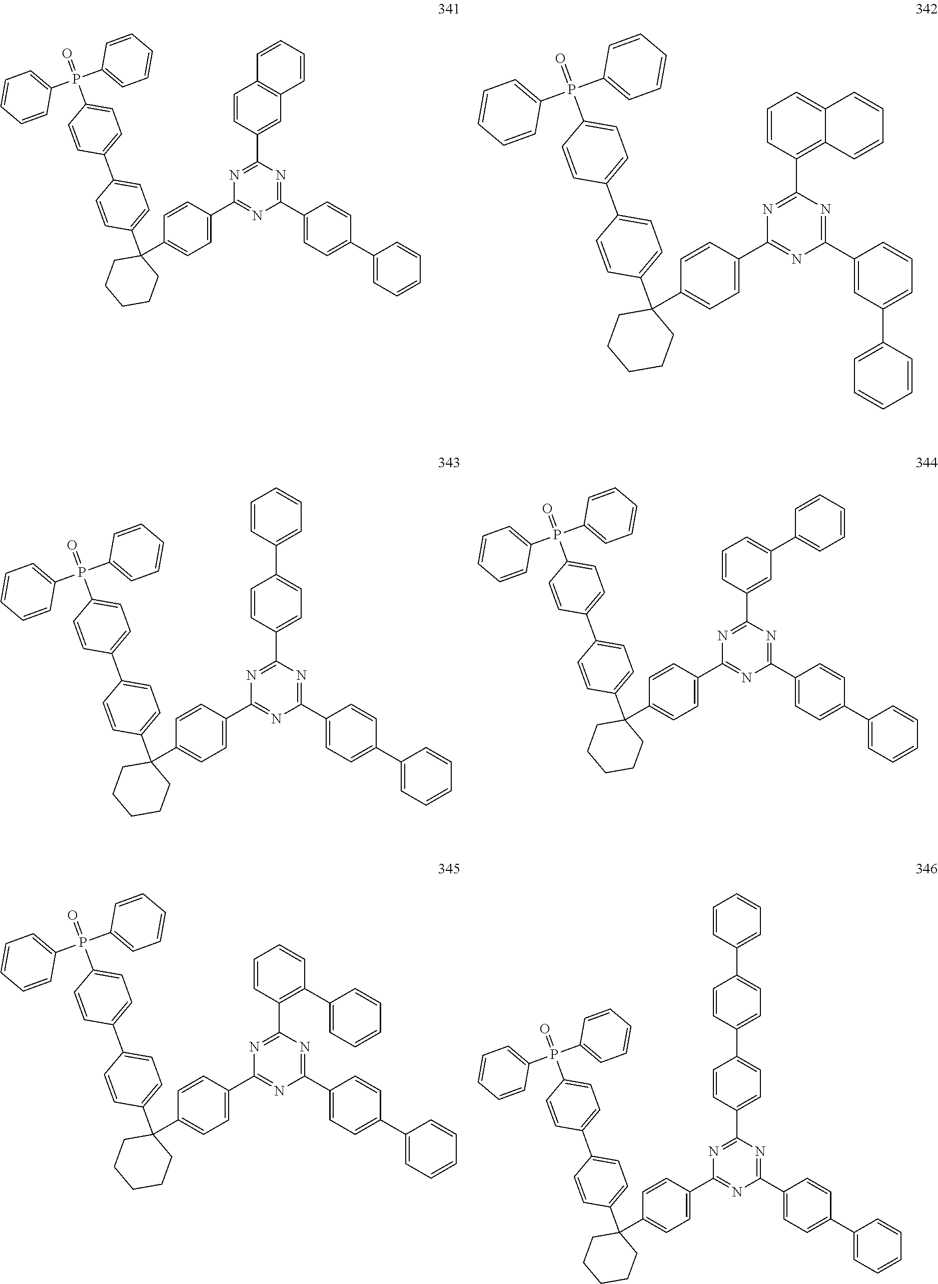

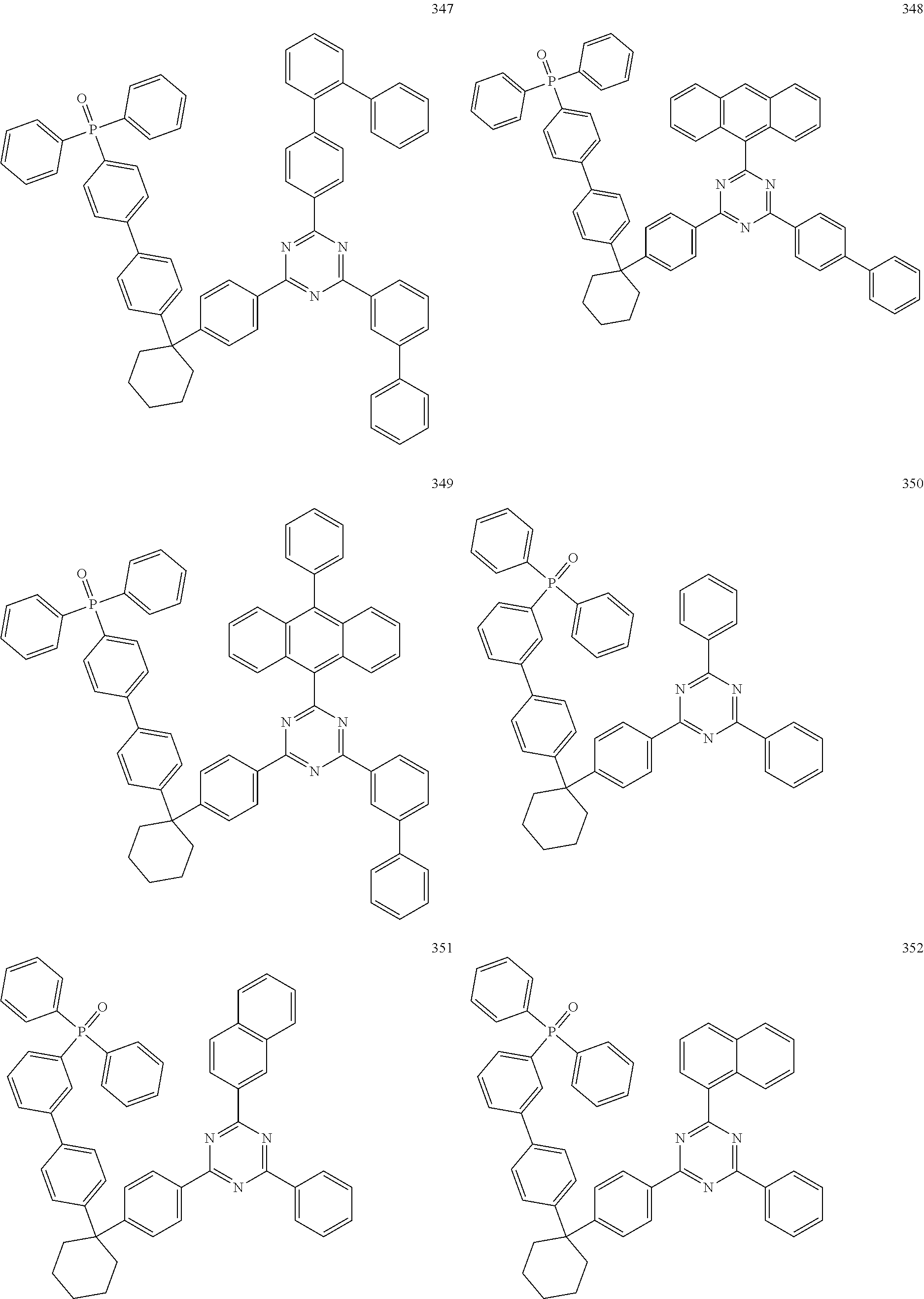

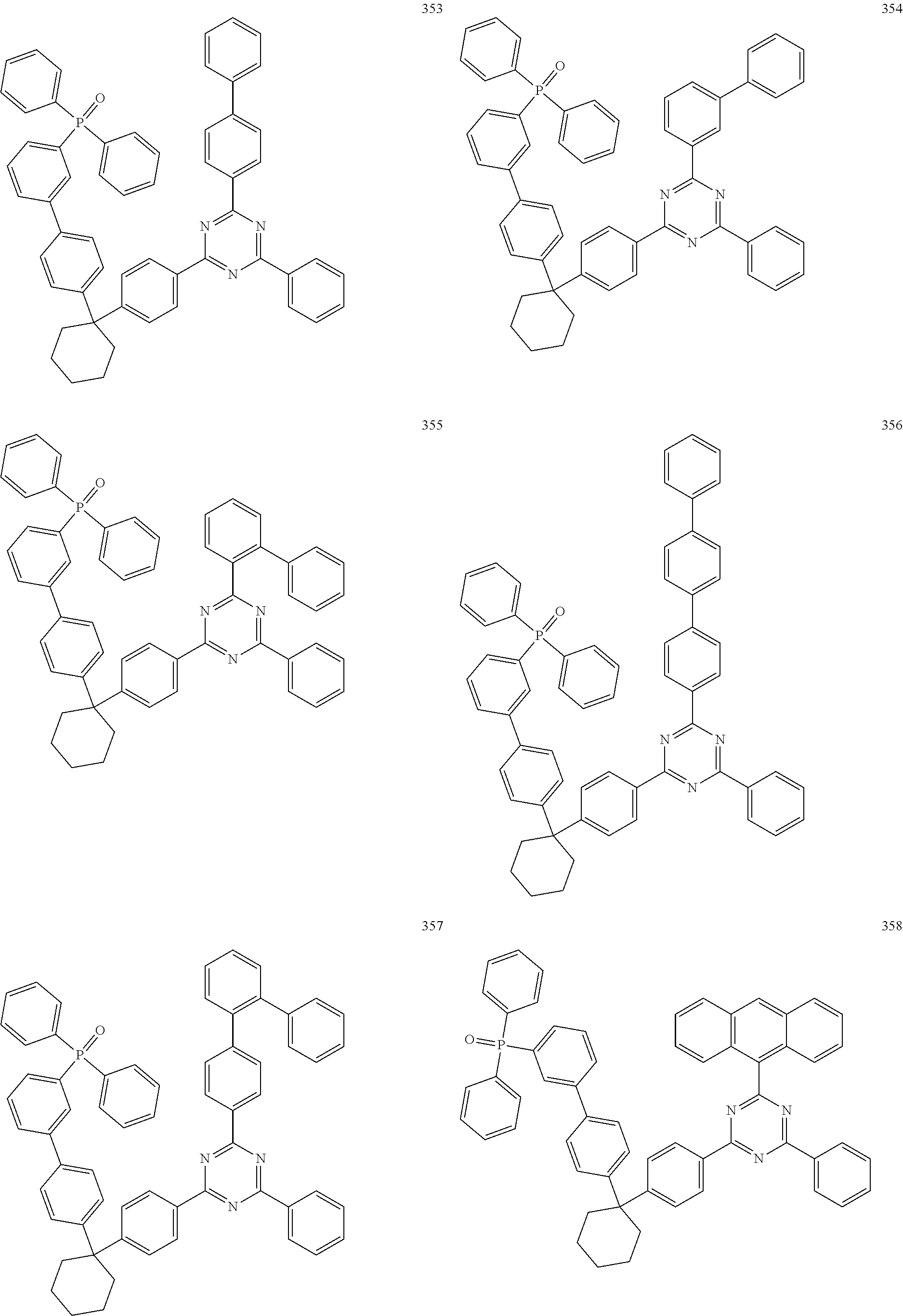

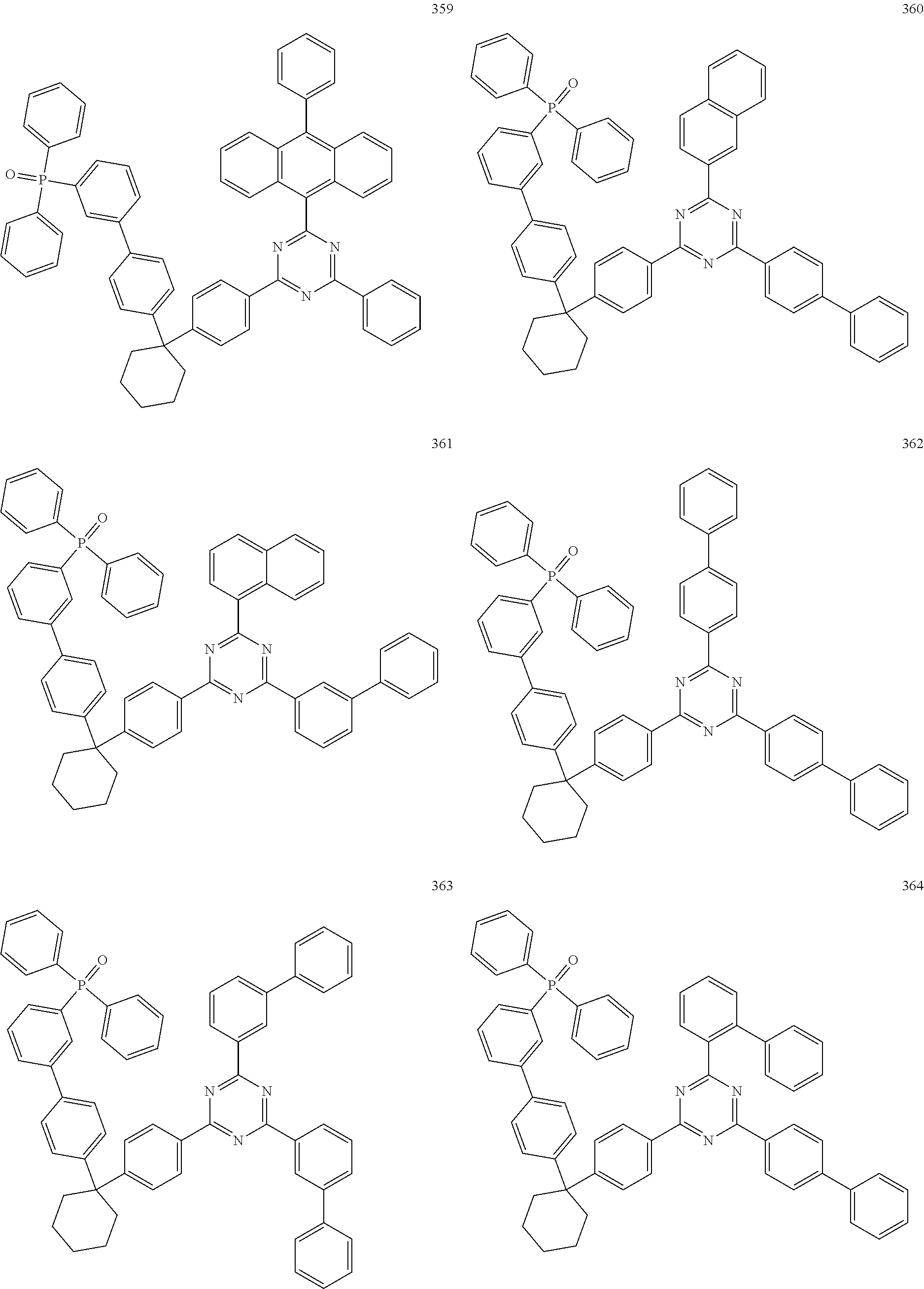

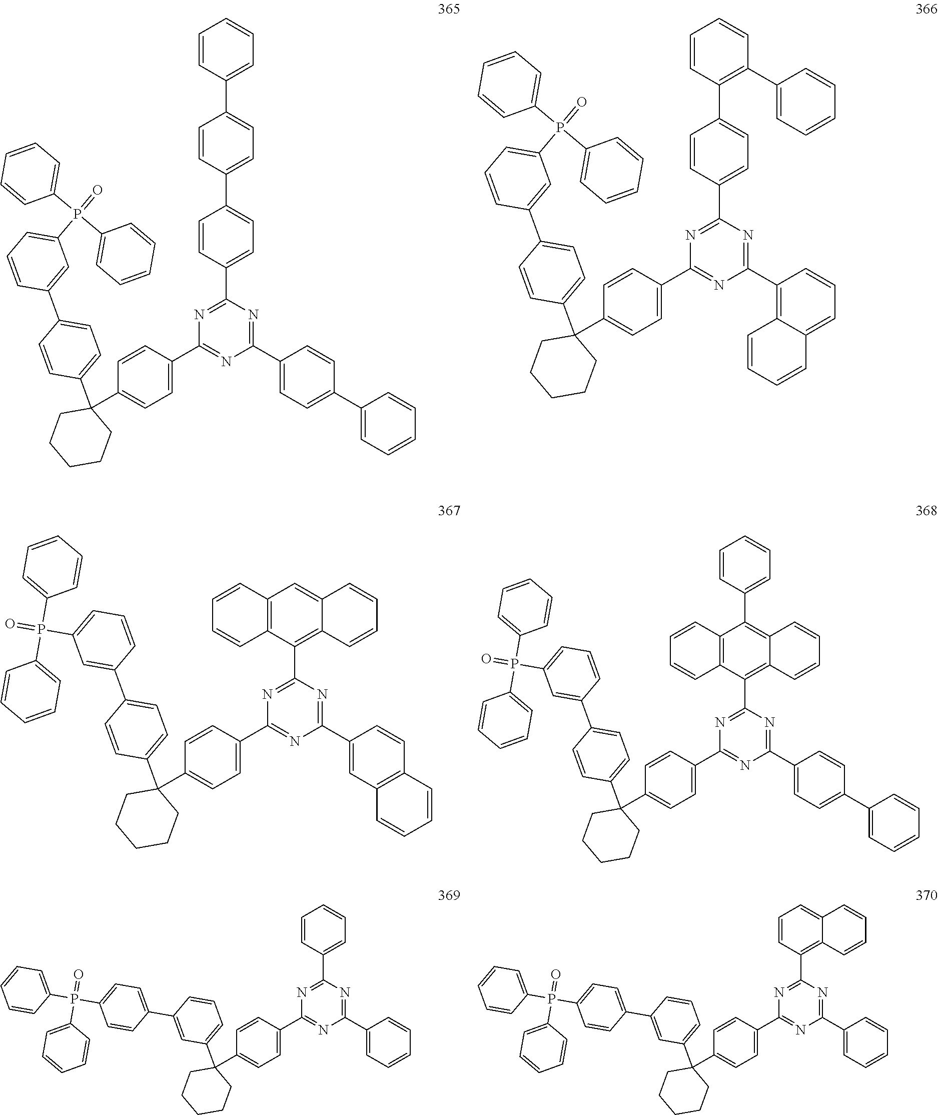

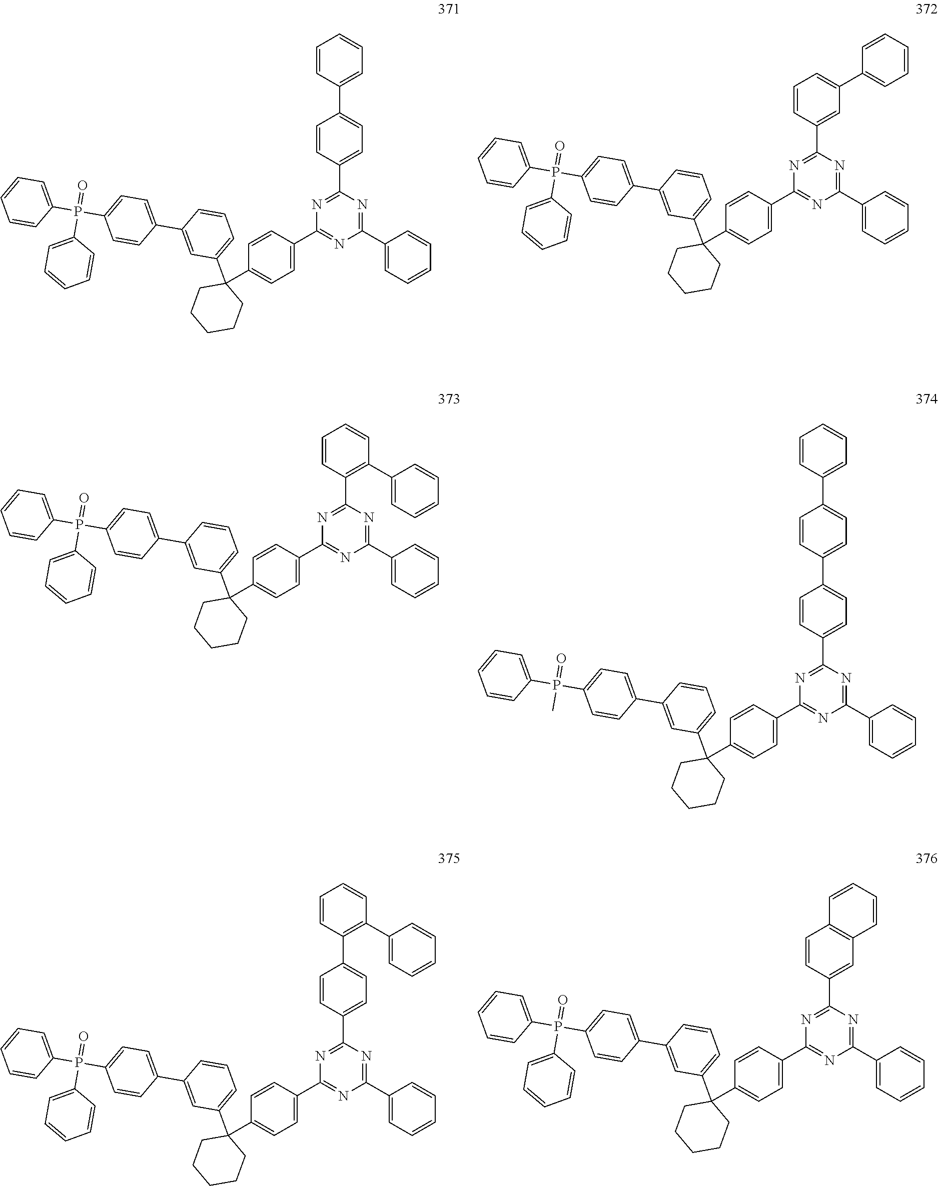

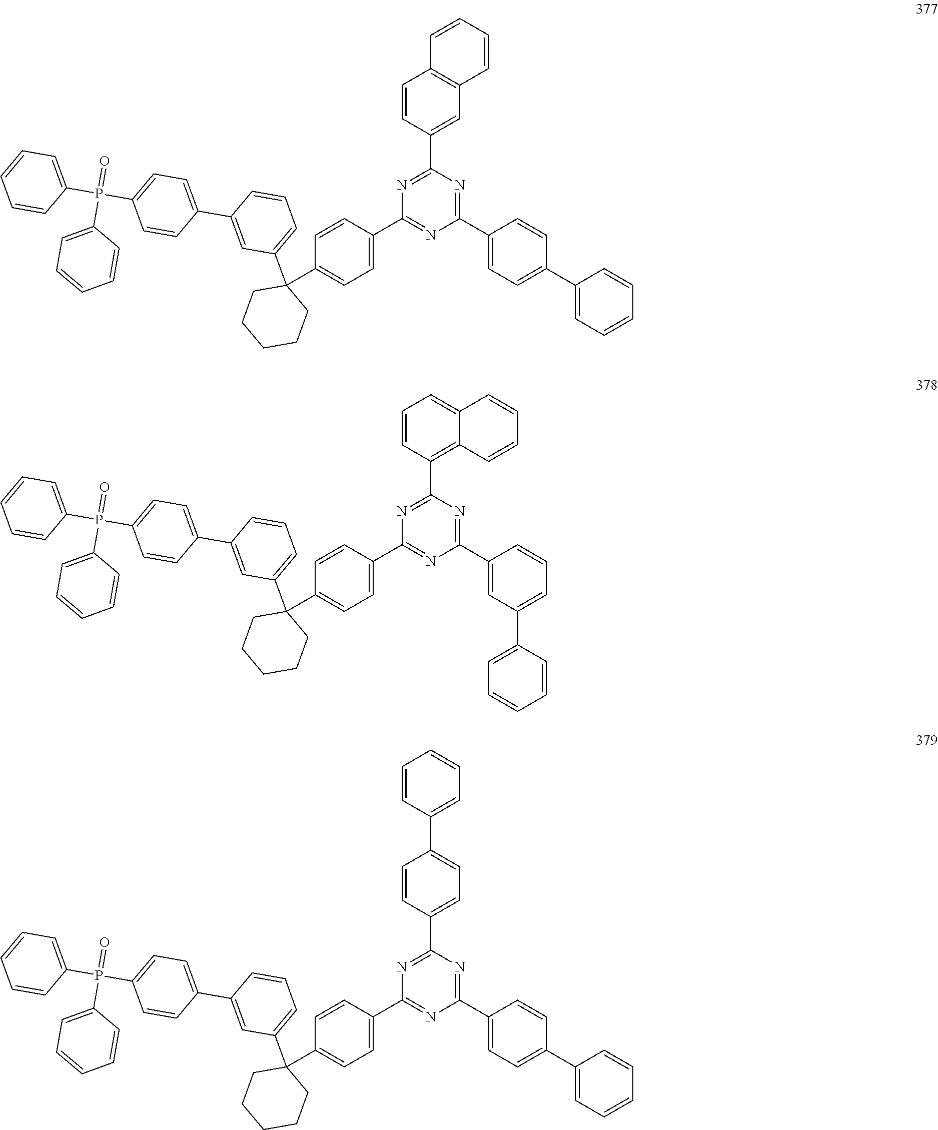 [SMILES: O=P(c1ccccc1)(c1ccccc1)c1ccc(-c2cccc(C3(c4ccc(-c5nc(-c6ccc(-c7ccccc7)cc6)nc(-c6ccc7ccccc7c6)n5)cc4)CCCCC3)c2)cc1 ; O=P(c1ccccc1)(c1ccccc1)c1ccc(-c2cccc(C3(c4ccc(-c5nc(-c6cccc(-c7ccccc7)c6)nc(-c6cccc7ccccc67)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccc(-c7ccccc7)cc6)n5)cc4)CCCCC3)c2)cc1]

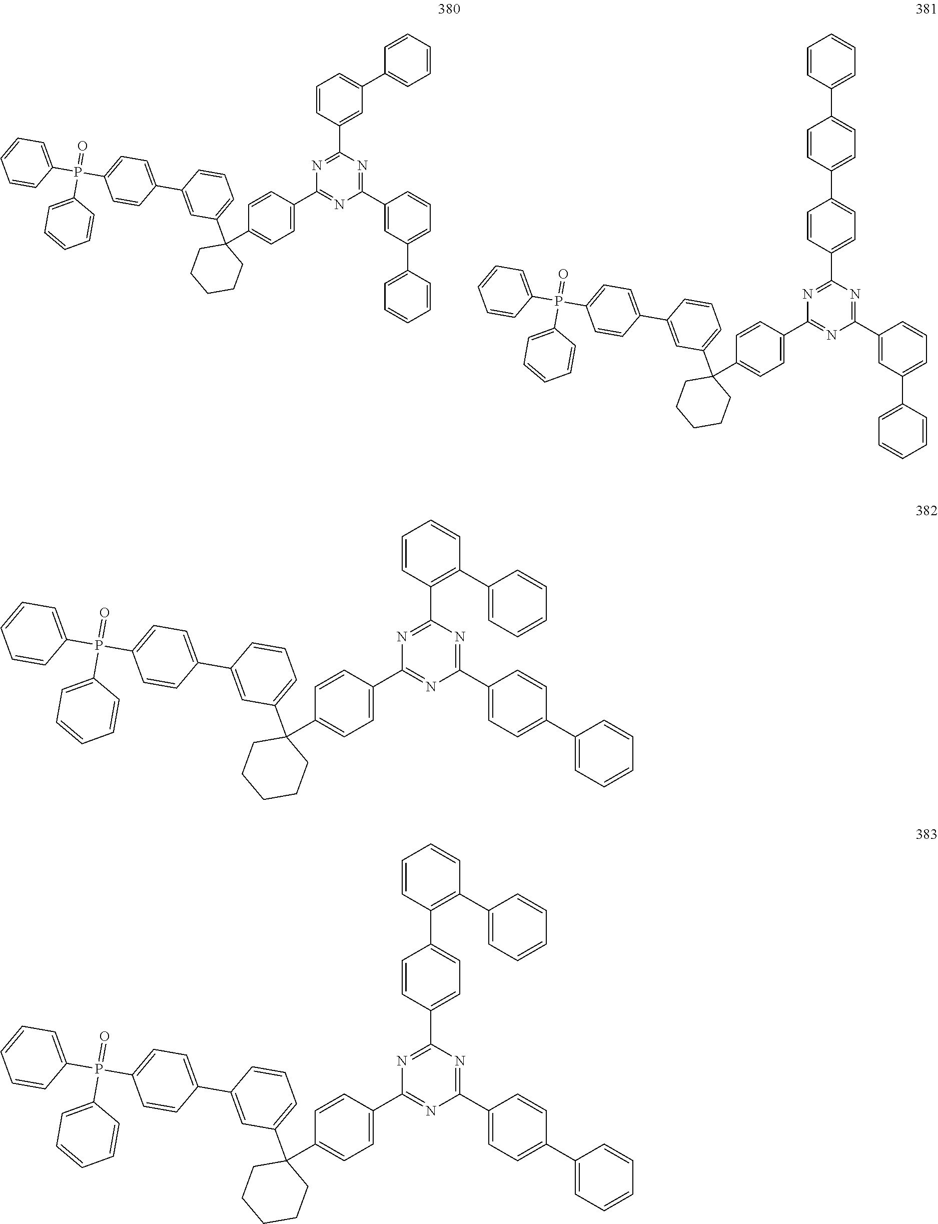 [SMILES: O=P(c1ccccc1)(c1ccccc1)c1ccc(-c2cccc(C3(c4ccc(-c5nc(-c6cccc(-c7ccccc7)c6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccc(-c8ccccc8)cc7)cc6)nc(-c6cccc(-c7ccccc7)c6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccccc6-c6ccccc6)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6ccc(-c7ccccc7-c7ccccc7)cc6)n5)cc4)CCCCC3)c2)cc1]

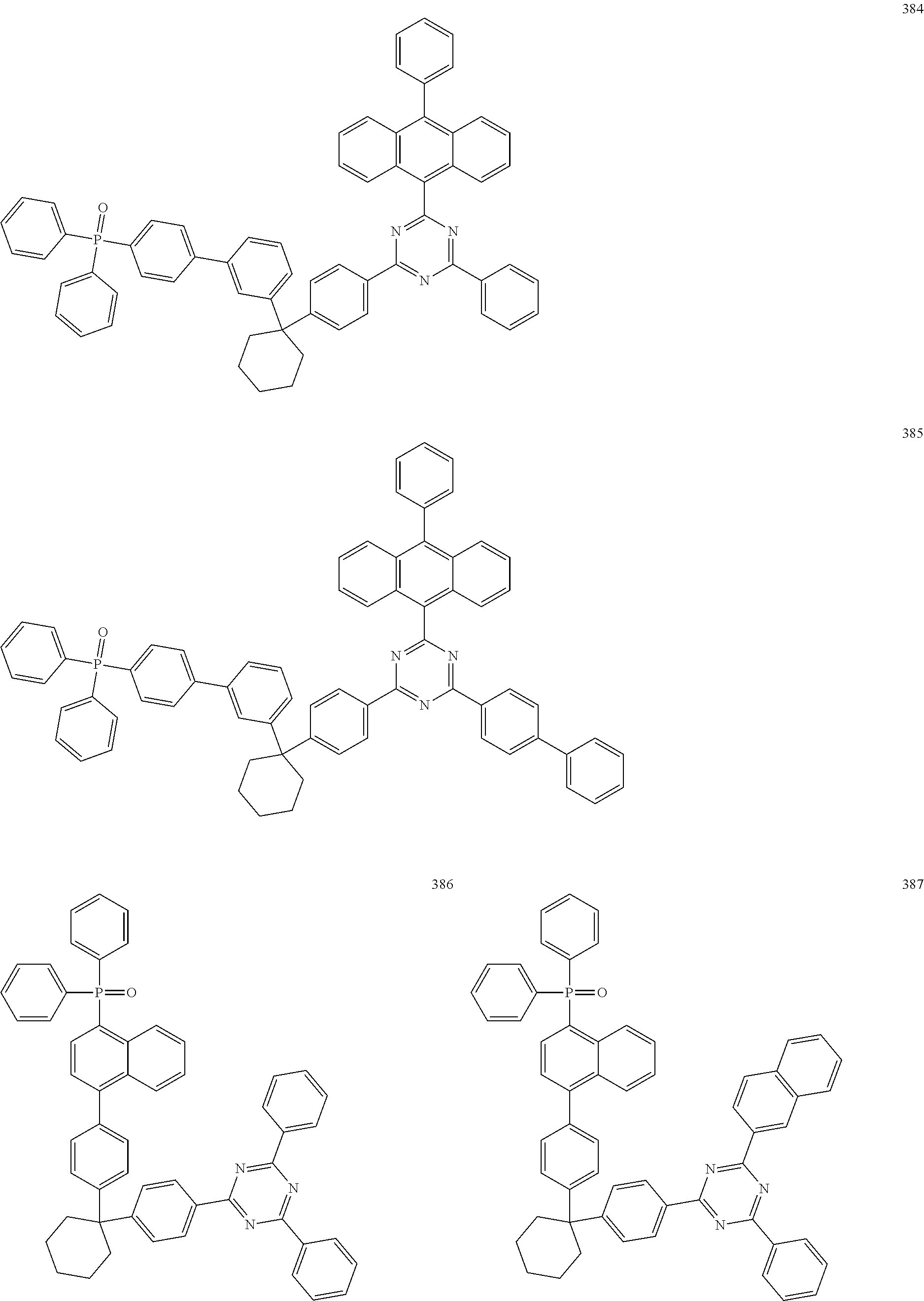 [SMILES: O=P(c1ccccc1)(c1ccccc1)c1ccc(-c2cccc(C3(c4ccc(-c5nc(-c6ccccc6)nc(-c6c7ccccc7c(-c7ccccc7)c7ccccc67)n5)cc4)CCCCC3)c2)cc1 ; O=P(c1ccccc1)(c1ccccc1)c1ccc(-c2cccc(C3(c4ccc(-c5nc(-c6ccc(-c7ccccc7)cc6)nc(-c6c7ccccc7c(-c7ccccc7)c7ccccc67)n5)cc4)CCCCC3)c2)cc1 ; O=P(c1ccccc1)(c1ccccc1)c1ccc(-c2ccc(C3(c4ccc(-c5nc(-c6ccccc6)nc(-c6ccccc6)n5)cc4)CCCCC3)cc2)c2ccccc12 ; O=P(c1ccccc1)(c1ccccc1)c1ccc(-c2ccc(C3(c4ccc(-c5nc(-c6ccccc6)nc(-c6ccc7ccccc7c6)n5)cc4)CCCCC3)cc2)c2ccccc12]

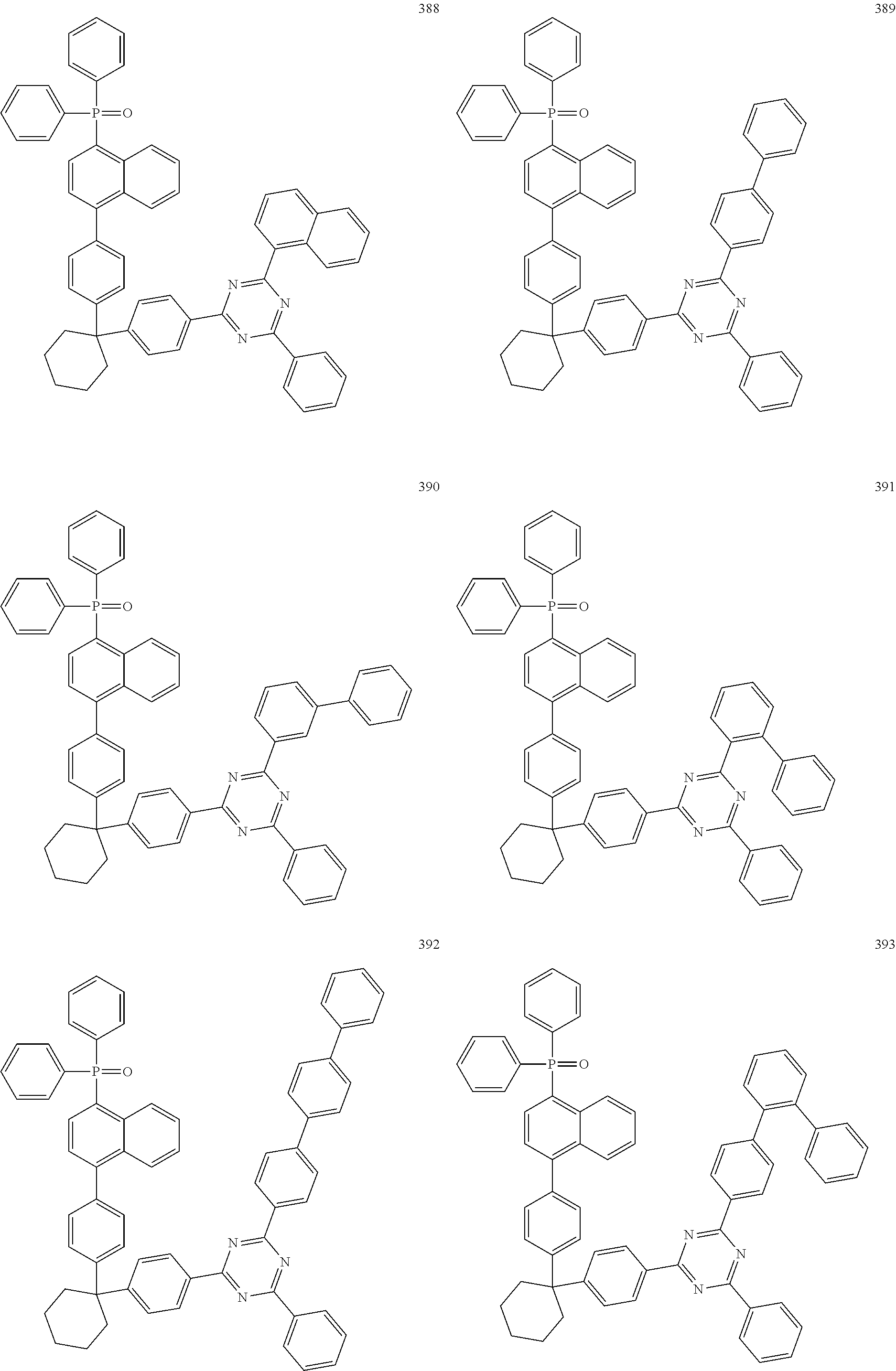

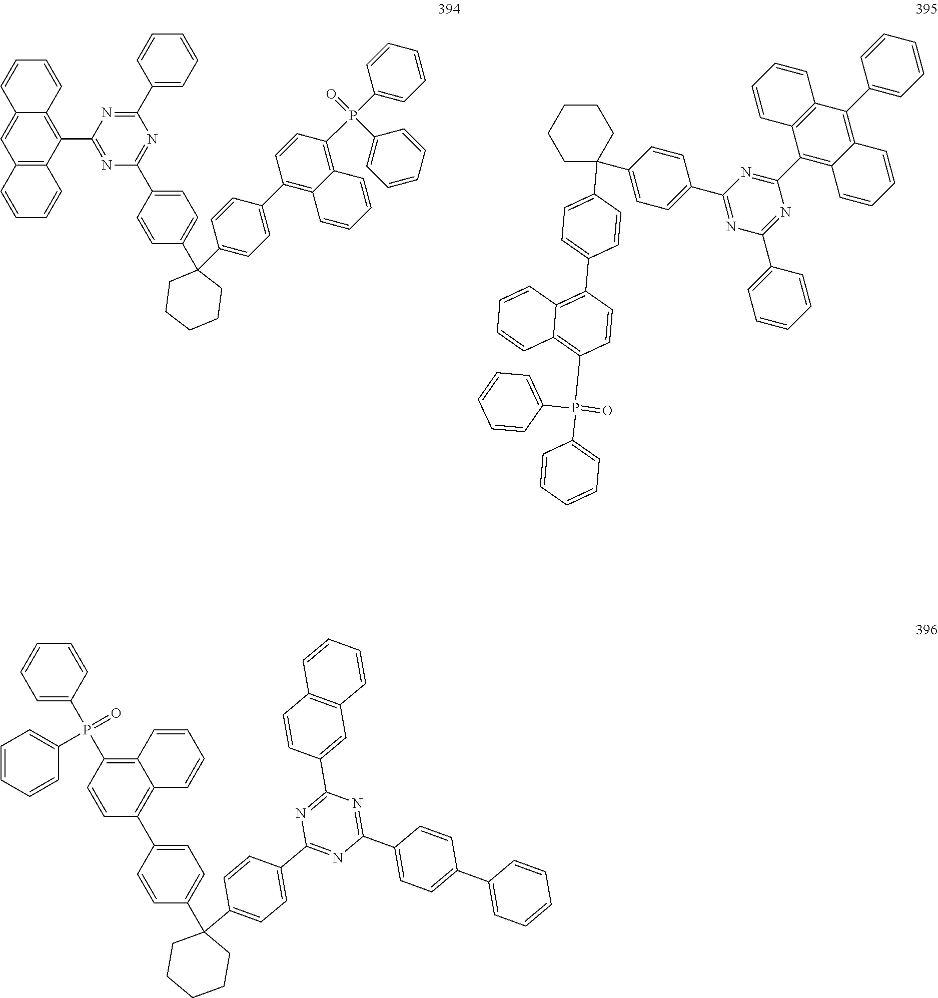

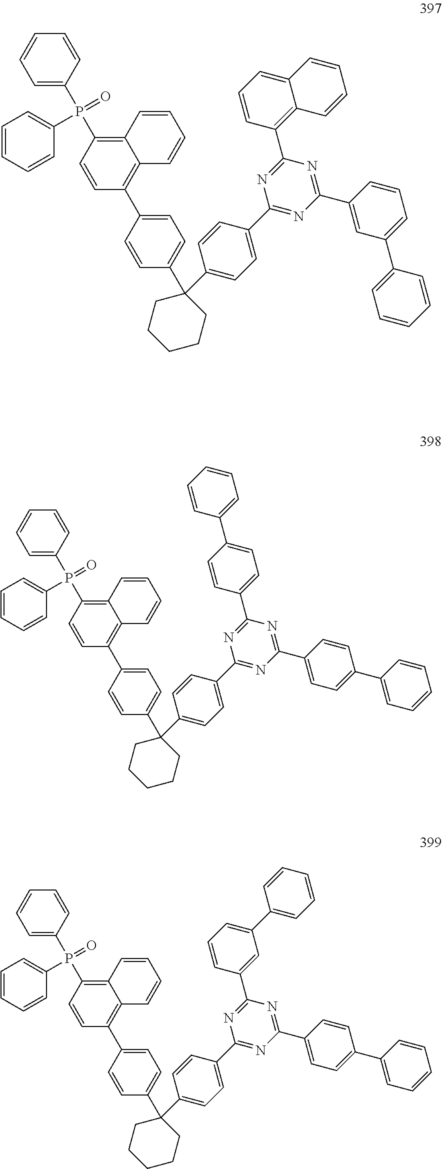 [SMILES: O=P(c1ccccc1)(c1ccccc1)c1ccc(-c2ccc(C3(c4ccc(-c5nc(-c6cccc(-c7ccccc7)c6)nc(-c6cccc7ccccc67)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12]

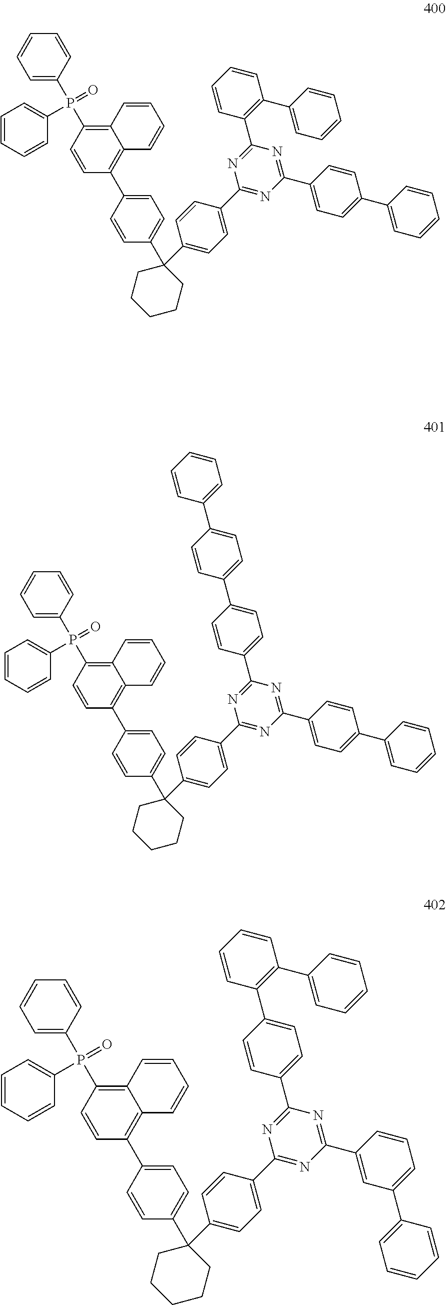 [SMILES: O=P(c1ccccc1)(c1ccccc1)c1ccc(-c2ccc(C3(c4ccc(-c5nc(-c6ccc(-c7ccccc7)cc6)nc(-c6ccccc6-c6ccccc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; O=P(c1ccccc1)(c1ccccc1)c1ccc(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

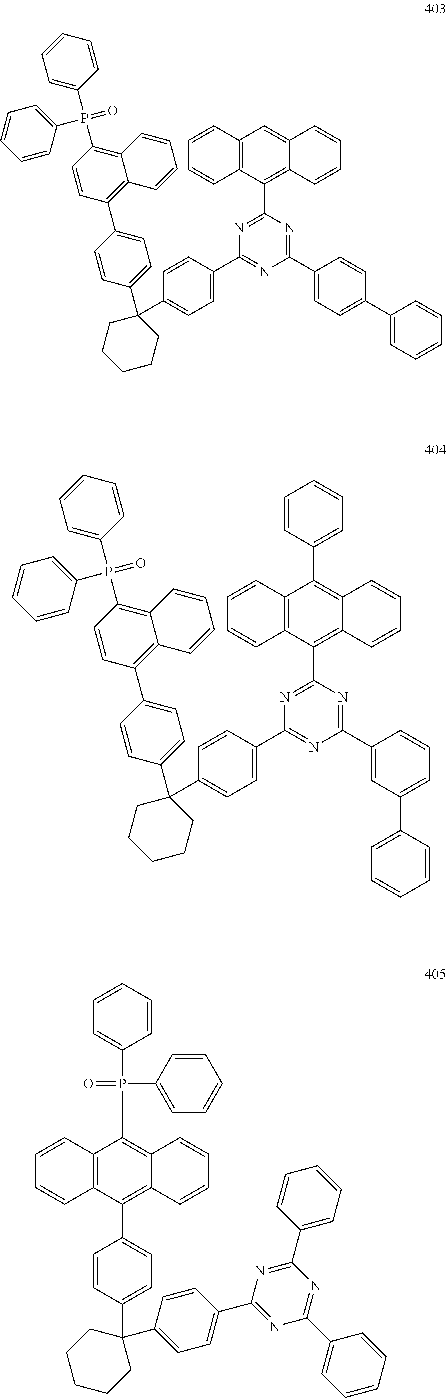 [SMILES: O=P(c1ccccc1)(c1ccccc1)c1ccc(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; O=P(c1ccccc1)(c1ccccc1)c1ccc(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6)n5)cc4)CCCCC3)cc2)c2ccccc12]

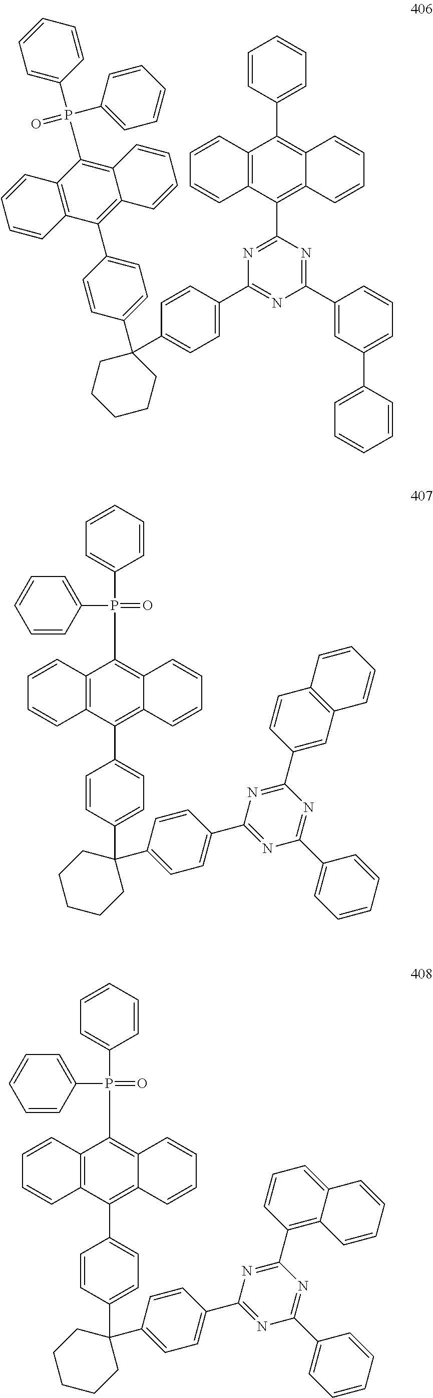 [SMILES: O=P(c1ccccc1)(c1ccccc1)c1c2ccccc2c(-c2ccc(C3(c4ccc(-c5nc(-c6cccc(-c7ccccc7)c6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccc7ccccc7c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6cccc7ccccc67)n5)cc4)CCCCC3)cc2)c2ccccc12]

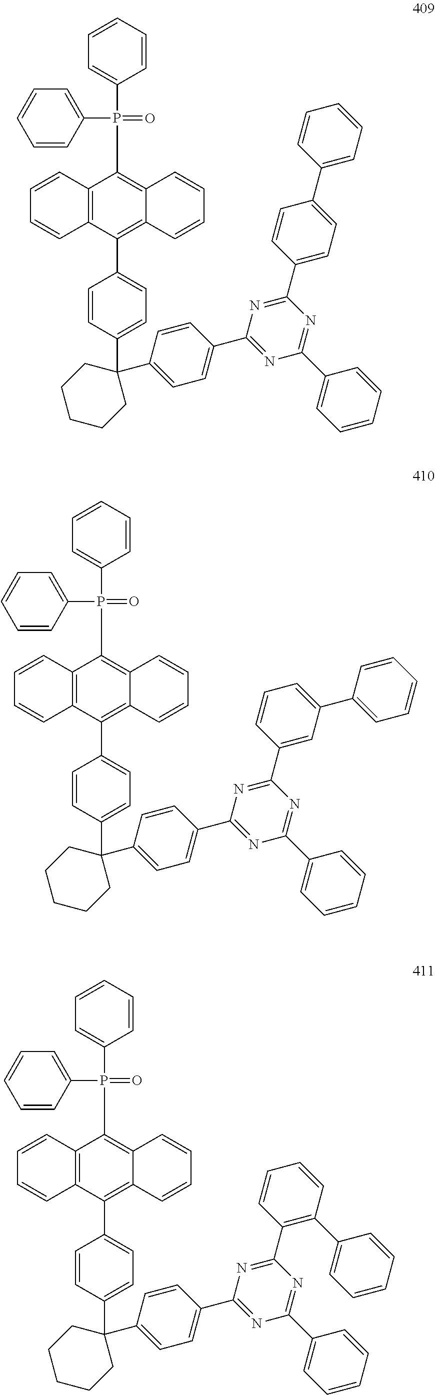 [SMILES: O=P(c1ccccc1)(c1ccccc1)c1c2ccccc2c(-c2ccc(C3(c4ccc(-c5nc(-c6ccccc6)nc(-c6ccc(-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccccc6-c6ccccc6)n5)cc4)CCCCC3)cc2)c2ccccc12]

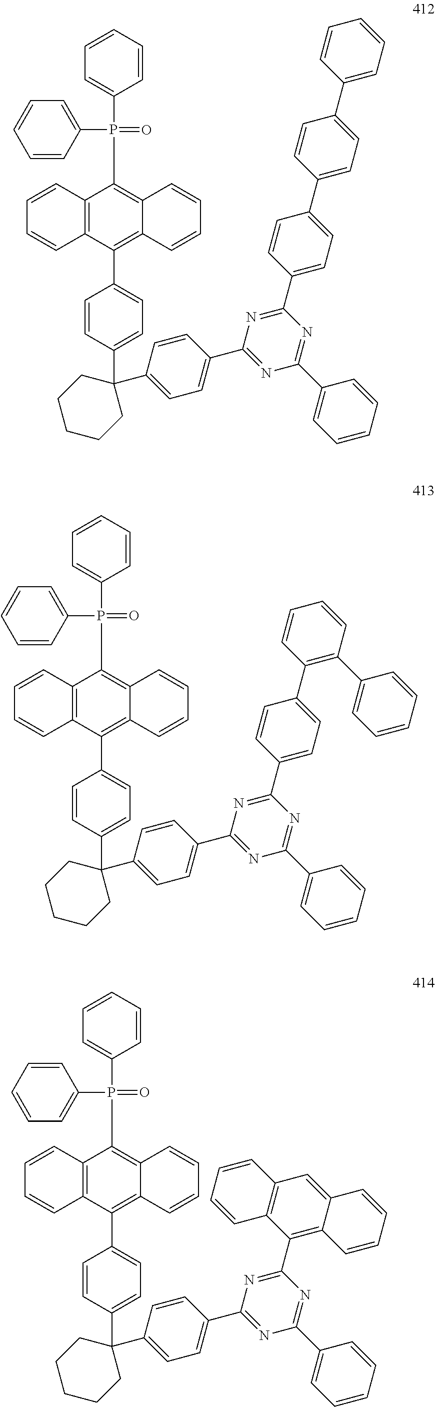 [SMILES: O=P(c1ccccc1)(c1ccccc1)c1c2ccccc2c(-c2ccc(C3(c4ccc(-c5nc(-c6ccccc6)nc(-c6ccc(-c7ccc(-c8ccccc8)cc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6ccc(-c7ccccc7-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccccc6)nc(-c6c7ccccc7cc7ccccc67)n5)cc4)CCCCC3)cc2)c2ccccc12]

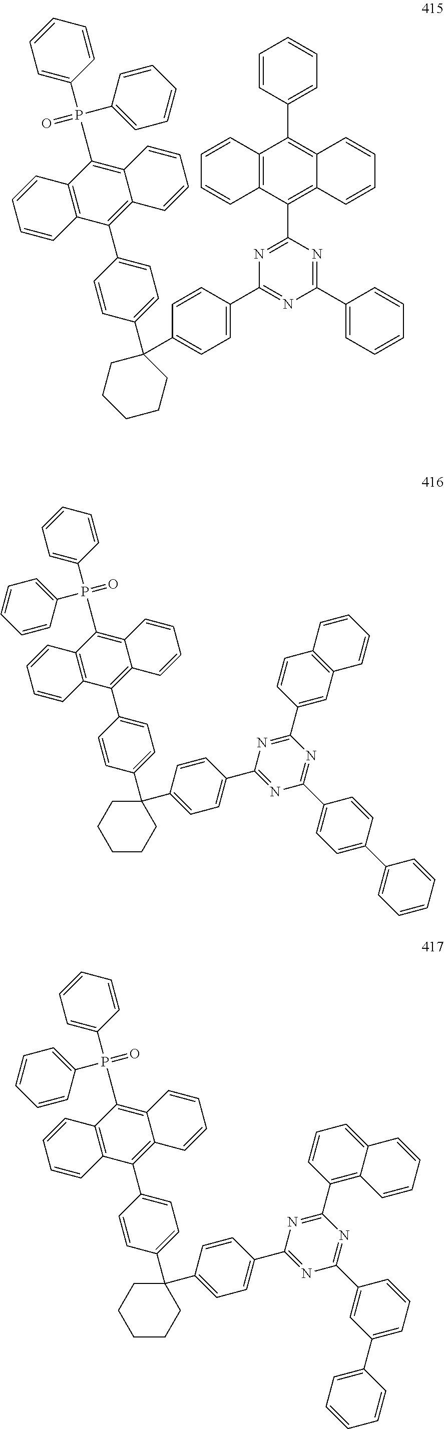 [SMILES: O=P(c1ccccc1)(c1ccccc1)c1c2ccccc2c(-c2ccc(C3(c4ccc(-c5nc(-c6ccccc6)nc(-c6c7ccccc7c(-c7ccccc7)c7ccccc67)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccc7ccccc7c6)n5)cc4)CCCCC3)cc2)c2ccccc12 ; O=P(c1ccccc1)(c1ccccc1)c1c2ccccc2c(-c2ccc(C3(c4ccc(-c5nc(-c6cccc(-c7ccccc7)c6)nc(-c6cccc7ccccc67)n5)cc4)CCCCC3)cc2)c2ccccc12]

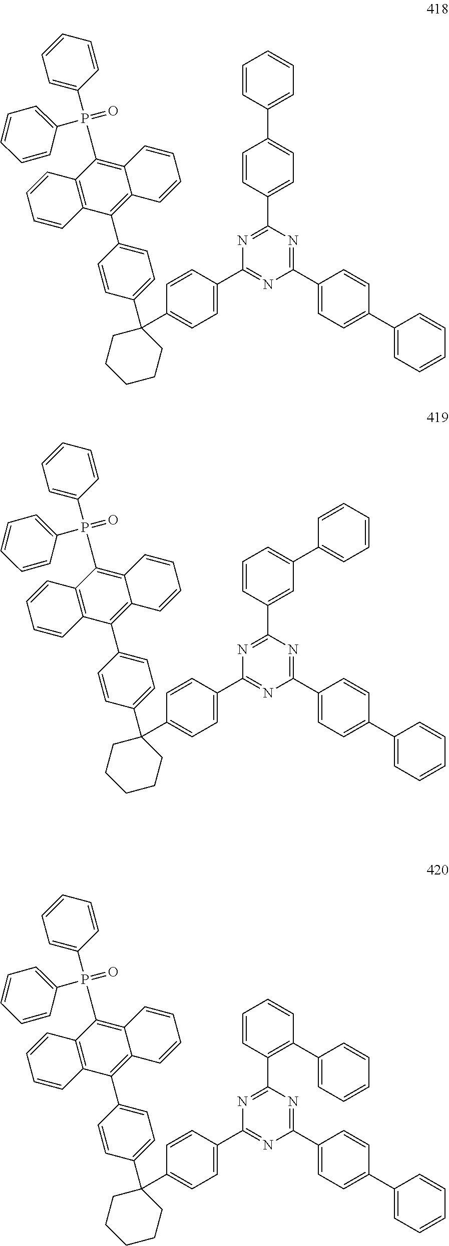 [SMILES: O=P(c1ccccc1)(c1ccccc1)c1c2ccccc2c(-c2ccc(C3(c4ccc(-c5nc(-c6ccc(-c7ccccc7)cc6)nc(-c6ccc(-c7ccccc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6cccc(-c7ccccc7)c6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7)cc6)nc(-c6ccccc6-c6ccccc6)n5)cc4)CCCCC3)cc2)c2ccccc12]

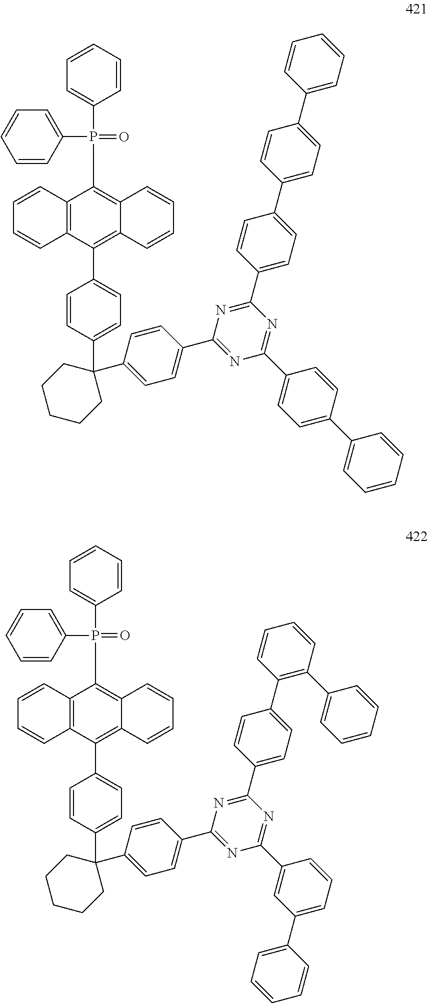 [SMILES: O=P(c1ccccc1)(c1ccccc1)c1c2ccccc2c(-c2ccc(C3(c4ccc(-c5nc(-c6ccc(-c7ccccc7)cc6)nc(-c6ccc(-c7ccc(-c8ccccc8)cc7)cc6)n5)cc4)CCCCC3)cc2)c2ccccc12 ; O=P(c1ccccc1)(c1ccccc1)c1c2ccccc2c(-c2ccc(C3(c4ccc(-c5nc(-c6ccc(-c7ccccc7-c7ccccc7)cc6)nc(-c6cccc(-c7ccccc7)c6)n5)cc4)CCCCC3)cc2)c2ccccc12]

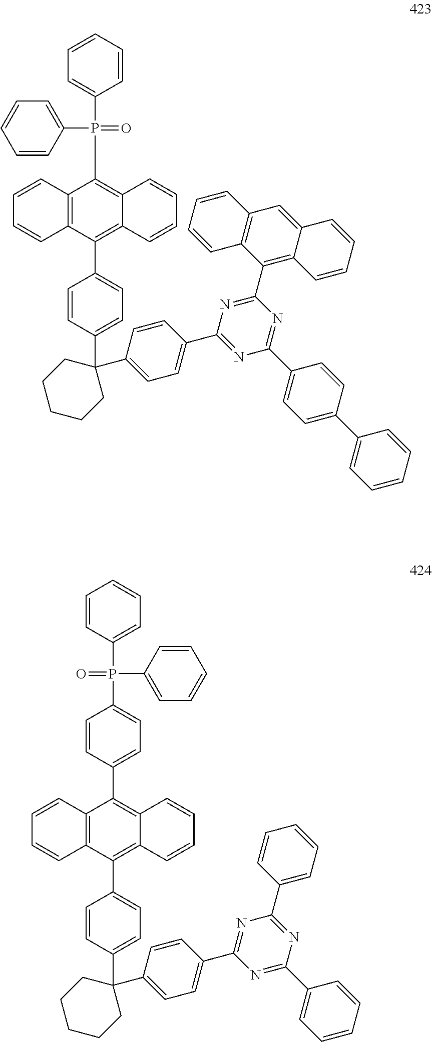 [SMILES: O=P(c1ccccc1)(c1ccccc1)c1c2ccccc2c(-c2ccc(C3(c4ccc(-c5nc(-c6ccc(-c7ccccc7)cc6)nc(-c6c7ccccc7cc7ccccc67)n5)cc4)CCCCC3)cc2)c2ccccc12 ; O=P(c1ccccc1)(c1ccccc1)c1ccc(-c2c3ccccc3c(-c3ccc(C4(c5ccc(-c6nc(-c7ccccc7)nc(-c7ccccc7)n6)cc5)CCCCC4)cc3)c3ccccc23)cc1]

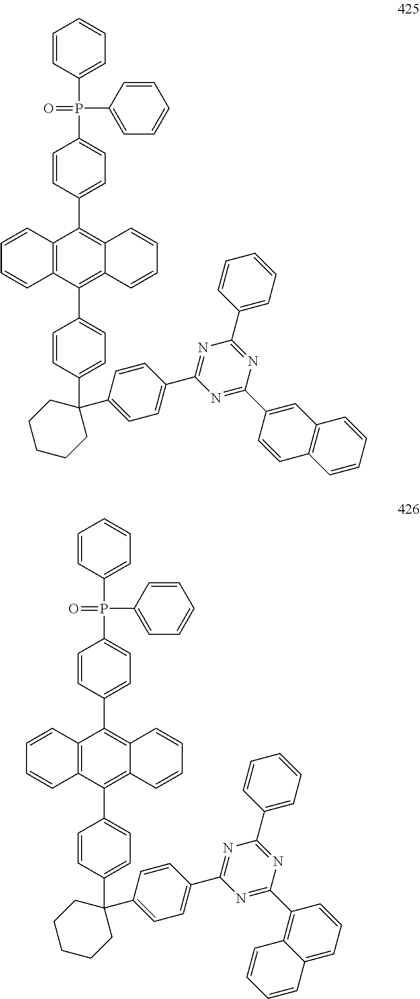 [SMILES: O=P(c1ccccc1)(c1ccccc1)c1ccc(-c2c3ccccc3c(-c3ccc(C4(c5ccc(-c6nc(-c7ccccc7)nc(-c7ccc8ccccc8c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7cccc8ccccc78)n6)cc5)CCCCC4)cc3)c3ccccc23)cc1]

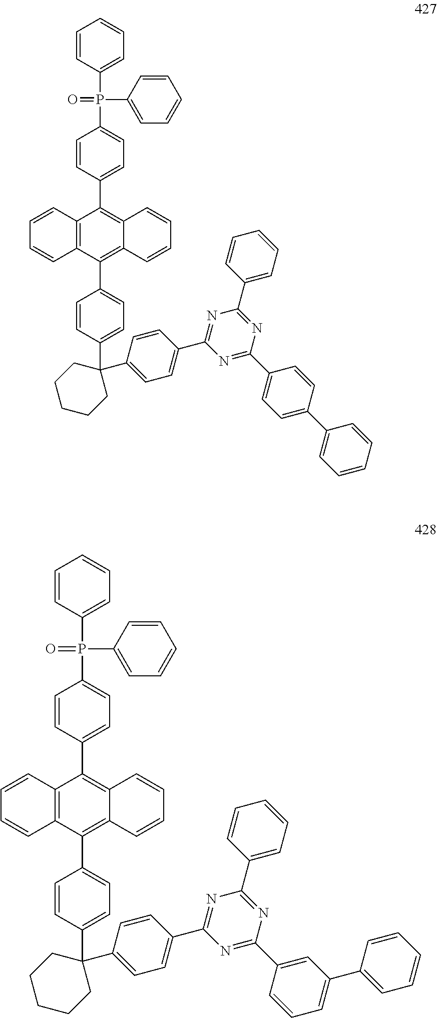 [SMILES: O=P(c1ccccc1)(c1ccccc1)c1ccc(-c2c3ccccc3c(-c3ccc(C4(c5ccc(-c6nc(-c7ccccc7)nc(-c7ccc(-c8ccccc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7cccc(-c8ccccc8)c7)n6)cc5)CCCCC4)cc3)c3ccccc23)cc1]

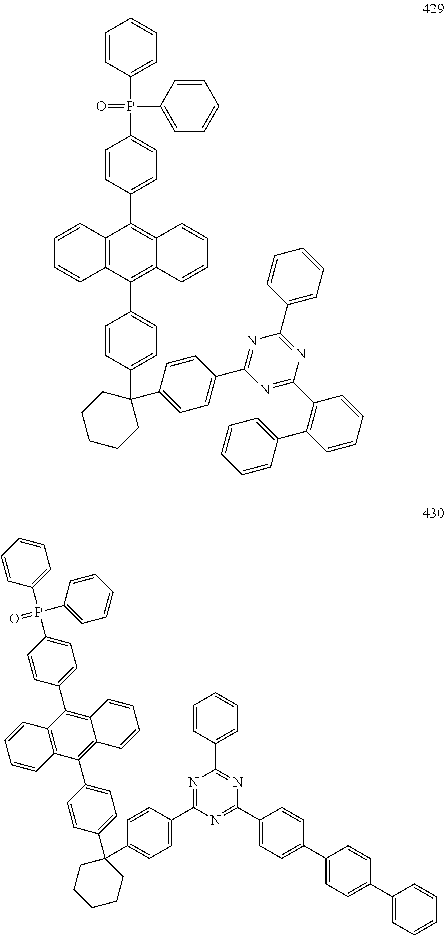 [SMILES: O=P(c1ccccc1)(c1ccccc1)c1ccc(-c2c3ccccc3c(-c3ccc(C4(c5ccc(-c6nc(-c7ccccc7)nc(-c7ccccc7-c7ccccc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7ccc(-c8ccc(-c9ccccc9)cc8)cc7)n6)cc5)CCCCC4)cc3)c3ccccc23)cc1]

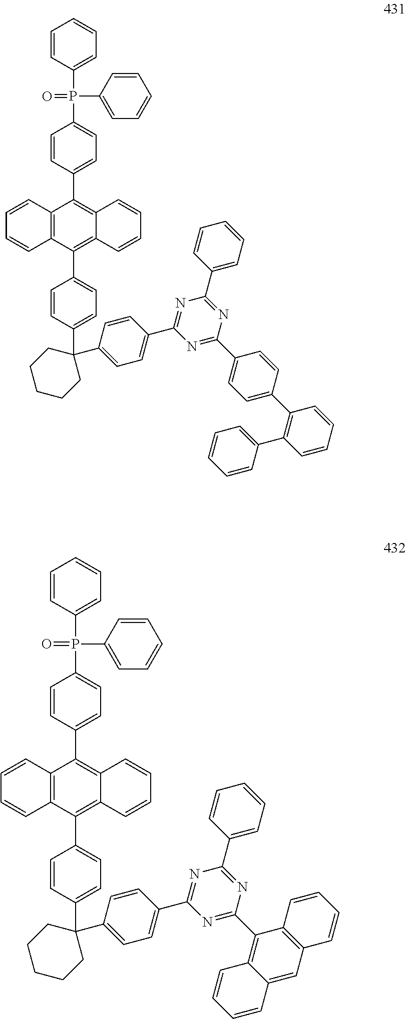 [SMILES: O=P(c1ccccc1)(c1ccccc1)c1ccc(-c2c3ccccc3c(-c3ccc(C4(c5ccc(-c6nc(-c7ccccc7)nc(-c7ccc(-c8ccccc8-c8ccccc8)cc7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccccc7)nc(-c7c8ccccc8cc8ccccc78)n6)cc5)CCCCC4)cc3)c3ccccc23)cc1]

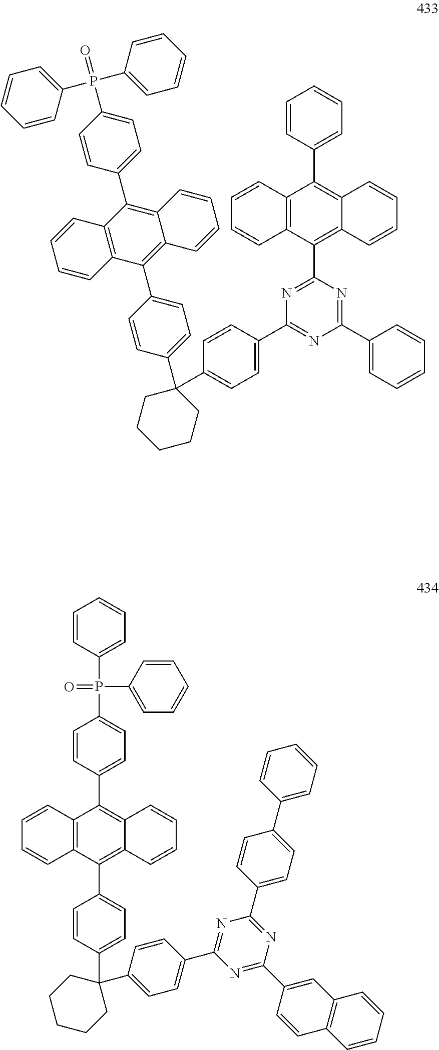 [SMILES: O=P(c1ccccc1)(c1ccccc1)c1ccc(-c2c3ccccc3c(-c3ccc(C4(c5ccc(-c6nc(-c7ccccc7)nc(-c7c8ccccc8c(-c8ccccc8)c8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc8ccccc8c7)n6)cc5)CCCCC4)cc3)c3ccccc23)cc1]

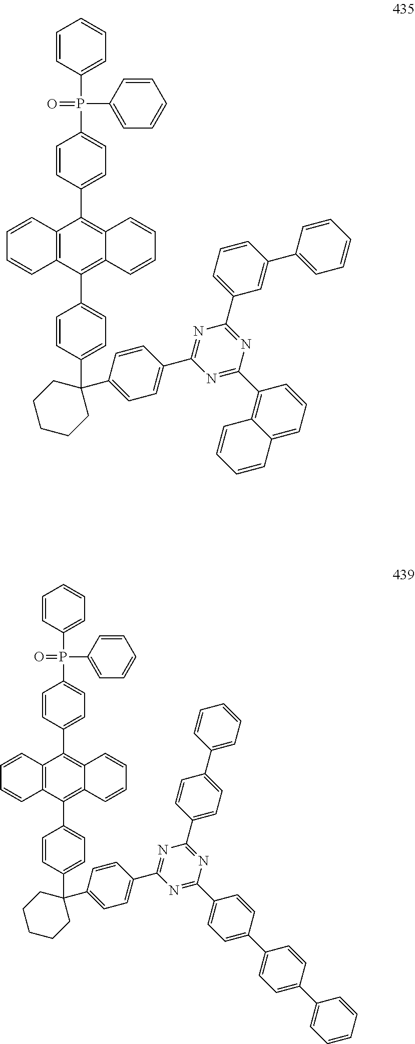 [SMILES: O=P(c1ccccc1)(c1ccccc1)c1ccc(-c2c3ccccc3c(-c3ccc(C4(c5ccc(-c6nc(-c7cccc(-c8ccccc8)c7)nc(-c7cccc8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc(-c8ccc(-c9ccccc9)cc8)cc7)n6)cc5)CCCCC4)cc3)c3ccccc23)cc1]

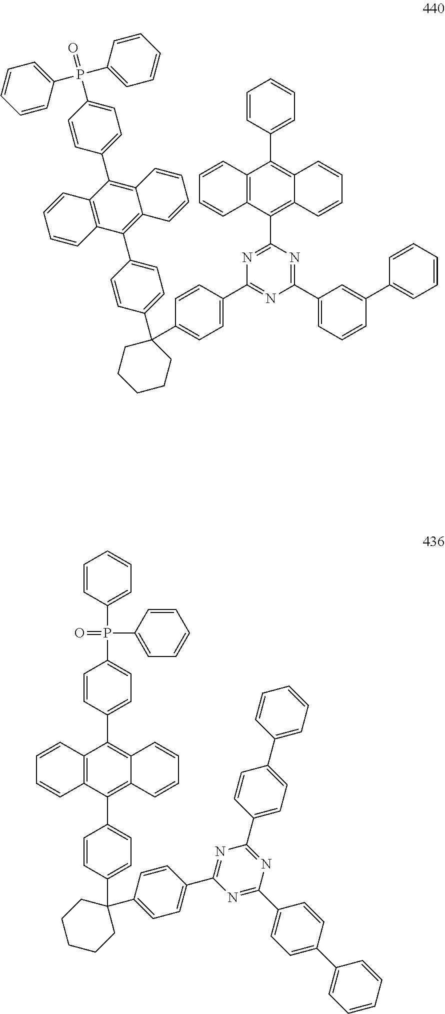 [SMILES: O=P(c1ccccc1)(c1ccccc1)c1ccc(-c2c3ccccc3c(-c3ccc(C4(c5ccc(-c6nc(-c7cccc(-c8ccccc8)c7)nc(-c7c8ccccc8c(-c8ccccc8)c8ccccc78)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccc(-c8ccccc8)cc7)n6)cc5)CCCCC4)cc3)c3ccccc23)cc1]

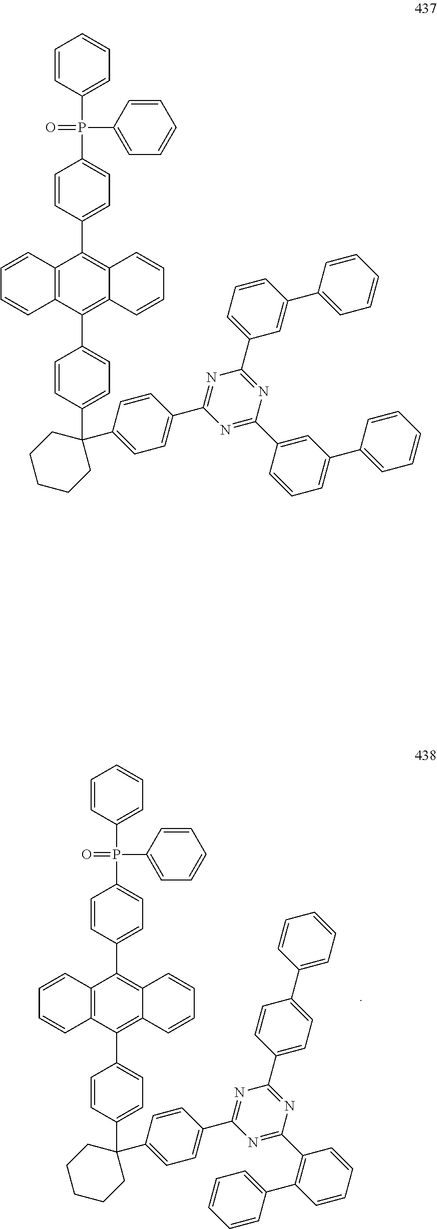 [SMILES: O=P(c1ccccc1)(c1ccccc1)c1ccc(-c2c3ccccc3c(-c3ccc(C4(c5ccc(-c6nc(-c7cccc(-c8ccccc8)c7)nc(-c7cccc(-c8ccccc8)c7)n6)cc5)CCCCC4)cc3)c3ccccc23)cc1 ; O=P(c1ccccc1)(c1ccccc1)c1ccc(-c2c3ccccc3c(-c3ccc(C4(c5ccc(-c6nc(-c7ccc(-c8ccccc8)cc7)nc(-c7ccccc7-c7ccccc7)n6)cc5)CCCCC4)cc3)c3ccccc23)cc1]

18. A display device comprising:
a base layer;
a circuit layer on the base layer; and
a display element layer comprising a light emitting element, and on the circuit layer,
wherein the light emitting element comprises a first electrode, a second electrode opposite to the first electrode, and at least one functional layer between the first electrode and the second electrode, and
the at least one functional layer comprises a compound represented by Formula 1: 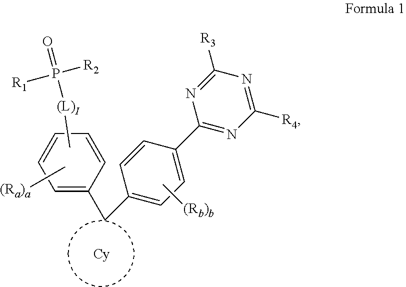
and
in Formula 1,
Cy is a substituted or unsubstituted cycloalkyl group of 3 to 30 ring-forming carbon atoms,
L is a substituted or unsubstituted arylene group of 6 to 30 ring-forming carbon atoms, or a substituted or unsubstituted heteroarylene group of 2 to 30 ring-forming carbon atoms,
R₁ to R₄ are each independently a substituted or unsubstituted alkyl group of 1 to 10 carbon atoms, or a substituted or unsubstituted aryl group of 6 to 30 ring-forming carbon atoms,
Rₐ and R_{b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“a” and “b” are each independently an integer of 0 to 4, and
“l” is 1 or 2.

19. The display device of claim 18, wherein the at least one functional layer comprises an emission layer, a hole transport region between the first electrode and the emission layer, and an electron transport region between the emission layer and the second electrode, and
the electron transport region comprises the compound represented by Formula 1.

20. The display device of claim 18, further comprising a light control layer on the display element layer,
wherein the light control layer comprises a quantum dot.
